(19) United States
(12) Patent Application Publication
(10) Pub. No.: US 2024/0090310 A1
(43) Pub. Date: Mar. 14, 2024

(54) ORGANIC ELECTROLUMINESCENT MATERIALS AND DEVICES

(71) Applicant: UNIVERSAL DISPLAY CORPORATION, Ewing, NJ (US)

(72) Inventors: Jui-Yi TSAI, Newtown, PA (US); Alexey Borisovich DYATKIN, Ambler, PA (US); Walter YEAGER, Yardley, PA (US); Pierre-Luc T. BOUDREAULT, Pennington, NJ (US); Hsiao-Fan CHEN, Lawrence Township, NJ (US); Wei-Chun SHIH, Lawrenceville, NJ (US)

(73) Assignee: UNIVERSAL DISPLAY CORPORATION, Ewing, NJ (US)

(21) Appl. No.: 18/297,676

(22) Filed: Apr. 10, 2023

Related U.S. Application Data
(63) Continuation-in-part of application No. 18/177,178, filed on Mar. 2, 2023.
(60) Provisional application No. 63/332,165, filed on Apr. 18, 2022.
(60) Provisional application No. 63/353,920, filed on Jun. 21, 2022.
(60) Provisional application No. 63/385,994, filed on Dec. 5, 2022.
(60) Provisional application No. 63/350,150, filed on Jun. 8, 2022.
(60) Provisional application No. 63/351,049, filed on Jun. 10, 2022.
(60) Provisional application No. 63/356,191, filed on Jun. 28, 2022.
(60) Provisional application No. 63/392,731, filed on Jul. 27, 2022.
(60) Provisional application No. 63/385,730, filed on Dec. 1, 2022.
(60) Provisional application No. 63/406,019, filed on Sep. 13, 2022.
(60) Provisional application No. 63/407,981, filed on Sep. 19, 2022.
(60) Provisional application No. 63/408,357, filed on Sep. 20, 2022.
(60) Provisional application No. 63/408,686, filed on Sep. 21, 2022.
(60) Provisional application No. 63/382,134, filed on Nov. 3, 2022.
(60) Provisional application No. 63/417,746, filed on Oct. 20, 2022.
(60) Provisional application No. 63/481,143, filed on Jan. 23, 2023.
(60) Provisional application No. 63/476,204, filed on Dec. 20, 2022.

(51) Int. Cl. H10K 85/30; C07F 15/00; H10K 85/40; H10K 85/60

(52) U.S. Cl. CPC H10K 85/342; C07F 15/0033; H10K 85/40; H10K 85/615; H10K 85/622; H10K 85/626; H10K 85/654; H10K 85/657; H10K 85/6572; H10K 85/6574; H10K 85/6576; H10K 85/658; C07B 2200/05

(57) ABSTRACT

A compound comprising a first ligand L_{A} of Formula I,

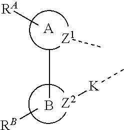

is provided. In Formula I, moiety A is a 5-membered or 6-membered ring; moiety B is a fused ring structure comprising at least four rings; K is a direct bond, O, or S; each of Z¹ and Z² is independently C or N; each R^{A} and R^{B} is independently hydrogen or a General Substituent; at least one R^{B} comprises a cyclic group or an electron-withdrawing group; L_{A} is coordinated to a metal M that has an atomic mass of at least 40 and is optionally coordinated to other ligands; and the ligand L_{A} is optionally linked with other ligands. Formulations, OLEDs, and consumer products including the compound are also provided.

### CROSS-REFERENCE TO RELATED APPLICATIONS

This application is a continuation-in-part of U.S. patent application Ser. No. 18/058,461, filed Nov. 23, 2022, and U.S. patent application Ser. No. 18/177,178, filed on Mar. 2, 2023. This application claims priority under 35 U.S.C. § 119(e) to U.S. Provisional Applications No. 63/481,143, filed on Jan. 23, 2023, No. 63/476,204, filed Dec. 20, 2022, No. 63/385,994, filed Dec. 5, 2022, No. 63/385,730, filed Dec. 1, 2022, No. 63/382,134, filed Nov. 3, 2022, No. 63/417,746, filed Oct. 20, 2022, No. 63/408,686, filed Sep. 21, 2022, No. 63/408,357, filed Sep. 20, 2022, No. 63/407,981, filed Sep. 19, 2022, No. 63/406,019, filed Sep. 13, 2022, No. 63/392,731, filed Jul. 27, 2022, No. 63/356,191, filed Jun. 28, 2022, No. 63/354,721, filed Jun. 23, 2022, No. 63/353,920, filed Jun. 21, 2022, No. 63/351,049, filed Jun. 10, 2022, No. 63/350,150, filed Jun. 8, 2022, No. 63/332,165, filed Apr. 18, 2022, the entire contents of all the above referenced applications are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound comprising a first ligand L_{A} of Formula I,

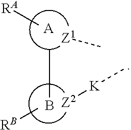

In Formula I: moiety A is a 5-membered or 6-membered carbocyclic or heterocyclic ring; moiety B is a fused ring structure comprising at least three rings, each of which is independently heterocyclic or carbocyclic; K is a direct bond, O, or S; each of Z¹ and Z² is independently C or N; each of R^{A} and R^{B} independently represents mono to the maximum possible number of substitutions, or no substitution; each R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; any two R^{A} or R^{B} can be joined or fused to form a ring; at least one R^{B} comprises a cyclic group or an electron-withdrawing group; L_{A} is coordinated to a metal M; metal M has an atomic mass of at least 40 and can be coordinated to other ligands; and the ligand L_{A} is optionally linked with other ligands to comprise a tridentate, tetradentate, pentadentate, or hexadentate ligand.

In another aspect, the present disclosure provides a formulation including a compound having a first ligand L_{A} of Formula I as described herein.

In yet another aspect, the present disclosure provides an OLED having an organic layer comprising a compound having a first ligand L_{A} of Formula I as described herein.

In yet another aspect, the present disclosure provides a consumer product comprising an OLED with an organic layer comprising a compound having a first ligand L_{A} of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “selenyl” refers to a —SeRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “germyl” refers to a —Ge(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, aryl, heteroaryl, sulfanyl, and combinations thereof.

In yet other instances, the Most Preferred General Substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution).

Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. pat. application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2,2′ positions in a biphenyl, or 1,8 position in a naphthalene, as long as they can form a stable fused ring system.

### B. The Compounds of the Present Disclosure

In one aspect, the present disclosure provides a compound comprising a first ligand L_{A} of Formula

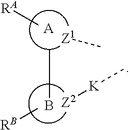

### In Formula I:

moiety A is a 5-membered or 6-membered carbocyclic or heterocyclic ring;
moiety B is a fused ring structure comprising at least three rings, each of which is independently heterocyclic or carbocyclic;
K is a direct bond, O, or S;
each of Z¹ and Z² is independently C or N;
each of R^{A} and R^{B} independently represents mono to the maximum possible number of substitutions, or no substitution;
each R^{A} and R^{B} is independently hydrogen or a substituent selected from the group consisting of the General Substituents defined herein;
any two R^{A} or R^{B} can be joined or fused to form a ring;
at least one R^{B} comprises a cyclic group or an electron-withdrawing group; L_{A} is coordinated to a metal M;
metal M has an atomic mass of at least 40 and can be coordinated to other ligands; and the ligand L_{A} is optionally linked with other ligands to comprise a tridentate, tetradentate, pentadentate, or hexadentate ligand.

In some embodiments, each R^{A} and R^{B} is independently hydrogen or a substituent selected from the group consisting of the Preferred General Substituents defined herein. In some embodiments, each R^{A} and R^{B} is independently hydrogen or a substituent selected from the group consisting of the More Preferred General Substituents defined herein. In some embodiments, each R^{A} and R^{B} is independently hydrogen or a substituent selected from the group consisting of the Most Preferred General Substituents defined herein.

In some embodiments, the at least one R^{B} that comprises a cyclic group or an electron-withdrawing group is not joined or fused with another R^{A} or R^{B} to form a ring.

In some embodiments, moiety A is selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, phenanthridine, fluorene, and aza-fluorene. In some embodiments, the aza variant includes one N on a benzo ring. In some embodiments, the aza variant includes one N on a benzo ring and the N is bonded to the metal M.

In some embodiments, K can be a direct bond. In some embodiments, K can be O. In some embodiments, K can be S. It should be understood that when K is O or S, Z² is C.

In some embodiments, when K is a direct bond and moiety A is an imidazole ring, then two R^{A} are not joined to form a 6-membered ring. In some embodiments, when K is a direct bond and moiety A is an imidazole ring, then two R^{A} are not joined to form a phenyl ring. In some embodiments, when K is a direct bond and moiety A is an imidazole ring and one N atom of the imidazole ring is coordinated to a metal, then two R^{A} are not joined to form a 6-membered ring. In some embodiments, when K is a direct bond and moiety A is an imidazole ring and one N atom of the imidazole ring is coordinated to a metal, then two R^{A} are not joined to form a phenyl ring. In some embodiments, when K is a direct bond and moiety A is a benzimidazole group and one N atom of the benzimidazole group is coordinated to a metal, then moiety B is a polycyclic fused ring structure comprising at least 5 rings. In some embodiments, when moiety A is a benzimidazole group and one N atom of the benzimidazole group is coordinated to a metal, then the ring of moiety B coordinated to the metal is not a benzene ring. In some embodiments, when moiety A of L_{A} is a benzimidazole group, then L_{A} does not form a metal complex with another ligand containing a substituted pyridine ring. In some embodiments, when moiety A of L_{A} is a benzimidazole group, then L_{A} does not form a metal complex with another ligand containing a silyl or germyl substituted pyridine moiety. In some embodiments, when moiety A of L_{A} is a benzimidazole group, then L_{A} does not form a metal complex with another ligand containing a 3-silyl or 3-germyl substituted pyridine moiety.

In some embodiments, moiety B comprises at least one ring of Formula II,

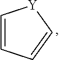

where Y is selected from the group consisting of BR′, BR′R″, NR′, PR′, P(O)R′, O, S, Se, C═O, C═S, C═Se, C═NR′, C═CR′R″, S═O, SO₂, CR′, CR′R″, SiR′R″, GeR′R″, alkylene, cycloalkyl, aryl, cycloalkylene, arylene, heteroarylene, and combinations thereof. In some embodiments, each R′ or R″ is independently hydrogen or a substituent selected from the group consisting of the General Substituents defined herein.

In some embodiments including Formula II, moiety B comprises at least two rings of Formula II, wherein the at least two rings of Formula II may be the same or different.

In some embodiments, moiety B comprises exactly three fused rings, each of which is independently heterocyclic or carbocyclic. In some of such embodiments, two rings are 6-membered rings, and one ring is a 5-membered ring. In some of such embodiments, the middle ring is a 5-membered ring. In some of such embodiments, moiety B may not be dibenzofuran. In some of such embodiments, each of the rings is independently 5-membered or 6-membered aryl or heteroaryl. In some embodiments, each of the rings is independently selected from the group consisting of phenyl, pyridine, pyrimidine, pyridazine, pyrazine, triazine, imidazole, pyrazole, pyrrole, oxazole, furan, thiophene, thiazole, and triazole.

In some embodiments, moiety B is a fused ring structure comprising at least five rings, each of which is independently heterocyclic or carbocyclic.

In some embodiments, moiety B comprises at least four fused rings, and each of the at least four rings of moiety B is independently selected from the group consisting of phenyl, pyridine, pyrimidine, pyridazine, pyrazine, triazine, imidazole, pyrazole, pyrrole, oxazole, furan, thiophene, thiazole, and triazole.

In some embodiments, moiety B comprises at least three six-membered rings. In some embodiments, moiety B comprises at least three six-membered rings that are each independently phenyl or pyridine.

In some embodiments, moiety B comprises at least four six-membered rings. In some embodiments, moiety B comprises at least four six-membered rings that are each independently phenyl or pyridine.

In some embodiments, moiety B is a polycyclic fused ring structure. In some embodiments, moiety B is a polycyclic fused ring structure comprising at least three fused rings. In some embodiments, the polycyclic fused ring structure has two 6-membered rings and one 5-membered ring. In some such embodiments, the 5-membered ring is fused to the ring coordinated to metal M and the second 6-membered ring is fused to the 5-membered ring. In some embodiments, moiety B is selected from the group consisting of dibenzofuran, dibenzothiophene, dibenzoselenophene, and aza-variants thereof. In some such embodiments, moiety B can be further substituted at the position ortho- or meta- to the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, moiety B is a polycyclic fused ring structure comprising at least four fused rings. In some embodiments, the polycyclic fused ring structure comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, moiety B is a polycyclic fused ring structure comprising at least five fused rings. In some embodiments, the polycyclic fused ring structure comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, moiety B is independently an aza version of the fused rings as described above. In some such embodiments, moiety B independently contains exact one aza N atom. In some such embodiments, moiety B contains exact two aza N atoms, which can be in one ring, or in two different rings. In some such embodiments, the ring having aza N atom is at least separated by another two rings from the Ir atom. In some such embodiments, the ring having aza N atom is at least separated by another three rings from the Ir atom. In some such embodiments, each of the ortho position of the aza N atom is substituted.

In some embodiments, Z¹ is N and Z² is C. In some embodiments, Z¹ is C and Z² is N. In some embodiments, Z¹ is C and Z² is C. In some embodiments, Z¹ is N and Z² is N.

In some embodiments, at least one R^{A} is other than hydrogen and deuterium.

In some embodiments, at least one R^{B} is a cyclic group. In some embodiments, at least one R^{B} comprises an aryl or heteroaryl group. In some embodiments, at least one R^{B} comprises a cycloalkyl or heterocycloalkyl group, either of which may be substituted or unsubstituted.

In some embodiments, at least one R^{B} comprises at least one monocyclic group. In some embodiments, at least one R^{B} comprises a fused multicyclic group. In some of such embodiments, the fused multicyclic group may comprise all saturated carbocyclic or heterocyclic rings. In some of such embodiments, the fused multicyclic group may comprise all unsaturated carbocyclic or heterocyclic rings. In some of such embodiments, the fused multicyclic group may comprise both saturated and unsaturated carbocyclic or heterocyclic rings. In some of such embodiments, the fused multicyclic group may comprise aryl and/or heteroaryl rings. In some of such embodiments, the fused multicyclic group may be naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, phenanthridine, fluorene, and aza-fluorene. In some of such embodiments, the aza variant includes one N on a benzo ring. It should be understood that all the above fused multicyclic group can be unsubstituted or further substituted.

In some embodiments, at least one R^{B} is an electron-withdrawing group having Hammett constant larger than 0. In some embodiments, at least one R^{B} is an electron-withdrawing group having Hammett constant equal or larger than the number selected from the group consisting of 0.1, 0.2, 0.3, 0.4, 0.5, 0.6, 0.7, 0.8, 0.9, 1.0, and 1.1. In these embodiments, the electron-withdrawing group commonly comprises one or more highly electronegative elements such as but not limited to fluorine, oxygen, sulfur, nitrogen, chlorine, and bromine.

In some embodiments, at least one R^{B} comprises or is an electron-withdrawing group selected from the group consisting of the following LIST 1: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R)₃, (R)₂CCN, (R)₂CCF₃, CNC(CF₃)₂, BRR′, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

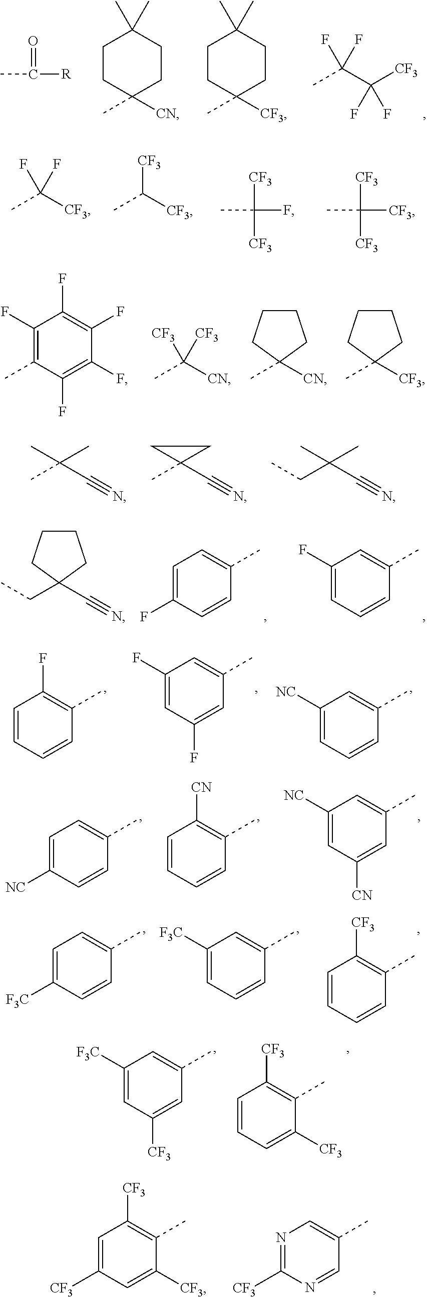

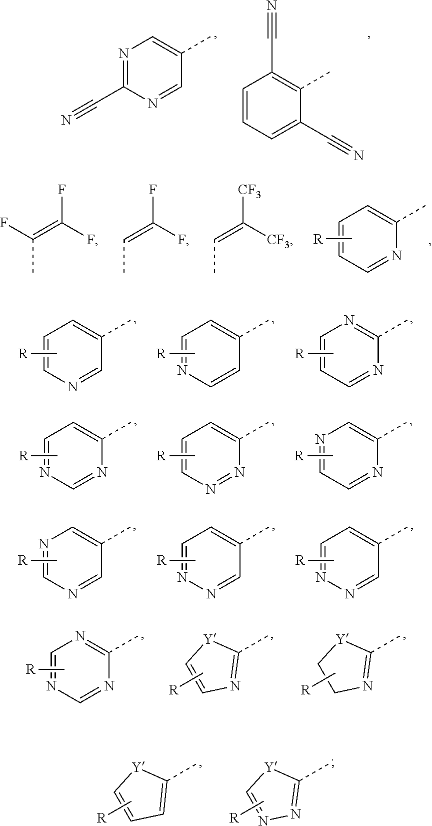

wherein Y′ is selected from the group consisting of BRₑ, NRₑ, PRₑ, O, S, Se, C═O, S═O, SO₂, CRₑR_{f}, SiRₑR_{f}, and GeReRf′, and each R, Rₑ, and R_{f} is independently a hydrogen or a substituent selected from the group consisting of the General Substituents defined herein. In some embodiments, R can be a mono up to the maximum number of allowable substitutions or no substitution.

In some embodiments of L_{A} of Formula I, at least one R^{B} is an electron-withdrawing group selected from the group consisting of:

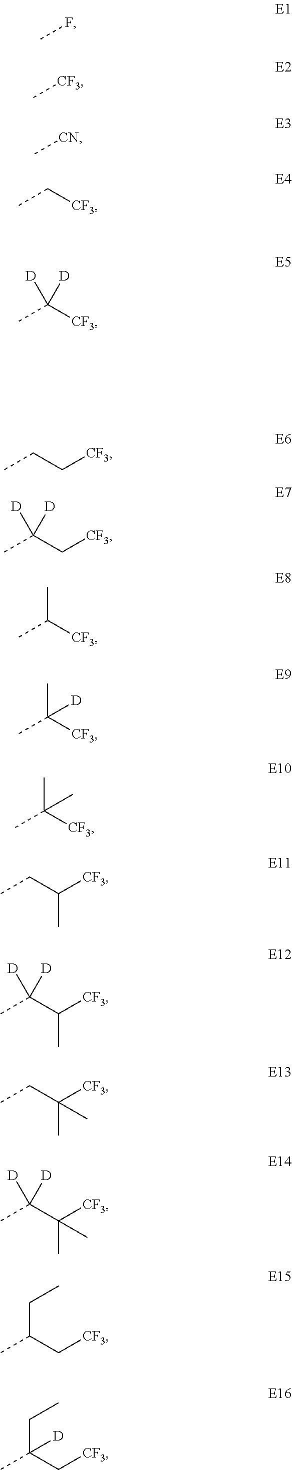

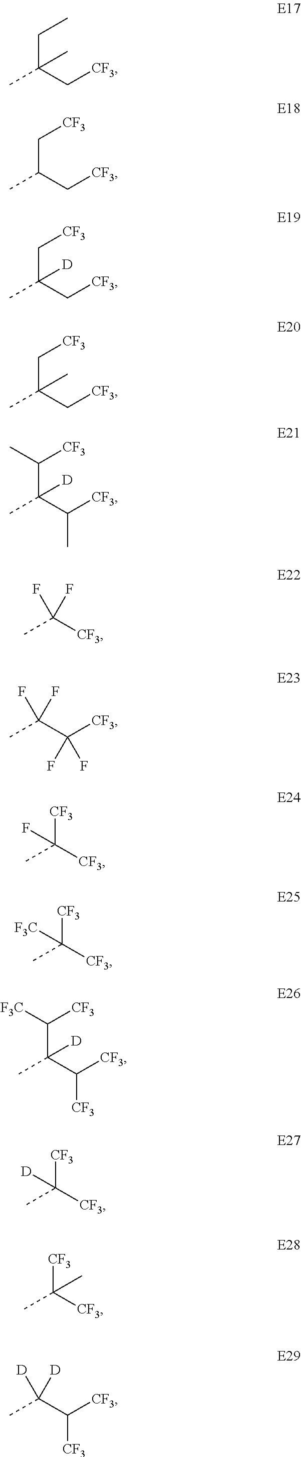

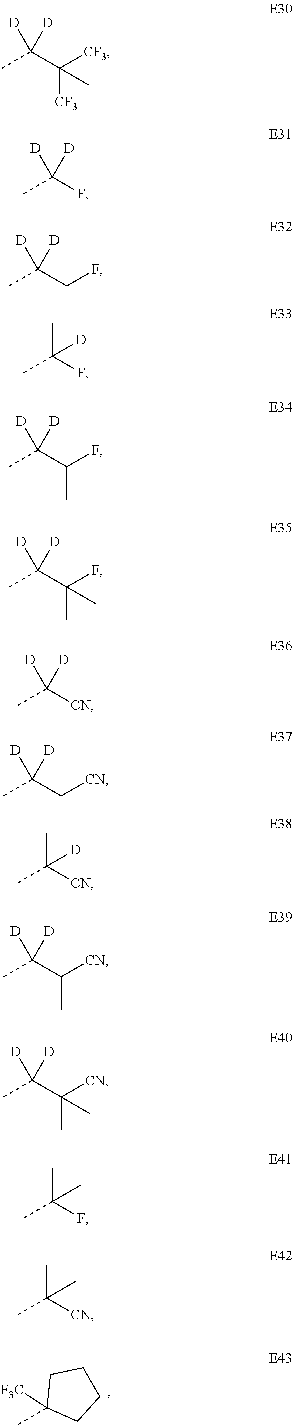

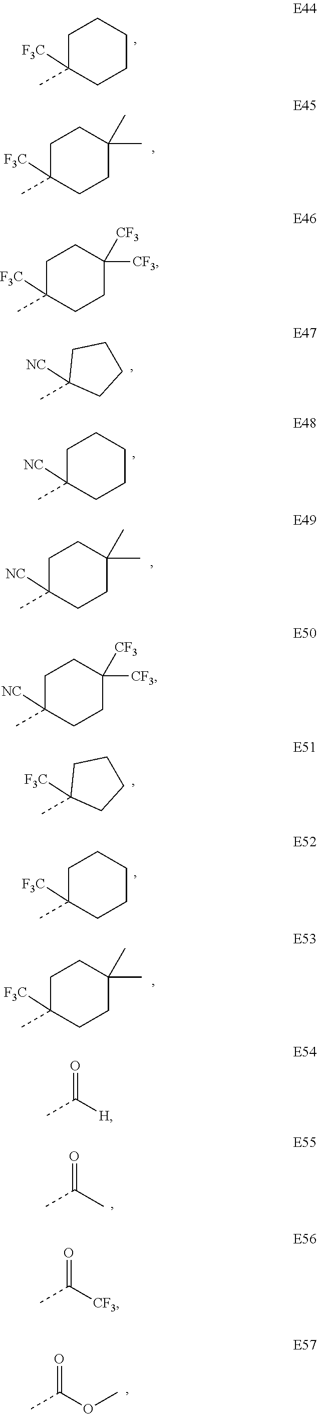

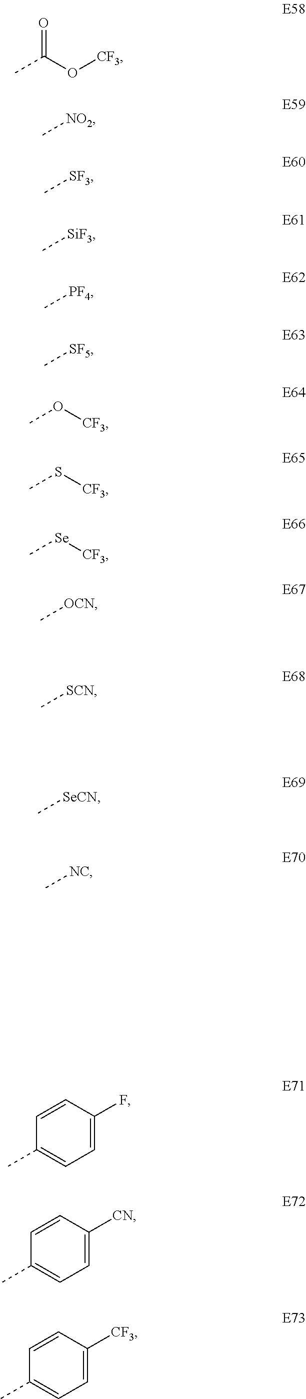

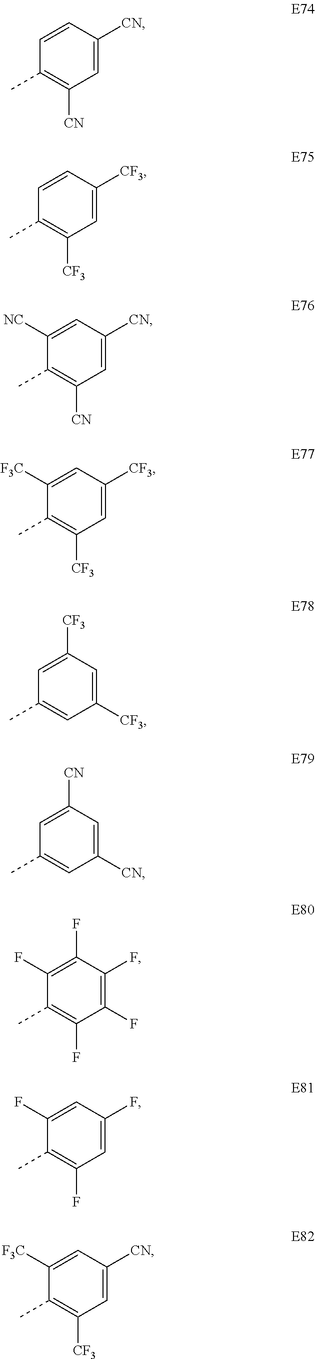

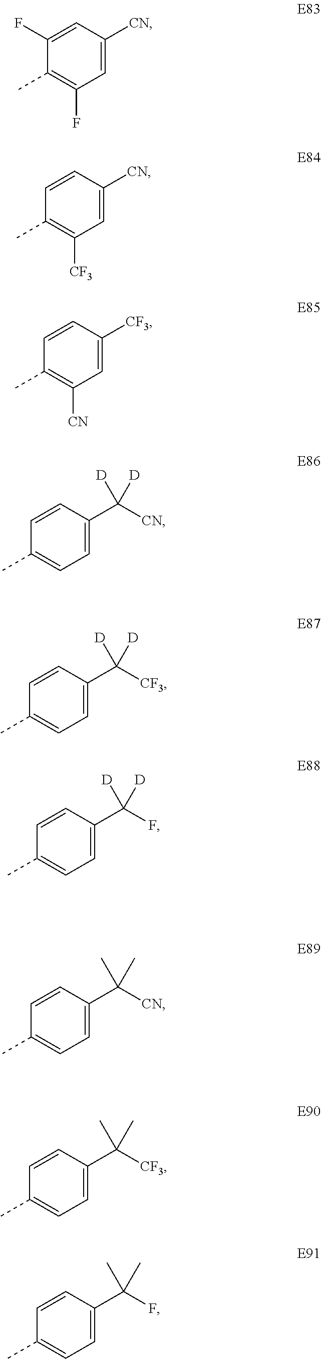

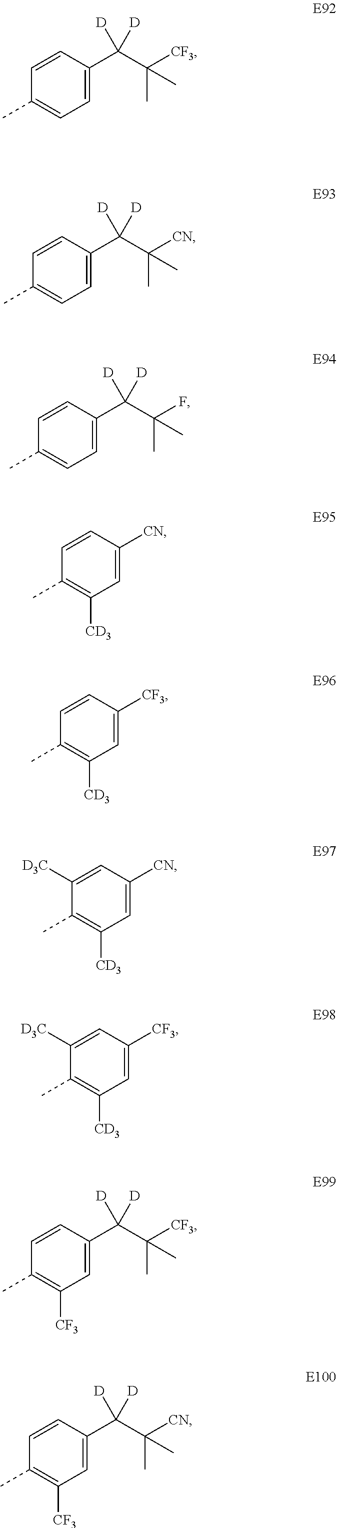

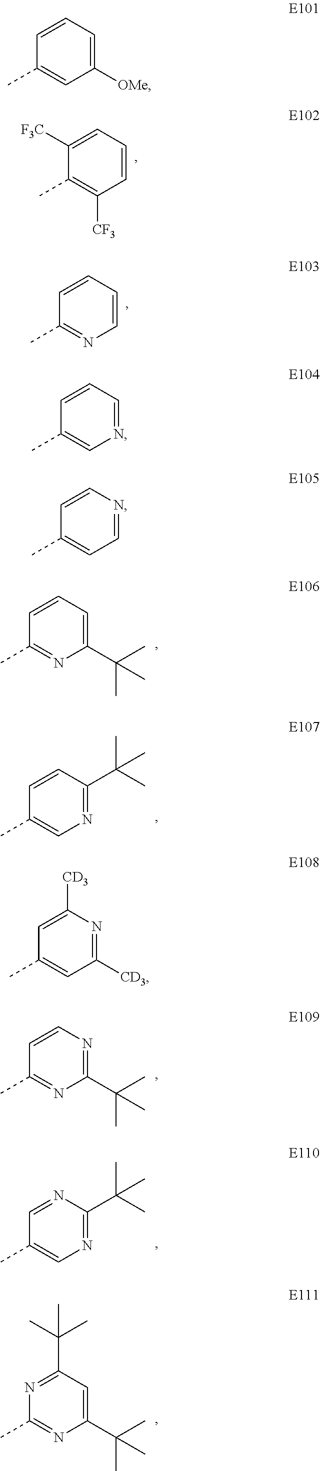

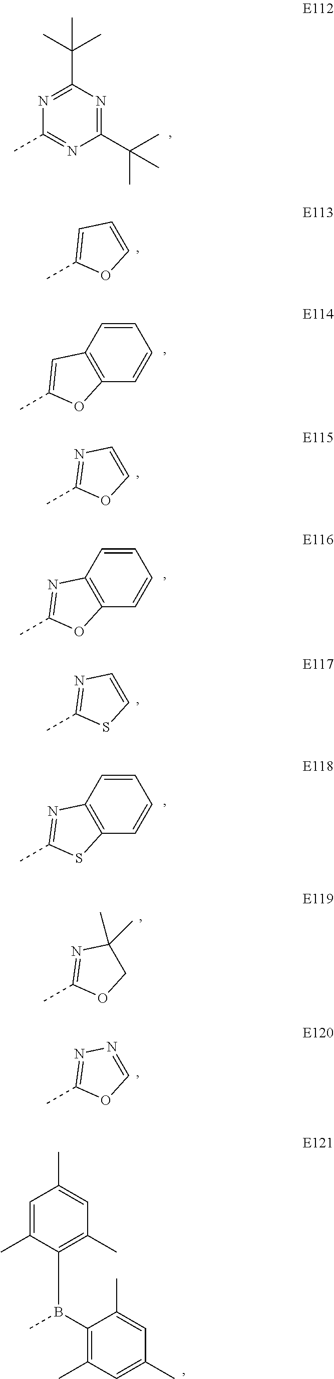

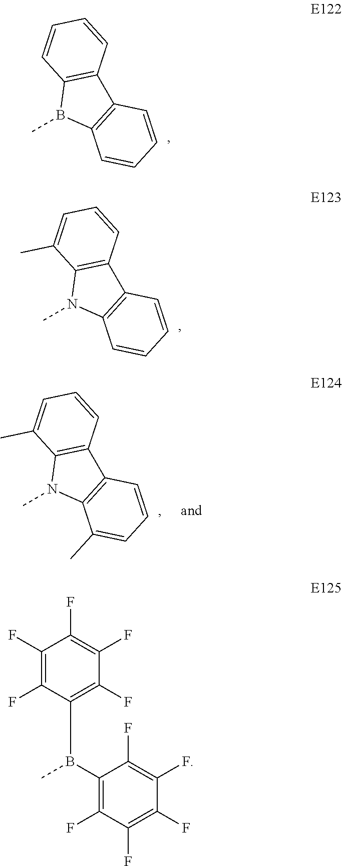

In some embodiments of L_{A} of Formula I, at least one R^{B} is an electron-withdrawing group selected from the group consisting of:

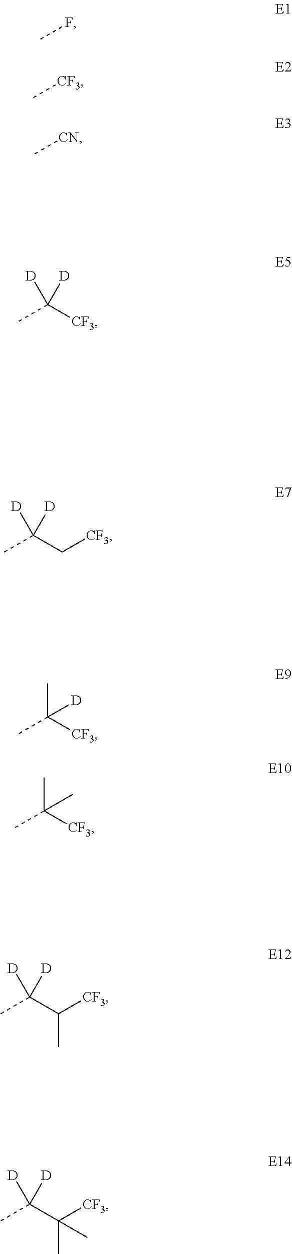

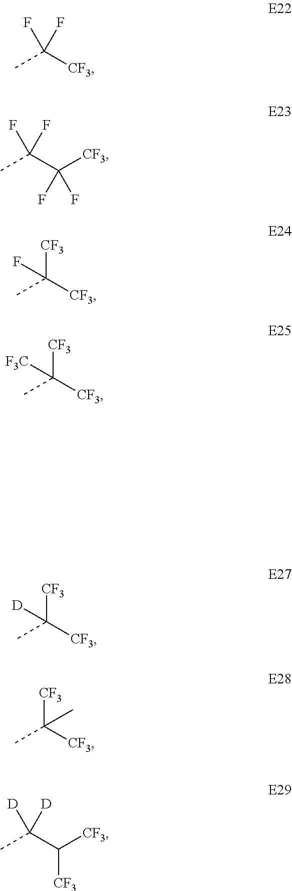

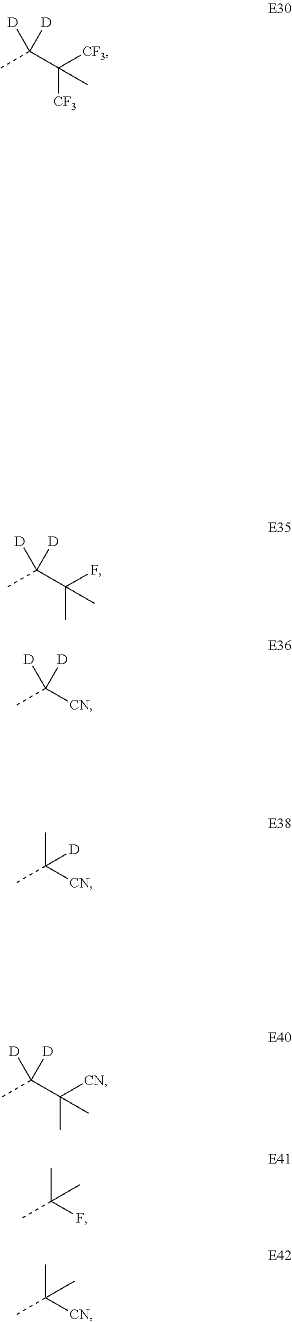

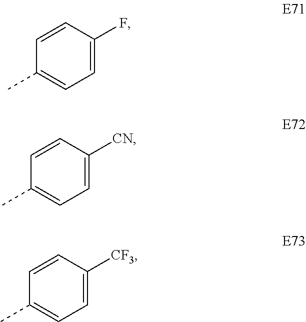

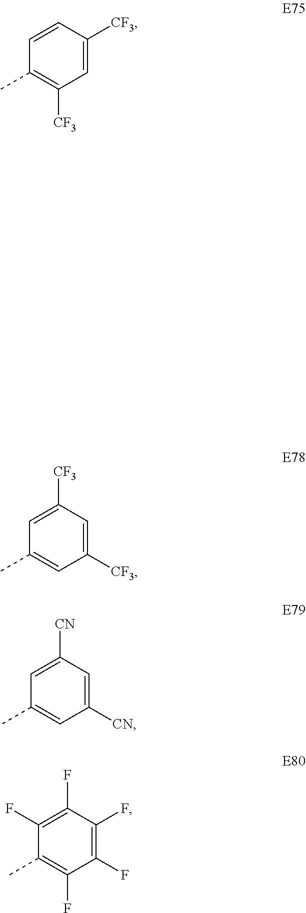

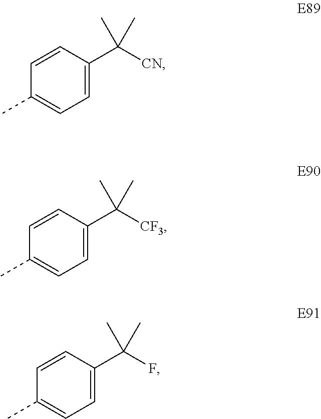

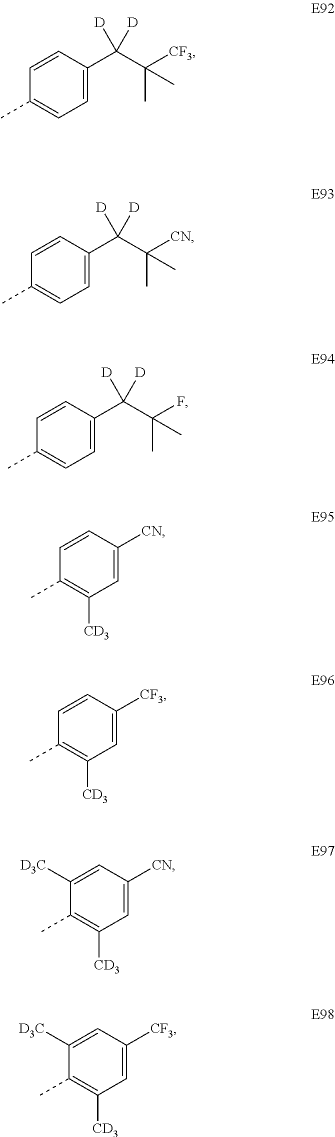

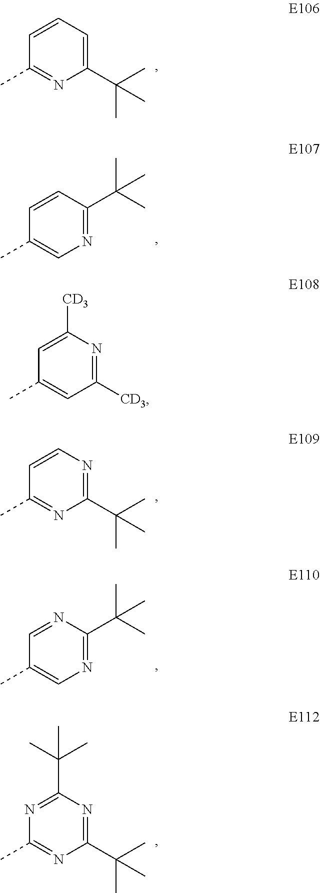

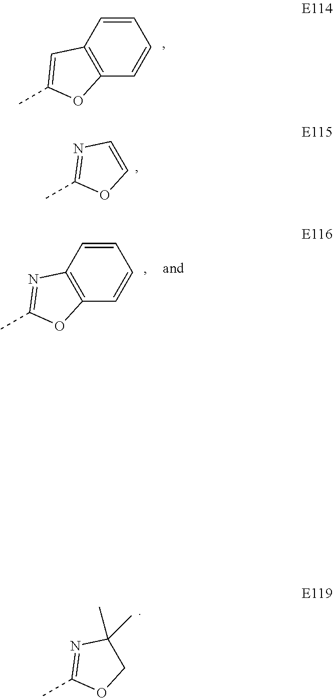

In some embodiments, at least one R^{B} is an electron-withdrawing group selected from the group consisting of:

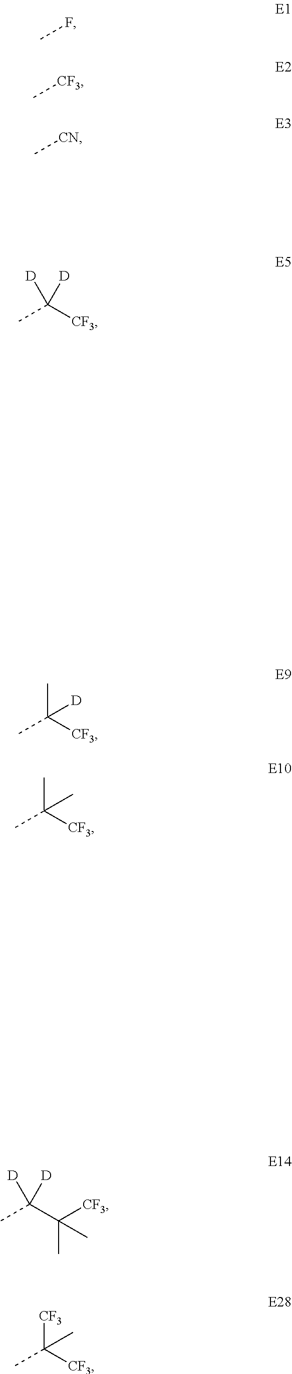

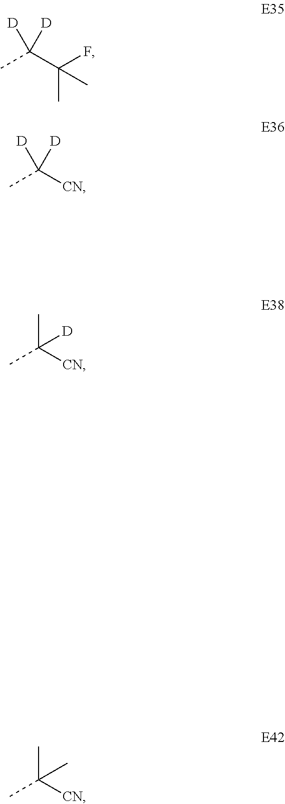

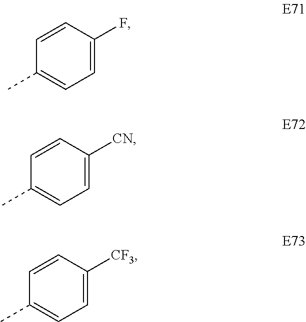

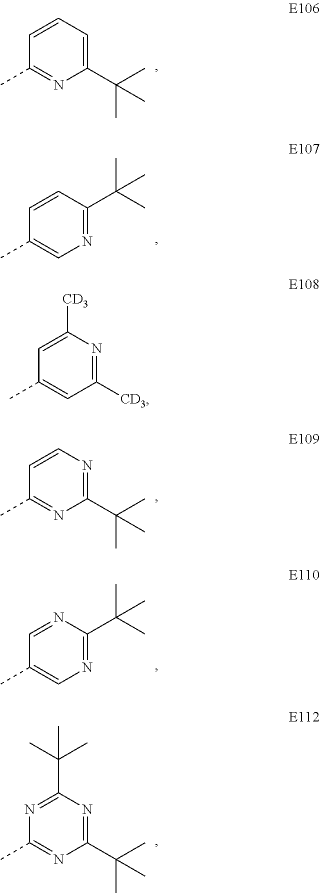

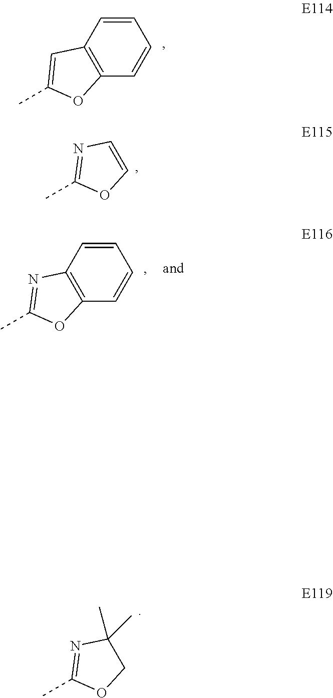

In some embodiments, at least one R^{B} is an electron-withdrawing group is selected from the group consisting of fluoride, perfluoroalkyl, perfluorocycloalkyl, perfluorovinyl, CN, SCN, SF₅, and SCF₃.

In some embodiments, the electron-withdrawing group is a π-electron deficient electron-withdrawing group. In some embodiments, the π-electron deficient electron-withdrawing group is selected from the group consisting of CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R)₃, BRR′, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

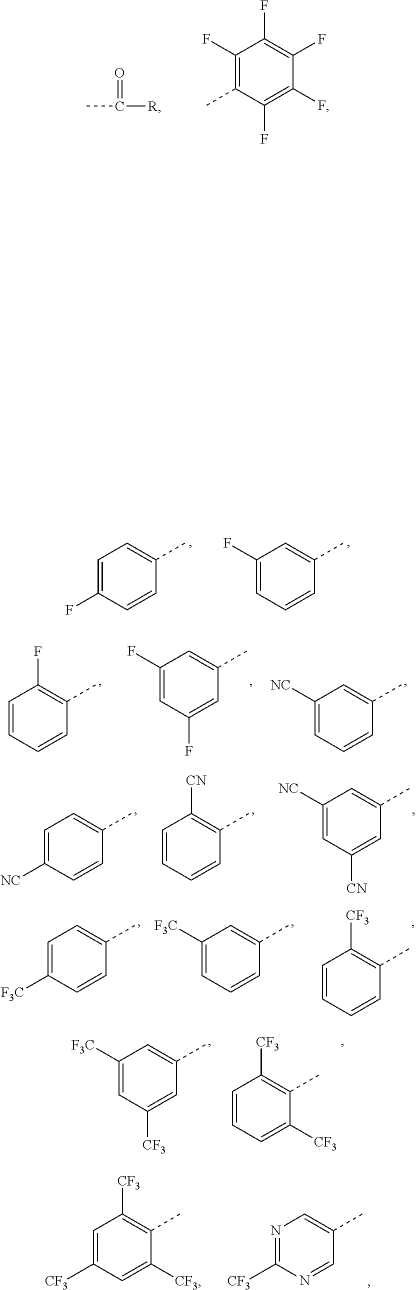

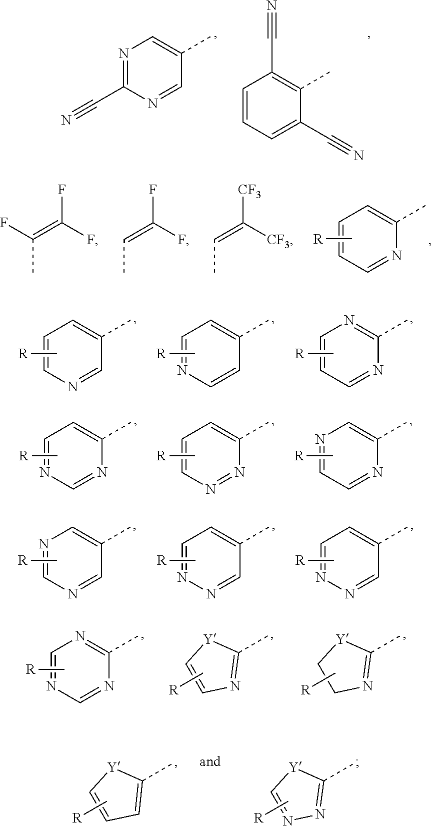

wherein each R, Rₑ, and R_{f} is independently a hydrogen or a substituent selected from the group consisting of the General Substituents defined herein; wherein Y′ is selected from the group consisting of BRₑ, NRₑ, PRₑ, O, S, Se, C═O, S═O, SO₂, CRₑR_{f}, SiRₑR_{f}, and GeRₑR_{f}. More detailed information about the π-electron deficient electron-withdrawing groups can be found in the U.S. Provisional Application No. 63/417,746, filed on Oct. 20, 2022, 2023, and 63/481,143, filed on Jan. 23, 2023, which are incorporated herein by reference.

In some embodiments, at least one R^{B} comprises a group selected from the group consisting of halogen, nitrile, fully fluorinated alkyl, and partially fluorinated alkyl. In some embodiments, at least one R^{B} is selected from the group consisting of F; CN, CF₃, cycloalkyl, and CH₂CF₃.

In some embodiments, the at least one R^{B} that comprises a cyclic group or an electron-withdrawing group is bonded to a distal ring of the fused ring structure of moiety B. As used herein, “distal” refers to the ring (or rings) that is farthest from the metal M.

In some embodiments, at least one R^{A} is other than hydrogen or deuterium. In some embodiments, at least one R^{A} is partially or fully deuterated alkyl.

In some embodiments, at least two R^{A} are other than hydrogen or deuterium. In some embodiments, at least two R^{A} are each independently partially or fully deuterated alkyl.

In some embodiments, two adjacent R^{A} or R^{B} may be joined to form a ring. In some embodiments, two adjacent R^{A} or R^{B} may be joined to form a 5-membered or 6-membered carbocyclic or heterocyclic aromatic ring. In some embodiments, two adjacent R^{A} or R^{B} may be joined to form a 5-membered or 6-membered carbocyclic or heterocyclic non-aromatic ring. In some embodiments, two adjacent R^{A} or R^{B} may be joined to form a ring selected from the group consisting of benzene, pyridine, pyrimidine, pyridazine, pyrazine, triazine, imidazole, pyrazole, pyrrole, oxazole, furan, thiophene, and thiazole.

In some embodiments, the metal M is selected from the group consisting of Ir, Os, Rh, Re, Ru, Pt, Pd, Cu, Ag, and Au. In some embodiments, metal M is Ir. In some embodiments, metal M is Pt or Pd.

In some embodiments, the ligand L_{A} is selected from the group consisting of the structures of the following LIST 2:

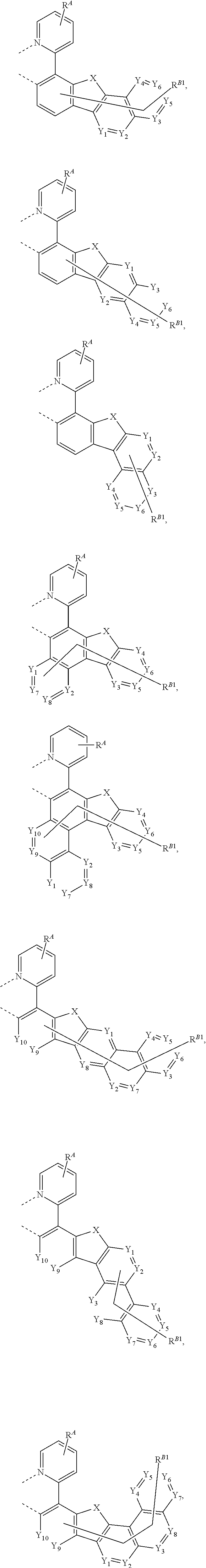

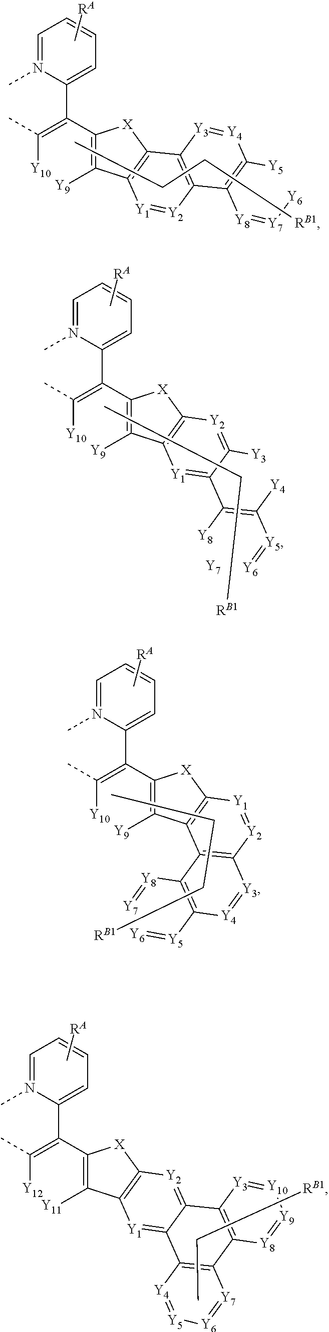

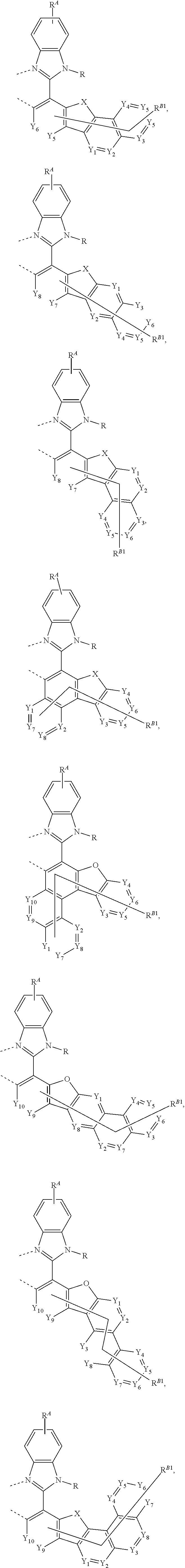

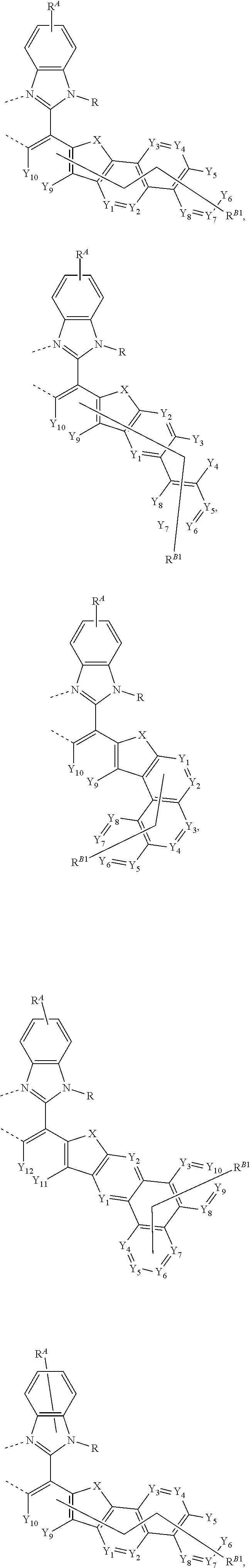

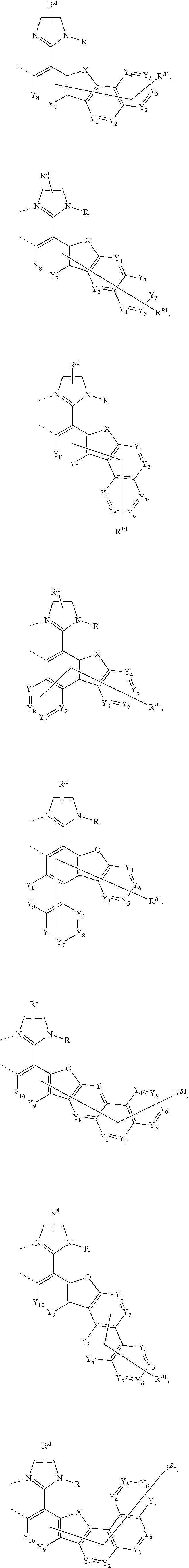

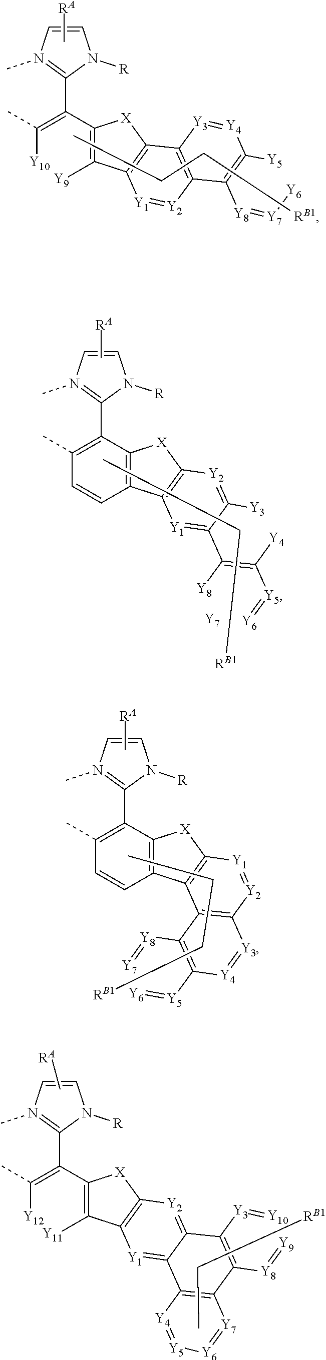

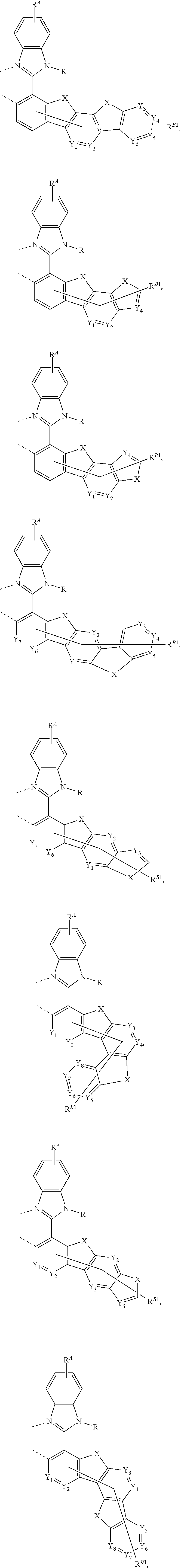

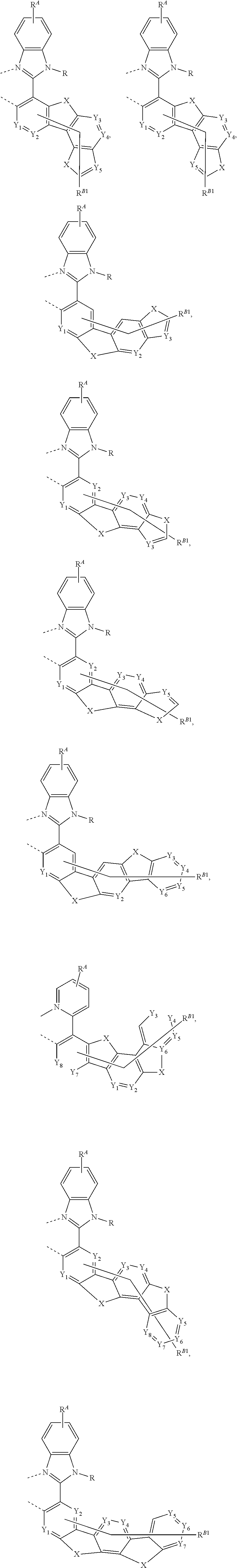

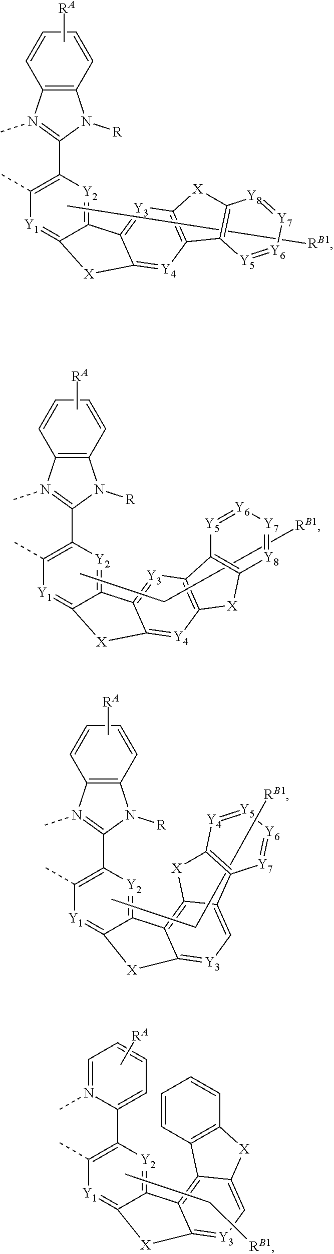

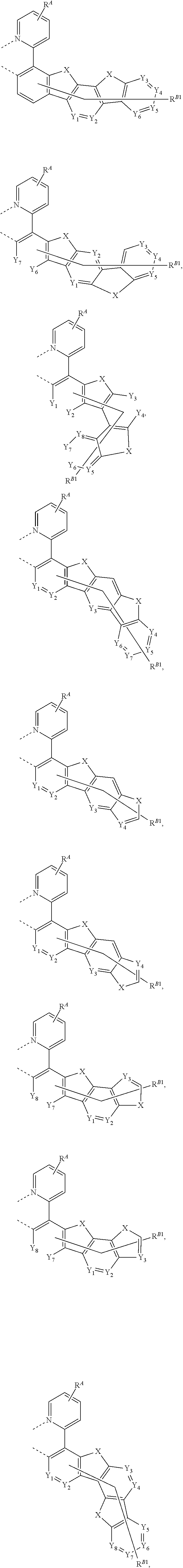

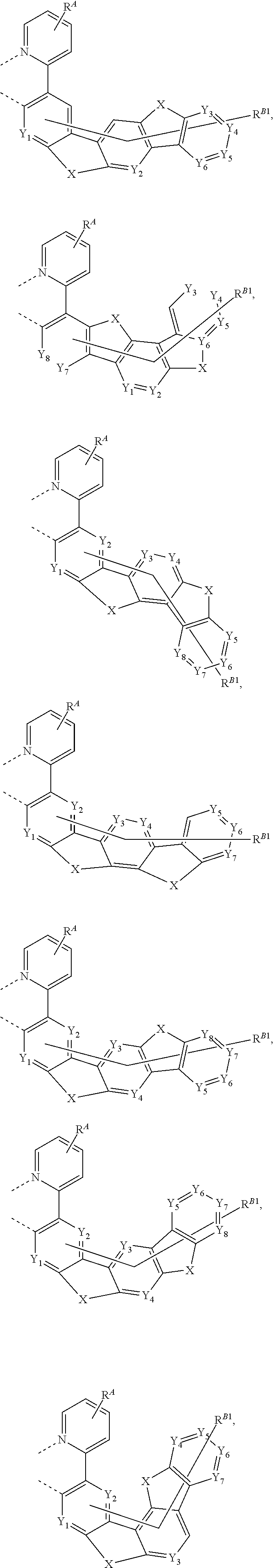

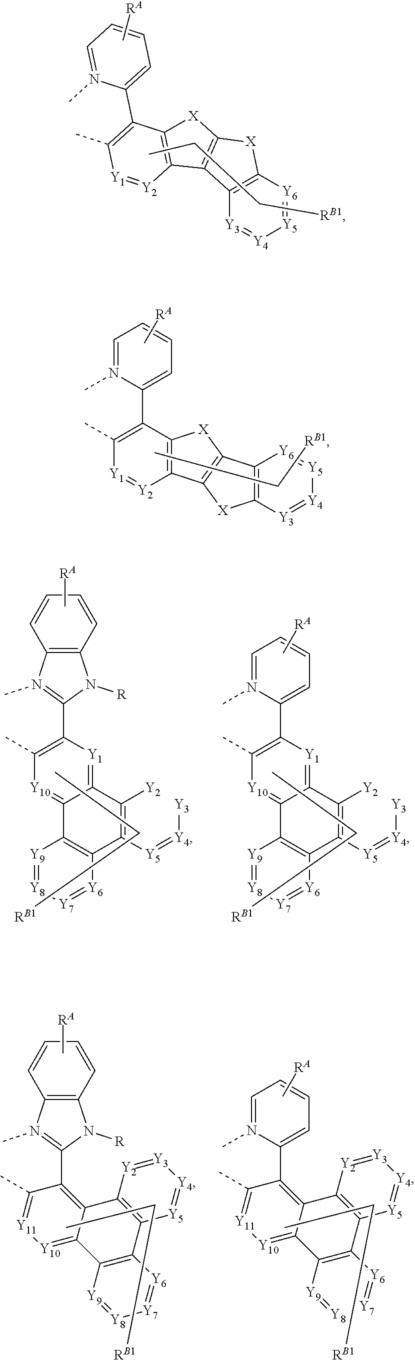

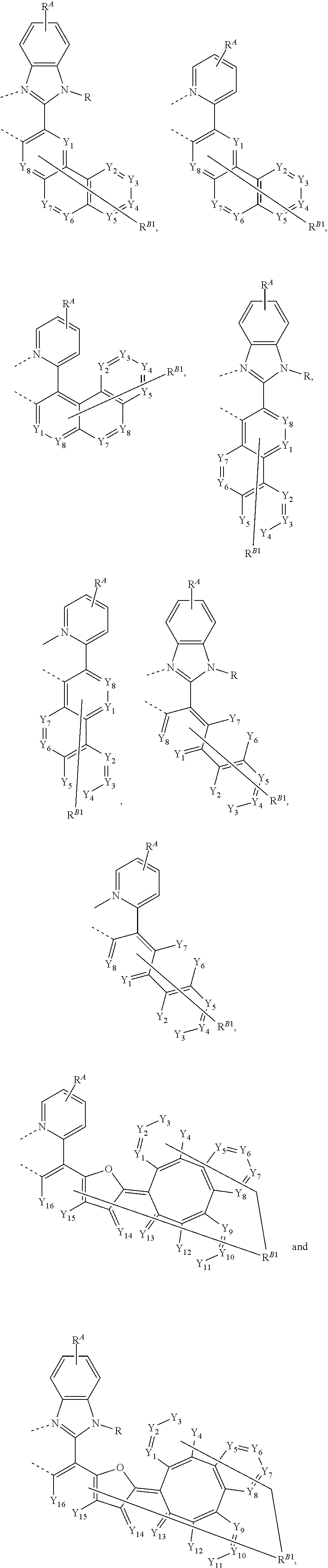

wherein:
each of Y₁, Y₂, Y₃, Y₄, Y₅, Y₆, Y₇, Y₈, Y₉, Y₁₀, Y₁₁, Y₁₂, Y₁₃, Y₁₄, Y₁₅, and Y₁₆ is independently C or N;
each X is independently O, S, CR₂, SiR₂ or NR;
R^{B1} represents mono to the maximum possible number of substitutions, or no substitution;
each R and R^{B1} is independently hydrogen or a substituent selected from the group consisting of the General Substituents defined herein;
at least one R^{B1} comprises a cyclic group or an electron-withdrawing group; and
two adjacent R^{B1} can be joined to form a ring.

In some embodiments, one R^{B1} is an electron-withdrawing group selected from the group consisting of the structures of LIST 1 as defined herein.

In some embodiments, one R^{B1} is a 5-membered or 6-membered carbocyclic or heterocyclic aromatic ring. In some embodiments, one R^{B1} is a 5-membered or 6-membered carbocyclic or heterocyclic non-aromatic ring. In some embodiments, one R^{B1} is selected from the group consisting of benzene, pyridine, pyrimidine, pyridazine, pyrazine, triazine, imidazole, pyrazole, pyrrole, oxazole, furan, thiophene, and thiazole.

In some embodiments, ligand L_{A} is selected from the group consisting of the structures of the following LIST 3:

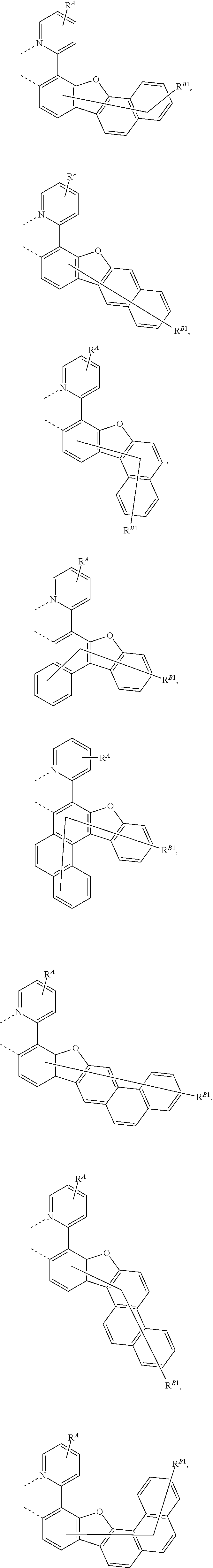

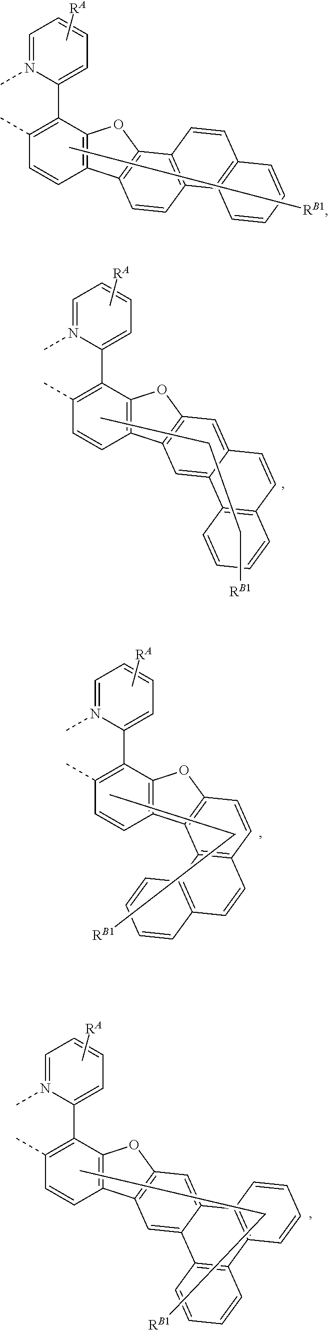

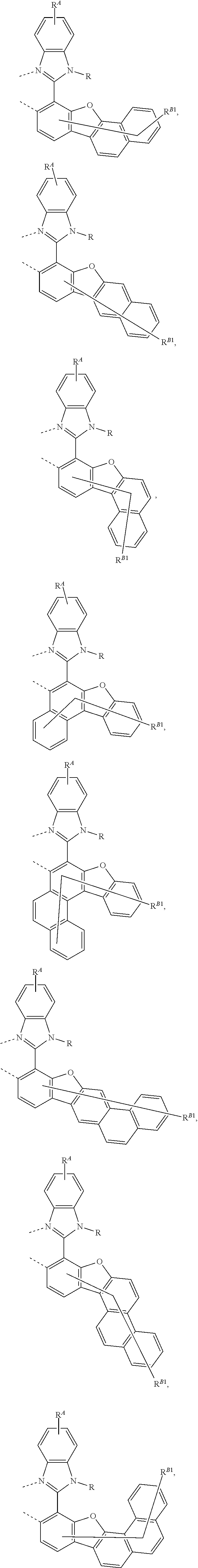

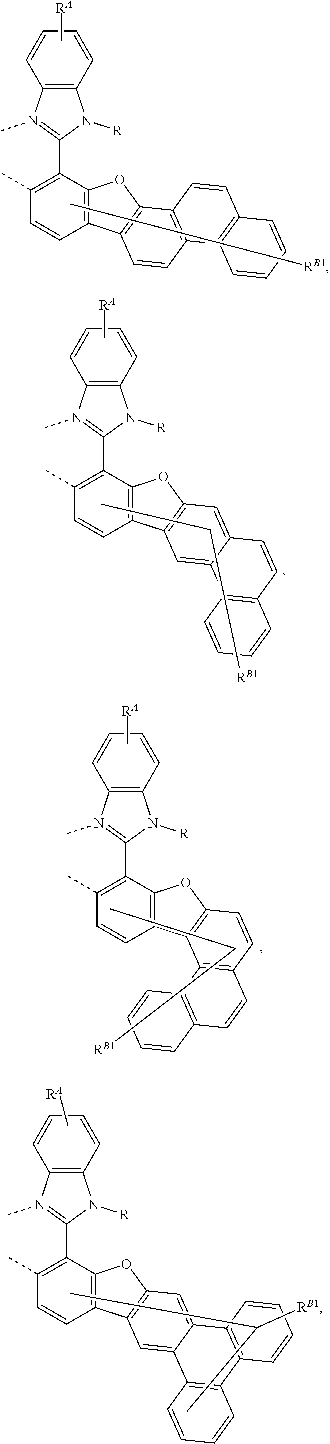

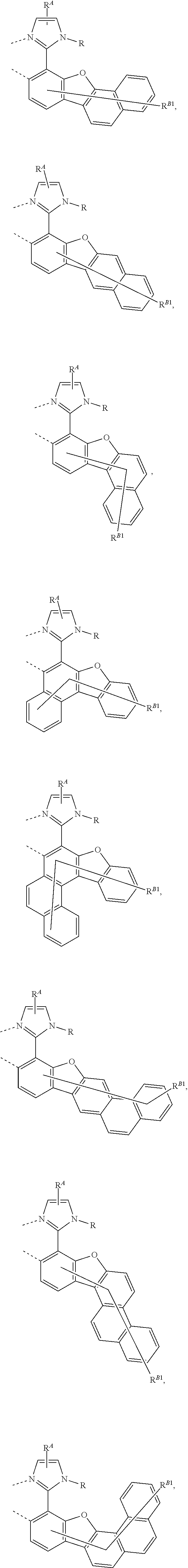

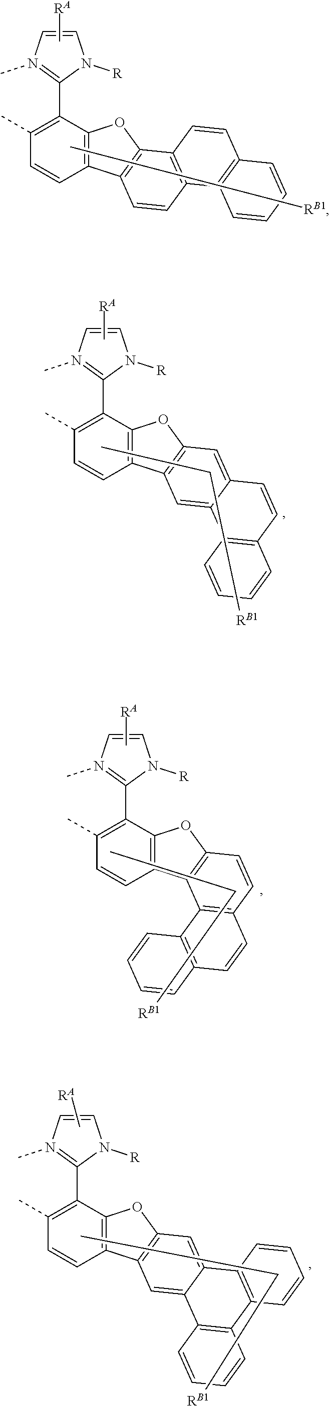

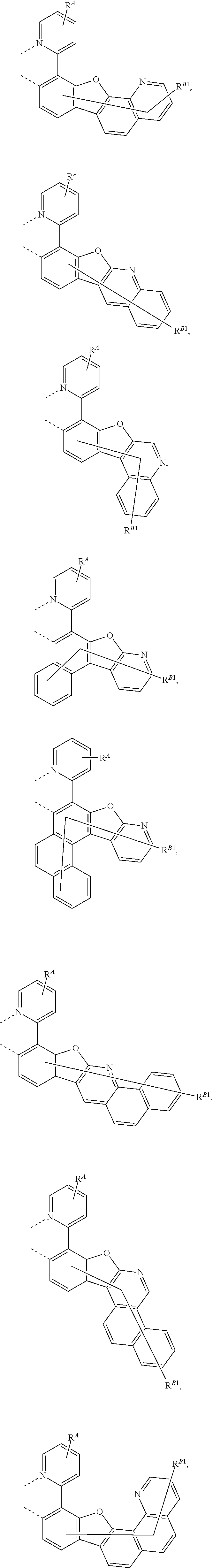

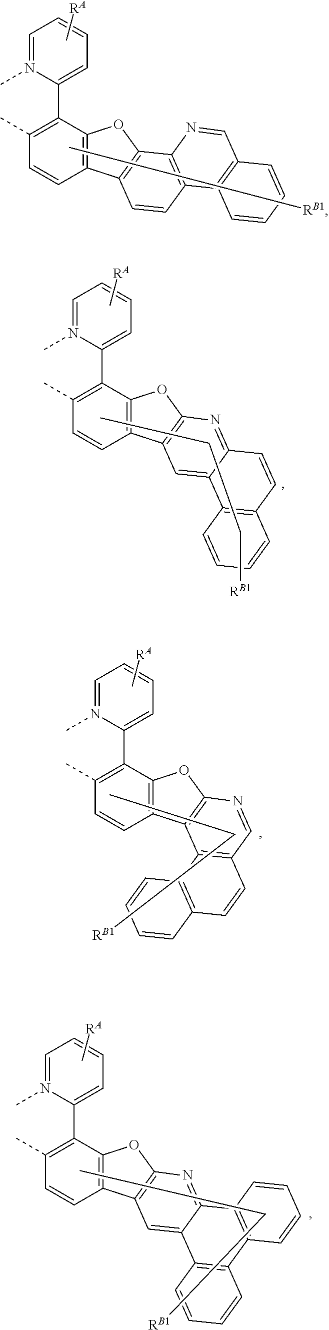

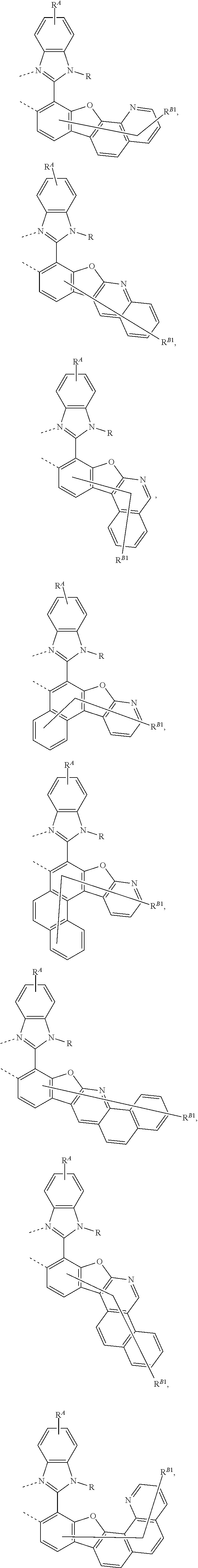

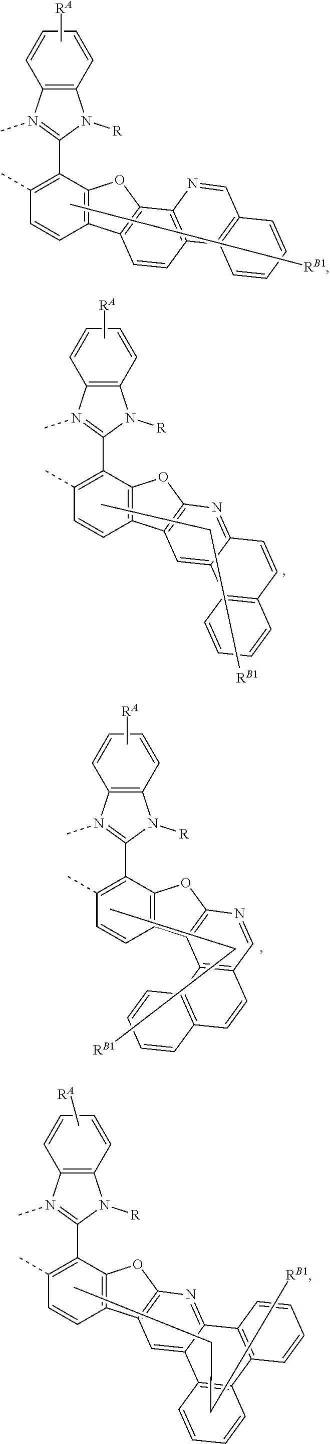

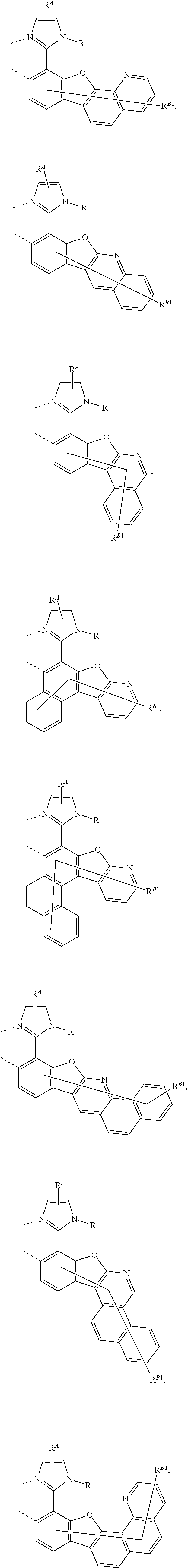

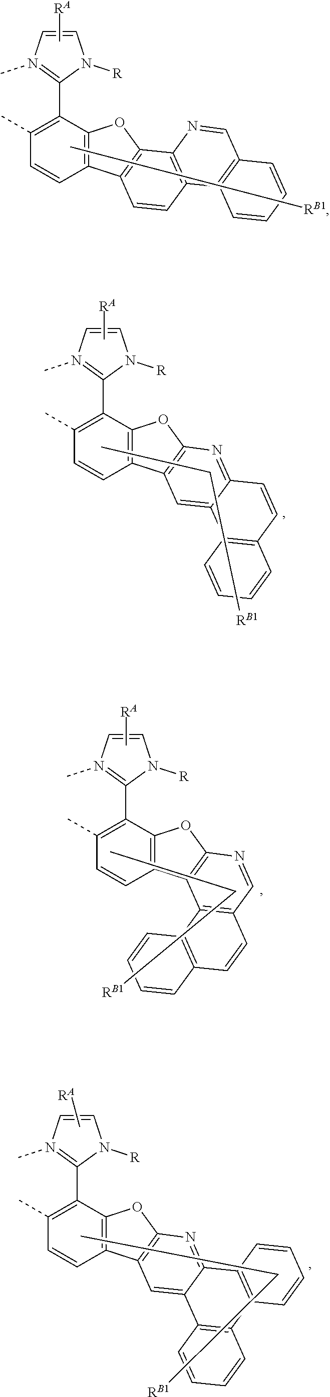

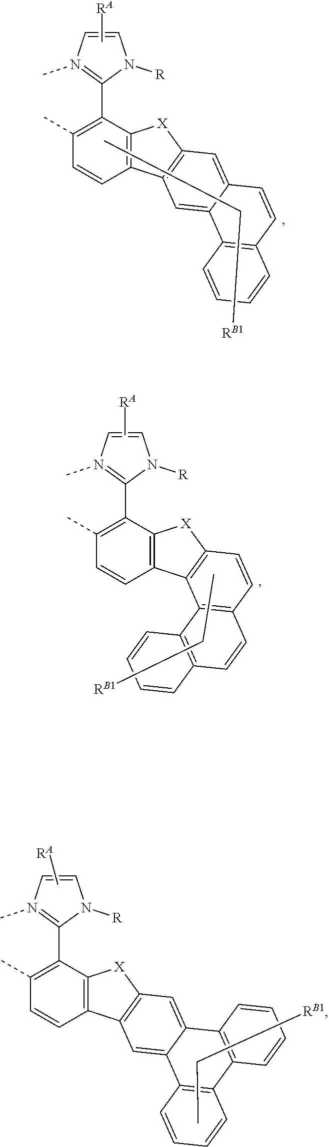

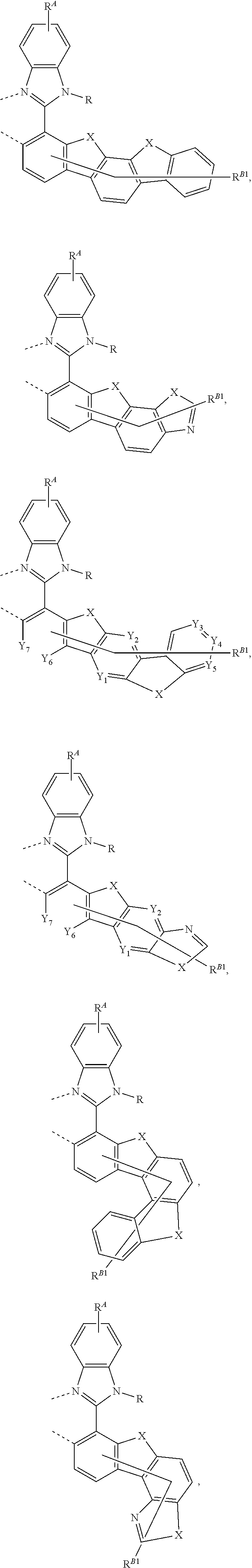

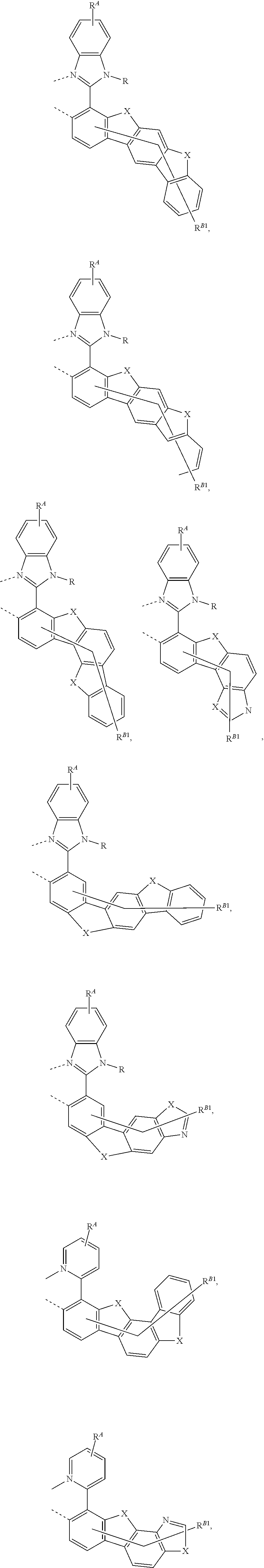

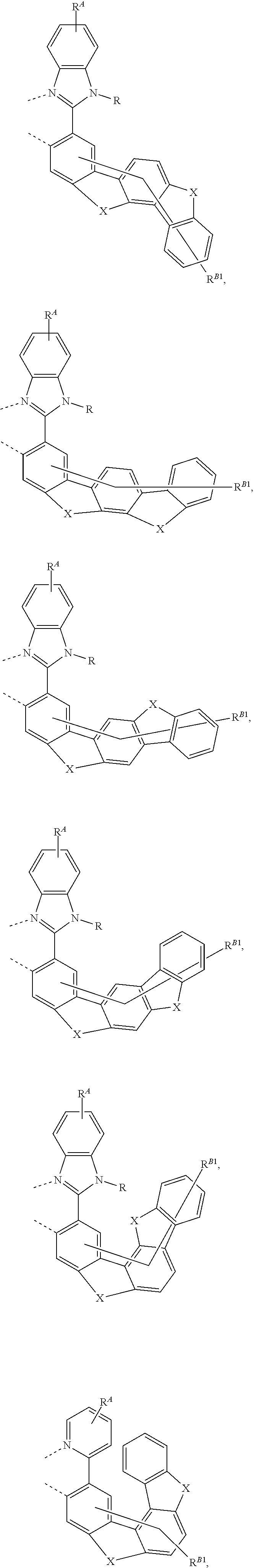

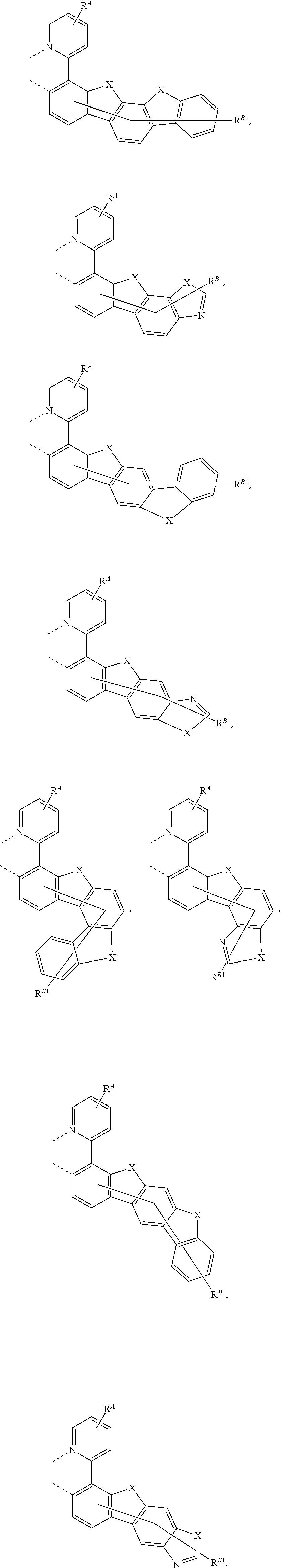

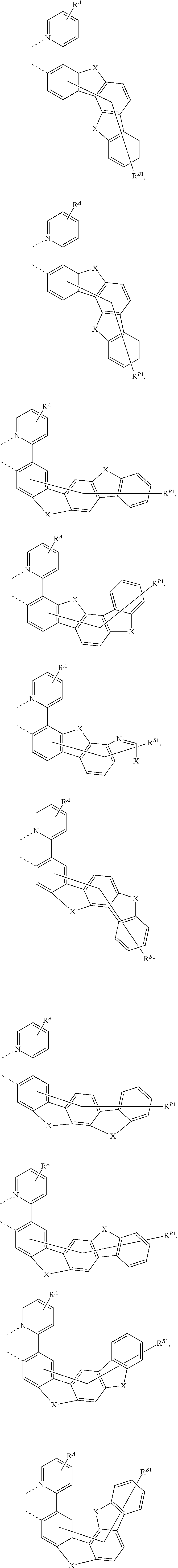

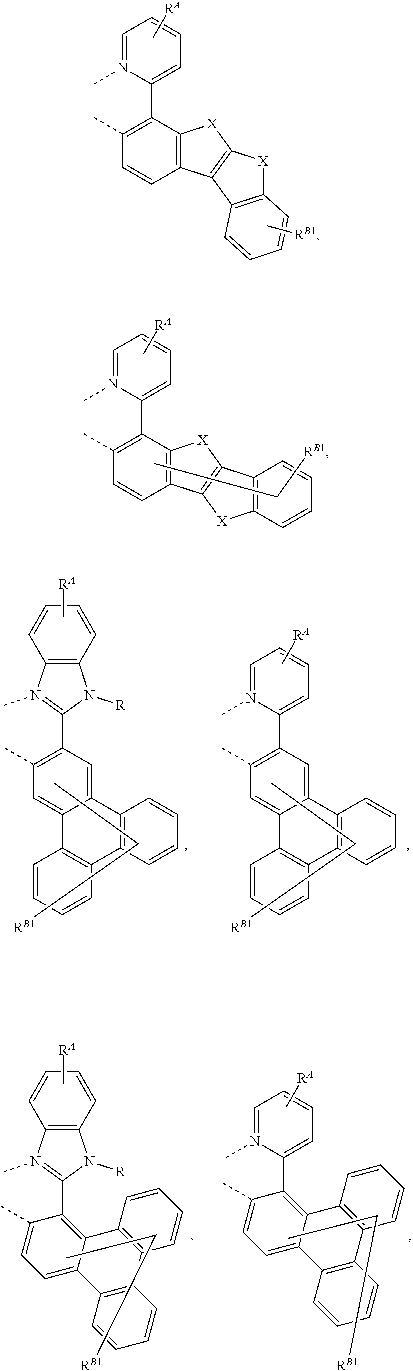

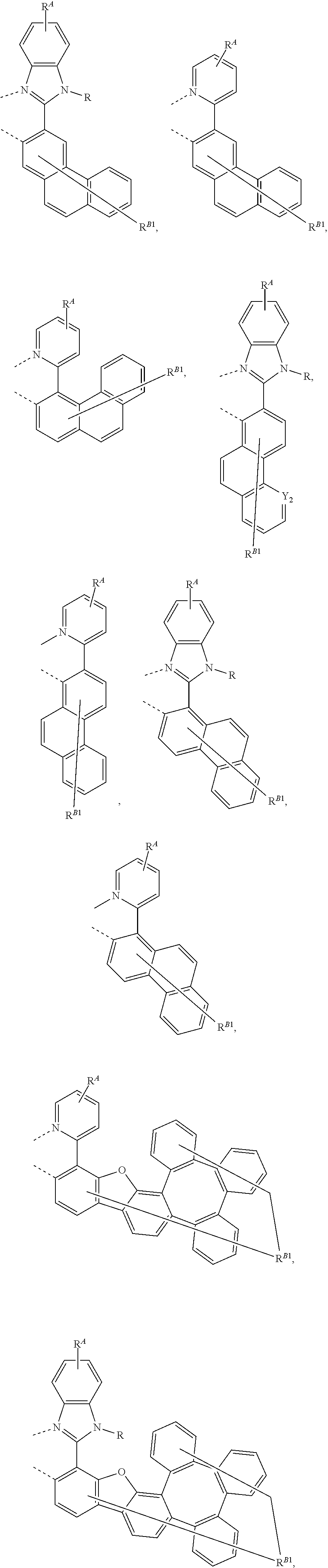

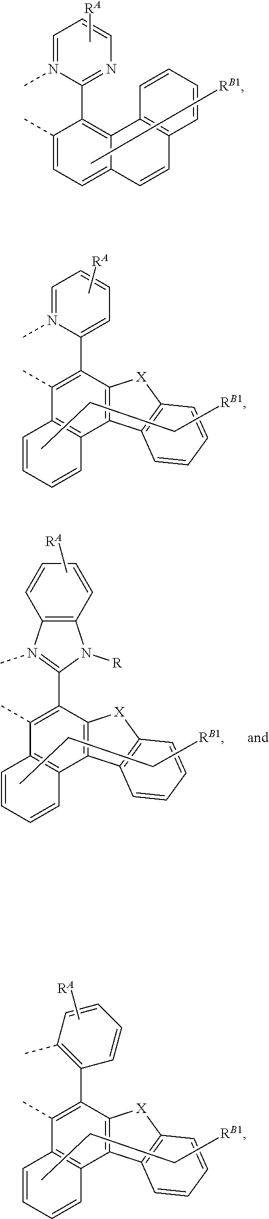

wherein:
R^{B1} represents mono to the maximum possible number of substitutions, or no substitution; each X is independently O, S, CR2, or NR;
each R and R^{B1} is independently hydrogen or a substituent selected from the group consisting of the General Substituents defined herein;
at least one R^{B1} comprises a cyclic group or an electron-withdrawing group; and any two R_{A} and R^{B1} can be joined to form a ring.

In some embodiments, ligand L_{A} is selected from the group consisting of L_{Ai}-(Rⁿ)(R^{m})(E^{o})(W^{t}), wherein i is an integer from 1 to 152, n and m are each independently an integer from 1 to 70, o is an integer from 1 to 125, and t is an integer from 1 to 16; wherein structures of L_{A1}-(R1)(R1)(E1)(W1) to L_{A152}-(R70)(R70)(E125)(W16) are defined in the following LIST 4:

| L_{A} | Structure of L_{A} |
|---|---|
| L_{A1}-(Rn)(Rm)(Eo)(Wt), wherein L_{A1} (R1)(R1)(E1)(W1) to L_{A1}- (R70)(R70)(E125)(W16) have the structure | 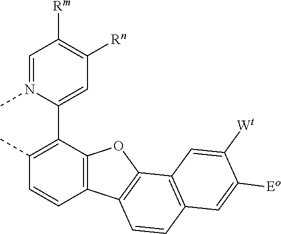 |
| L_{A2}-(Rn)(Rm)(Eo)(Wt), wherein L_{A2} (R1)(R1)(E1)(W1) to L_{A2}- (R70)(R70)(E125)(W16) have the structure | 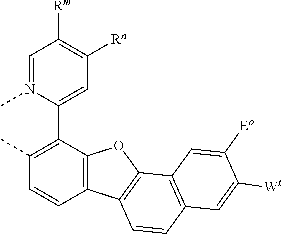 |
| L_{A3}-(Rn)(Rm)(Eo)(Wt), wherein L_{A3} (R1)(R1)(E1)(W1) to LA3- (R70)(R70)(E125)(W16) have the structure | 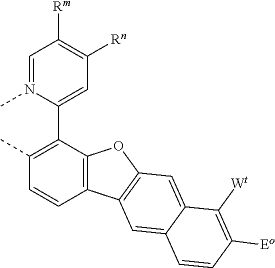 |
| LA4-(Rn)(Rm)(Eo)(Wt), wherein LA4 (R1)(R1)(E1)(W1) to LA4- (R70)(R70)(E125)(W16) have the structure | 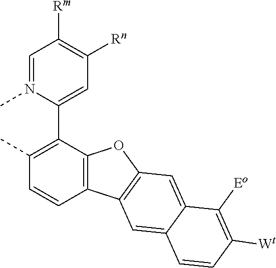 |
| LA5-(Rn)(Rm)(Eo)(Wt), wherein LA5 (R1)(R1)(E1)(W1) to LA5- (R70)(R70)(E125)(W16) have the structure | 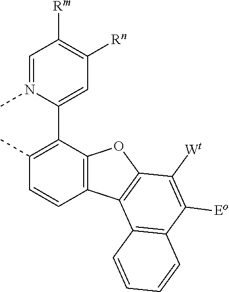 |
| LA6-(Rn)(Rm)(Eo)(Wt), wherein LA6 (R1)(R1)(E1)(W1) to LA6- (R70)(R70)(E125)(W16) have the structure | 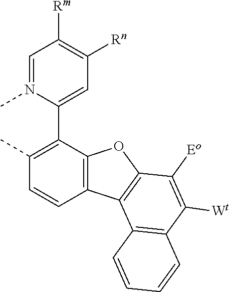 |
| LA7-(Rn)(Rm)(Eo)(Wt), wherein LA7 (R1)(R1)(E1)(W1) to LA7- (R70)(R70)(E125)(W16) have the structure | 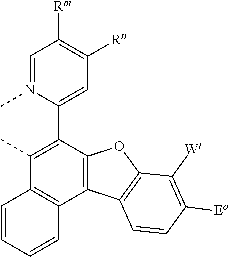 |
| LA8-(Rn)(Rm)(Eo)(Wt), wherein LA8- (R1)(R1)(E1)(W1) to LA8-(R70)(R70)(E125) (W16) have the structure | 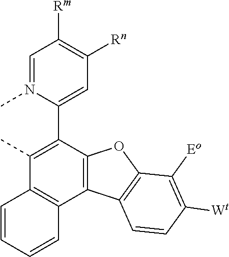 |
| LA9-(Rn)(Rm)(Eo)(Wt), wherein LA9 (R1)(R1)(E1)(W1) to LA9- (R70)(R70)(E125)(W16) have the structure | 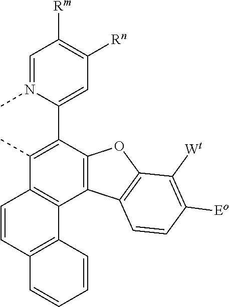 |
| LA10-(Rn)(Rm)(Eo)(Wt), wherein LA10 (R1)(R1)(E1)(W1) to LA10- (R70)(R70)(E125)(W16) have the structure | 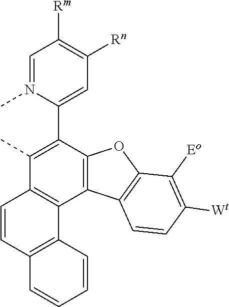 |
| LA11-(Rn)(Rm)(Eo)(Wt), wherein LA11 (R1)(R1)(E1)(W1) to LA11- (R70)(R70)(E125)(W16) have the structure | 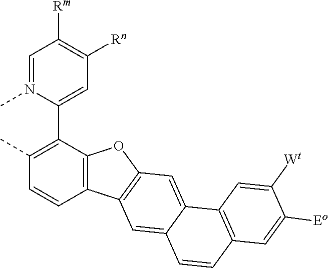 |
| LA12-(Rn)(Rm)(Eo)(Wt), wherein LA12- (R1)(R1)(E1)(W1) to LA12-(R70)(R70)(E125) (W16) have the structure | 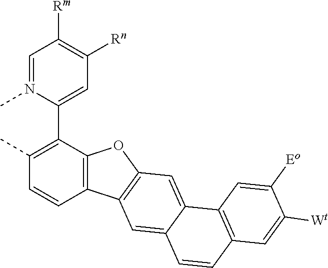 |
| LA13-(Rn)(Rm)(Eo)(Wt), wherein LA13- (R1)(R1)(E1)(W1) to LA13-(R70)(R70)(E125) (W16) have the structure | 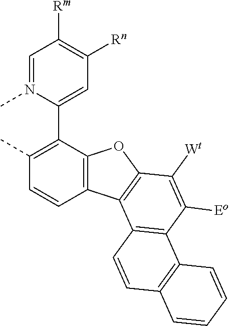 |
| LA14-(Rn)(Rm)(Eo)(Wt), wherein LA14- (R1)(R1)(E1)(W1) to LA14-(R70)(R70)(E125) (W16) have the structure | 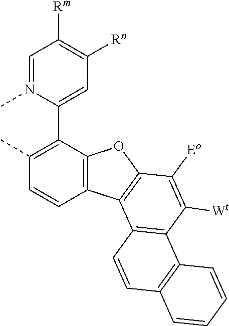 |
| LA15-(Rn)(Rm)(Eo)(Wt), wherein LA15- (R1)(R1)(E1)(W1) to LA15-(R70)(R70)(E125) (W16) have the structure | 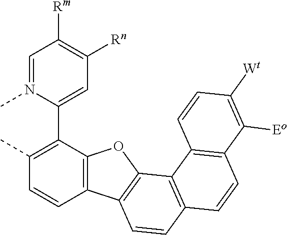 |
| LA16-(Rn)(Rm)(Eo)(Wt), wherein LA16- (R1)(R1)(E1)(W1) to LA16-(R70)(R70)(E125) (W16) have the structure | 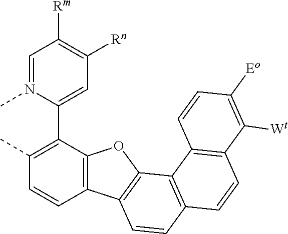 |
| LA17-(Rn)(Rm)(Eo)(Wt), wherein LA17- (R1)(R1)(E1)(W1) to LA17-(R70)(R70)(E125) (W16) have the structure | 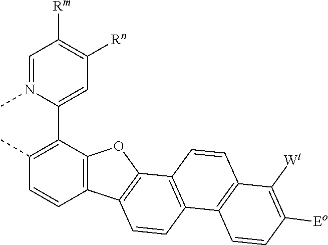 |
| LA18-(Rn)(Rm)(Eo)(Wt), wherein LA18- (R1)(R1)(E1)(W1) to LA18-(R70)(R70)(E125) (W16) have the structure | 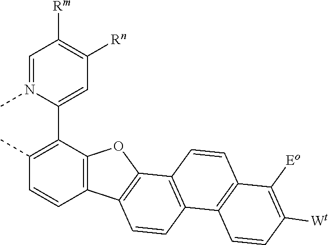 |
| LA19-(Rn)(Rm)(Eo)(Wt), wherein LA19 (R1)(R1)(E1)(W1) to LA19- (R70)(R70)(E125)(W16) have the structure | 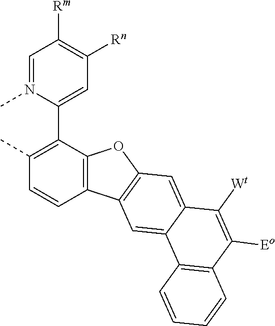 |
| LA20-(Rn)(Rm)(Eo)(Wt), wherein LA20- (R1)(R1)(E1)(W1) to LA20-(R70)(R70)(E125) (W16) have the structure | 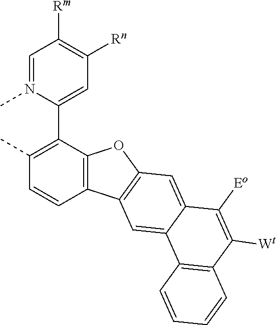 |
| LA21-(Rn)(Rm)(Eo)(Wt), wherein LA21- (R1)(R1)(E1)(W1) to LA21-(R70)(R70)(E125) (W16) have the structure | 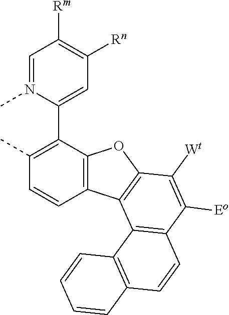 |
| LA22-(Rn)(Rm)(Eo)(Wt), wherein LA22- (R1)(R1)(E1)(W1) to LA22-(R70)(R70)(E125) (W16) have the structure | 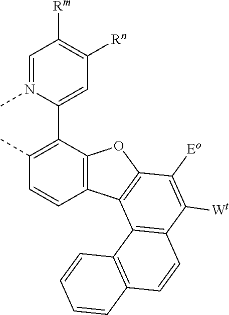 |
| LA23-(Rn)(Rm)(Eo)(Wt), wherein LA23- (R1)(R1)(E1)(W1) to LA23-(R70)(R70)(E125) (W16) have the structure | 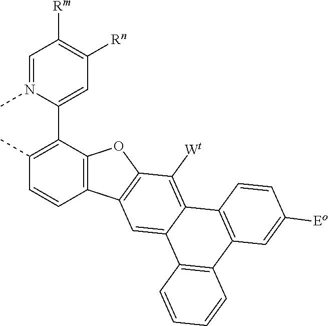 |
| LA24-(Rn)(Rm)(Eo)(Wt), wherein LA24- (R1)(R1)(E1)(W1) to LA24-(R70)(R70)(E125) (W16) have the structure | 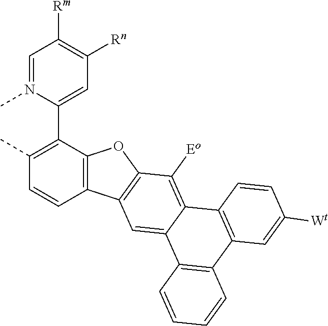 |
| LA25-(Rn)(Rm)(Eo)(Wt), wherein LA25- (R1)(R1)(E1)(W1) to LA25-(R70)(R70)(E125) (W16) have the structure | 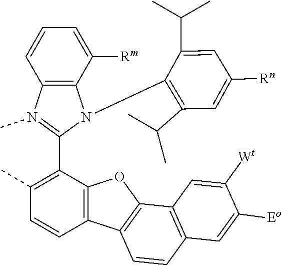 |
| LA26-(Rn)(Rm)(Eo)(Wt), wherein LA26- (R1)(R1)(E1)(W1) to LA26-(R70)(R70)(E125) (W16) have the structure | 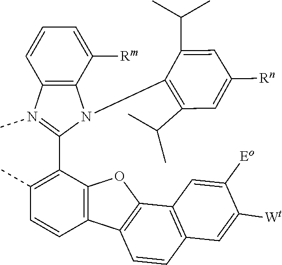 |
| LA27-(Rn)(Rm)(Eo)(Wt), wherein LA27- (R1)(R1)(E1)(W1) to LA27-(R70)(R70)(E125) (W16) have the structure | 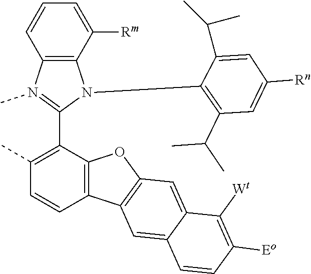 |
| LA28-(Rn)(Rm)(Eo)(Wt), wherein LA28- (R1)(R1)(E1)(W1) to LA28-(R70)(R70)(E125) (W16) have the structure | 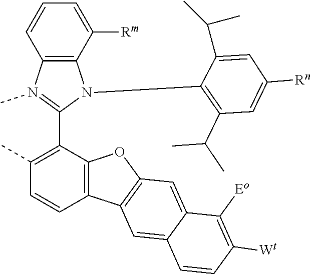 |
| LA29-(Rn)(Rm)(Eo)(Wt), wherein LA29- (R1)(R1)(E1)(W1) to LA29-(R70)(R70)(E125) (W16) have the structure | 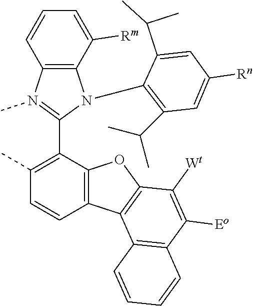 |
| LA30-(Rn)(Rm)(Eo)(Wt), wherein LA30- (R1)(R1)(E1)(W1) to LA30-(R70)(R70)(E125) (W16) have the structure | 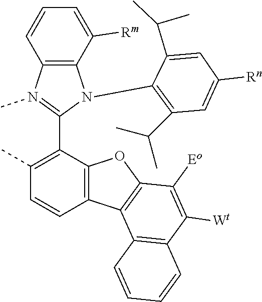 |
| LA31-(Rn)(Rm)(Eo)(Wt), wherein LA31- (R1)(R1)(E1)(W1) to LA31-(R70)(R70)(E125) (W16) have the structure | 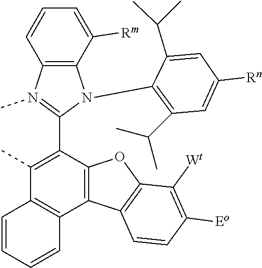 |
| LA32-(Rn)(Rm)(Eo)(Wt), wherein LA32- (R1)(R1)(E1)(W1) to LA32-(R70)(R70)(E125) (W16) have the structure | 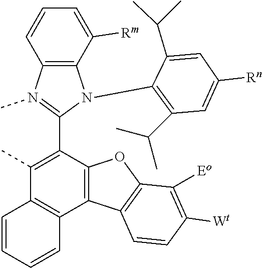 |
| LA33-(Rn)(Rm)(Eo)(Wt), wherein LA33- (R1)(R1)(E1)(W1) to LA33-(R70)(R70)(E125) (W16) have the structure | 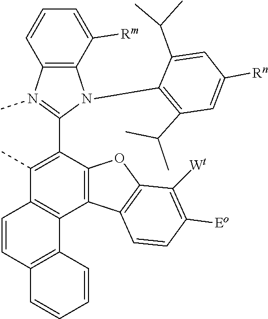 |
| LA34-(Rn)(Rm)(Eo)(Wt), wherein LA34- (R1)(R1)(E1)(W1) to LA34-(R70)(R70)(E125) (W16) have the structure | 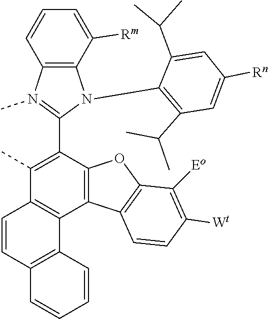 |
| LA35-(Rn)(Rm)(Eo)(Wt), wherein LA35- (R1)(R1)(E1)(W1) to LA35-(R70)(R70)(E125) (W16) have the structure | 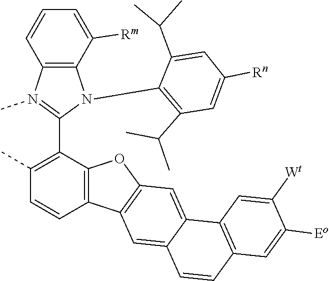 |
| LA36-(Rn)(Rm)(Eo)(Wt), wherein LA36- (R1)(R1)(E1)(W1) to LA36-(R70)(R70)(E125) (W16) have the structure | 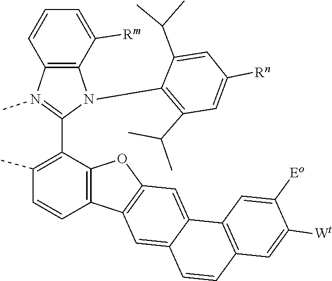 |
| LA37-(Rn)(Rm)(Eo)(Wt), wherein LA37- (R1)(R1)(E1)(W1) to LA37-(R70)(R70)(E125) (W16) have the structure | 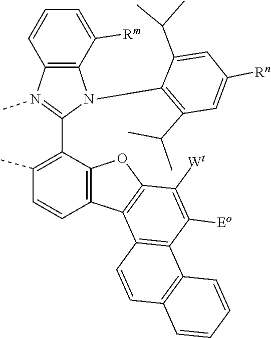 |
| LA38-(Rn)(Rm)(Eo)(Wt), wherein LA38- (R1)(R1)(E1)(W1) to LA38-(R70)(R70)(E125) (W16) have the structure | 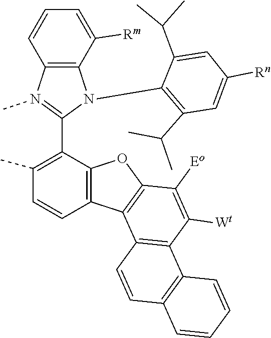 |
| LA39-(Rn)(Rm)(Eo)(Wt), wherein LA39- (R1)(R1)(E1)(W1) to LA39-(R70)(R70)(E125) (W16) have the structure | 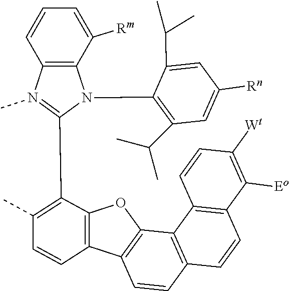 |
| LA40-(Rn)(Rm)(Eo)(Wt), wherein LA40- (R1)(R1)(E1)(W1) to LA40-(R70)(R70)(E125) (W16) have the structure | 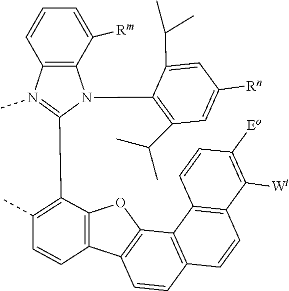 |
| LA41-(Rn)(Rm)(Eo)(Wt), wherein LA41- (R1)(R1)(E1)(W1) to LA41-(R70)(R70)(E125) (W16) have the structure | 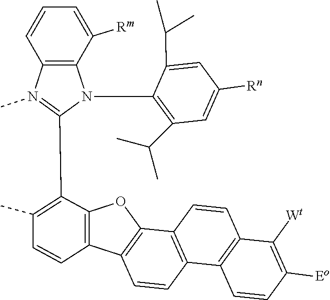 |
| LA42-(Rn)(Rm)(Eo)(Wt), wherein LA42- (R1)(R1)(E1)(W1) to LA42-(R70)(R70)(E125) (W16) have the structure | 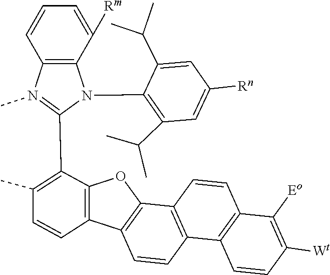 |
| LA43-(Rn)(Rm)(Eo)(Wt), wherein LA43- (R1)(R1)(E1)(W1) to LA43-(R70)(R70)(E125) (W16) have the structure | 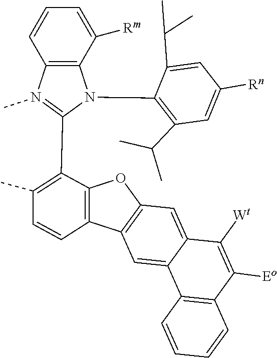 |
| LA44-(Rn)(Rm)(Eo)(Wt), wherein LA44- (R1)(R1)(E1)(W1) to LA44-(R70)(R70)(E125) (W16) have the structure | 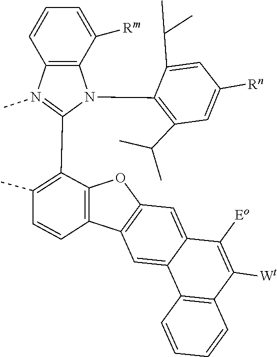 |
| LA45-(Rn)(Rm)(Eo)(Wt), wherein LA45- (R1)(R1)(E1)(W1) to LA45-(R70)(R70)(E125) (W16) have the structure | 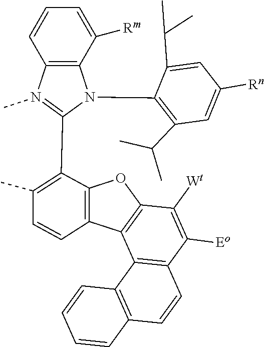 |
| LA46-(Rn)(Rm)(Eo)(Wt), wherein LA46- (R1)(R1)(E1)(W1) to LA46-(R70)(R70)(E125) (W16) have the structure | 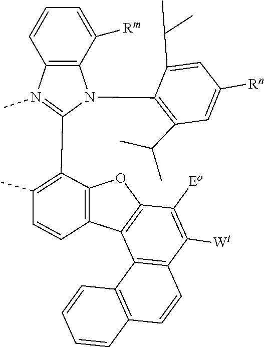 |
| LA47-(Rn)(Rm)(Eo)(Wt), wherein LA47- (R1)(R1)(E1)(W1) to LA47-(R70)(R70)(E125) (W16) have the structure | 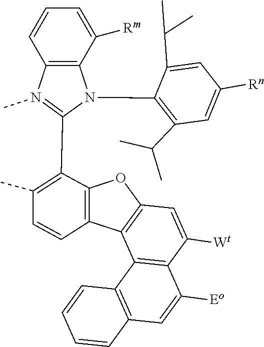 |
| LA48-(Rn)(Rm)(Eo)(Wt), wherein LA48- (R1)(R1)(E1)(W1) to LA48-(R70)(R70)(E125) (W16) have the structure | 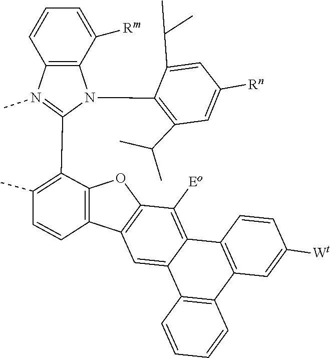 |
| LA49-(Rn)(Rm)(Eo)(Wt), wherein LA49- (R1)(R1)(E1)(W1) to LA49-(R70)(R70)(E125) (W16) have the structure | 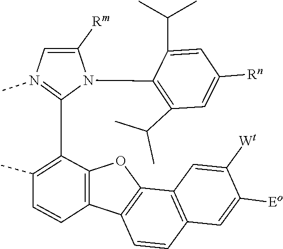 |
| LA50-(Rn)(Rm)(Eo)(Wt), wherein LA50- (R1)(R1)(E1)(W1) to LA50-(R70)(R70)(E125) (W16) have the structure | 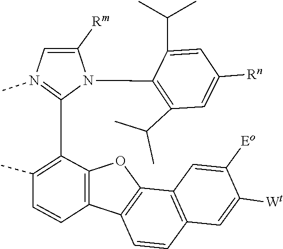 |
| LA51-(Rn)(Rm)(Eo)(Wt), wherein LA51- (R1)(R1)(E1)(W1) to LA51-(R70)(R70)(E125) (W16) have the structure | 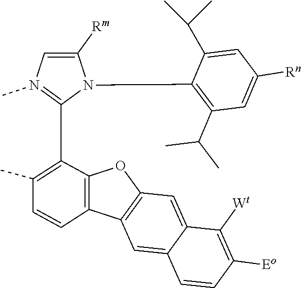 |
| LA52-(Rn)(Rm)(Eo)(Wt), wherein LA52- (R1)(R1)(E1)(W1) to LA52-(R70)(R70)(E125) (W16) have the structure | 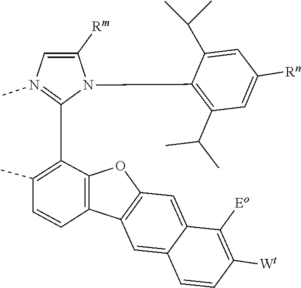 |
| LA53-(Rn)(Rm)(Eo)(Wt), wherein LA53- (R1)(R1)(E1)(W1) to LA53-(R70)(R70)(E125) (W16) have the structure | 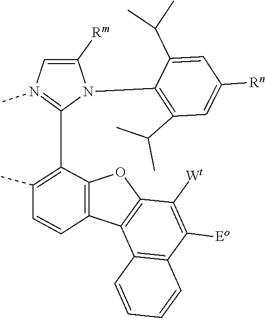 |
| LA54-(Rn)(Rm)(Eo)(Wt), wherein LA54- (R1)(R1)(E1)(W1) to LA54-(R70)(R70)(E125) (W16) have the structure | 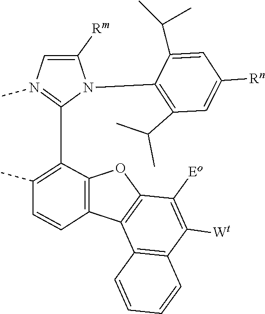 |
| LA55-(Rn)(Rm)(Eo)(Wt), wherein LA55- (R1)(R1)(E1)(W1) to LA55-(R70)(R70)(E125) (W16) have the structure | 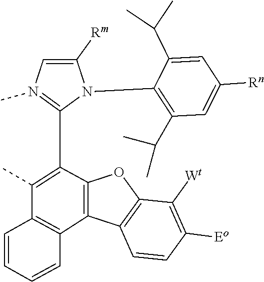 |
| LA56-(Rn)(Rm)(Eo)(Wt), wherein LA56- (R1)(R1)(E1)(W1) to LA56-(R70)(R70)(E125) (W16) have the structure | 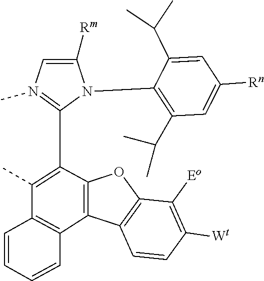 |
| LA57-(Rn)(Rm)(Eo)(Wt), wherein LA57- (R1)(R1)(E1)(W1) to LA57-(R70)(R70) (E125)(W16) have the structure | 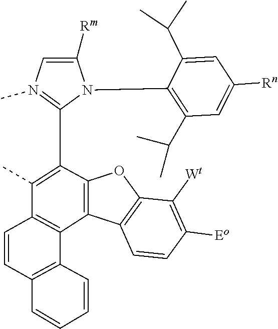 |
| LA58-(Rn)(Rm)(Eo)(Wt), wherein LA58- (R1)(R1)(E1)(W1) to LA58-(R70)(R70) (E125)(W16) have the structure | 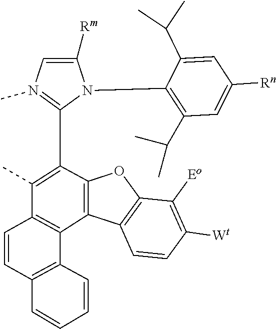 |
| LA59-(Rn)(Rm)(Eo)(Wt), wherein LA59- (R1)(R1)(E1)(W1) to LA59-(R70)(R70) (E125)(W16) have the structure | 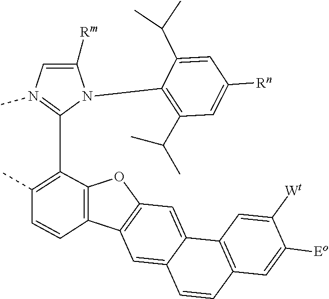 |
| LA60-(Rn)(Rm)(Eo)(Wt), wherein LA60- (R1)(R1)(E1)(W1) to LA60-(R70)(R70) (E125)(W16) have the structure | 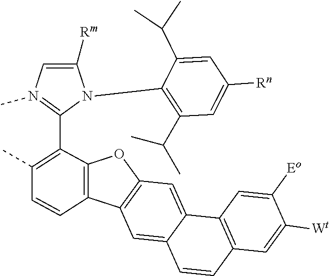 |
| LA61-(Rn)(Rm)(Eo)(Wt), wherein LA61- (R1)(R1)(E1)(W1) to LA61-(R70)(R70) (E125)(W16) have the structure | 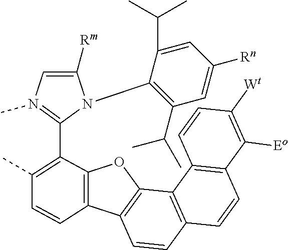 |
| LA62-(Rn)(Rm)(Eo)(Wt), wherein LA62- (R1)(R1)(E1)(W1) to LA62-(R70)(R70) (E125)(W16) have the structure | 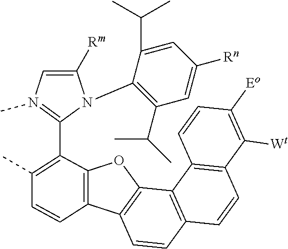 |
| LA63-(Rn)(Rm)(Eo)(Wt), wherein LA63- (R1)(R1)(E1)(W1) to LA63-(R70)(R70) (E125)(W16) have the structure | 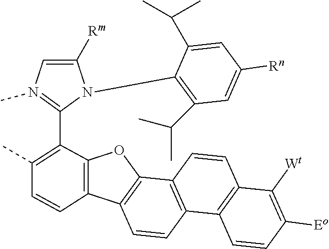 |
| LA64-(Rn)(Rm)(Eo)(Wt), wherein LA64- (R1)(R1)(E1)(W1) to LA64-(R70)(R70) (E125)(W16) have the structure | 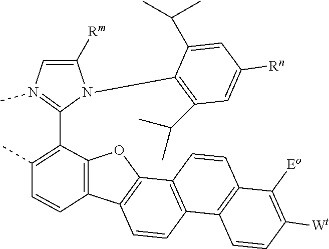 |
| LA65-(Rn)(Rm)(Eo)(Wt), wherein LA65- (R1)(R1)(E1)(W1) to LA65-(R70)(R70) (E125)(W16) have the structure | 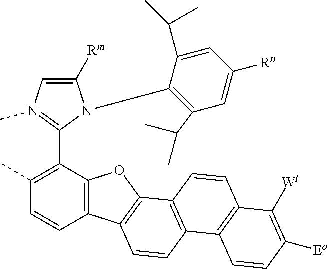 |
| LA66-(Rn)(Rm)(Eo)(Wt), wherein LA66- (R1)(R1)(E1)(W1) to LA66-(R70)(R70) (E125)(W16) have the structure | 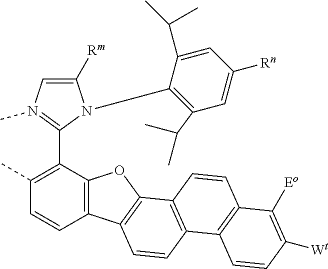 |
| LA67-(Rn)(Rm)(Eo)(Wt), wherein LA67- (R1)(R1)(E1)(W1) to LA67-(R70)(R70) (E125)(W16) have the structure | 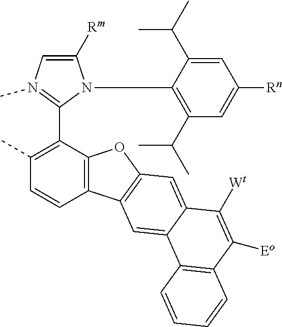 |
| LA68-(Rn)(Rm)(Eo)(Wt), wherein LA68- (R1)(R1)(E1)(W1) to LA68-(R70)(R70) (E125)(W16) have the structure | 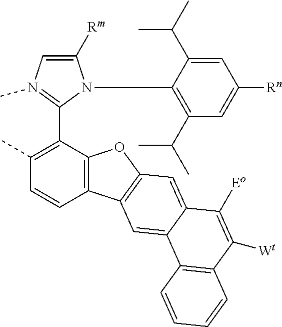 |
| LA69-(Rn)(Rm)(Eo)(Wt), wherein LA69- (R1)(R1)(E1)(W1) to LA69-(R70)(R70) (E125)(W16) have the structure | 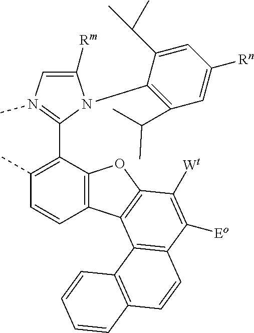 |
| LA70-(Rn)(Rm)(Eo)(Wt), wherein LA70- (R1)(R1)(E1)(W1) to LA70-(R70)(R70) (E125)(W16) have the structure | 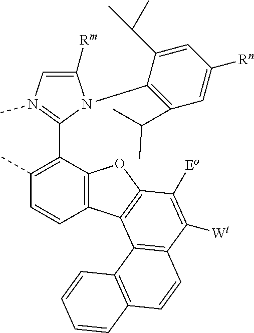 |
| LA71-(Rn)(Rm)(Eo)(Wt), wherein LA71- (R1)(R1)(E1)(W1) to LA71-(R70)(R70) (E125)(W16) have the structure | 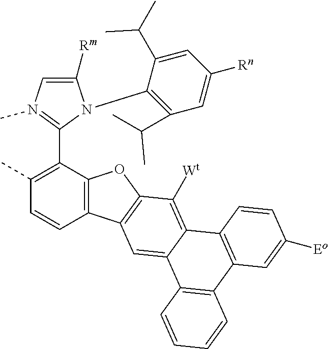 |
| LA72-(Rn)(Rm)(Eo)(Wt), wherein LA72- (R1)(R1)(E1)(W1) to LA72-(R70)(R70) (E125)(W16) have the structure | 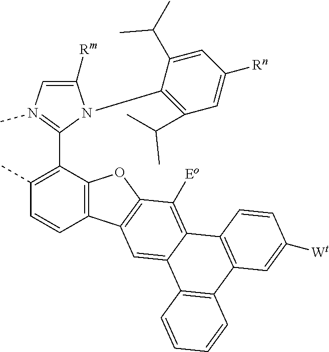 |
| LA73-(Rn)(Rm)(Eo)(Wt), wherein LA73- (R1)(R1)(E1)(W1) to LA73-(R70)(R70) (E125)(W16) have the structure | 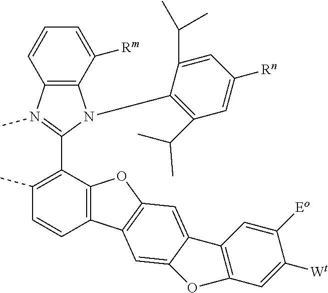 |
| LA75-(Rn)(Rm)(Eo)(Wt), wherein LA75- (R1)(R1)(E1)(W1) to LA75-(R70)(R70) (E125)(W16) have the structure | 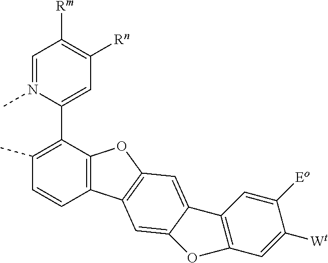 |
| LA76-(Rn)(Rm)(Eo)(Wt), wherein LA76- (R1)(R1)(E1)(W1) to LA76-(R70)(R70) (E125)(W16) have the structure | 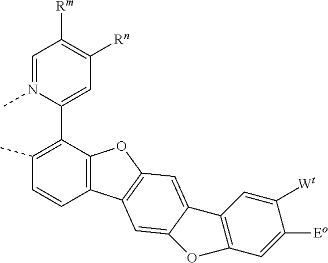 |
| LA77-(Rn)(Rm)(Eo)(Wt), wherein LA77- (R1)(R1)(E1)(W1) to LA77-(R70)(R70) (E125)(W16) have the structure | 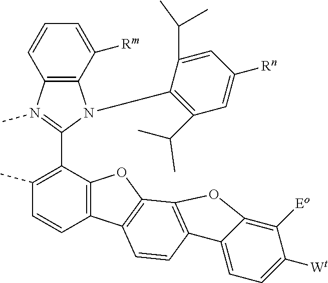 |
| LA78-(Rn)(Rm)(Eo)(Wt), wherein LA78- (R1)(R1)(E1)(W1) to LA78-(R70)(R70) (E125)(W16) have the structure | 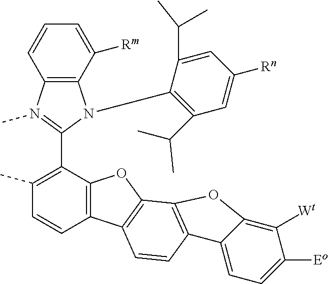 |
| LA79-(Rn)(Rm)(Eo)(Wt), wherein LA79- (R1)(R1)(E1)(W1) to LA79-(R70)(R70) (E125)(W16) have the structure | 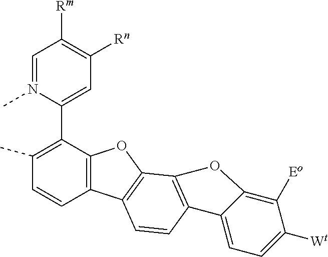 |
| LA80-(Rn)(Rm)(Eo)(Wt), wherein LA80- (R1)(R1)(E1)(W1) to LA80-(R70)(R70) (E125)(W16) have the structure | 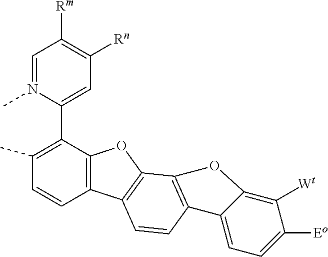 |
| LA81-(Rn)(Rm)(Eo)(Wt), wherein LA81- (R1)(R1)(E1)(W1) to LA81-(R70)(R70) (E125)(W16) have the structure | 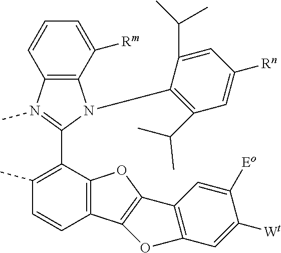 |
| LA82-(Rn)(Rm)(Eo)(Wt), wherein LA82- (R1)(R1)(E1)(W1) to LA82-(R70)(R70) (E125)(W16) have the structure | 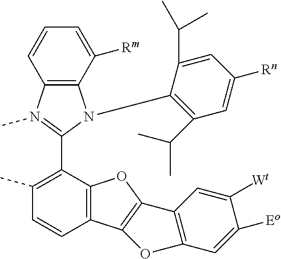 |
| LA83-(Rn)(Rm)(Eo)(Wt), wherein LA83- (R1)(R1)(E1)(W1) to LA83-(R70)(R70) (E125)(W16) have the structure | 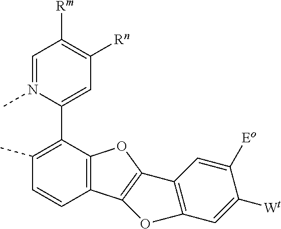 |
| LA84-(Rn)(Rm)(Eo)(Wt), wherein LA84- (R1)(R1)(E1)(W1) to LA84-(R70)(R70) (E125)(W16) have the structure | 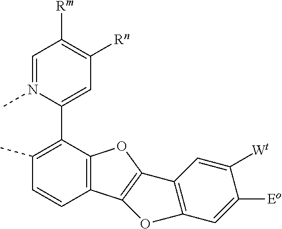 |
| LA85-(Rn)(Rm)(Eo)(Wt), wherein LA85- (R1)(R1)(E1)(W1) to LA85-(R70)(R70) (E125)(W16) have the structure | 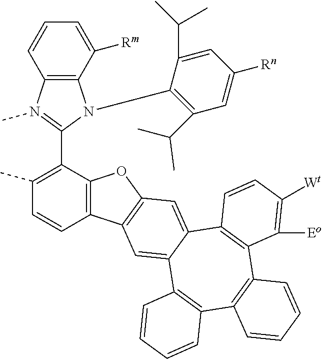 |
| LA86-(Rn)(Rm)(Eo)(Wt), wherein LA86- (R1)(R1)(E1)(W1) to LA86-(R70)(R70) (E125)(W16) have the structure | 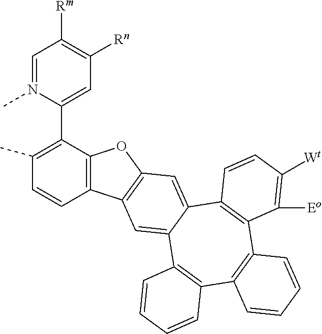 |
| LA87-(Rn)(Rm)(Eo)(Wt), wherein LA87- (R1)(R1)(E1)(W1) to LA87-(R70)(R70) (E125)(W16) have the structure | 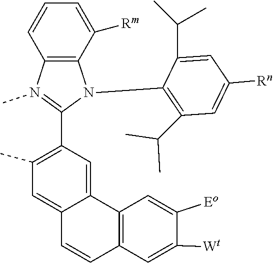 |
| LA88-(Rn)(Rm)(Eo)(Wt), wherein LA88- (R1)(R1)(E1)(W1) to LA88-(R70)(R70) (E125)(W16) have the structure | 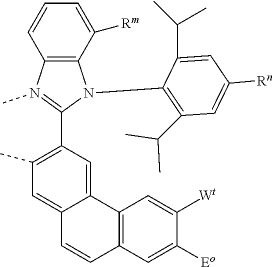 |
| LA89-(Rn)(Rm)(Eo)(Wt), wherein LA89- (R1)(R1)(E1)(W1) to LA89-(R70)(R70) (E125)(W16) have the structure | 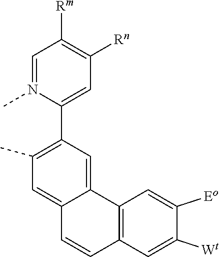 |
| LA90-(Rn)(Rm)(Eo)(Wt), wherein LA90- (R1)(R1)(E1)(W1) to LA90-(R70)(R70) (E125)(W16) have the structure | 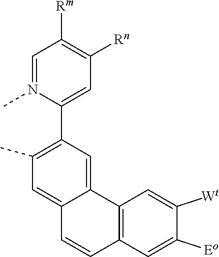 |
| LA91-(Rn)(Rm)(Eo)(Wt), wherein LA91- (R1)(R1)(E1)(W1) to LA91-(R70)(R70) (E125)(W16) have the structure | 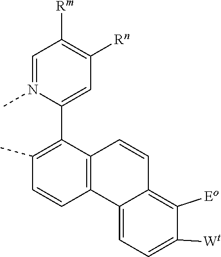 |
| LA92-(Rn)(Rm)(Eo)(Wt), wherein LA92- (R1)(R1)(E1)(W1) to LA92-(R70)(R70) (E125)(W16) have the structure | 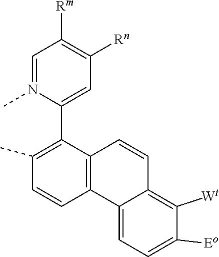 |
| LA93-(Rn)(Rm)(Eo)(Wt), wherein LA93- (R1)(R1)(E1)(W1) to LA93-(R70)(R70) (E125)(W16) have the structure | 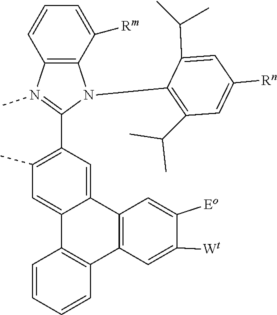 |
| LA94-(Rn)(Rm)(Eo)(Wt), wherein LA94- (R1)(R1)(E1)(W1) to LA94-(R70)(R70) (E125)(W16) have the structure | 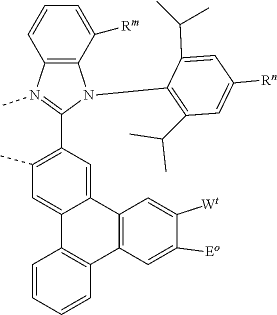 |
| LA95-(Rn)(Rm)(Eo)(Wt), wherein LA95- (R1)(R1)(E1)(W1) to LA95-(R70)(R70) (E125)(W16) have the structure | 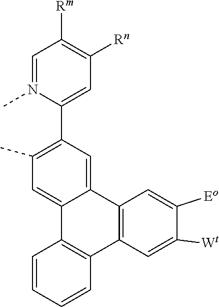 |
| LA96-(Rn)(Rm)(Eo)(Wt), wherein LA96- (R1)(R1)(E1)(W1) to LA96-(R70)(R70) (E125)(W16) have the structure | 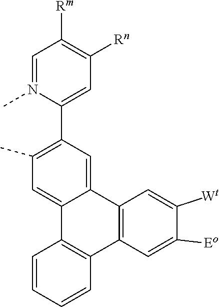 |
| LA97-(Rn)(Rm)(Eo)(Wt), wherein LA97- (R1)(R1)(E1)(W1) to LA97-(R70)(R70) (E125)(W16) have the structure | 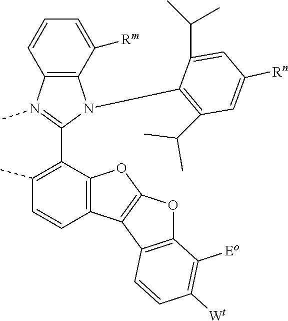 |
| LA98-(Rn)(Rm)(Eo)(Wt), wherein LA98- (R1)(R1)(E1)(W1) to LA98-(R70)(R70) (E125)(W16) have the structure | 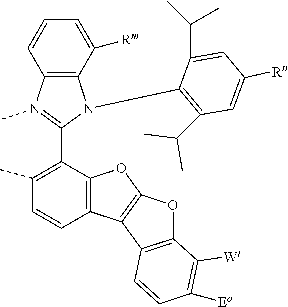 |
| LA99-(Rn)(Rm)(Eo)(Wt), wherein LA99- (R1)(R1)(E1)(W1) to LA99-(R70)(R70) (E125)(W16) have the structure | 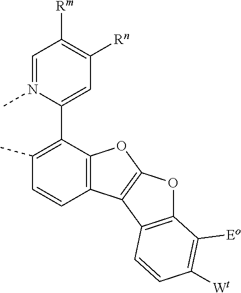 |
| LA100- (Rn)(Rm)(Eo)(Wt), wherein LA100- (R1)(R1)(E1)(W1) to LA100-(R70)(R70) (E125)(W16) have the structure | 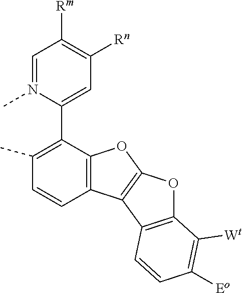 |
| LA101- (Rn)(Rm)(Eo)(Wt), wherein LA101- (R1)(R1)(E1)(W1) to LA101-(R70)(R70) (E125)(W16) have the structure | 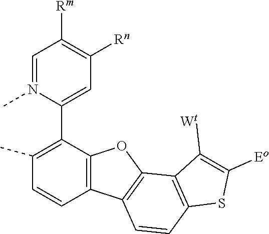 |
| LA102- (Rn)(Rm)(Eo)(Wt), wherein LA102- (R1)(R1)(E1)(W1) to LA102-(R70)(R70) (E125)(W16) have the structure | 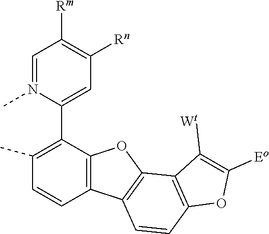 |
| LA103- (Rn)(Rm)(Eo)(Wt), wherein LA103- (R1)(R1)(E1)(W1) to LA103-(R70)(R70) (E125)(W16) have the structure | 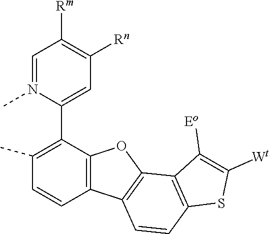 |
| LA104- (Rn)(Rm)(Eo)(Wt), wherein LA104- (R1)(R1)(E1)(W1) to LA104-(R70)(R70) (E125)(W16) have the structure | 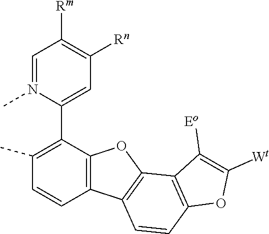 |
| LA105- (Rn)(Rm)(Eo)(Wt), wherein LA105- (R1)(R1)(E1)(W1) to LA105-(R70)(R70) (E125)(W16) have the structure | 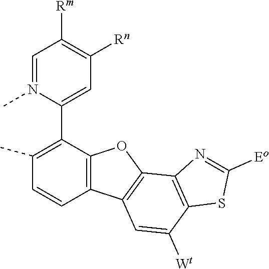 |
| LA106- (Rn)(Rm)(Eo)(Wt), wherein LA106- (R1)(R1)(E1)(W1) to LA106-(R70)(R70) (E125)(W16) have the structure | 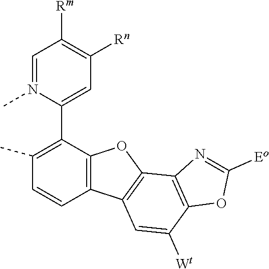 |
| LA107- (Rn)(Rm)(Eo)(Wt), wherein LA107- (R1)(R1)(E1)(W1) to LA107-(R70)(R70) (E125)(W16) have the structure | 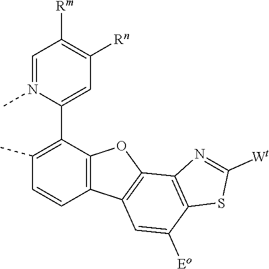 |
| LA108- (Rn)(Rm)(Eo)(Wt), wherein LA108- (R1)(R1)(E1)(W1) to LA108-(R70)(R70) (E125)(W16) have the structure | 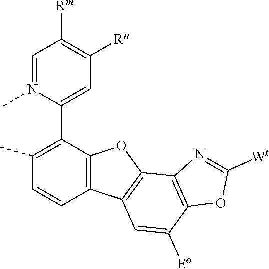 |
| LA109- (Rn)(Rm)(Eo)(Wt), wherein LA109- (R1)(R1)(E1)(W1) to LA109-(R70)(R70) (E125)(W16) have the structure | 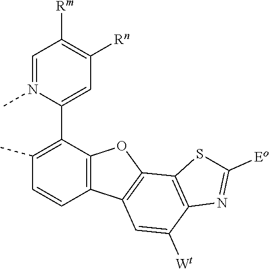 |
| LA110- (Rn)(Rm)(Eo)(Wt), wherein LA110- (R1)(R1)(E1)(W1) to LA110-(R70)(R70) (E125)(W16) have the structure | 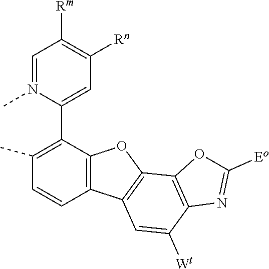 |
| LA111- (Rn)(Rm)(Eo)(Wt), wherein LA111- (R1)(R1)(E1)(W1) to LA111-(R70)(R70) (E125)(W16) have the structure | 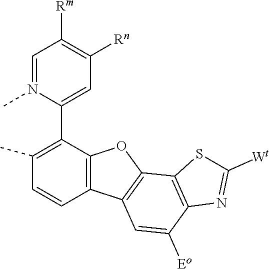 |
| LA112- (Rn)(Rm)(Eo)(Wt), wherein LA112- (R1)(R1)(E1)(W1) to LA112-(R70)(R70) (E125)(W16) have the structure | 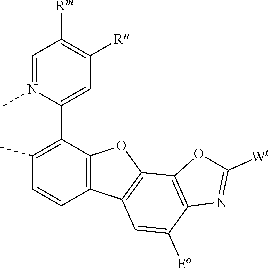 |
| LA113- (Rn)(Rm)(Eo)(Wt), wherein LA113- (R1)(R1)(E1)(W1) to LA113-(R70)(R70) (E125)(W16) have the structure | 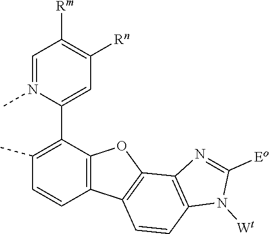 |
| LA114- (Rn)(Rm)(Eo)(Wt), wherein LA114- (R1)(R1)(E1)(W1) to LA114-(R70)(R70) (E125)(W16) have the structure | 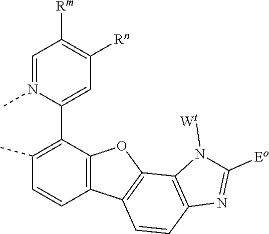 |
| LA115- (Rn)(Rm)(Eo)(Wt), wherein LA115- (R1)(R1)(E1)(W1) to LA115-(R70)(R70) (E125)(W16) have the structure | 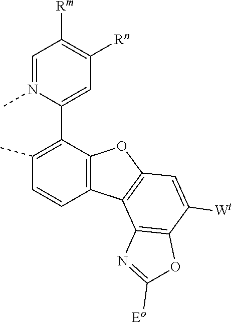 |
| LA116- (Rn)(Rm)(Eo)(Wt), wherein LA116- (R1)(R1)(E1)(W1) to LA116-(R70)(R70) (E125)(W16) have the structure | 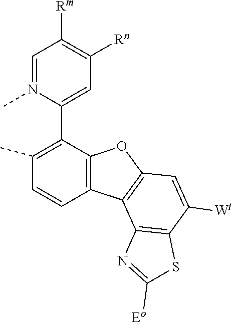 |
| LA117- (Rn)(Rm)(Eo)(Wt), wherein LA117- (R1)(R1)(E1)(W1) to LA117-(R70)(R70) (E125)(W16) have the structure | 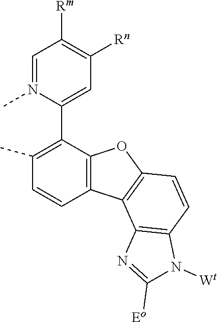 |
| LA118- (Rn)(Rm)(Eo)(Wt), wherein LA118- (R1)(R1)(E1)(W1) to LA118-(R70)(R70) (E125)(W16) have the structure | 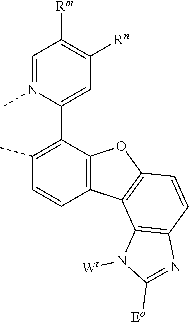 |
| LA119- (Rn)(Rm)(Eo)(Wt), wherein LA119- (R1)(R1)(E1)(W1) to LA119-(R70)(R70) (E125)(W16) have the structure | 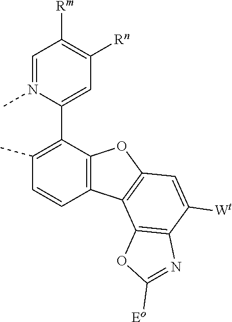 |
| LA120- (Rn)(Rm)(Eo)(Wt), wherein LA120- (R1)(R1)(E1)(W1) to LA120-(R70)(R70) (E125)(W16) have the structure | 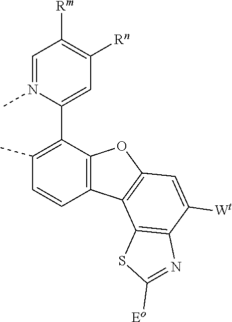 |
| LA121- (Rn)(Rm)(Eo)(Wt), wherein LA121- (R1)(R1)(E1)(W1) to LA121-(R70)(R70) (E125)(W16) have the structure | 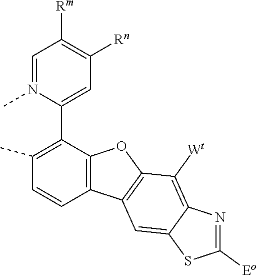 |
| LA122- (Rn)(Rm)(Eo)(Wt), wherein LA122- (R1)(R1)(E1)(W1) to LA122-(R70)(R70) (E125)(W16) have the structure | 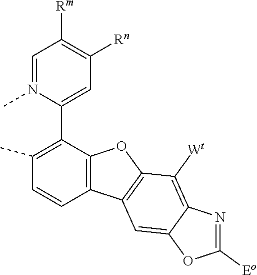 |
| LA123- (Rn)(Rm)(Eo)(Wt), wherein LA123- (R1)(R1)(E1)(W1) to LA123-(R70)(R70) (E125)(W16) have the structure | 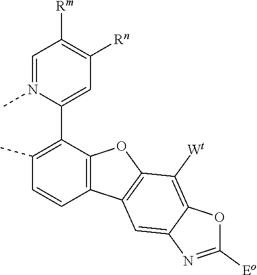 |
| LA124- (Rn)(Rm)(Eo)(Wt), wherein LA124- (R1)(R1)(E1)(W1) to LA124-(R70)(R70) (E125)(W16) have the structure | 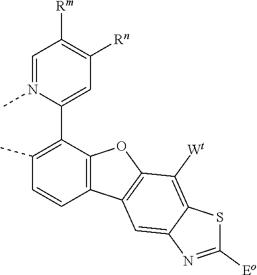 |
| L_{A125}- (Rn)(Rm)(Eo)(Wt), wherein L_{A125}- (R1)(R1)(E1)(W1) to L_{A125}-(R70)(R70) (E125)(W16) have the structure | 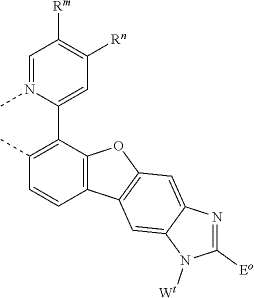 |
| L_{A126}- (Rn)(Rm)(Eo)(Wt), wherein L_{A126}- (R1)(R1)(E1)(W1) to L_{A126}-(R70)(R70) (E125)(W16) have the structure | 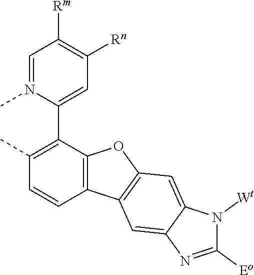 |
| LA127- (Rn)(Rm)(Eo)(Wt), wherein LA127- (R1)(R1)(E1)(W1) to LA127-(R70)(R70) (E125)(W16) have the structure | 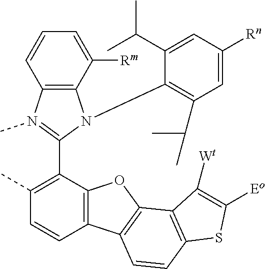 |
| LA128- (Rn)(Rm)(Eo)(Wt), wherein LA128- (R1)(R1)(E1)(W1) to LA128-(R70)(R70) (E125)(W16) have the structure | 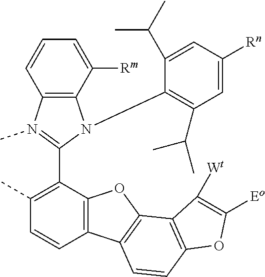 |
| LA129- (Rn)(Rm)(Eo)(Wt), wherein LA129- (R1)(R1)(E1)(W1) to LA129-(R70)(R70) (E125)(W16) have the structure | 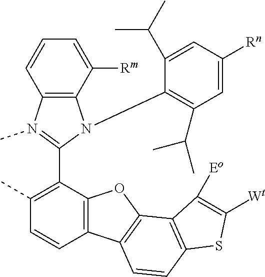 |
| LA130- (Rn)(Rm)(Eo)(Wt), wherein LA130- (R1)(R1)(E1)(W1) to LA130-(R70)(R70) (E125)(W16) have the structure | 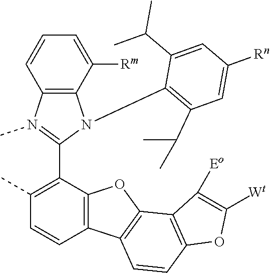 |
| LA131- (Rn)(Rm)(Eo)(Wt), wherein LA131- (R1)(R1)(E1)(W1) to LA131-(R70)(R70) (E125)(W16) have the structure | 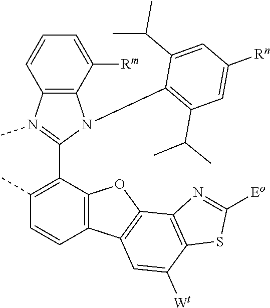 |
| LA132- (Rn)(Rm)(Eo)(Wt), wherein LA132- (R1)(R1)(E1)(W1) to LA132-(R70)(R70) (E125)(W16) have the structure | 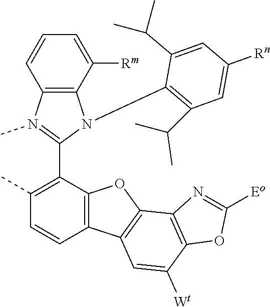 |
| LA133- (Rn)(Rm)(Eo)(Wt), wherein LA133- (R1)(R1)(E1)(W1) to LA133-(R70)(R70) (E125)(W16) have the structure | 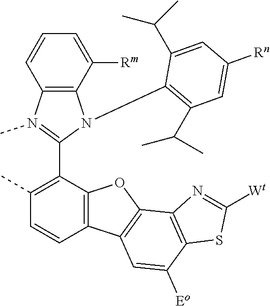 |
| LA134- (Rn)(Rm)(Eo)(Wt), wherein LA134- (R1)(R1)(E1)(W1) to LA134-(R70)(R70) (E125)(W16) have the structure | 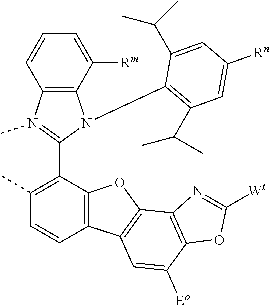 |
| LA135- (Rn)(Rm)(Eo)(Wt), wherein LA135- (R1)(R1)(E1)(W1) to LA135-(R70)(R70) (E125)(W16) have the structure | 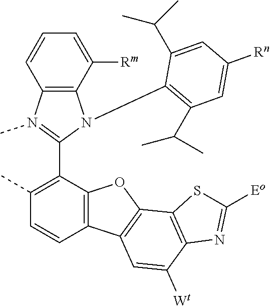 |
| LA136- (Rn)(Rm)(Eo)(Wt), wherein LA136- (R1)(R1)(E1)(W1) to LA136-(R70)(R70) (E125)(W16) have the structure | 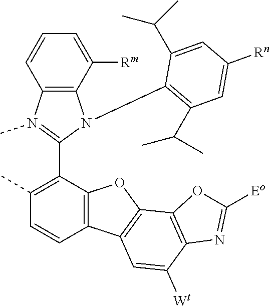 |
| LA137- (Rn)(Rm)(Eo)(Wt), wherein LA137- (R1)(R1)(E1)(W1) to LA137-(R70)(R70) (E125)(W16) have the structure | 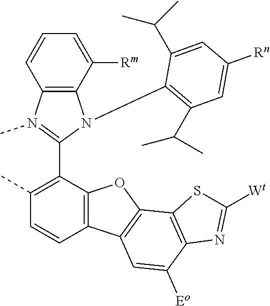 |
| LA138- (Rn)(Rm)(Eo)(Wt), wherein LA138- (R1)(R1)(E1)(W1) to LA138-(R70)(R70) (E125)(W16) have the structure | 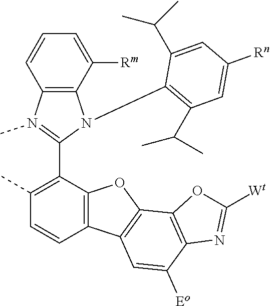 |
| LA139- (Rn)(Rm)(Eo)(Wt), wherein LA139- (R1)(R1)(E1)(W1) to LA139-(R70)(R70) (E125)(W16) have the structure | 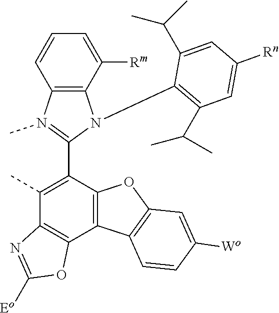 |
| LA140- (Rn)(Rm)(Eo)(Wt), wherein LA140- (R1)(R1)(E1)(W1) to LA140-(R70)(R70) (E125)(W16) have the structure | 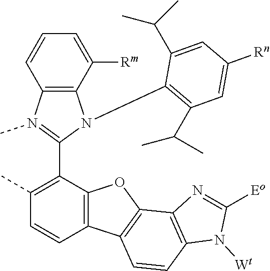 |
| LA141- (Rn)(Rm)(Eo)(Wt), wherein LA141- (R1)(R1)(E1)(W1) to LA141-(R70)(R70) (E125)(W16) have the structure | 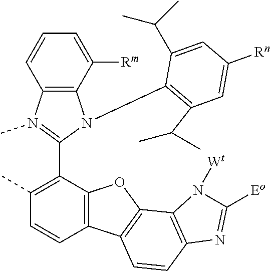 |
| LA142- (Rn)(Rm)(Eo)(Wt), wherein LA142- (R1)(R1)(E1)(W1) to LA142-(R70)(R70) (E125)(W16) have the structure | 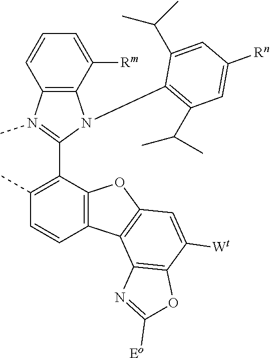 |
| LA143- (Rn)(Rm)(Eo)(Wt), wherein LA143- (R1)(R1)(E1)(W1) to LA143-(R70)(R70) (E125)(W16) have the structure | 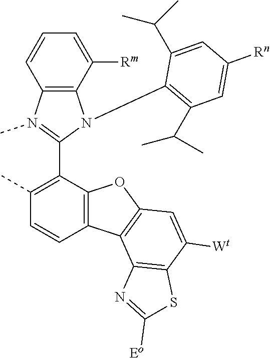 |
| LA144- (Rn)(Rm)(Eo)(Wt), wherein LA144- (R1)(R1)(E1)(W1) to LA144-(R70)(R70) (E125)(W16) have the structure | 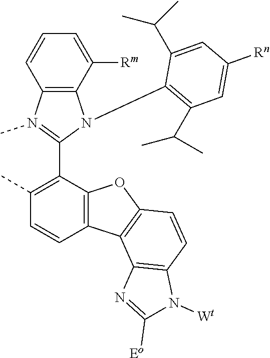 |
| LA145- (Rn)(Rm)(Eo)(Wt), wherein LA145- (R1)(R1)(E1)(W1) to LA145-(R70)(R70) (E125)(W16) have the structure | 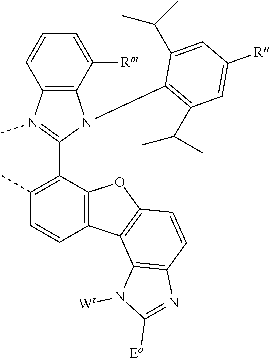 |
| LA146- (Rn)(Rm)(Eo)(Wt), wherein LA146- (R1)(R1)(E1)(W1) to LA146-(R70)(R70) (E125)(W16) have the structure | 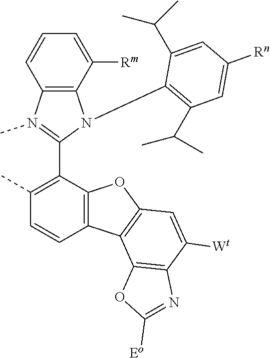 |
| LA147- (Rn)(Rm)(Eo)(Wt), wherein LA147- (R1)(R1)(E1)(W1) to LA147-(R70)(R70) (E125)(W16) have the structure | 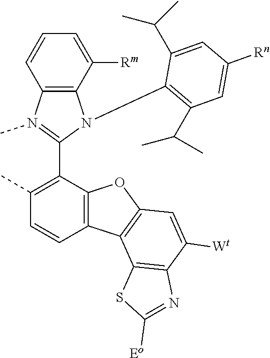 |
| LA148- (Rn)(Rm)(Eo)(Wt), wherein LA148- (R1)(R1)(E1)(W1) to LA148-(R70)(R70) (E125)(W16) have the structure | 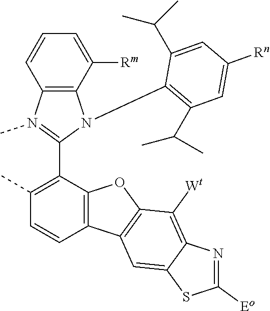 |
| LA149- (Rn)(Rm)(Eo)(Wt), wherein LA149- (R1)(R1)(E1)(W1) to LA149-(R70)(R70) (E125)(W16) have the structure | 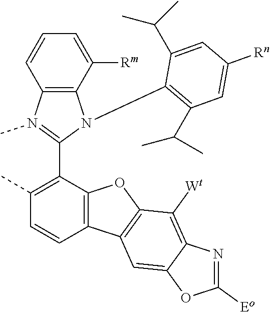 |
| LA150- (Rn)(Rm)(Eo)(Wt), wherein LA150- (R1)(R1)(E1)(W1) to LA150-(R70)(R70) (E125)(W16) have the structure | 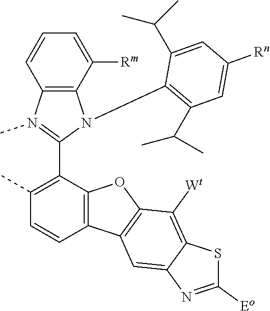 |
| LA151- (Rn)(Rm)(Eo)(Wt), wherein LA151- (R1)(R1)(E1)(W1) to LA151-(R70)(R70) (E125)(W16) have the structure | 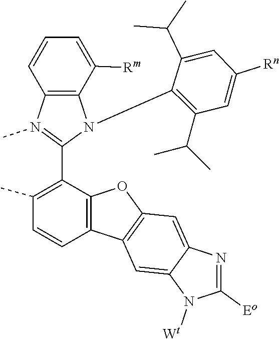 |
| LA152- (Rn)(Rm)(Eo)(Wt), wherein LA152- (R1)(R1)(E1)(W1) to LA152-(R70)(R70) (E125)(W16) have the structure | 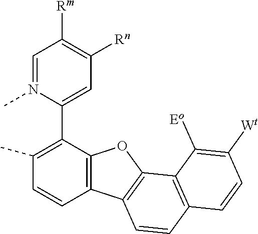 |
| LA153- (Rn)(Rm)(Eo)(Wt), wherein LA153- (R1)(R1)(E1)(W1) to LA153-(R70)(R70) (E125)(W16) have the structure | 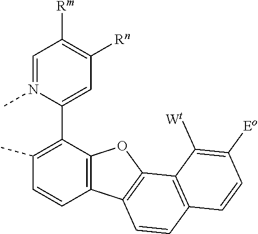 |
| LA154- (Rn)(Rm)(Eo)(Wt), wherein LA154- (R1)(R1)(E1)(W1) to LA154-(R70)(R70) (E125)(W16) have the structure | 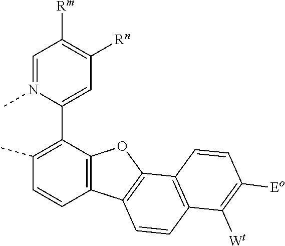 |
| LA155- (Rn)(Rm)(Eo)(Wt), wherein LA155- (R1)(R1)(E1)(W1) to LA155-(R70)(R70) (E125)(W16) have the structure | 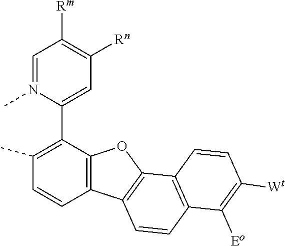 |
| LA156- (Rn)(Rm)(Eo)(Wt), wherein LA156- (R1)(R1)(E1)(W1) to LA156-(R70)(R70) (E125)(W16) have the structure | 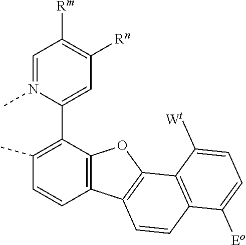 |
| LA157- (Rn)(Rm)(Eo)(Wt), wherein LA157- (R1)(R1)(E1)(W1) to LA157-(R70)(R70) (E125)(W16) have the structure | 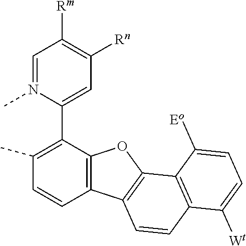 |
| LA158- (Rn)(Rm)(Eo)(Wt), wherein LA158- (R1)(R1)(E1)(W1) to LA158-(R70)(R70) (E125)(W16) have the structure | 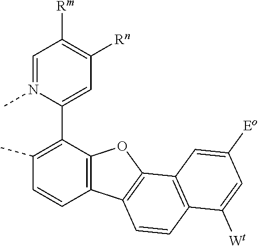 |
| LA159- (Rn)(Rm)(Eo)(Wt), wherein LA159- (R1)(R1)(E1)(W1) to LA159-(R70)(R70) (E125)(W16) have the structure | 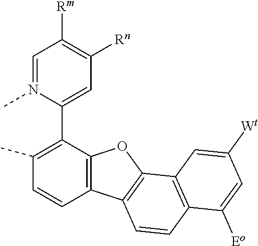 |
| LA160- (Rn)(Rm)(Eo)(Wt), wherein LA160- (R1)(R1)(E1)(W1) to LA160-(R70)(R70) (E125)(W16) have the structure | 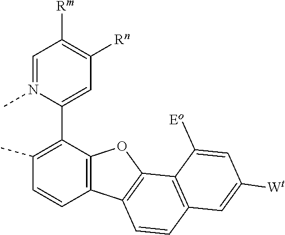 |
| LA161- (Rn)(Rm)(Eo)(Wt), wherein LA161- (R1)(R1)(E1)(W1) to LA161-(R70)(R70) (E125)(W16) have the structure | 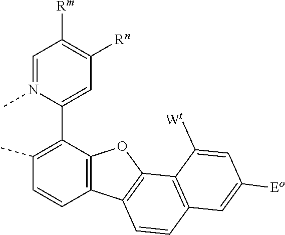 |
| LA162- (Rn)(Rm)(Eo)(Wt), wherein LA162- (R1)(R1)(E1)(W1) to LA162-(R70)(R70) (E125)(W16) have the structure | 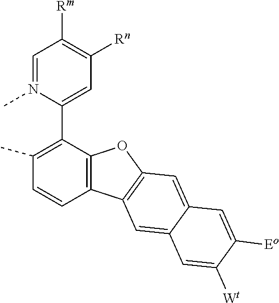 |
| LA163- (Rn)(Rm)(Eo)(Wt), wherein LA163- (R1)(R1)(E1)(W1) to LA163-(R70)(R70) (E125)(W16) have the structure | 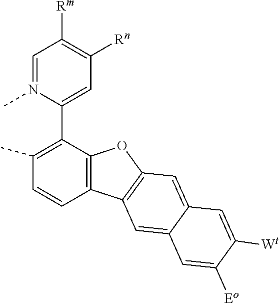 |
| LA164- (Rn)(Rm)(Eo)(Wt), wherein LA164- (R1)(R1)(E1)(W1) to LA164-(R70)(R70) (E125)(W16) have the structure | 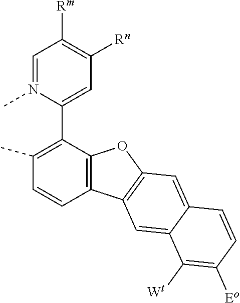 |
| LA165- (Rn)(Rm)(Eo)(Wt), wherein LA165- (R1)(R1)(E1)(W1) to LA165-(R70)(R70) (E125)(W16) have the structure | 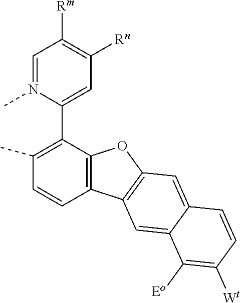 |
| LA166- (Rn)(Rm)(Eo)(Wt), wherein LA166- (R1)(R1)(E1)(W1) to LA166-(R70)(R70) (E125)(W16) have the structure | 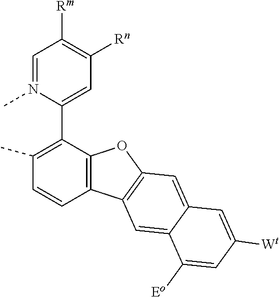 |
| LA167- (Rn)(Rm)(Eo)(Wt), wherein LA167- (R1)(R1)(E1)(W1) to LA167-(R70)(R70) (E125)(W16) have the structure | 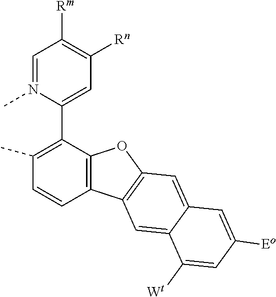 |
| LA168- (Rn)(Rm)(Eo)(Wt), wherein LA168- (R1)(R1)(E1)(W1) to LA168-(R70)(R70) (E125)(W16) have the structure | 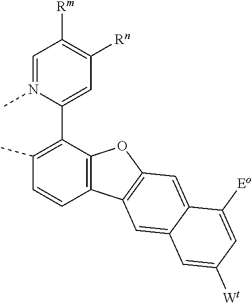 |
| LA169- (Rn)(Rm)(Eo)(Wt), wherein LA169- (R1)(R1)(E1)(W1) to LA169-(R70)(R70) (E125)(W16) have the structure | 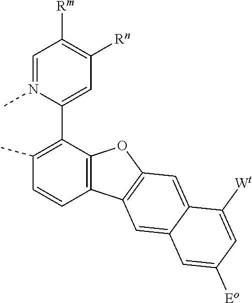 |
| LA170- (Rn)(Rm)(Eo)(Wt), wherein LA170- (R1)(R1)(E1)(W1) to LA170-(R70)(R70) (E125)(W16) have the structure | 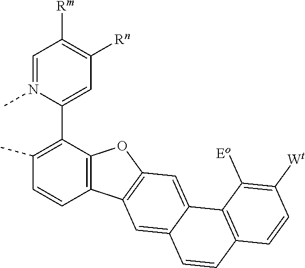 |
| LA171- (Rn)(Rm)(Eo)(Wt), wherein LA171- (R1)(R1)(E1)(W1) to LA171-(R70)(R70) (E125)(W16) have the structure | 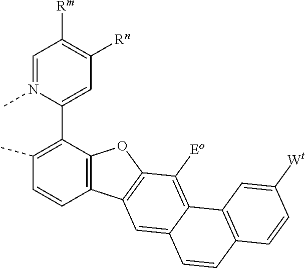 |
| LA172- (Rn)(Rm)(Eo)(Wt), wherein LA172- (R1)(R1)(E1)(W1) to LA172-(R70)(R70) (E125)(W16) have the structure | 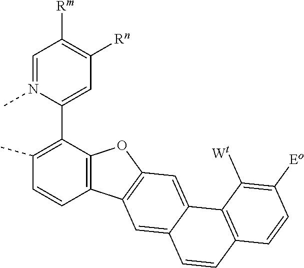 |
| LA173- (Rn)(Rm)(Eo)(Wt), wherein LA173- (R1)(R1)(E1)(W1) to LA173-(R70)(R70) (E125)(W16) have the structure | 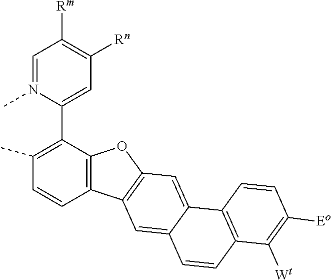 |
| LA174- (Rn)(Rm)(Eo)(Wt), wherein LA174- (R1)(R1)(E1)(W1) to LA174-(R70)(R70) (E125)(W16) have the structure | 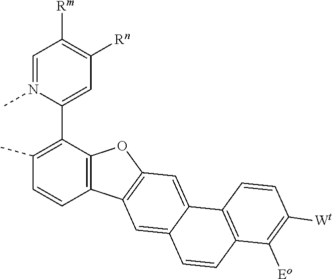 |
| LA175- (Rn)(Rm)(Eo)(Wt), wherein LA175- (R1)(R1)(E1)(W1) to LA175-(R70)(R70) (E125)(W16) have the structure | 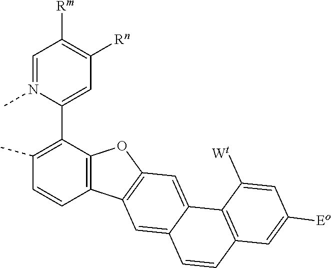 |
| LA176- (Rn)(Rm)(Eo)(Wt), wherein LA176- (R1)(R1)(E1)(W1) to LA176-(R70)(R70) (E125)(W16) have the structure | 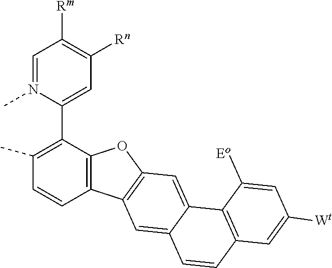 |
| LA177- (Rn)(Rm)(Eo)(Wt), wherein LA177- (R1)(R1)(E1)(W1) to LA177-(R70)(R70) (E125)(W16) have the structure | 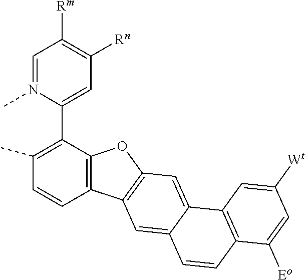 |
| LA178- (Rn)(Rm)(Eo)(Wt), wherein LA178- (R1)(R1)(E1)(W1) to LA178-(R70)(R70) (E125)(W16) have the structure | 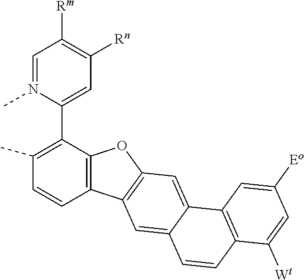 |
| LA179- (Rn)(Rm)(Eo)(Wt), wherein LA179- (R1)(R1)(E1)(W1) to LA179-(R70)(R70) (E125)(W16) have the structure | 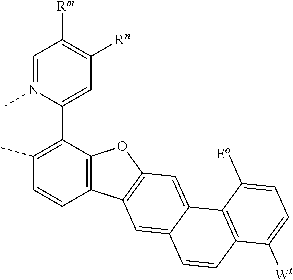 |
| LA180- (Rn)(Rm)(Eo)(Wt), wherein LA180- (R1)(R1)(E1)(W1) to LA180-(R70)(R70) (E125)(W16) have the structure | 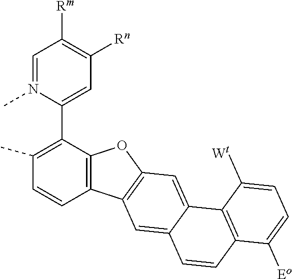 |
| LA181- (Rn)(Rm)(Eo)(Wt), wherein LA181- (R1)(R1)(E1)(W1) to LA181-(R70)(R70) (E125)(W16) have the structure | 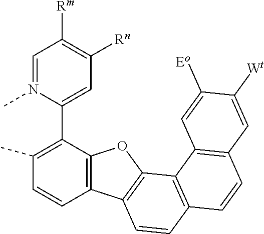 |
| LA182- (Rn)(Rm)(Eo)(Wt), wherein LA182- (R1)(R1)(E1)(W1) to LA182-(R70)(R70) (E125)(W16) have the structure | 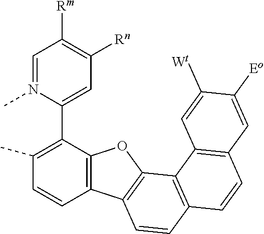 |
| LA183- (Rn)(Rm)(Eo)(Wt), wherein LA183- (R1)(R1)(E1)(W1) to LA183-(R70)(R70) (E125)(W16) have the structure | 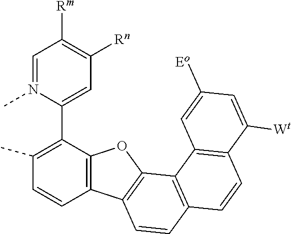 |
| LA184- (Rn)(Rm)(Eo)(Wt), wherein LA184- (R1)(R1)(E1)(W1) to LA184-(R70)(R70) (E125)(W16) have the structure | 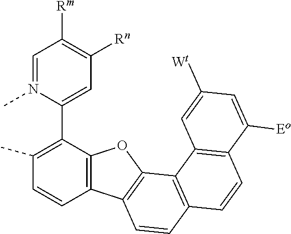 |
| LA185- (Rn)(Rm)(Eo)(Wt), wherein LA185- (R1)(R1)(E1)(W1) to LA185-(R70)(R70) (E125)(W16) have the structure | 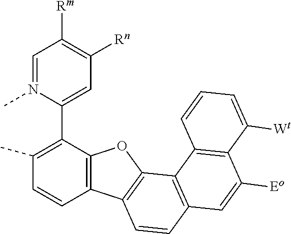 |
| LA186- (Rn)(Rm)(Eo)(Wt), wherein LA186- (R1)(R1)(E1)(W1) to LA186-(R70)(R70) (E125)(W16) have the structure | 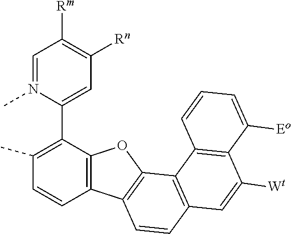 |
| LA187- (Rn)(Rm)(Eo)(Wt), wherein LA187- (R1)(R1)(E1)(W1) to LA187-(R70)(R70) (E125)(W16) have the structure | 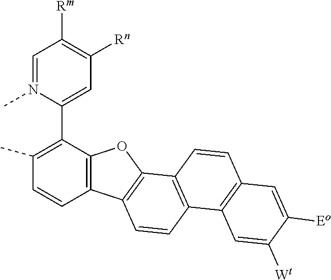 |
| LA188- (Rn)(Rm)(Eo)(Wt), wherein LA188- (R1)(R1)(E1)(W1) to LA188-(R70)(R70) (E125)(W16) have the structure | 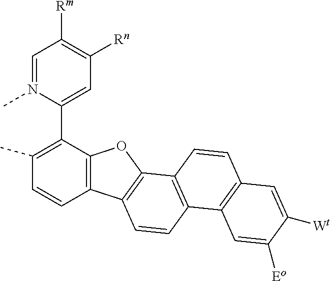 |
| LA189- (Rn)(Rm)(Eo)(Wt), wherein LA189- (R1)(R1)(E1)(W1) to LA189-(R70)(R70) (E125)(W16) have the structure | 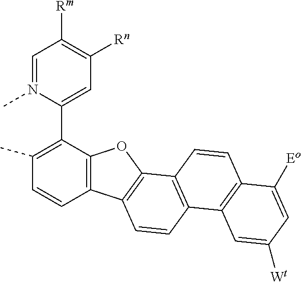 |
| LA190- (Rn)(Rm)(Eo)(Wt), wherein LA190- (R1)(R1)(E1)(W1) to LA190-(R70)(R70) (E125)(W16) have the structure | 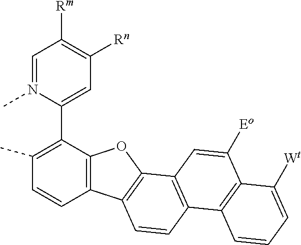 |
| LA191- (Rn)(Rm)(Eo)(Wt), wherein LA191- (R1)(R1)(E1)(W1) to LA191-(R70)(R70) (E125)(W16) have the structure | 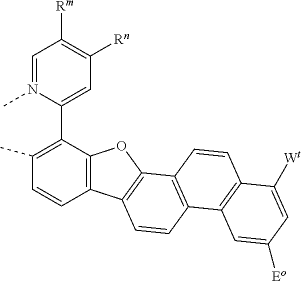 |
| LA192- (Rn)(Rm)(Eo)(Wt), wherein LA192- (R1)(R1)(E1)(W1) to LA192-(R70)(R70) (E125)(W16) have the structure | 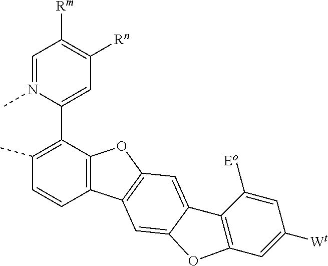 |
| LA193- (Rn)(Rm)(Eo)(Wt), wherein LA193- (R1)(R1)(E1)(W1) to LA193-(R70)(R70) (E125)(W16) have the structure | 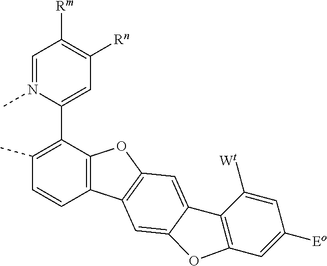 |
| LA194- (Rn)(Rm)(Eo)(Wt), wherein LA194- (R1)(R1)(E1)(W1) to LA194-(R70)(R70) (E125)(W16) have the structure | 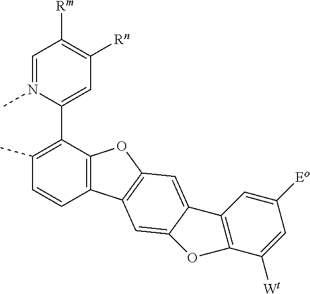 |
| LA195- (Rn)(Rm)(Eo)(Wt), wherein LA195- (R1)(R1)(E1)(W1) to LA195-(R70)(R70) (E125)(W16) have the structure | 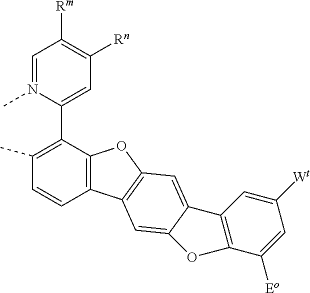 |
| LA196- (Rn)(Rm)(Eo)(Wt), wherein LA196- (R1)(R1)(E1)(W1) to LA196-(R70)(R70) (E125)(W16) have the structure | 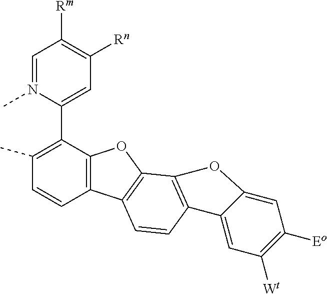 |
| LA197- (Rn)(Rm)(Eo)(Wt), wherein LA197- (R1)(R1)(E1)(W1) to LA197-(R70)(R70) (E125)(W16) have the structure | 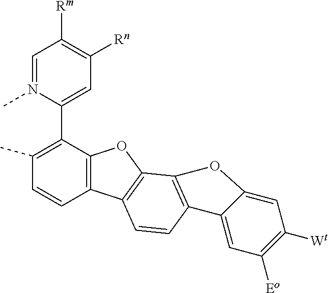 |
| LA198- (Rn)(Rm)(Eo)(Wt), wherein LA198- (R1)(R1)(E1)(W1) to LA198-(R70)(R70) (E125)(W16) have the structure | 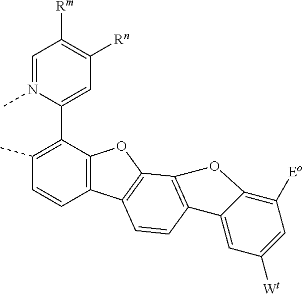 |
| LA199- (Rn)(Rm)(Eo)(Wt), wherein LA199- (R1)(R1)(E1)(W1) to LA199-(R70)(R70) (E125)(W16) have the structure | 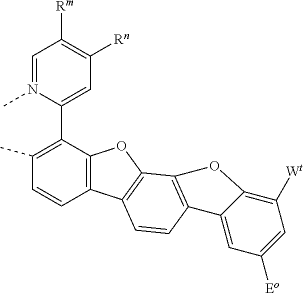 |
| LA200- (Rn)(Rm)(Eo)(Wt), wherein LA200- (R1)(R1)(E1)(W1) to LA200-(R70)(R70) (E125)(W16) have the structure | 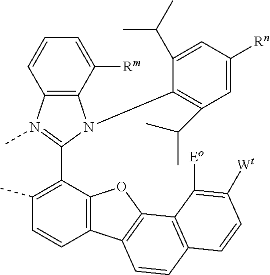 |
| LA201- (Rn)(Rm)(Eo)(Wt), wherein LA201- (R1)(R1)(E1)(W1) to LA201-(R70)(R70) (E125)(W16) have the structure | 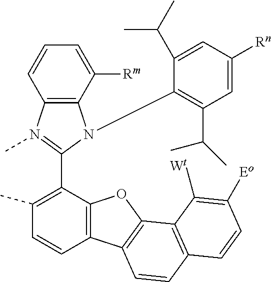 |
| LA202- (Rn)(Rm)(Eo)(Wt), wherein LA202- (R1)(R1)(E1)(W1) to LA202-(R70)(R70) (E125)(W16) have the structure | 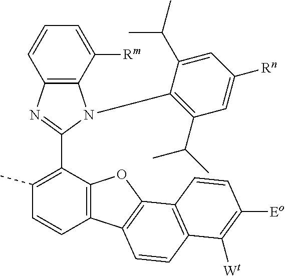 |
| LA203- (Rn)(Rm)(Eo)(Wt), wherein LA203- (R1)(R1)(E1)(W1) to LA203-(R70)(R70) (E125)(W16) have the structure | 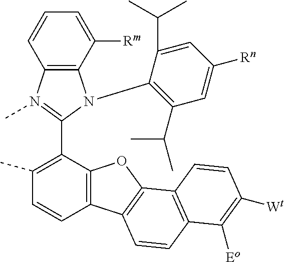 |
| LA204- (Rn)(Rm)(Eo)(Wt), wherein LA204- (R1)(R1)(E1)(W1) to LA204-(R70)(R70) (E125)(W16) have the structure | 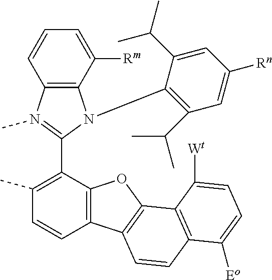 |
| LA205- (Rn)(Rm)(Eo)(Wt), wherein LA205- (R1)(R1)(E1)(W1) to LA205-(R70)(R70) (E125)(W16) have the structure | 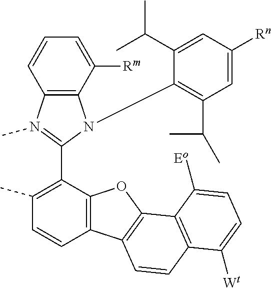 |
| LA206- (Rn)(Rm)(Eo)(Wt), wherein LA206- (R1)(R1)(E1)(W1) to LA206-(R70)(R70) (E125)(W16) have the structure | 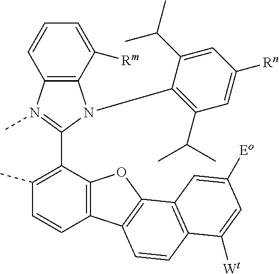 |
| LA207- (Rn)(Rm)(Eo)(Wt), wherein LA207- (R1)(R1)(E1)(W1) to LA207-(R70)(R70) (E125)(W16) have the structure | 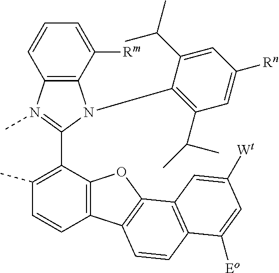 |
| LA208- (Rn)(Rm)(Eo)(Wt), wherein LA208- (R1)(R1)(E1)(W1) to LA208-(R70)(R70) (E125)(W16) have the structure | 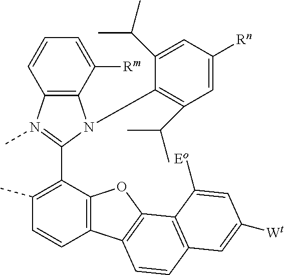 |
| LA209- (Rn)(Rm)(Eo)(Wt), wherein LA209- (R1)(R1)(E1)(W1) to LA209-(R70)(R70) (E125)(W16) have the structure | 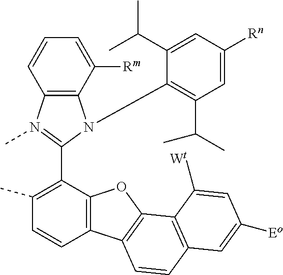 |
| LA210- (Rn)(Rm)(Eo)(Wt), wherein LA210- (R1)(R1)(E1)(W1) to LA210-(R70)(R70) (E125)(W16) have the structure | 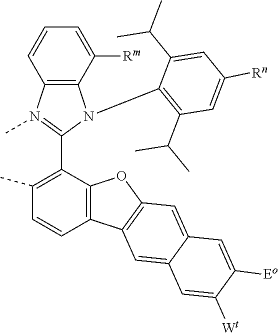 |
| LA211- (Rn)(Rm)(Eo)(Wt), wherein LA211- (R1)(R1)(E1)(W1) to LA211-(R70)(R70) (E125)(W16) have the structure | 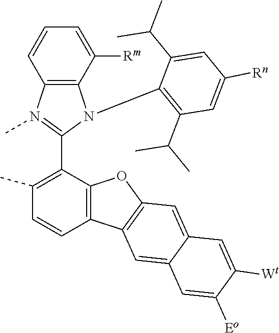 |
| LA212- (Rn)(Rm)(Eo)(Wt), wherein LA212- (R1)(R1)(E1)(W1) to LA212-(R70)(R70) (E125)(W16) have the structure | 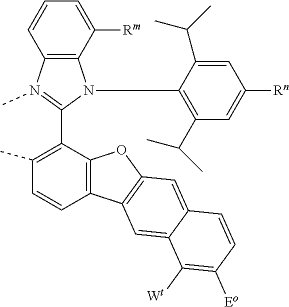 |
| LA213- (Rn)(Rm)(Eo)(Wt), wherein LA213- (R1)(R1)(E1)(W1) to LA213-(R70)(R70) (E125)(W16) have the structure | 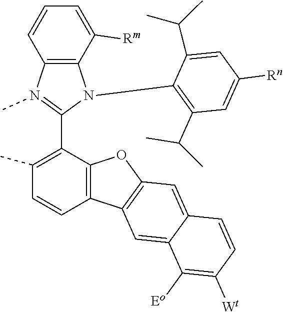 |
| LA214- (Rn)(Rm)(Eo)(Wt), wherein LA214- (R1)(R1)(E1)(W1) to LA214-(R70)(R70) (E125)(W16) have the structure | 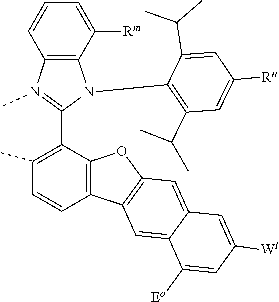 |
| LA215- (Rn)(Rm)(Eo)(Wt), wherein LA215- (R1)(R1)(E1)(W1) to LA215-(R70)(R70) (E125)(W16) have the structure | 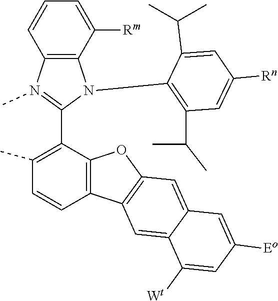 |
| LA216- (Rn)(Rm)(Eo)(Wt), wherein LA216- (R1)(R1)(E1)(W1) to LA216-(R70)(R70) (E125)(W16) have the structure | 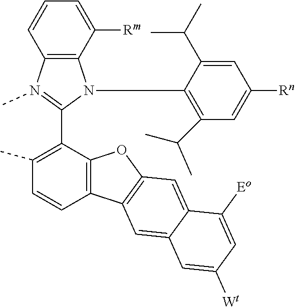 |
| LA217- (Rn)(Rm)(Eo)(Wt), wherein LA217- (R1)(R1)(E1)(W1) to LA217-(R70)(R70) (E125)(W16) have the structure | 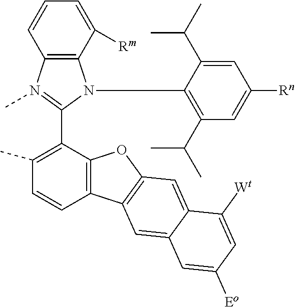 |
| LA218- (Rn)(Rm)(Eo)(Wt), wherein LA218- (R1)(R1)(E1)(W1) to LA218-(R70)(R70) (E125)(W16) have the structure | 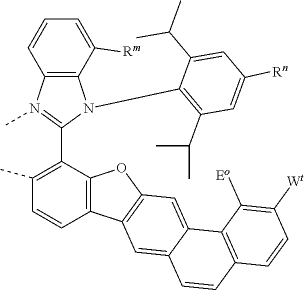 |
| LA219- (Rn)(Rm)(Eo)(Wt), wherein LA219- (R1)(R1)(E1)(W1) to LA219-(R70)(R70) (E125)(W16) have the structure | 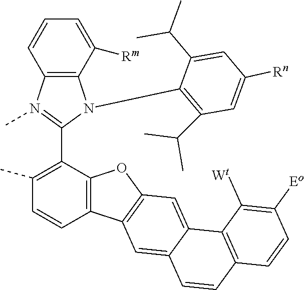 |
| LA220- (Rn)(Rm)(Eo)(Wt), wherein LA220- (R1)(R1)(E1)(W1) to LA220-(R70)(R70) (E125)(W16) have the structure | 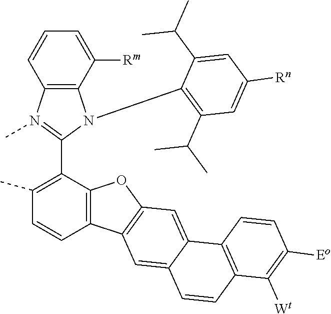 |
| LA221- (Rn)(Rm)(Eo)(Wt), wherein LA221- (R1)(R1)(E1)(W1) to LA221-(R70)(R70) (E125)(W16) have the structure | 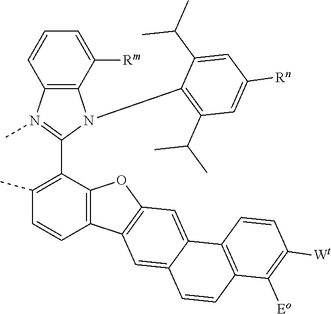 |
| LA222- (Rn)(Rm)(Eo)(Wt), wherein LA222- (R1)(R1)(E1)(W1) to LA222-(R70)(R70) (E125)(W16) have the structure | 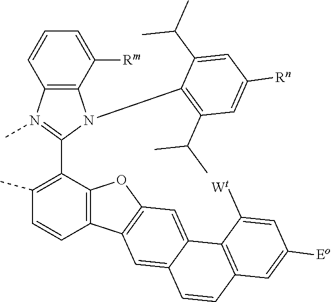 |
| LA223- (Rn)(Rm)(Eo)(Wt), wherein LA223- (R1)(R1)(E1)(W1) to LA223-(R70)(R70) (E125)(W16) have the structure | 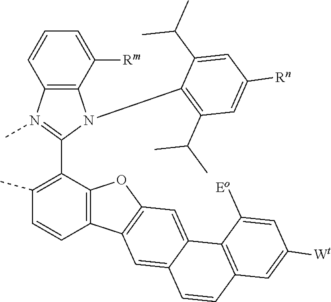 |
| LA224- (Rn)(Rm)(Eo)(Wt), wherein LA224- (R1)(R1)(E1)(W1) to LA224-(R70)(R70) (E125)(W16) have the structure | 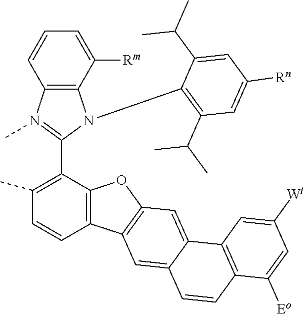 |
| LA225- (Rn)(Rm)(Eo)(Wt), wherein LA225- (R1)(R1)(E1)(W1) to L- (R70)(R70) (E125)(W16) have the structure | 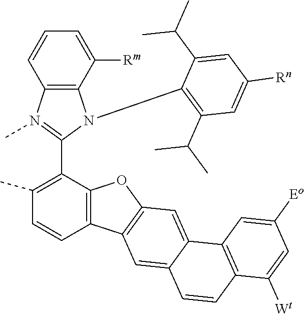 |
| LA226- (Rn)(Rm)(Eo)(Wt), wherein LA226- (R1)(R1)(E1)(W1) to LA226-(R70)(R70) (E125)(W16) have the structure | 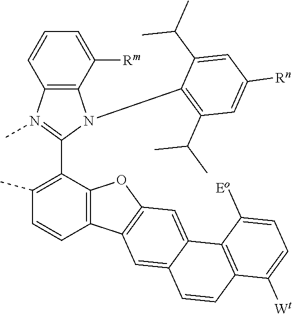 |
| LA227- (Rn)(Rm)(Eo)(Wt), wherein LA227- (R1)(R1)(E1)(W1) to LA227-(R70)(R70) (E125)(W16) have the structure | 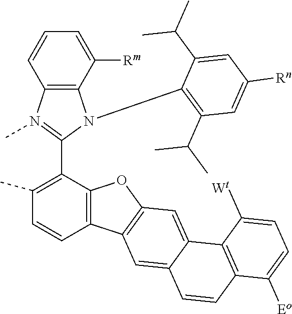 |
| LA228- (Rn)(Rm)(Eo)(Wt), wherein LA228- (R1)(R1)(E1)(W1) to LA228-(R70)(R70) (E125)(W16) have the structure | 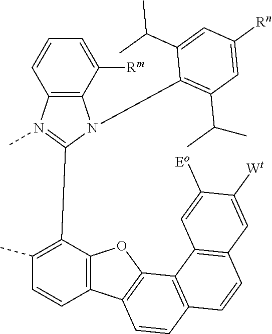 |
| LA229- (Rn)(Rm)(Eo)(Wt), wherein LA229- (R1)(R1)(E1)(W1) to LA229-(R70)(R70) (E125)(W16) have the structure | 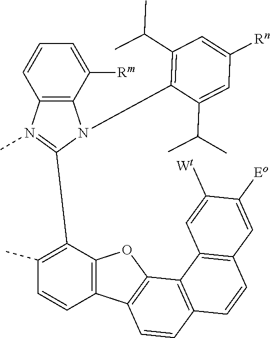 |
| LA230- (Rn)(Rm)(Eo)(Wt), wherein LA230- (R1)(R1)(E1)(W1) to LA230-(R70)(R70) (E125)(W16) have the structure | 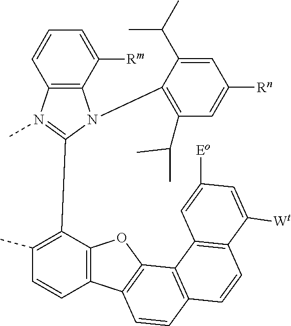 |
| LA231- (Rn)(Rm)(Eo)(Wt), wherein LA231- (R1)(R1)(E1)(W1) to LA231-(R70)(R70) (E125)(W16) have the structure | 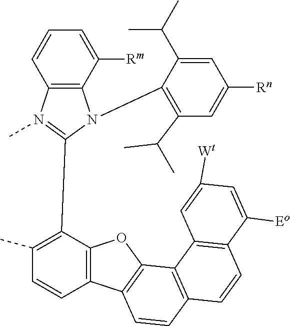 |
| LA232- (Rn)(Rm)(Eo)(Wt), wherein LA232- (R1)(R1)(E1)(W1) to LA232-(R70)(R70) (E125)(W16) have the structure | 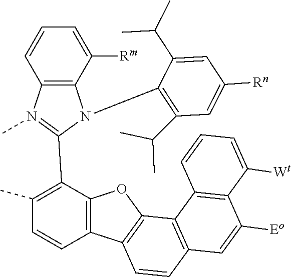 |
| LA233- (Rn)(Rm)(Eo)(Wt), wherein LA233- (R1)(R1)(E1)(W1) to LA233-(R70)(R70) (E125)(W16) have the structure | 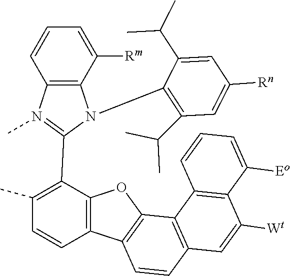 |
| LA234- (Rn)(Rm)(Eo)(Wt), wherein LA234- (R1)(R1)(E1)(W1) to LA234-(R70)(R70) (E125)(W16) have the structure | 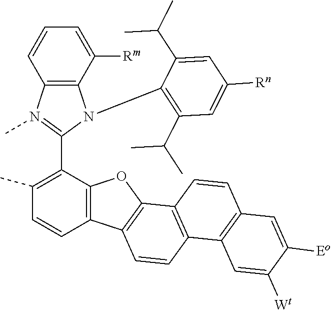 |
| LA235- (Rn)(Rm)(Eo)(Wt), wherein LA235- (R1)(R1)(E1)(W1) to LA235-(R70)(R70) (E125)(W16) have the structure | 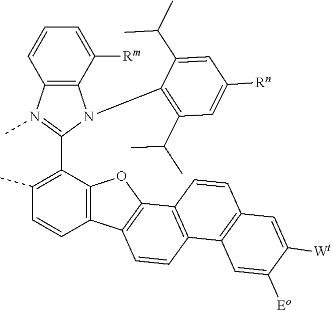 |
| LA236- (Rn)(Rm)(Eo)(Wt), wherein LA236- (R1)(R1)(E1)(W1) to LA236-(R70)(R70) (E125)(W16) have the structure | 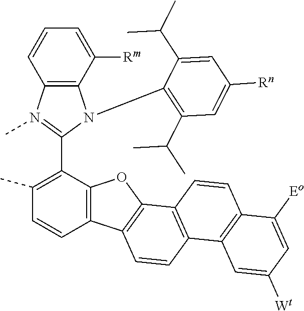 |
| LA237- (Rn)(Rm)(Eo)(Wt), wherein LA237- (R1)(R1)(E1)(W1) to LA237-(R70)(R70) (E125)(W16) have the structure | 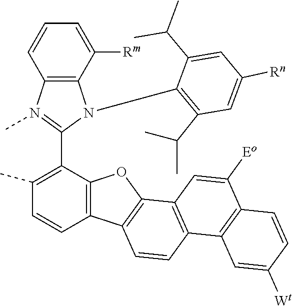 |
| LA238- (Rn)(Rm)(Eo)(Wt), wherein LA238- (R1)(R1)(E1)(W1) to LA238-(R70)(R70) (E125)(W16) have the structure | 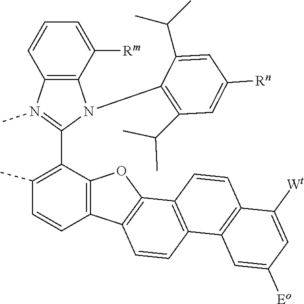 |
| LA239- (Rn)(Rm)(Eo)(Wt), wherein LA239- (R1)(R1)(E1)(W1) to LA239-(R70)(R70) (E125)(W16) have the structure | 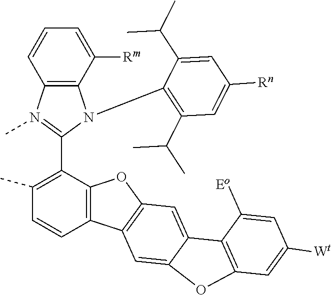 |
| LA240- (Rn)(Rm)(Eo)(Wt), wherein LA240- (R1)(R1)(E1)(W1) to LA240-(R70)(R70) (E125)(W16) have the structure | 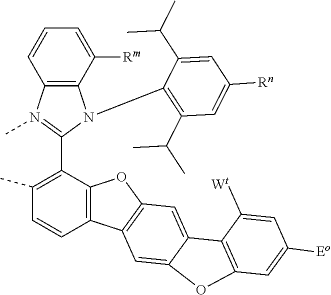 |
| LA241- (Rn)(Rm)(Eo)(Wt), wherein LA241- (R1)(R1)(E1)(W1) to LA241-(R70)(R70) (E125)(W16) have the structure | 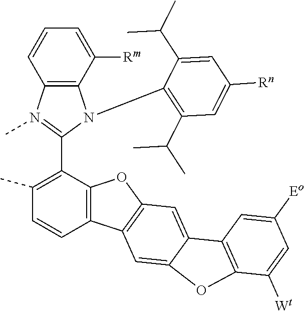 |
| LA242- (Rn)(Rm)(Eo)(Wt), wherein LA242- (R1)(R1)(E1)(W1) to LA242-(R70)(R70) (E125)(W16) have the structure | 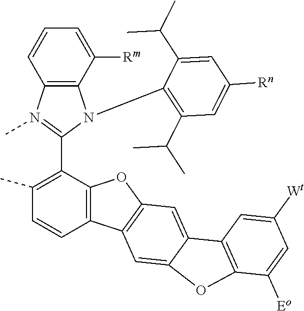 |
| LA243- (Rn)(Rm)(Eo)(Wt), wherein LA243- (R1)(R1)(E1)(W1) to LA243-(R70)(R70) (E125)(W16) have the structure | 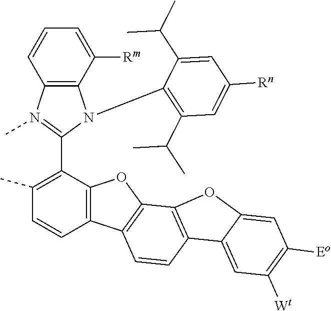 |
| LA244- (Rn)(Rm)(Eo)(Wt), wherein LA244- (R1)(R1)(E1)(W1) to LA244-(R70)(R70) (E125)(W16) have the structure | 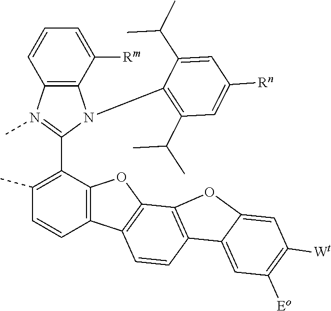 |
| LA245- (Rn)(Rm)(Eo)(Wt), wherein LA245- (R1)(R1)(E1)(W1) to LA245-(R70)(R70) (E125)(W16) have the structure | 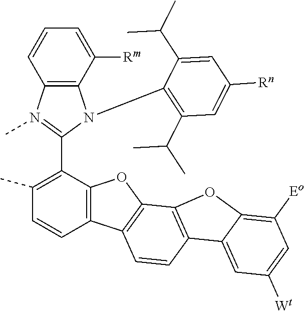 |
| LA246- (Rn)(Rm)(Eo)(Wt), wherein LA246- (R1)(R1)(E1)(W1) to LA246-(R70)(R70) (E125)(W16) have the structure | 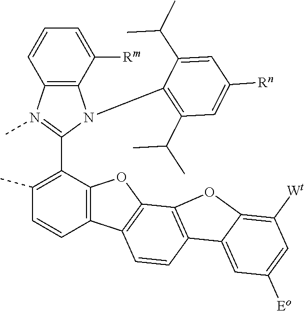 |

wherein E1 to E125 has the structures defined in the following LIST 5:

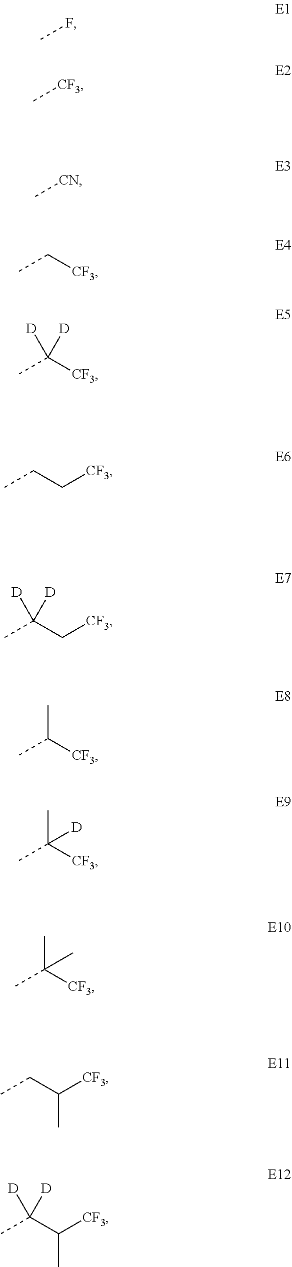

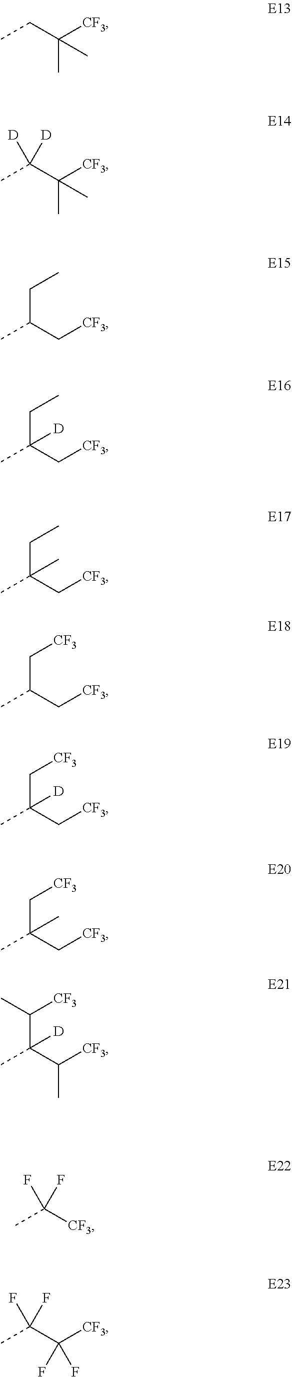

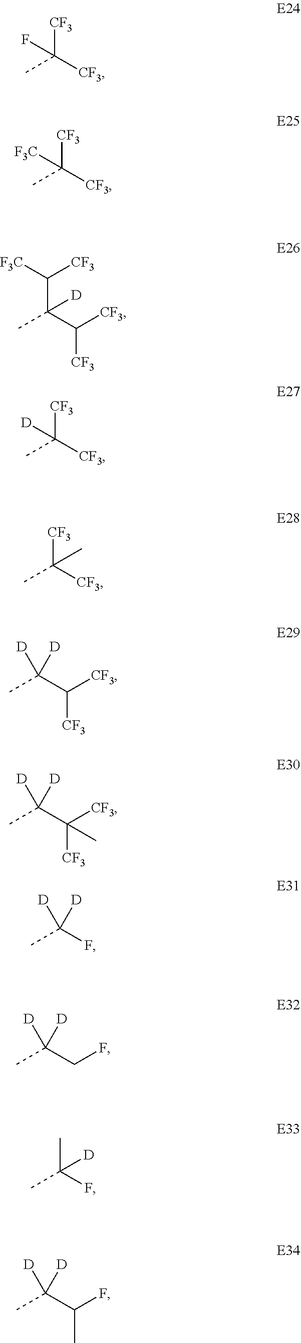

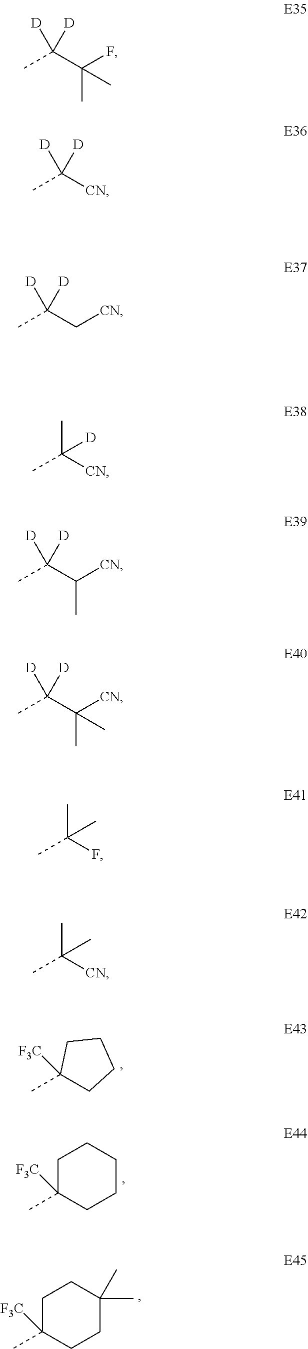

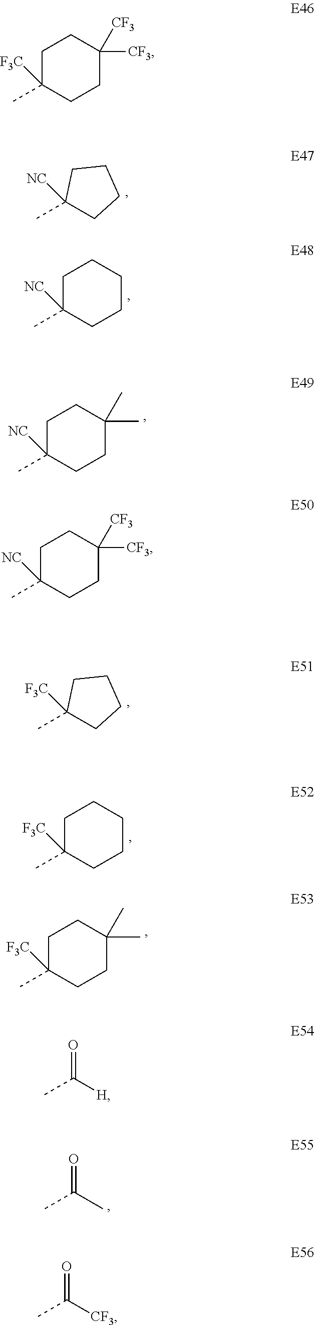

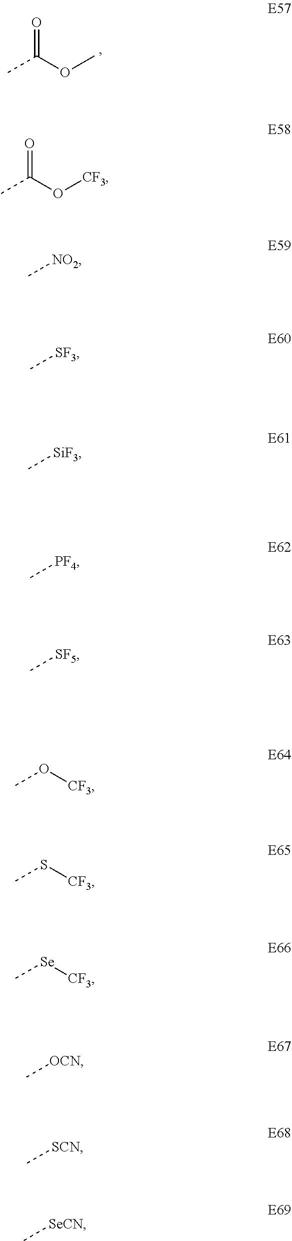

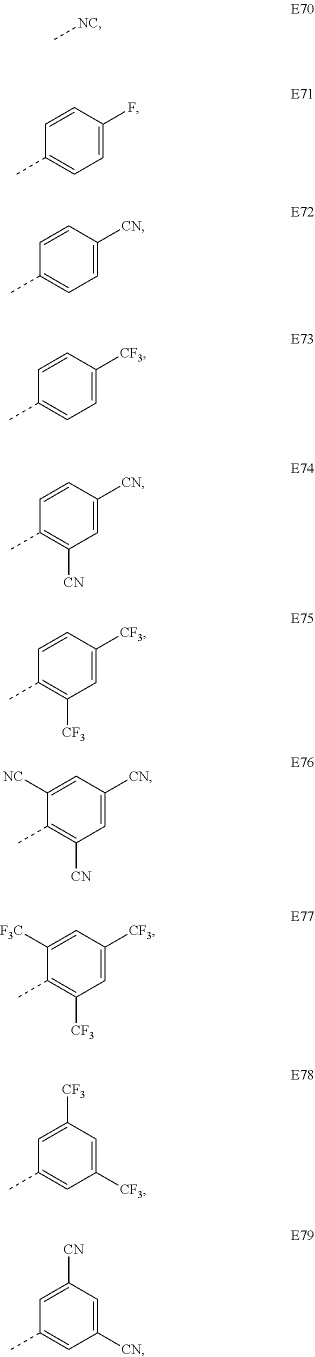

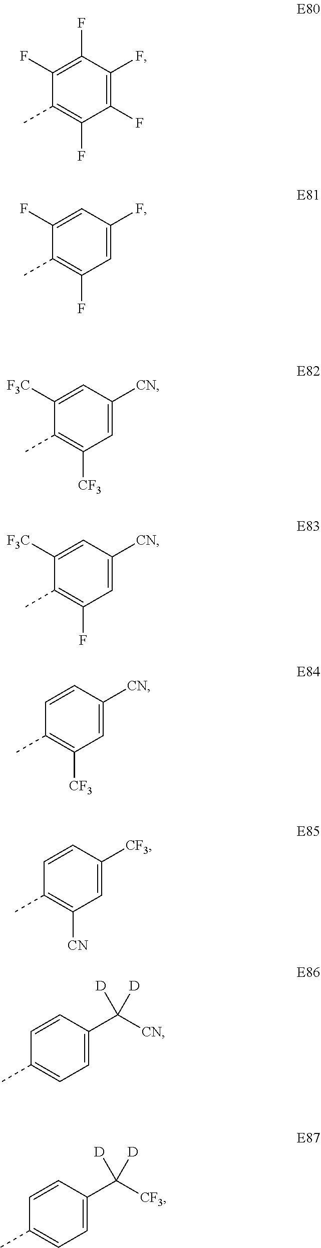

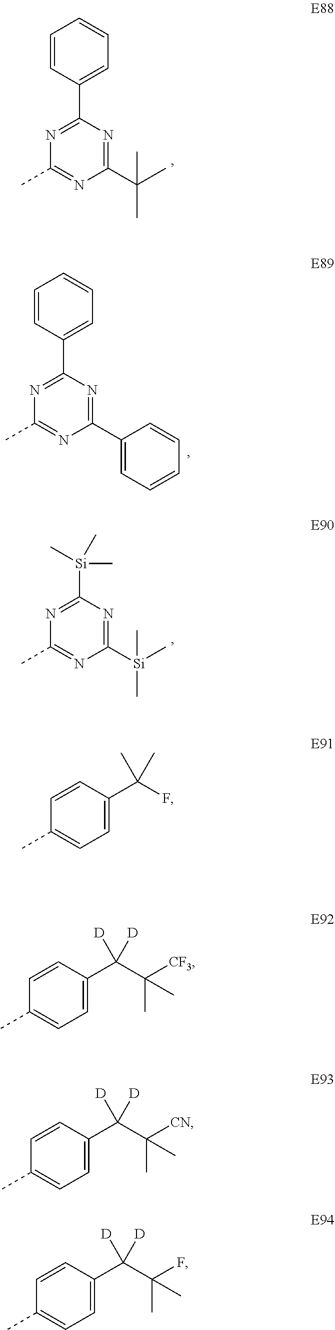

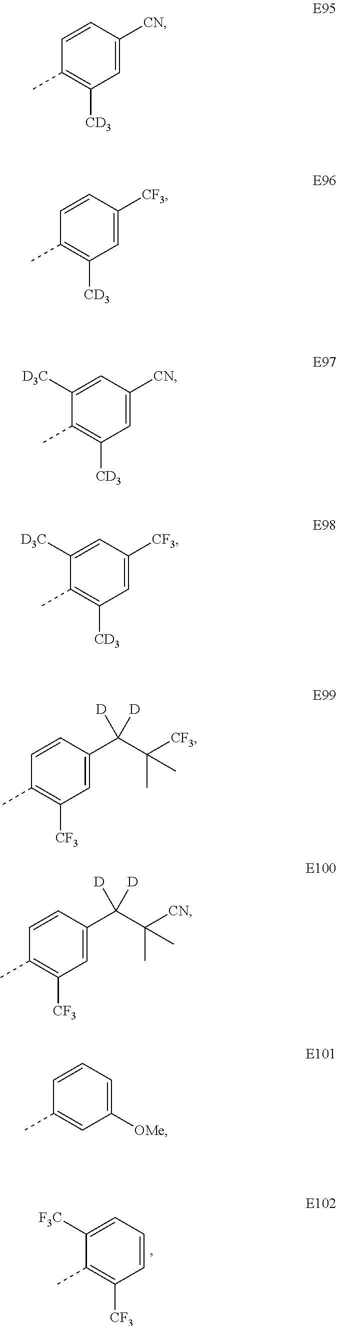

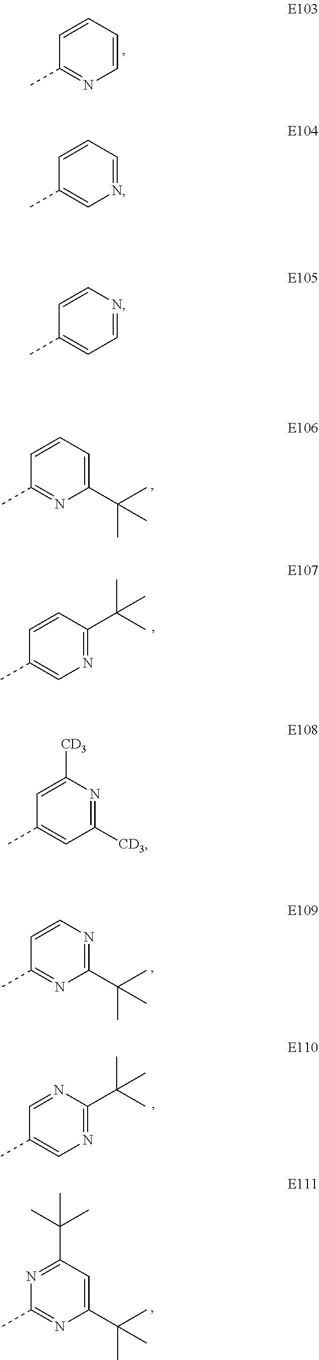

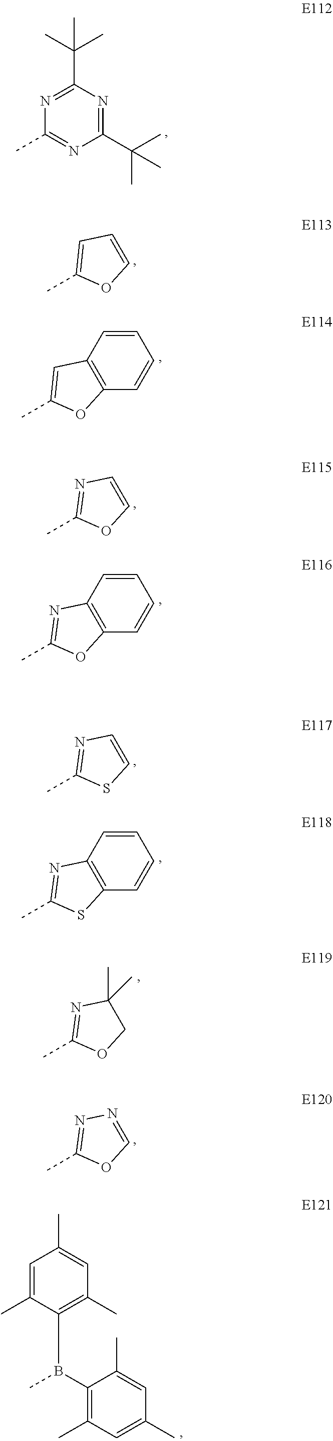

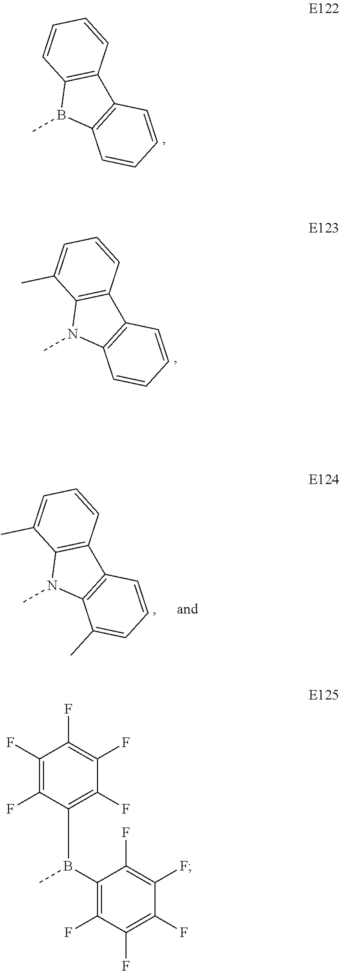

wherein W1 to W16 have the structures defined in the following LIST 6:

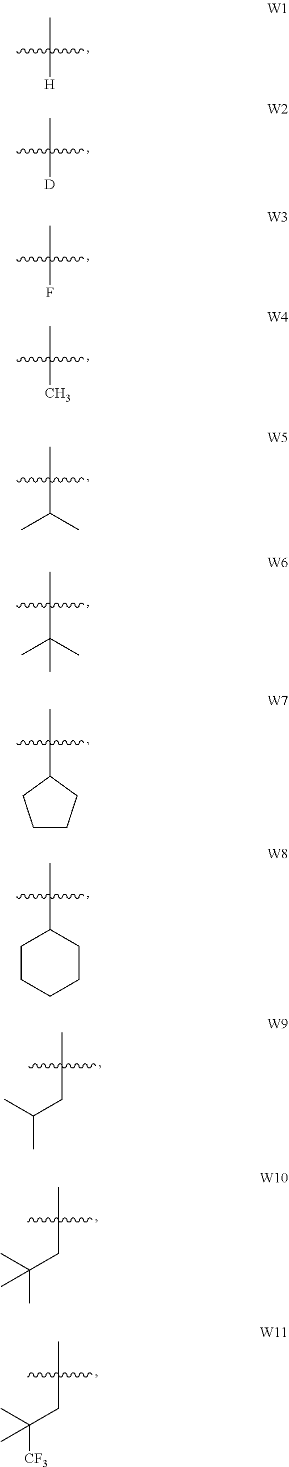

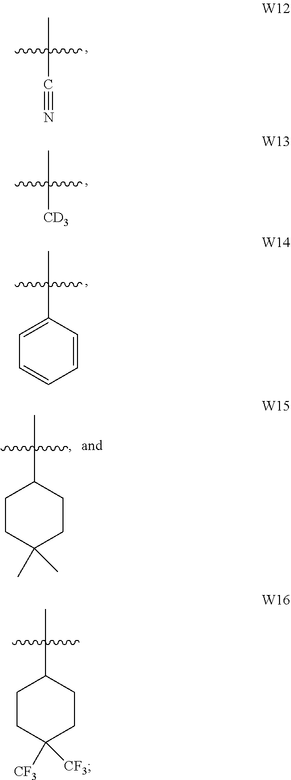

and
wherein R1 to R70 have the structures defined in the following LIST 7:

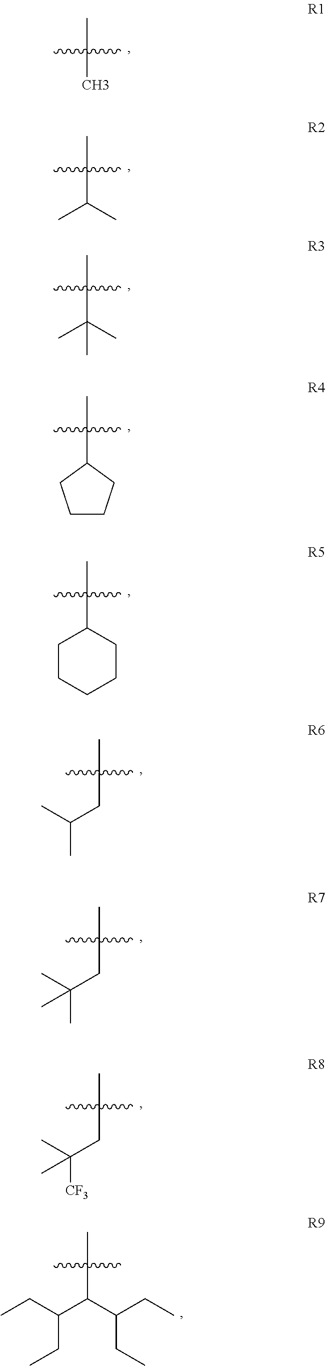

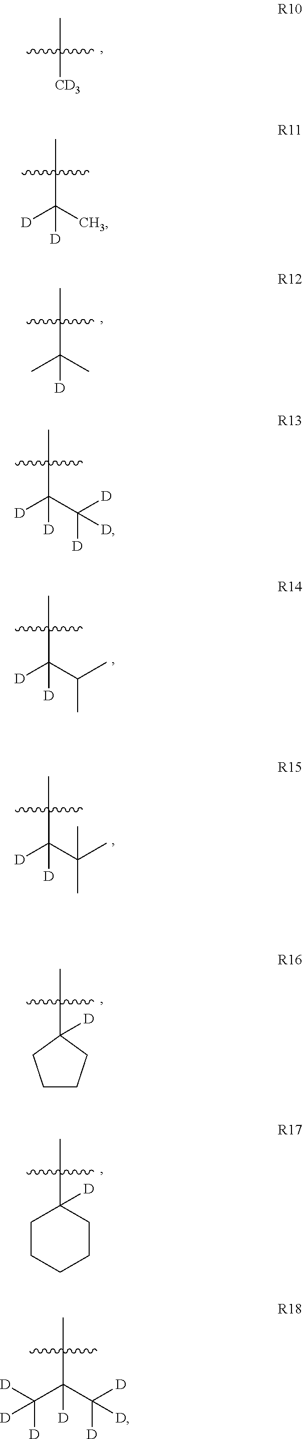

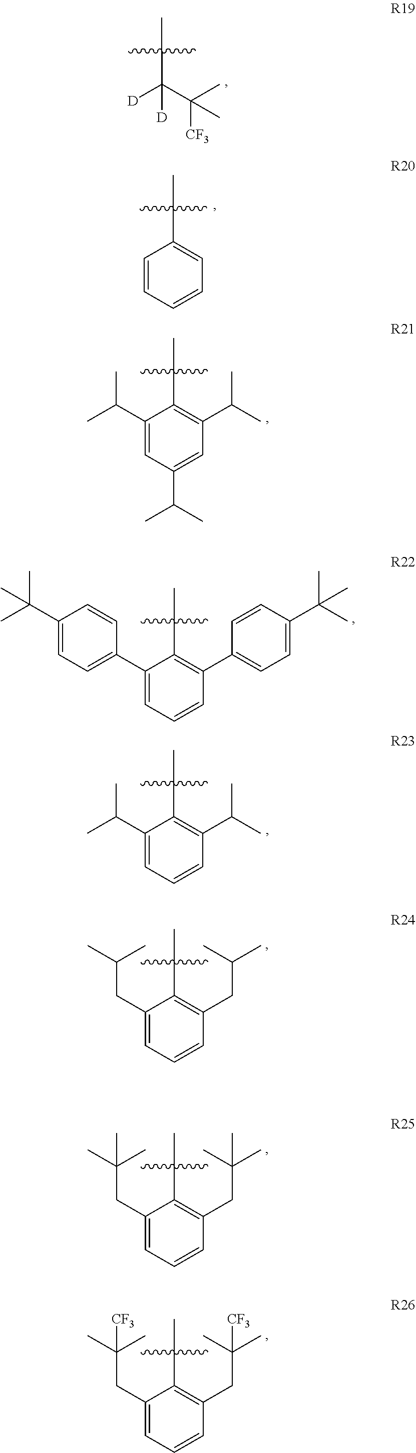

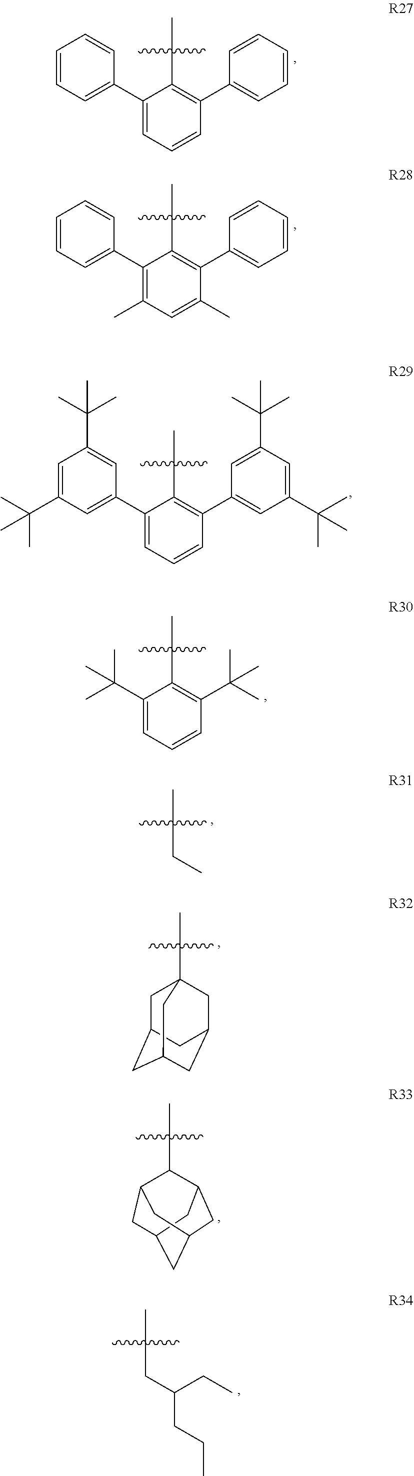

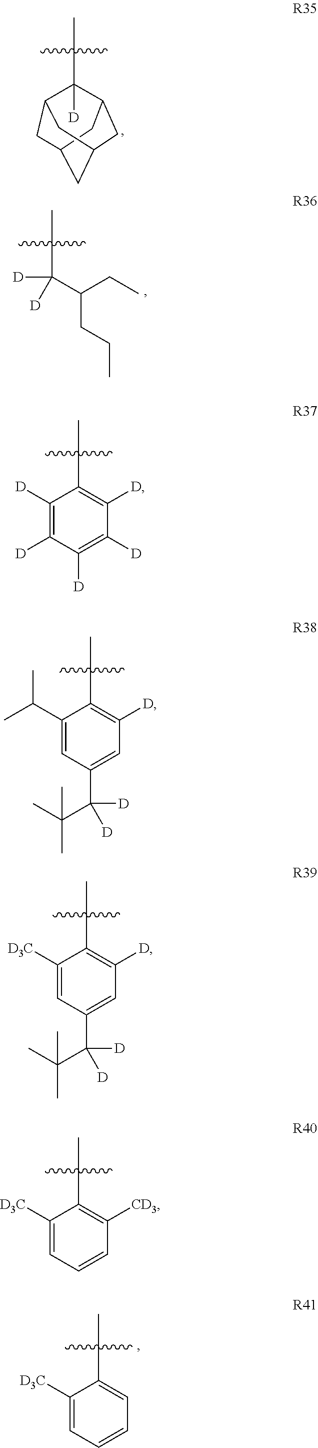

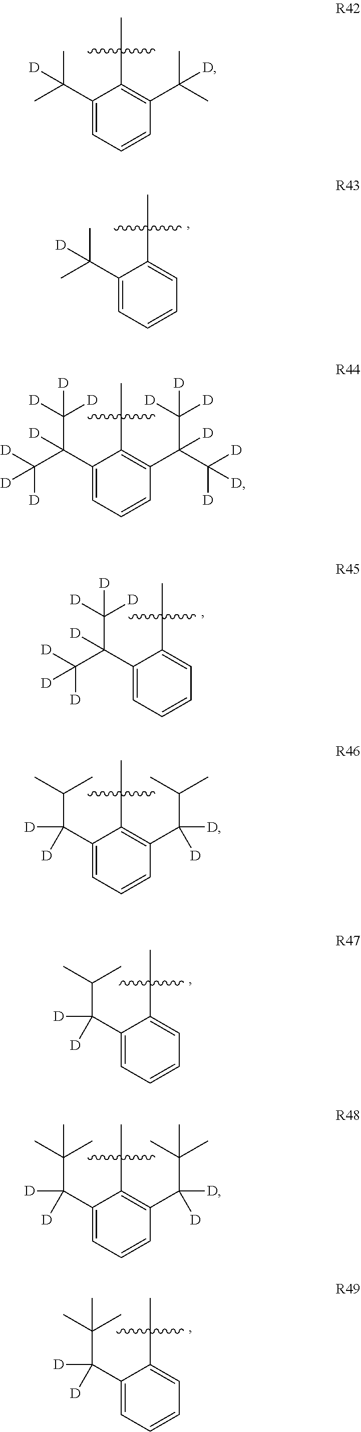

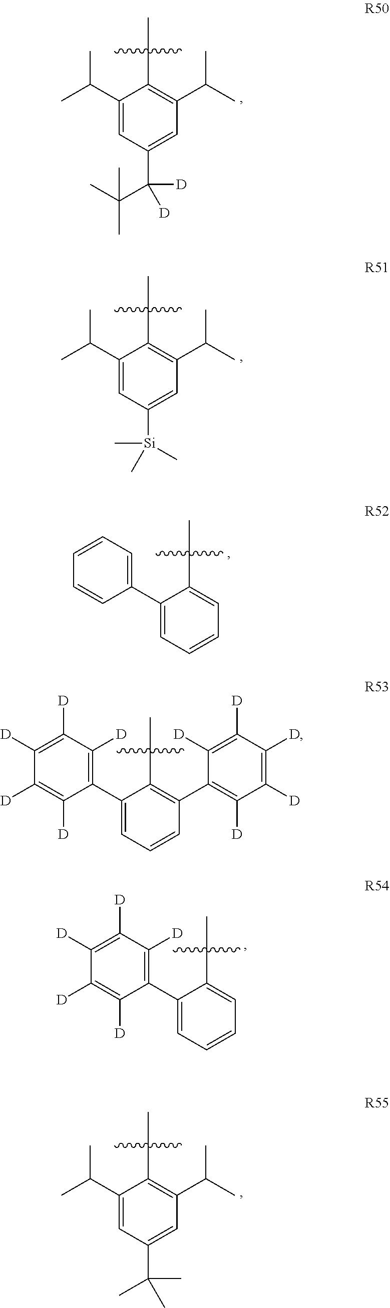

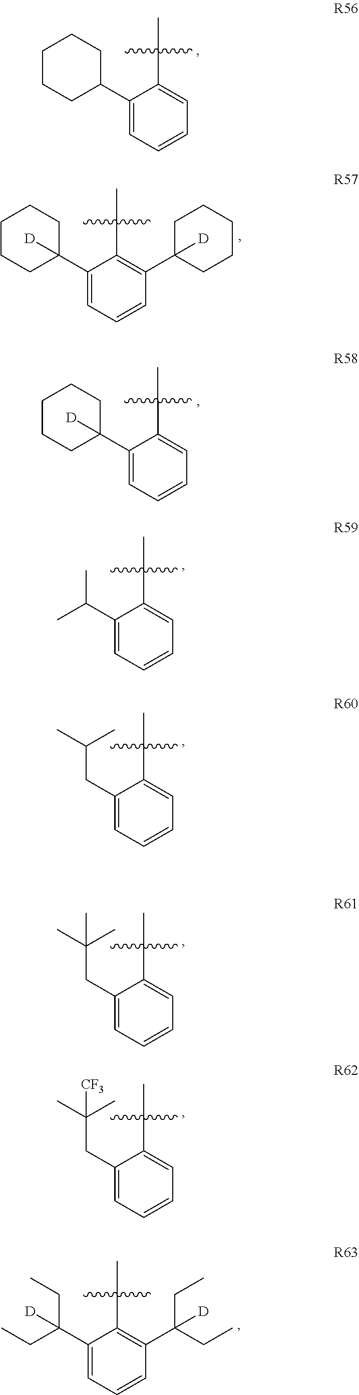

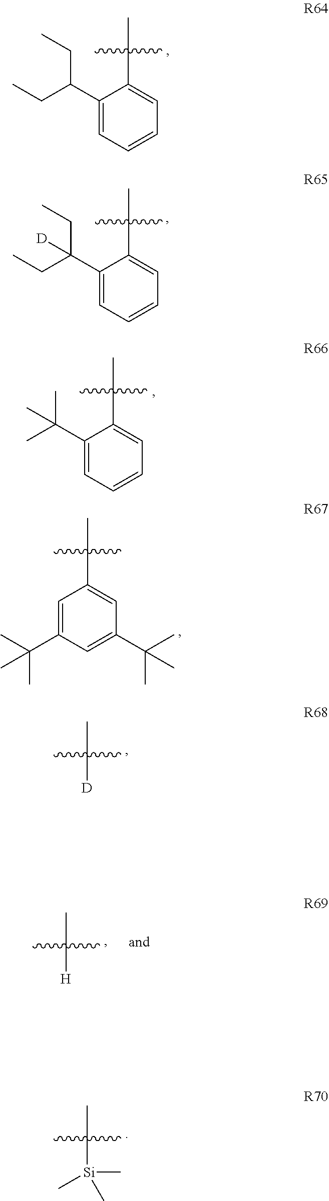

In some embodiments, the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound can have the formula Ir(L_{A})₃, the formula Ir(L_{A})(L_{Bk})₂, the formula Ir(L_{Ai}-(Rⁿ)(R^{m})(E^{o})(W^{t}))(L_{B})₂, the formula Ir(L_{A})₂(L_{Bk}), the formula Ir(L_{Ai}-(Rⁿ)(R^{m})(E^{o})(W^{t}))₂(L_{B}), the formula Ir(L_{A})₂(L_{Cj-I}), the formula Ir(L_{A})₂(L_{Cj-II}), the formula Ir(L_{A})(L_{Bk})(L_{Cj-I}), or the formula Ir(L_{A})(L_{Bk})(L_{Cj-I}), wherein L_{A} is a ligand with respect to Formula I as defined here; L_{Bk} is defined herein; and L_{Cj-I} and L_{Cj-II} are each defined herein. In some embodiments, the compound can have a formula Ir(L_{Ai}-(Rⁿ)(R^{m})(E^{o})(W^{t}))₃, Ir(L_{Ai}-(Rⁿ)(R^{m})(E^{o})(W^{t})(L_{Bk})₂, Ir(L_{Ai}-(Rⁿ)(R^{m})(E^{o})(W^{t}))₂(L_{Bk}), Ir(L_{Ai}-(Rⁿ)(R^{m})(E^{o})(W^{t}))₂(L_{Cj-I}), Ir(L_{Ai}-(Rⁿ)(R^{m})(E^{o})(W^{t}))₂(L_{Cj-II}), or Ir(L_{Ai}-(Rⁿ)(R^{m})(E^{o})(W^{t}))(L_{Bk})(L_{Cj-II}), wherein all the variables are the same as previously defined.

In some embodiments, the compound has a formula of Pt(L_{A})(L_{B}); and wherein L_{A} and L_{B} can be same or different. In some such embodiments, L_{A} and L_{B} are connected to form a tetradentate ligand.

In some embodiments, L_{B} and L_{C} are each independently selected from the group consisting of the structures of the following

### LIST 8:

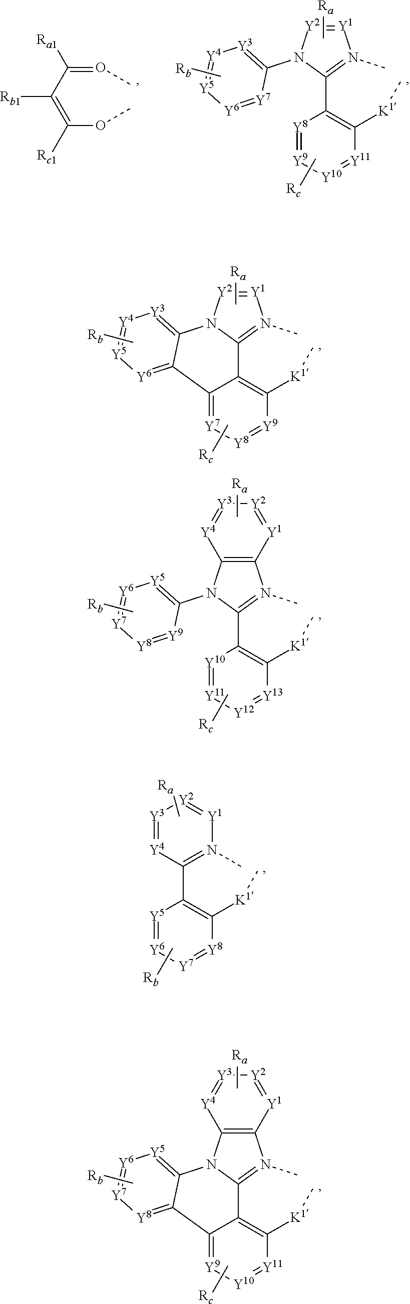 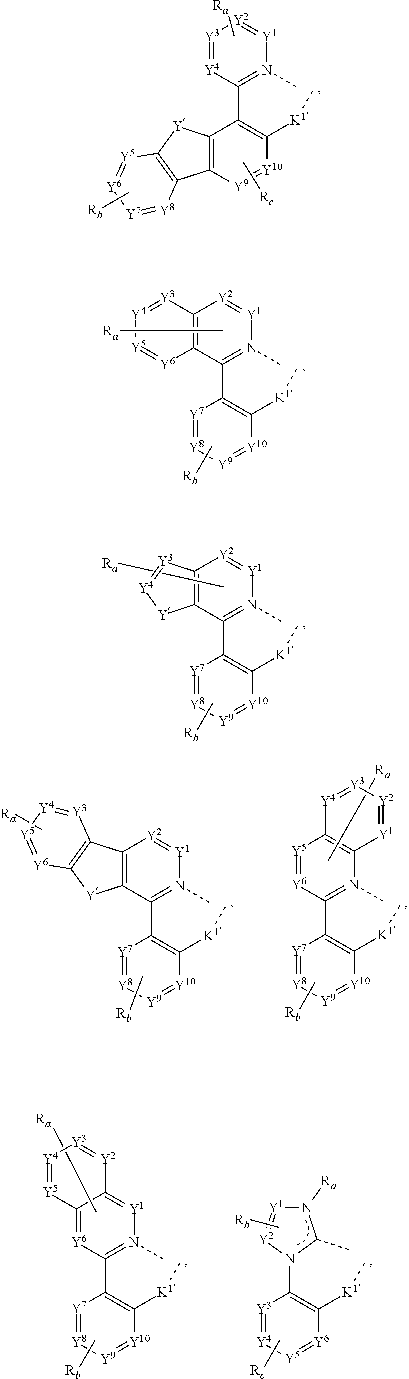 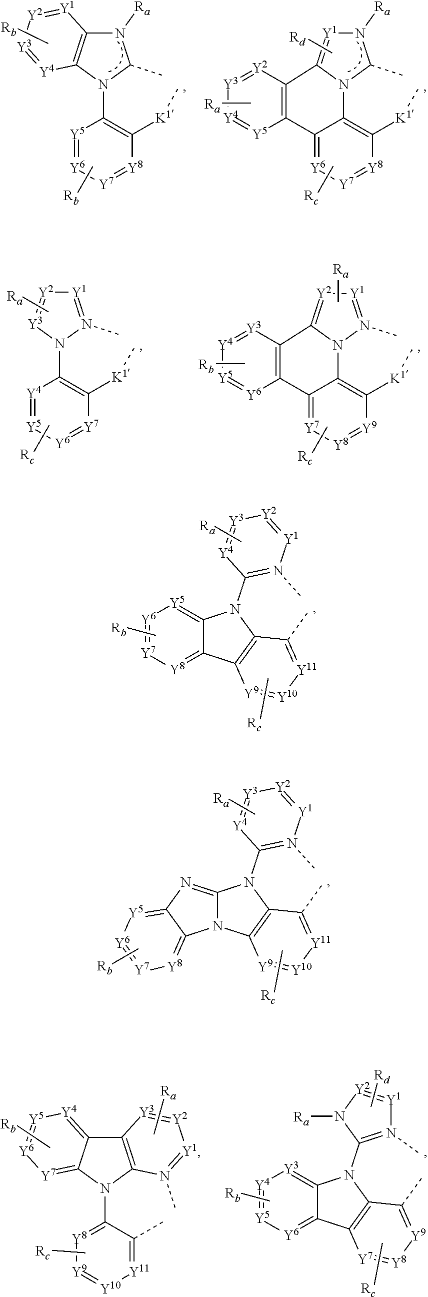 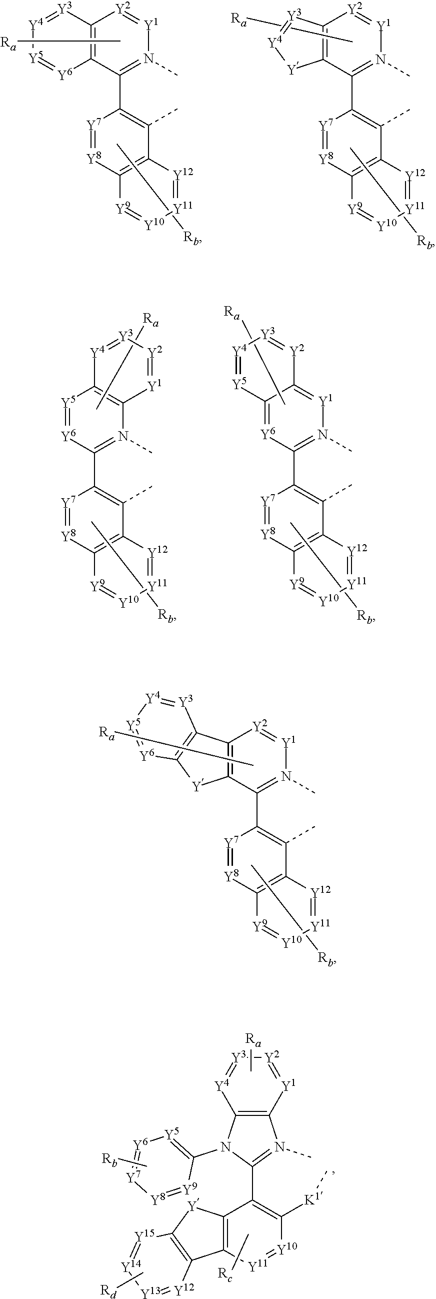 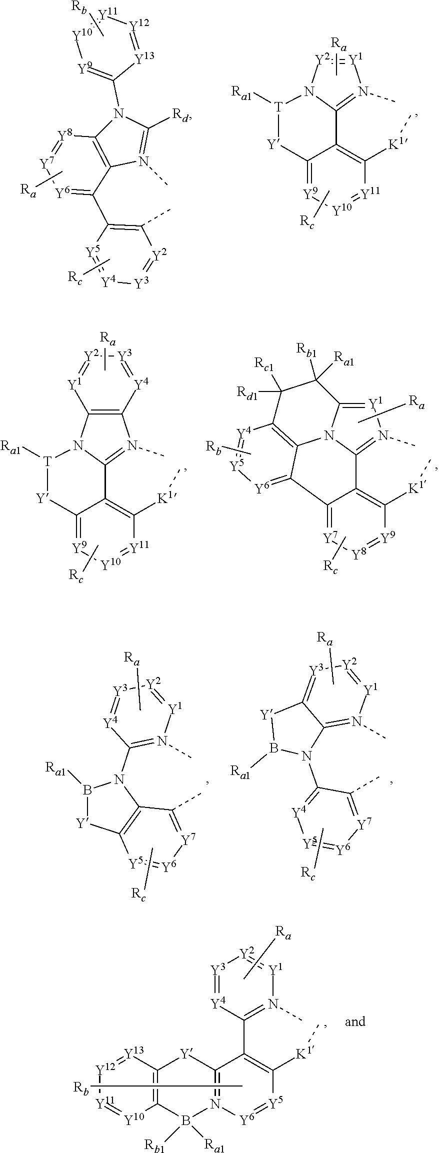 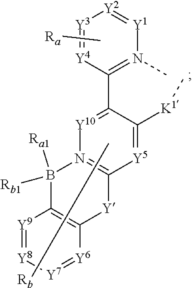 [0121] wherein T is selected from the group consisting of B, Al, Ga, and In;
wherein K^{1′} is a direct bond or is selected from the group consisting of NRₑ, PRₑ, O, S, and Se;
wherein each Y¹ to Y¹³ are independently selected from the group consisting of carbon and nitrogen;
wherein Y′ is selected from the group consisting of BRₑ, NRₑ, PRₑ, O, S, Se, C═O, S═O, SO₂, CRₑR_{f}, SiRₑR_{f}, and GeRₑR_{f};
wherein Rₑ and R_{f} can be fused or joined to form a ring;
wherein each Rₐ, R_{b}, R_{c}, and R_{d} can independently represent from mono to the maximum possible number of substitutions, or no substitution;
wherein each Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents as defined herein; and
wherein any two of Rₐ₁, R_{b1}, R_{c1}, R_{d1}, Rₐ, R_{b}, R_{c}, and R_{d} can be fused or joined to form a ring or form a multidentate ligand.

### LIST 9:

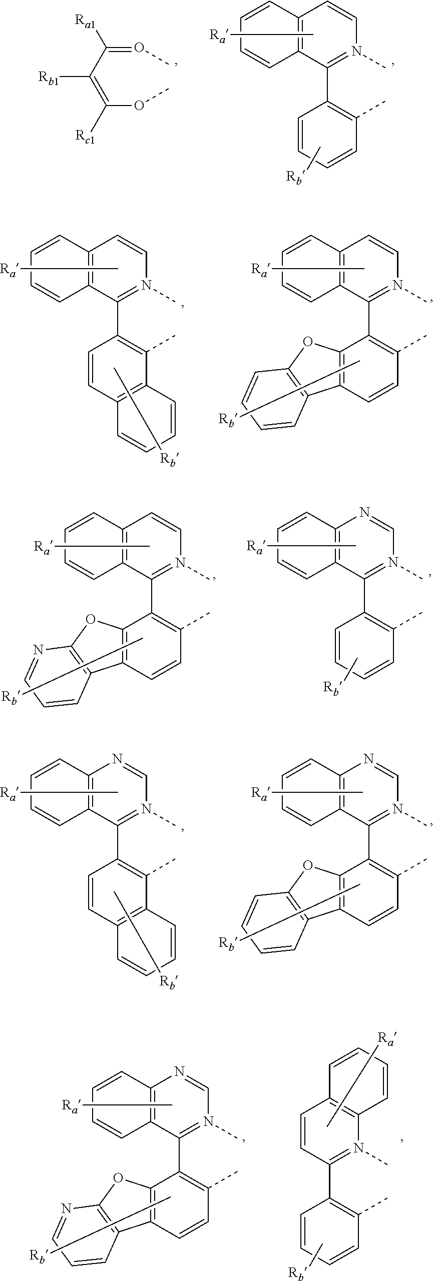 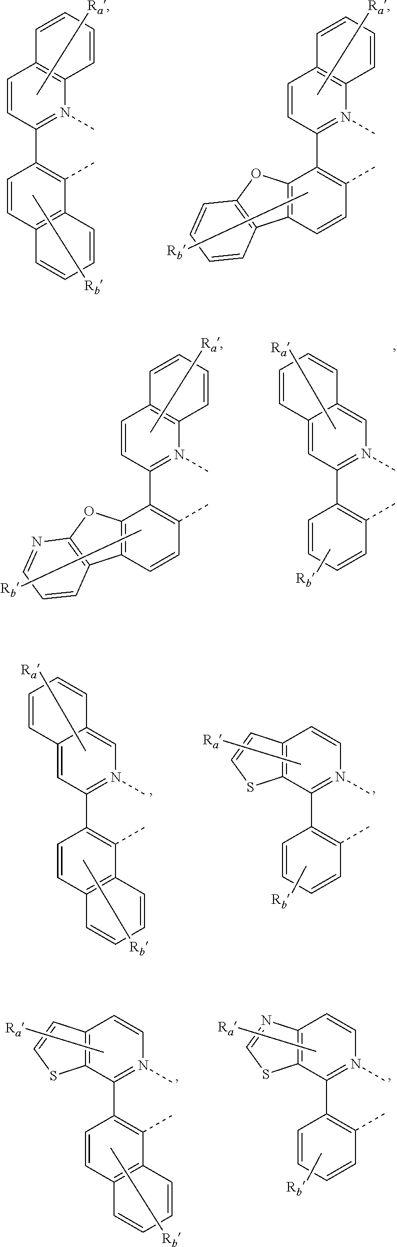 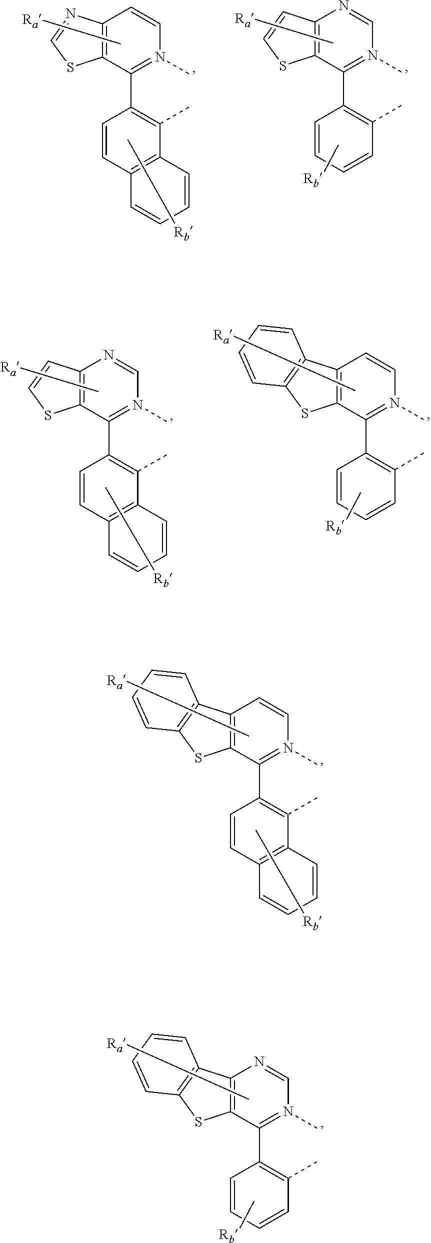 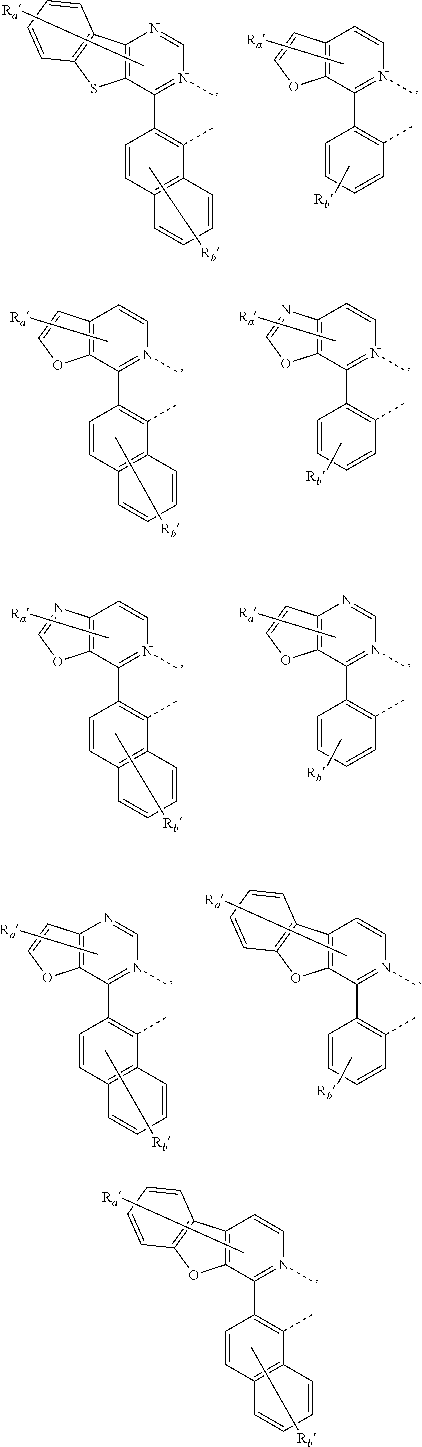 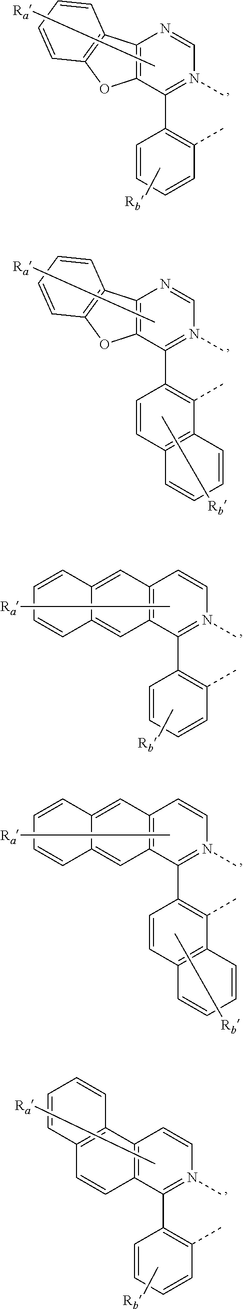 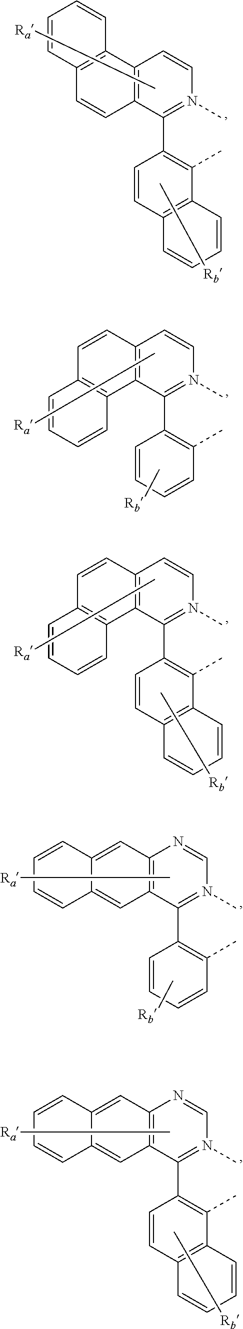 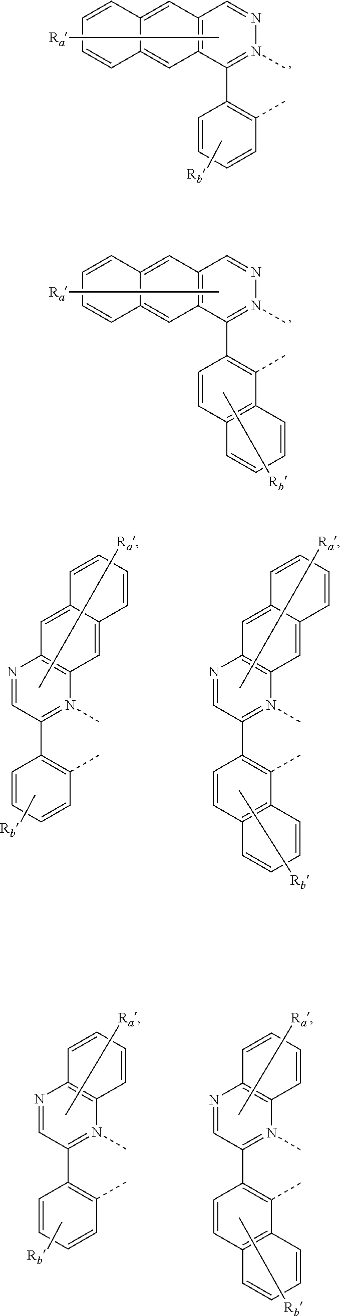 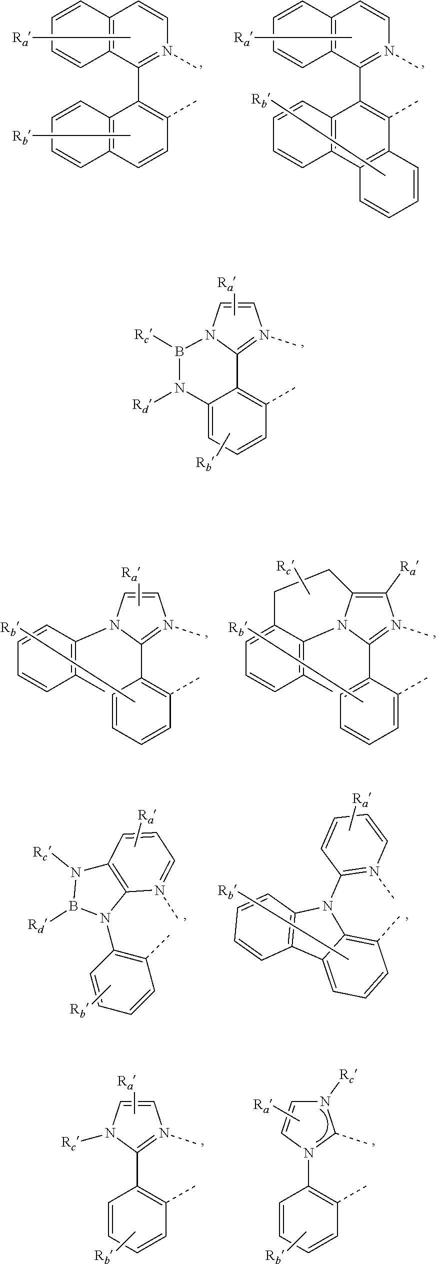 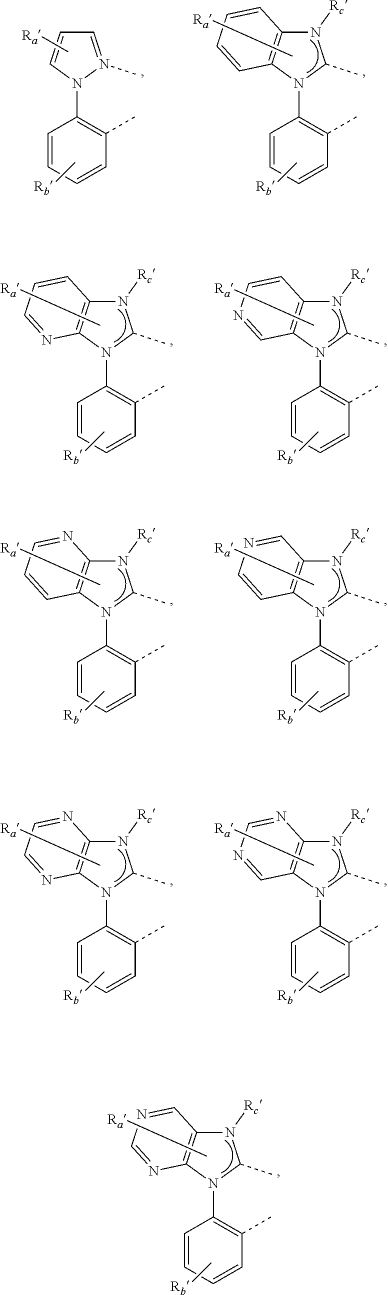 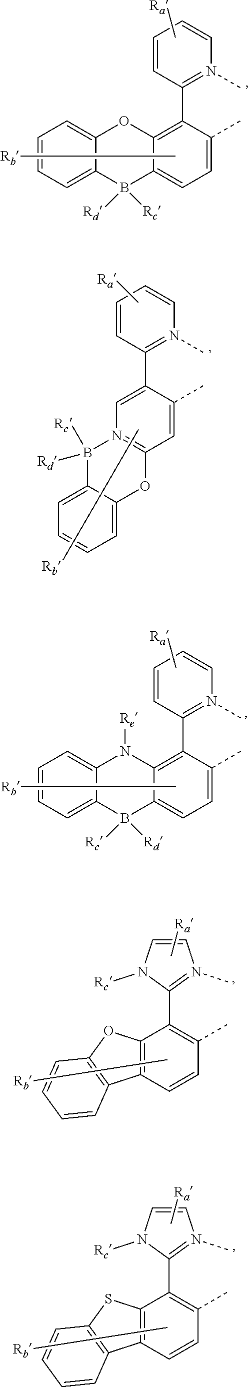 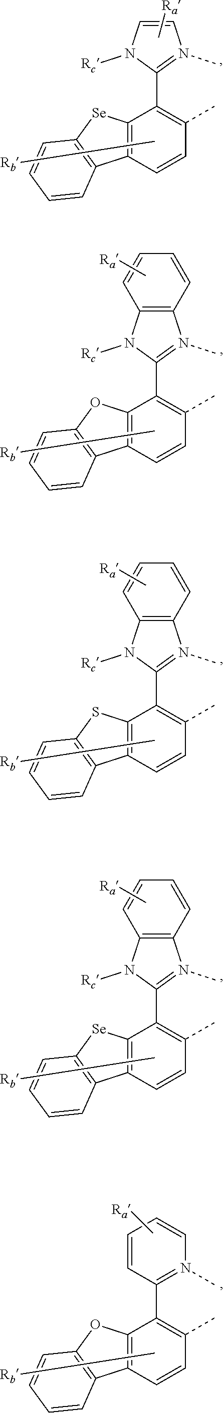 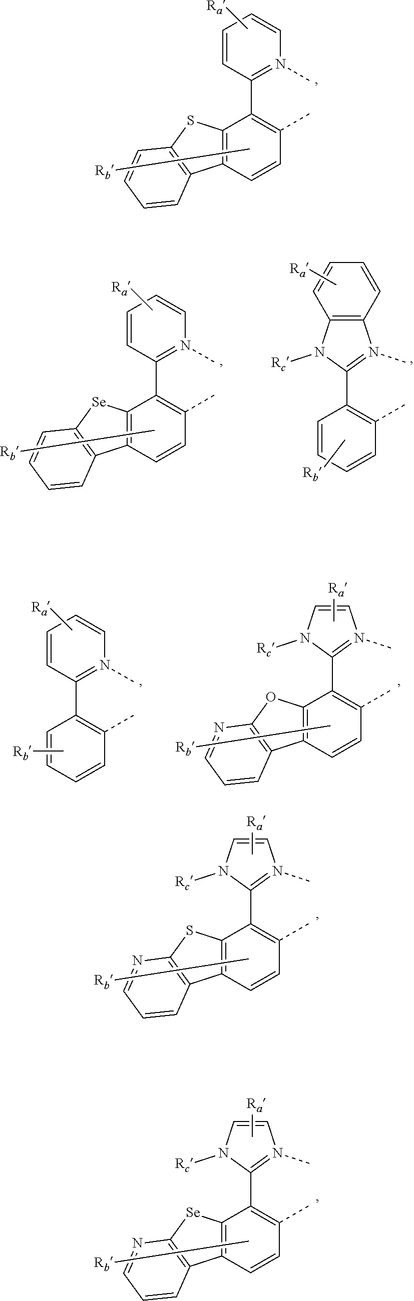 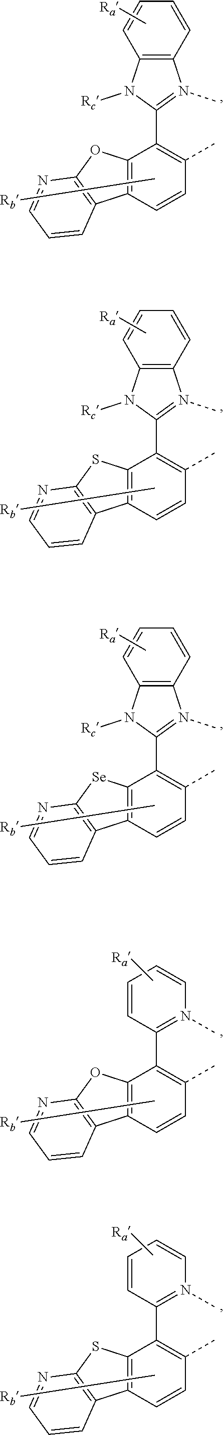 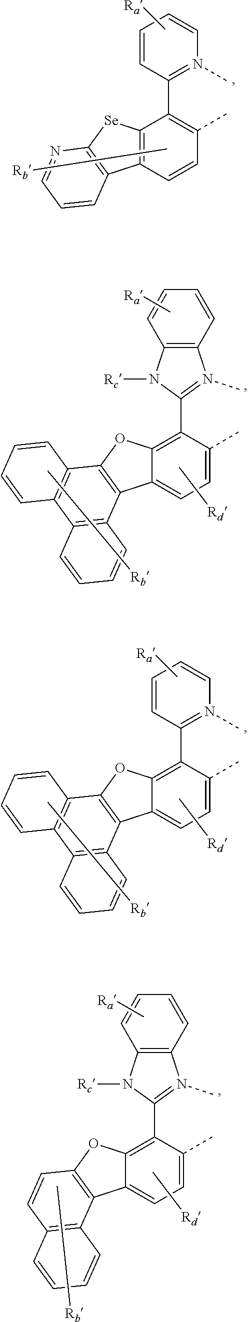 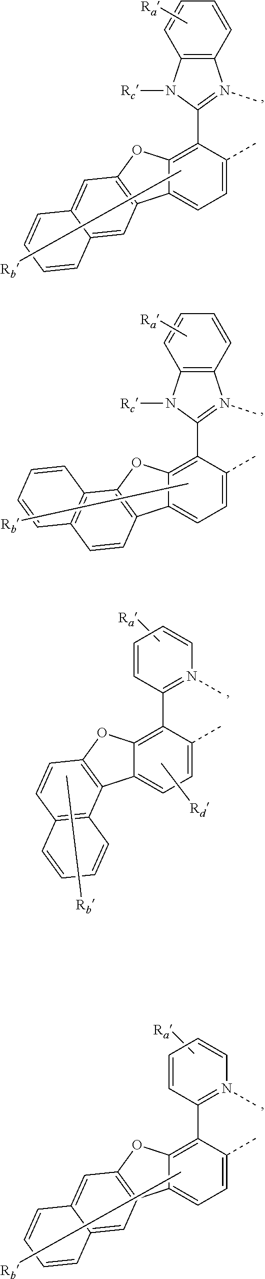 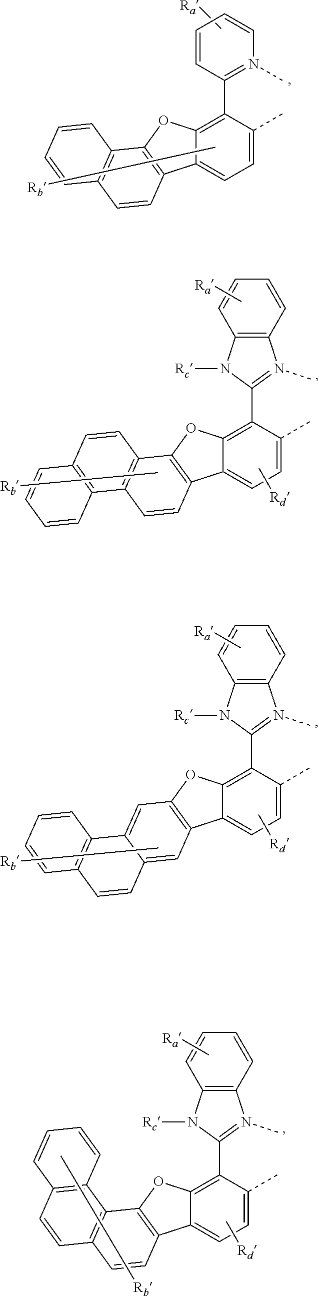 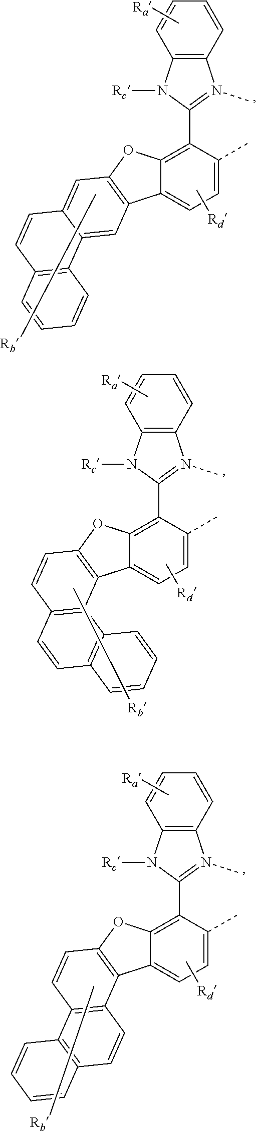 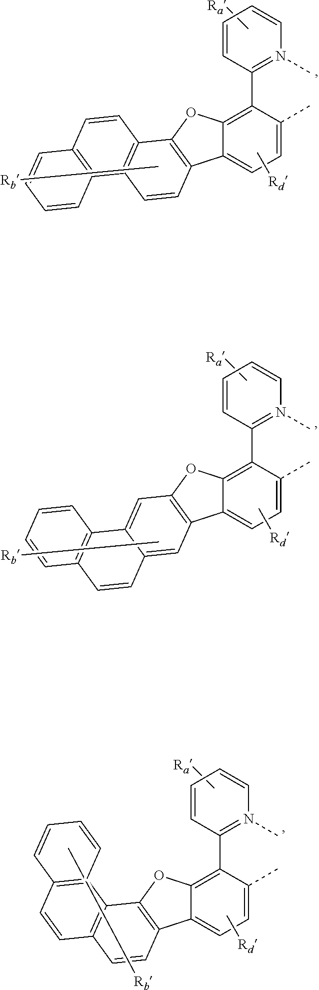 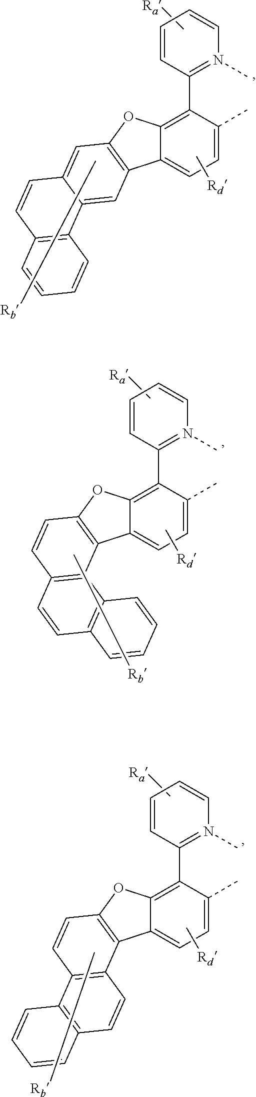 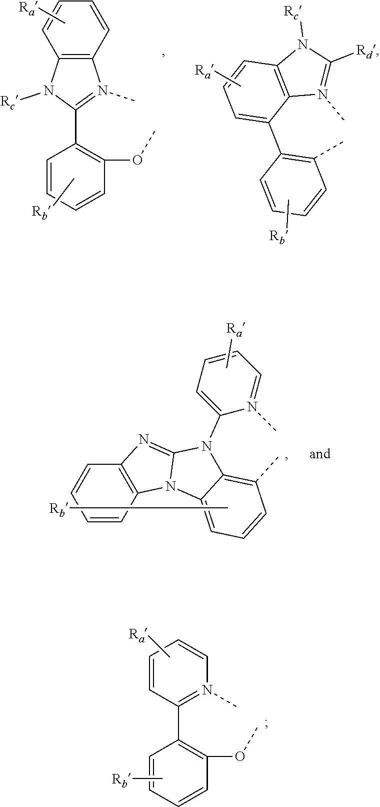 [0130] wherein Rₐ′, R_{b}′, R_{c}′, R_{d}′, and Rₑ′ each independently represent zero, mono, or up to a maximum allowed substitution to its associated ring;
wherein Rₐ′, R_{b}′, R_{c}′, R_{d}′, and Rₑ′ each independently hydrogen or a substituent selected from the group consisting of the General Substituents as defined herein; and
wherein two of Rₐ₁, R_{b1}, R_{c1}, Rₐ′, R_{b}′, R_{c}′, R_{d}′, and Rₑ′ can be fused or joined to form a ring or form a multidentate ligand.

In some embodiments, the compound has a formula selected from the group consisting of Formula Ir(L_{A})₃, Formula Ir(L_{A})(L_{Bk})₂, Formula Ir(L_{A})₂(L_{Bk}), Formula Ir(L_{A})₂(L_{Cj-I}), and Formula Ir(L_{A})₂(L_{Cj-II}),
wherein the structures of each L_{A} is selected from any L_{A} described herein;
wherein k is an integer from 1 to 474;
wherein j is an integer from 1 to 1416;
wherein each L_{Bk} has the structure defined in the following LIST 10:

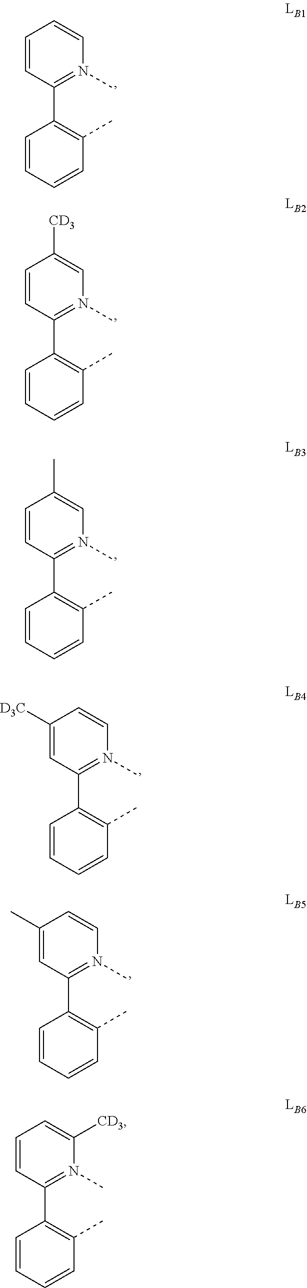

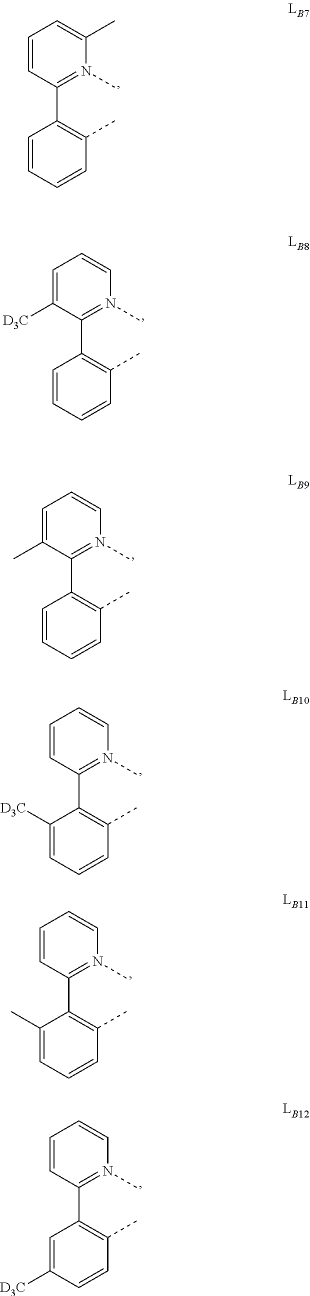

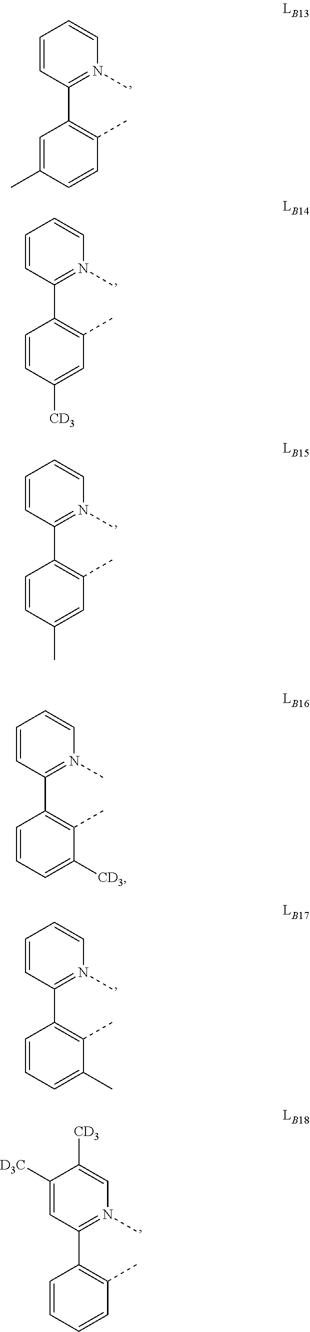

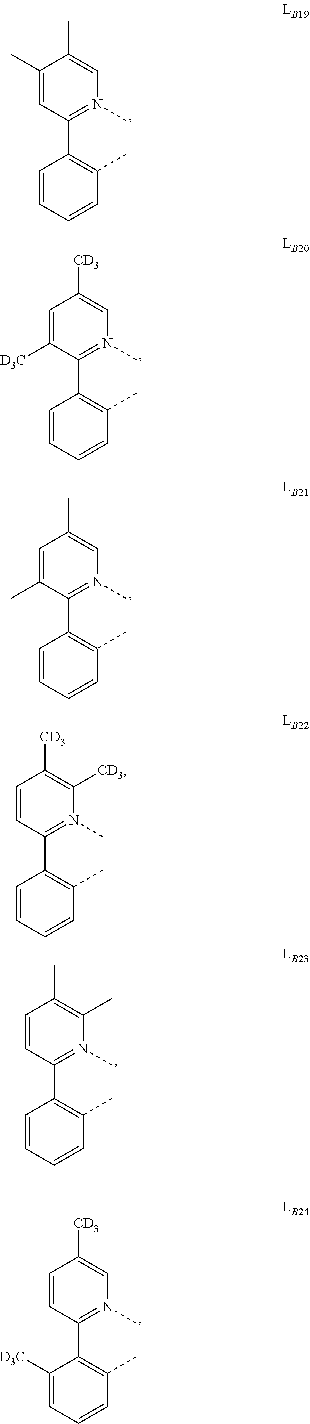

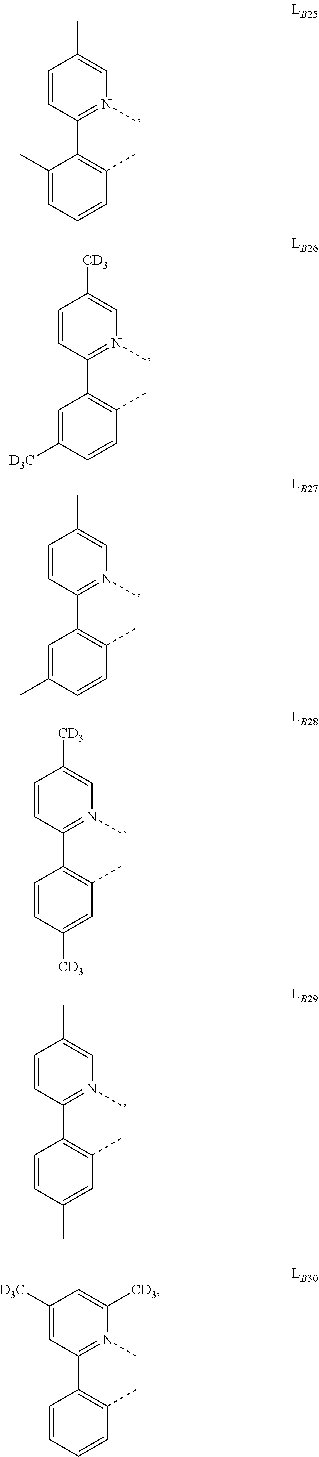

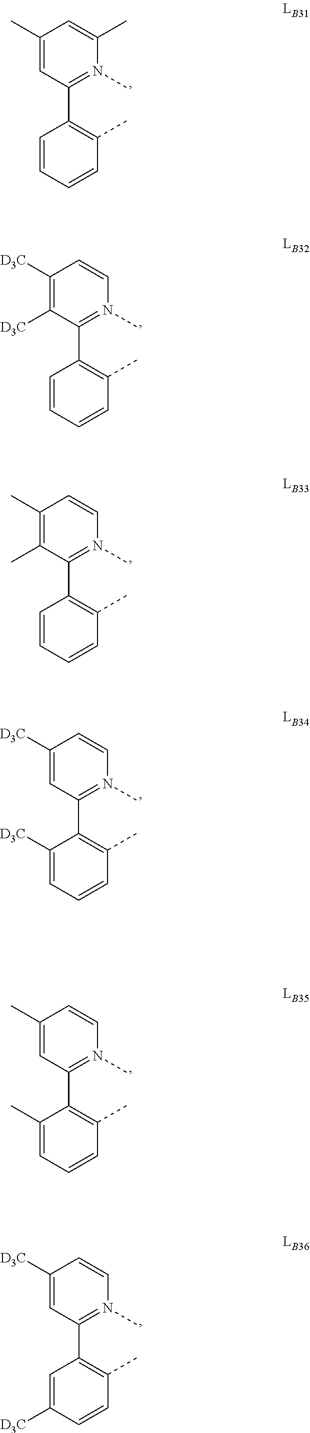

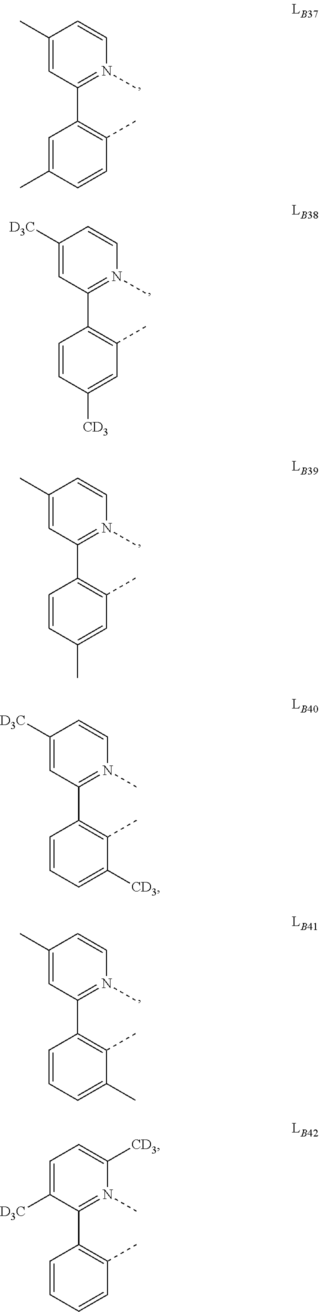

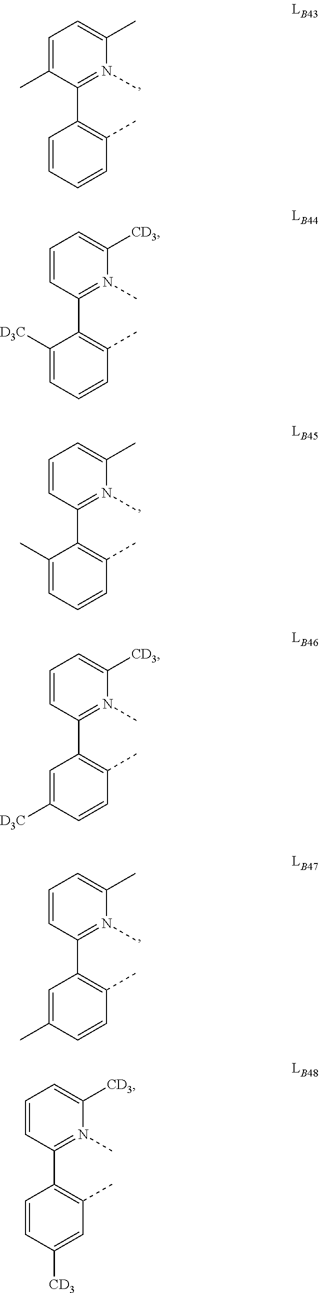

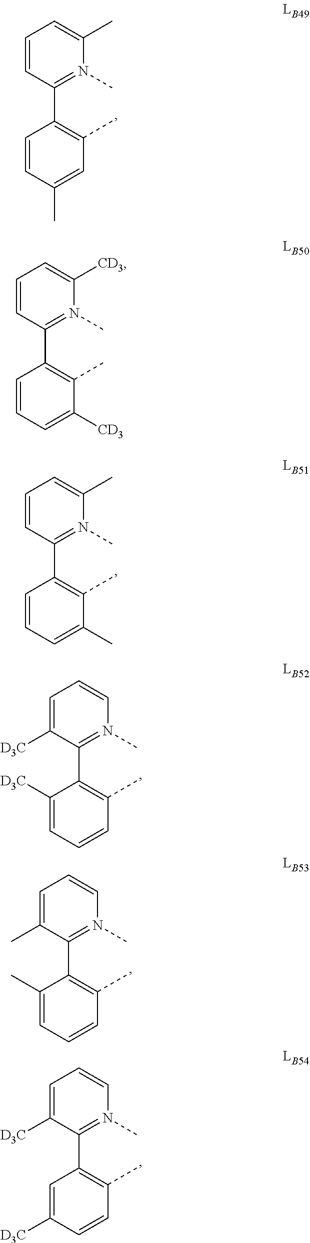

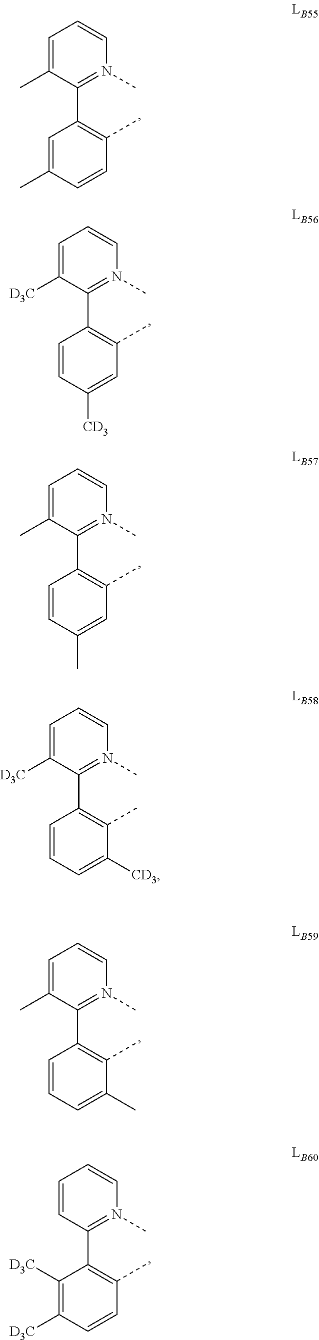

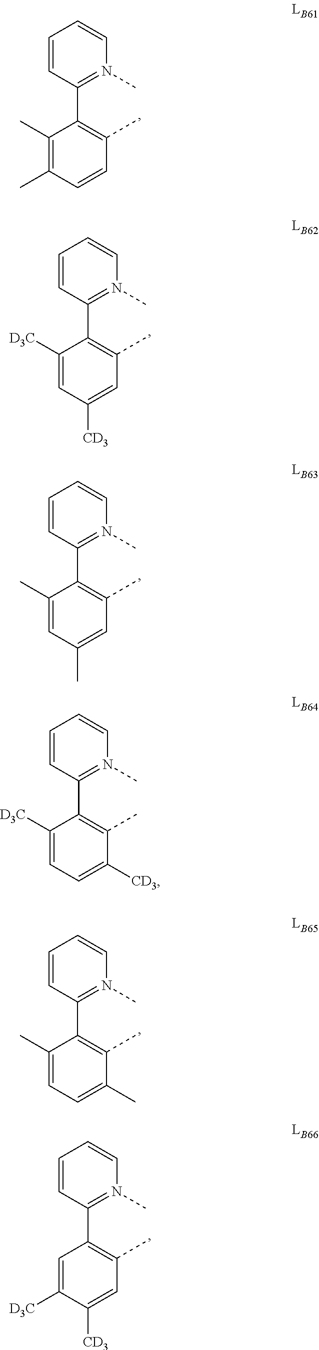

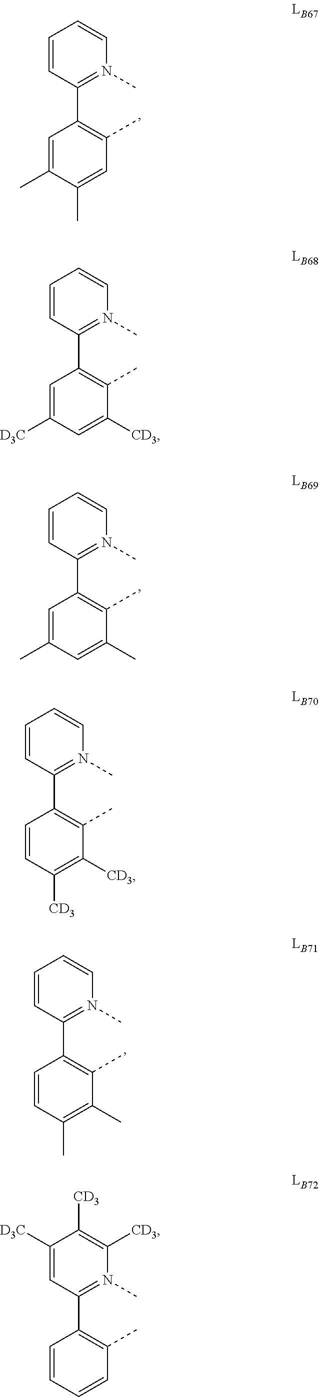

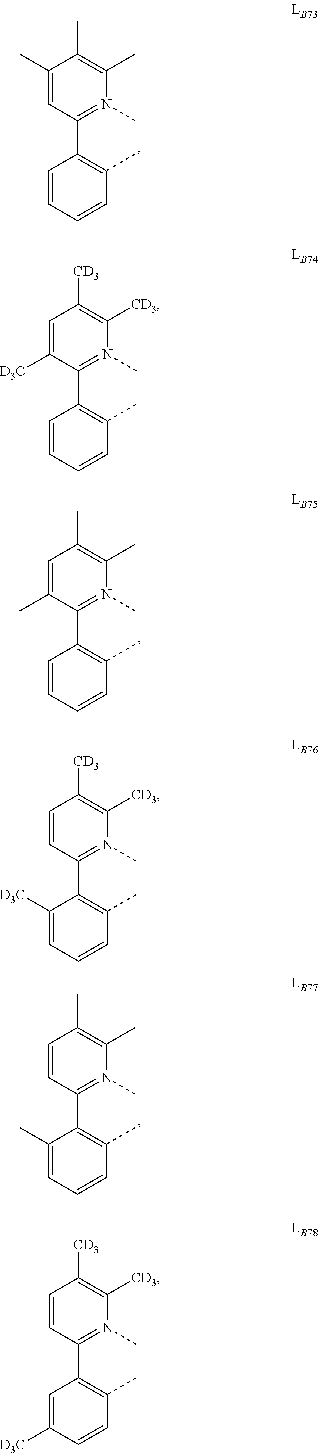

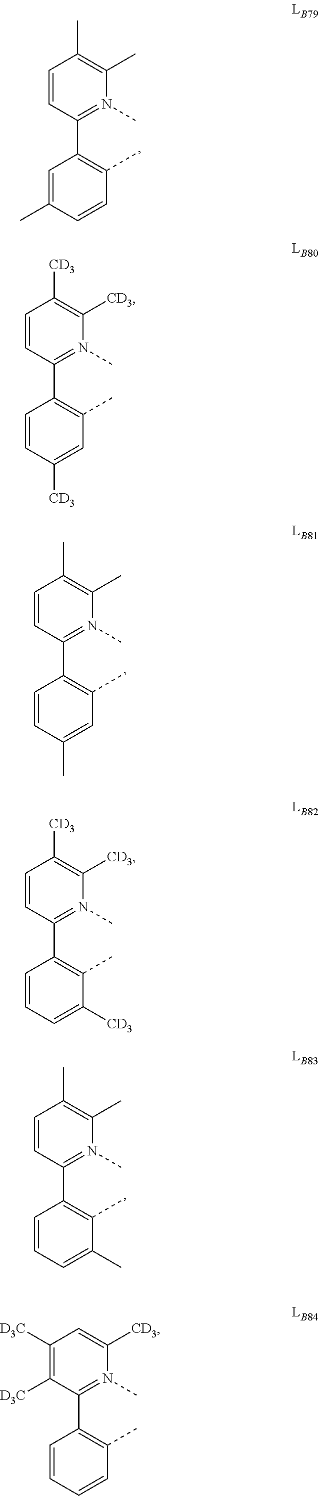

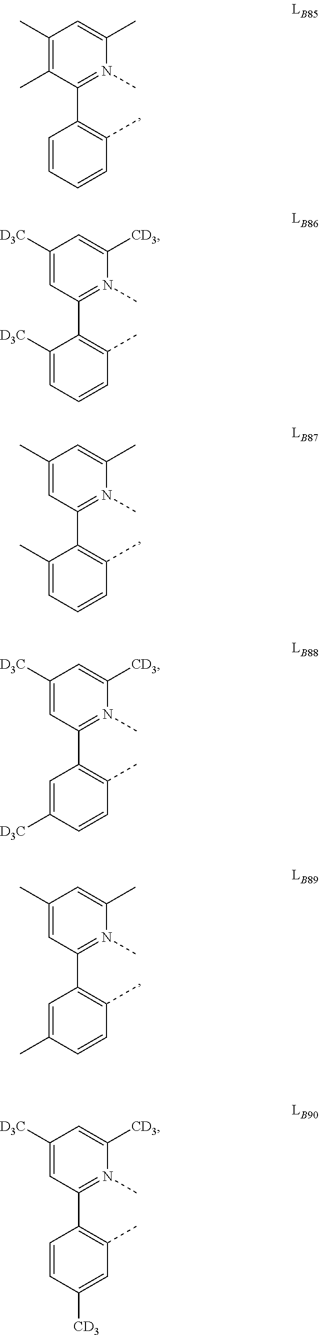

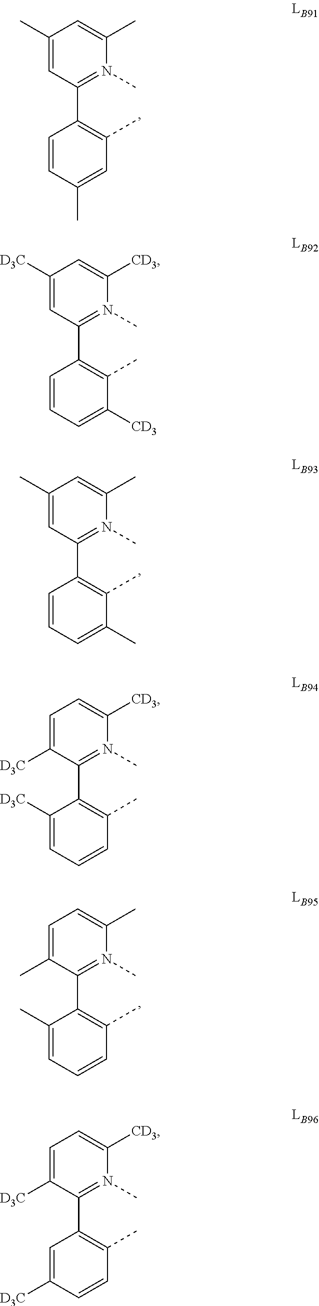

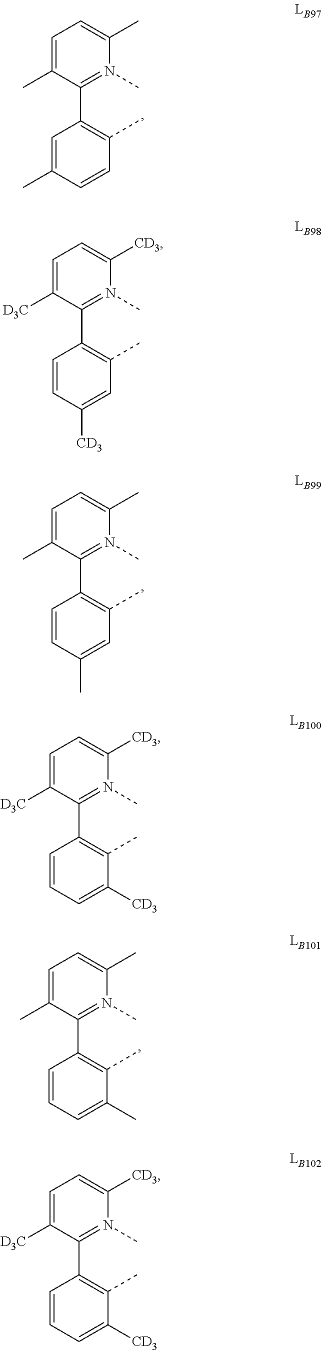

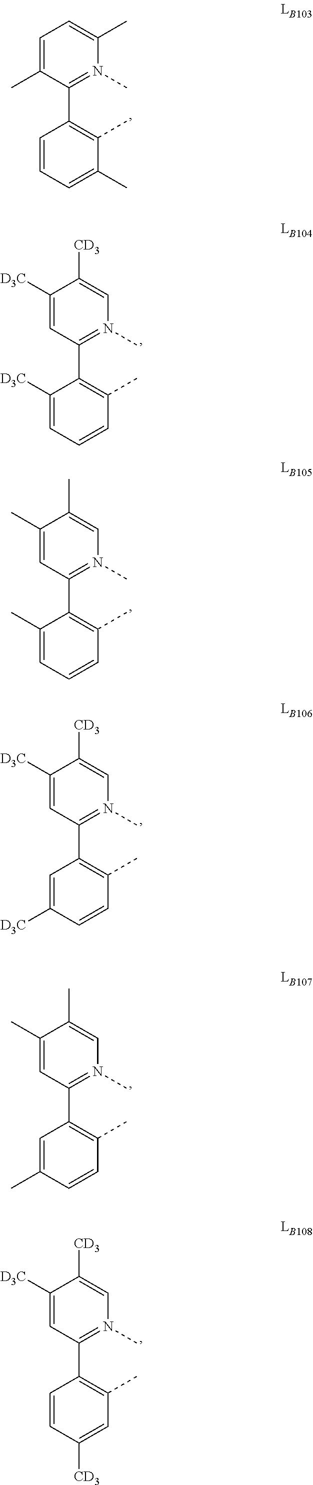

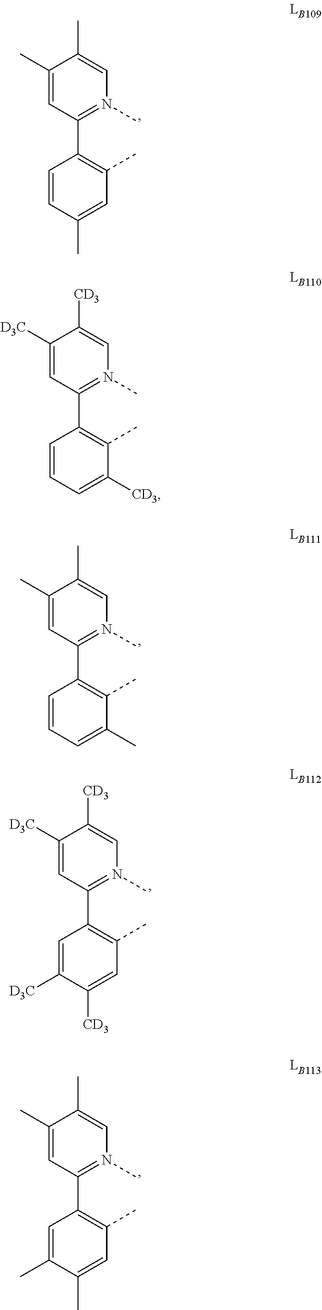

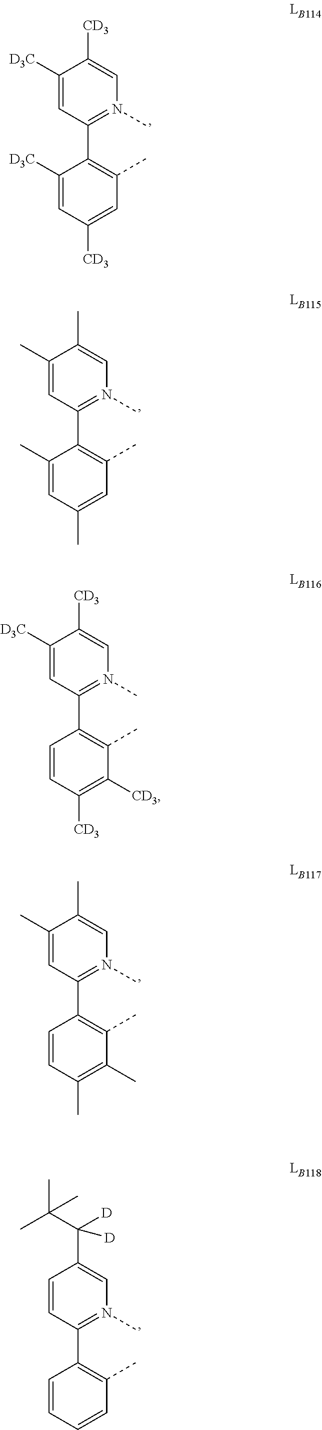

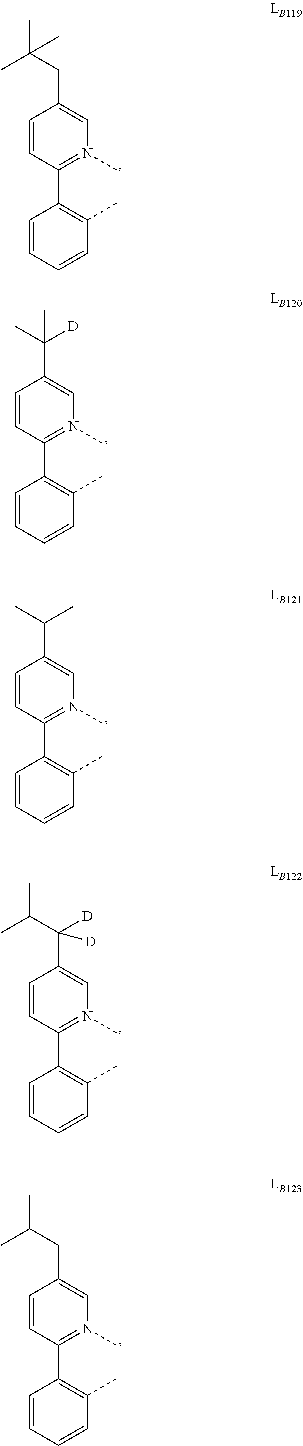

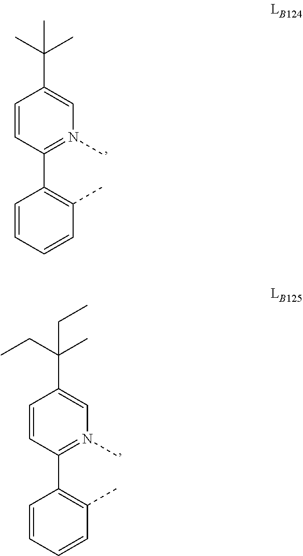

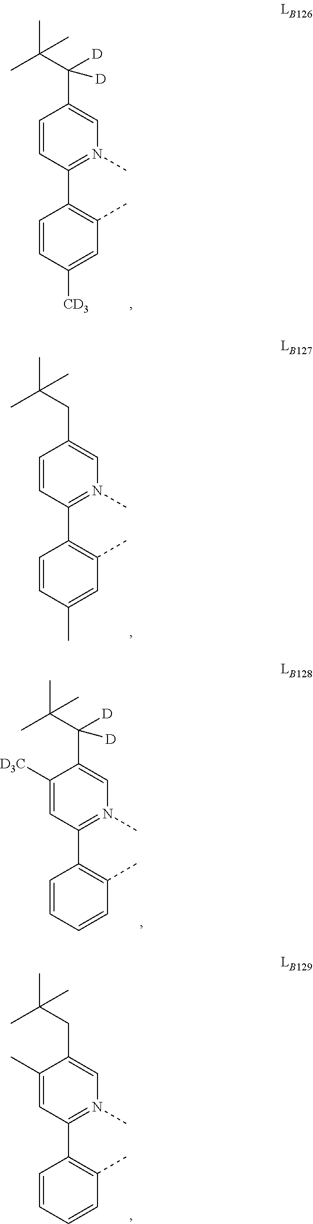

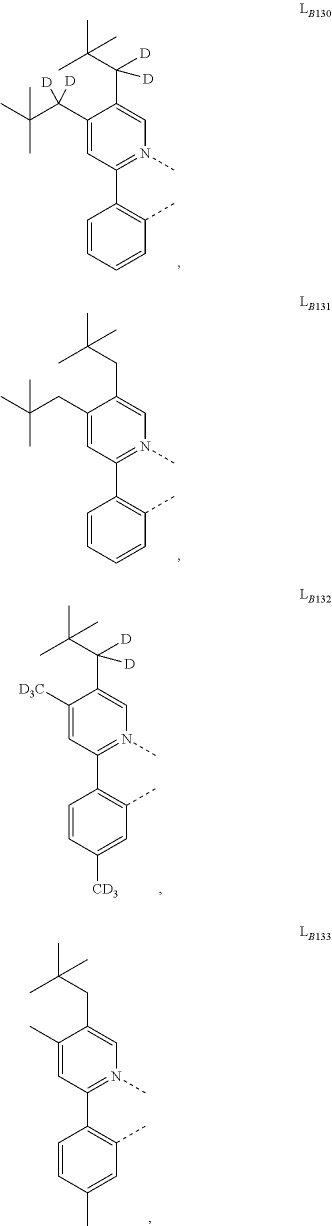

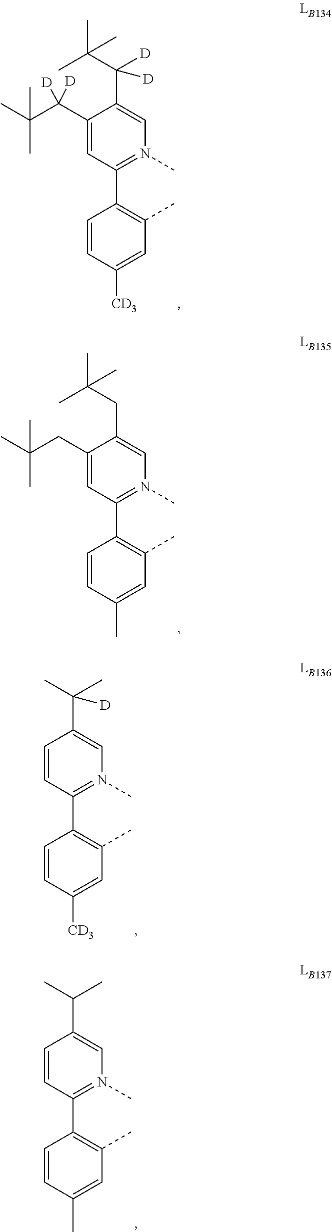

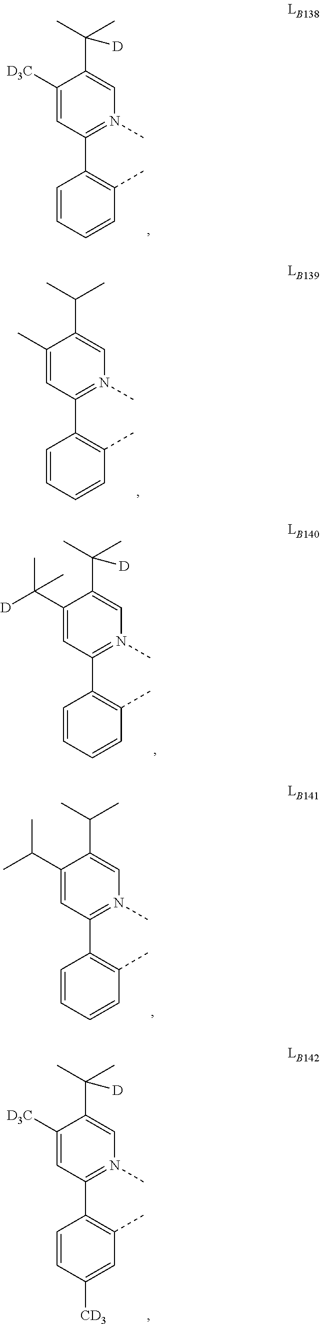

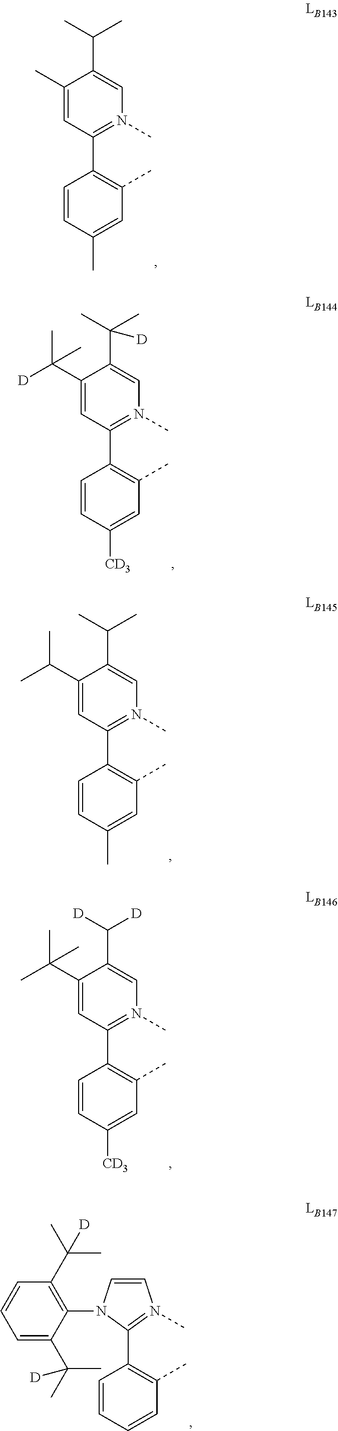

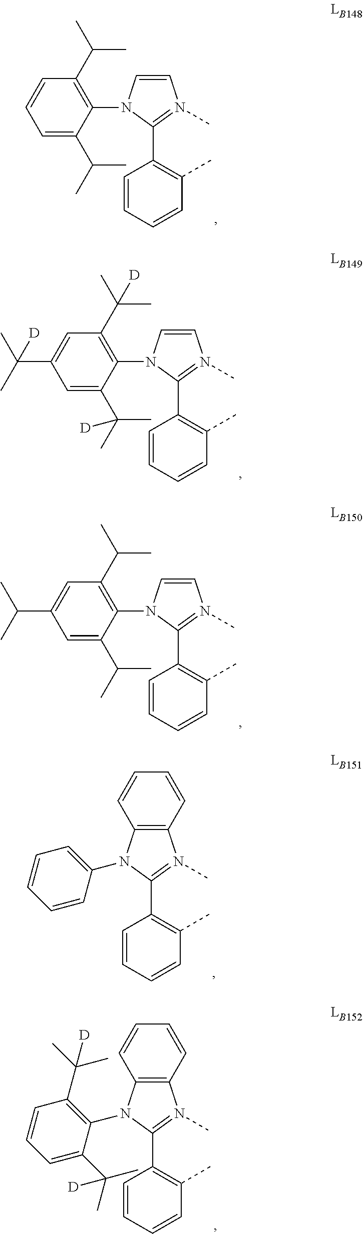

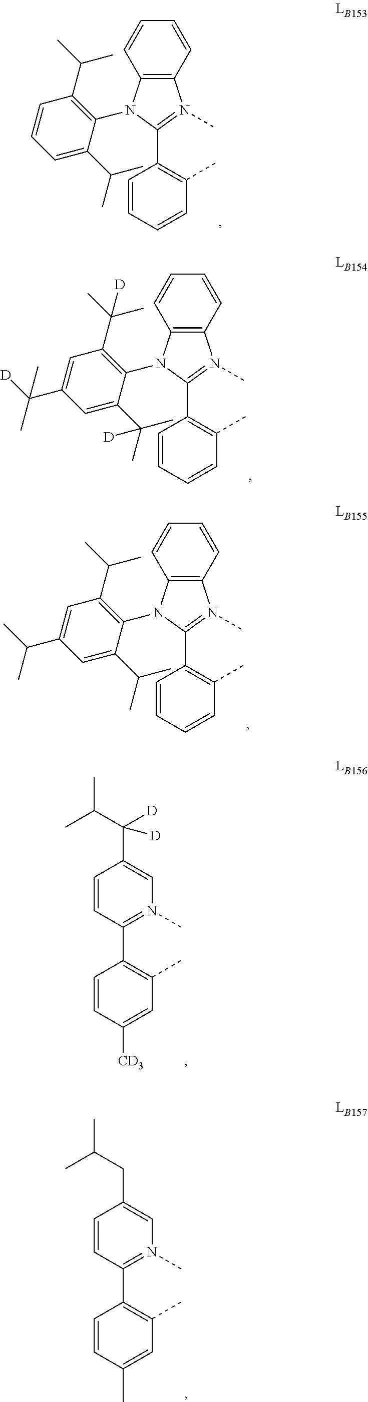

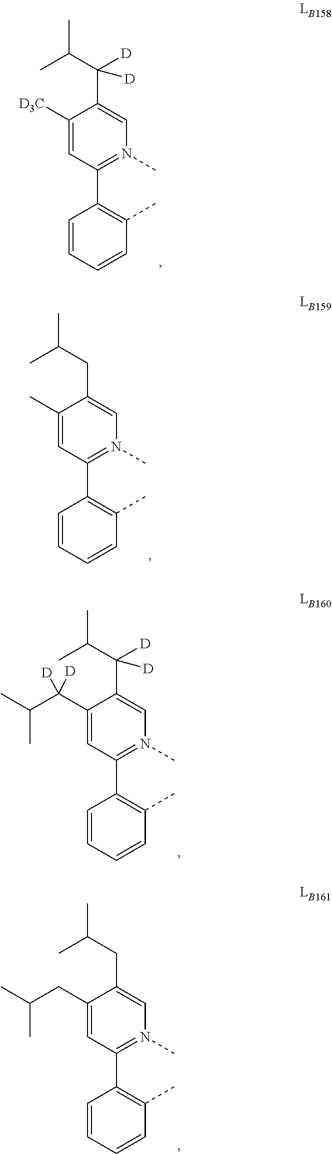

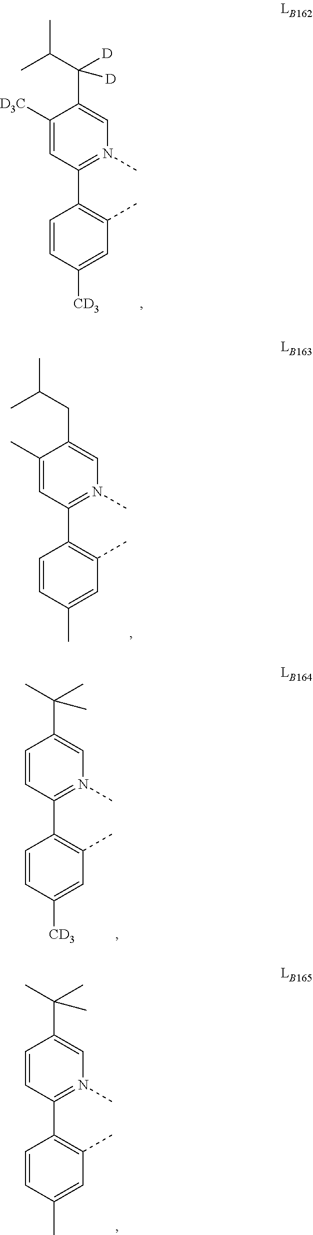

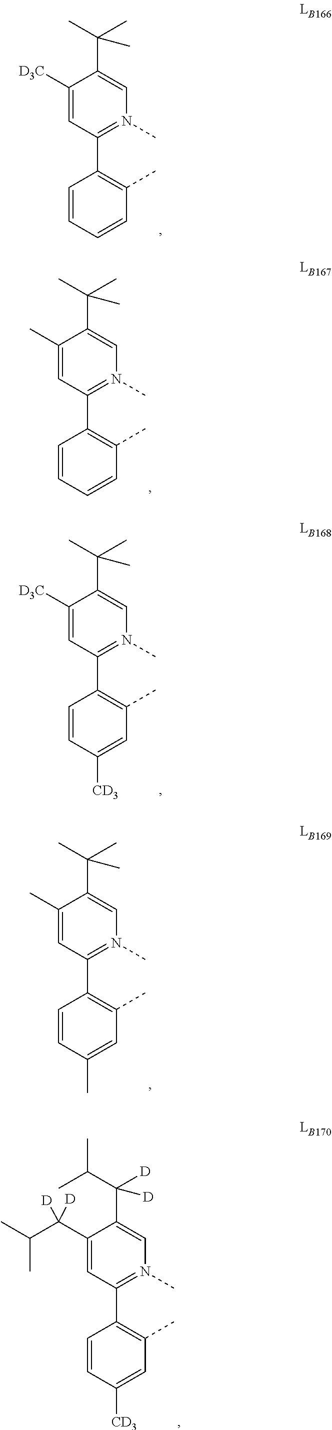

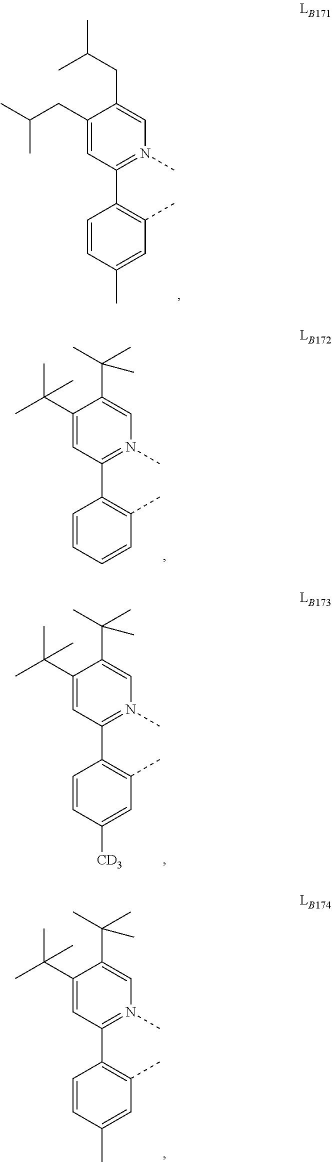

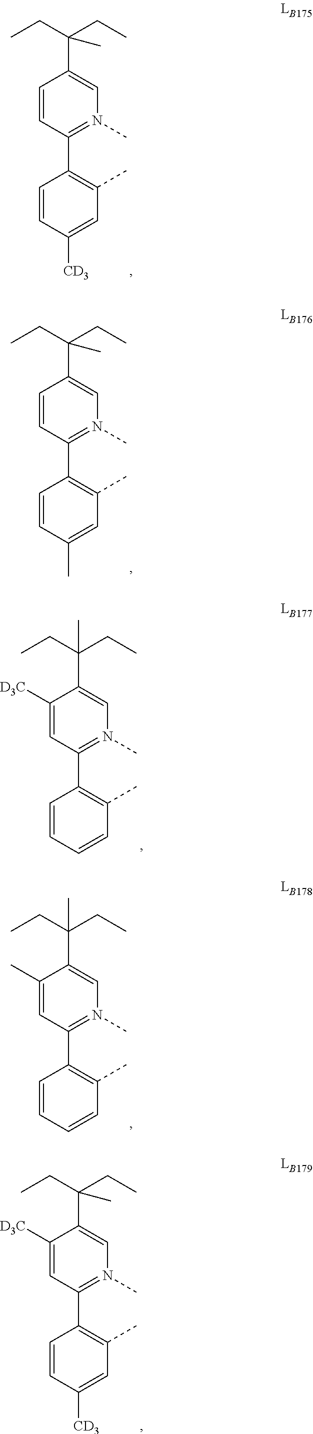

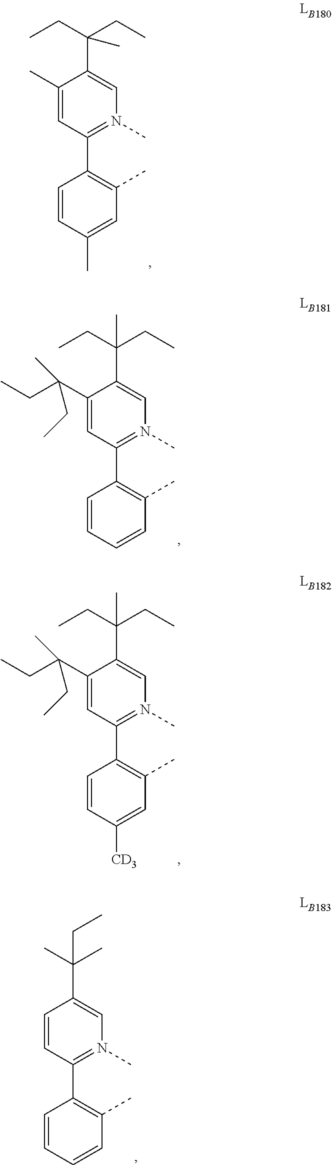

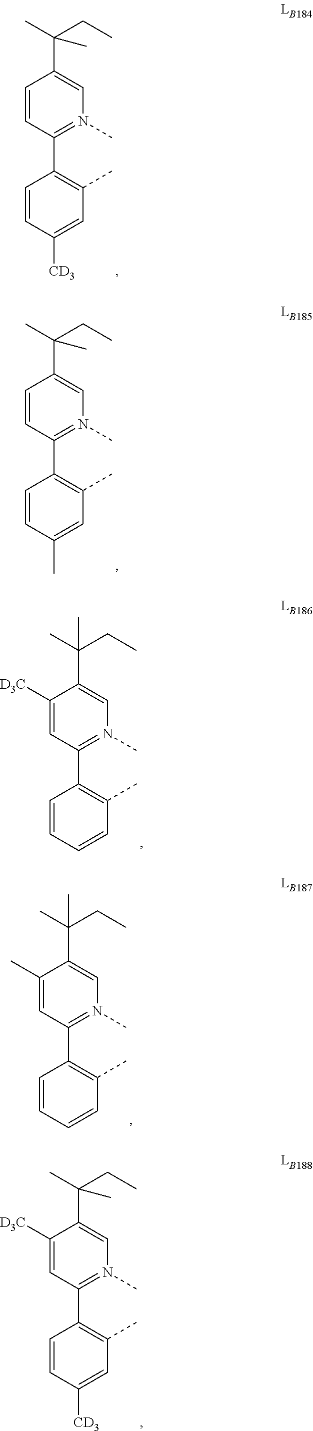

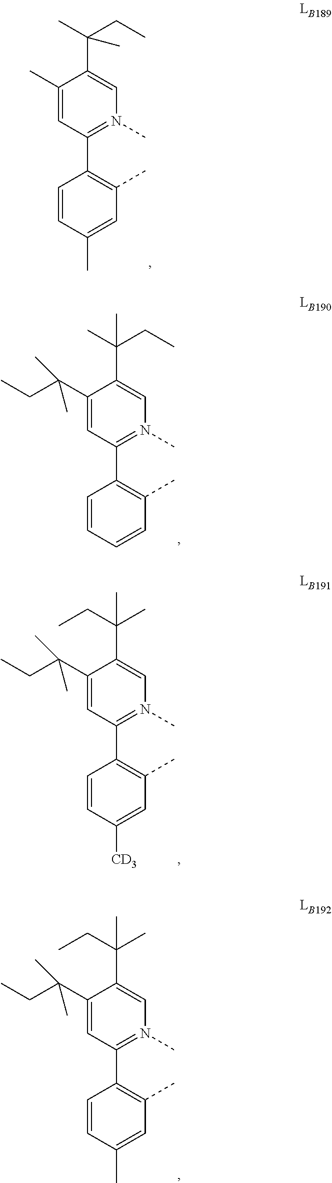

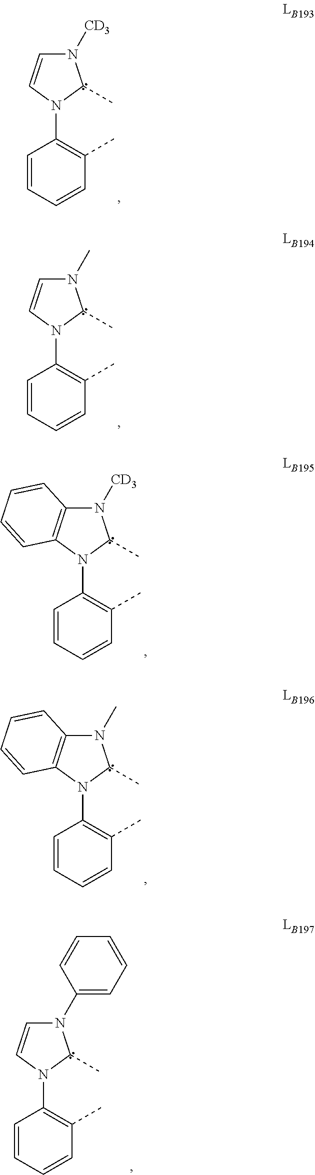

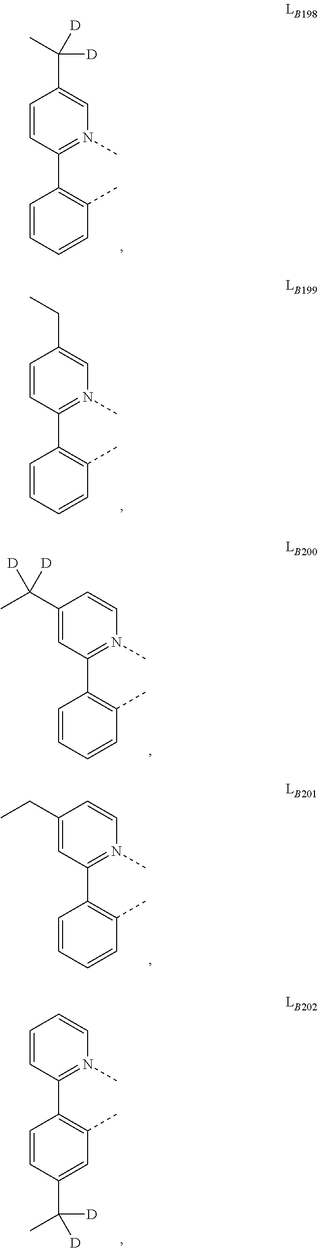

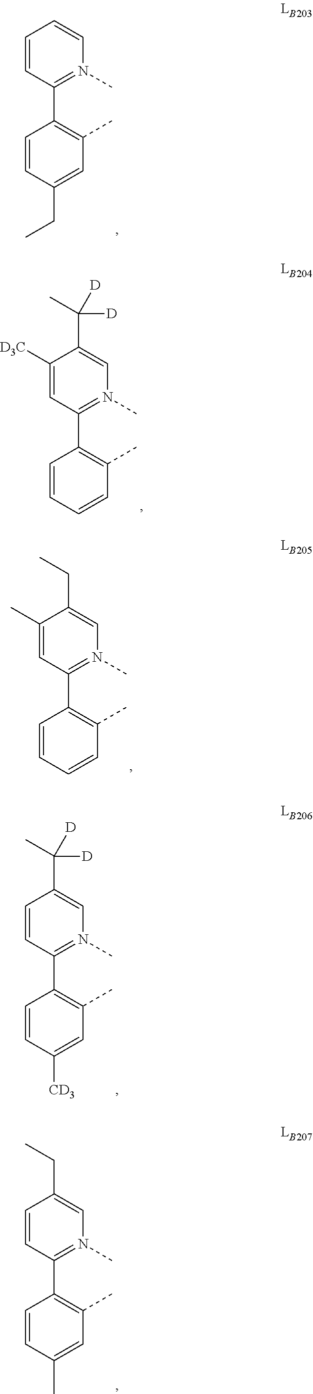

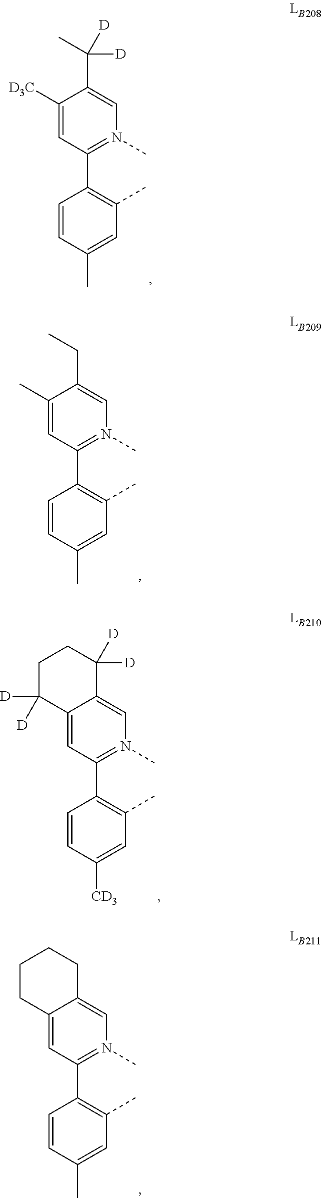

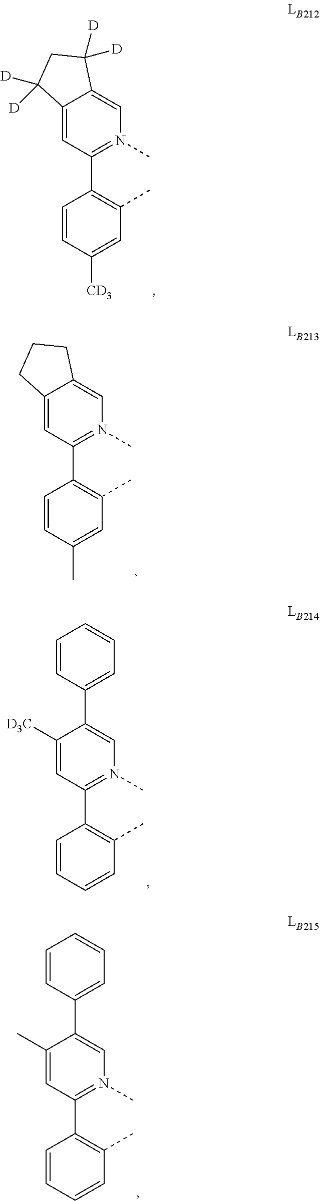

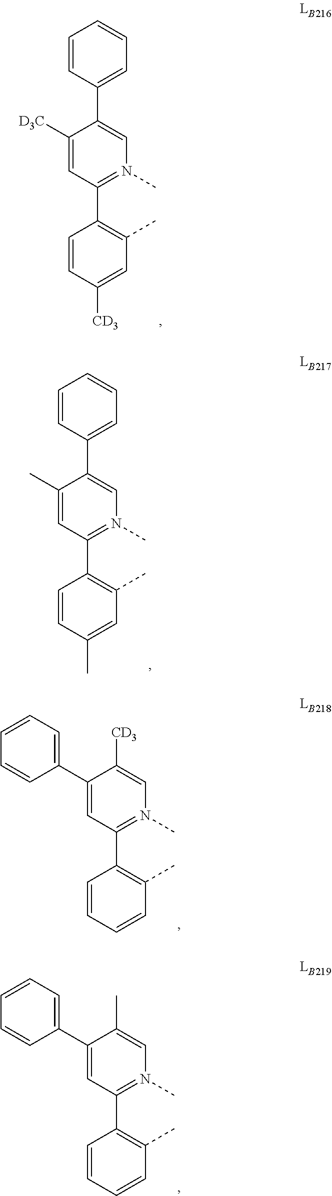

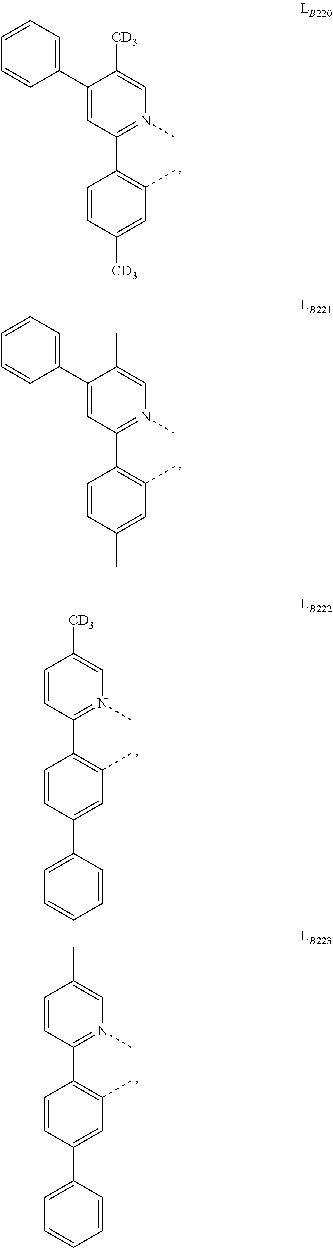

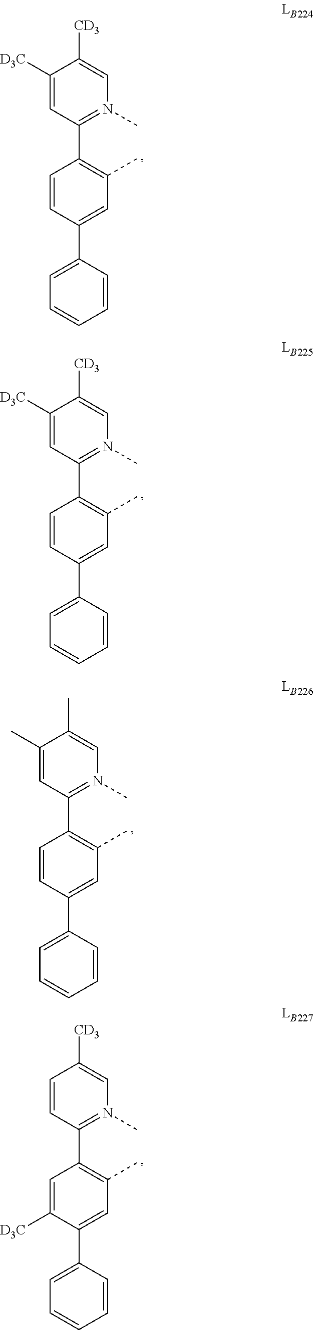

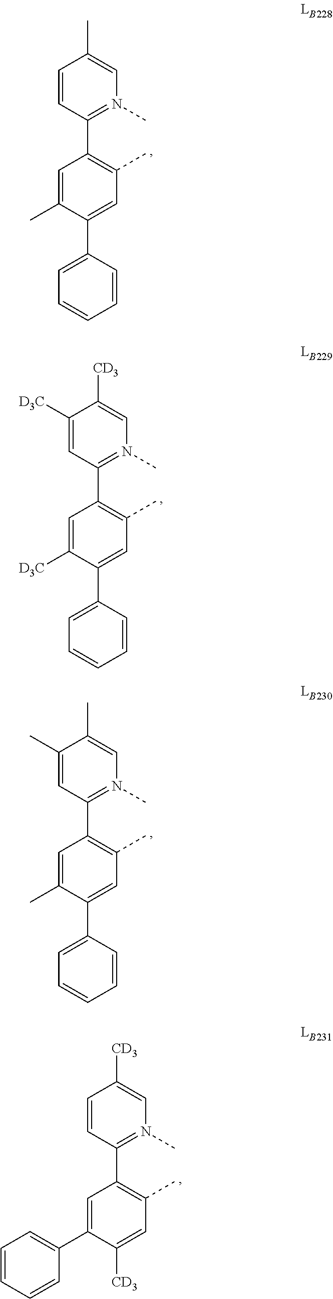

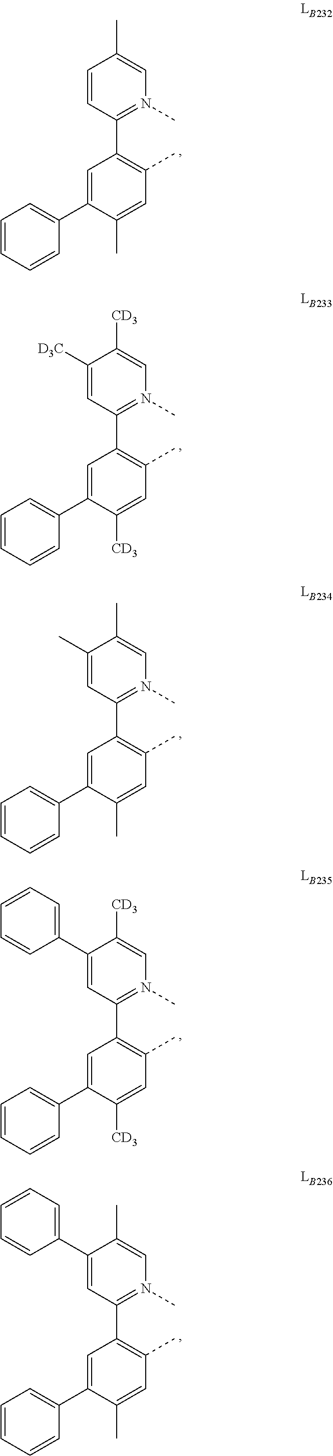

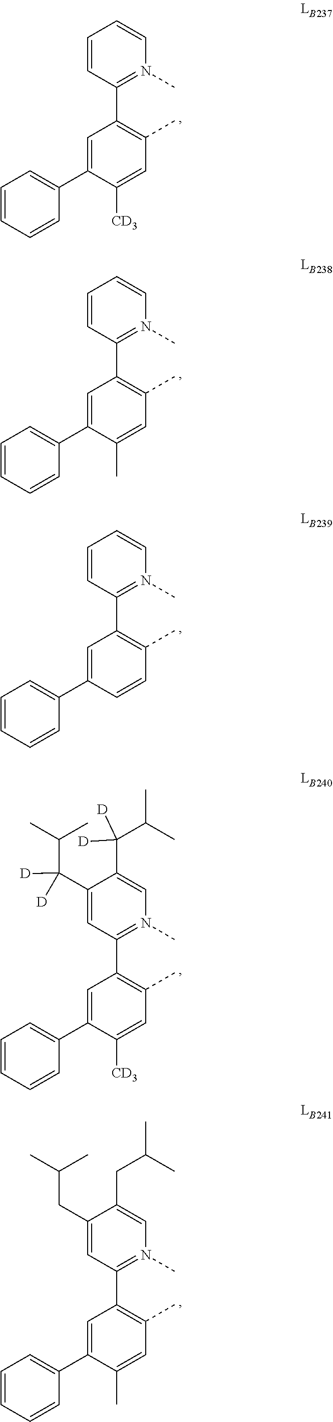

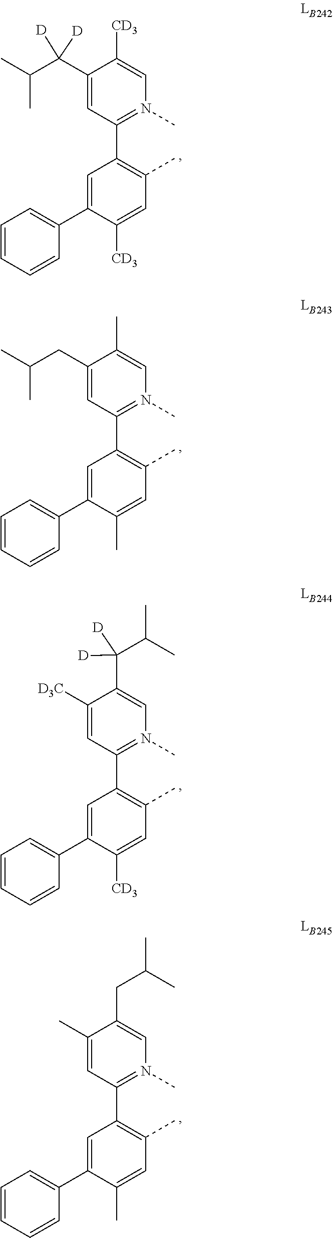

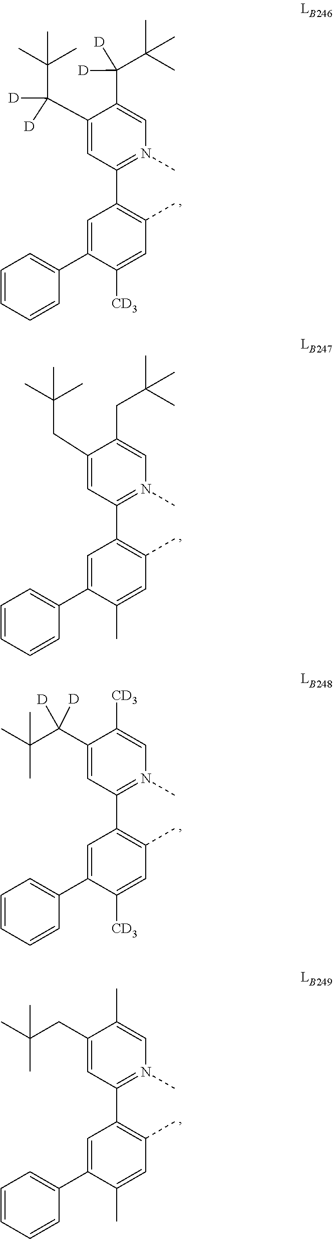

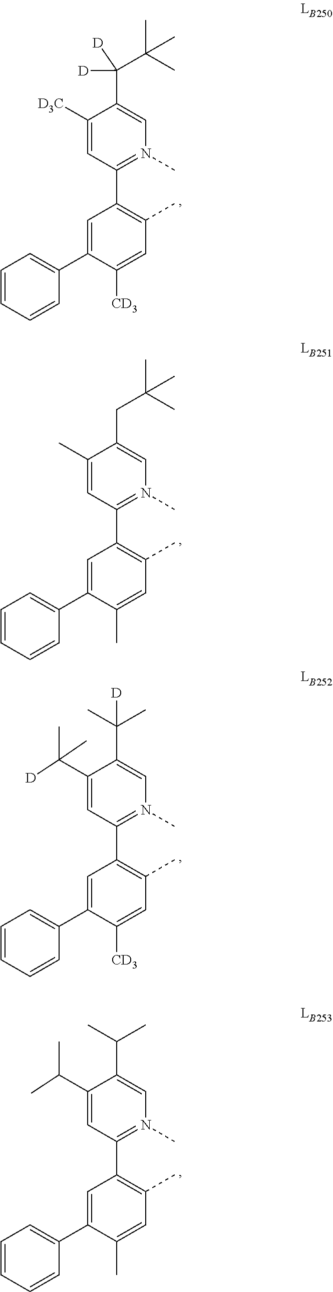

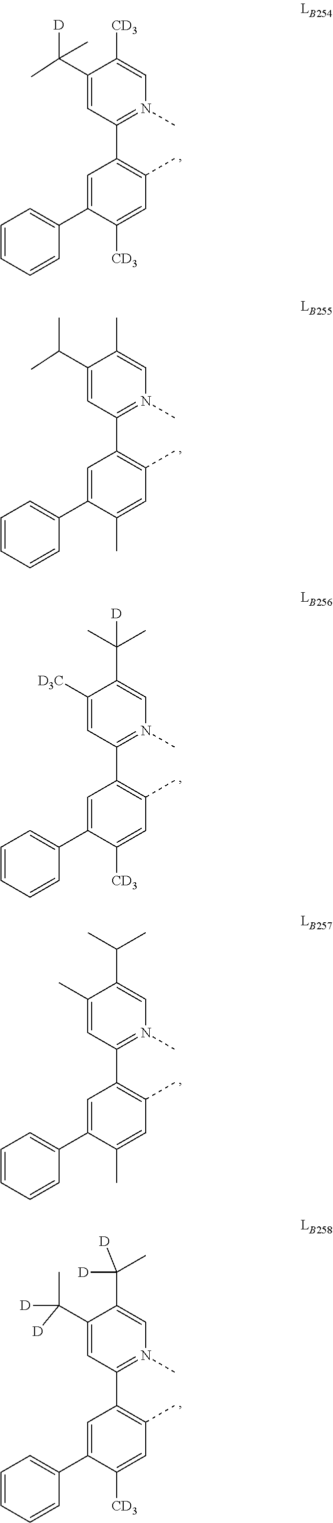

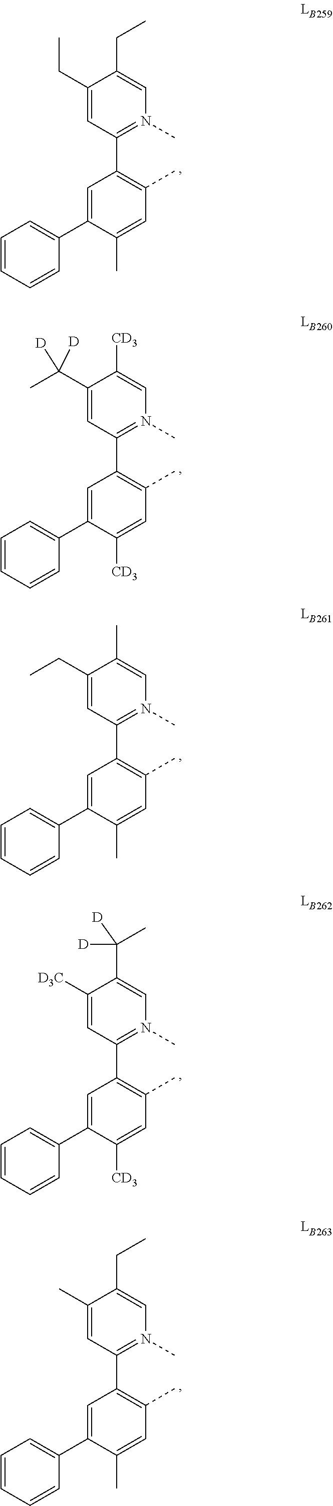

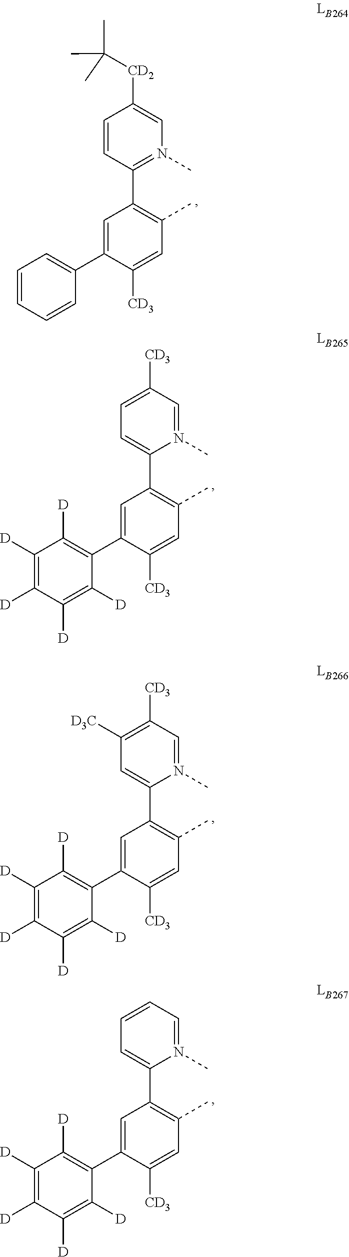

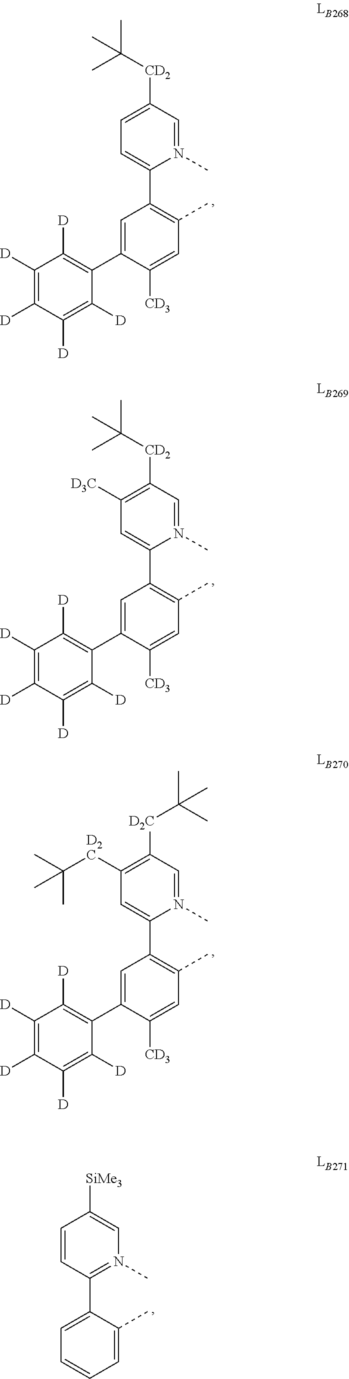

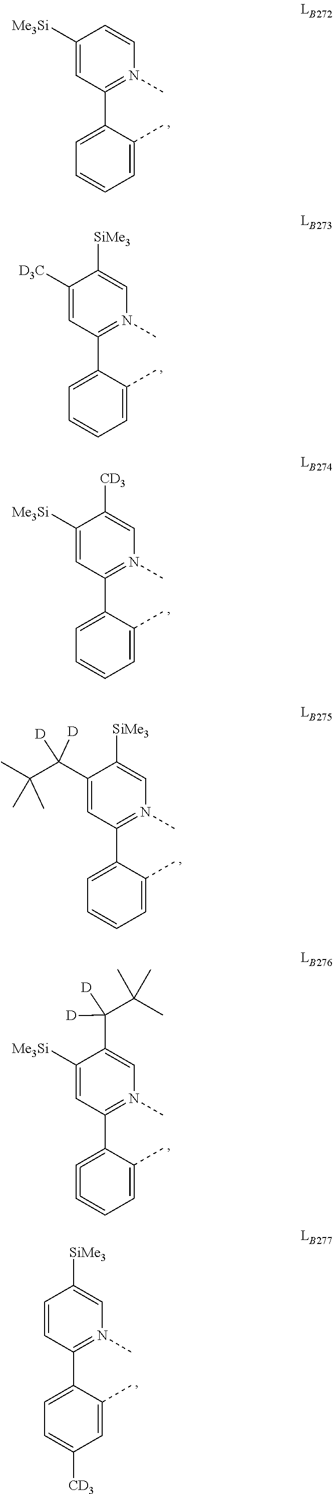

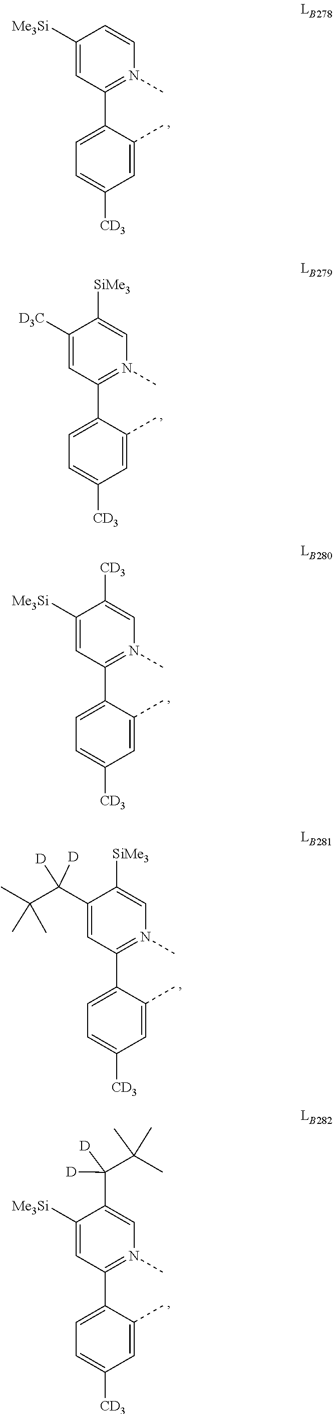

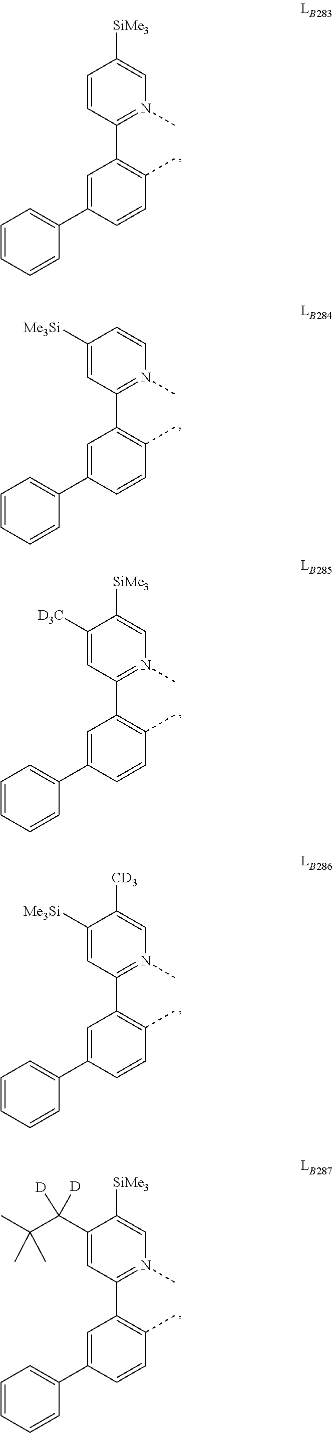

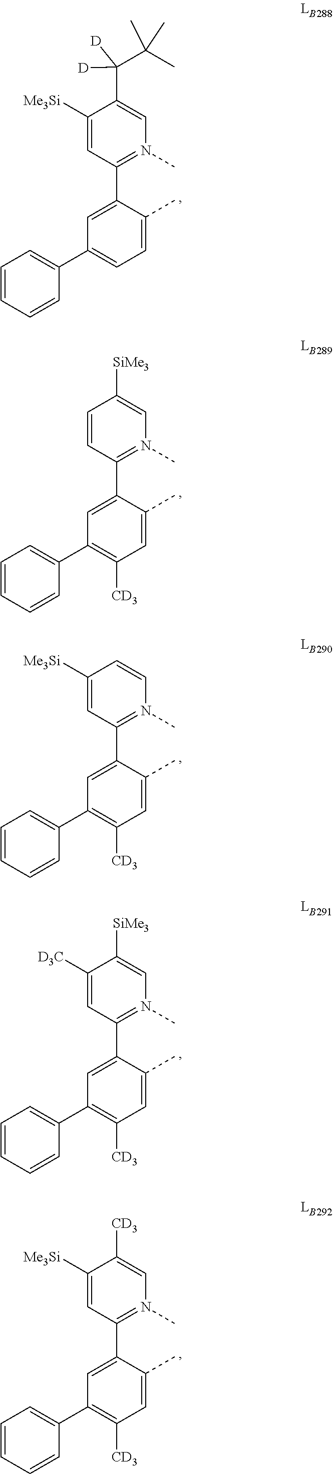

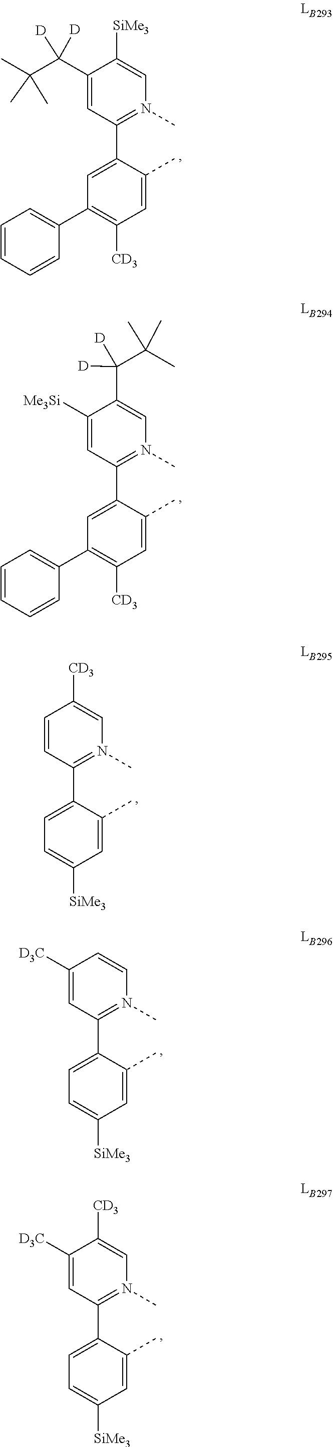

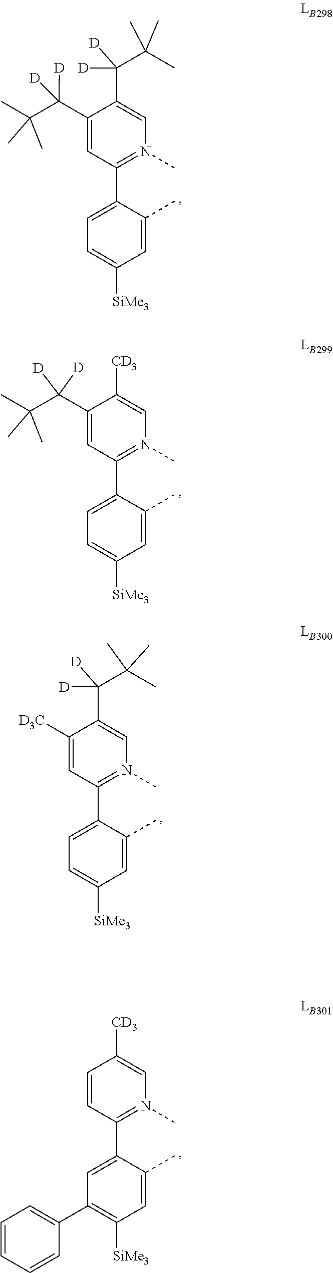

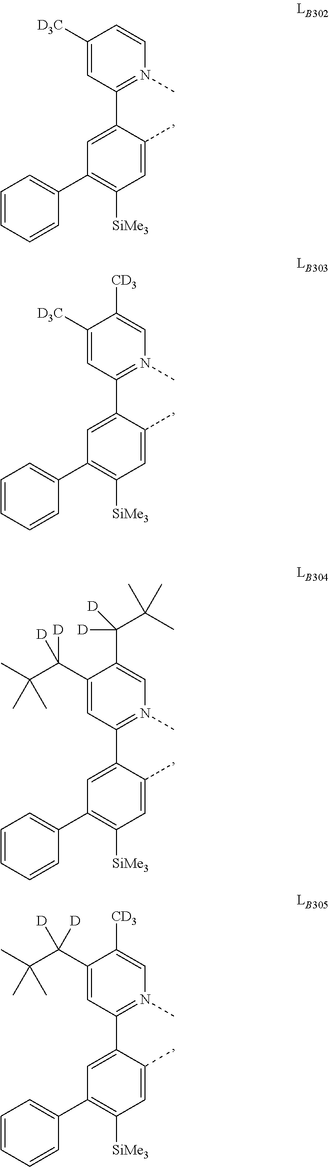

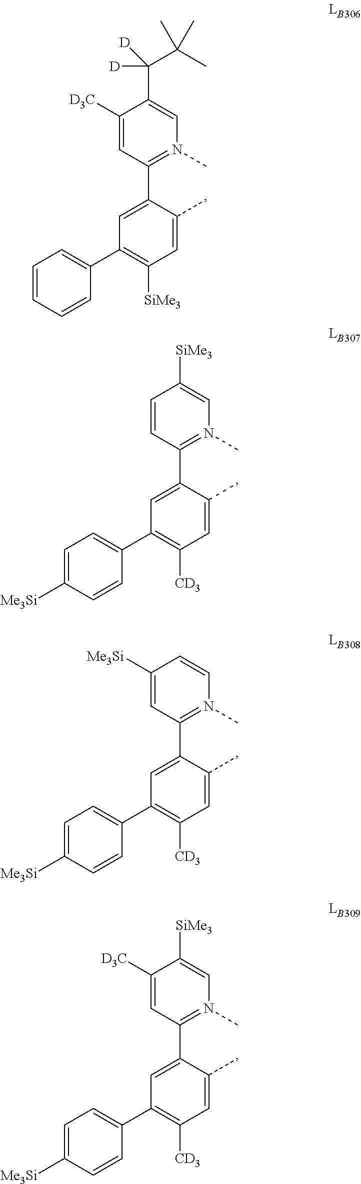

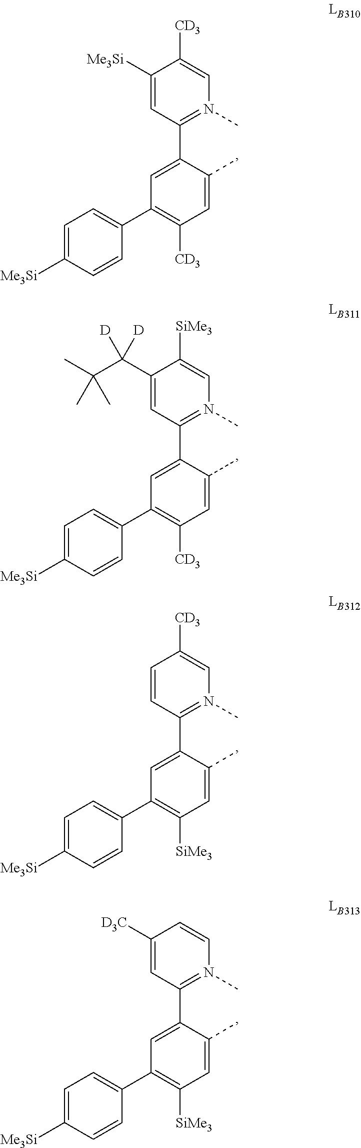

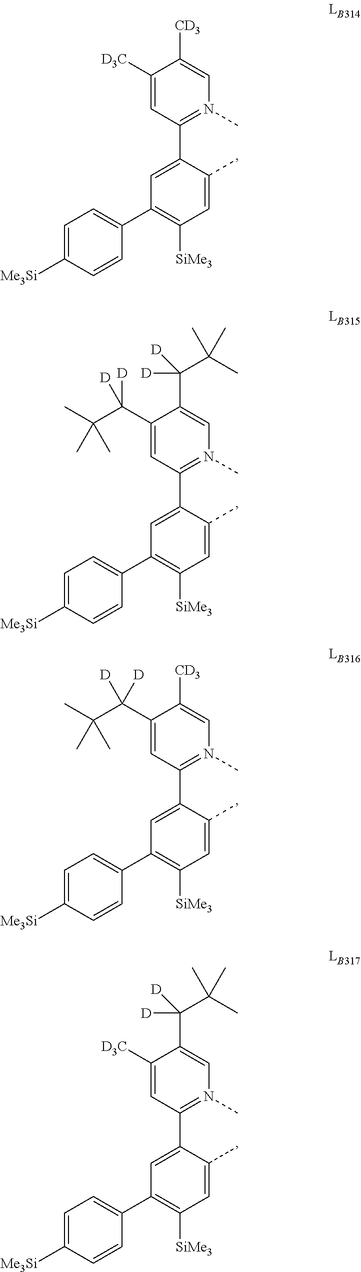

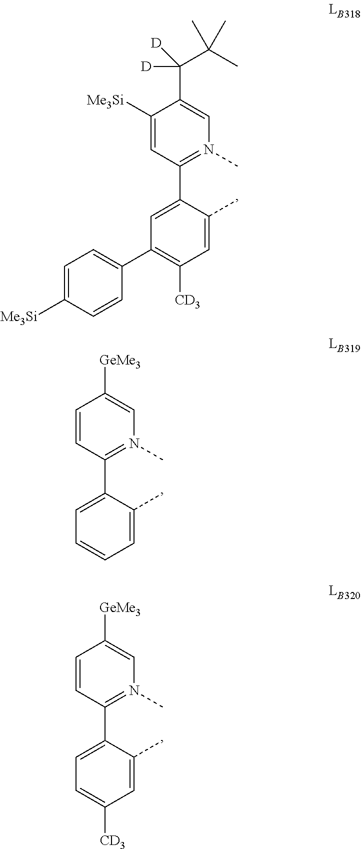

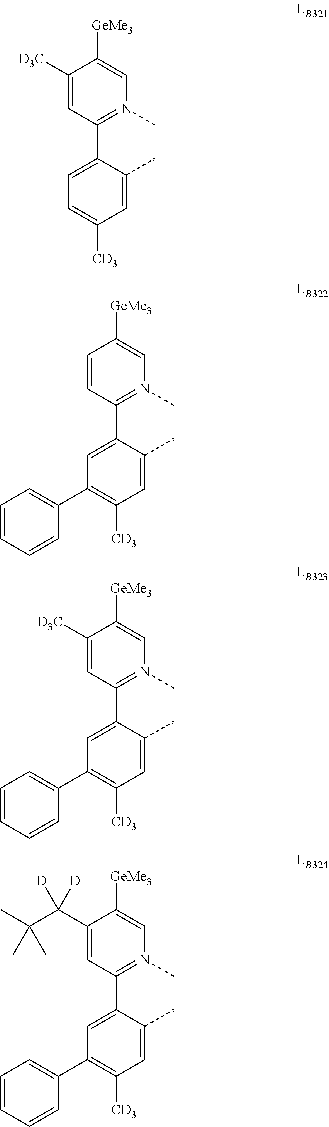

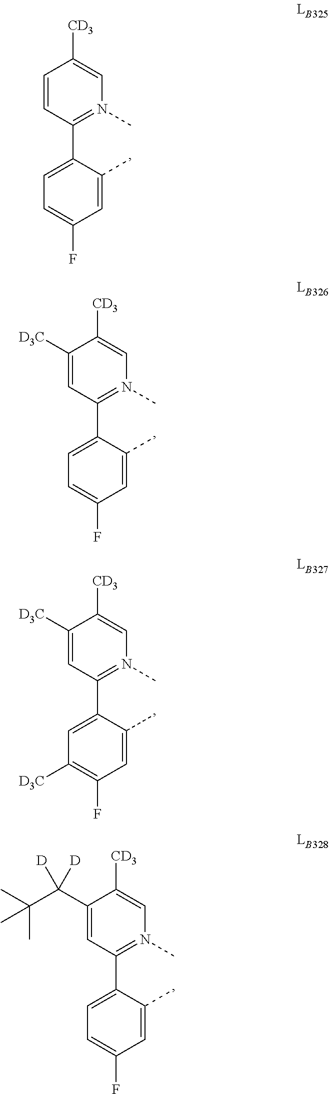

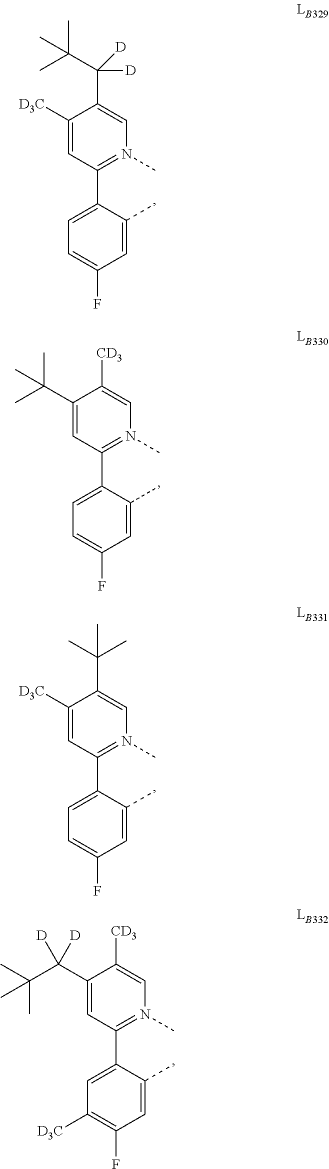

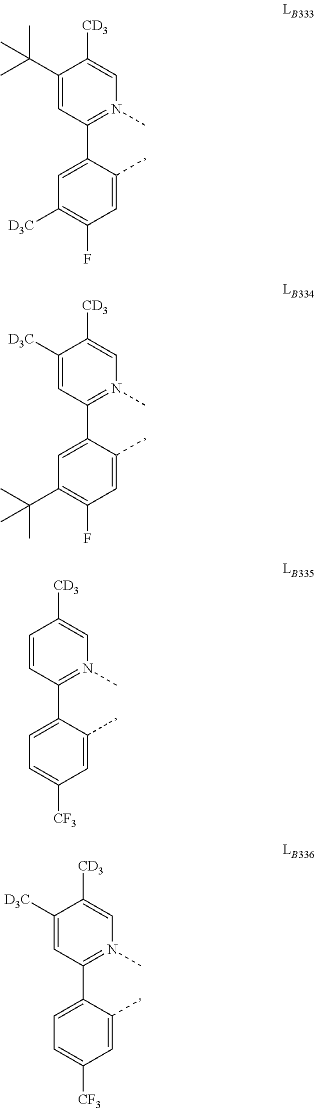

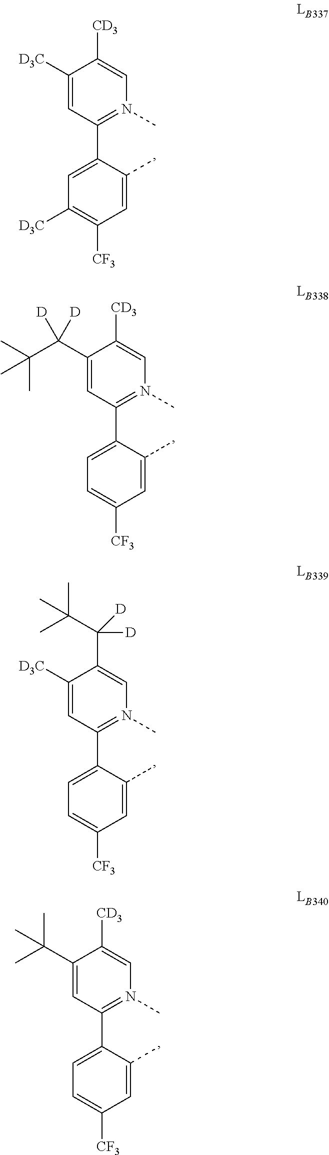

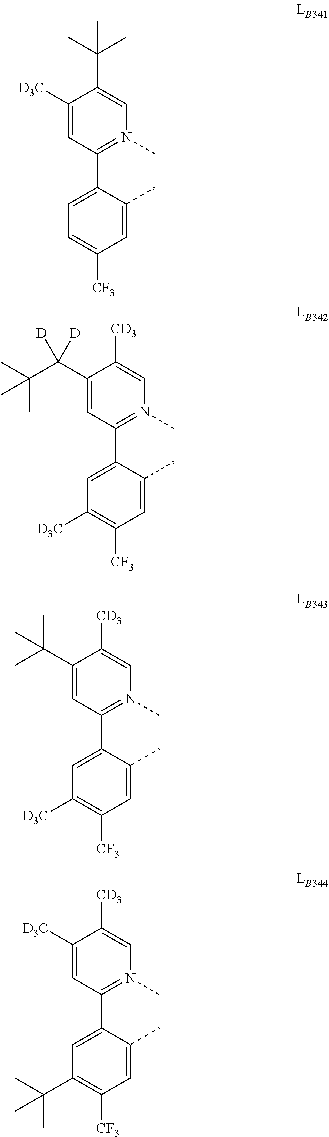

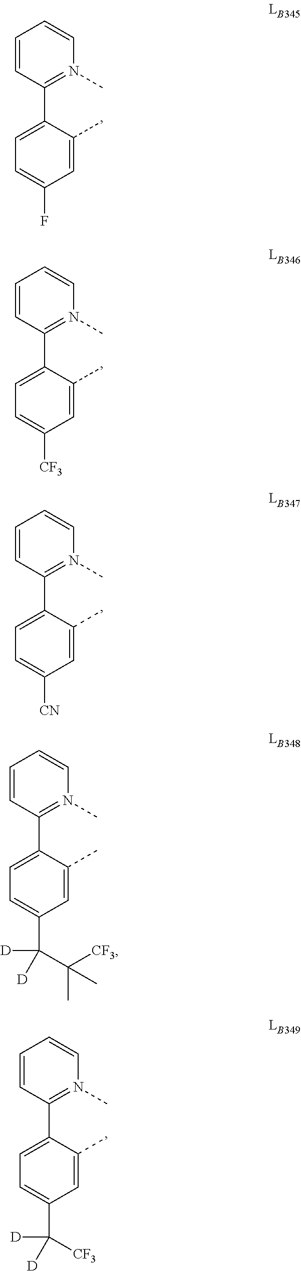

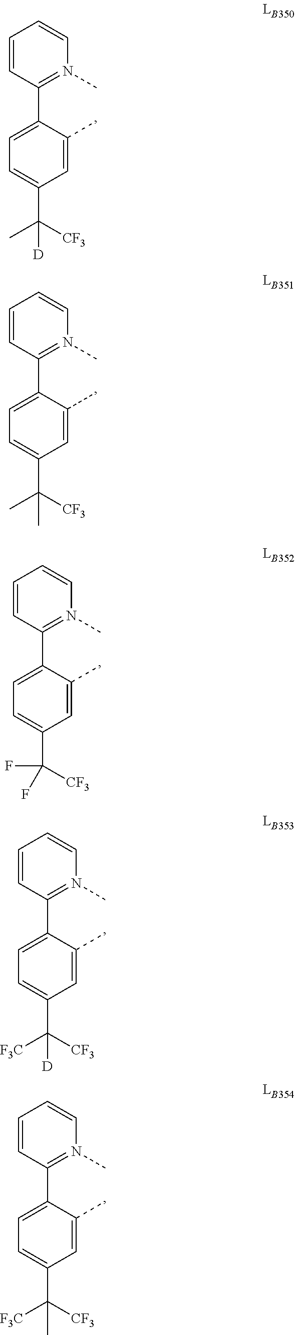

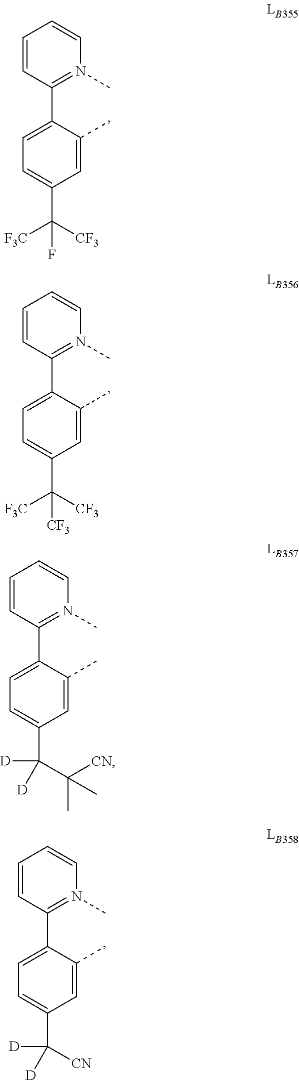

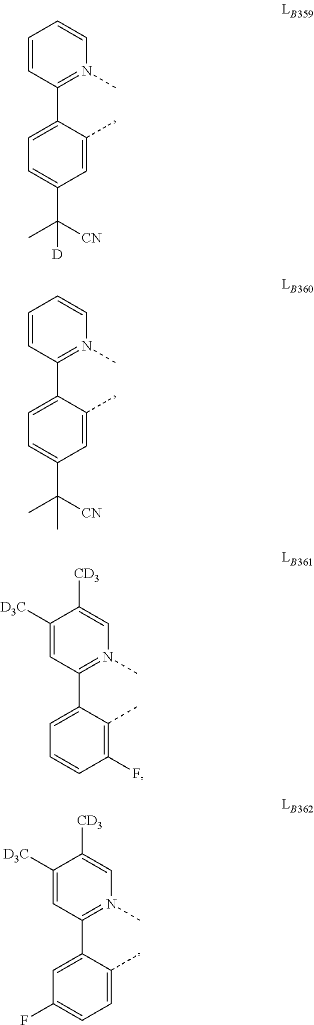

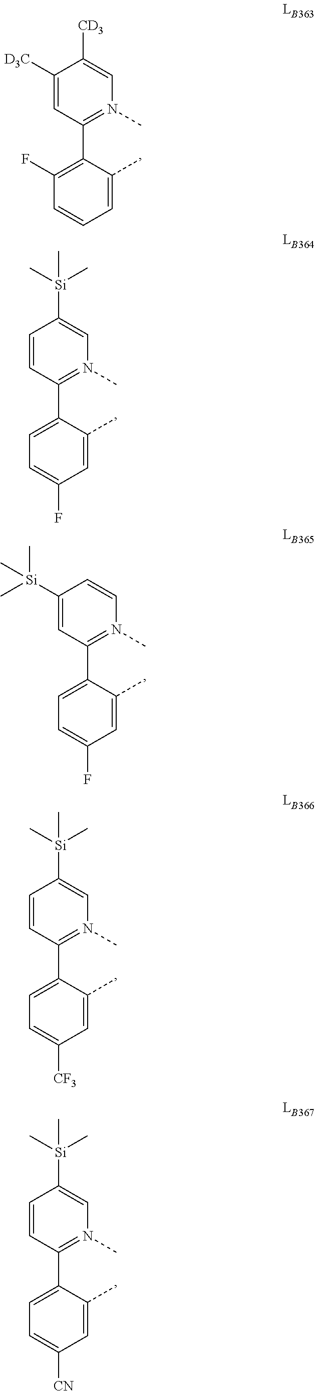

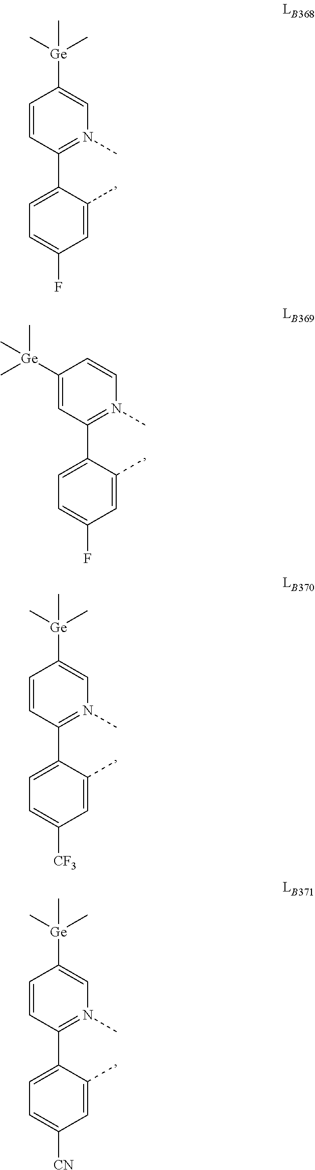

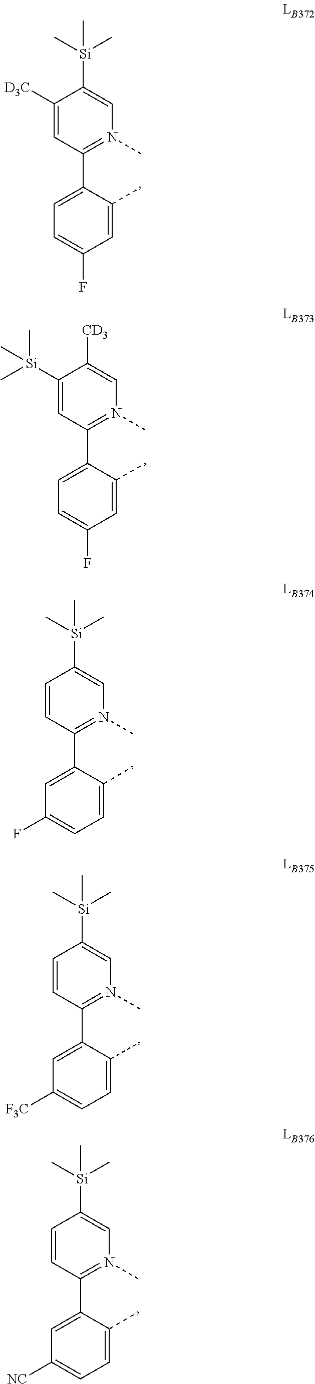

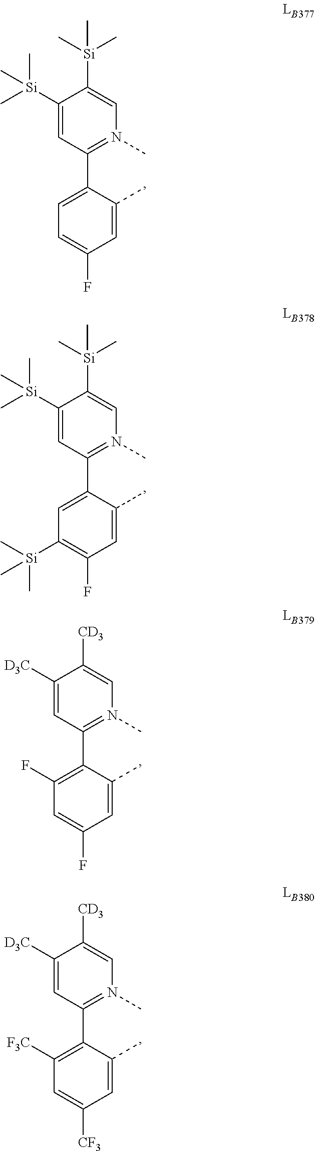

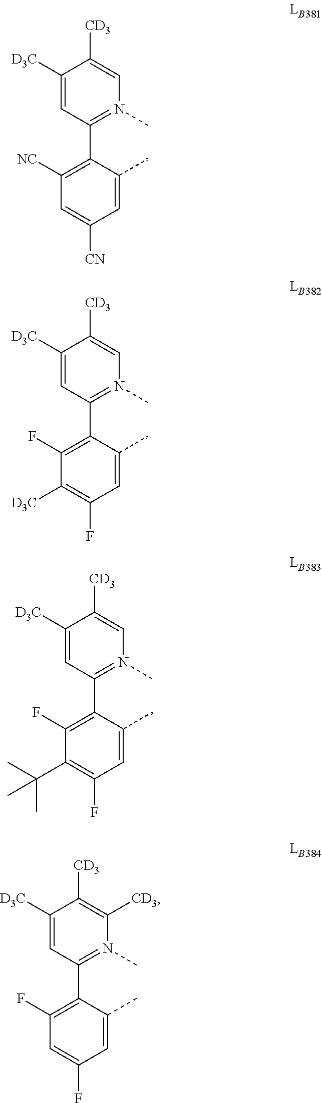

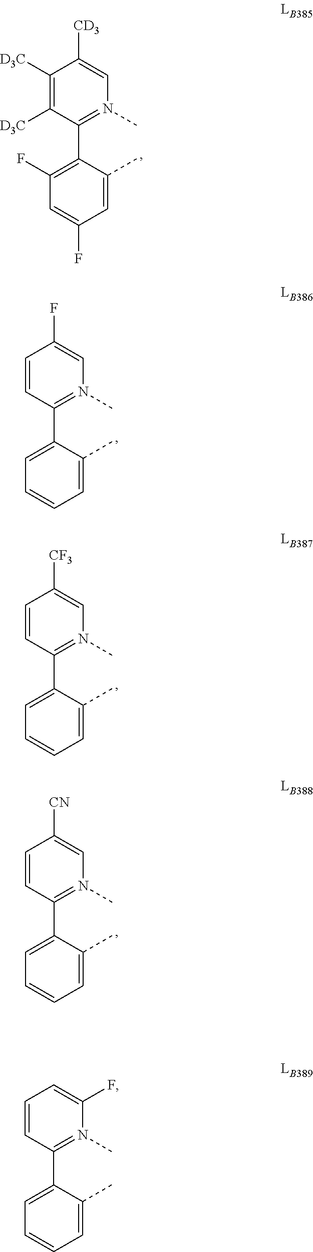

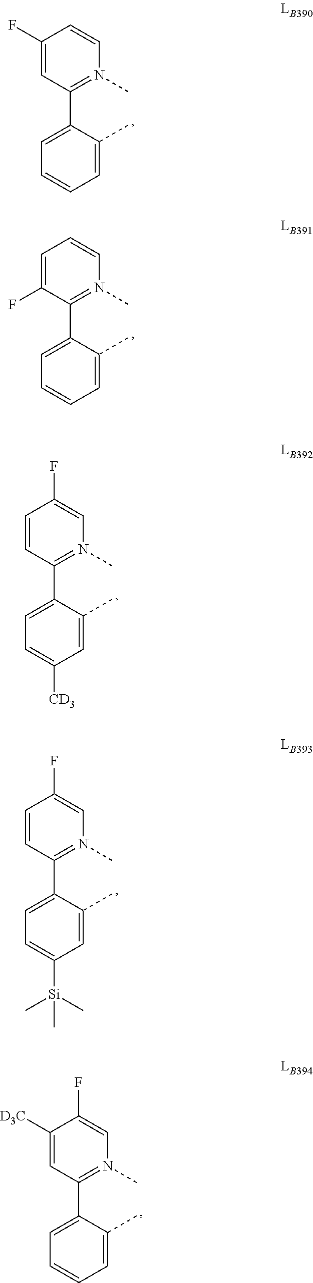

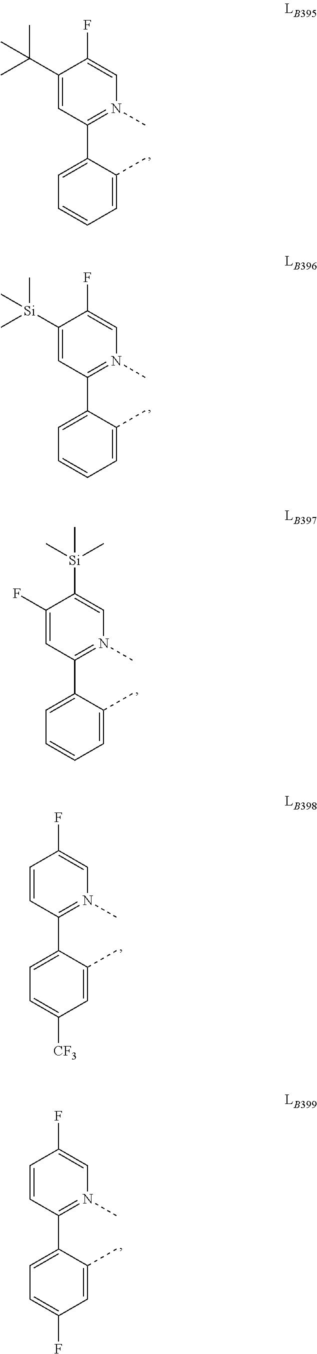

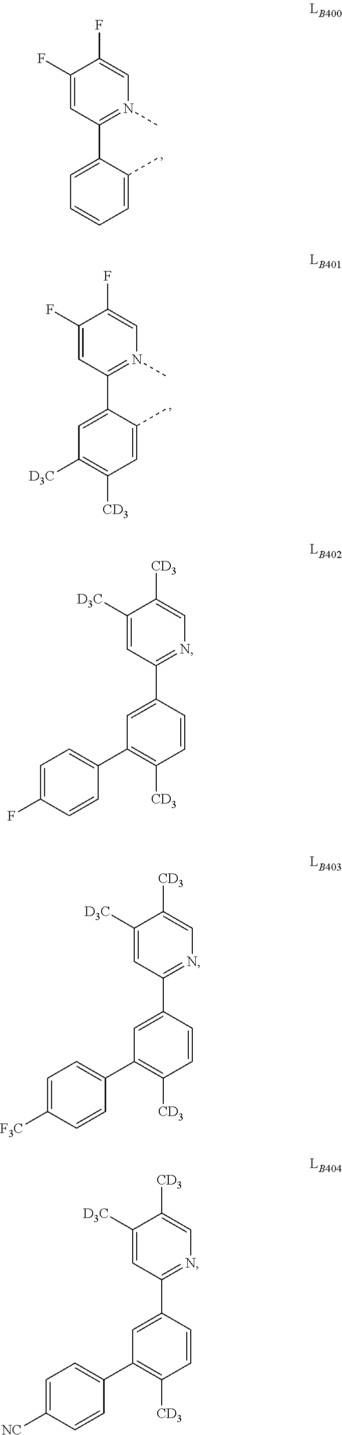

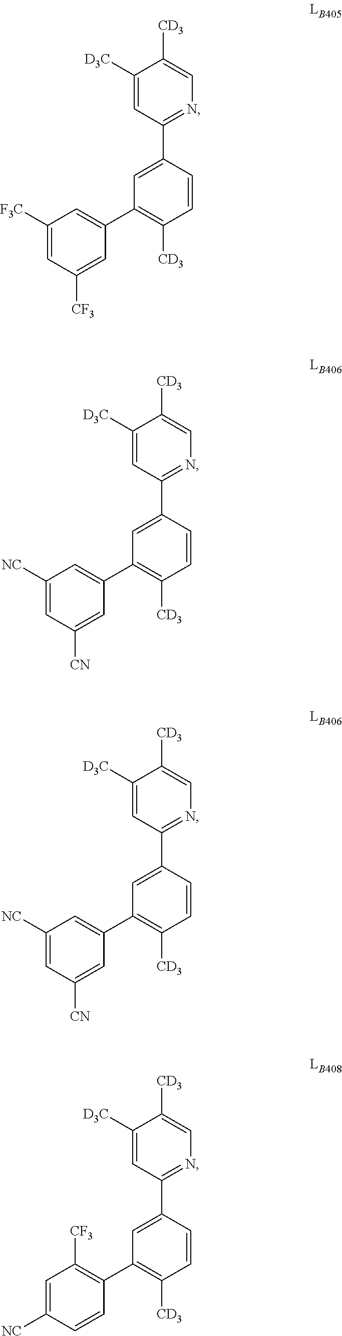 [SMILES: [2H]C([2H])([2H])c1ccc(-c2cc(C([2H])([2H])[2H])c(C([2H])([2H])[2H])cn2)cc1-c1cc(C(F)(F)F)cc(C(F)(F)F)c1 ; [2H]C([2H])([2H])c1ccc(-c2cc(C([2H])([2H])[2H])c(C([2H])([2H])[2H])cn2)cc1-c1cc(C#N)cc(C#N)c1 ; [2H]C([2H])([2H])c1ccc(-c2cc(C([2H])([2H])[2H])c(C([2H])([2H])[2H])cn2)cc1-c1cc(C#N)cc(C#N)c1 ; [2H]C([2H])([2H])c1ccc(-c2cc(C([2H])([2H])[2H])c(C([2H])([2H])[2H])cn2)cc1-c1ccc(C#N)cc1C(F)(F)F]

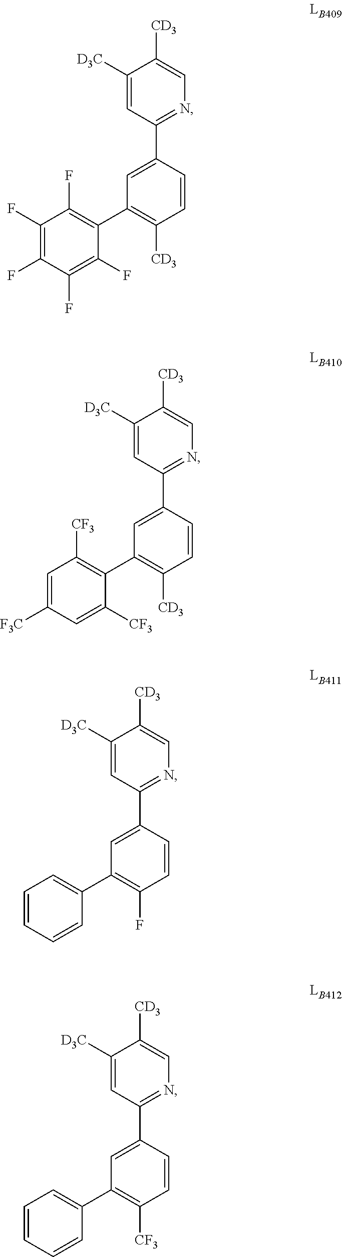 [SMILES: [2H]C([2H])([2H])c1ccc(-c2cc(C([2H])([2H])[2H])c(C([2H])([2H])[2H])cn2)cc1-c1c(F)c(F)c(F)c(F)c1F ; [2H]C([2H])([2H])c1ccc(-c2cc(C([2H])([2H])[2H])c(C([2H])([2H])[2H])cn2)cc1-c1c(C(F)(F)F)cc(C(F)(F)F)cc1C(F)(F)F ; [2H]C([2H])([2H])c1cnc(-c2ccc(F)c(-c3ccccc3)c2)cc1C([2H])([2H])[2H] ; [2H]C([2H])([2H])c1cnc(-c2ccc(C(F)(F)F)c(-c3ccccc3)c2)cc1C([2H])([2H])[2H]]

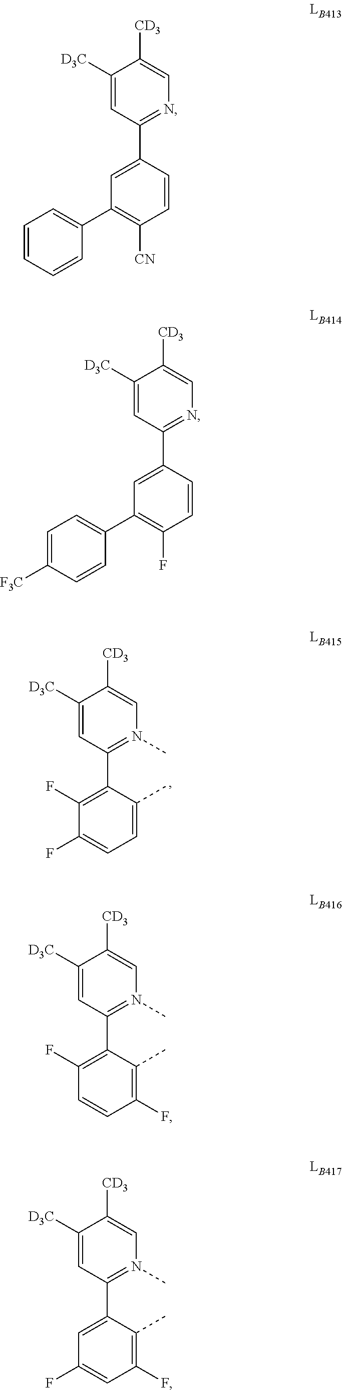

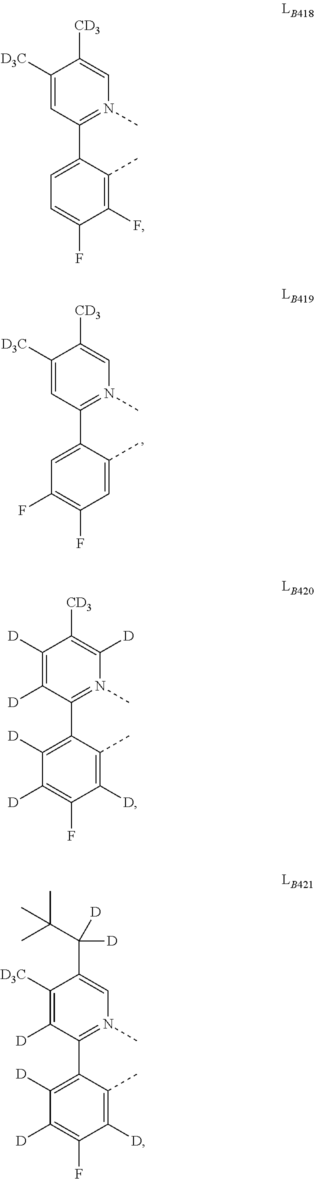

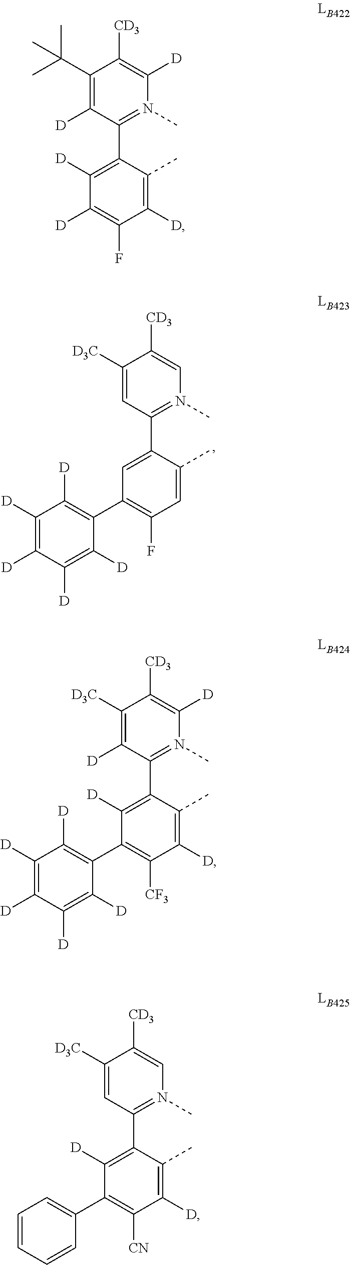

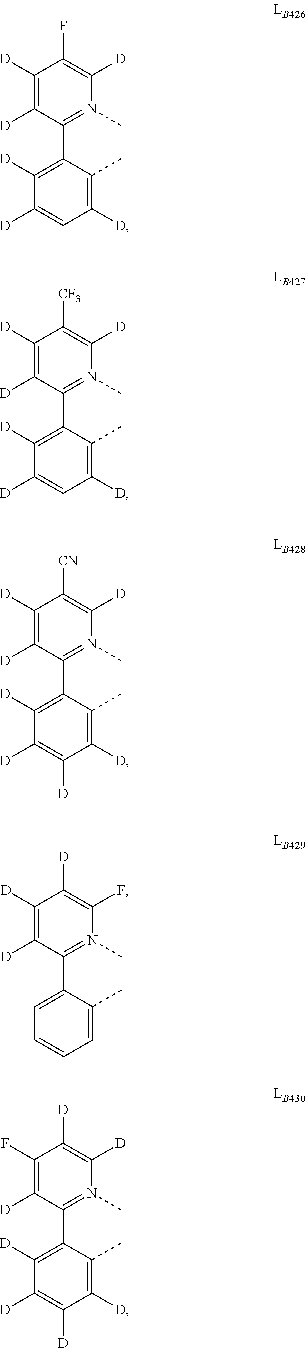

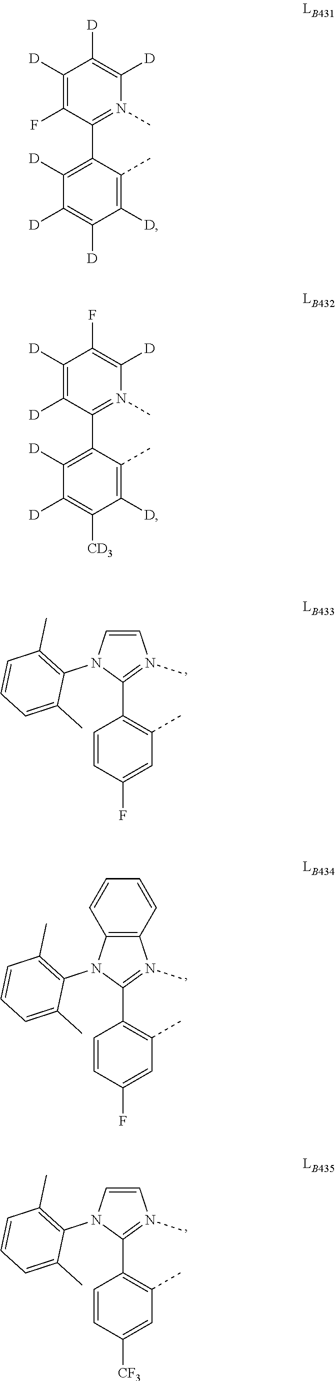

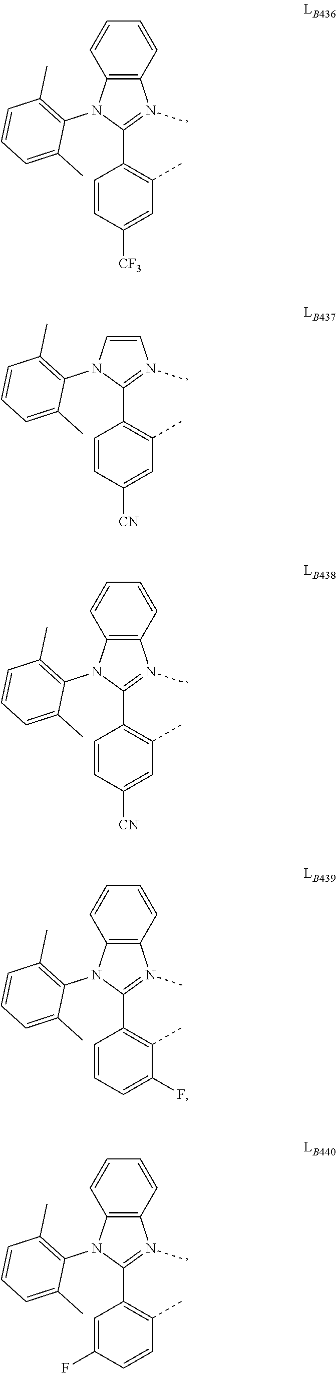

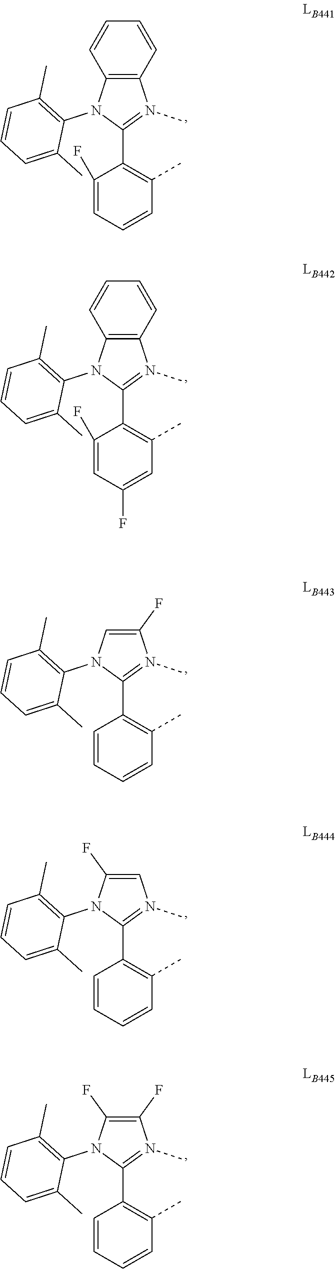

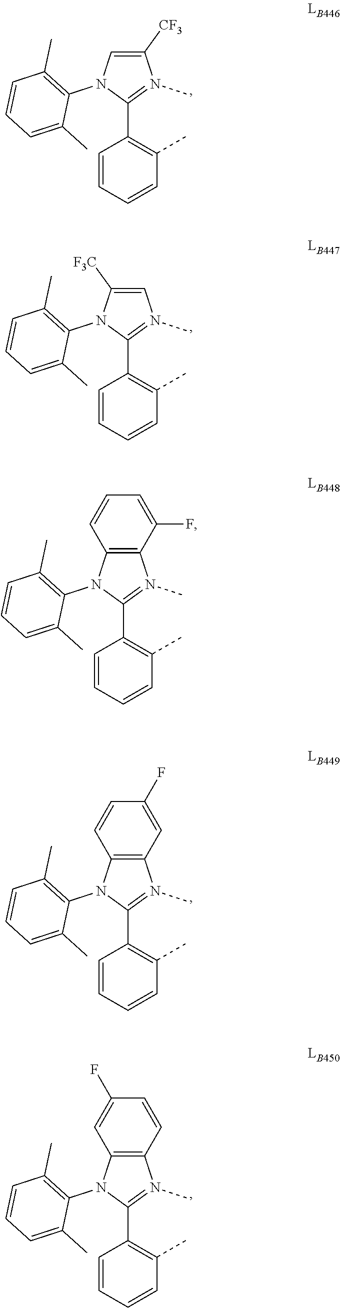

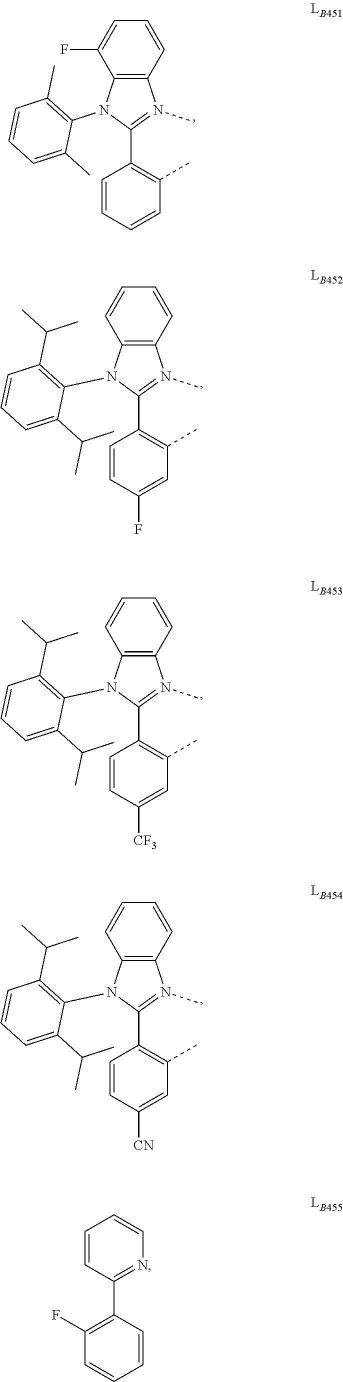

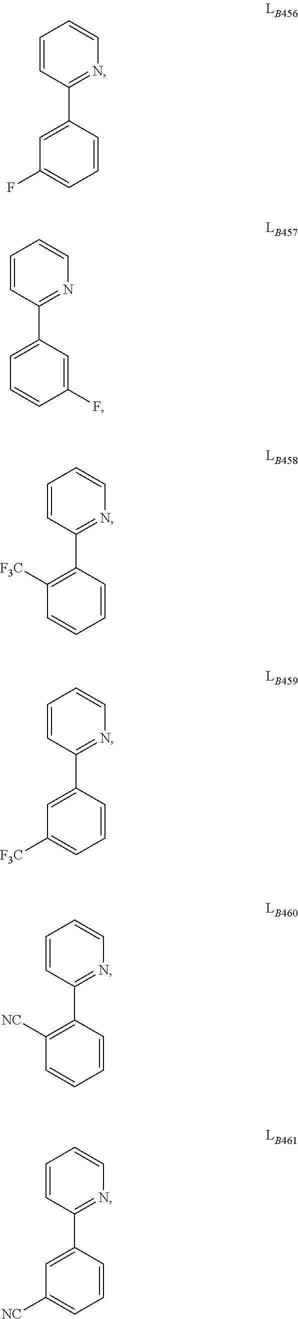 [SMILES: Fc1cccc(-c2ccccn2)c1 ; Fc1cccc(-c2ccccn2)c1 ; FC(F)(F)c1ccccc1-c1ccccn1 ; FC(F)(F)c1cccc(-c2ccccn2)c1 ; N#Cc1ccccc1-c1ccccn1 ; N#Cc1cccc(-c2ccccn2)c1]

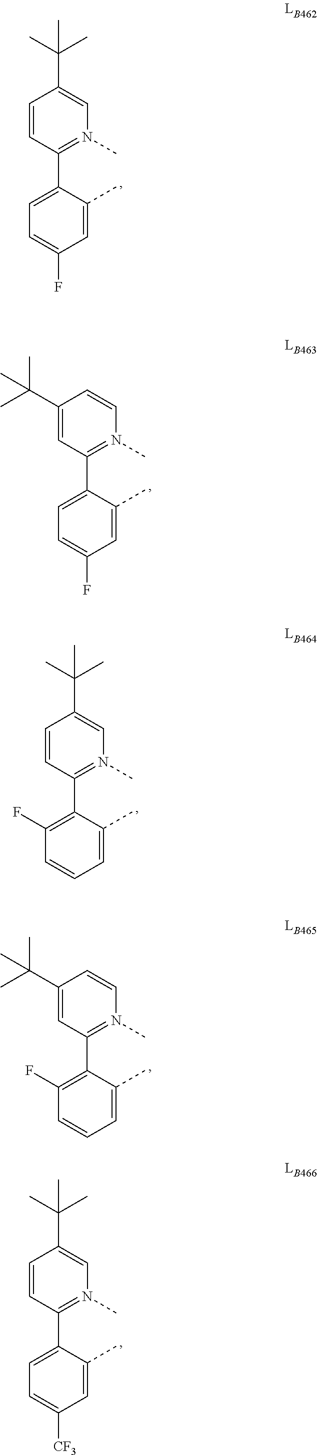

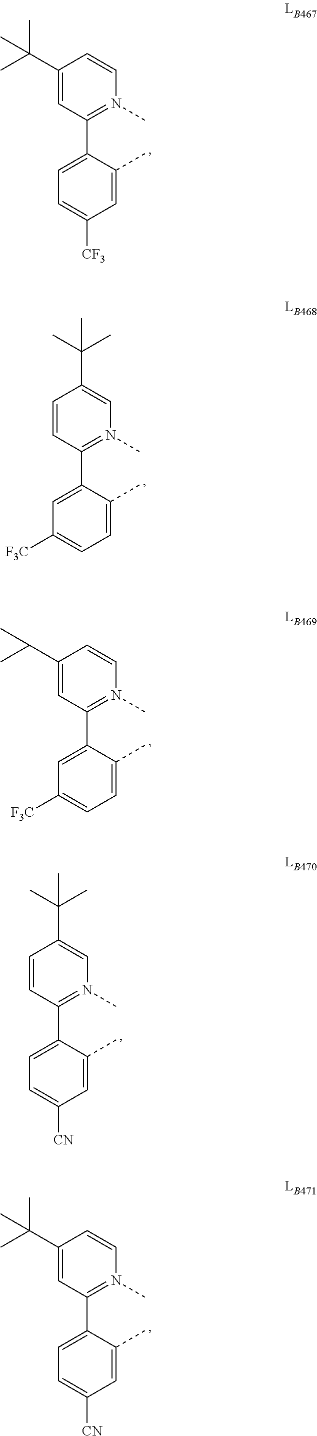

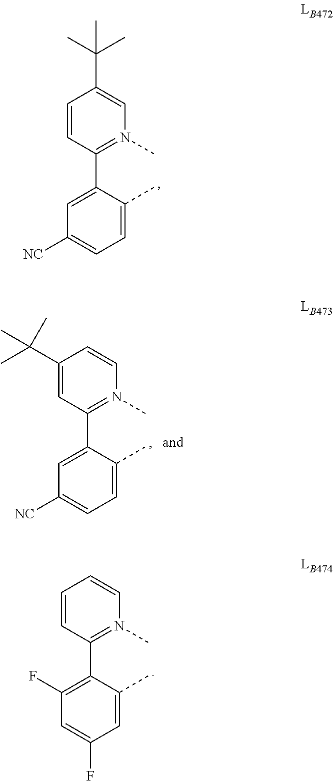

wherein each L_{Cj-I} has a structure based on formula

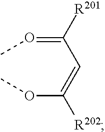

and each L_{Cj-II} has a structure based on formula

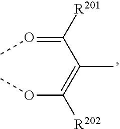

wherein for each L_{Cj} in L_{Cj-I} and L_{Cj-II}, R²⁰¹ and R²⁰² are each independently defined in the following LIST 11:

| L_{Cj} | R²⁰¹ | R²⁰² |
|---|---|---|
| L_{C1} | R^{D1} | R^{D1} |
| L_{C2} | R^{D2} | R^{D2} |
| L_{C3} | R^{D3} | R^{D3} |
| L_{C4} | R^{D4} | R^{D4} |
| L_{C5} | R^{D5} | R^{D5} |
| L_{C6} | R^{D6} | R^{D6} |
| L_{C7} | R^{D7} | R^{D7} |
| L_{C8} | R^{D8} | R^{D8} |
| L_{C9} | R^{D9} | R^{D9} |
| L_{C10} | R^{D10} | R^{D10} |
| L_{C11} | R^{D11} | R^{D11} |
| L_{C12} | R^{D12} | R^{D12} |
| L_{C13} | R^{D13} | R^{D13} |
| L_{C14} | R^{D14} | R^{D14} |
| L_{C15} | R^{D15} | R^{D15} |
| L_{C16} | R^{D16} | R^{D16} |
| L_{C17} | R^{D17} | R^{D17} |
| L_{C18} | R^{D18} | R^{D18} |
| L_{C19} | R^{D19} | R^{D19} |
| L_{C20} | R^{D20} | R^{D20} |
| L_{C21} | R^{D21} | R^{D21} |
| L_{C22} | R^{D22} | R^{D22} |
| L_{C23} | R^{D23} | R^{D23} |
| L_{C24} | R^{D24} | R^{D24} |
| L_{C25} | R^{D25} | R^{D25} |
| L_{C26} | R^{D26} | R^{D26} |
| L_{C27} | R^{D27} | R^{D27} |
| L_{C28} | R^{D28} | R^{D28} |
| L_{C29} | R^{D29} | R^{D29} |
| L_{C30} | R^{D30} | R^{D30} |
| L_{C31} | R^{D31} | R^{D31} |
| L_{C32} | R^{D32} | R^{D32} |
| L_{C33} | R^{D33} | R^{D33} |
| L_{C34} | R^{D34} | R^{D34} |
| L_{C35} | R^{D35} | R^{D35} |
| L_{C36} | R^{D36} | R^{D36} |
| L_{C37} | R^{D37} | R^{D37} |
| L_{C38} | R^{D38} | R^{D38} |
| L_{C39} | R^{D39} | R^{D39} |
| L_{C40} | R^{D40} | R^{D40} |
| L_{C41} | R^{D41} | R^{D41} |
| L_{C42} | R^{D42} | R^{D42} |
| L_{C43} | R^{D43} | R^{D43} |
| L_{C44} | R^{D44} | R^{D44} |
| L_{C45} | R^{D45} | R^{D45} |
| L_{C46} | R^{D46} | R^{D46} |
| L_{C47} | R^{D42} | R^{D47} |
| L_{C48} | R^{D48} | R^{D48} |
| L_{C49} | R^{D49} | R^{D49} |
| L_{C50} | R^{D50} | R^{D50} |
| L_{C51} | R^{D51} | R^{D51} |
| L_{C52} | R^{D52} | R^{D52} |
| L_{C53} | R^{D53} | R^{D53} |
| L_{C54} | R^{D54} | R^{D54} |
| L_{C55} | R^{D55} | R^{D55} |
| L_{C56} | R^{D56} | R^{D56} |
| L_{C57} | R^{D57} | R^{D57} |
| L_{C58} | R^{D58} | R^{D58} |
| L_{C59} | R^{D59} | R^{D59} |
| L_{C60} | R^{D60} | R^{D60} |
| L_{C61} | R^{D61} | R^{D61} |
| L_{C62} | R^{D62} | R^{D62} |
| L_{C63} | R^{D63} | R^{D63} |
| L_{C64} | R^{D64} | R^{D64} |
| L_{C65} | R^{D65} | R^{D65} |
| L_{C66} | R^{D66} | R^{D66} |
| L_{C67} | R^{D67} | R^{D67} |
| L_{C68} | R^{D68} | R^{D68} |
| L_{C69} | R^{D69} | R^{D69} |
| L_{C70} | R^{D70} | R^{D70} |
| L_{C71} | R^{D71} | R^{D71} |
| L_{C72} | R^{D72} | R^{D72} |
| L_{C73} | R^{D73} | R^{D73} |
| L_{C74} | R^{D74} | R^{D74} |
| L_{C75} | R^{D75} | R^{D75} |
| L_{C76} | R^{D76} | R^{D76} |
| L_{C77} | R^{D77} | R^{D77} |
| L_{C78} | R^{D78} | R^{D78} |
| L_{C79} | R^{D79} | R^{D79} |
| L_{C80} | R^{D80} | R^{D80} |
| L_{C81} | R^{D81} | R^{D81} |
| L_{C82} | R^{D82} | R^{D82} |
| L_{C83} | R^{D83} | R^{D83} |
| L_{C84} | R^{D84} | R^{D84} |
| L_{C85} | R^{D85} | R^{D85} |
| L_{C86} | R^{D86} | R^{D86} |
| L_{C87} | R^{D87} | R^{D87} |
| L_{C88} | R^{D88} | R^{D88} |
| L_{C89} | R^{D89} | R^{D89} |
| L_{C90} | R^{D90} | R^{D90} |
| L_{C91} | R^{D91} | R^{D91} |
| L_{C92} | R^{D92} | R^{D92} |
| L_{C93} | R^{D93} | R^{D93} |
| L_{C94} | R^{D94} | R^{D94} |
| L_{C95} | R^{D95} | R^{D95} |
| L_{C96} | R^{D96} | R^{D96} |
| L_{C97} | R^{D97} | R^{D97} |
| L_{C98} | R^{D98} | R^{D98} |
| L_{C99} | R^{D99} | R^{D99} |
| L_{C100} | R^{D100} | R^{D100} |
| L_{C101} | R^{D101} | R^{D101} |
| L_{C102} | R^{D102} | R^{D102} |
| L_{C103} | R^{D103} | R^{D103} |
| L_{C104} | R^{D104} | R^{D104} |
| L_{C105} | R^{D105} | R^{D105} |
| L_{C106} | R^{D106} | R^{D106} |
| L_{C107} | R^{D107} | R^{D107} |
| L_{C108} | R^{D108} | R^{D108} |
| L_{C109} | R^{D109} | R^{D109} |
| L_{C110} | R^{D110} | R^{D110} |
| L_{C111} | R^{D111} | R^{D111} |
| L_{C112} | R^{D112} | R^{D112} |
| L_{C113} | R^{D113} | R^{D113} |
| L_{C114} | R^{D114} | R^{D114} |
| L_{C115} | R^{D115} | R^{D115} |
| L_{C116} | R^{D116} | R^{D116} |
| L_{C117} | R^{D117} | R^{D117} |
| L_{C118} | R^{D118} | R^{D118} |
| L_{C119} | R^{D119} | R^{D119} |
| L_{C120} | R^{D120} | R^{D120} |
| L_{C121} | R^{D121} | R^{D121} |
| L_{C122} | R^{D122} | R^{D122} |
| L_{C123} | R^{D123} | R^{D123} |
| L_{C124} | R^{D124} | R^{D124} |
| L_{C125} | R^{D125} | R^{D125} |
| L_{C126} | R^{D126} | R^{D126} |
| L_{C127} | R^{D127} | R^{D127} |
| L_{C128} | R^{D128} | R^{D128} |
| L_{C129} | R^{D129} | R^{D129} |
| L_{C130} | R^{D130} | R^{D130} |
| L_{C131} | R^{D131} | R^{D131} |
| L_{C132} | R^{D132} | R^{D132} |
| L_{C133} | R^{D133} | R^{D133} |
| L_{C134} | R^{D134} | R^{D134} |
| L_{C135} | R^{D135} | R^{D135} |
| L_{C136} | R^{D136} | R^{D136} |
| L_{C137} | R^{D137} | R^{D137} |
| L_{C138} | R^{D138} | R^{D138} |
| L_{C139} | R^{D139} | R^{D139} |
| L_{C140} | R^{D140} | R^{D140} |
| L_{C141} | R^{D141} | R^{D141} |
| L_{C142} | R^{D142} | R^{D142} |
| L_{C143} | R^{D143} | R^{D143} |
| L_{C144} | R^{D144} | R^{D144} |
| L_{C145} | R^{D145} | R^{D145} |
| L_{C146} | R^{D146} | R^{D146} |
| L_{C147} | R^{D147} | R^{D147} |
| L_{C148} | R^{D148} | R^{D148} |
| L_{C149} | R^{D149} | R^{D149} |
| L_{C150} | R^{D150} | R^{D150} |
| L_{C151} | R^{D151} | R^{D151} |
| L_{C152} | R^{D152} | R^{D152} |
| L_{C153} | R^{D153} | R^{D153} |
| L_{C154} | R^{D154} | R^{D154} |
| L_{C155} | R^{D155} | R^{D155} |
| L_{C156} | R^{D156} | R^{D156} |
| L_{C157} | R^{D157} | R^{D157} |
| L_{C158} | R^{D158} | R^{D158} |
| L_{C159} | R^{D159} | R^{D159} |
| L_{C160} | R^{D160} | R^{D160} |
| L_{C161} | R^{D161} | R^{D161} |
| L_{C162} | R^{D162} | R^{D162} |
| L_{C163} | R^{D163} | R^{D163} |
| L_{C164} | R^{D164} | R^{D164} |
| L_{C165} | R^{D165} | R^{D165} |
| L_{C166} | R^{D166} | R^{D166} |
| L_{C167} | R^{D167} | R^{D167} |
| L_{C168} | R^{D168} | R^{D168} |
| L_{C169} | R^{D169} | R^{D169} |
| L_{C170} | R^{D170} | R^{D170} |
| L_{C171} | R^{D171} | R^{D171} |
| L_{C172} | R^{D172} | R^{D172} |
| L_{C173} | R^{D173} | R^{D173} |
| L_{C174} | R^{D174} | R^{D174} |
| L_{C175} | R^{D175} | R^{D175} |
| L_{C176} | R^{D176} | R^{D176} |
| L_{C177} | R^{D177} | R^{D177} |
| L_{C178} | R^{D178} | R^{D178} |
| L_{C179} | R^{D179} | R^{D179} |
| L_{C180} | R^{D180} | R^{D180} |
| L_{C181} | R^{D181} | R^{D181} |
| L_{C182} | R^{D182} | R^{D182} |
| L_{C183} | R^{D183} | R^{D183} |
| L_{C184} | R^{D184} | R^{D184} |
| L_{C185} | R^{D185} | R^{D185} |
| L_{C186} | R^{D186} | R^{D186} |
| L_{C187} | R^{D187} | R^{D187} |
| L_{C188} | R^{D188} | R^{D188} |
| L_{C189} | R^{D189} | R^{D189} |
| L_{C190} | R^{D190} | R^{D190} |
| L_{C191} | R^{D191} | R^{D191} |
| L_{C192} | R^{D192} | R^{D192} |
| L_{C193} | R^{D1} | R^{D3} |
| L_{C194} | R^{D1} | R^{D4} |
| L_{C195} | R^{D1} | R^{D5} |
| L_{C196} | R^{D1} | R^{D9} |
| L_{C197} | R^{D1} | R^{D10} |
| L_{C198} | R^{D1} | R^{D17} |
| L_{C199} | R^{D1} | R^{D18} |
| L_{C200} | R^{D1} | R^{D20} |
| L_{C201} | R^{D1} | R^{D22} |
| L_{C202} | R^{D1} | R^{D37} |
| L_{C203} | R^{D1} | R^{D40} |
| L_{C204} | R^{D1} | R^{D41} |
| L_{C205} | R^{D1} | R^{D42} |
| L_{C206} | R^{D1} | R^{D43} |
| L_{C207} | R^{D1} | R^{D48} |
| L_{C208} | R^{D1} | R^{D49} |
| L_{C209} | R^{D1} | R^{D50} |
| L_{C210} | R^{D1} | R^{D54} |
| L_{C211} | R^{D1} | R^{D55} |
| L_{C212} | R^{D1} | R^{D58} |
| L_{C213} | R^{D1} | R^{D59} |
| L_{C214} | R^{D1} | R^{D78} |
| L_{C215} | R^{D1} | R^{D79} |
| L_{C216} | R^{D1} | R^{D81} |
| L_{C217} | R^{D1} | R^{D87} |
| L_{C218} | R^{D1} | R^{D88} |
| L_{C219} | R^{D1} | R^{D89} |
| L_{C220} | R^{D1} | R^{D93} |
| L_{C221} | R^{D1} | R^{D116} |
| L_{C222} | R^{D1} | R^{D117} |
| L_{C223} | R^{D1} | R^{D118} |
| L_{C224} | R^{D1} | R^{D119} |
| L_{C225} | R^{D1} | R^{D120} |
| L_{C226} | R^{D1} | R^{D133} |
| L_{C227} | R^{D1} | R^{D134} |
| L_{C228} | R^{D1} | R^{D135} |
| L_{C229} | R^{D1} | R^{D136} |
| L_{C230} | R^{D1} | R^{D143} |
| L_{C231} | R^{D1} | R^{D144} |
| L_{C232} | R^{D1} | R^{D145} |
| L_{C233} | R^{D1} | R^{D146} |
| L_{C234} | R^{D1} | R^{D147} |
| L_{C235} | R^{D1} | R^{D149} |
| L_{C236} | R^{D1} | R^{D151} |
| L_{C237} | R^{D1} | R^{D154} |
| L_{C238} | R^{D1} | R^{D155} |
| L_{C239} | R^{D1} | R^{D161} |
| L_{C240} | R^{D1} | R^{D175} |
| L_{C241} | R^{D4} | R^{D3} |
| L_{C242} | R^{D4} | R^{D5} |
| L_{C243} | R^{D4} | R^{D9} |
| L_{C244} | R^{D4} | R^{D10} |
| L_{C245} | R^{D4} | R^{D17} |
| L_{C246} | R^{D4} | R^{D18} |
| L_{C247} | R^{D4} | R^{D20} |
| L_{C248} | R^{D4} | R^{D22} |
| L_{C249} | R^{D4} | R^{D37} |
| L_{C250} | R^{D4} | R^{D40} |
| L_{C251} | R^{D4} | R^{D41} |
| L_{C252} | R^{D4} | R^{D42} |
| L_{C253} | R^{D4} | R^{D43} |
| L_{C254} | R^{D4} | R^{D48} |
| L_{C255} | R^{D4} | R^{D49} |
| L_{C256} | R^{D4} | R^{D50} |
| L_{C257} | R^{D4} | R^{D54} |
| L_{C258} | R^{D4} | R^{D55} |
| L_{C259} | R^{D4} | R^{D58} |
| L_{C260} | R^{D4} | R^{D59} |
| L_{C261} | R^{D4} | R^{D78} |
| L_{C262} | R^{D4} | R^{D79} |
| L_{C263} | R^{D4} | R^{D81} |
| L_{C264} | R^{D4} | R^{D87} |
| L_{C265} | R^{D4} | R^{D88} |
| L_{C266} | R^{D4} | R^{D89} |
| L_{C267} | R^{D4} | R^{D93} |
| L_{C268} | R^{D4} | R^{D116} |
| L_{C269} | R^{D4} | R^{D117} |
| L_{C270} | R^{D4} | R^{D118} |
| L_{C271} | R^{D4} | R^{D119} |
| L_{C272} | R^{D4} | R^{D120} |
| L_{C273} | R^{D4} | R^{D133} |
| L_{C274} | R^{D4} | R^{D134} |
| L_{C275} | R^{D4} | R^{D135} |
| L_{C276} | R^{D4} | R^{D136} |
| L_{C277} | R^{D4} | R^{D143} |
| L_{C278} | R^{D4} | R^{D144} |
| L_{C279} | R^{D4} | R^{D145} |
| L_{C280} | R^{D4} | R^{D146} |
| L_{C281} | R^{D4} | R^{D147} |
| L_{C282} | R^{D4} | R^{D149} |
| L_{C283} | R^{D4} | R^{D151} |
| L_{C284} | R^{D4} | R^{D154} |
| L_{C285} | R^{D4} | R^{D155} |
| L_{C286} | R^{D4} | R^{D161} |
| L_{C287} | R^{D4} | R^{D175} |
| L_{C288} | R^{D9} | R^{D3} |
| L_{C289} | R^{D9} | R^{D5} |
| L_{C290} | R^{D9} | R^{D10} |
| L_{C291} | R^{D9} | R^{D17} |
| L_{C292} | R^{D9} | R^{D18} |
| L_{C293} | R^{D9} | R^{D20} |
| L_{C294} | R^{D9} | R^{D22} |
| L_{C295} | R^{D9} | R^{D37} |
| L_{C296} | R^{D9} | R^{D40} |
| L_{C297} | R^{D9} | R^{D41} |
| L_{C298} | R^{D9} | R^{D42} |
| L_{C299} | R^{D9} | R^{D43} |
| L_{C300} | R^{D9} | R^{D48} |
| L_{C301} | R^{D9} | R^{D49} |
| L_{C302} | R^{D9} | R^{D50} |
| L_{C303} | R^{D9} | R^{D54} |
| L_{C304} | R^{D9} | R^{D55} |
| L_{C305} | R^{D9} | R^{D58} |
| L_{C306} | R^{D9} | R^{D59} |
| L_{C307} | R^{D9} | R^{D78} |
| L_{C308} | R^{D9} | R^{D79} |
| L_{C309} | R^{D9} | R^{D81} |
| L_{C310} | R^{D9} | R^{D87} |
| L_{C311} | R^{D9} | R^{D88} |
| L_{C312} | R^{D9} | R^{D89} |
| L_{C313} | R^{D9} | R^{D93} |
| L_{C314} | R^{D9} | R^{D116} |
| L_{C315} | R^{D9} | R^{D117} |
| L_{C316} | R^{D9} | R^{D118} |
| L_{C317} | R^{D9} | R^{D119} |
| L_{C318} | R^{D9} | R^{D120} |
| L_{C319} | R^{D9} | R^{D133} |
| L_{C320} | R^{D9} | R^{D134} |
| L_{C321} | R^{D9} | R^{D135} |
| L_{C322} | R^{D9} | R^{D136} |
| L_{C323} | R^{D9} | R^{D143} |
| L_{C324} | R^{D9} | R^{D144} |
| L_{C325} | R^{D9} | R^{D145} |
| L_{C326} | R^{D9} | R^{D146} |
| L_{C327} | R^{D9} | R^{D147} |
| L_{C328} | R^{D9} | R^{D149} |
| L_{C329} | R^{D9} | R^{D151} |
| L_{C330} | R^{D9} | R^{D154} |
| L_{C331} | R^{D9} | R^{D155} |
| L_{C332} | R^{D9} | R^{D161} |
| L_{C333} | R^{D9} | R^{D175} |
| L_{C334} | R^{D10} | R^{D3} |
| L_{C335} | R^{D10} | R^{D5} |
| L_{C336} | R^{D10} | R^{D17} |
| L_{C337} | R^{D10} | R^{D18} |
| L_{C338} | R^{D10} | R^{D20} |
| L_{C339} | R^{D10} | R^{D22} |
| L_{C340} | R^{D10} | R^{D37} |
| L_{C341} | R^{D10} | R^{D40} |
| L_{C342} | R^{D10} | R^{D41} |
| L_{C343} | R^{D10} | R^{D42} |
| L_{C344} | R^{D10} | R^{D43} |
| L_{C345} | R^{D10} | R^{D48} |
| L_{C346} | R^{D10} | R^{D49} |
| L_{C347} | R^{D10} | R^{D50} |
| L_{C348} | R^{D10} | R^{D54} |
| L_{C349} | R^{D10} | R^{D55} |
| L_{C350} | R^{D10} | R^{D58} |
| L_{C351} | R^{D10} | R^{D59} |
| L_{C352} | R^{D10} | R^{D78} |
| L_{C353} | R^{D10} | R^{D79} |
| L_{C354} | R^{D10} | R^{D81} |
| L_{C355} | R^{D10} | R^{D87} |
| L_{C356} | R^{D10} | R^{D88} |
| L_{C357} | R^{D10} | R^{D89} |
| L_{C358} | R^{D10} | R^{D93} |
| L_{C359} | R^{D10} | R^{D116} |
| L_{C360} | R^{D10} | R^{D117} |
| L_{C361} | R^{D10} | R^{D118} |
| L_{C362} | R^{D10} | R^{D119} |
| L_{C363} | R^{D10} | R^{D120} |
| L_{C364} | R^{D10} | R^{D133} |
| L_{C365} | R^{D10} | R^{D134} |
| L_{C366} | R^{D10} | R^{D135} |
| L_{C367} | R^{D10} | R^{D136} |
| L_{C368} | R^{D10} | R^{D143} |
| L_{C369} | R^{D10} | R^{D144} |
| L_{C370} | R^{D10} | R^{D145} |
| L_{C371} | R^{D10} | R^{D146} |
| L_{C372} | R^{D10} | R^{D147} |
| L_{C373} | R^{D10} | R^{D149} |
| L_{C374} | R^{D10} | R^{D151} |
| L_{C375} | R^{D10} | R^{D154} |
| L_{C376} | R^{D10} | R^{D155} |
| L_{C377} | R^{D10} | R^{D161} |
| L_{C378} | R^{D10} | R^{D175} |
| L_{C379} | R^{D17} | R^{D3} |
| L_{C380} | R^{D17} | R^{D5} |
| L_{C381} | R^{D17} | R^{D18} |
| L_{C382} | R^{D17} | R^{D20} |
| L_{C383} | R^{D17} | R^{D22} |
| L_{C384} | R^{D17} | R^{D37} |
| L_{C385} | R^{D17} | R^{D40} |
| L_{C386} | R^{D17} | R^{D41} |
| L_{C387} | R^{D17} | R^{D42} |
| L_{C388} | R^{D17} | R^{D43} |
| L_{C389} | R^{D17} | R^{D48} |
| L_{C390} | R^{D17} | R^{D49} |
| L_{C391} | R^{D17} | R^{D50} |
| L_{C392} | R^{D17} | R^{D54} |
| L_{C393} | R^{D17} | R^{D55} |
| L_{C394} | R^{D17} | R^{D58} |
| L_{C395} | R^{D17} | R^{D59} |
| L_{C396} | R^{D17} | R^{D78} |
| L_{C397} | R^{D17} | R^{D79} |
| L_{C398} | R^{D17} | R^{D81} |
| L_{C399} | R^{D17} | R^{D87} |
| L_{C400} | R^{D17} | R^{D88} |
| L_{C401} | R^{D17} | R^{D89} |
| L_{C402} | R^{D17} | R^{D93} |
| L_{C403} | R^{D17} | R^{D116} |
| L_{C404} | R^{D17} | R^{D117} |
| L_{C405} | R^{D17} | R^{D118} |
| L_{C406} | R^{D17} | R^{D119} |
| L_{C407} | R^{D17} | R^{D120} |
| L_{C408} | R^{D17} | R^{D133} |
| L_{C409} | R^{D17} | R^{D134} |
| L_{C410} | R^{D17} | R^{D135} |
| L_{C411} | R^{D17} | R^{D136} |
| L_{C412} | R^{D17} | R^{D143} |
| L_{C413} | R^{D17} | R^{D144} |
| L_{C414} | R^{D17} | R^{D145} |
| L_{C415} | R^{D17} | R^{D146} |
| L_{C416} | R^{D17} | R^{D147} |
| L_{C417} | R^{D17} | R^{D149} |
| L_{C418} | R^{D17} | R^{D151} |
| L_{C419} | R^{D17} | R^{D154} |
| L_{C420} | R^{D17} | R^{D155} |
| L_{C421} | R^{D17} | R^{D161} |
| L_{C422} | R^{D17} | R^{D175} |
| L_{C423} | R^{D50} | R^{D3} |
| L_{C424} | R^{D50} | R^{D5} |
| L_{C425} | R^{D50} | R^{D18} |
| L_{C426} | R^{D50} | R^{D20} |
| L_{C427} | R^{D50} | R^{D22} |
| L_{C428} | R^{D50} | R^{D37} |
| L_{C429} | R^{D50} | R^{D40} |
| L_{C430} | R^{D50} | R^{D41} |
| L_{C431} | R^{D50} | R^{D42} |
| L_{C432} | R^{D50} | R^{D43} |
| L_{C433} | R^{D50} | R^{D48} |
| L_{C434} | R^{D50} | R^{D49} |
| L_{C435} | R^{D50} | R^{D54} |
| L_{C436} | R^{D50} | R^{D55} |
| L_{C437} | R^{D50} | R^{D58} |
| L_{C438} | R^{D50} | R^{D59} |
| L_{C439} | R^{D50} | R^{D78} |
| L_{C440} | R^{D50} | R^{D79} |
| L_{C441} | R^{D50} | R^{D81} |
| L_{C442} | R^{D50} | R^{D87} |
| L_{C443} | R^{D50} | R^{D88} |
| L_{C444} | R^{D50} | R^{D89} |
| L_{C445} | R^{D50} | R^{D93} |
| L_{C446} | R^{D50} | R^{D116} |
| L_{C447} | R^{D50} | R^{D117} |
| L_{C448} | R^{D50} | R^{D118} |
| L_{C449} | R^{D50} | R^{D119} |
| L_{C450} | R^{D50} | R^{D120} |
| L_{C451} | R^{D50} | R^{D133} |
| L_{C452} | R^{D50} | R^{D134} |
| L_{C453} | R^{D50} | R^{D135} |
| L_{C454} | R^{D50} | R^{D136} |
| L_{C455} | R^{D50} | R^{D143} |
| L_{C456} | R^{D50} | R^{D144} |
| L_{C457} | R^{D50} | R^{D145} |
| L_{C458} | R^{D50} | R^{D146} |
| L_{C459} | R^{D50} | R^{D147} |
| L_{C460} | R^{D50} | R^{D149} |
| L_{C461} | R^{D50} | R^{D151} |
| L_{C462} | R^{D50} | R^{D154} |
| L_{C463} | R^{D50} | R^{D155} |
| L_{C464} | R^{D50} | R^{D161} |
| L_{C465} | R^{D50} | R^{D175} |
| L_{C466} | R^{D55} | R^{D3} |
| L_{C467} | R^{D55} | R^{D5} |
| L_{C468} | R^{D55} | R^{D18} |
| L_{C469} | R^{D55} | R^{D20} |
| L_{C470} | R^{D55} | R^{D22} |
| L_{C471} | R^{D55} | R^{D37} |
| L_{C472} | R^{D55} | R^{D40} |
| L_{C473} | R^{D55} | R^{D41} |
| L_{C474} | R^{D55} | R^{D42} |
| L_{C475} | R^{D55} | R^{D43} |
| L_{C476} | R^{D55} | R^{D48} |
| L_{C477} | R^{D55} | R^{D49} |
| L_{C478} | R^{D55} | R^{D54} |
| L_{C479} | R^{D55} | R^{D58} |
| L_{C480} | R^{D55} | R^{D59} |
| L_{C481} | R^{D55} | R^{D78} |
| L_{C482} | R^{D55} | R^{D79} |
| L_{C483} | R^{D55} | R^{D81} |
| L_{C484} | R^{D55} | R^{D87} |
| L_{C485} | R^{D55} | R^{D88} |
| L_{C486} | R^{D55} | R^{D89} |
| L_{C487} | R^{D55} | R^{D93} |
| L_{C488} | R^{D55} | R^{D116} |
| L_{C489} | R^{D55} | R^{D117} |
| L_{C490} | R^{D55} | R^{D118} |
| L_{C491} | R^{D55} | R^{D119} |
| L_{C492} | R^{D55} | R^{D120} |
| L_{C493} | R^{D55} | R^{D133} |
| L_{C494} | R^{D55} | R^{D134} |
| L_{C495} | R^{D55} | R^{D135} |
| L_{C496} | R^{D55} | R^{D136} |
| L_{C497} | R^{D55} | R^{D143} |
| L_{C498} | R^{D55} | R^{D144} |
| L_{C499} | R^{D55} | R^{D145} |
| L_{C500} | R^{D55} | R^{D146} |
| L_{C501} | R^{D55} | R^{D147} |
| L_{C502} | R^{D55} | R^{D149} |
| L_{C503} | R^{D55} | R^{D151} |
| L_{C504} | R^{D55} | R^{D154} |
| L_{C505} | R^{D55} | R^{D155} |
| L_{C506} | R^{D55} | R^{D161} |
| L_{C507} | R^{D55} | R^{D175} |
| L_{C508} | R^{D116} | R^{D3} |
| L_{C509} | R^{D116} | R^{D5} |
| L_{C510} | R^{D116} | R^{D17} |
| L_{C511} | R^{D116} | R^{D18} |
| L_{C512} | R^{D116} | R^{D20} |
| L_{C513} | R^{D116} | R^{D22} |
| L_{C514} | R^{D116} | R^{D37} |
| L_{C515} | R^{D116} | R^{D40} |
| L_{C516} | R^{D116} | R^{D41} |
| L_{C517} | R^{D116} | R^{D42} |
| L_{C518} | R^{D116} | R^{D43} |
| L_{C519} | R^{D116} | R^{D48} |
| L_{C520} | R^{D116} | R^{D49} |
| L_{C521} | R^{D116} | R^{D54} |
| L_{C522} | R^{D116} | R^{D58} |
| L_{C523} | R^{D116} | R^{D59} |
| L_{C524} | R^{D116} | R^{D78} |
| L_{C525} | R^{D116} | R^{D79} |
| L_{C526} | R^{D116} | R^{D81} |
| L_{C527} | R^{D116} | R^{D87} |
| L_{C528} | R^{D116} | R^{D88} |
| L_{C529} | R^{D116} | R^{D89} |
| L_{C530} | R^{D116} | R^{D93} |
| L_{C531} | R^{D116} | R^{D117} |
| L_{C532} | R^{D116} | R^{D118} |
| L_{C533} | R^{D116} | R^{D119} |
| L_{C534} | R^{D116} | R^{D120} |
| L_{C535} | R^{D116} | R^{D133} |
| L_{C536} | R^{D116} | R^{D134} |
| L_{C537} | R^{D116} | R^{D135} |
| L_{C538} | R^{D116} | R^{D136} |
| L_{C539} | R^{D116} | R^{D143} |
| L_{C540} | R^{D116} | R^{D144} |
| L_{C541} | R^{D116} | R^{D145} |
| L_{C542} | R^{D116} | R^{D146} |
| L_{C543} | R^{D116} | R^{D147} |
| L_{C544} | R^{D116} | R^{D149} |
| L_{C545} | R^{D116} | R^{D151} |
| L_{C546} | R^{D116} | R^{D154} |
| L_{C547} | R^{D116} | R^{D155} |
| L_{C548} | R^{D116} | R^{D161} |
| L_{C549} | R^{D116} | R^{D175} |
| L_{C550} | R^{D143} | R^{D3} |
| L_{C551} | R^{D143} | R^{D5} |
| L_{C552} | R^{D143} | R^{D17} |
| L_{C553} | R^{D143} | R^{D18} |
| L_{C554} | R^{D143} | R^{D20} |
| L_{C555} | R^{D143} | R^{D22} |
| L_{C556} | R^{D143} | R^{D37} |
| L_{C557} | R^{D143} | R^{D40} |
| L_{C558} | R^{D143} | R^{D41} |
| L_{C559} | R^{D143} | R^{D42} |
| L_{C560} | R^{D143} | R^{D43} |
| L_{C561} | R^{D143} | R^{D48} |
| L_{C562} | R^{D143} | R^{D49} |
| L_{C563} | R^{D143} | R^{D54} |
| L_{C564} | R^{D143} | R^{D58} |
| L_{C565} | R^{D143} | R^{D59} |
| L_{C566} | R^{D143} | R^{D78} |
| L_{C567} | R^{D143} | R^{D79} |
| L_{C568} | R^{D143} | R^{D81} |
| L_{C569} | R^{D143} | R^{D87} |
| L_{C570} | R^{D143} | R^{D88} |
| L_{C571} | R^{D143} | R^{D89} |
| L_{C572} | R^{D143} | R^{D93} |
| L_{C573} | R^{D143} | R^{D116} |
| L_{C574} | R^{D143} | R^{D117} |
| L_{C575} | R^{D143} | R^{D118} |
| L_{C576} | R^{D143} | R^{D119} |
| L_{C577} | R^{D143} | R^{D120} |
| L_{C578} | R^{D143} | R^{D133} |
| L_{C579} | R^{D143} | R^{D134} |
| L_{C580} | R^{D143} | R^{D135} |
| L_{C581} | R^{D143} | R^{D136} |
| L_{C582} | R^{D143} | R^{D144} |
| L_{C583} | R^{D143} | R^{D145} |
| L_{C584} | R^{D143} | R^{D146} |
| L_{C585} | R^{D143} | R^{D147} |
| L_{C586} | R^{D143} | R^{D149} |
| L_{C587} | R^{D143} | R^{D151} |
| L_{C588} | R^{D143} | R^{D154} |
| L_{C589} | R^{D143} | R^{D155} |
| L_{C590} | R^{D143} | R^{D161} |
| L_{C591} | R^{D143} | R^{D175} |
| L_{C592} | R^{D144} | R^{D3} |
| L_{C593} | R^{D144} | R^{D5} |
| L_{C594} | R^{D144} | R^{D17} |
| L_{C595} | R^{D144} | R^{D18} |
| L_{C596} | R^{D144} | R^{D20} |
| L_{C597} | R^{D144} | R^{D22} |
| L_{C598} | R^{D144} | R^{D37} |
| L_{C599} | R^{D144} | R^{D40} |
| L_{C600} | R^{D144} | R^{D41} |
| L_{C601} | R^{D144} | R^{D42} |
| L_{C602} | R^{D144} | R^{D43} |
| L_{C603} | R^{D144} | R^{D48} |
| L_{C604} | R^{D144} | R^{D49} |
| L_{C605} | R^{D144} | R^{D54} |
| L_{C606} | R^{D144} | R^{D58} |
| L_{C607} | R^{D144} | R^{D59} |
| L_{C608} | R^{D144} | R^{D78} |
| L_{C609} | R^{D144} | R^{D79} |
| L_{C610} | R^{D144} | R^{D81} |
| L_{C611} | R^{D144} | R^{D87} |
| L_{C612} | R^{D144} | R^{D88} |
| L_{C613} | R^{D144} | R^{D89} |
| L_{C614} | R^{D144} | R^{D93} |
| L_{C615} | R^{D144} | R^{D116} |
| L_{C616} | R^{D144} | R^{D117} |
| L_{C617} | R^{D144} | R^{D118} |
| L_{C618} | R^{D144} | R^{D119} |
| L_{C619} | R^{D144} | R^{D120} |
| L_{C620} | R^{D144} | R^{D133} |
| L_{C621} | R^{D144} | R^{D134} |
| L_{C622} | R^{D144} | R^{D135} |
| L_{C623} | R^{D144} | R^{D136} |
| L_{C624} | R^{D144} | R^{D145} |
| L_{C625} | R^{D144} | R^{D146} |
| L_{C626} | R^{D144} | R^{D147} |
| L_{C627} | R^{D144} | R^{D149} |
| L_{C628} | R^{D144} | R^{D151} |
| L_{C629} | R^{D144} | R^{D154} |
| L_{C630} | R^{D144} | R^{D155} |
| L_{C631} | R^{D144} | R^{D161} |
| L_{C632} | R^{D144} | R^{D175} |
| L_{C633} | R^{D145} | R^{D3} |
| L_{C634} | R^{D145} | R^{D5} |
| L_{C635} | R^{D145} | R^{D17} |
| L_{C636} | R^{D145} | R^{D18} |
| L_{C637} | R^{D145} | R^{D20} |
| L_{C638} | R^{D145} | R^{D22} |
| L_{C639} | R^{D145} | R^{D37} |
| L_{C640} | R^{D145} | R^{D40} |
| L_{C641} | R^{D145} | R^{D41} |
| L_{C642} | R^{D145} | R^{D42} |
| L_{C643} | R^{D145} | R^{D43} |
| L_{C644} | R^{D145} | R^{D48} |
| L_{C645} | R^{D145} | R^{D49} |
| L_{C646} | R^{D145} | R^{D54} |
| L_{C647} | R^{D145} | R^{D58} |
| L_{C648} | R^{D145} | R^{D59} |
| L_{C649} | R^{D145} | R^{D78} |
| L_{C650} | R^{D145} | R^{D79} |
| L_{C651} | R^{D145} | R^{D81} |
| L_{C652} | R^{D145} | R^{D87} |
| L_{C653} | R^{D145} | R^{D88} |
| L_{C654} | R^{D145} | R^{D89} |
| L_{C655} | R^{D145} | R^{D93} |
| L_{C656} | R^{D145} | R^{D116} |
| L_{C657} | R^{D145} | R^{D117} |
| L_{C658} | R^{D145} | R^{D118} |
| L_{C659} | R^{D145} | R^{D119} |
| L_{C660} | R^{D145} | R^{D120} |
| L_{C661} | R^{D145} | R^{D133} |
| L_{C662} | R^{D145} | R^{D134} |
| L_{C63} | R^{D145} | R^{D135} |
| L_{C664} | R^{D145} | R^{D136} |
| L_{C665} | R^{D145} | R^{D146} |
| L_{C666} | R^{D145} | R^{D147} |
| L_{C667} | R^{D145} | R^{D149} |
| L_{C668} | R^{D145} | R^{D151} |
| L_{C669} | R^{D145} | R^{D154} |
| L_{C670} | R^{D145} | R^{D155} |
| L_{C671} | R^{D145} | R^{D161} |
| L_{C672} | R^{D145} | R^{D175} |
| L_{C673} | R^{D146} | R^{D3} |
| L_{C674} | R^{D146} | R^{D5} |
| L_{C675} | R^{D146} | R^{D17} |
| L_{C676} | R^{D146} | R^{D18} |
| L_{C677} | R^{D146} | R^{D20} |
| L_{C678} | R^{D146} | R^{D22} |
| L_{C679} | R^{D146} | R^{D37} |
| L_{C680} | R^{D146} | R^{D40} |
| L_{C681} | R^{D146} | R^{D41} |
| L_{C682} | R^{D146} | R^{D42} |
| L_{C683} | R^{D146} | R^{D43} |
| L_{C684} | R^{D146} | R^{D48} |
| L_{C685} | R^{D146} | R^{D49} |
| L_{C686} | R^{D146} | R^{D54} |
| L_{C687} | R^{D146} | R^{D58} |
| L_{C688} | R^{D146} | R^{D59} |
| L_{C689} | R^{D146} | R^{D78} |
| L_{C690} | R^{D146} | R^{D79} |
| L_{C691} | R^{D146} | R^{D81} |
| L_{C692} | R^{D146} | R^{D87} |
| L_{C693} | R^{D146} | R^{D88} |
| L_{C694} | R^{D146} | R^{D89} |
| L_{C695} | R^{D146} | R^{D93} |
| L_{C696} | R^{D146} | R^{D117} |
| L_{C697} | R^{D146} | R^{D118} |
| L_{C698} | R^{D146} | R^{D119} |
| L_{C699} | R^{D146} | R^{D120} |
| L_{C700} | R^{D146} | R^{D133} |
| L_{C701} | R^{D146} | R^{D134} |
| L_{C702} | R^{D146} | R^{D135} |
| L_{C703} | R^{D146} | R^{D136} |
| L_{C704} | R^{D146} | R^{D146} |
| L_{C705} | R^{D146} | R^{D147} |
| L_{C706} | R^{D146} | R^{D149} |
| L_{C707} | R^{D146} | R^{D151} |
| L_{C708} | R^{D146} | R^{D154} |
| L_{C709} | R^{D146} | R^{D155} |
| L_{C710} | R^{D146} | R^{D161} |
| L_{C711} | R^{D146} | R^{D175} |
| L_{C712} | R^{D133} | R^{D3} |
| L_{C713} | R^{D133} | R^{D5} |
| L_{C714} | R^{D133} | R^{D3} |
| L_{C715} | R^{D133} | R^{D18} |
| L_{C716} | R^{D133} | R^{D20} |
| L_{C717} | R^{D133} | R^{D22} |
| L_{C718} | R^{D133} | R^{D37} |
| L_{C719} | R^{D133} | R^{D40} |
| L_{C720} | R^{D133} | R^{D41} |
| L_{C721} | R^{D133} | R^{D42} |
| L_{C722} | R^{D133} | R^{D43} |
| L_{C723} | R^{D133} | R^{D48} |
| L_{C724} | R^{D133} | R^{D49} |
| L_{C725} | R^{D133} | R^{D54} |
| L_{C726} | R^{D133} | R^{D58} |
| L_{C727} | R^{D133} | R^{D59} |
| L_{C728} | R^{D133} | R^{D78} |
| L_{C729} | R^{D133} | R^{D79} |
| L_{C730} | R^{D133} | R^{D81} |
| L_{C731} | R^{D133} | R^{D87} |
| L_{C732} | R^{D133} | R^{D88} |
| L_{C733} | R^{D133} | R^{D89} |
| L_{C734} | R^{D133} | R^{D93} |
| L_{C735} | R^{D133} | R^{D117} |
| L_{C736} | R^{D133} | R^{D118} |
| L_{C737} | R^{D133} | R^{D119} |
| L_{C738} | R^{D133} | R^{D120} |
| L_{C739} | R^{D133} | R^{D133} |
| L_{C740} | R^{D133} | R^{D134} |
| L_{C741} | R^{D133} | R^{D135} |
| L_{C742} | R^{D133} | R^{D136} |
| L_{C743} | R^{D133} | R^{D146} |
| L_{C744} | R^{D133} | R^{D147} |
| L_{C745} | R^{D133} | R^{D149} |
| L_{C746} | R^{D133} | R^{D151} |
| L_{C747} | R^{D133} | R^{D154} |
| L_{C748} | R^{D133} | R^{D155} |
| L_{C749} | R^{D133} | R^{D161} |
| L_{C750} | R^{D133} | R^{D175} |
| L_{C751} | R^{D175} | R^{D3} |
| L_{C752} | R^{D175} | R^{D5} |
| L_{C753} | R^{D175} | R^{D18} |
| L_{C754} | R^{D175} | R^{D20} |
| L_{C755} | R^{D175} | R^{D22} |
| L_{C756} | R^{D175} | R^{D37} |
| L_{C757} | R^{D175} | R^{D40} |
| L_{C758} | R^{D175} | R^{D41} |
| L_{C759} | R^{D175} | R^{D42} |
| L_{C760} | R^{D175} | R^{D43} |
| L_{C761} | R^{D175} | R^{D48} |
| L_{C762} | R^{D175} | R^{D49} |
| L_{C763} | R^{D175} | R^{D54} |
| L_{C764} | R^{D175} | R^{D58} |
| L_{C765} | R^{D175} | R^{D59} |
| L_{C766} | R^{D175} | R^{D78} |
| L_{C767} | R^{D175} | R^{D79} |
| L_{C768} | R^{D175} | R^{D81} |
| L_{C769} | R^{D193} | R^{D193} |
| L_{C770} | R^{D194} | R^{D194} |
| L_{C771} | R^{D195} | R^{D195} |
| L_{C772} | R^{D196} | R^{D196} |
| L_{C773} | R^{D197} | R^{D197} |
| L_{C774} | R^{D198} | R^{D198} |
| L_{C775} | R^{D199} | R^{D199} |
| L_{C776} | R^{D200} | R^{D200} |
| L_{C777} | R^{D201} | R^{D201} |
| L_{C778} | R^{D202} | R^{D202} |
| L_{C779} | R^{D203} | R^{D203} |
| L_{C780} | R^{D204} | R^{D204} |
| L_{C781} | R^{D205} | R^{D205} |
| L_{C782} | R^{D206} | R^{D206} |
| L_{C783} | R^{D207} | R^{D207} |
| L_{C784} | R^{D208} | R^{D208} |
| L_{C785} | R^{D209} | R^{D209} |
| L_{C786} | R^{D210} | R^{D210} |
| L_{C787} | R^{D211} | R^{D211} |
| L_{C788} | R^{D212} | R^{D212} |
| L_{C789} | R^{D213} | R^{D213} |
| L_{C790} | R^{D214} | R^{D214} |
| L_{C791} | R^{D215} | R^{D215} |
| L_{C792} | R^{D216} | R^{D216} |
| L_{C793} | R^{D217} | R^{D217} |
| L_{C794} | R^{D218} | R^{D218} |
| L_{C795} | R^{D219} | R^{D219} |
| L_{C796} | R^{D220} | R^{D220} |
| L_{C797} | R^{D221} | R^{D221} |
| L_{C798} | R^{D222} | R^{D222} |
| L_{C799} | R^{D223} | R^{D223} |
| L_{C800} | R^{D224} | R^{D224} |
| L_{C801} | R^{D225} | R^{D225} |
| L_{C802} | R^{D226} | R^{D226} |
| L_{C803} | R^{D227} | R^{D227} |
| L_{C804} | R^{D228} | R^{D228} |
| L_{C805} | R^{D229} | R^{D229} |
| L_{C806} | R^{D230} | R^{D230} |
| L_{C807} | R^{D231} | R^{D231} |
| L_{C808} | R^{D232} | R^{D232} |
| L_{C809} | R^{D233} | R^{D233} |
| L_{C810} | R^{D234} | R^{D234} |
| L_{C811} | R^{D235} | R^{D235} |
| L_{C812} | R^{D236} | R^{D236} |
| L_{C813} | R^{D237} | R^{D237} |
| L_{C814} | R^{D238} | R^{D238} |
| L_{C815} | R^{D239} | R^{D239} |
| L_{C816} | R^{D240} | R^{D240} |
| L_{C817} | R^{D241} | R^{D241} |
| L_{C818} | R^{D242} | R^{D242} |
| L_{C819} | R^{D243} | R^{D243} |
| L_{C820} | R^{D244} | R^{D244} |
| L_{C821} | R^{D245} | R^{D245} |
| L_{C822} | R^{D246} | R^{D246} |
| L_{C823} | R^{D17} | R^{D193} |
| L_{C824} | R^{D17} | R^{D194} |
| L_{C825} | R^{D17} | R^{D195} |
| L_{C826} | R^{D17} | R^{D196} |
| L_{C827} | R^{D17} | R^{D197} |
| L_{C828} | R^{D17} | R^{D198} |
| L_{C829} | R^{D17} | R^{D199} |
| L_{C830} | R^{D17} | R^{D200} |
| L_{C831} | R^{D17} | R^{D201} |
| L_{C832} | R^{D17} | R^{D202} |
| L_{C833} | R^{D17} | R^{D203} |
| L_{C834} | R^{D17} | R^{D204} |
| L_{C835} | R^{D17} | R^{D205} |
| L_{C836} | R^{D17} | R^{D206} |
| L_{C837} | R^{D17} | R^{D207} |
| L_{C838} | R^{D17} | R^{D208} |
| L_{C839} | R^{D17} | R^{D209} |
| L_{C840} | R^{D17} | R^{D210} |
| L_{C841} | R^{D17} | R^{D211} |
| L_{C842} | R^{D17} | R^{D212} |
| L_{C843} | R^{D17} | R^{D213} |
| L_{C844} | R^{D17} | R^{D214} |
| L_{C845} | R^{D17} | R^{D215} |
| L_{C846} | R^{D17} | R^{D216} |
| L_{C847} | R^{D17} | R^{D217} |
| L_{C848} | R^{D17} | R^{D218} |
| L_{C849} | R^{D17} | R^{D219} |
| L_{C850} | R^{D17} | R^{D220} |
| L_{C851} | R^{D17} | R^{D221} |
| L_{C852} | R^{D17} | R^{D222} |
| L_{C853} | R^{D17} | R^{D223} |
| L_{C854} | R^{D17} | R^{D224} |
| L_{C855} | R^{D17} | R^{D225} |
| L_{C856} | R^{D17} | R^{D226} |
| L_{C857} | R^{D17} | R^{D227} |
| L_{C858} | R^{D17} | R^{D228} |
| L_{C859} | R^{D17} | R^{D229} |
| L_{C860} | R^{D17} | R^{D230} |
| L_{C861} | R^{D17} | R^{D231} |
| L_{C862} | R^{D17} | R^{D232} |
| L_{C863} | R^{D17} | R^{D233} |
| L_{C864} | R^{D17} | R^{D234} |
| L_{C865} | R^{D17} | R^{D235} |
| L_{C866} | R^{D17} | R^{D236} |
| L_{C867} | R^{D17} | R^{D237} |
| L_{C868} | R^{D17} | R^{D238} |
| L_{C869} | R^{D17} | R^{D239} |
| L_{C870} | R^{D17} | R^{D240} |
| L_{C871} | R^{D17} | R^{D241} |
| L_{C872} | R^{D17} | R^{D242} |
| L_{C873} | R^{D17} | R^{D243} |
| L_{C874} | R^{D17} | R^{D244} |
| L_{C875} | R^{D17} | R^{D245} |
| L_{C876} | R^{D17} | R^{D246} |
| L_{C877} | R^{D1} | R^{D193} |
| L_{C878} | R^{D1} | R^{D194} |
| L_{C879} | R^{D1} | R^{D195} |
| L_{C880} | R^{D1} | R^{D196} |
| L_{C881} | R^{D1} | R^{D197} |
| L_{C882} | R^{D1} | R^{D198} |
| L_{C883} | R^{D1} | R^{D199} |
| L_{C884} | R^{D1} | R^{D200} |
| L_{C885} | R^{D1} | R^{D201} |
| L_{C886} | R^{D1} | R^{D202} |
| L_{C887} | R^{D1} | R^{D203} |
| L_{C888} | R^{D1} | R^{D204} |
| L_{C889} | R^{D1} | R^{D205} |
| L_{C890} | R^{D1} | R^{D206} |
| L_{C891} | R^{D1} | R^{D207} |
| L_{C892} | R^{D1} | R^{D208} |
| L_{C893} | R^{D1} | R^{D209} |
| L_{C894} | R^{D1} | R^{D210} |
| L_{C895} | R^{D1} | R^{D211} |
| L_{C896} | R^{D1} | R^{D212} |
| L_{C897} | R^{DI} | R^{D213} |
| L_{C898} | R^{D1} | R^{D214} |
| L_{C899} | R^{D1} | R^{D215} |
| L_{C900} | R^{D1} | R^{D216} |
| L_{C901} | R^{D1} | R^{D217} |
| L_{C902} | R^{D1} | R^{D218} |
| L_{C903} | R^{D1} | R^{D219} |
| L_{C904} | R^{D1} | R^{D220} |
| L_{C905} | R^{D1} | R^{D221} |
| L_{C906} | R^{D1} | R^{D222} |
| L_{C907} | R^{D1} | R^{D223} |
| L_{C908} | R^{D1} | R^{D224} |
| L_{C909} | R^{D1} | R^{D225} |
| L_{C910} | R^{D1} | R^{D226} |
| L_{C911} | R^{D1} | R^{D227} |
| L_{C912} | R^{D1} | R^{D228} |
| L_{C913} | R^{D1} | R^{D229} |
| L_{C914} | R^{D1} | R^{D230} |
| L_{C915} | R^{D1} | R^{D231} |
| L_{C916} | R^{D1} | R^{D232} |
| L_{C917} | R^{D1} | R^{D233} |
| L_{C918} | R^{D1} | R^{D234} |
| L_{C919} | R^{D1} | R^{D235} |
| L_{C920} | R^{D1} | R^{D236} |
| L_{C921} | R^{D1} | R^{D237} |
| L_{C922} | R^{D1} | R^{D238} |
| L_{C923} | R^{D1} | R^{D239} |
| L_{C924} | R^{D1} | R^{D240} |
| L_{C925} | R^{D1} | R^{D241} |
| L_{C926} | R^{D1} | R^{D242} |
| L_{C927} | R^{D1} | R^{D243} |
| L_{C928} | R^{D1} | R^{D244} |
| L_{C929} | R^{D1} | R^{D245} |
| L_{C930} | R^{D1} | R^{D246} |
| L_{C931} | R^{D50} | R^{D193} |
| L_{C932} | R^{D50} | R^{D194} |
| L_{C933} | R^{D50} | R^{D195} |
| L_{C934} | R^{D50} | R^{D196} |
| L_{C935} | R^{D50} | R^{D197} |
| L_{C936} | R^{D50} | R^{D198} |
| L_{C937} | R^{D50} | R^{D199} |
| L_{C938} | R^{D50} | R^{D200} |
| L_{C939} | R^{D50} | R^{D201} |
| L_{C940} | R^{D50} | R^{D202} |
| L_{C941} | R^{D50} | R^{D203} |
| L_{C942} | R^{D50} | R^{D204} |
| L_{C943} | R^{D50} | R^{D205} |
| L_{C944} | R^{D50} | R^{D206} |
| L_{C945} | R^{D50} | R^{D207} |
| L_{C946} | R^{D50} | R^{D208} |
| L_{C947} | R^{D50} | R^{D209} |
| L_{C948} | R^{D50} | R^{D210} |
| L_{C949} | R^{D50} | R^{D211} |
| L_{C950} | R^{D50} | R^{D212} |
| L_{C951} | R^{D50} | R^{D213} |
| L_{C952} | R^{D50} | R^{D214} |
| L_{C953} | R^{D50} | R^{D215} |
| L_{C954} | R^{D50} | R^{D216} |
| L_{C955} | R^{D50} | R^{D217} |
| L_{C956} | R^{D50} | R^{D218} |
| L_{C957} | R^{D50} | R^{D219} |
| L_{C958} | R^{D50} | R^{D220} |
| L_{C959} | R^{D50} | R^{D221} |
| L_{C960} | R^{D50} | R^{D222} |
| L_{C961} | R^{D50} | R^{D223} |
| L_{C962} | R^{D50} | R^{D224} |
| L_{C963} | R^{D50} | R^{D225} |
| L_{C964} | R^{D50} | R^{D226} |
| L_{C965} | R^{D50} | R^{D227} |
| L_{C966} | R^{D50} | R^{D228} |
| L_{C967} | R^{D50} | R^{D229} |
| L_{C968} | R^{D50} | R^{D230} |
| L_{C969} | R^{D50} | R^{D231} |
| L_{C970} | R^{D50} | R^{D232} |
| L_{C971} | R^{D50} | R^{D233} |
| L_{C972} | R^{D50} | R^{D234} |
| L_{C973} | R^{D50} | R^{D235} |
| L_{C974} | R^{D50} | R^{D236} |
| L_{C975} | R^{D50} | R^{D237} |
| L_{C976} | R^{D50} | R^{D238} |
| L_{C977} | R^{D50} | R^{D239} |
| L_{C978} | R^{D50} | R^{D240} |
| L_{C979} | R^{D50} | R^{D241} |
| L_{C980} | R^{D50} | R^{D242} |
| L_{C981} | R^{D50} | R^{D243} |
| L_{C982} | R^{D50} | R^{D244} |
| L_{C983} | R^{D50} | R^{D245} |
| L_{C984} | R^{D50} | R^{D246} |
| L_{C985} | R^{D4} | R^{D193} |
| L_{C986} | R^{D4} | R^{D194} |
| L_{C987} | R^{D4} | R^{D195} |
| L_{C988} | R^{D4} | R^{D196} |
| L_{C989} | R^{D4} | R^{D197} |
| L_{C990} | R^{D4} | R^{D198} |
| L_{C991} | R^{D4} | R^{D199} |
| L_{C992} | R^{D4} | R^{D200} |
| L_{C993} | R^{D4} | R^{D201} |
| L_{C994} | R^{D4} | R^{D202} |
| L_{C995} | R^{D4} | R^{D203} |
| L_{C996} | R^{D4} | R^{D204} |
| L_{C997} | R^{D4} | R^{D205} |
| L_{C998} | R^{D4} | R^{D206} |
| L_{C999} | R^{D4} | R^{D207} |
| L_{C1000} | R^{D4} | R^{D208} |
| L_{C1001} | R^{D4} | R^{D209} |
| L_{C1002} | R^{D4} | R^{D210} |
| L_{C1003} | R^{D4} | R^{D211} |
| L_{C1004} | R^{D4} | R^{D212} |
| L_{C1005} | R^{D4} | R^{D213} |
| L_{C1006} | R^{D4} | R^{D214} |
| L_{C1007} | R^{D4} | R^{D215} |
| L_{C1008} | R^{D4} | R^{D216} |
| L_{C1009} | R^{D4} | R^{D217} |
| L_{C1010} | R^{D4} | R^{D218} |
| L_{C1011} | R^{D4} | R^{D219} |
| L_{C1012} | R^{D4} | R^{D220} |
| L_{C1013} | R^{D4} | R^{D221} |
| L_{C1014} | R^{D4} | R^{D222} |
| L_{C1015} | R^{D4} | R^{D223} |
| L_{C1016} | R^{D4} | R^{D224} |
| L_{C1017} | R^{D4} | R^{D225} |
| L_{C1018} | R^{D4} | R^{D226} |
| L_{C1019} | R^{D4} | R^{D227} |
| L_{C1020} | R^{D4} | R^{D228} |
| L_{C1021} | R^{D4} | R^{D229} |
| L_{C1022} | R^{D4} | R^{D230} |
| L_{C1023} | R^{D4} | R^{D231} |
| L_{C1024} | R^{D4} | R^{D232} |
| L_{C1025} | R^{D4} | R^{D233} |
| L_{C1026} | R^{D4} | R^{D234} |
| L_{C1027} | R^{D4} | R^{D235} |
| L_{C1028} | R^{D4} | R^{D236} |
| L_{C1029} | R^{D4} | R^{D237} |
| L_{C1030} | R^{D4} | R^{D238} |
| L_{C1031} | R^{D4} | R^{D239} |
| L_{C1032} | R^{D4} | R^{D240} |
| L_{C1033} | R^{D4} | R^{D241} |
| L_{C1034} | R^{D4} | R^{D242} |
| L_{C1035} | R^{D4} | R^{D243} |
| L_{C1036} | R^{D4} | R^{D244} |
| L_{C1037} | R^{D4} | R^{D245} |
| L_{C1038} | R^{D4} | R^{D246} |
| L_{C1039} | R^{D145} | R^{D193} |
| L_{C1040} | R^{D145} | R^{D194} |
| L_{C1041} | R^{D145} | R^{D195} |
| L_{C1042} | R^{D145} | R^{D196} |
| L_{C1043} | R^{D145} | R^{D197} |
| L_{C1044} | R^{D145} | R^{D198} |
| L_{C1045} | R^{D145} | R^{D199} |
| L_{C1046} | R^{D145} | R^{D200} |
| L_{C1047} | R^{D145} | R^{D201} |
| L_{C1048} | R^{D145} | R^{D202} |
| L_{C1049} | R^{D145} | R^{D203} |
| L_{C1050} | R^{D145} | R^{D204} |
| L_{C1051} | R^{D145} | R^{D205} |
| L_{C1052} | R^{D145} | R^{D206} |
| L_{C1053} | R^{D145} | R^{D207} |
| L_{C1054} | R^{D145} | R^{D208} |
| L_{C1055} | R^{D145} | R^{D209} |
| L_{C1056} | R^{D145} | R^{D210} |
| L_{C1057} | R^{D145} | R^{D211} |
| L_{C1058} | R^{D145} | R^{D212} |
| L_{C1059} | R^{D145} | R^{D213} |
| L_{C1060} | R^{D145} | R^{D214} |
| L_{C1061} | R^{D145} | R^{D215} |
| L_{C1062} | R^{D145} | R^{D216} |
| L_{C1063} | R^{D145} | R^{D217} |
| L_{C1064} | R^{D145} | R^{D218} |
| L_{C1065} | R^{D145} | R^{D219} |
| L_{C1066} | R^{D145} | R^{D220} |
| L_{C1067} | R^{D145} | R^{D221} |
| L_{C1068} | R^{D145} | R^{D222} |
| L_{C1069} | R^{D145} | R^{D223} |
| L_{C1070} | R^{D145} | R^{D224} |
| L_{C1071} | R^{D145} | R^{D225} |
| L_{C1072} | R^{D145} | R^{D226} |
| L_{C1073} | R^{D145} | R^{D227} |
| L_{C1074} | R^{D145} | R^{D228} |
| L_{C1075} | R^{D145} | R^{D229} |
| L_{C1076} | R^{D145} | R^{D230} |
| L_{C1077} | R^{D145} | R^{D231} |
| L_{C1078} | R^{D145} | R^{D232} |
| L_{C1079} | R^{D145} | R^{D233} |
| L_{C1080} | R^{D145} | R^{D234} |
| L_{C1081} | R^{D145} | R^{D235} |
| L_{C1082} | R^{D145} | R^{D236} |
| L_{C1083} | R^{D145} | R^{D237} |
| L_{C1084} | R^{D145} | R^{D238} |
| L_{C1085} | R^{D145} | R^{D239} |
| L_{C1086} | R^{D145} | R^{D240} |
| L_{C1087} | R^{D145} | R^{D241} |
| L_{C1088} | R^{D145} | R^{D242} |
| L_{C1089} | R^{D145} | R^{D243} |
| L_{C1090} | R^{D145} | R^{D244} |
| L_{C1091} | R^{D145} | R^{D245} |
| L_{C1092} | R^{D145} | R^{D246} |
| L_{C1093} | R^{D9} | R^{D193} |
| L_{C1094} | R^{D9} | R^{D194} |
| L_{C1095} | R^{D9} | R^{D195} |
| L_{C1096} | R^{D9} | R^{D196} |
| L_{C1097} | R^{D9} | R^{D197} |
| L_{C1098} | R^{D9} | R^{D198} |
| L_{C1099} | R^{D9} | R^{D199} |
| L_{C1100} | R^{D9} | R^{D200} |
| L_{C1101} | R^{D9} | R^{D201} |
| L_{C1102} | R^{D9} | R^{D202} |
| L_{C1103} | R^{D9} | R^{D203} |
| L_{C1104} | R^{D9} | R^{D204} |
| L_{C1105} | R^{D9} | R^{D205} |
| L_{C1106} | R^{D9} | R^{D206} |
| L_{C1107} | R^{D9} | R^{D207} |
| L_{C1108} | R^{D9} | R^{D208} |
| L_{C1109} | R^{D9} | R^{D209} |
| L_{C1110} | R^{D9} | R^{D210} |
| L_{C1111} | R^{D9} | R^{D211} |
| L_{C1112} | R^{D9} | R^{D212} |
| L_{C1113} | R^{D9} | R^{D213} |
| L_{C1114} | R^{D9} | R^{D214} |
| L_{C1115} | R^{D9} | R^{D215} |
| L_{C1116} | R^{D9} | R^{D216} |
| L_{C1117} | R^{D9} | R^{D217} |
| L_{C1118} | R^{D9} | R^{D218} |
| L_{C1119} | R^{D9} | R^{D219} |
| L_{C1120} | R^{D9} | R^{D220} |
| L_{C1121} | R^{D9} | R^{D221} |
| L_{C1122} | R^{D9} | R^{D222} |
| L_{C1123} | R^{D9} | R^{D223} |
| L_{C1124} | R^{D9} | R^{D224} |
| L_{C1125} | R^{D9} | R^{D225} |
| L_{C1126} | R^{D9} | R^{D226} |
| L_{C1127} | R^{D9} | R^{D227} |
| L_{C1128} | R^{D9} | R^{D228} |
| L_{C1129} | R^{D9} | R^{D229} |
| L_{C1130} | R^{D9} | R^{D230} |
| L_{C1131} | R^{D9} | R^{D231} |
| L_{C1132} | R^{D9} | R^{D232} |
| L_{C1133} | R^{D9} | R^{D233} |
| L_{C1134} | R^{D9} | R^{D234} |
| L_{C1135} | R^{D9} | R^{D235} |
| L_{C1136} | R^{D9} | R^{D236} |
| L_{C1137} | R^{D9} | R^{D237} |
| L_{C1138} | R^{D9} | R^{D238} |
| L_{C1139} | R^{D9} | R^{D239} |
| L_{C1140} | R^{D9} | R^{D240} |
| L_{C1141} | R^{D9} | R^{D241} |
| L_{C1142} | R^{D9} | R^{D242} |
| L_{C1143} | R^{D9} | R^{D243} |
| L_{C1144} | R^{D9} | R^{D244} |
| L_{C1145} | R^{D9} | R^{D245} |
| L_{C1146} | R^{D9} | R^{D246} |
| L_{C1147} | R^{D168} | R^{D193} |
| L_{C1148} | R^{D168} | R^{D194} |
| L_{C1149} | R^{D168} | R^{D195} |
| L_{C1150} | R^{D168} | R^{D196} |
| L_{C1151} | R^{D168} | R^{D197} |
| L_{C1152} | R^{D168} | R^{D198} |
| L_{C1153} | R^{D168} | R^{D199} |
| L_{C1154} | R^{D168} | R^{D200} |
| L_{C1155} | R^{D168} | R^{D201} |
| L_{C1156} | R^{D168} | R^{D202} |
| L_{C1157} | R^{D168} | R^{D203} |
| L_{C1158} | R^{D168} | R^{D204} |
| L_{C1159} | R^{D168} | R^{D205} |
| L_{C1160} | R^{D168} | R^{D206} |
| L_{C1161} | R^{D168} | R^{D207} |
| L_{C1162} | R^{D168} | R^{D208} |
| L_{C1163} | R^{D168} | R^{D209} |
| L_{C1164} | R^{D168} | R^{D210} |
| L_{C1165} | R^{D168} | R^{D211} |
| L_{C1166} | R^{D168} | R^{D212} |
| L_{C1167} | R^{D168} | R^{D213} |
| L_{C1168} | R^{D168} | R^{D214} |
| L_{C1169} | R^{D168} | R^{D215} |
| L_{C1170} | R^{D168} | R^{D216} |
| L_{C1171} | R^{D168} | R^{D217} |
| L_{C1172} | R^{D168} | R^{D218} |
| L_{C1173} | R^{D168} | R^{D219} |
| L_{C1174} | R^{D168} | R^{D220} |
| L_{C1175} | R^{D168} | R^{D221} |
| L_{C1176} | R^{D168} | R^{D222} |
| L_{C1177} | R^{D168} | R^{D223} |
| L_{C1178} | R^{D168} | R^{D224} |
| L_{C1179} | R^{D168} | R^{D225} |
| L_{C1180} | R^{D168} | R^{D226} |
| L_{C1181} | R^{D168} | R^{D227} |
| L_{C1182} | R^{D168} | R^{D228} |
| L_{C1183} | R^{D168} | R^{D229} |
| L_{C1184} | R^{D168} | R^{D230} |
| L_{C1185} | R^{D168} | R^{D231} |
| L_{C1186} | R^{D168} | R^{D232} |
| L_{C1187} | R^{D168} | R^{D233} |
| L_{C1188} | R^{D168} | R^{D234} |
| L_{C1189} | R^{D168} | R^{D235} |
| L_{C1190} | R^{D168} | R^{D236} |
| L_{C1191} | R^{D168} | R^{D237} |
| L_{C1192} | R^{D168} | R^{D238} |
| L_{C1193} | R^{D168} | R^{D239} |
| L_{C1194} | R^{D168} | R^{D240} |
| L_{C1195} | R^{D168} | R^{D241} |
| L_{C1196} | R^{D168} | R^{D242} |
| L_{C1197} | R^{D168} | R^{D243} |
| L_{C1198} | R^{D168} | R^{D244} |
| L_{C1199} | R^{D168} | R^{D245} |
| L_{C1200} | R^{D168} | R^{D246} |
| L_{C1201} | R^{D10} | R^{D193} |
| L_{C1202} | R^{D10} | R^{D194} |
| L_{C1203} | R^{D10} | R^{D195} |
| L_{C1204} | R^{D10} | R^{D196} |
| L_{C1205} | R^{D10} | R^{D197} |
| L_{C1206} | R^{D10} | R^{D198} |
| L_{C1207} | R^{D10} | R^{D199} |
| L_{C1208} | R^{D10} | R^{D200} |
| L_{C1209} | R^{D10} | R^{D201} |
| L_{C1210} | R^{D10} | R^{D202} |
| L_{C1211} | R^{D10} | R^{D203} |
| L_{C1212} | R^{D10} | R^{D204} |
| L_{C1213} | R^{D10} | R^{D205} |
| L_{C1214} | R^{D10} | R^{D206} |
| L_{C1215} | R^{D10} | R^{D207} |
| L_{C1216} | R^{D10} | R^{D208} |
| L_{C1217} | R^{D10} | R^{D209} |
| L_{C1218} | R^{D10} | R^{D210} |
| L_{C1219} | R^{D10} | R^{D211} |
| L_{C1220} | R^{D10} | R^{D212} |
| L_{C1221} | R^{D10} | R^{D213} |
| L_{C1222} | R^{D10} | R^{D214} |
| L_{C1223} | R^{D10} | R^{D215} |
| L_{C1224} | R^{D10} | R^{D216} |
| L_{C1225} | R^{D10} | R^{D217} |
| L_{C1226} | R^{D10} | R^{D218} |
| L_{C1227} | R^{D10} | R^{D219} |
| L_{C1228} | R^{D10} | R^{D220} |
| L_{C1229} | R^{D10} | R^{D221} |
| L_{C1230} | R^{D10} | R^{D222} |
| L_{C1231} | R^{D10} | R^{D223} |
| L_{C1232} | R^{D10} | R^{D224} |
| L_{C1233} | R^{D10} | R^{D225} |
| L_{C1234} | R^{D10} | R^{D226} |
| L_{C1235} | R^{D10} | R^{D227} |
| L_{C1236} | R^{D10} | R^{D228} |
| L_{C1237} | R^{D10} | R^{D229} |
| L_{C1238} | R^{D10} | R^{D230} |
| L_{C1239} | R^{D10} | R^{D231} |
| L_{C1240} | R^{D10} | R^{D232} |
| L_{C1241} | R^{D10} | R^{D233} |
| L_{C1242} | R^{D10} | R^{D234} |
| L_{C1243} | R^{D10} | R^{D235} |
| L_{C124} | R^{D10} | R^{D236} |
| L_{C1245} | R^{D10} | R^{D237} |
| L_{C1246} | R^{D10} | R^{D238} |
| L_{C1247} | R^{D10} | R^{D239} |
| L_{C1248} | R^{D10} | R^{D240} |
| L_{C1249} | R^{D10} | R^{D241} |
| L_{C1250} | R^{D10} | R^{D242} |
| L_{C1251} | R^{D10} | R^{D243} |
| L_{C1252} | R^{D10} | R^{D244} |
| L_{C1253} | R^{D10} | R^{D245} |
| L_{C1254} | R^{D10} | R^{D246} |
| L_{C1255} | R^{D55} | R^{D193} |
| L_{C1256} | R^{D55} | R^{D194} |
| L_{C1257} | R^{D55} | R^{D195} |
| L_{C1258} | R^{D55} | R^{D196} |
| L_{C1259} | R^{D55} | R^{D197} |
| L_{C1260} | R^{D55} | R^{D198} |
| L_{C1261} | R^{D55} | R^{D199} |
| L_{C1262} | R^{D55} | R^{D200} |
| L_{C1263} | R^{D55} | R^{D201} |
| L_{C1264} | R^{D55} | R^{D202} |
| L_{C1265} | R^{D55} | R^{D203} |
| L_{C1266} | R^{D55} | R^{D204} |
| L_{C1267} | R^{D55} | R^{D205} |
| L_{C1268} | R^{D55} | R^{D206} |
| L_{C1269} | R^{D55} | R^{D207} |
| L_{C1270} | R^{D55} | R^{D208} |
| L_{C1271} | R^{D55} | R^{D209} |
| L_{C1272} | R^{D55} | R^{D210} |
| L_{C1273} | R^{D55} | R^{D211} |
| L_{C1274} | R^{D55} | R^{D212} |
| L_{C1275} | R^{D55} | R^{D213} |
| L_{C1276} | R^{D55} | R^{D214} |
| L_{C1277} | R^{D55} | R^{D215} |
| L_{C1278} | R^{D55} | R^{D216} |
| L_{C1279} | R^{D55} | R^{D217} |
| L_{C1280} | R^{D55} | R^{D218} |
| L_{C1281} | R^{D55} | R^{D219} |
| L_{C1282} | R^{D55} | R^{D220} |
| L_{C1283} | R^{D55} | R^{D221} |
| L_{C1284} | R^{D55} | R^{D222} |
| L_{C1285} | R^{D55} | R^{D223} |
| L_{C1286} | R^{D55} | R^{D224} |
| L_{C1287} | R^{D55} | R^{D225} |
| L_{C1288} | R^{D55} | R^{D226} |
| L_{C1289} | R^{D55} | R^{D227} |
| L_{C1290} | R^{D55} | R^{D228} |
| L_{C1291} | R^{D55} | R^{D229} |
| L_{C1292} | R^{D55} | R^{D230} |
| L_{C1293} | R^{D55} | R^{D231} |
| L_{C1294} | R^{D55} | R^{D232} |
| L_{C1295} | R^{D55} | R^{D233} |
| L_{C1296} | R^{D55} | R^{D234} |
| L_{C1297} | R^{D55} | R^{D235} |
| L_{C1298} | R^{D55} | R^{D236} |
| L_{C1299} | R^{D55} | R^{D237} |
| L_{C1300} | R^{D55} | R^{D238} |
| L_{C1301} | R^{D55} | R^{D239} |
| L_{C1302} | R^{D55} | R^{D240} |
| L_{C1303} | R^{D55} | R^{D241} |
| L_{C1304} | R^{D55} | R^{D242} |
| L_{C1305} | R^{D55} | R^{D243} |
| L_{C1306} | R^{D55} | R^{D244} |
| L_{C1307} | R^{D55} | R^{D245} |
| L_{C1308} | R^{D55} | R^{D246} |
| L_{C1309} | R^{D37} | R^{D193} |
| L_{C1310} | R^{D37} | R^{D194} |
| L_{C1311} | R^{D37} | R^{D195} |
| L_{C1312} | R^{D37} | R^{D196} |
| L_{C1313} | R^{D37} | R^{D197} |
| L_{C1314} | R^{D37} | R^{D198} |
| L_{C1315} | R^{D37} | R^{D199} |
| L_{C1316} | R^{D37} | R^{D200} |
| L_{C1317} | R^{D37} | R^{D201} |
| L_{C1318} | R^{D37} | R^{D202} |
| L_{C1319} | R^{D37} | R^{D203} |
| L_{C1320} | R^{D37} | R^{D204} |
| L_{C1321} | R^{D37} | R^{D205} |
| L_{C1322} | R^{D37} | R^{D206} |
| L_{C1323} | R^{D37} | R^{D207} |
| L_{C1324} | R^{D37} | R^{D208} |
| L_{C1325} | R^{D37} | R^{D209} |
| L_{C1326} | R^{D37} | R^{D210} |
| L_{C1327} | R^{D37} | R^{D211} |
| L_{C1328} | R^{D37} | R^{D212} |
| L_{C1329} | R^{D37} | R^{D213} |
| L_{C1330} | R^{D37} | R^{D214} |
| L_{C1331} | R^{D37} | R^{D215} |
| L_{C1332} | R^{D37} | R^{D216} |
| L_{C1333} | R^{D37} | R^{D217} |
| L_{C1334} | R^{D37} | R^{D218} |
| L_{C1335} | R^{D37} | R^{D219} |
| L_{C1336} | R^{D37} | R^{D220} |
| L_{C1337} | R^{D37} | R^{D221} |
| L_{C1338} | R^{D37} | R^{D222} |
| L_{C1339} | R^{D37} | R^{D223} |
| L_{C1340} | R^{D37} | R^{D224} |
| L_{C1341} | R^{D37} | R^{D225} |
| L_{C1342} | R^{D37} | R^{D226} |
| L_{C1343} | R^{D37} | R^{D227} |
| L_{C1344} | R^{D37} | R^{D228} |
| L_{C1345} | R^{D37} | R^{D229} |
| L_{C1346} | R^{D37} | R^{D230} |
| L_{C1347} | R^{D37} | R^{D231} |
| L_{C1348} | R^{D37} | R^{D232} |
| L_{C1349} | R^{D37} | R^{D233} |
| L_{C1350} | R^{D37} | R^{D234} |
| L_{C1351} | R^{D37} | R^{D235} |
| L_{C1352} | R^{D37} | R^{D236} |
| L_{C1353} | R^{D37} | R^{D237} |
| L_{C1354} | R^{D37} | R^{D238} |
| L_{C1355} | R^{D37} | R^{D239} |
| L_{C1356} | R^{D37} | R^{D240} |
| L_{C1357} | R^{D37} | R^{D241} |
| L_{C1358} | R^{D37} | R^{D242} |
| L_{C1359} | R^{D37} | R^{D243} |
| L_{C1360} | R^{D37} | R^{D244} |
| L_{C1361} | R^{D37} | R^{D245} |
| L_{C1362} | R^{D37} | R^{D246} |
| L_{C1363} | R^{D143} | R^{D193} |
| L_{C1364} | R^{D143} | R^{D194} |
| L_{C1365} | R^{D143} | R^{D195} |
| L_{C1366} | R^{D143} | R^{D196} |
| L_{C1367} | R^{D143} | R^{D197} |
| L_{C1368} | R^{D143} | R^{D198} |
| L_{C1369} | R^{D143} | R^{D199} |
| L_{C1370} | R^{D143} | R^{D200} |
| L_{C1371} | R^{D143} | R^{D201} |
| L_{C1372} | R^{D143} | R^{D202} |
| L_{C1373} | R^{D143} | R^{D203} |
| L_{C1374} | R^{D143} | R^{D204} |
| L_{C1375} | R^{D143} | R^{D205} |
| L_{C1376} | R^{D143} | R^{D206} |
| L_{C1377} | R^{D143} | R^{D207} |
| L_{C1378} | R^{D143} | R^{D208} |
| L_{C1379} | R^{D143} | R^{D209} |
| L_{C1380} | R^{D143} | R^{D210} |
| L_{C1381} | R^{D143} | R^{D211} |
| L_{C1382} | R^{D143} | R^{D212} |
| L_{C1383} | R^{D143} | R^{D213} |
| L_{C1384} | R^{D143} | R^{D214} |
| L_{C1385} | R^{D143} | R^{D215} |
| L_{C1386} | R^{D143} | R^{D216} |
| L_{C1387} | R^{D143} | R^{D217} |
| L_{C1388} | R^{D143} | R^{D218} |
| L_{C1389} | R^{D143} | R^{D219} |
| L_{C1390} | R^{D143} | R^{D220} |
| L_{C1391} | R^{D143} | R^{D221} |
| L_{C1392} | R^{D143} | R^{D222} |
| L_{C1393} | R^{D143} | R^{D223} |
| L_{C1394} | R^{D143} | R^{D224} |
| L_{C1395} | R^{D143} | R^{D225} |
| L_{C1396} | R^{D143} | R^{D226} |
| L_{C1397} | R^{D143} | R^{D227} |
| L_{C1398} | R^{D143} | R^{D228} |
| L_{C1399} | R^{D143} | R^{D229} |
| L_{C1400} | R^{D143} | R^{D230} |
| L_{C1401} | R^{D143} | R^{D231} |
| L_{C1402} | R^{D143} | R^{D232} |
| L_{C1403} | R^{D143} | R^{D233} |
| L_{C1404} | R^{D143} | R^{D234} |
| L_{C1405} | R^{D143} | R^{D235} |
| L_{C1406} | R^{D143} | R^{D236} |
| L_{C1407} | R^{D143} | R^{D237} |
| L_{C1408} | R^{D143} | R^{D238} |
| L_{C1409} | R^{D143} | R^{D239} |
| L_{C1410} | R^{D143} | R^{D240} |
| L_{C1411} | R^{D143} | R^{D241} |
| L_{C1412} | R^{D143} | R^{D242} |
| L_{C1413} | R^{D143} | R^{D243} |
| L_{C1414} | R^{D143} | R^{D244} |
| L_{C1415} | R^{D143} | R^{D245} |
| L_{C1416} | R^{D143} | R^{D246} |

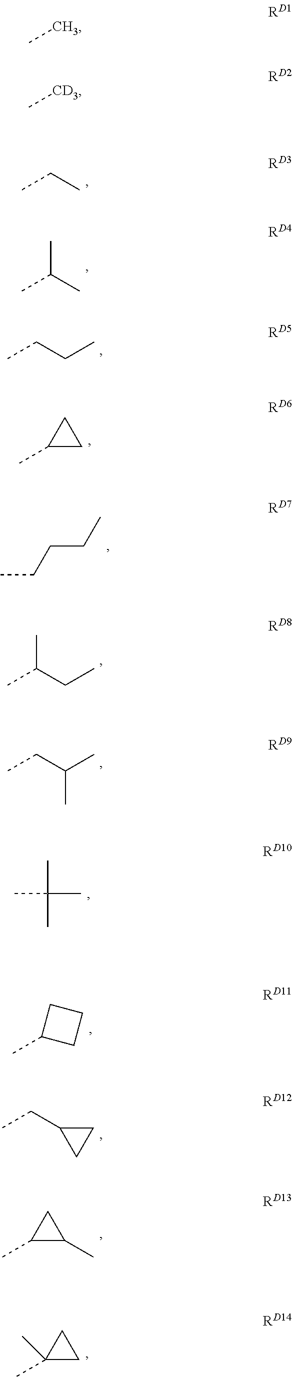

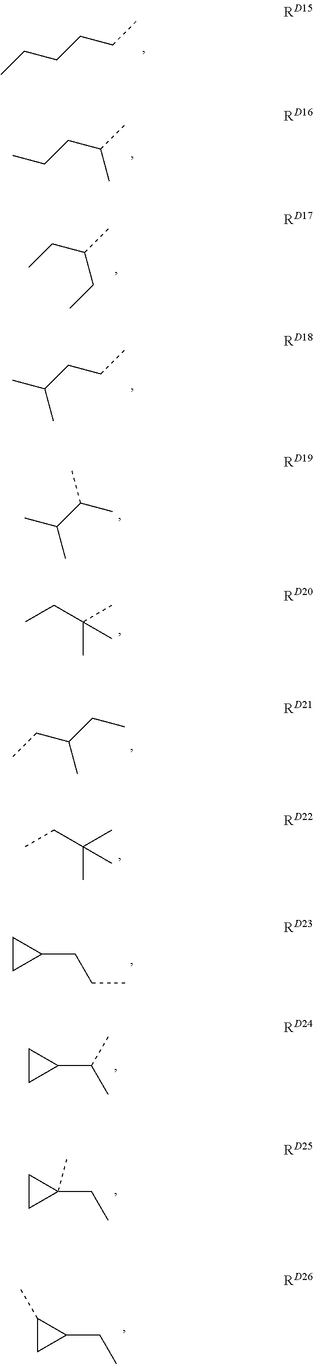

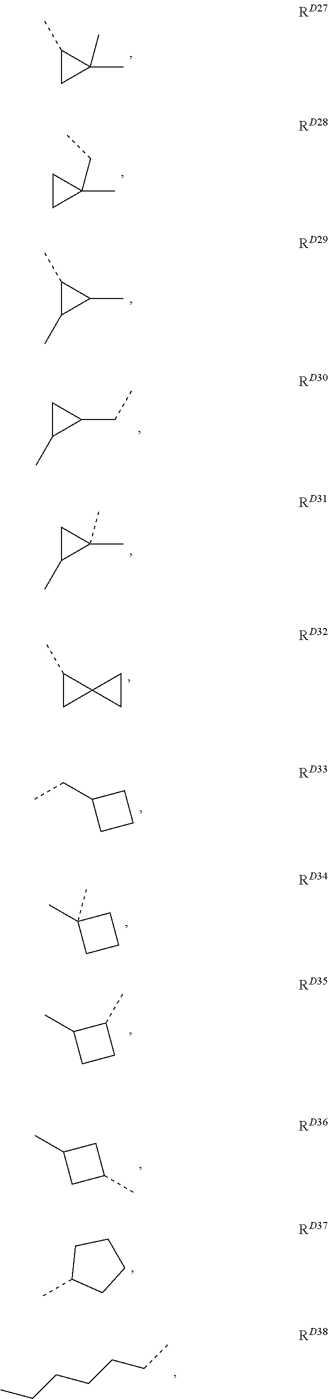

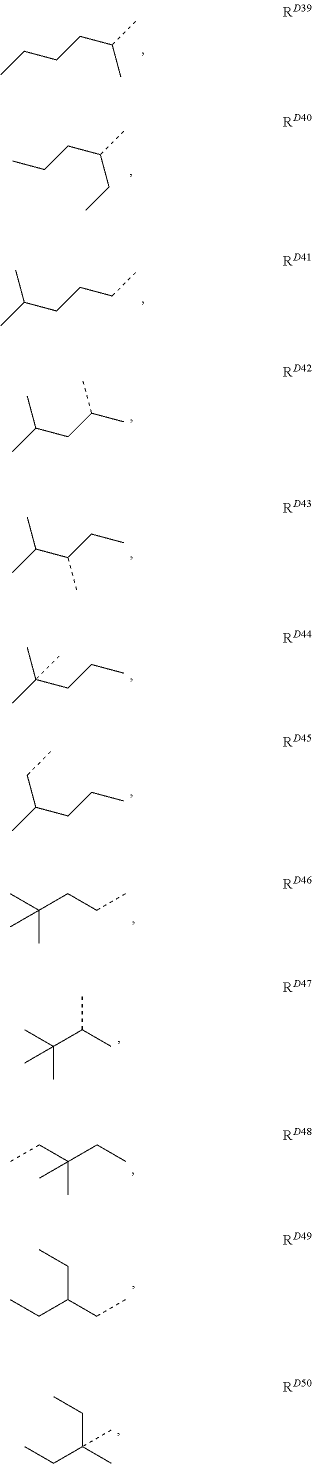

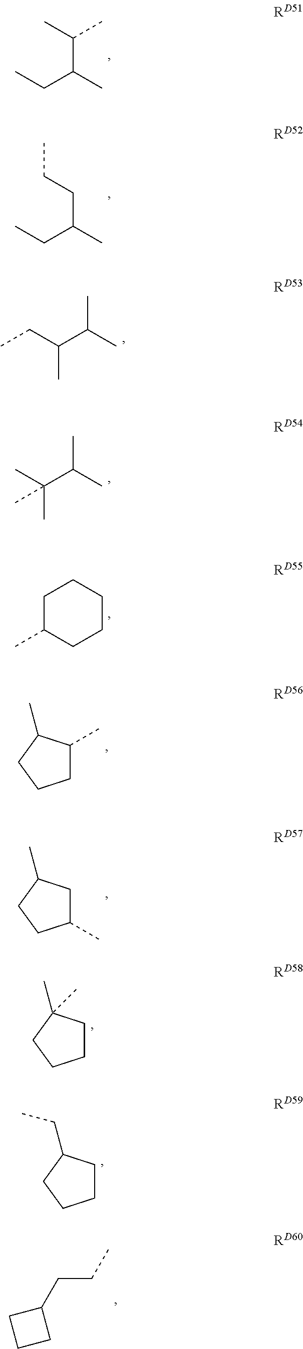

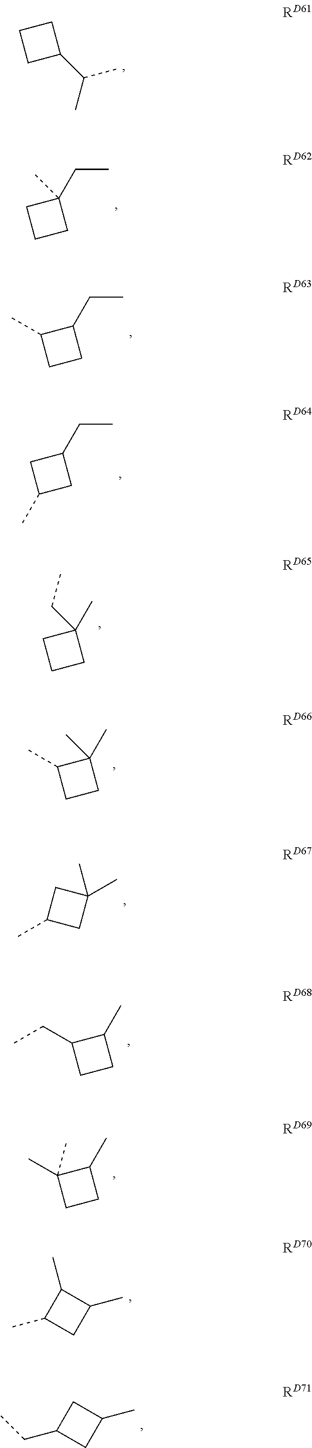

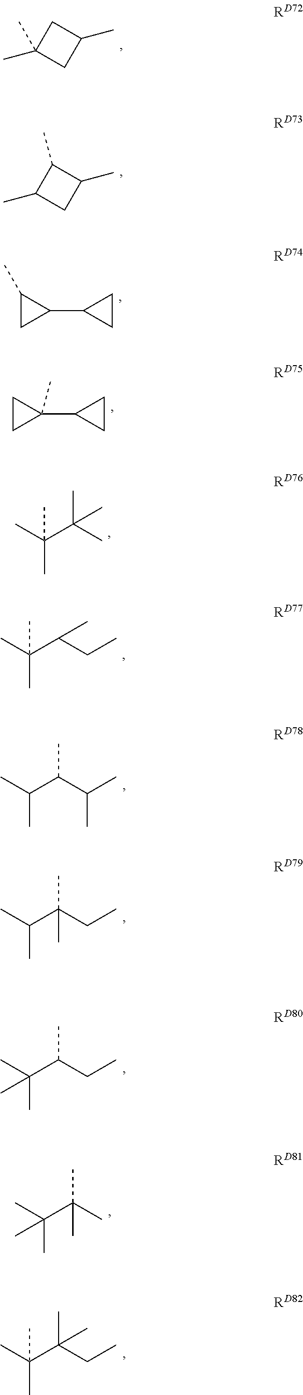

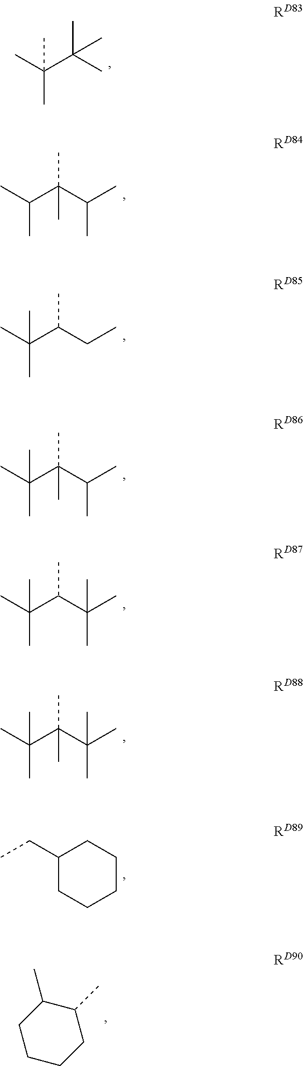

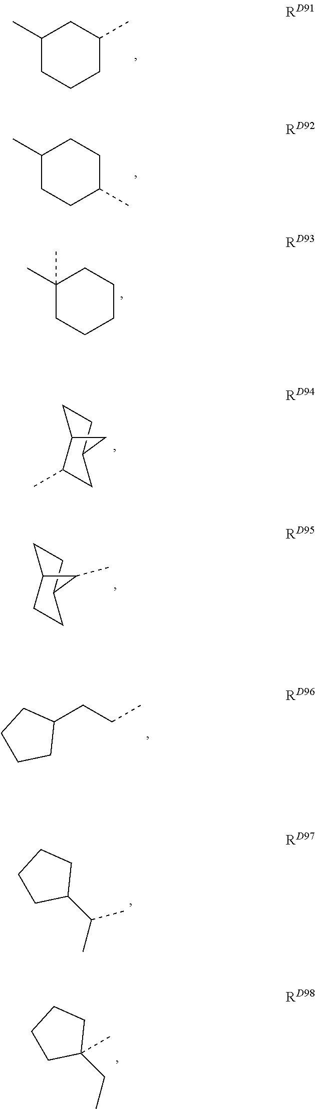

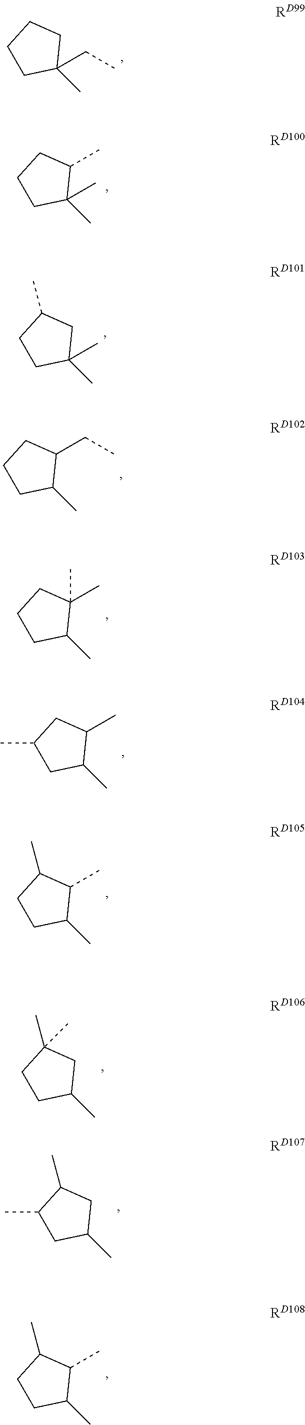

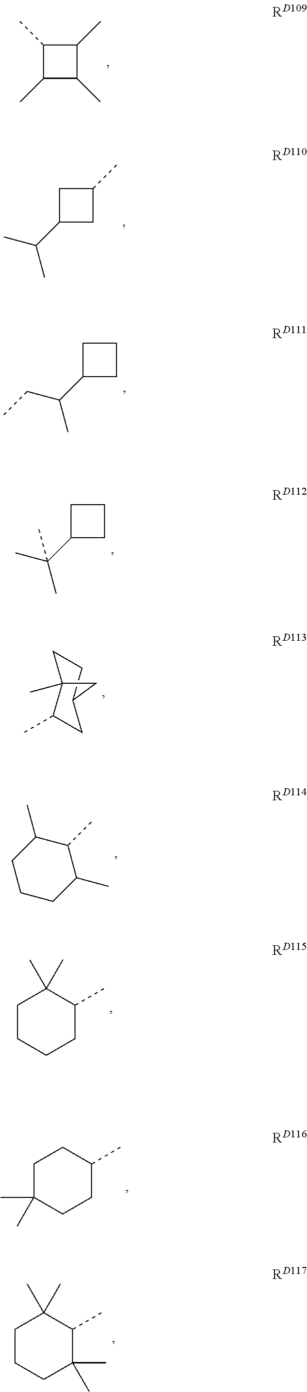

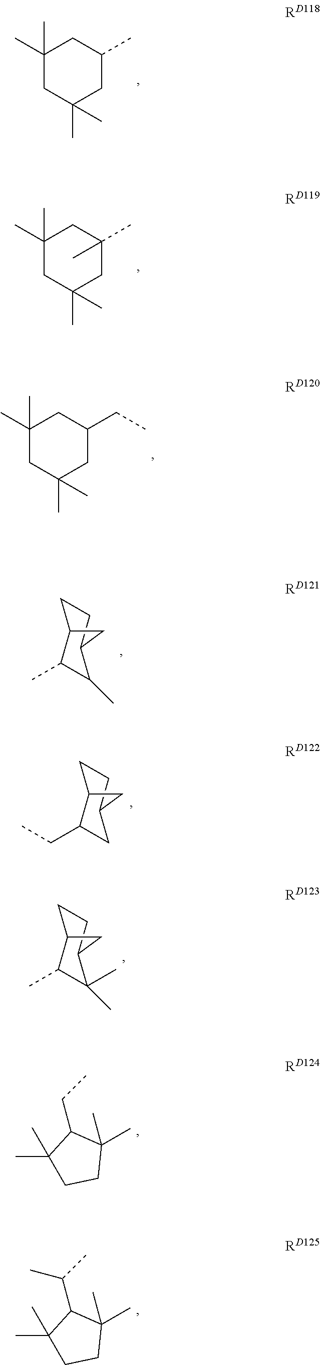

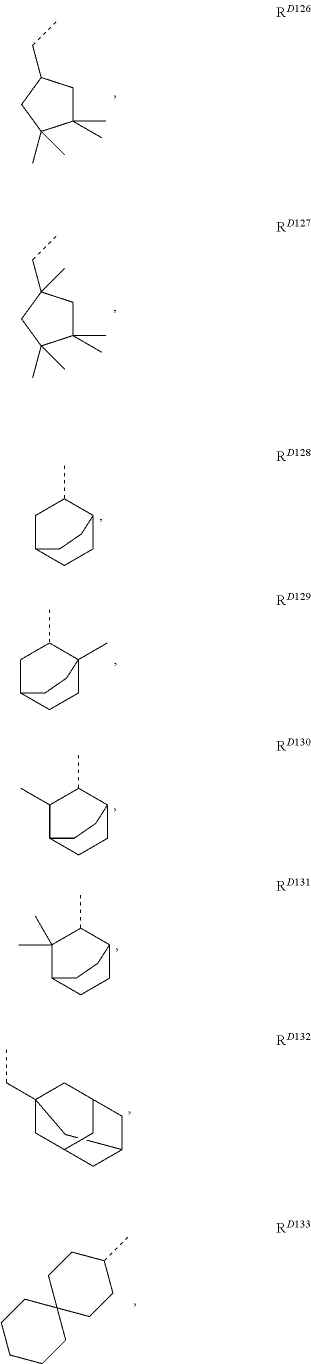

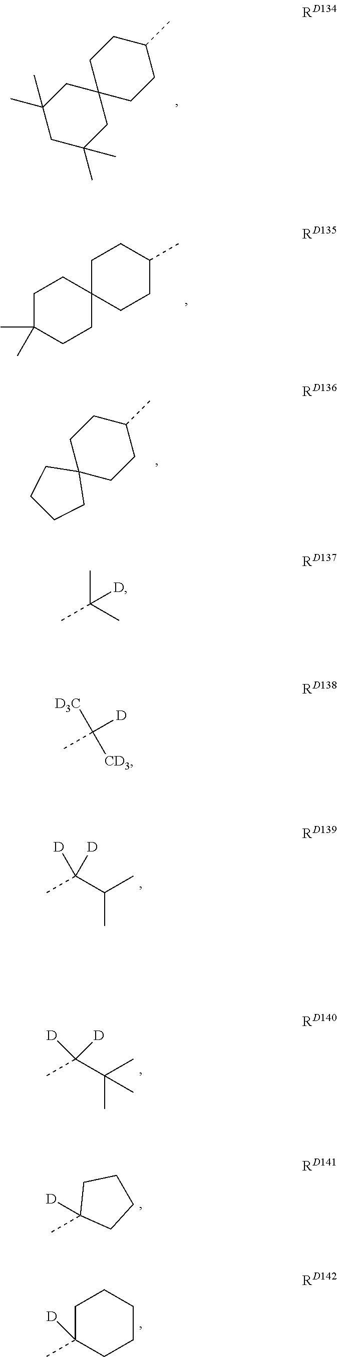

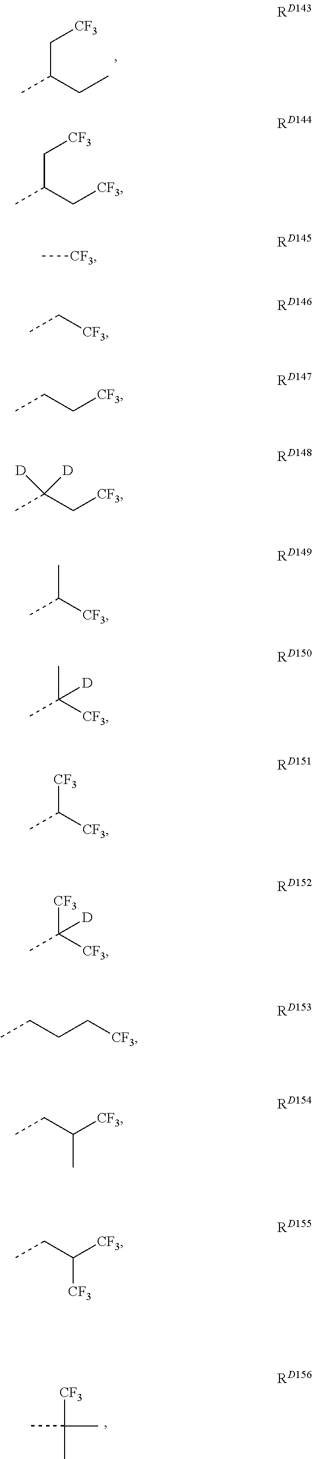

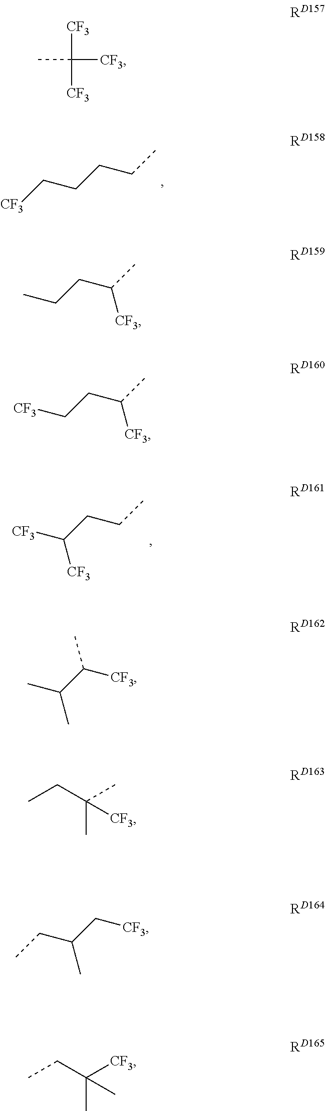

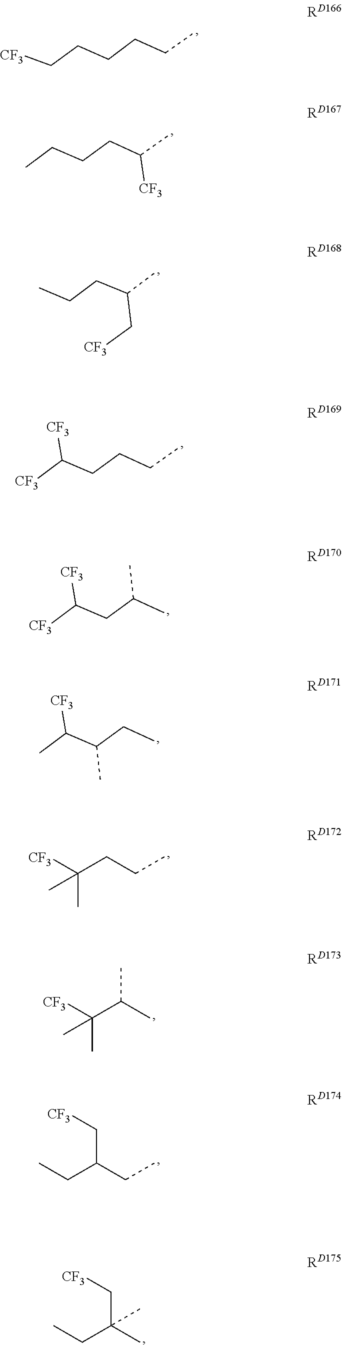

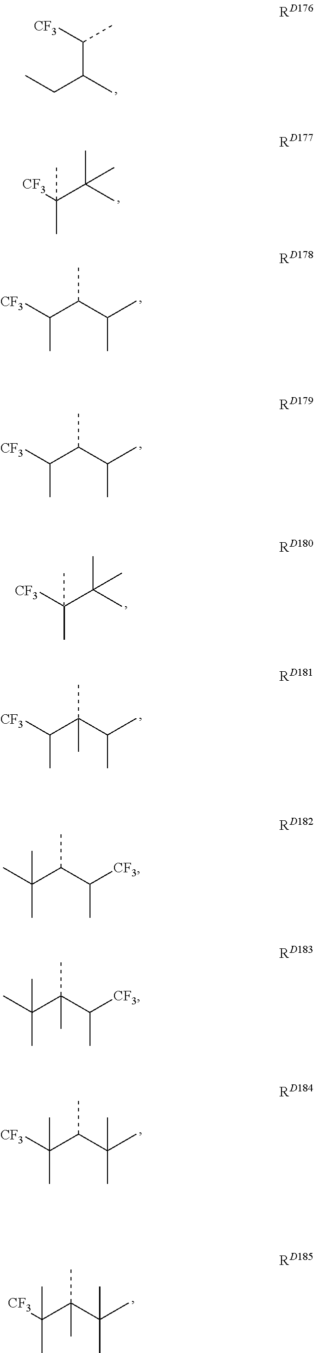

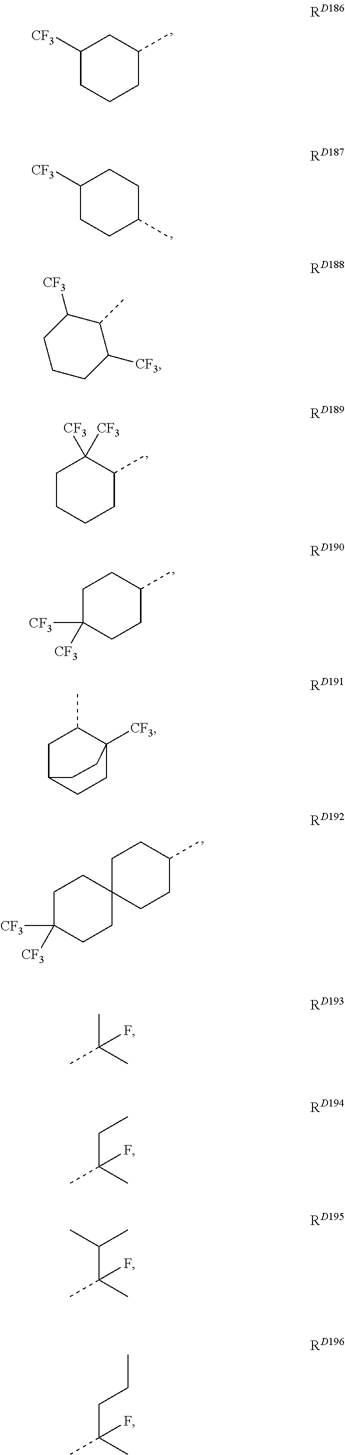

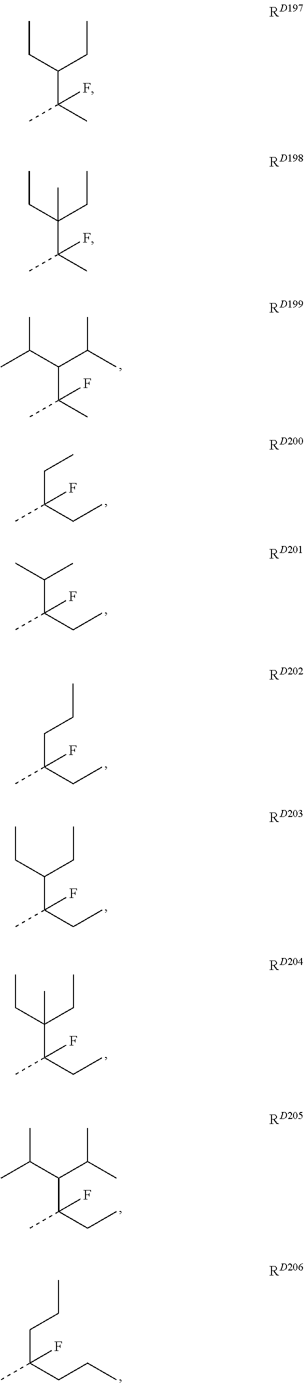

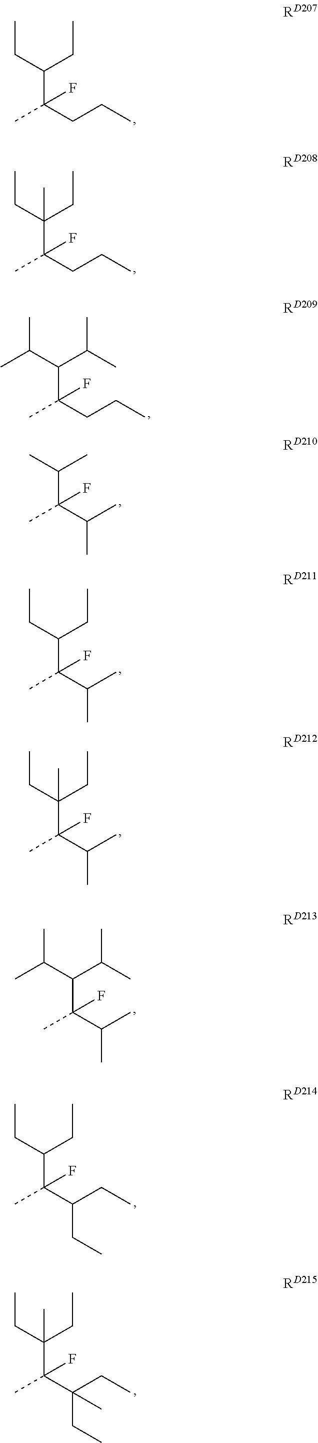

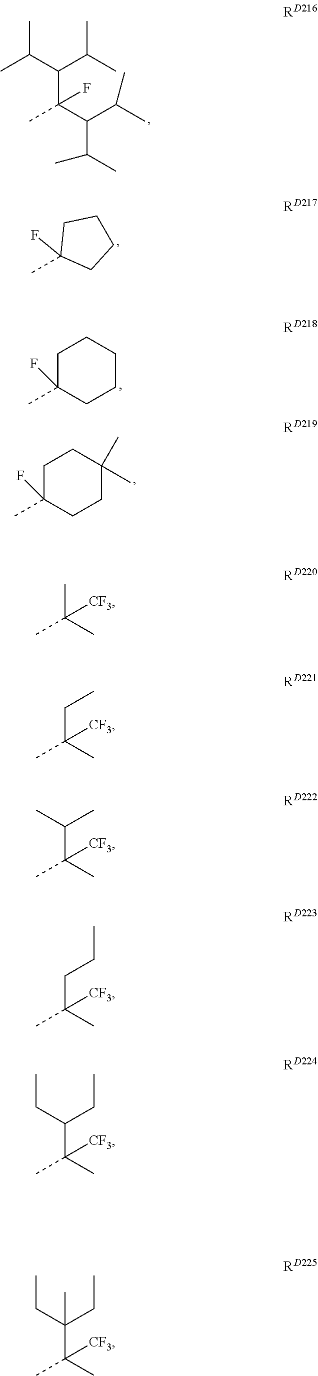

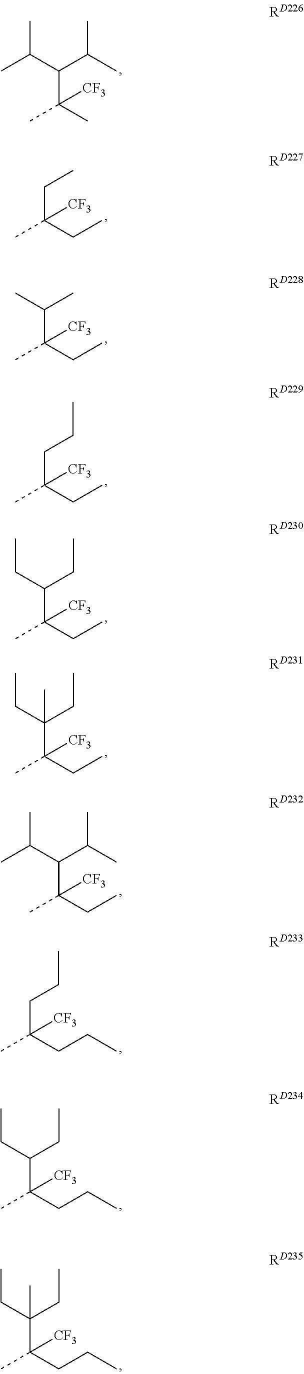

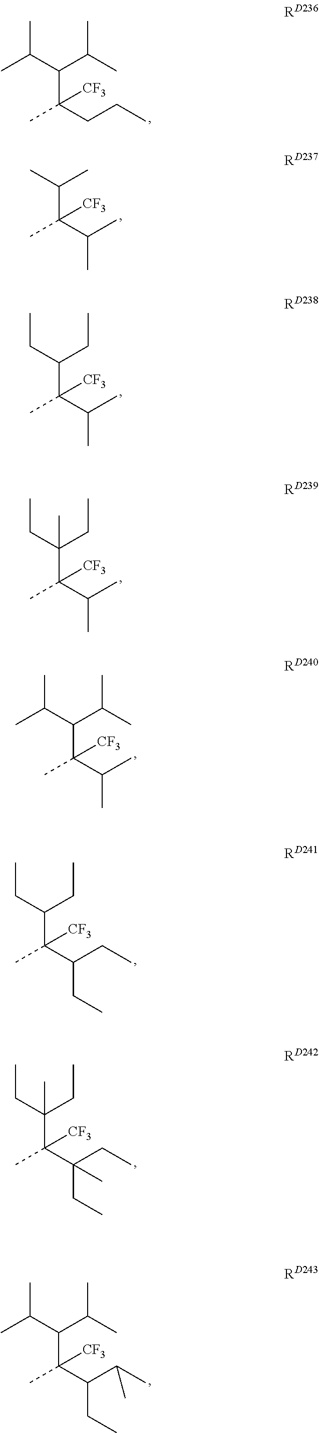

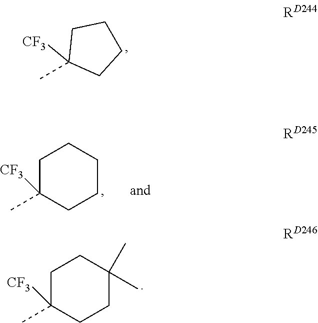

In some embodiments, the compound is selected from the group consisting of only those compounds whose L_{Bk} corresponds to one of the following: L_{B1}, L_{B2}, L_{B18}, L_{B28}, L_{B38}, L_{B108}, L_{B118}, L_{B122}, L_{B124}, L_{B126}, L_{B128}, L_{B130}, L_{B132}, L_{B134}, L_{B136}, L_{B138}, L_{B140}, L_{B142}, L_{B144}, L_{B156}, L_{B158}, L_{B160}, L_{B162}, L_{B164}, L_{B168}, L_{B172}, L_{B175}, L_{B204}, L_{B206}, L_{B214}, L_{B216}, L_{B218}, L_{B220}, L_{B222}, L_{B231}, L_{B233}, L_{B235}, L_{B237}, L_{B240}, L_{B242}, L_{B244}, L_{B246}, L_{B248}, L_{B250}, L_{B252}, L_{B254}, L_{B256}, L_{B258}, L_{B260}, L_{B262}, L_{B264}, L_{B265}, L_{B266}, L_{B267}, L_{B268}, L_{B269}, and L_{B270}.

In some embodiments, the compound is selected from the group consisting of only those compounds whose L_{Bk} corresponds to one of the following: L_{B1}, L_{B2}, L_{B18}, L_{B28}, L_{B38}, L_{B108}, L_{B118}, L_{B122}, L_{B126}, L_{B128}, L_{B132}, L_{B136}, L_{B138}, L_{B142}, L_{B156}, L_{B162}, L_{B204}, L_{B206}, L_{B214}, L_{B216}, L_{B218}, L_{B220}, L_{B231}, L_{B233}, L_{B237}, L_{B264}, L_{B265}, L_{B266}, L_{B267}, L_{B268}, L_{B269}, and L_{B270}.

In some embodiments, the compound is selected from the group consisting of only those compounds having L_{Cj-I} or L_{Cj-II} ligand whose corresponding R²⁰¹ and R²⁰² are defined to be one of the following structures: R^{D1}, R^{D3}, R^{D4}, R^{D5}, R^{D9}, R^{D10}, R^{D17}, R^{D18}, R^{D20}, R^{D22}, R^{D37}, R^{D40}, R^{D41}, R^{D42}, R^{D43}, R^{D48}, R^{D49}, R^{D50}, R^{D54}, R^{D55}, R^{D58}, R^{D59}, R^{D78}, R^{D79}, R^{D81}, R^{D87}, R^{D88}, R^{D89}, R^{D93}, R^{D116}, R^{D117}, R^{D118}, R^{D119}, R^{D120}, R^{D133}, R^{D134}, R^{D135}, R^{D136}, R^{D143}, R^{D144}, R^{D145}, R^{D146}, R^{D147}, R^{D149}, R^{D151}, R^{D154}, R^{D15}, R^{D161}, R^{D175}, R^{D190}, R^{D193}, R^{D200}, R^{D201}, R^{D206}, R^{D210}, R^{D214}, R^{D215}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having L_{Cj-I} or L_{Cj-II} ligand whose corresponding R²⁰¹ and R²⁰² are defined to be one of selected from the following structures: R^{D1}, R^{D3}, R^{D4}, R^{D5}, R^{D9}, R^{D10}, R^{D17}, R^{D22}, R^{D43}, R^{D50}, R^{D78}, R^{D116}, R^{D118}, R^{D133}, R^{D134}, R^{D135}, R^{D136}, R^{D143}, R^{D144}, R^{D145}, R^{D146}, R^{D149}, R^{D151}, R^{D154}, R^{D155}, R^{D190}, R^{D193}, R^{D200}, R^{D201}, R^{D206}, R^{D210}, R^{D214}, R^{D215}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having one of the following structures for the L_{Cj-I} ligand:

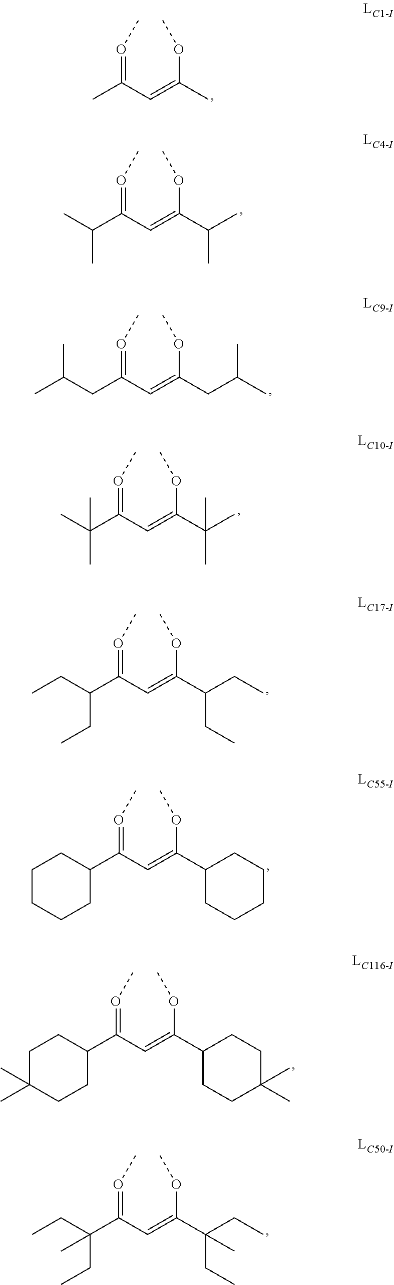

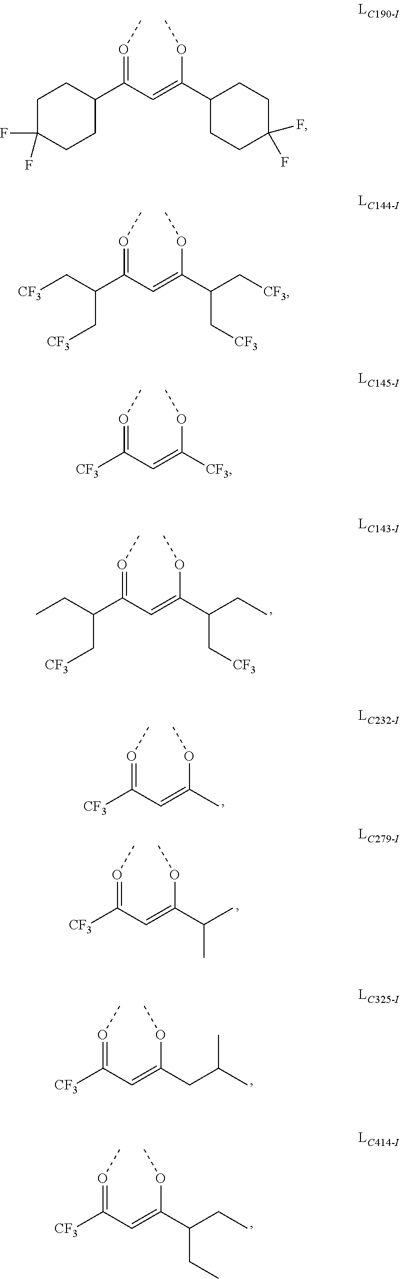

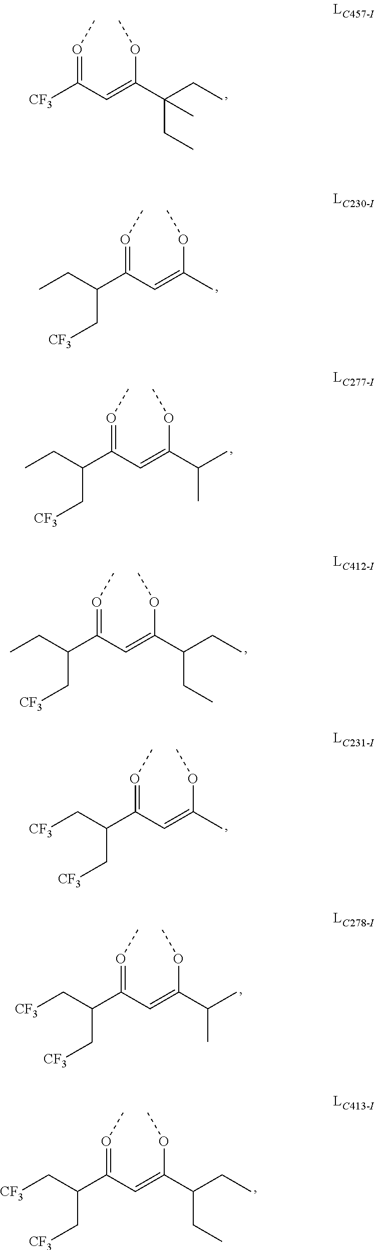

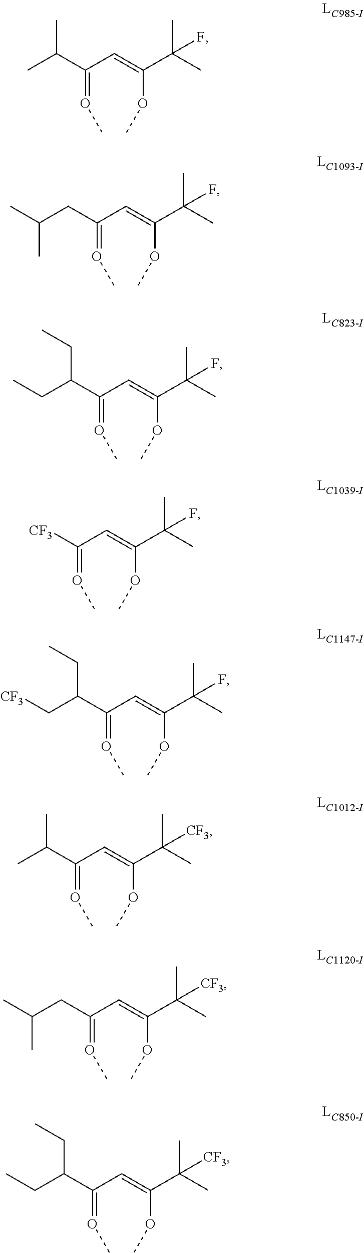

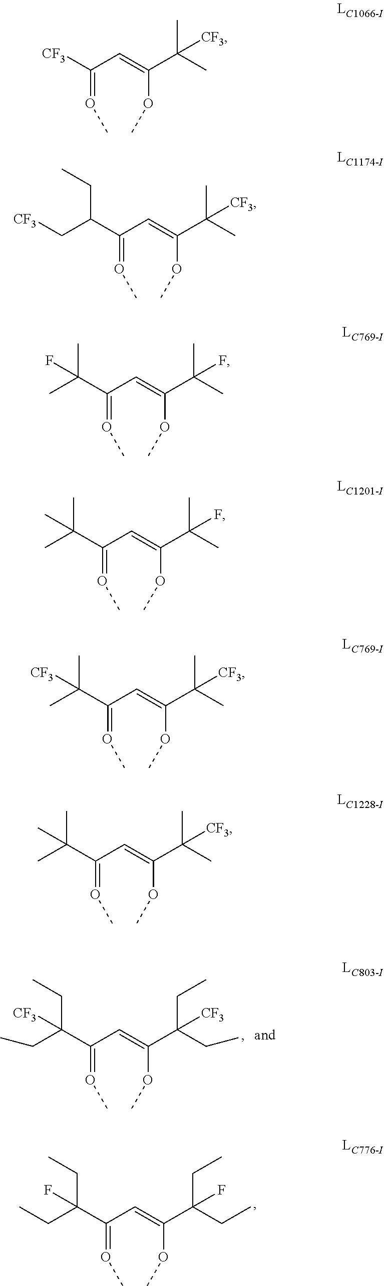

In some embodiments, the compound comprising a first ligand L_{A} of Formula I is selected from the group consisting of:

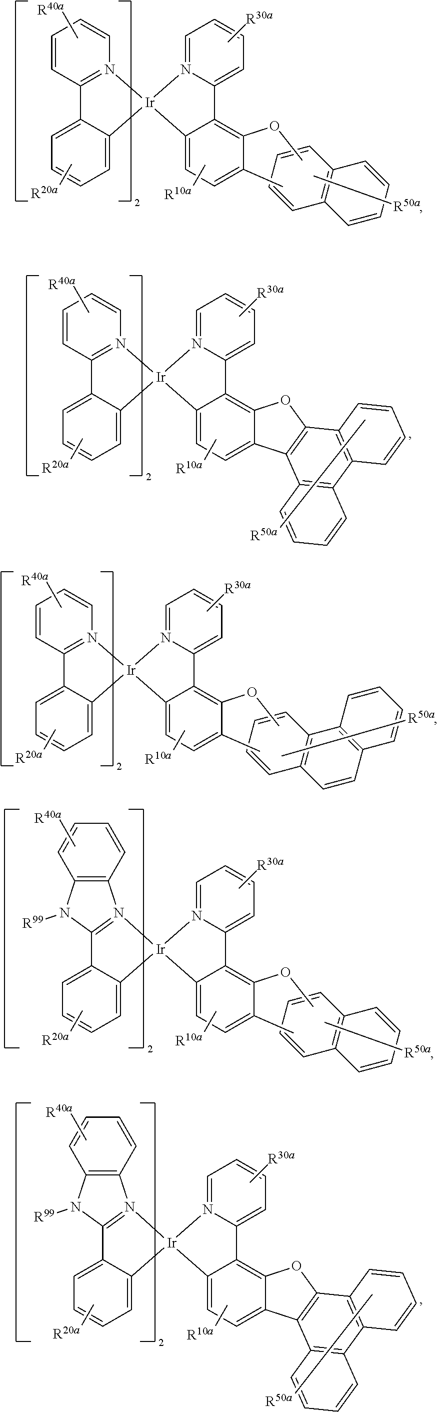

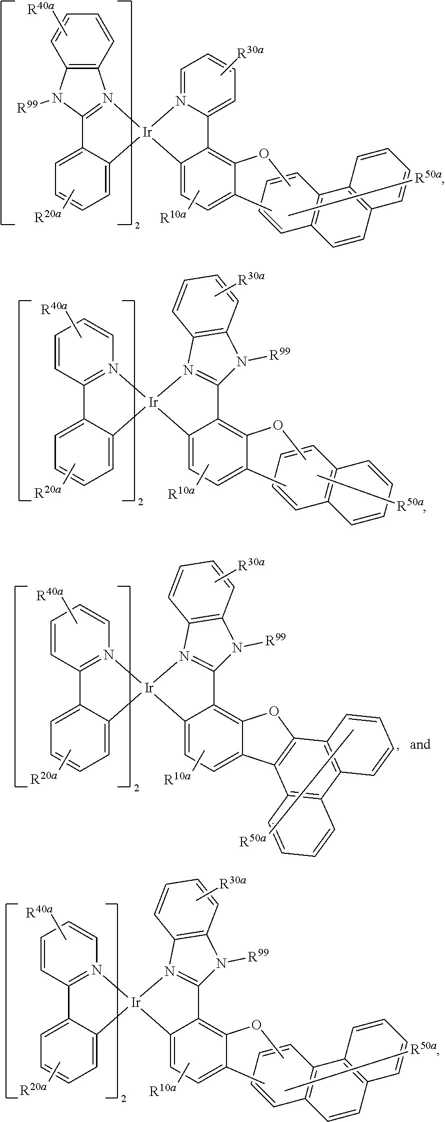

wherein
each of R^{10a}, R^{20a}, R^{30a}, R^{40a}, and R^{50a} independently represents mono substitution, up to the maximum substitutions, or no substitution;
each of R^{10a}, R^{20a}, R^{30a}, R^{40a}, R^{50a}, and R⁹⁹ is independently a hydrogen or a substituent selected from the group consisting of the General Substituents defined herein; and
at least one R^{10a} or R^{50a} comprises a cyclic group or an electron-withdrawing group; and
two adjacent R^{10a}, R^{20a}, R^{30a}, R^{40a}, R^{50a}, and R⁹⁹ are optionally joined or fused to form a ring.

In some embodiments, the compound is selected from the group consisting of the structures of the following LIST 13:

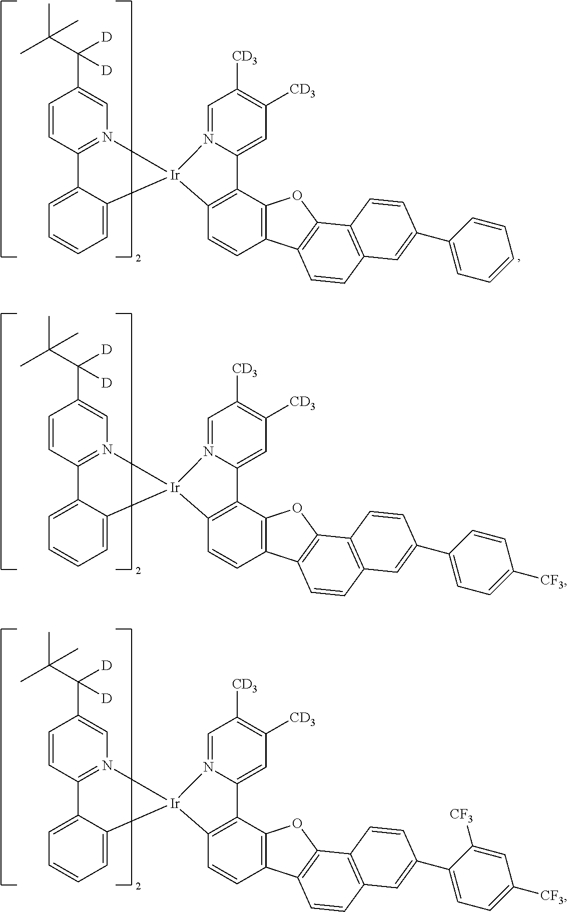

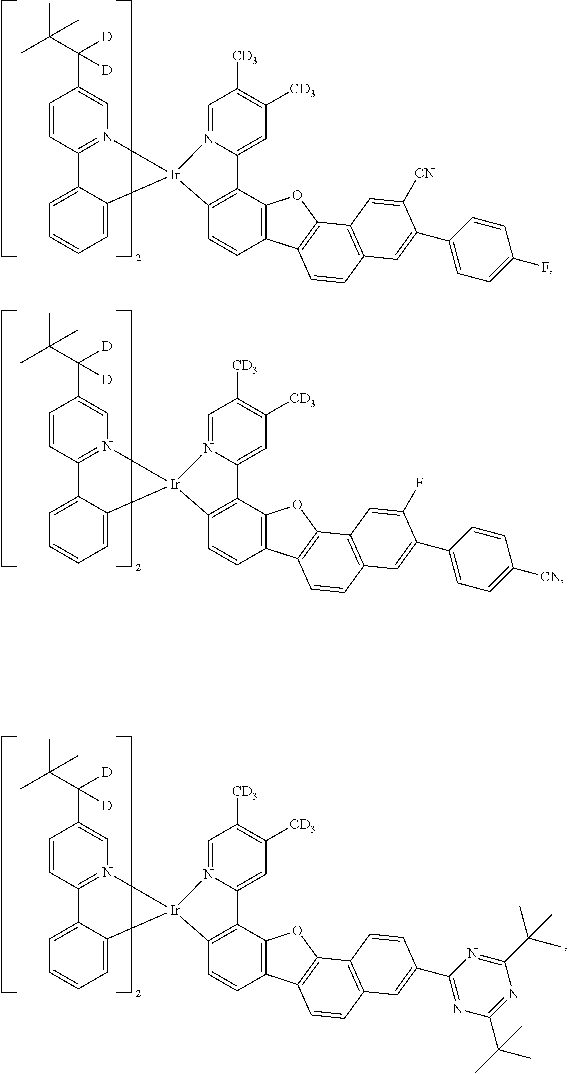

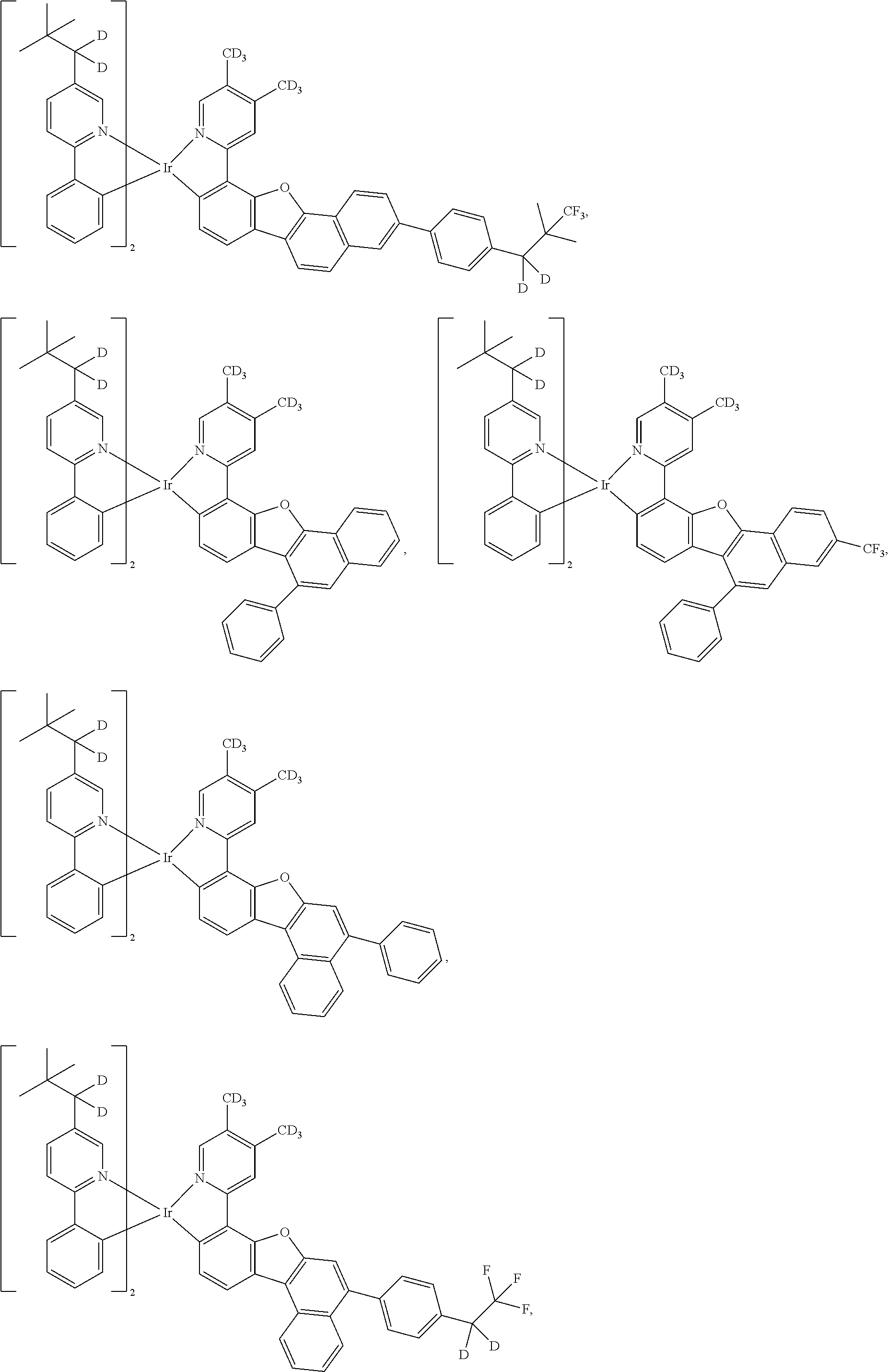

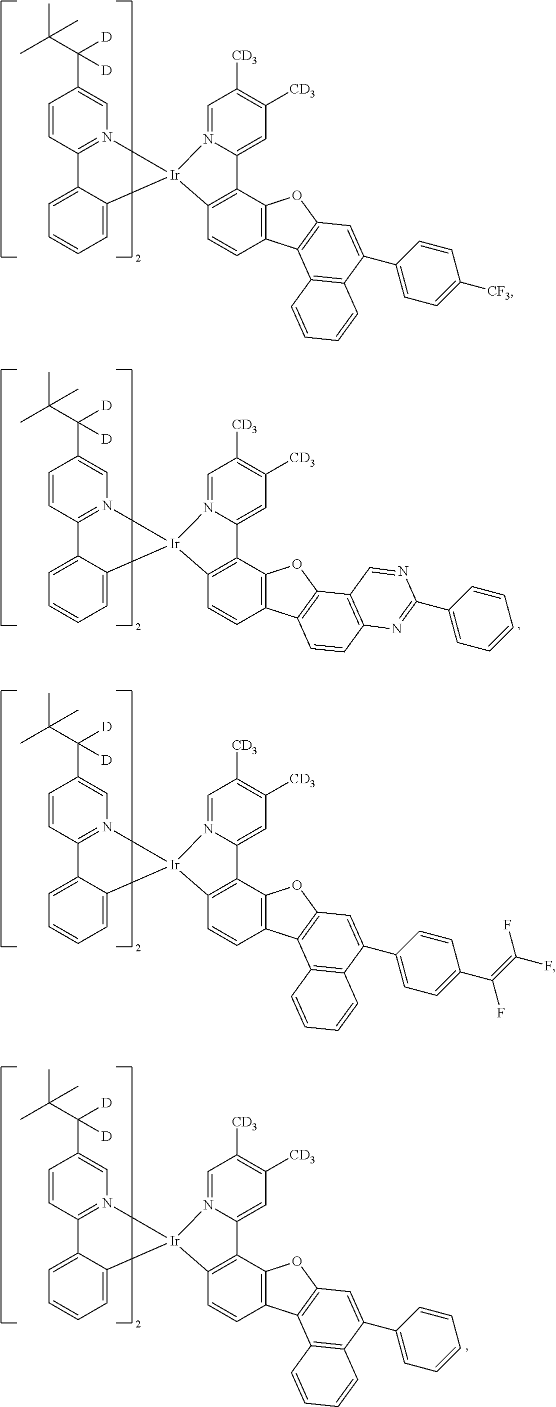

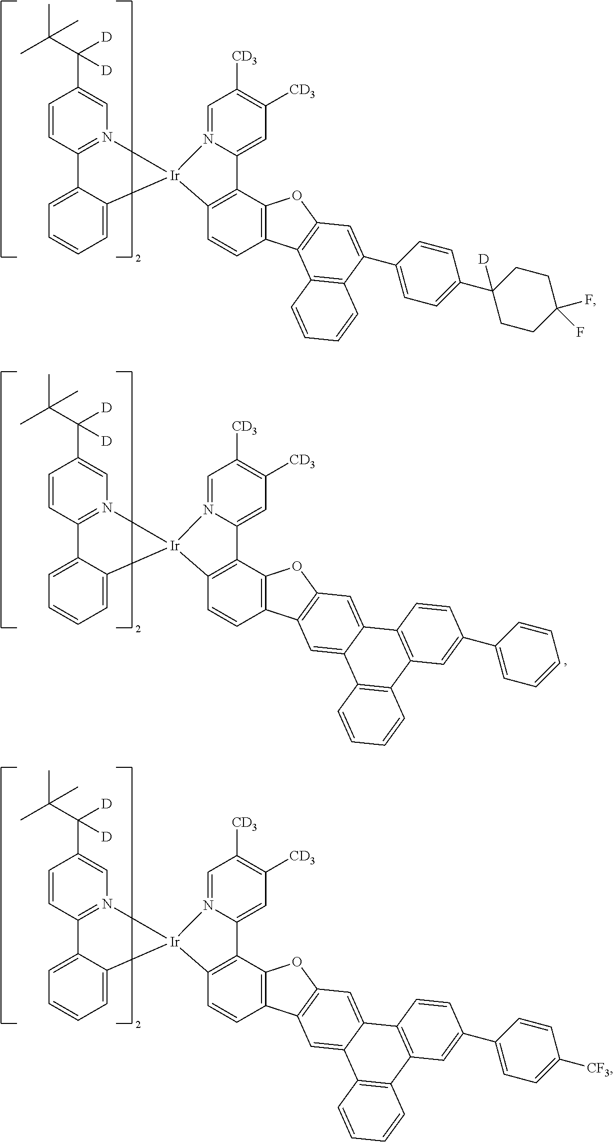

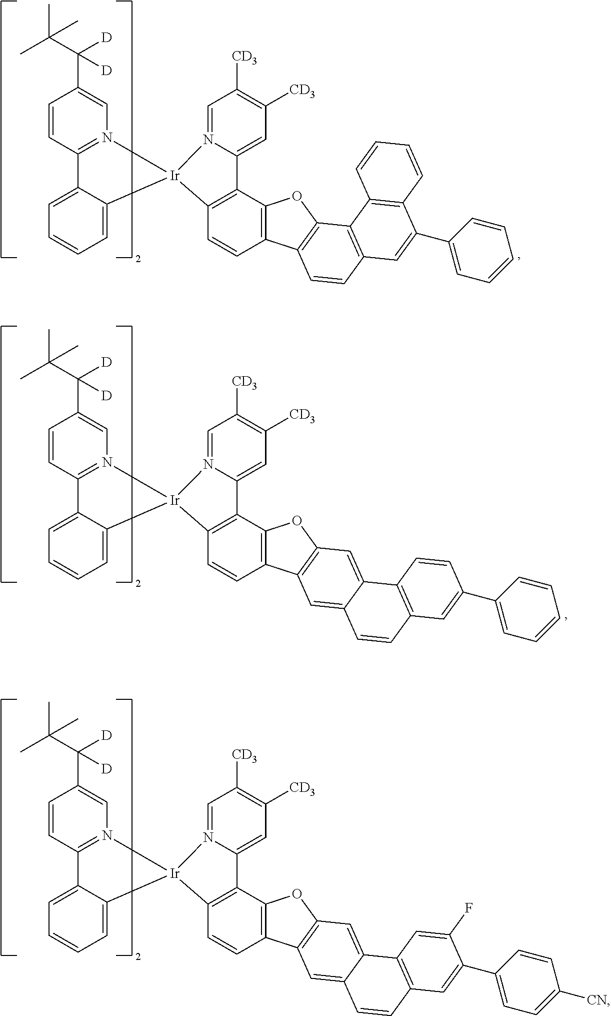

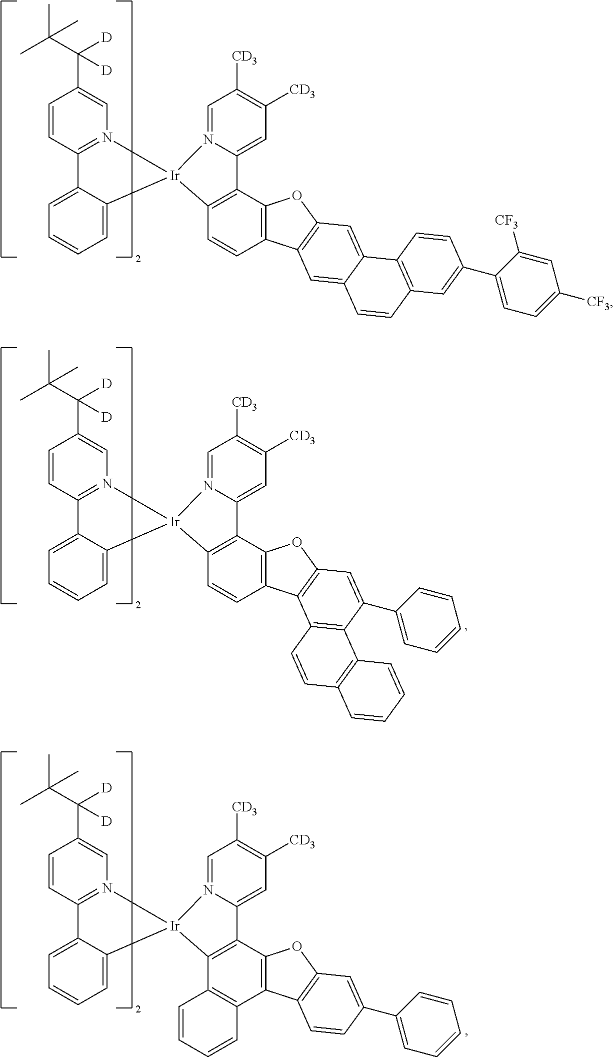

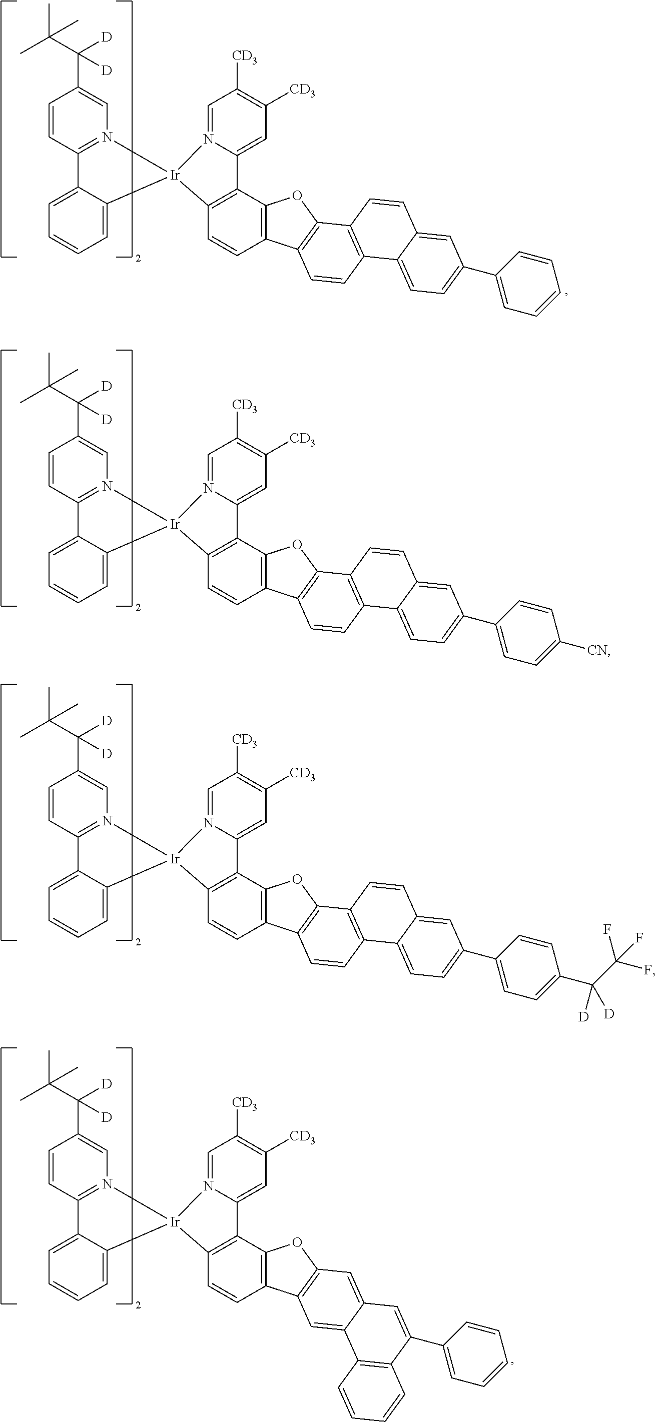

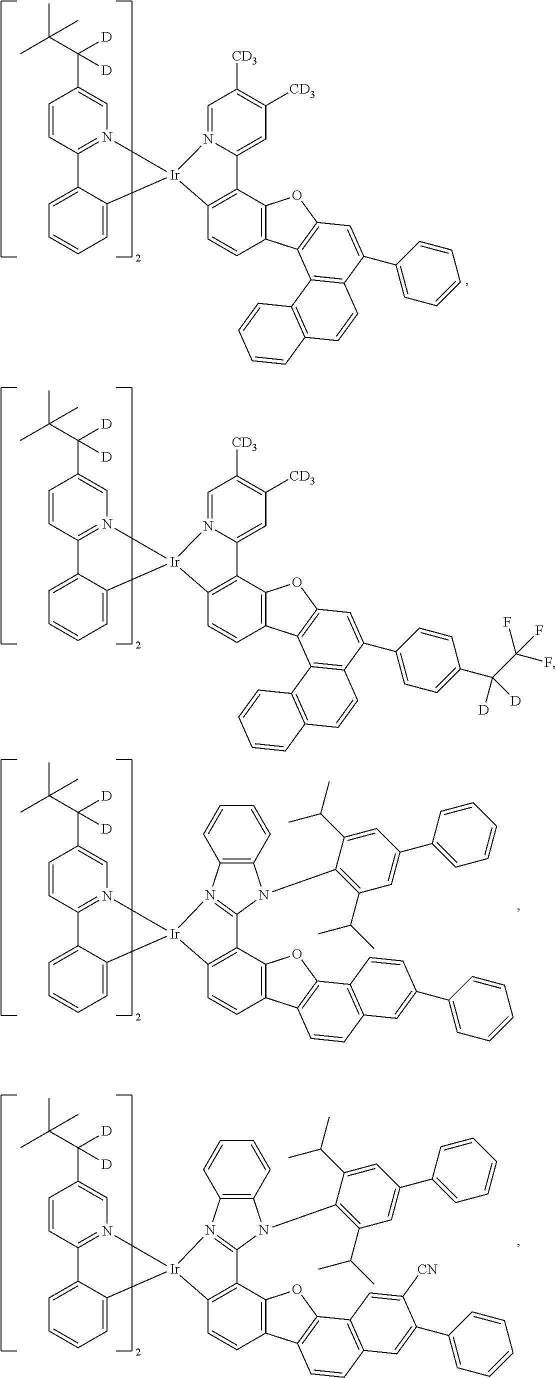

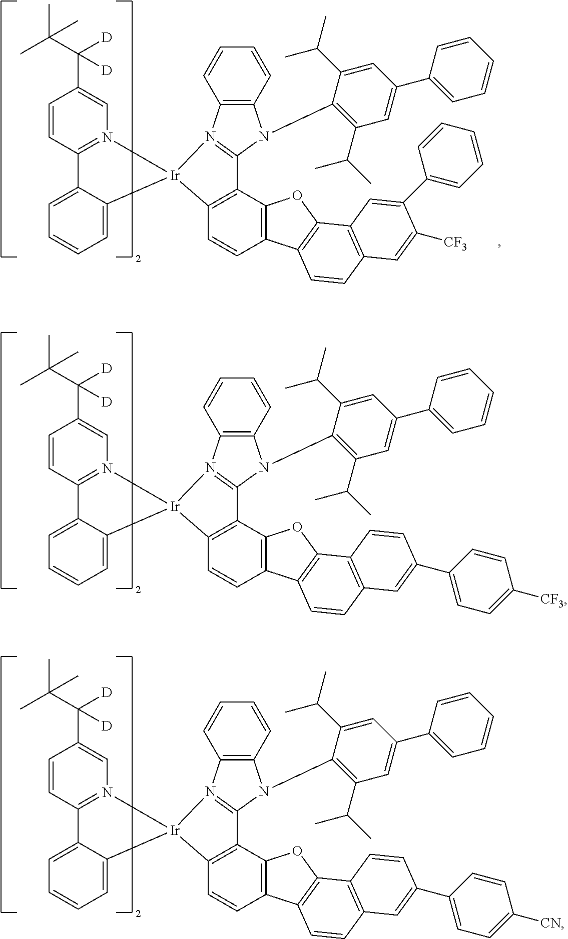

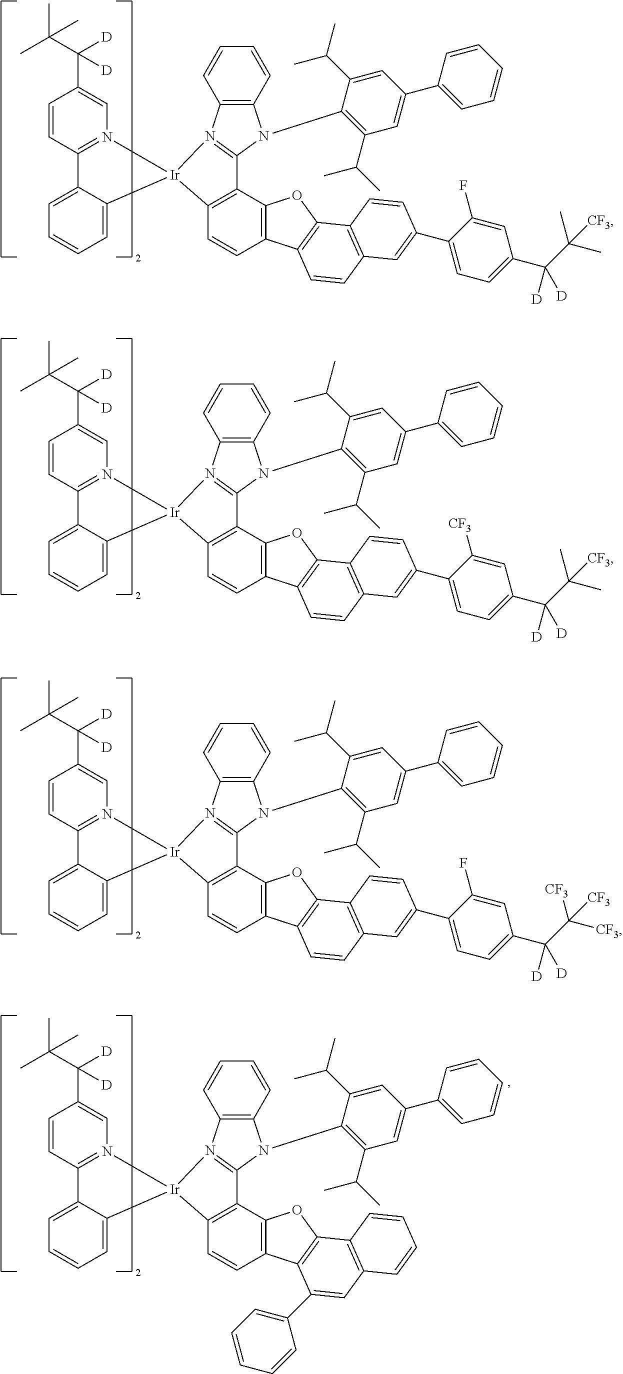

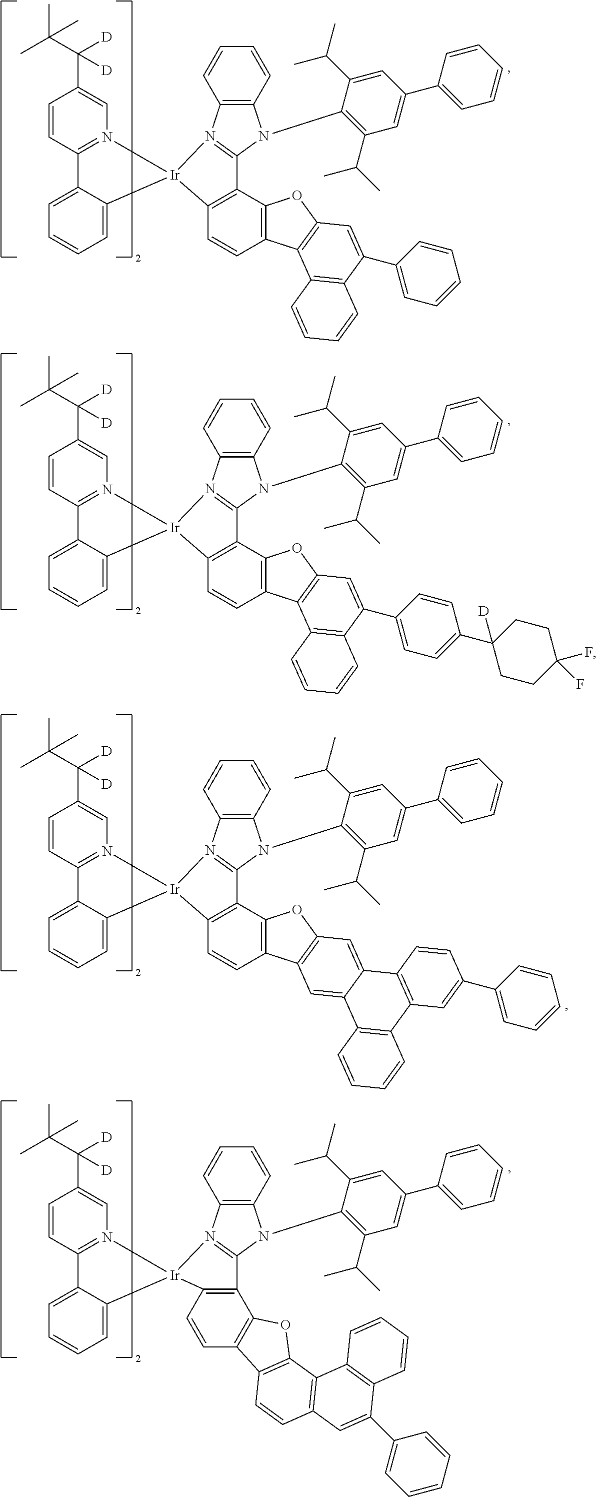

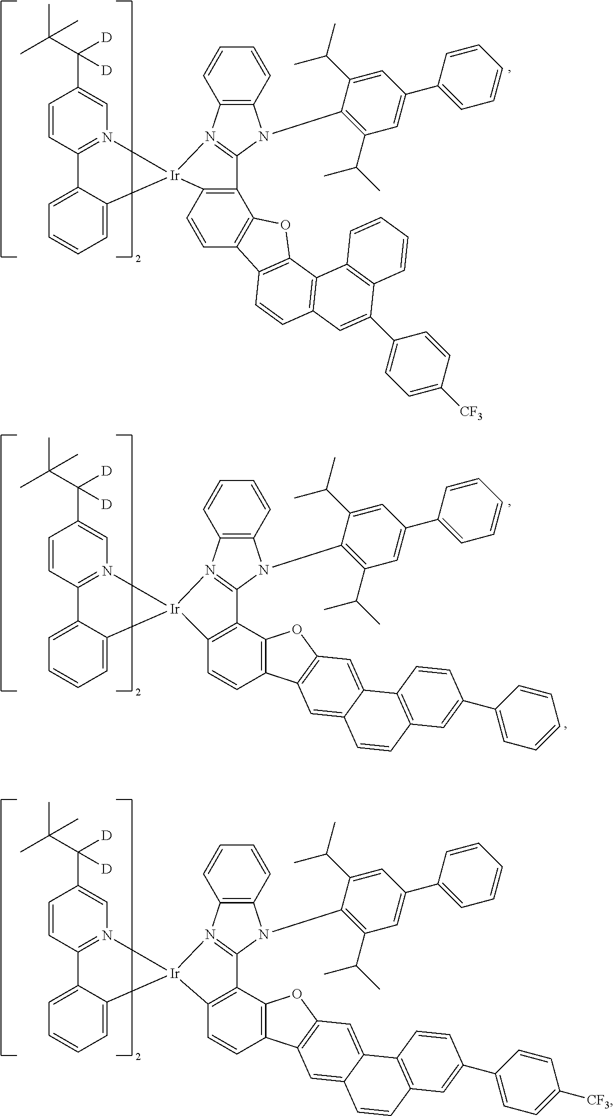

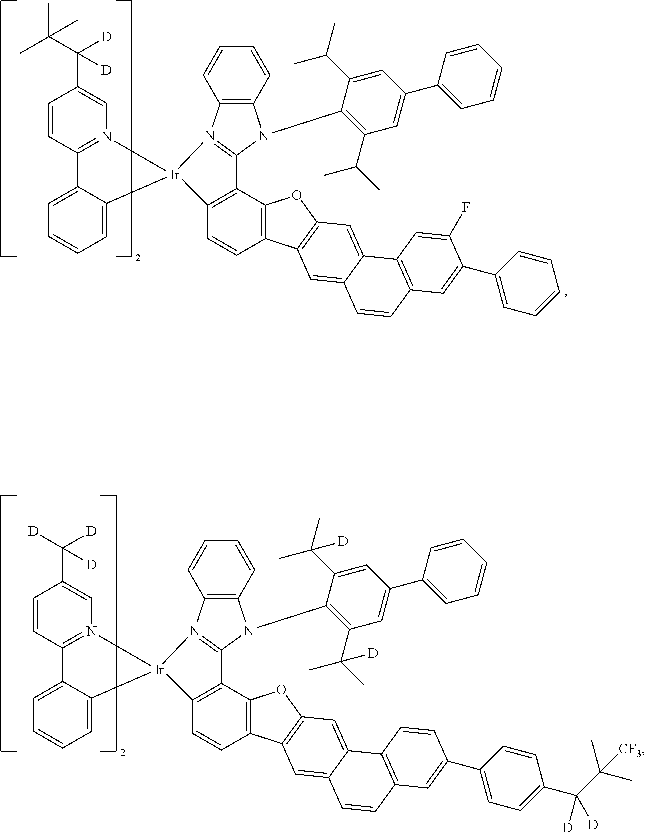

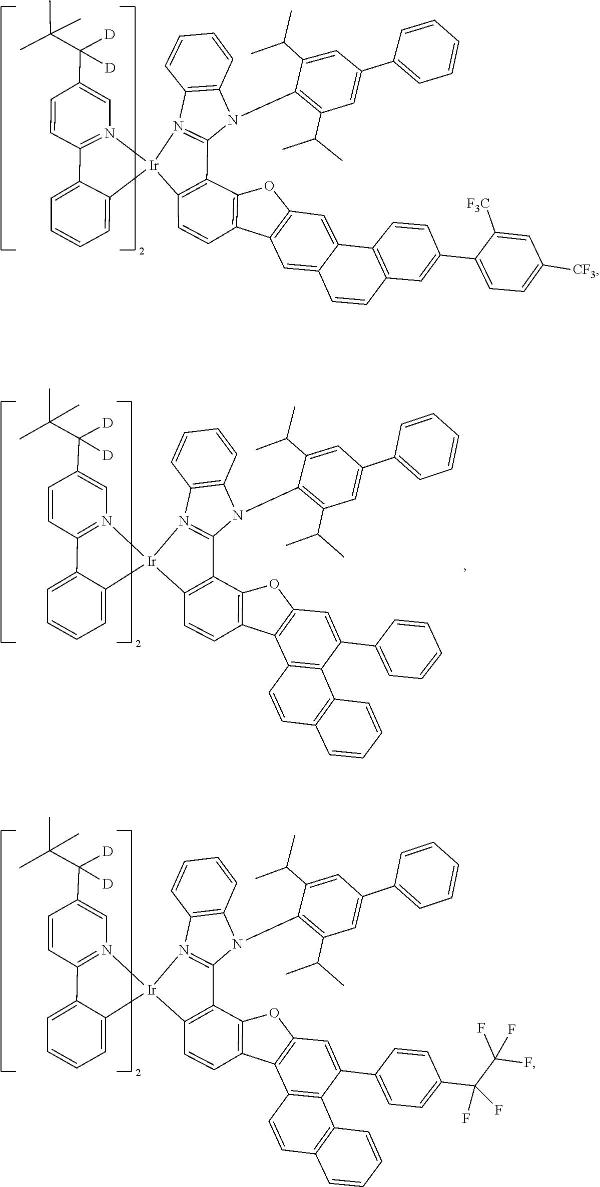

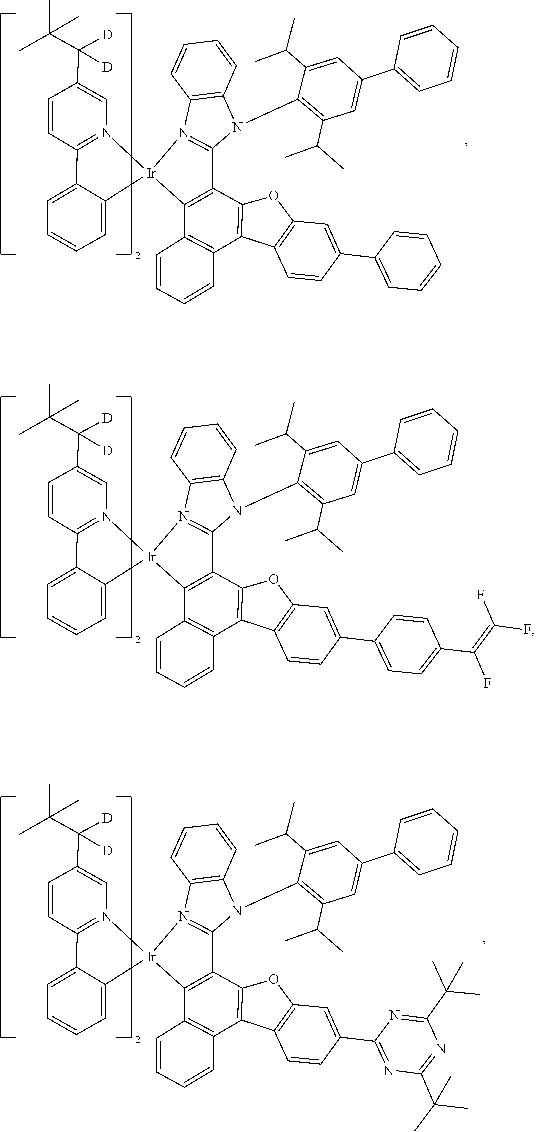

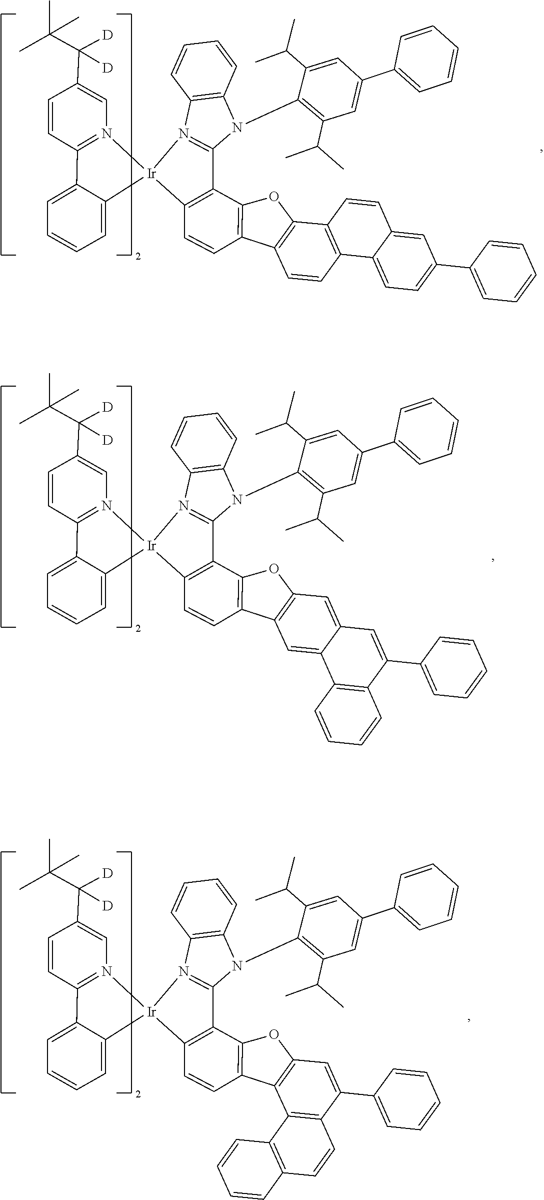

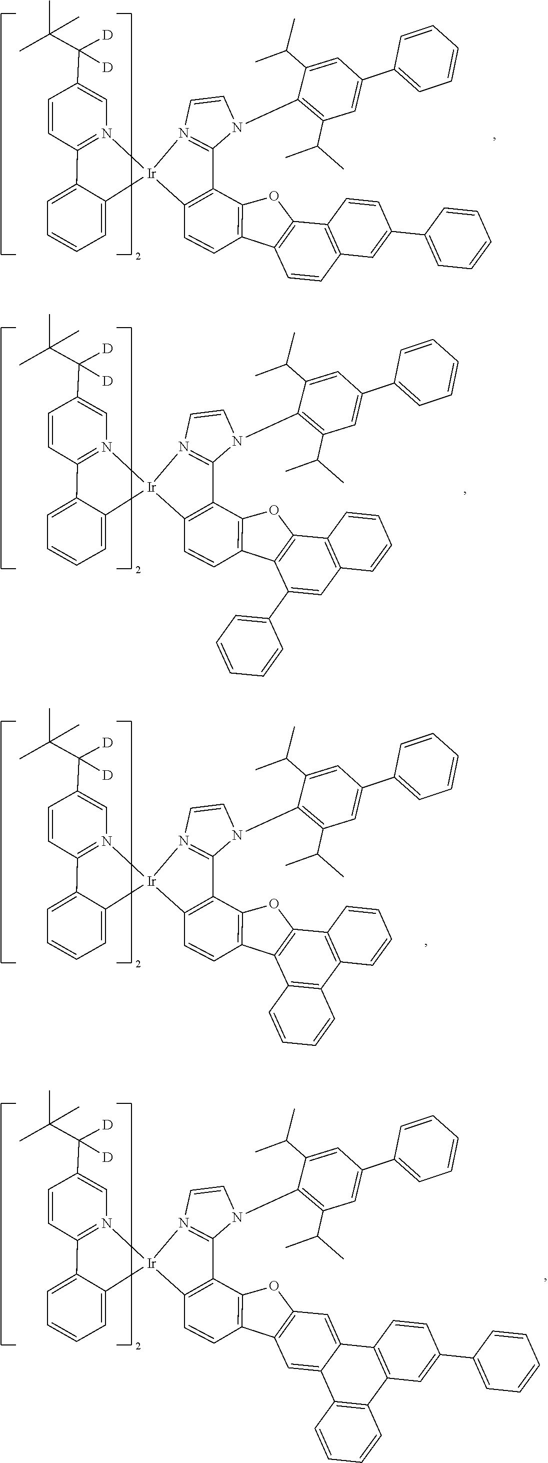

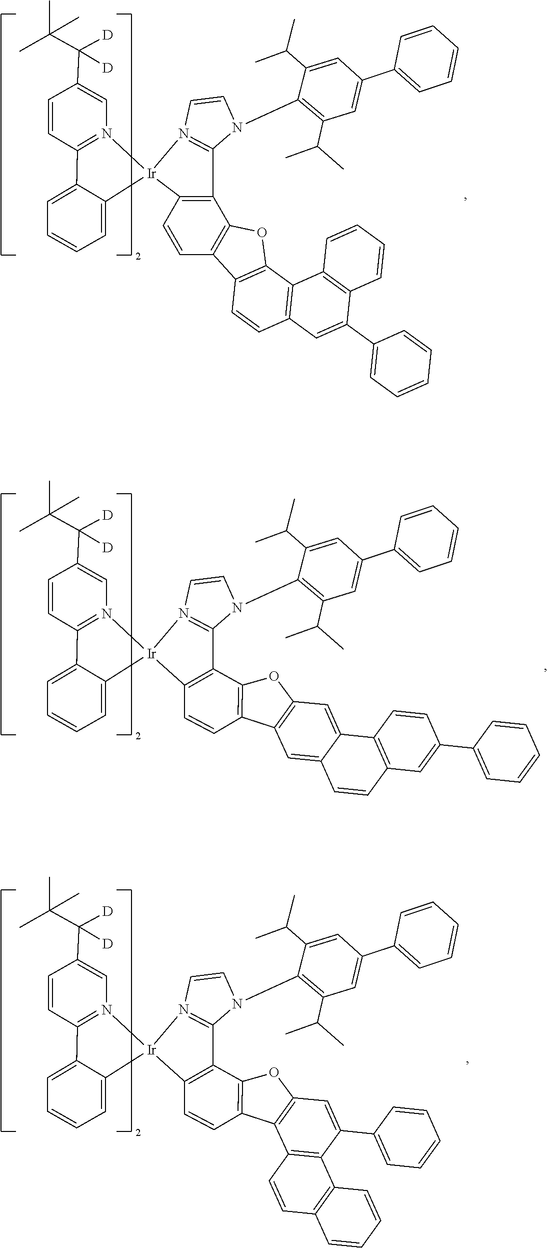

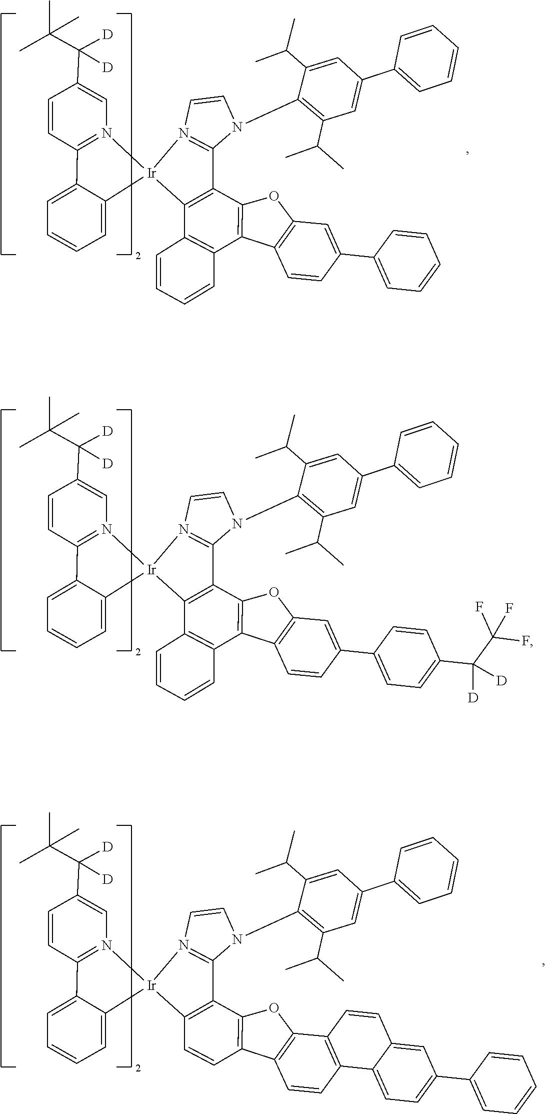

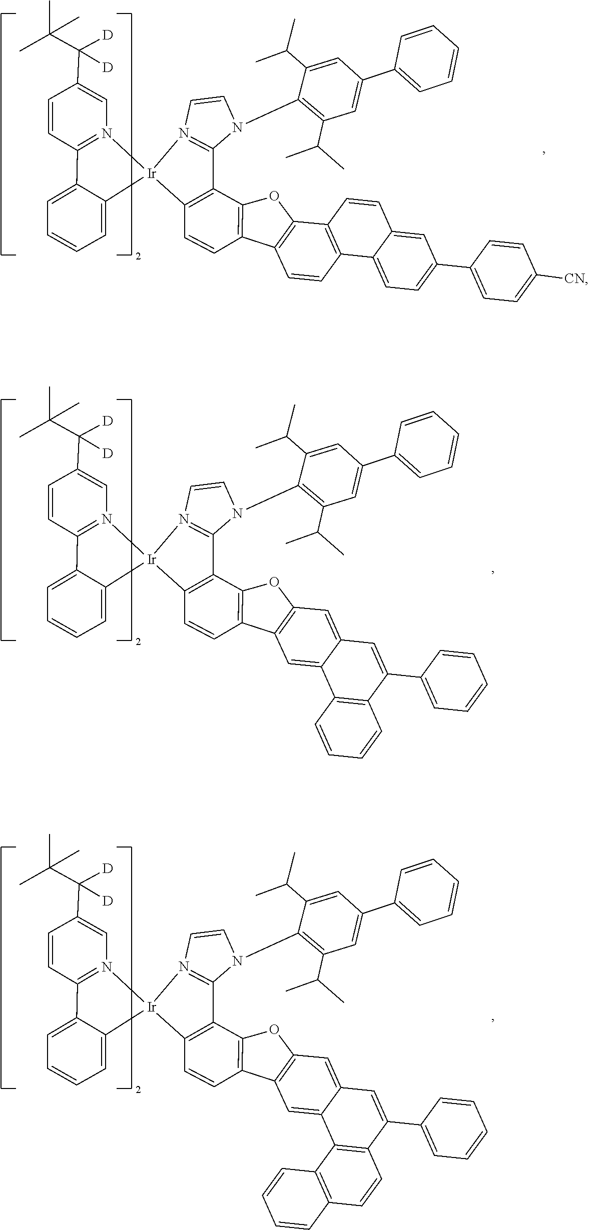

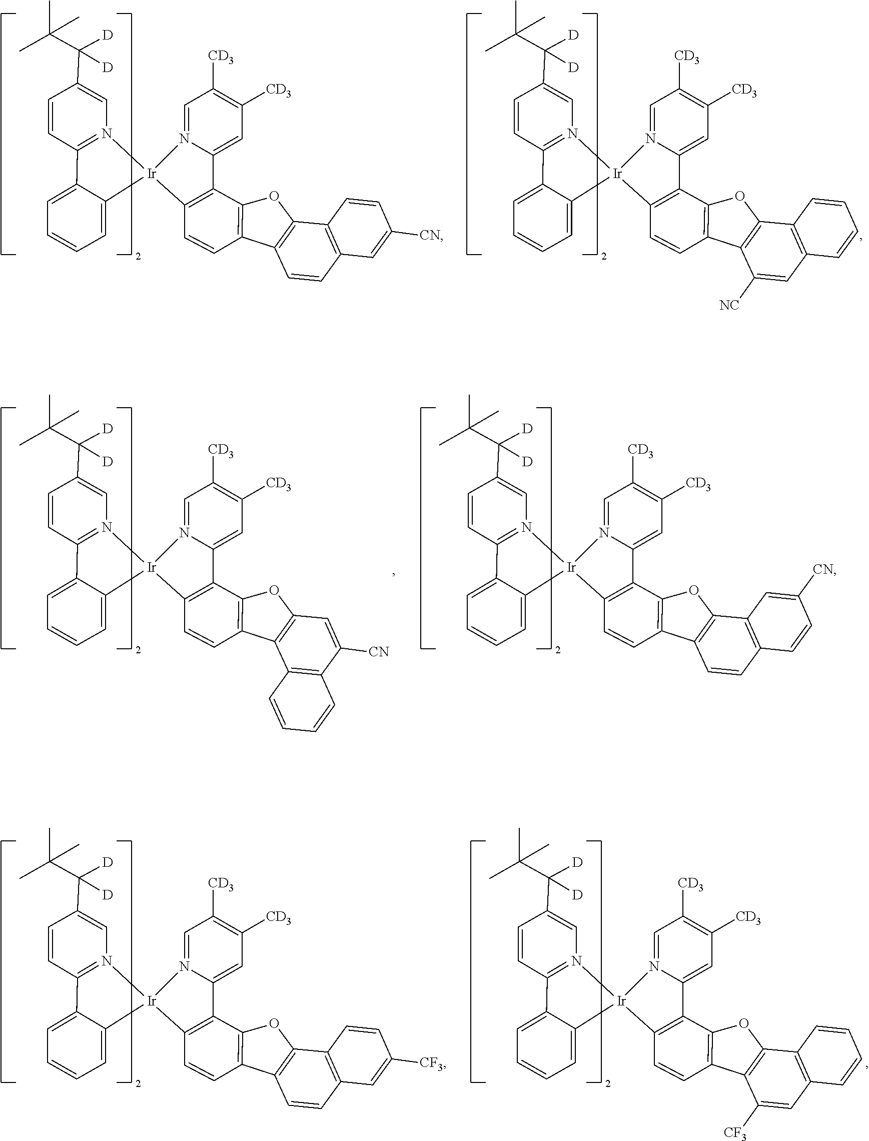

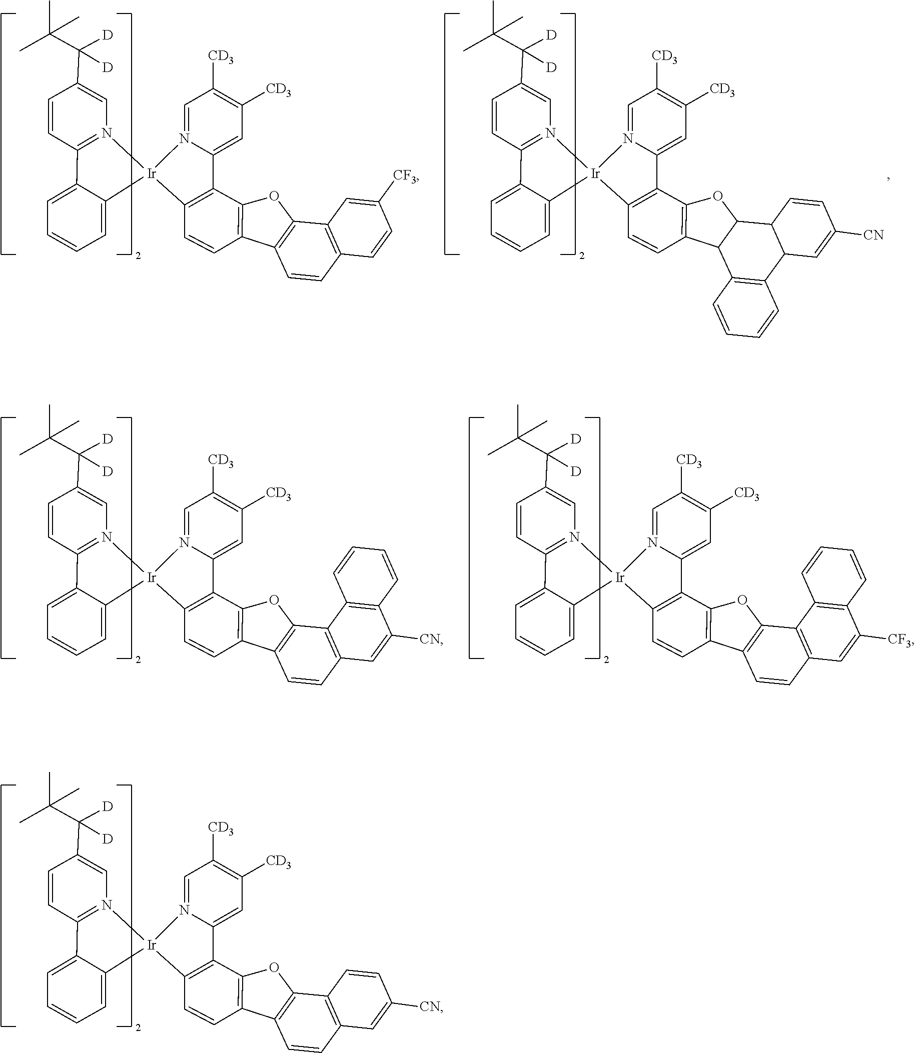

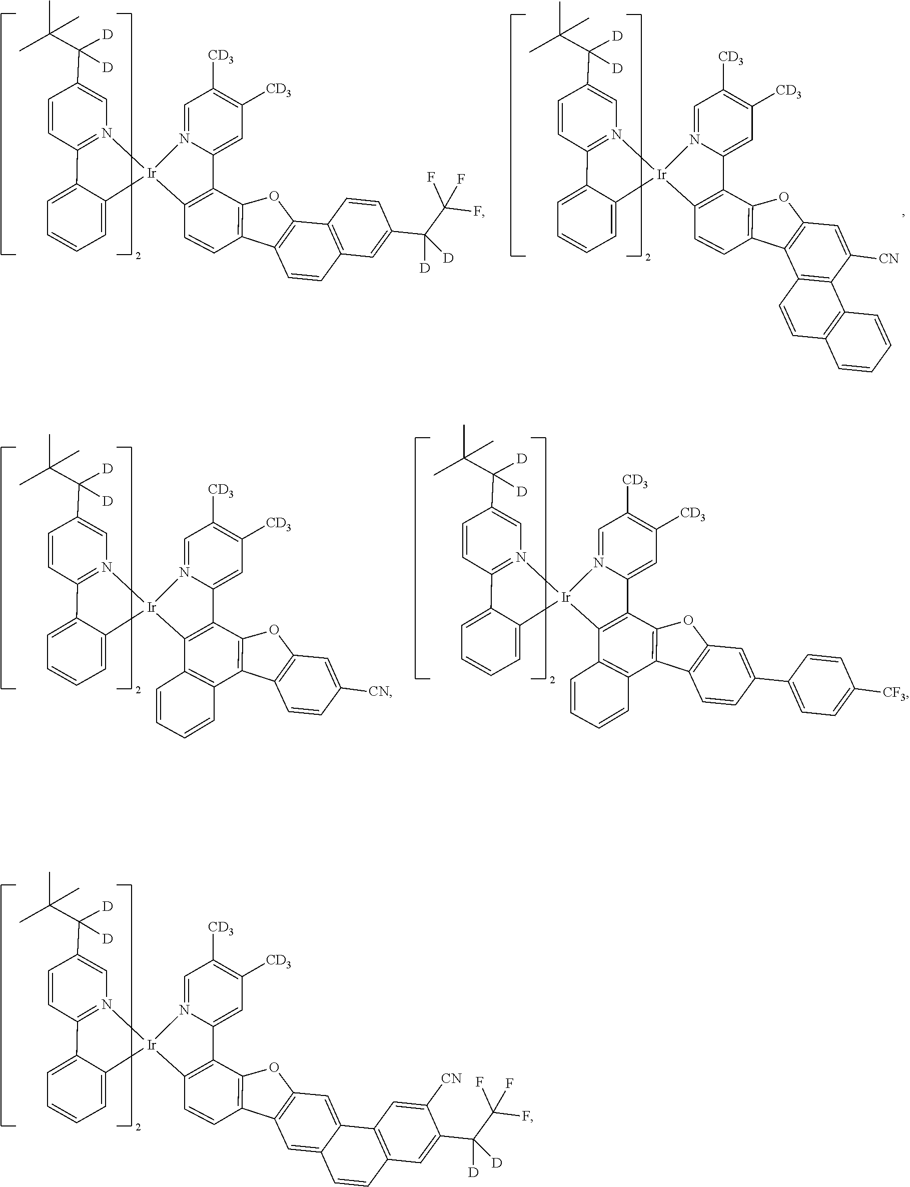

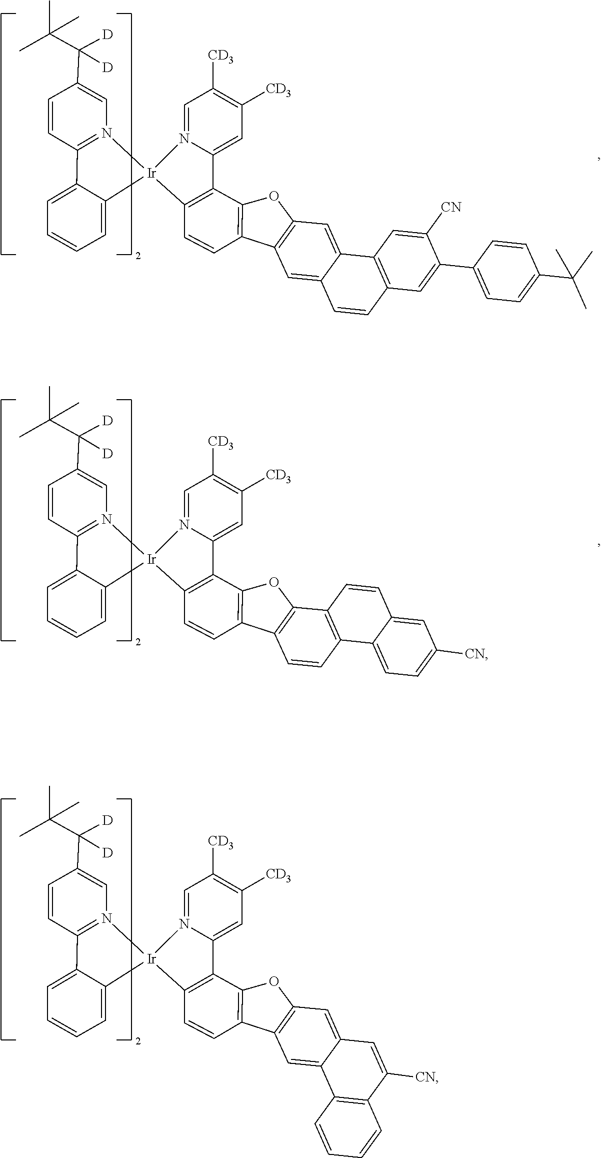

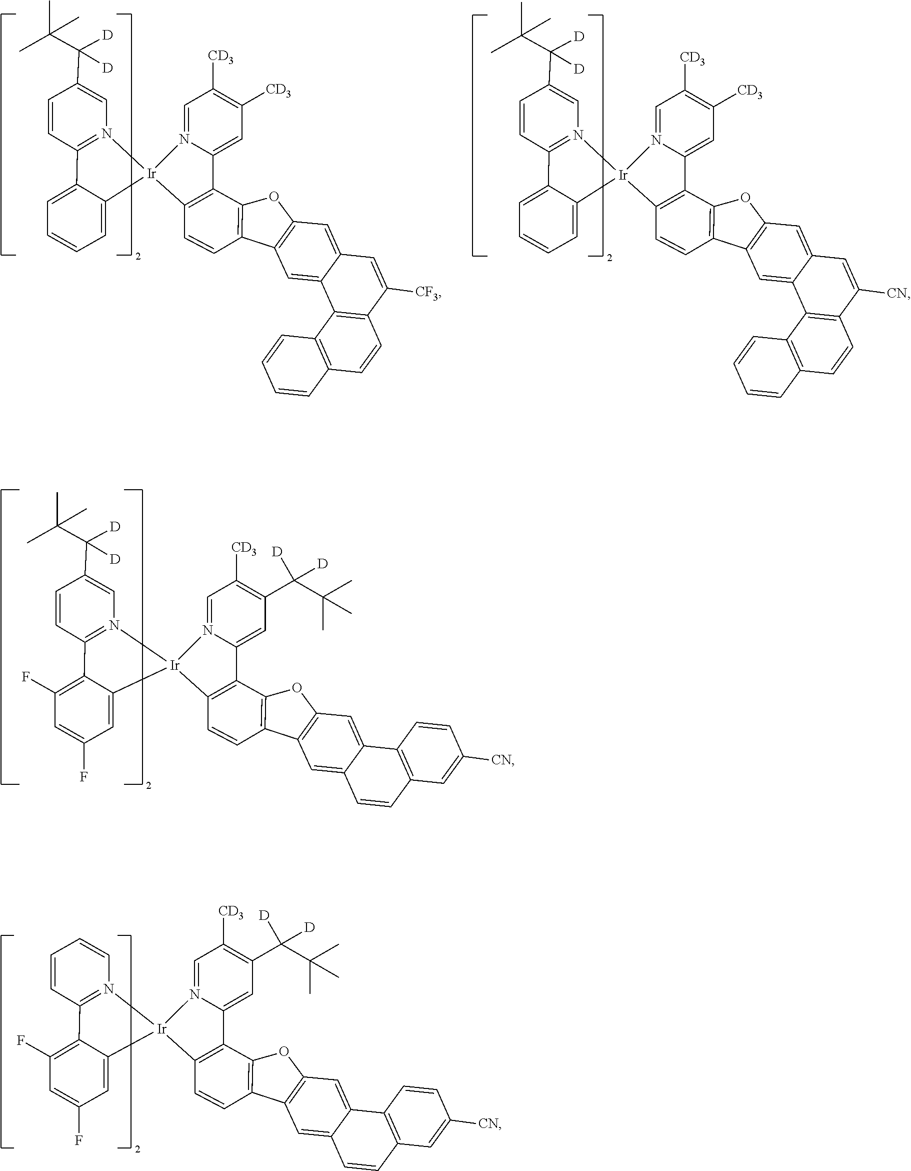

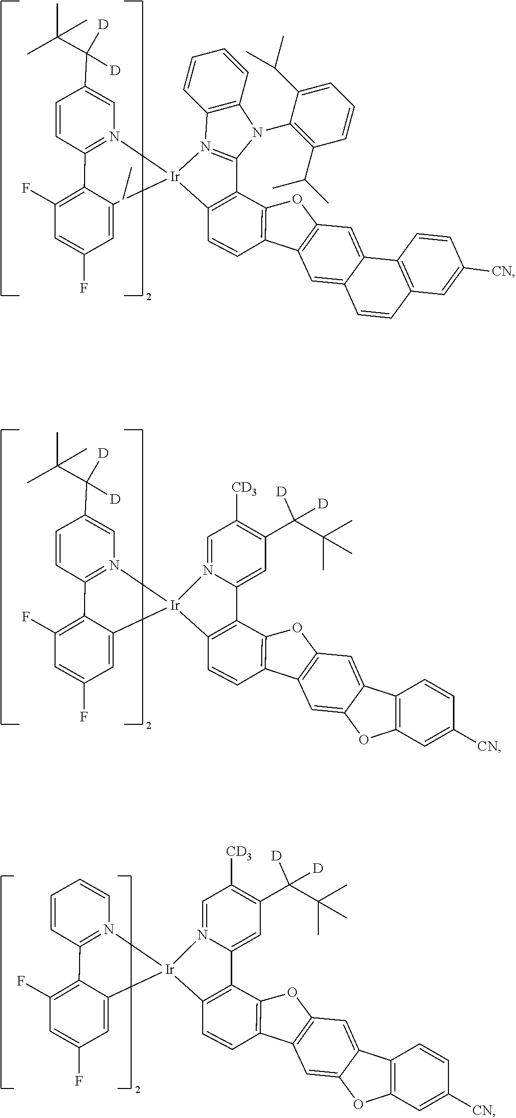

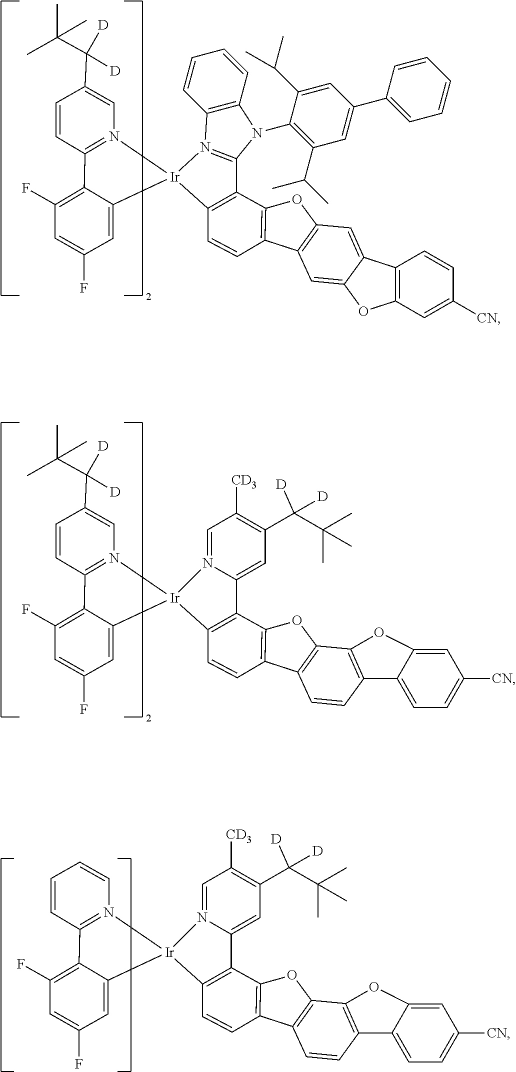

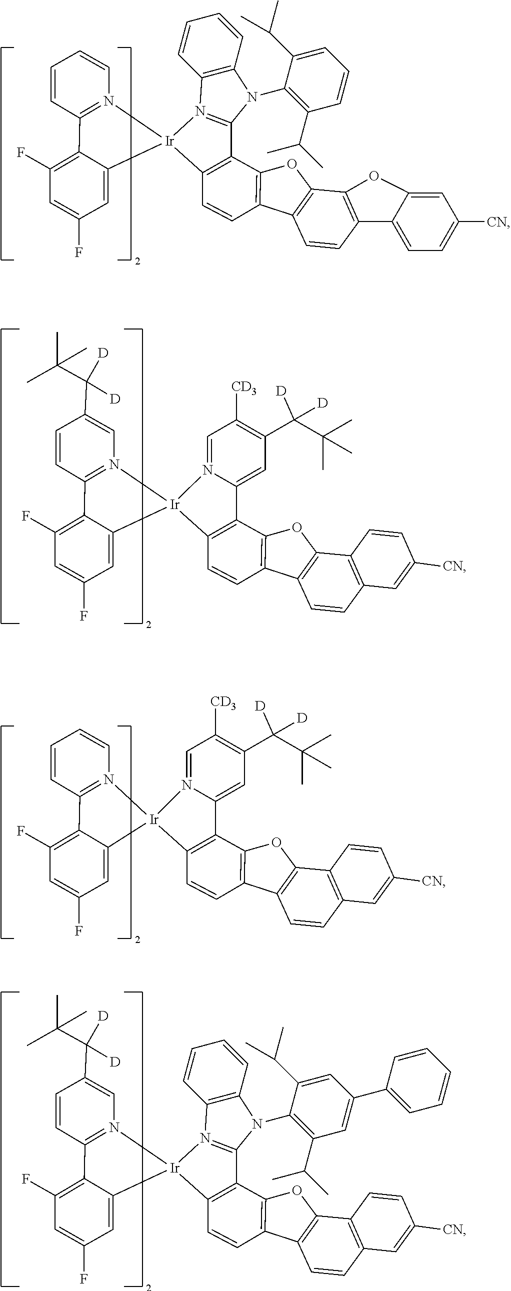

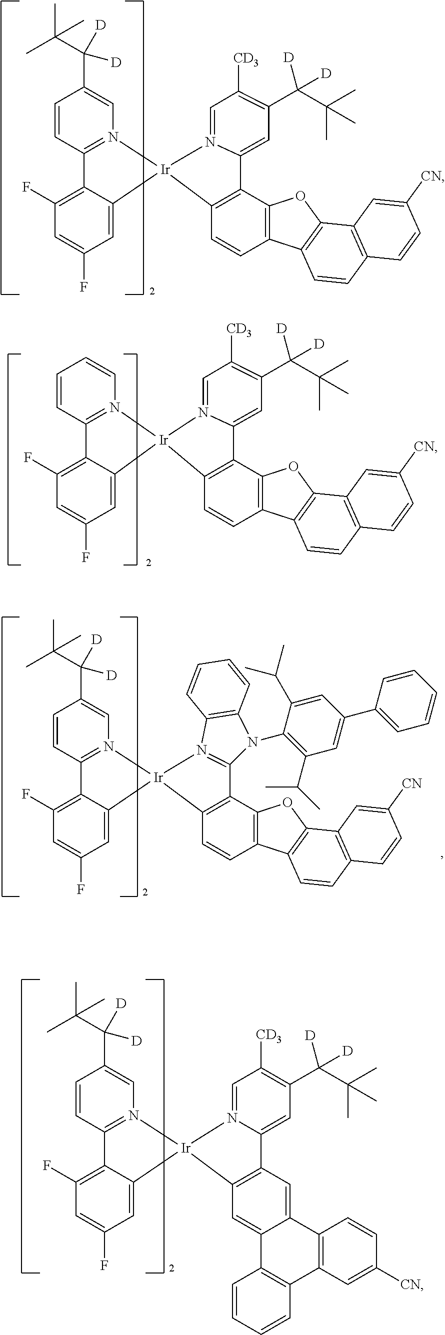

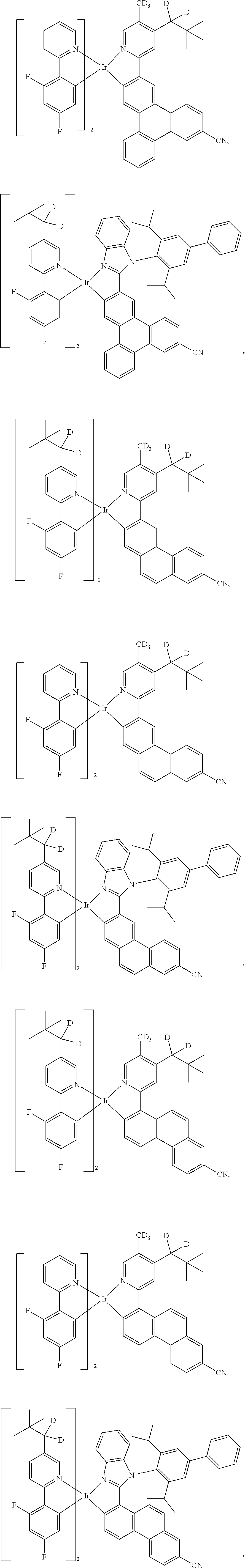

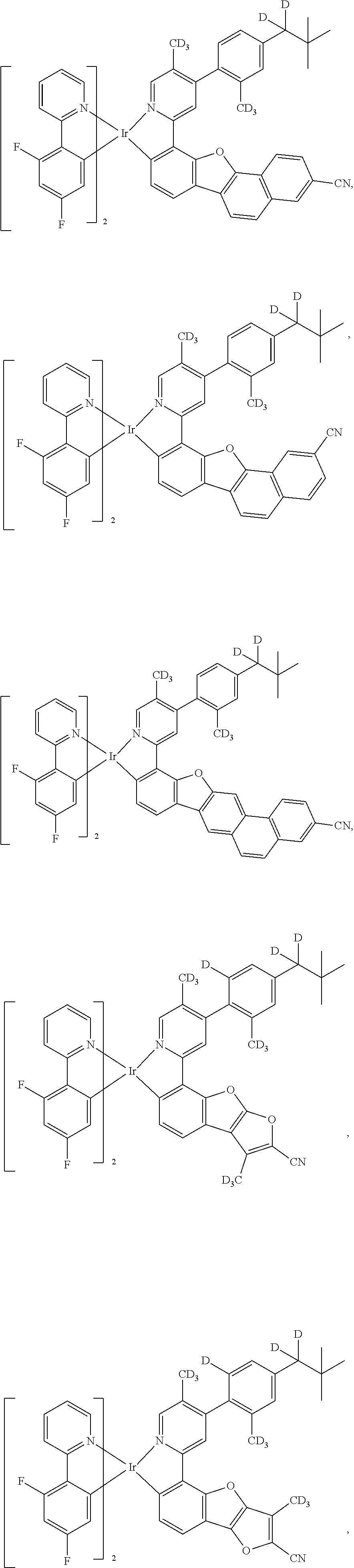

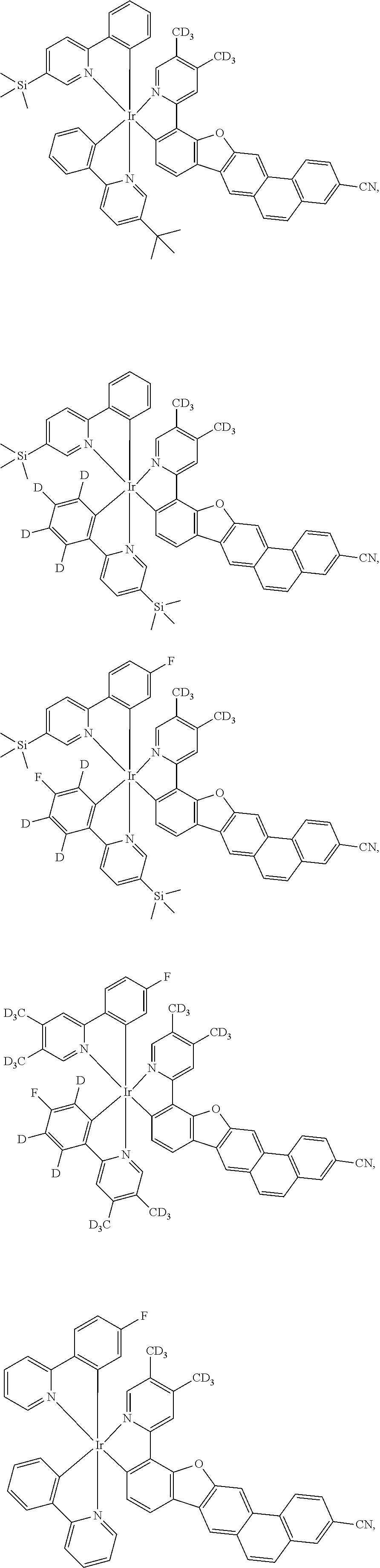

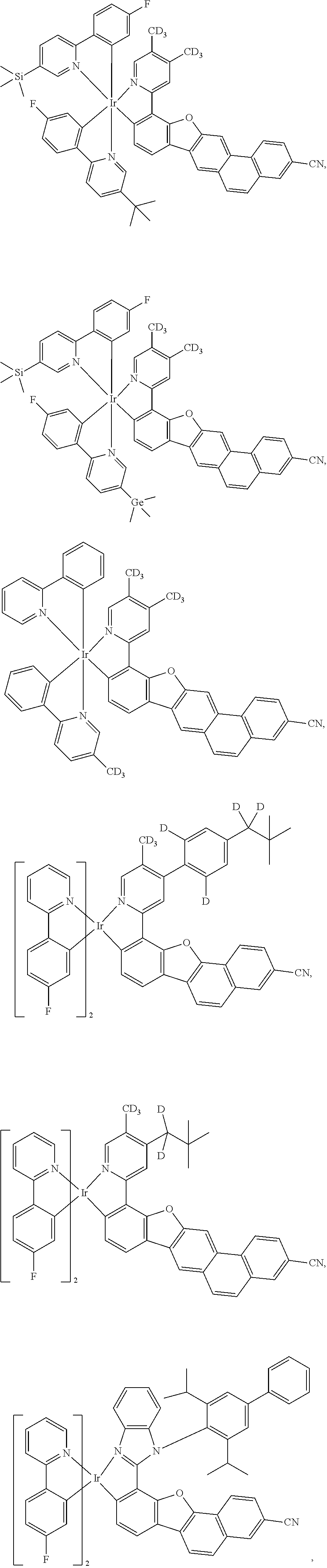

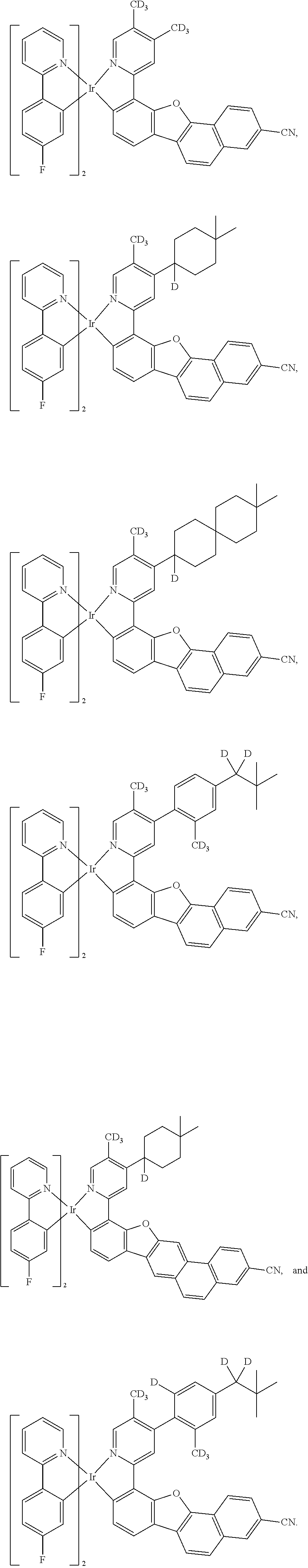

In some embodiments, the compound has the Formula III,

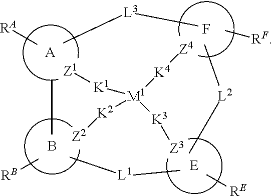

### In Formula III:

M¹ is Pd or Pt;
moieties E and F are each independently monocyclic or polycyclic ring structure comprising 5-membered and/or 6-membered carbocyclic or heterocyclic rings;
Z³ and Z⁴ are each independently C or N;
K¹, K², K³, and K⁴ are each independently selected from the group consisting of a direct bond, O, and S, wherein at least two of them are direct bonds;
L¹, L², and L³ are each independently selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof;
at least one of L¹ and L² is present;
R^{E} and R^{F} each independently represents zero, mono, or up to a maximum allowed number of substitutions to its associated ring;
each R, R′, R^{E}, and R^{F} is independently a hydrogen or a substituent selected from the group consisting of the Preferred General Substituents; and
two adjacent R, R′, R^{A}, R^{B}, R^{E}, and R^{F} can be joined or fused together to form a ring where chemically feasible.

In some embodiments, moiety E and moiety F are both 6-membered aromatic rings.

In some embodiments, moiety F is a 5-membered or 6-membered heteroaromatic ring.

In some embodiments, L¹ is O or CRR′.

In some embodiments, Z² is N and Z¹ is C.

In some embodiments, Z² is C and Z¹ is N.

In some embodiments, L² is a direct bond. In some embodiments, L² is NR.

In some embodiments, K¹, K², K³, and K⁴ are all direct bonds.

In some embodiments, one of K¹, K², K³, and K⁴ is O.

In some embodiments, the compound can be selected from the group consisting of compounds having the formula of Pt(L_{A′})(Ly).

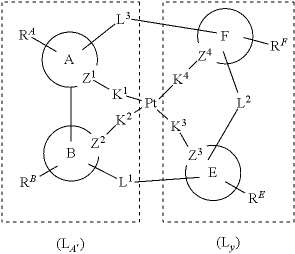

wherein L_{A′} is selected from the group consisting of the structures shown in the following LIST 14:

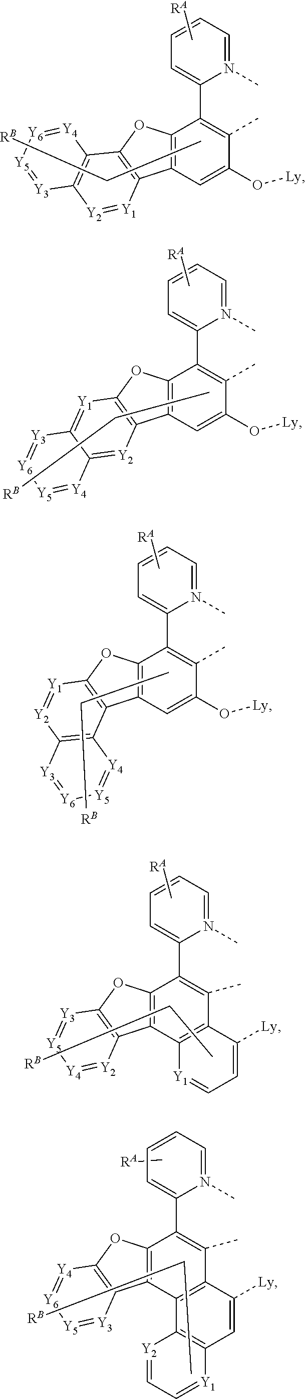

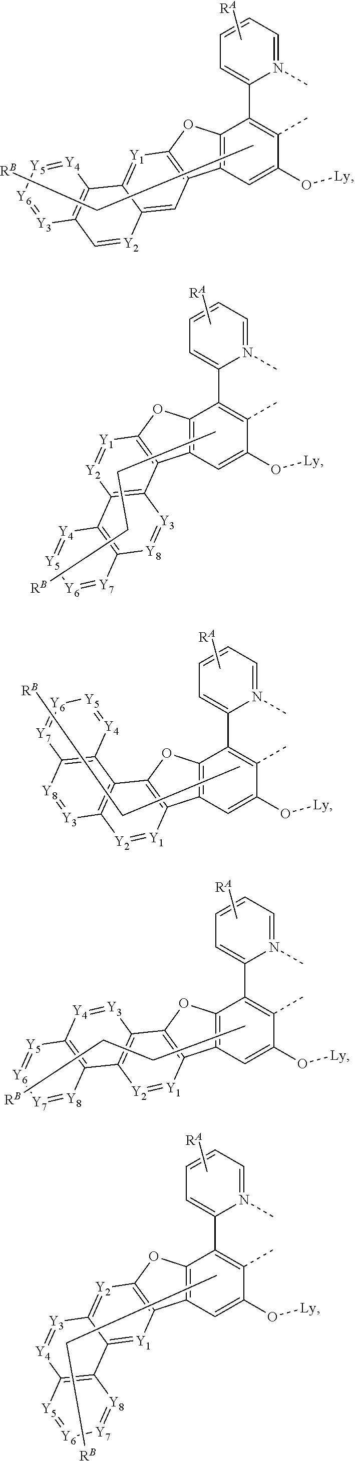

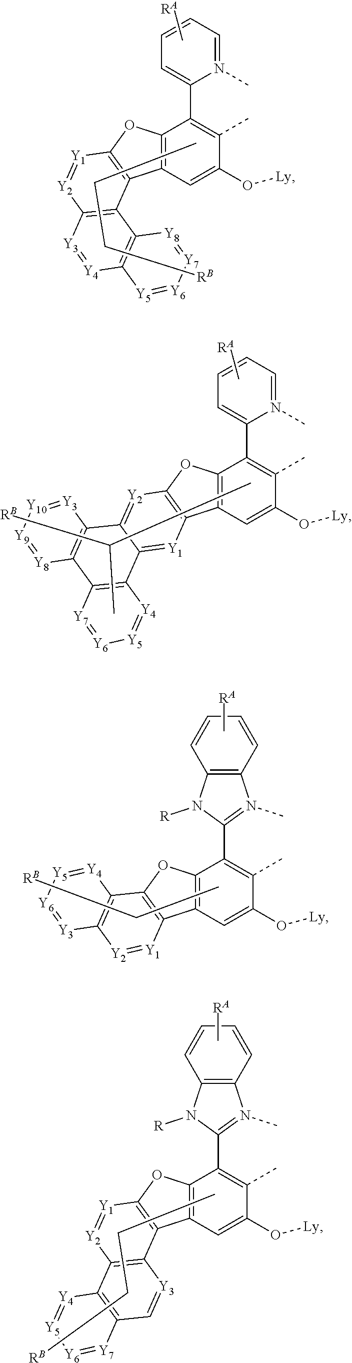

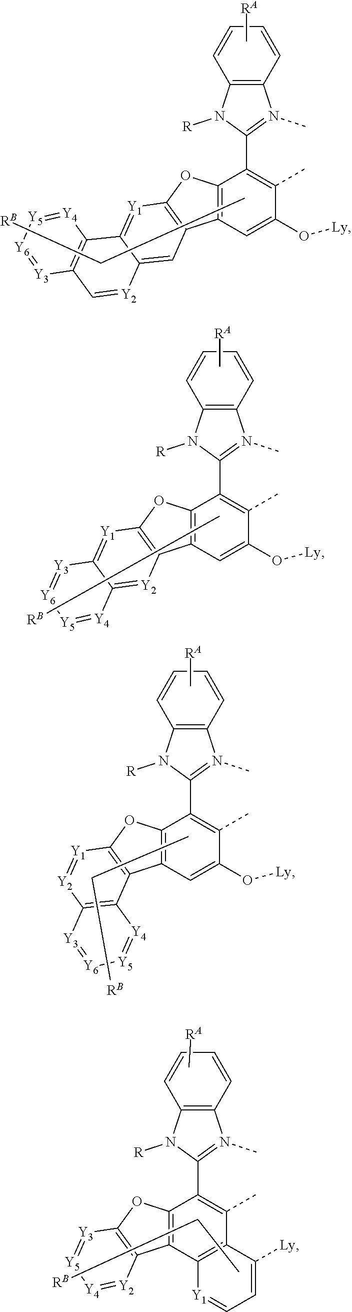

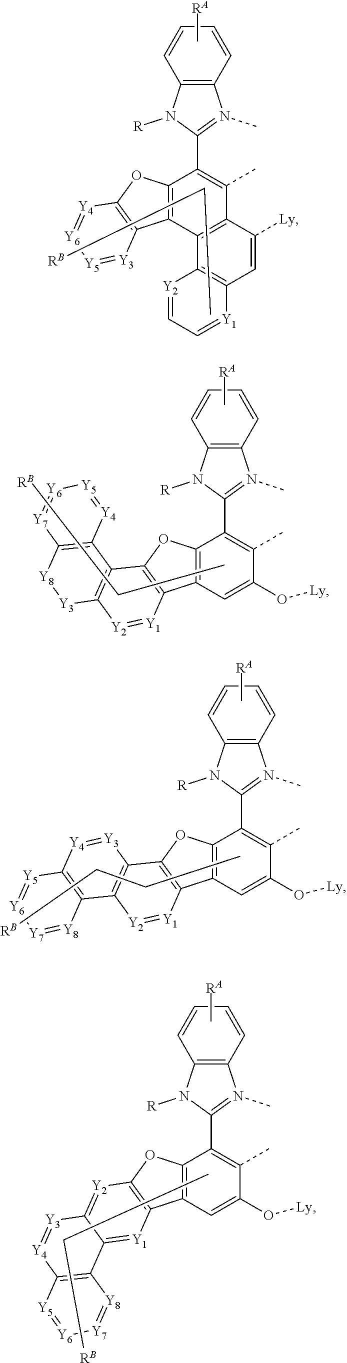

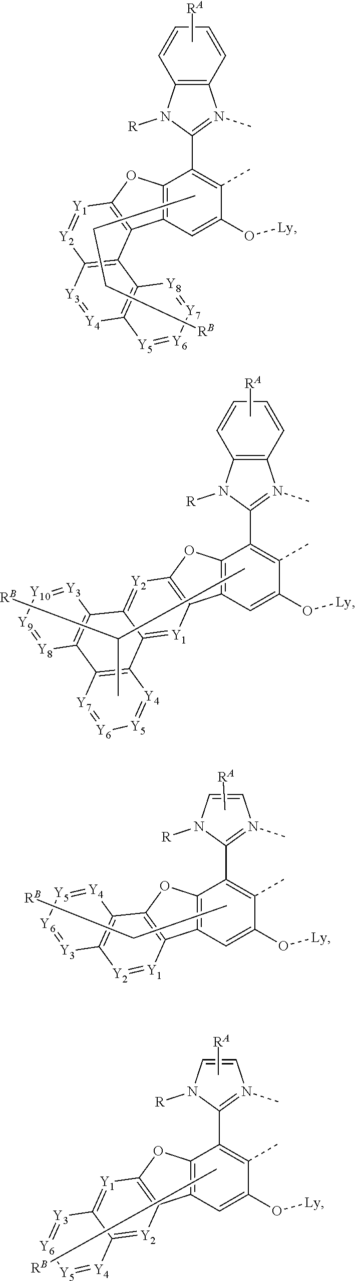

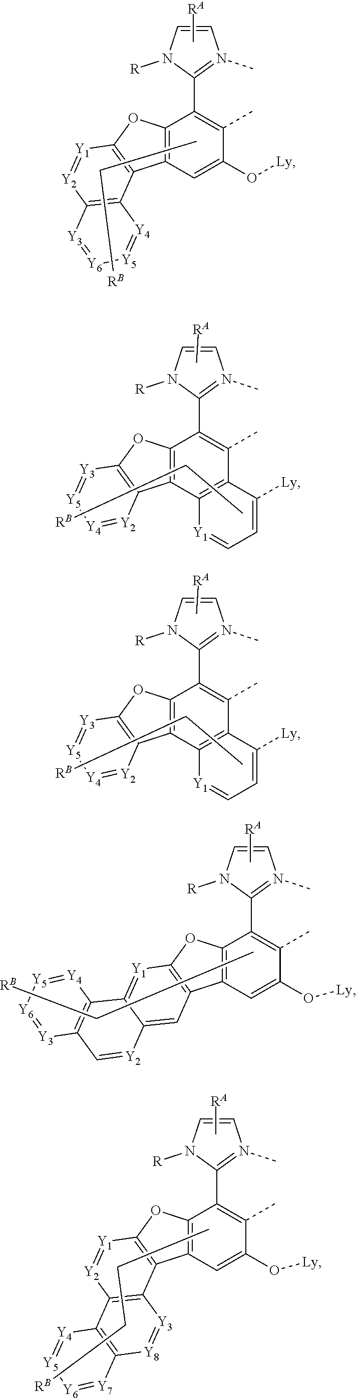

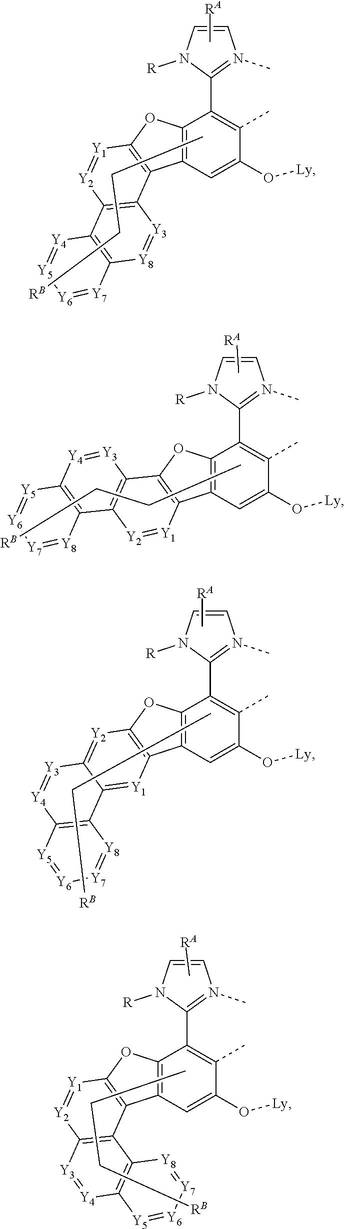

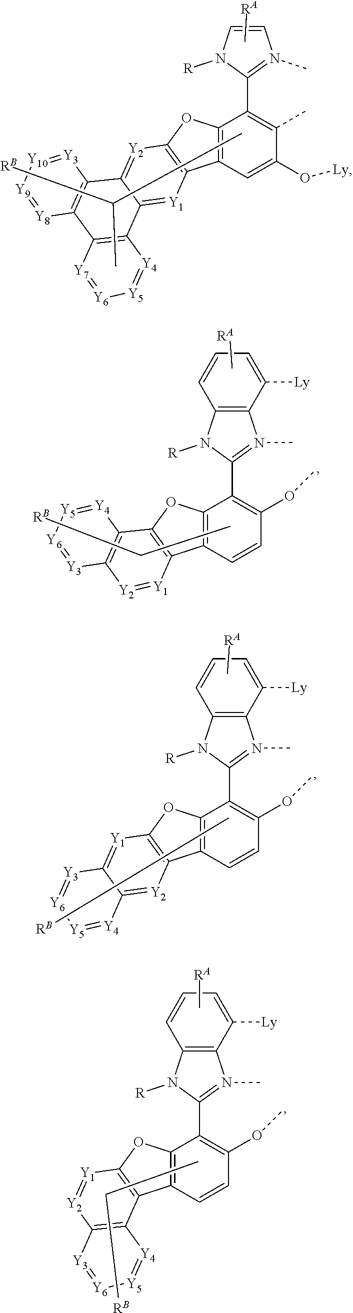

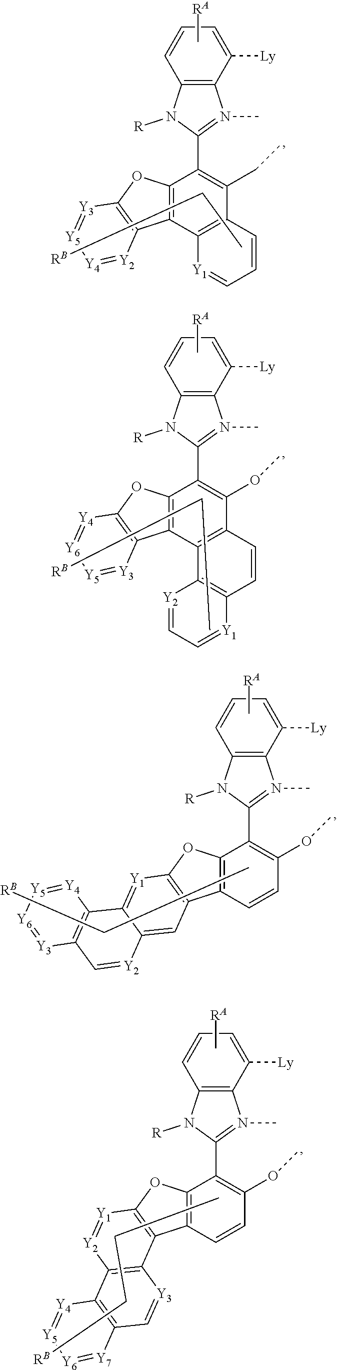

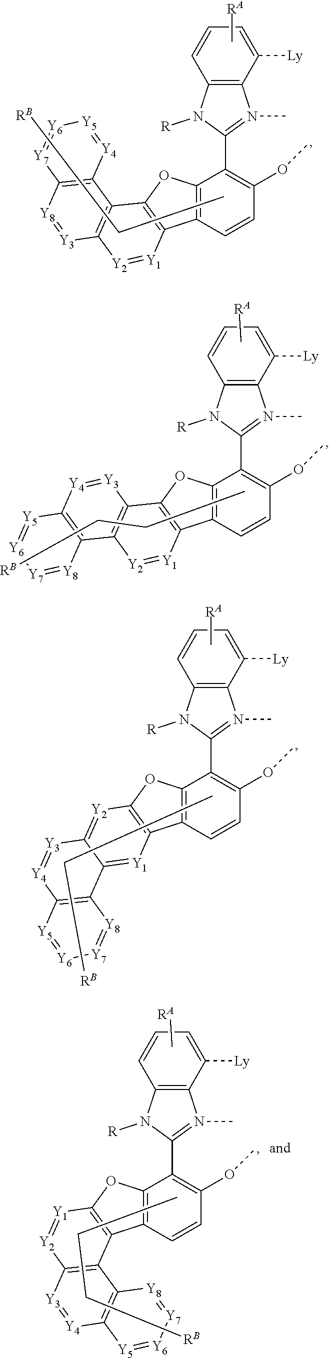

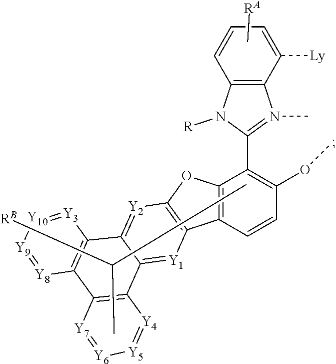

wherein L_{y} is selected from the group consisting of the structures shown in the following LIST 15:

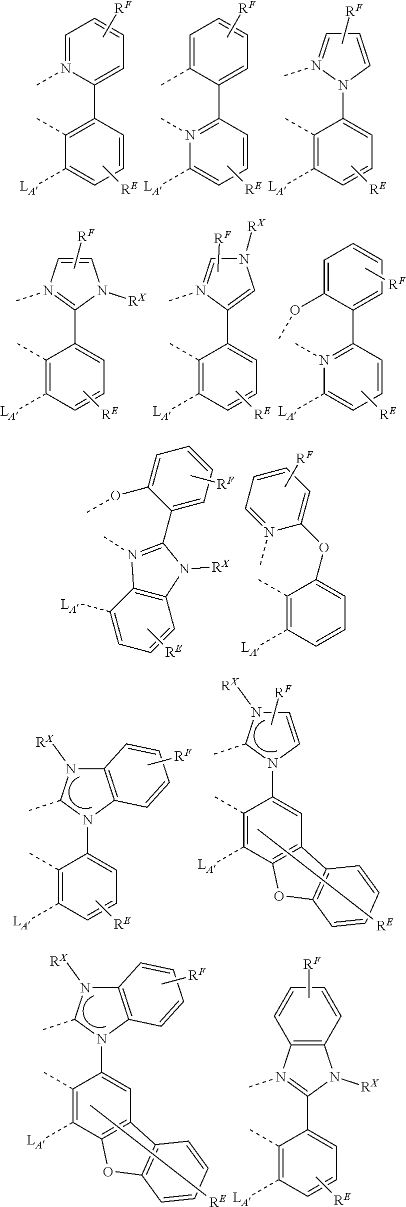

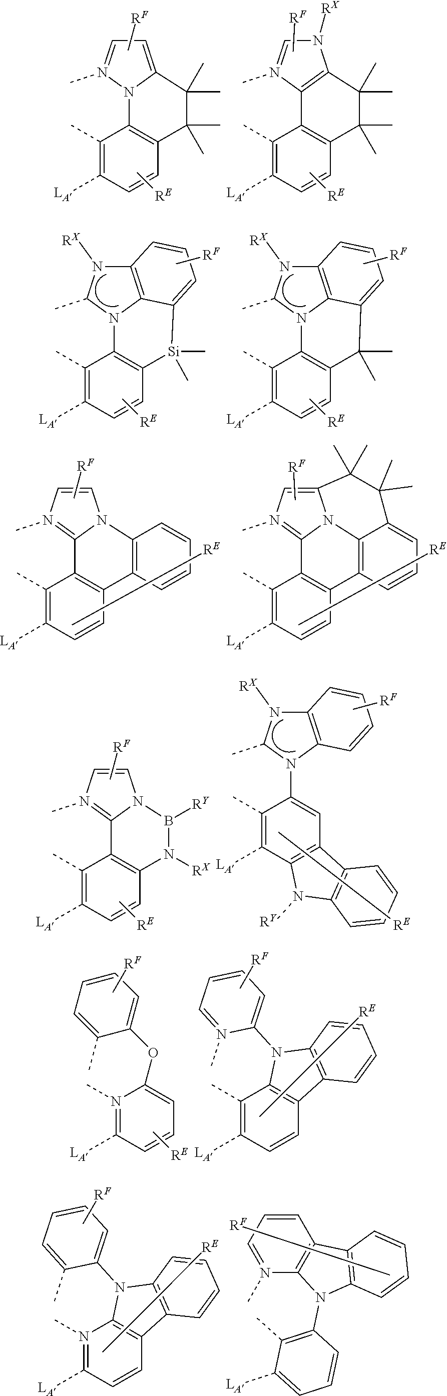

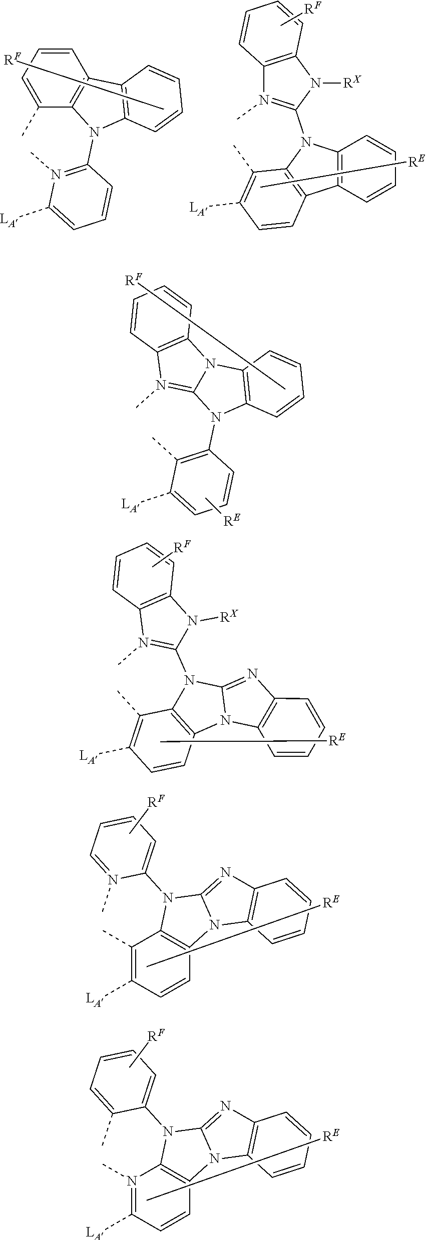

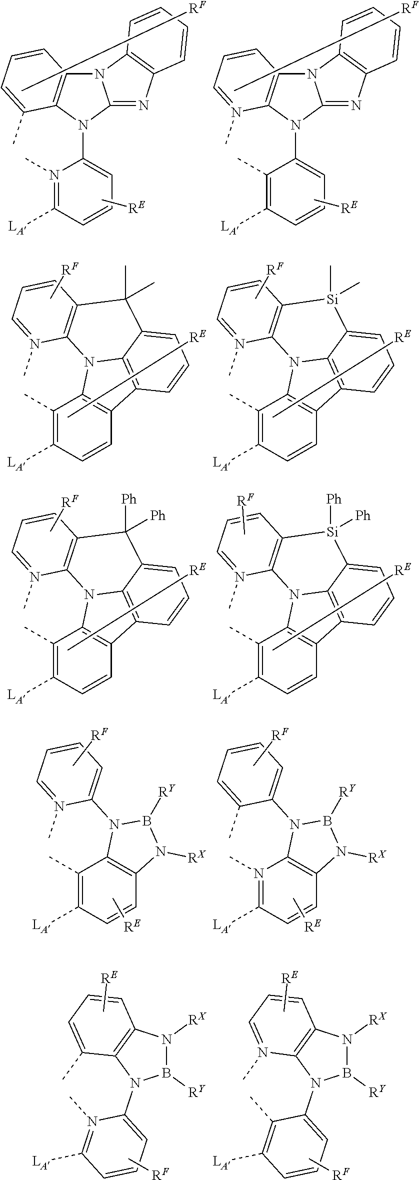

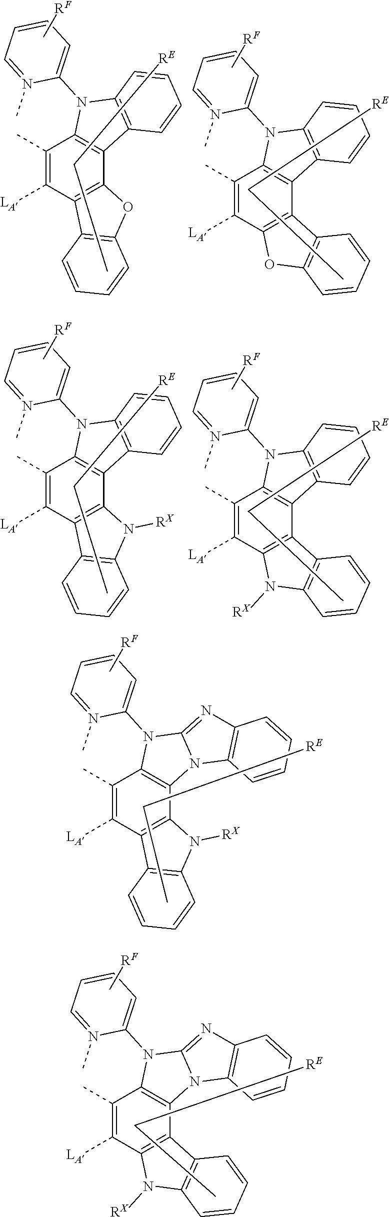

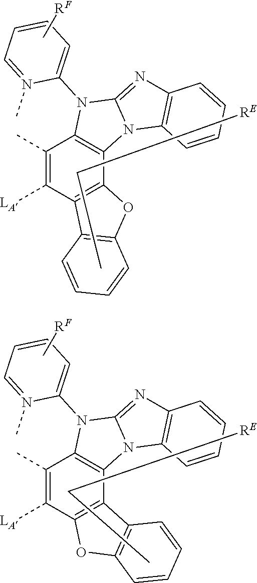

wherein each of Y₁, Y₂, Y₃, Y₄, Y₅, Y₆, Y₇, Y₈, Y₉, and Y₁₀ is independently C or N;
wherein each of R^{A}, R^{B}, R^{E}, and R^{F} is independently mono-substitution, up to the maximum allowable substitutions, or no substitutions;
wherein each R^{B} is independently selected from the group consisting of the structures of LIST 15A, LIST 5, and LIST 6;
wherein at least one R^{B} comprises a cyclic group of LIST 6 or an electron-withdrawing group of LIST 5;
wherein each R^{A}, R^{E}, R^{F}, R^{X}, and R^{Y} is independently selected from the list consisting of the structures of the following LIST 15A:

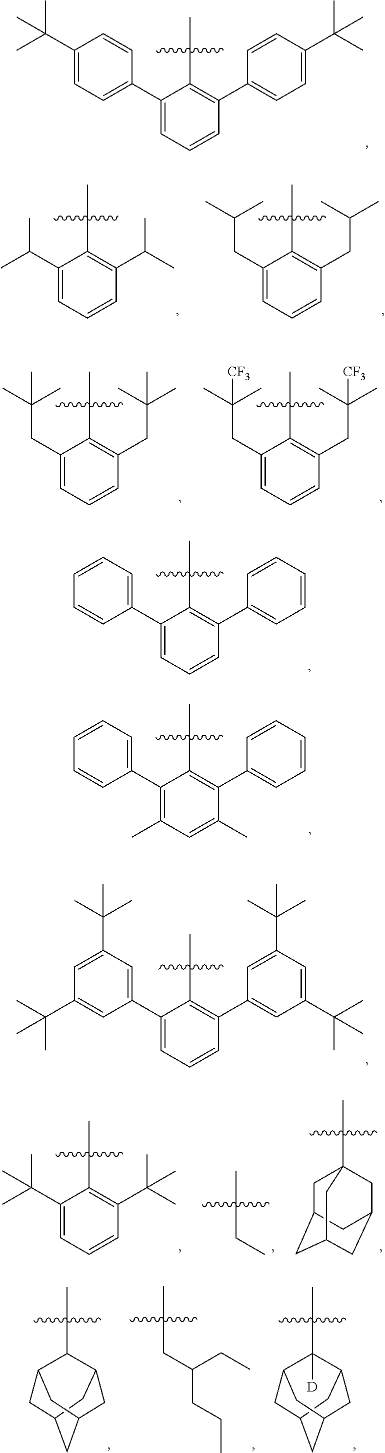

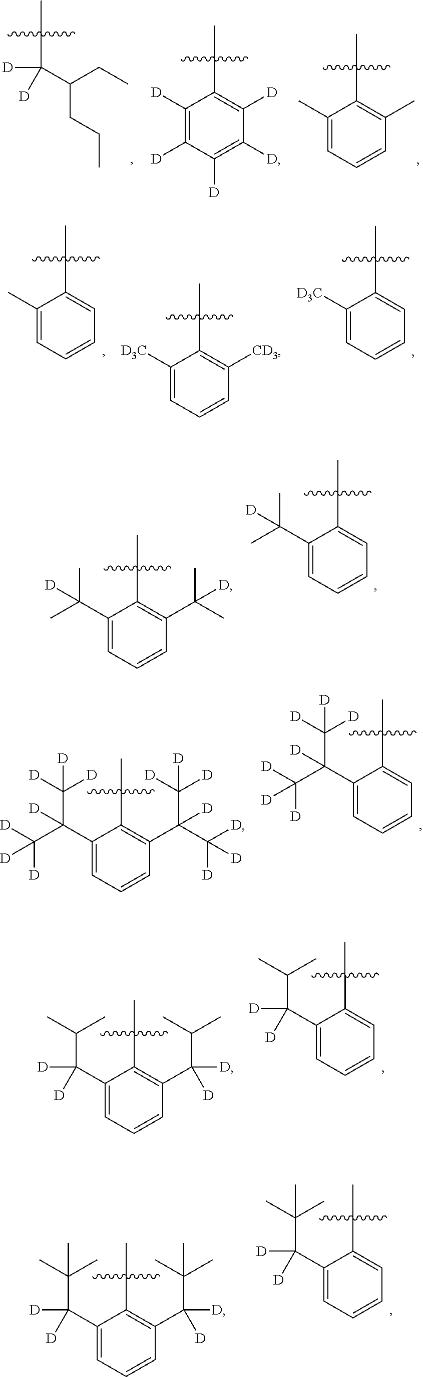

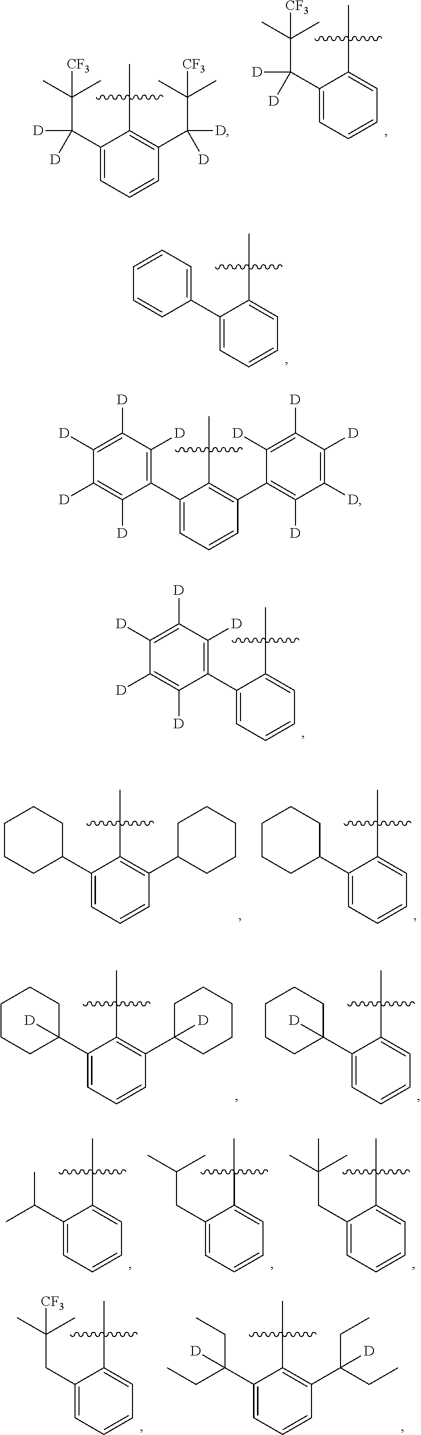

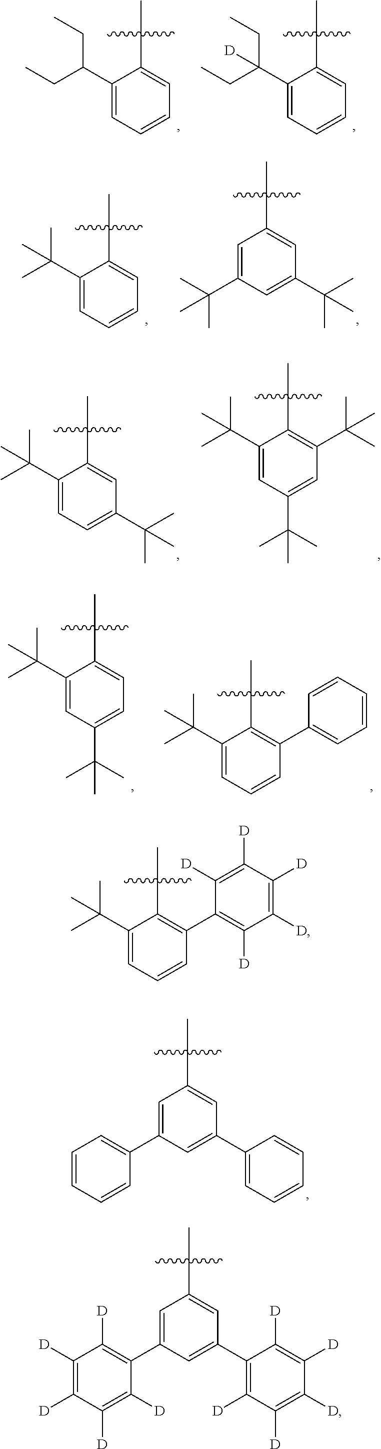

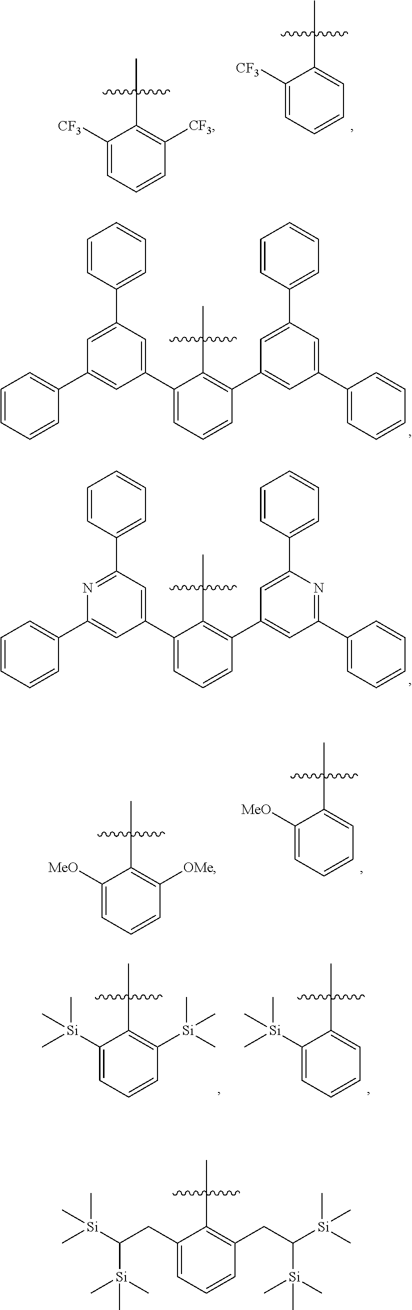

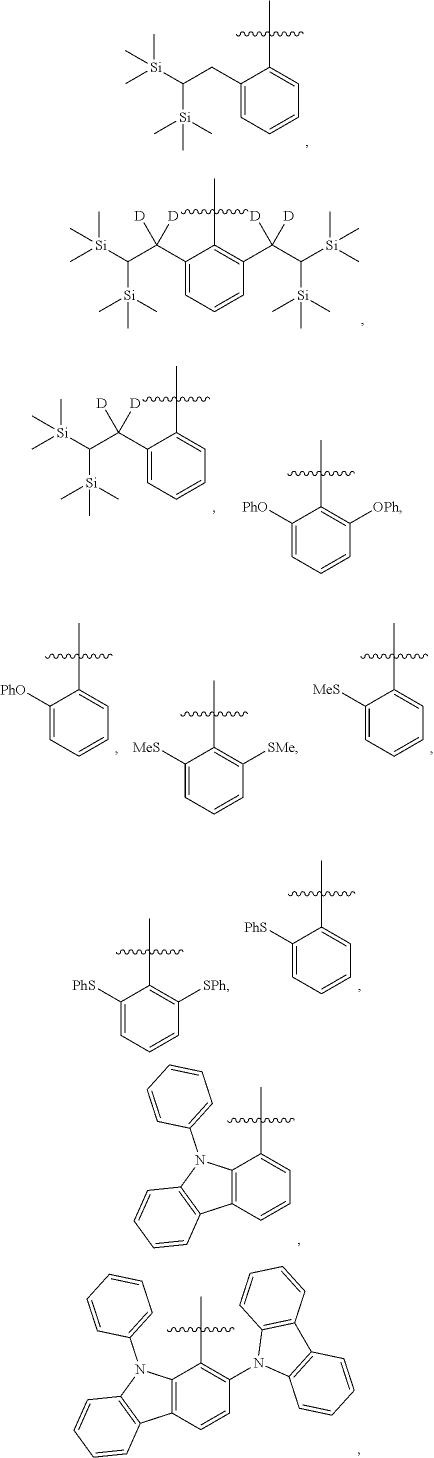

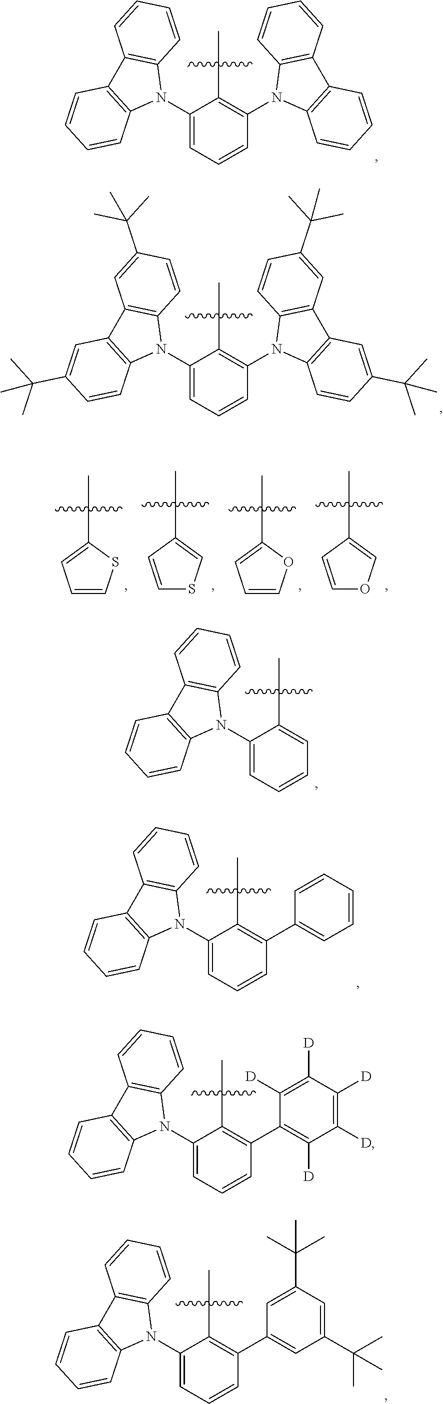

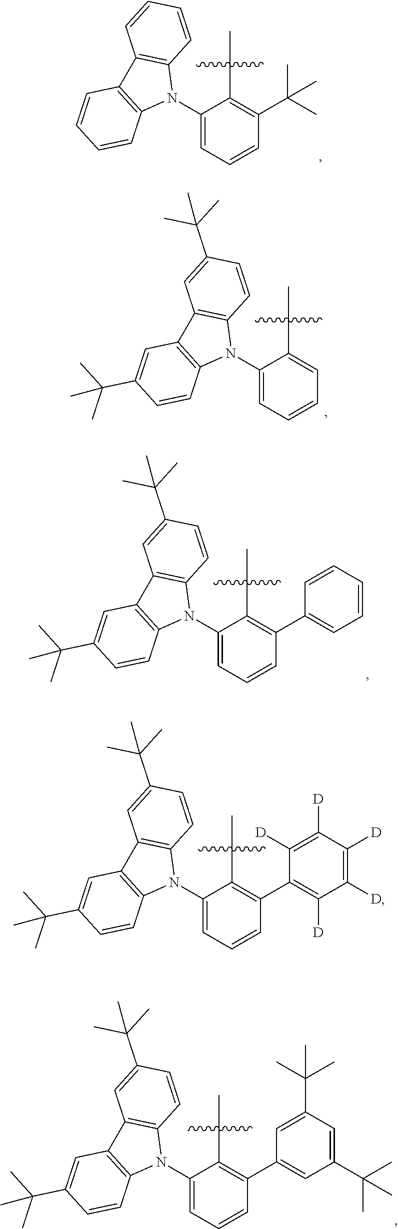

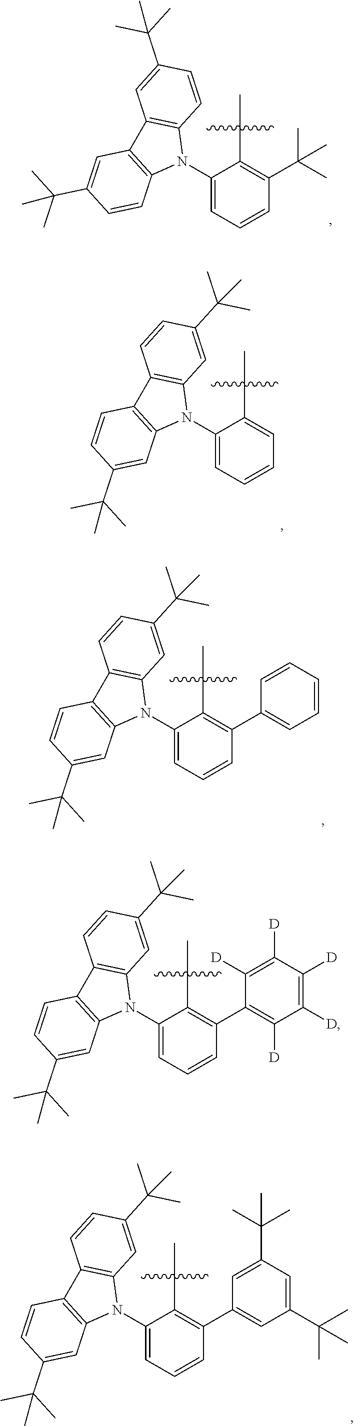

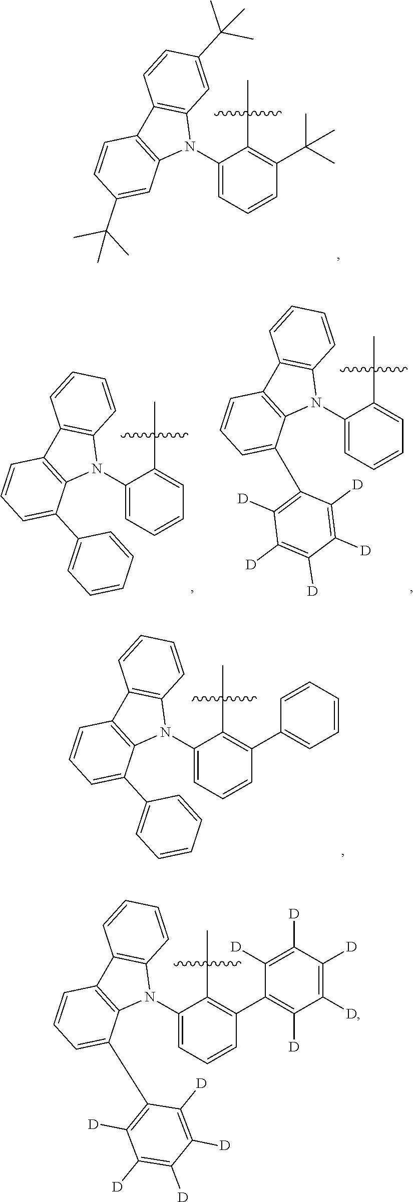

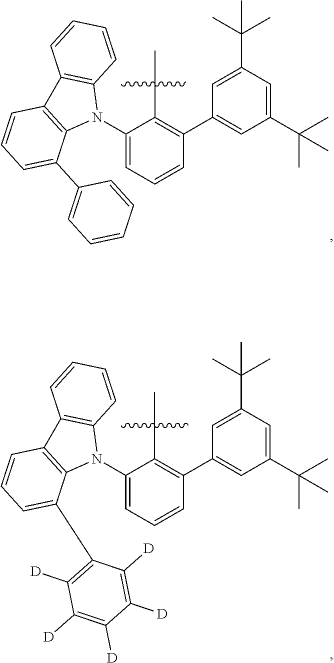 [SMILES: *c1c(-c2cc(C(C)(C)C)cc(C(C)(C)C)c2)cccc1-n1c2ccccc2c2cccc(-c3ccccc3)c21 ; *c1c(-c2cc(C(C)(C)C)cc(C(C)(C)C)c2)cccc1-n1c2ccccc2c2cccc(-c3c([2H])c([2H])c([2H])c([2H])c3[2H])c21]

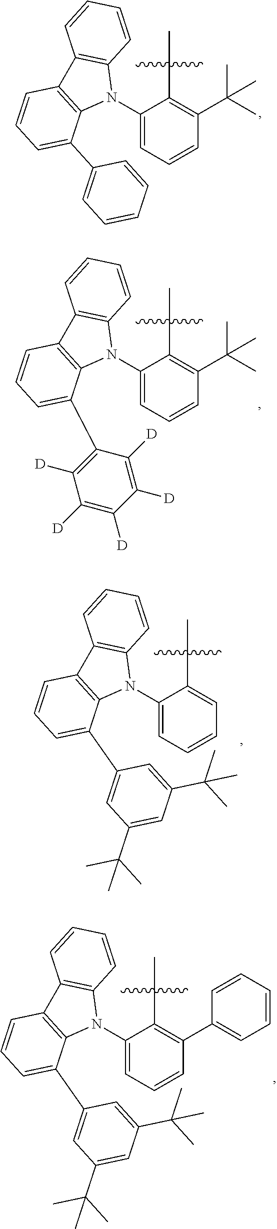

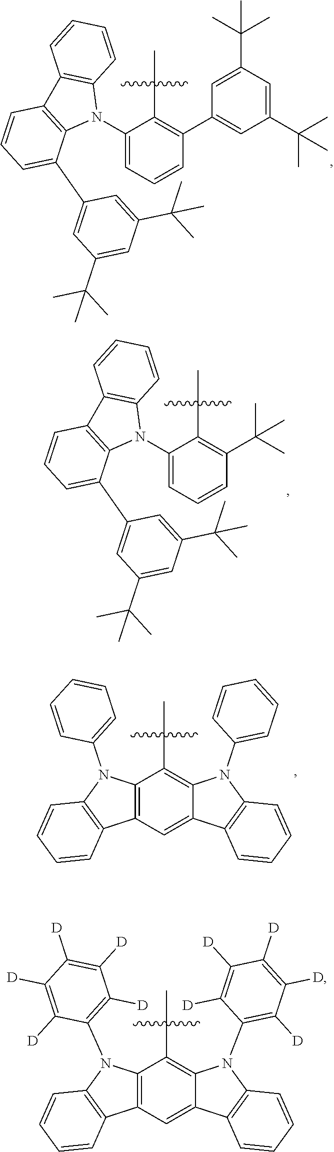

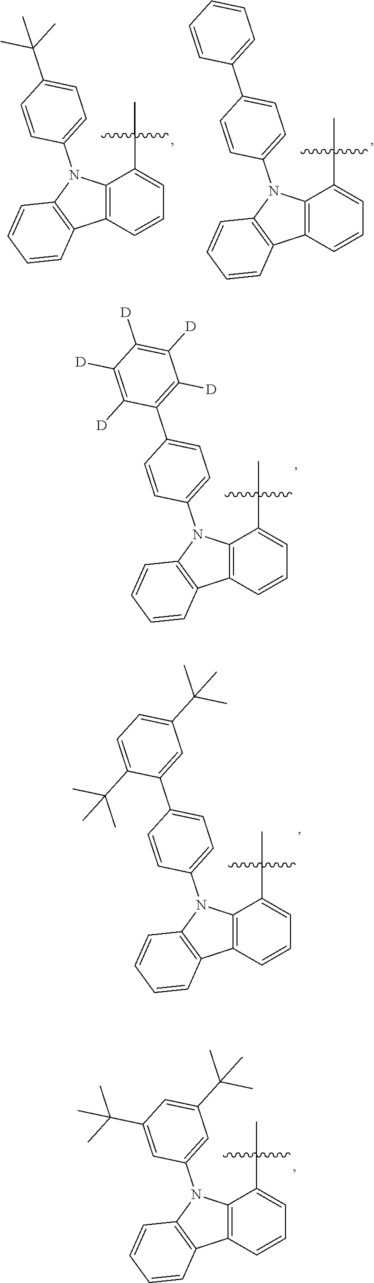

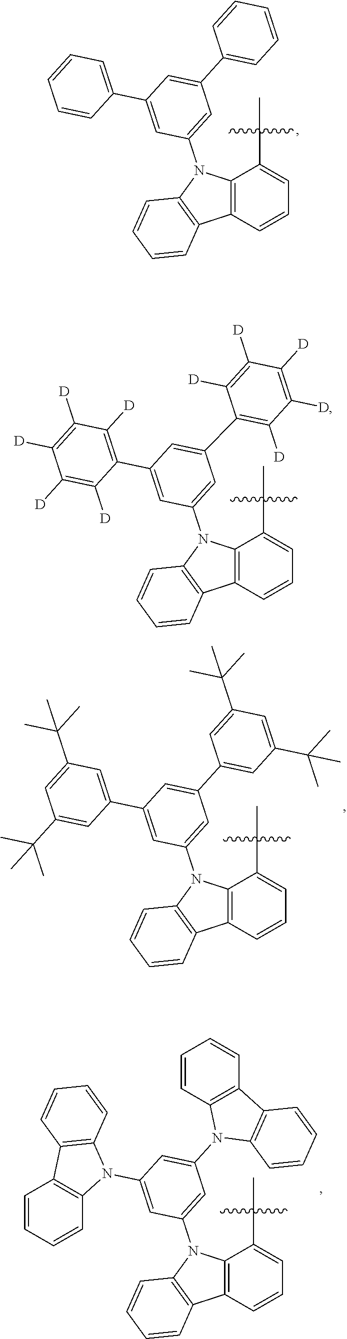

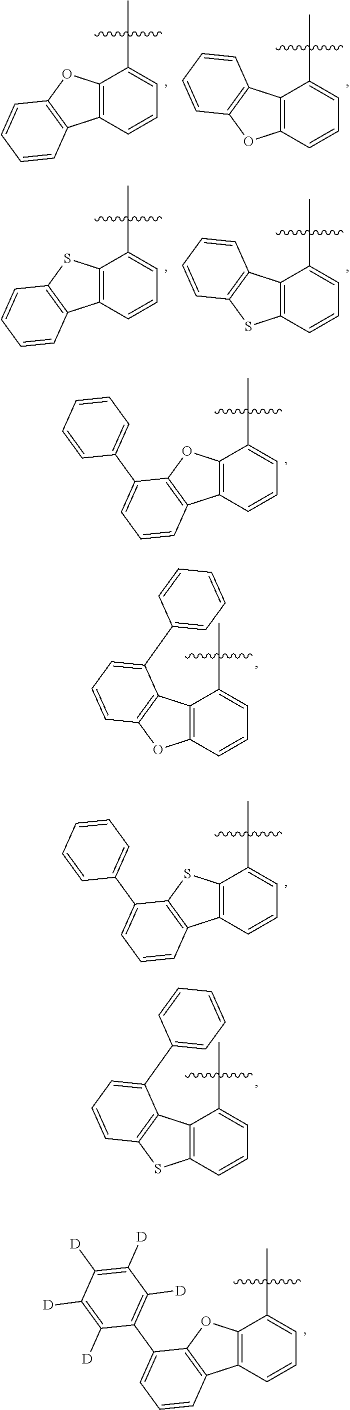

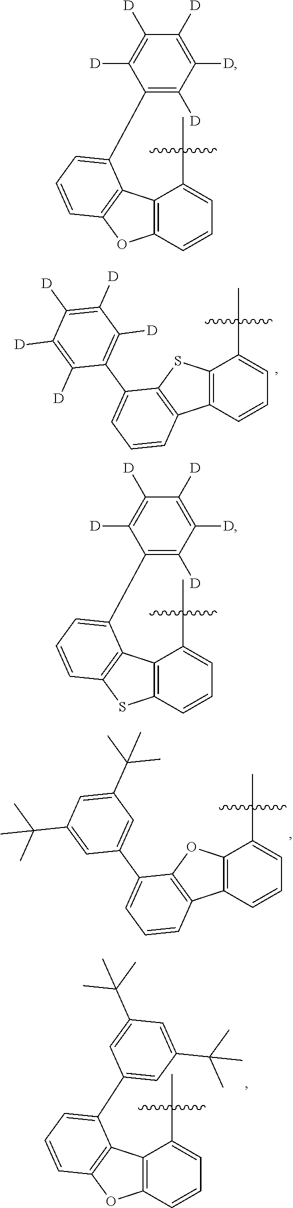

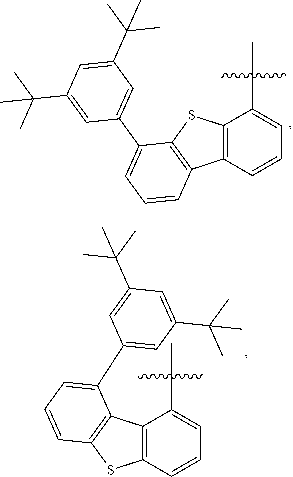

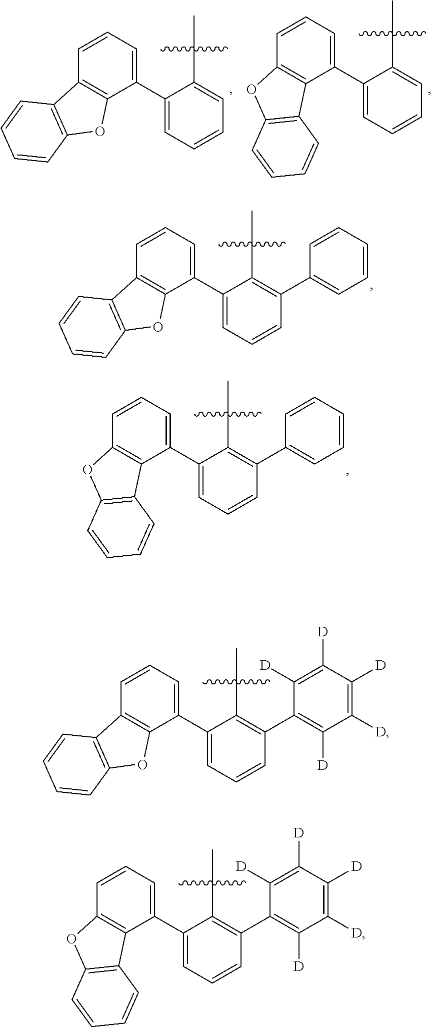

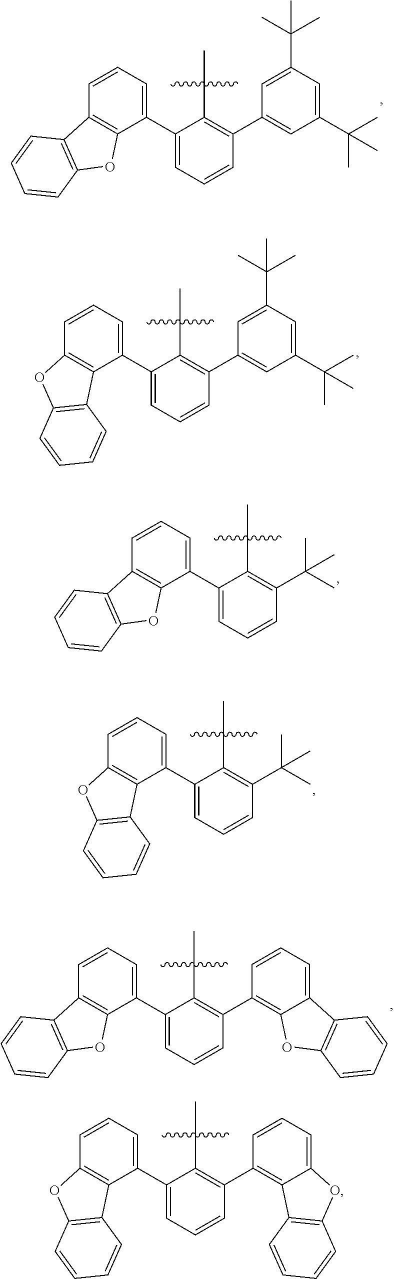 [SMILES: *c1c(-c2cc(C(C)(C)C)cc(C(C)(C)C)c2)cccc1-c1cccc2c1oc1ccccc12 ; *c1c(-c2cc(C(C)(C)C)cc(C(C)(C)C)c2)cccc1-c1cccc2oc3ccccc3c12 ; *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12]

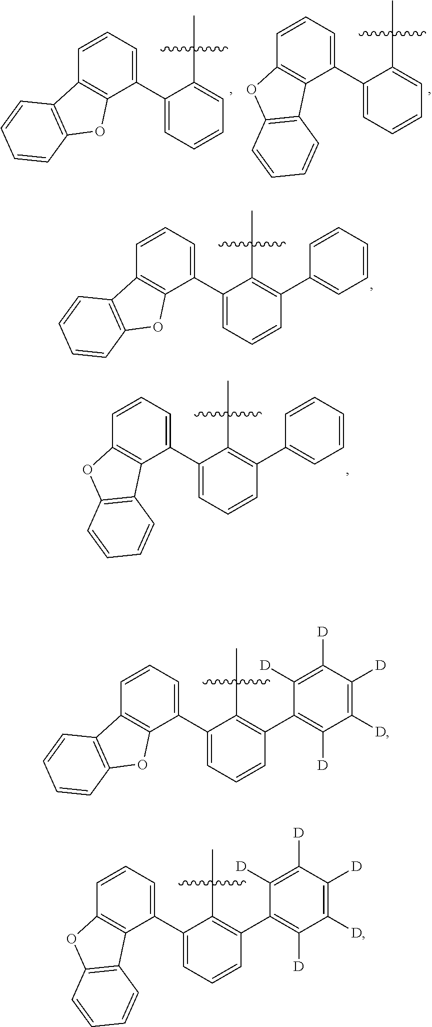

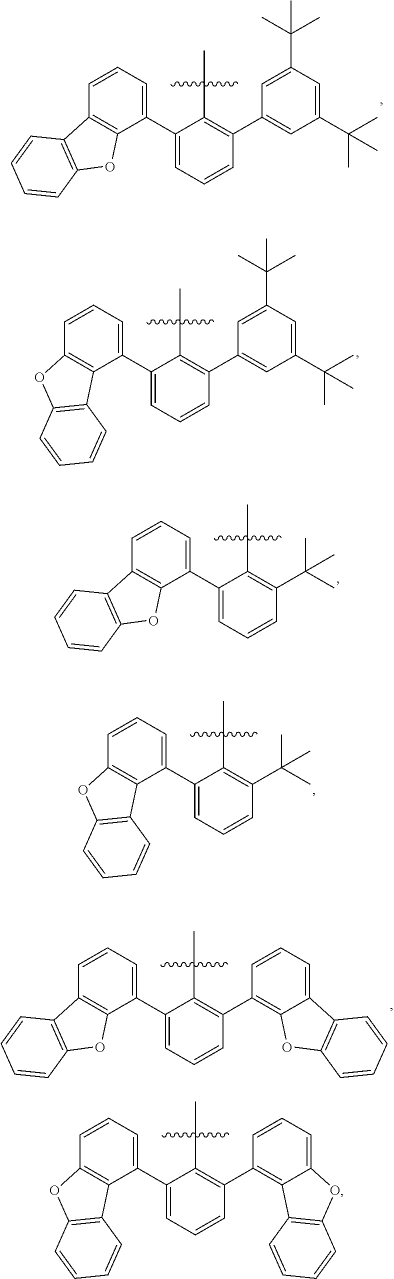 [SMILES: *c1c(-c2cc(C(C)(C)C)cc(C(C)(C)C)c2)cccc1-c1cccc2c1oc1ccccc12 ; *c1c(-c2cc(C(C)(C)C)cc(C(C)(C)C)c2)cccc1-c1cccc2oc3ccccc3c12 ; *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12]

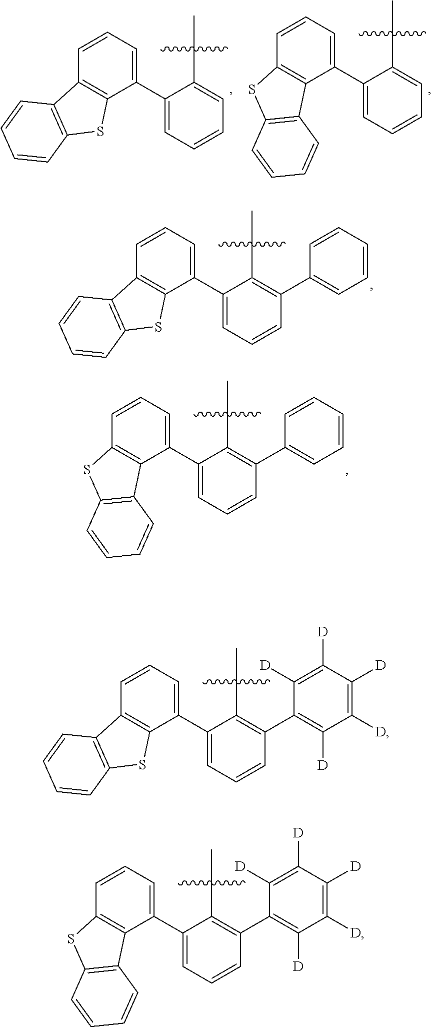

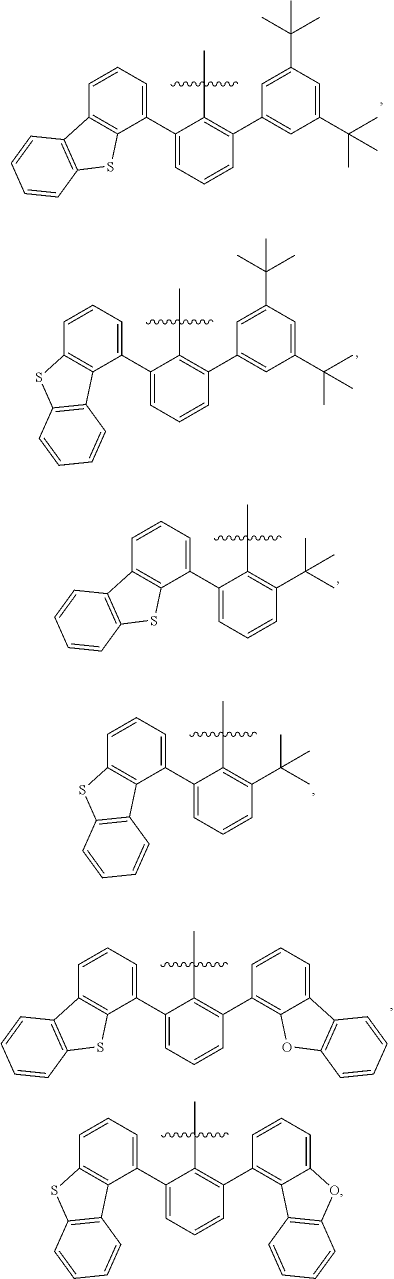 [SMILES: *c1c(-c2cc(C(C)(C)C)cc(C(C)(C)C)c2)cccc1-c1cccc2c1sc1ccccc12 ; *c1c(-c2cc(C(C)(C)C)cc(C(C)(C)C)c2)cccc1-c1cccc2sc3ccccc3c12 ; *c1c(-c2cccc3c2sc2ccccc23)cccc1C(C)(C)C ; *c1c(-c2cccc3sc4ccccc4c23)cccc1C(C)(C)C ; *c1c(-c2cccc3c2oc2ccccc23)cccc1-c1cccc2c1sc1ccccc12 ; *c1c(-c2cccc3oc4ccccc4c23)cccc1-c1cccc2sc3ccccc3c12]

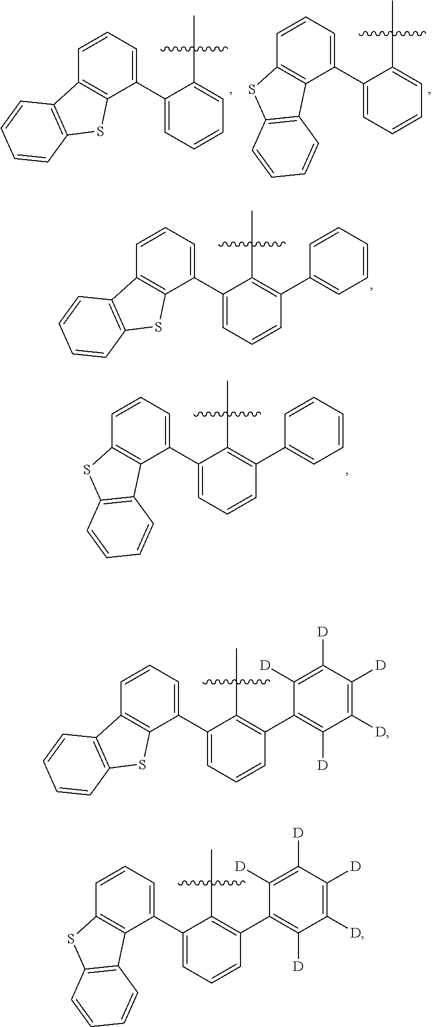

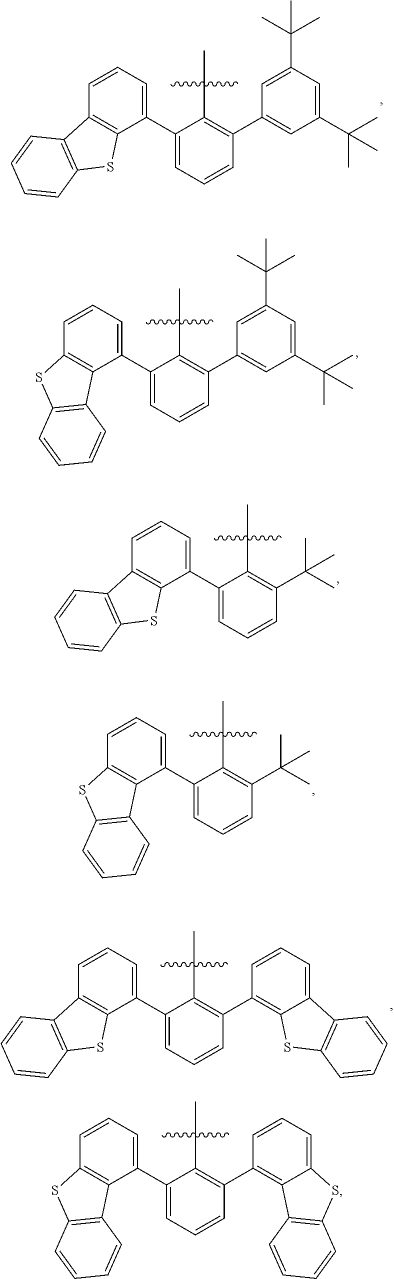 [SMILES: *c1c(-c2cc(C(C)(C)C)cc(C(C)(C)C)c2)cccc1-c1cccc2c1sc1ccccc12 ; *c1c(-c2cc(C(C)(C)C)cc(C(C)(C)C)c2)cccc1-c1cccc2sc3ccccc3c12 ; *c1c(-c2cccc3c2sc2ccccc23)cccc1C(C)(C)C ; *c1c(-c2cccc3sc4ccccc4c23)cccc1C(C)(C)C ; *c1c(-c2cccc3c2sc2ccccc23)cccc1-c1cccc2c1sc1ccccc12 ; *c1c(-c2cccc3sc4ccccc4c23)cccc1-c1cccc2sc3ccccc3c12]

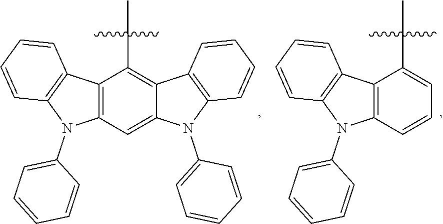

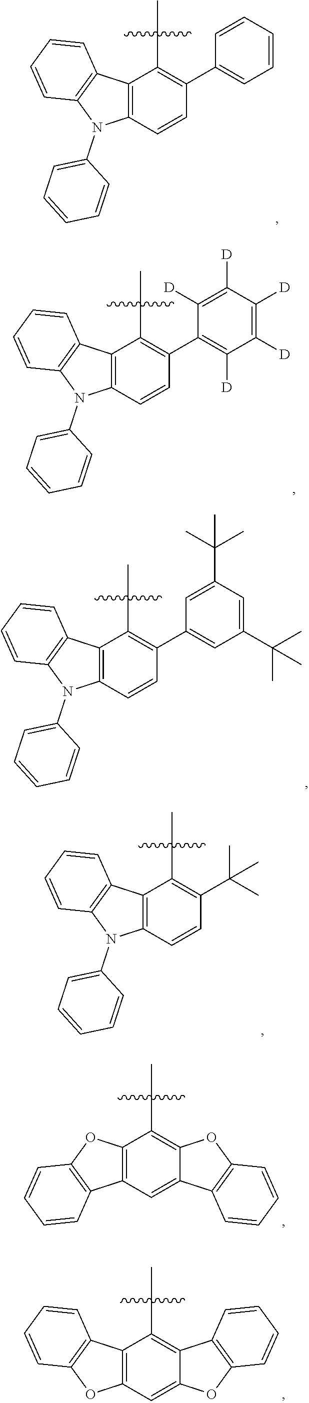 [SMILES: *c1c(-c2ccccc2)ccc2c1c1ccccc1n2-c1ccccc1 ; *c1c(-c2c([2H])c([2H])c([2H])c([2H])c2[2H])ccc2c1c1ccccc1n2-c1ccccc1 ; *c1c(-c2cc(C(C)(C)C)cc(C(C)(C)C)c2)ccc2c1c1ccccc1n2-c1ccccc1 ; *c1c(C(C)(C)C)ccc2c1c1ccccc1n2-c1ccccc1 ; *c1c2oc3ccccc3c2cc2c1oc1ccccc12 ; *c1c2c(cc3oc4ccccc4c13)oc1ccccc12]

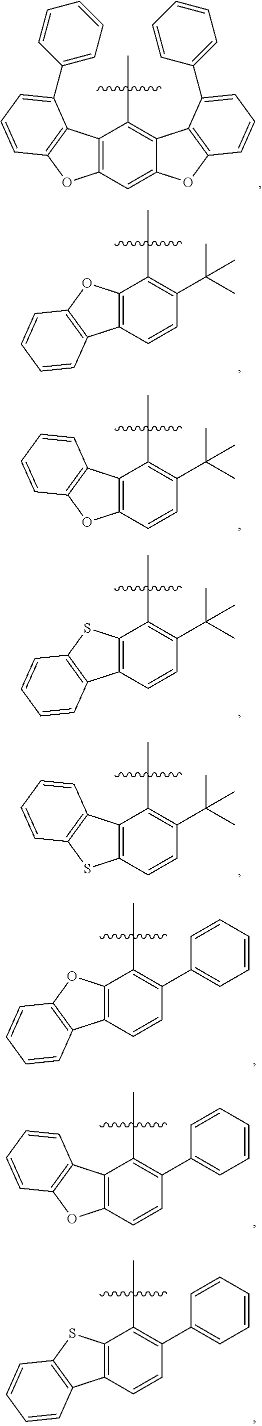

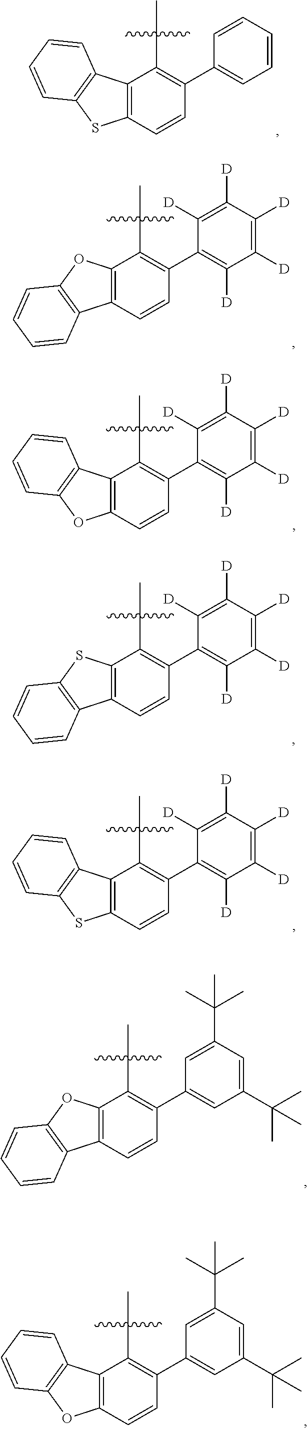

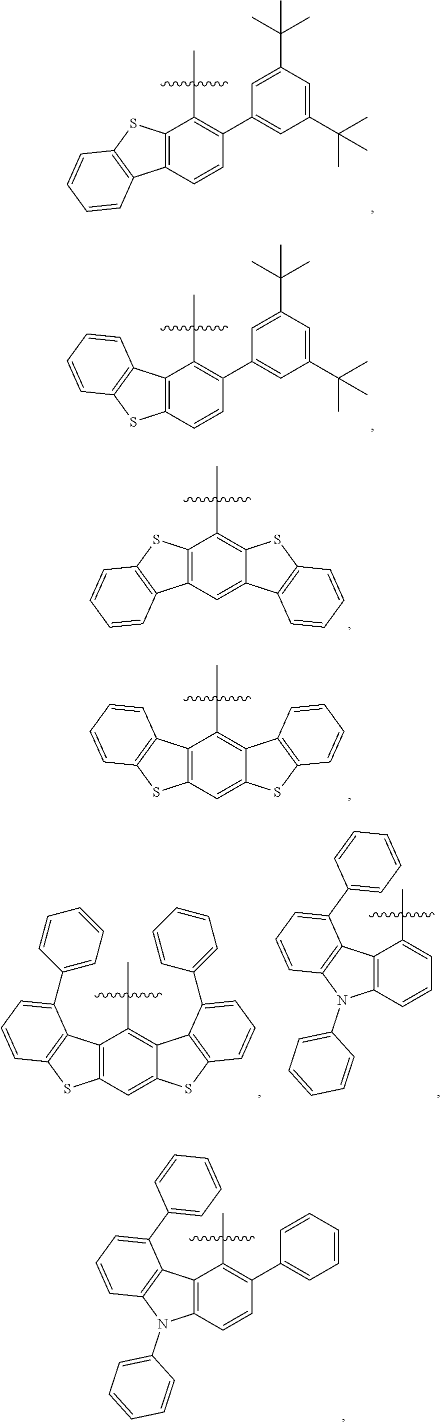

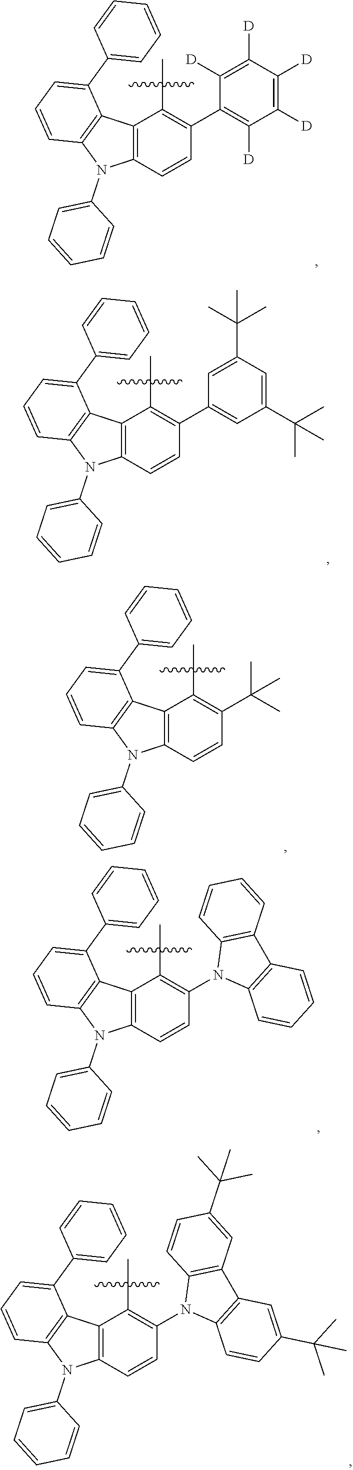

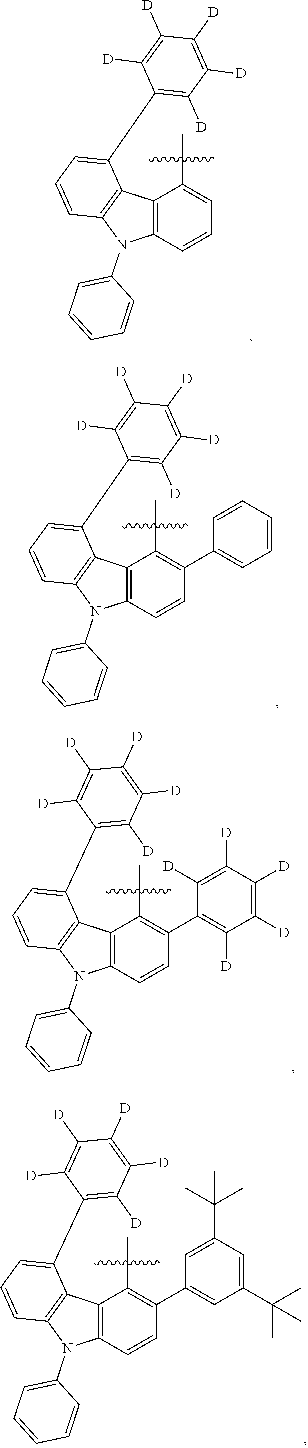

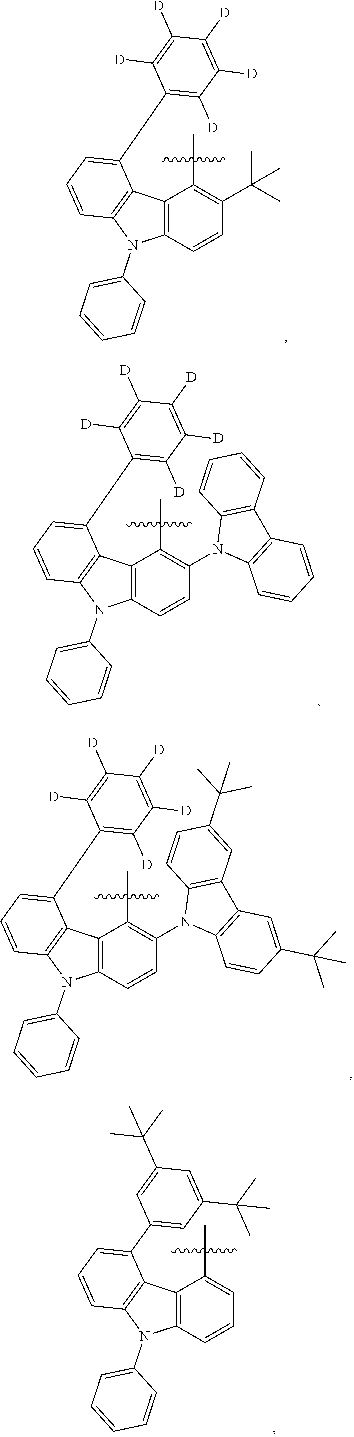

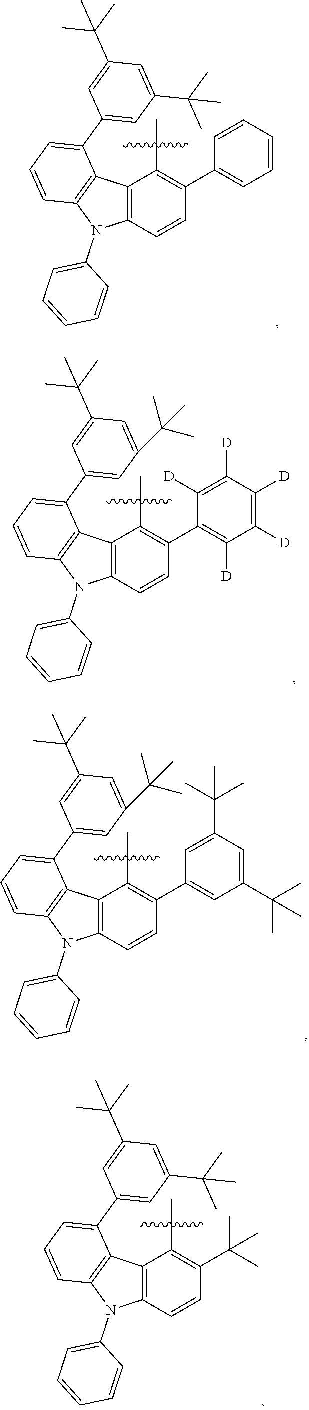

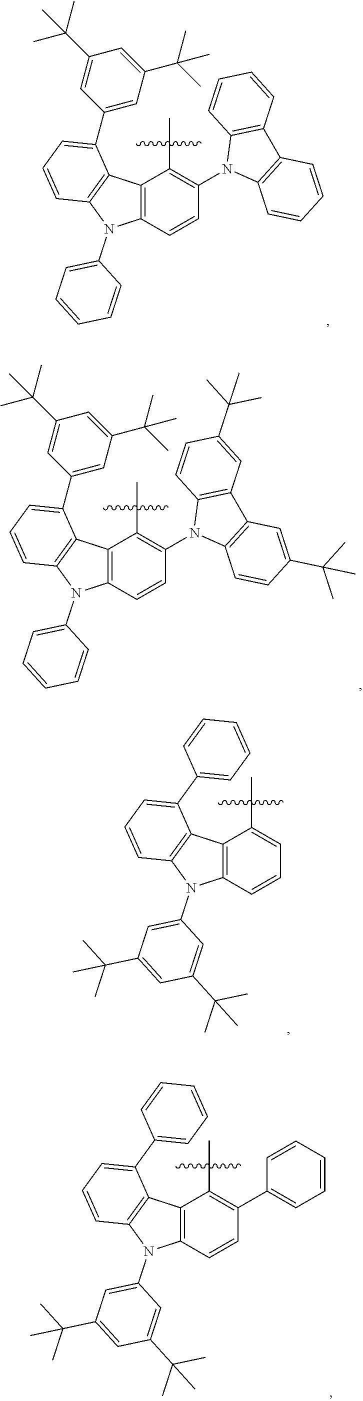

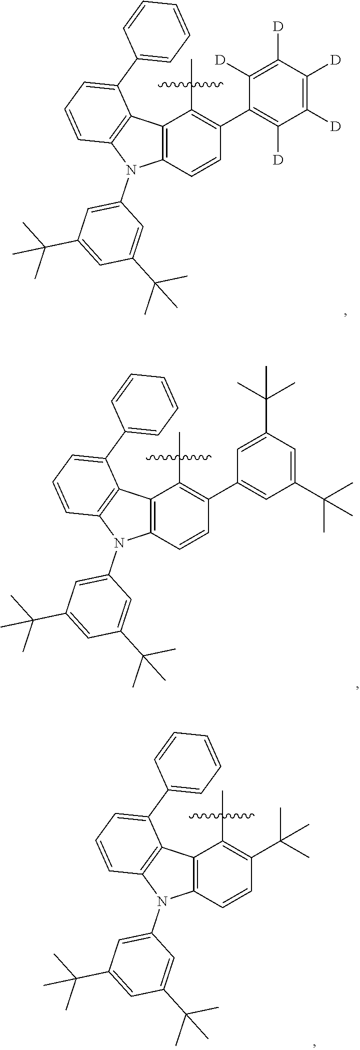

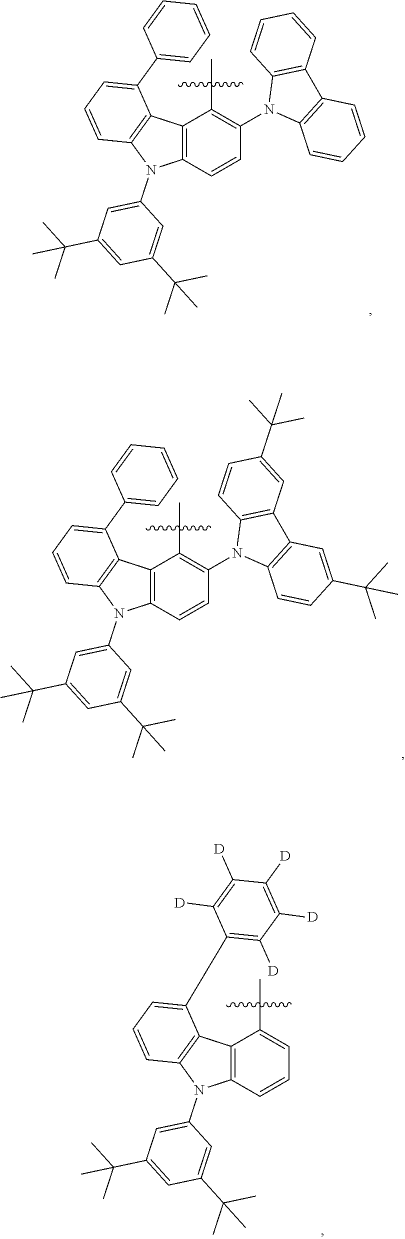

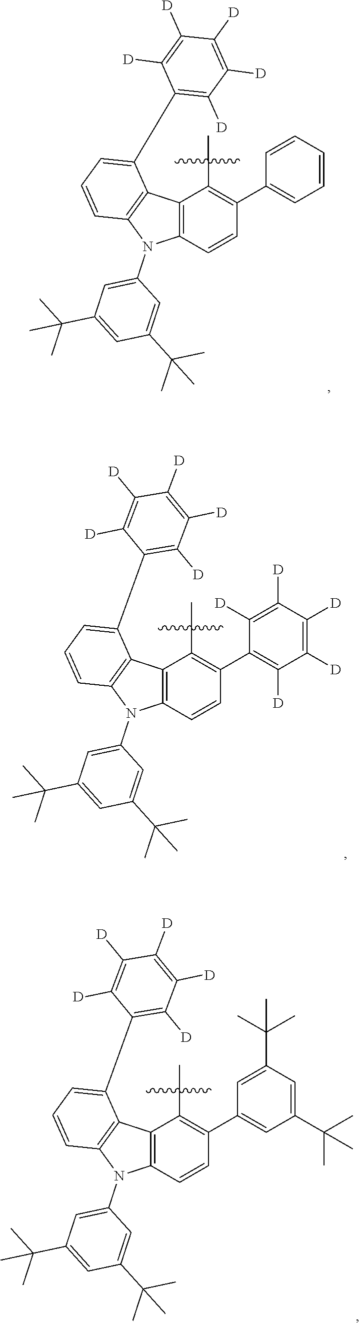 [SMILES: *c1c(-c2ccccc2)ccc2c1c1c(-c3c([2H])c([2H])c([2H])c([2H])c3[2H])cccc1n2-c1cc(C(C)(C)C)cc(C(C)(C)C)c1 ; *c1c(-c2c([2H])c([2H])c([2H])c([2H])c2[2H])ccc2c1c1c(-c3c([2H])c([2H])c([2H])c([2H])c3[2H])cccc1n2-c1cc(C(C)(C)C)cc(C(C)(C)C)c1 ; *c1c(-c2cc(C(C)(C)C)cc(C(C)(C)C)c2)ccc2c1c1c(-c3c([2H])c([2H])c([2H])c([2H])c3[2H])cccc1n2-c1cc(C(C)(C)C)cc(C(C)(C)C)c1]

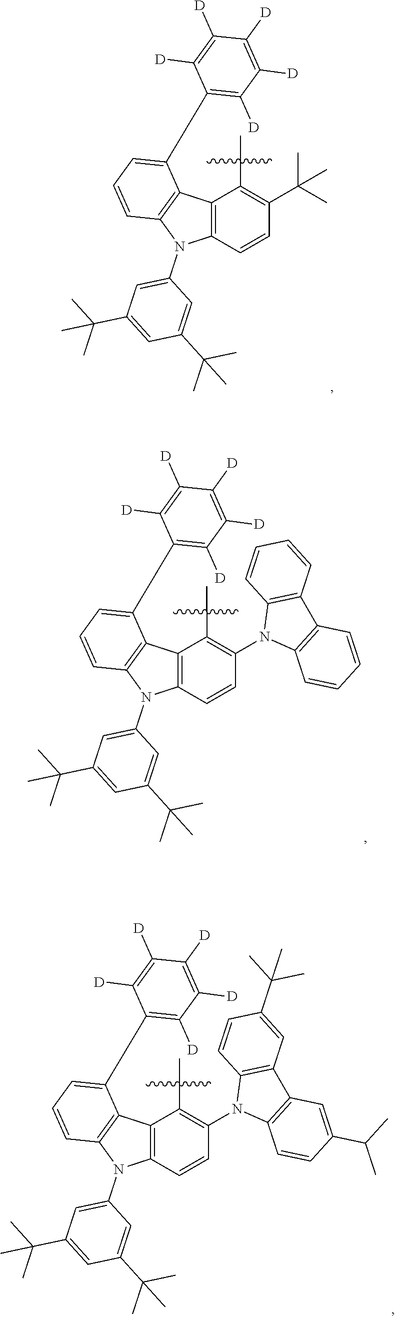

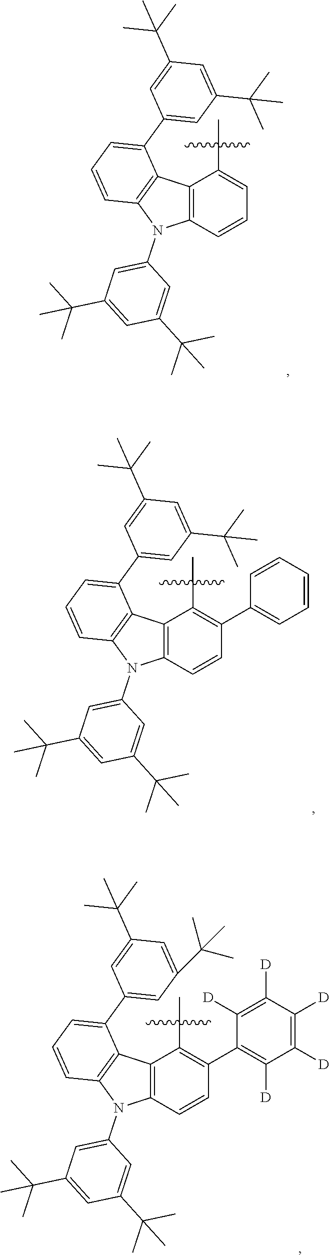

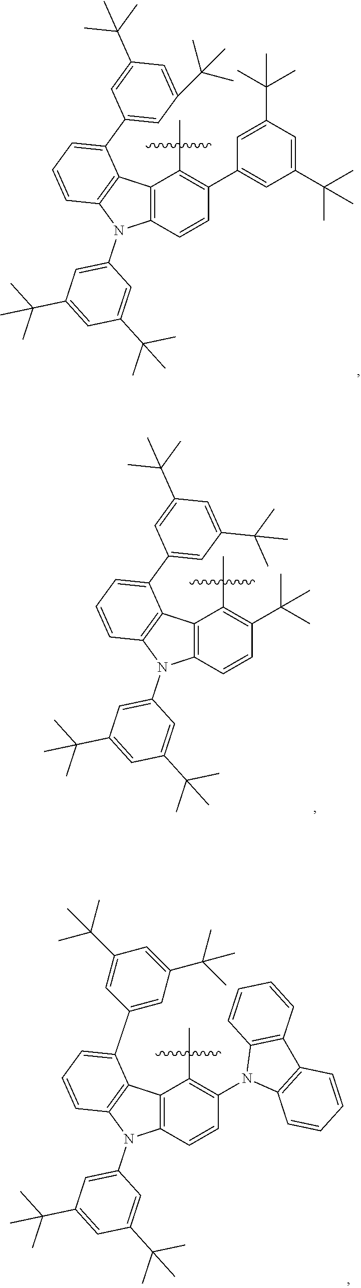

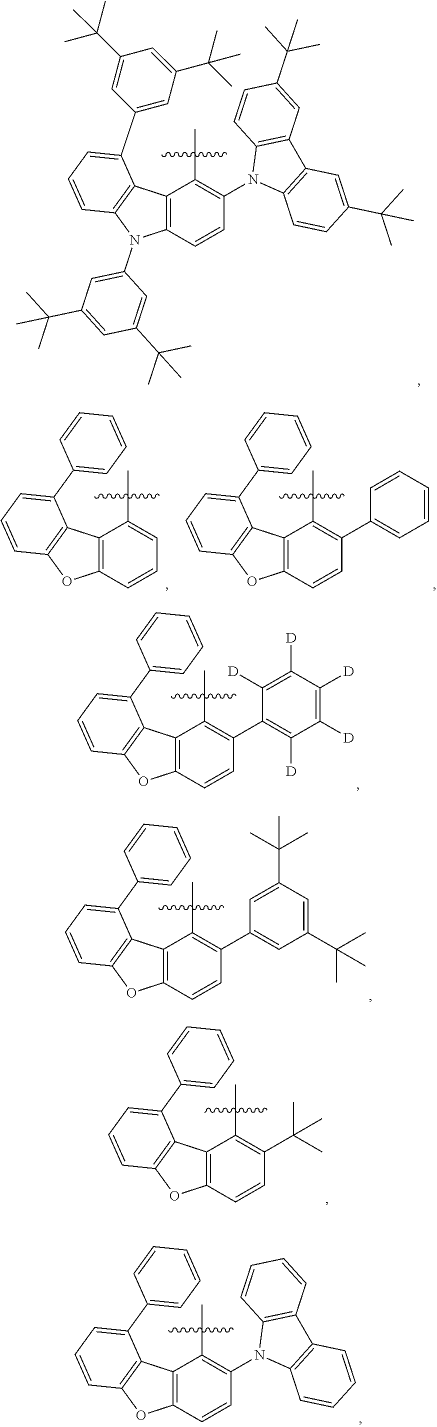

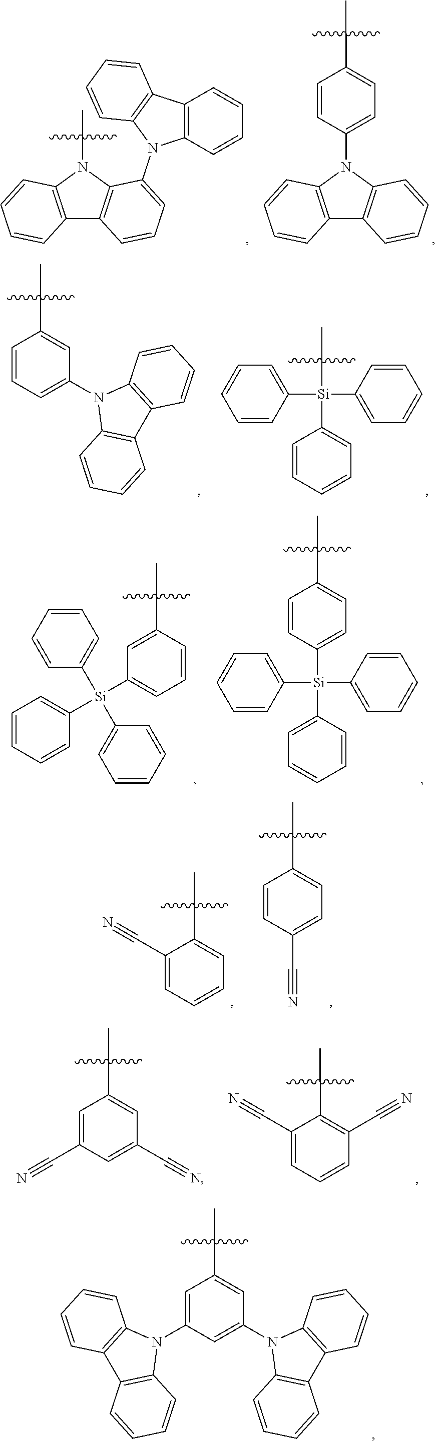

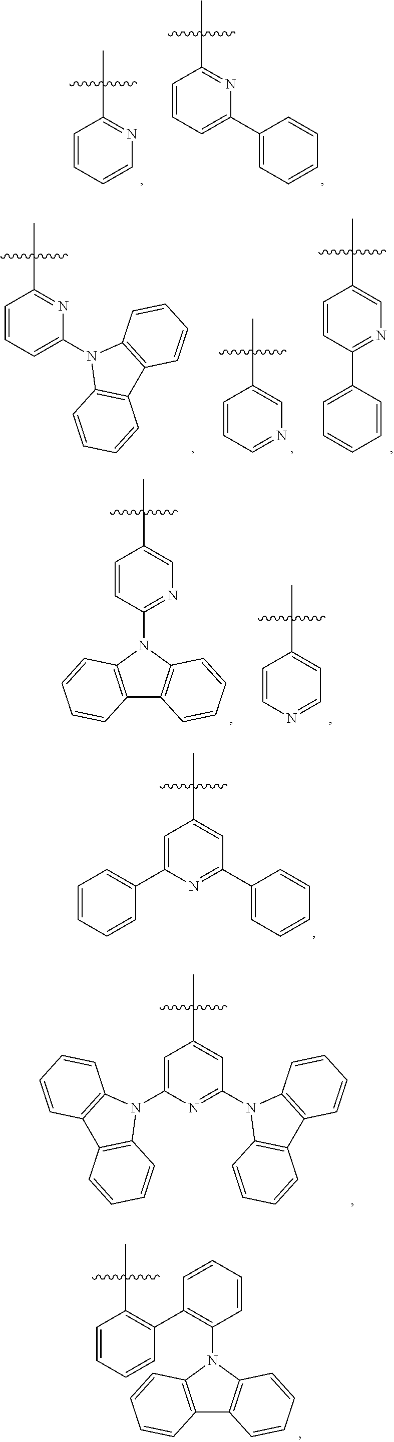

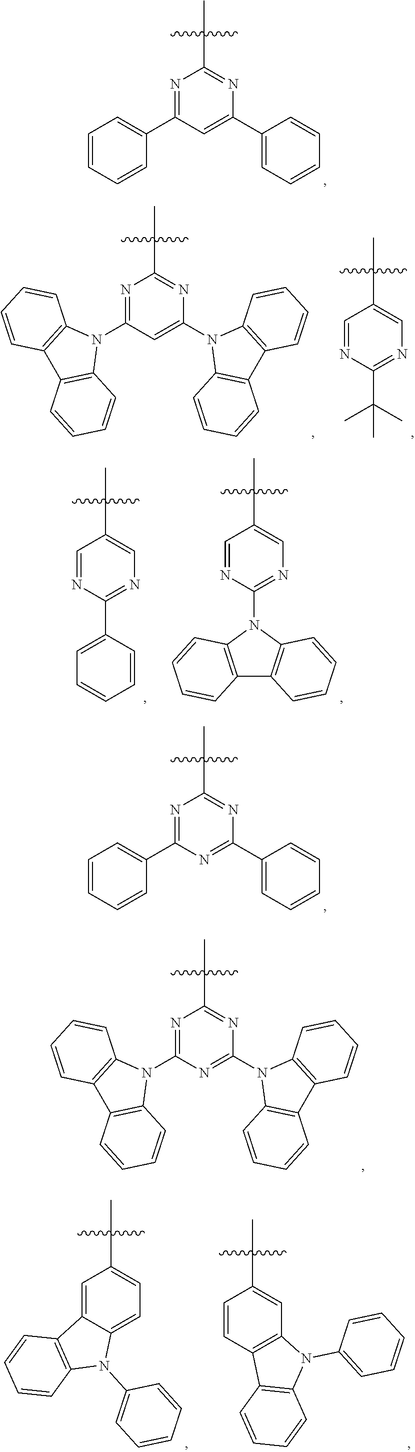

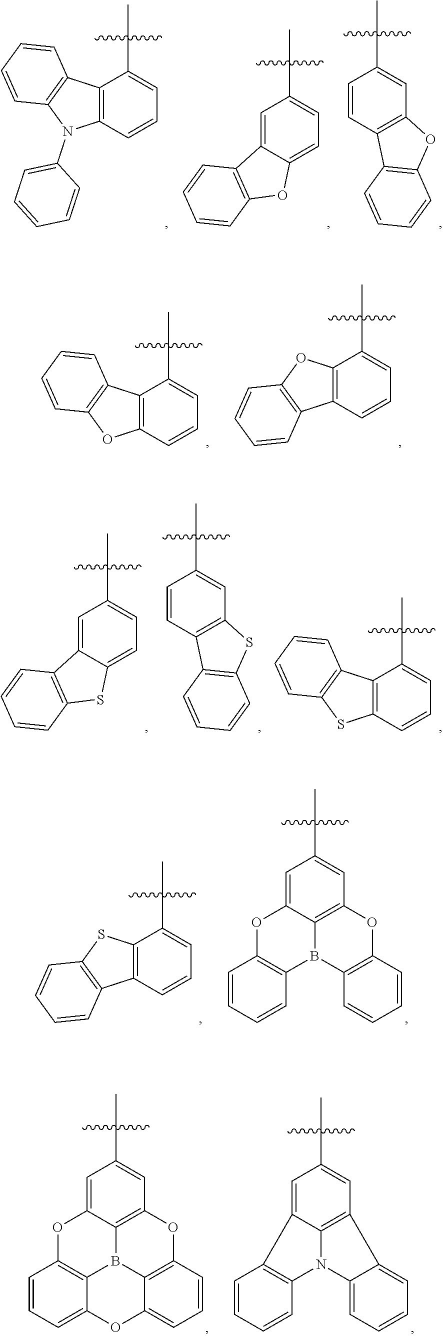

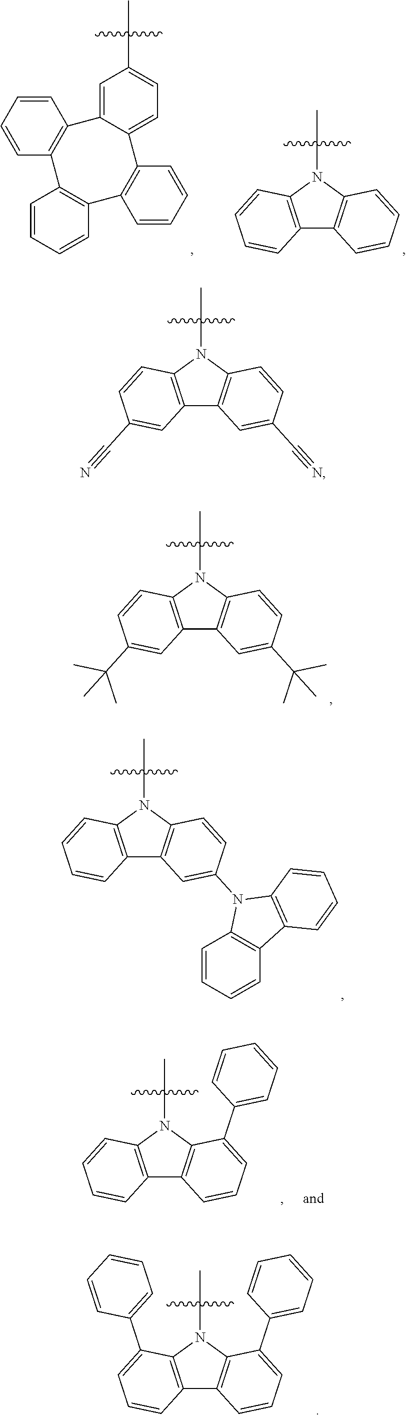

In some embodiments, each R^{B} is selected from the group consisting of the structures of LIST 5, LIST 6, and LIST 7 defined herein. In some embodiments, at least one R^{B} comprises a cyclic group selected from the group consisting of W1 to W16 (LIST 6 defined herein) or an electron-withdrawing group selected from the group consisting of E1 to E125 (LIST 5 defined herein).

In some embodiments, the compound can be selected from the group consisting of the compounds having the formula of Pt(L_{A′})(Ly):

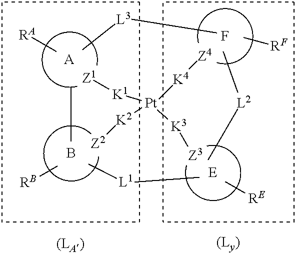

wherein ligand L_{A′} is selected from the group consistng of L_{A′}-(Rs)(Rt)(Vv), wherein i is an integer from 1 to 48, and s and t are each independently an integer from 1 to 70, and v is an integer from 1 to 44; wherein L_{A′1}-(R1)(R1)(V1) to L_{A48}-(R70)(R70)(V44) are defined by the structures in the following LIST 16:

| L_{A}′ | Structure of L_{A}′ |
|---|---|
| L_{A}′1-(Rs)(Rf)(Vv), wherein L_{A}′1-(R1)(R1)(V1) to L_{A}′1- (R70)(R70)(V44), having the structure | 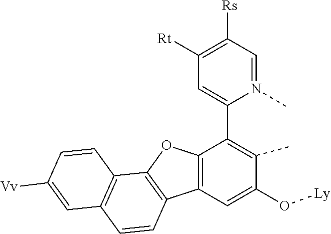 |
| L_{A}′2-(Rs)(Rt)(Vv), wherein L_{A}′2-(R1)(R1)(V1) to L_{A}′2- (R70)(R70)(V44), having the structure | 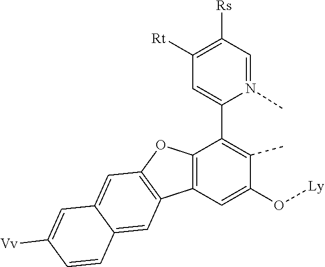 |
| L_{A}′3-(Rs)(Rf)(Vv), wherein L_{A}′3-(R1)(R1)(V1) to L_{A}′3- (R70)(R70)(V44), having the structure | 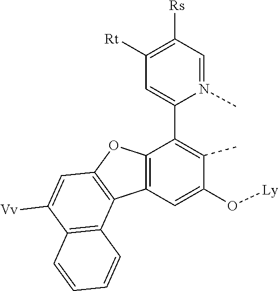 |
| L_{A}′4-(Rs)(Rf)(Vv), wherein L_{A}′4-(R1)(R1)(V1) to L_{A}′4- (R70)(R70)(V44), having the structure | 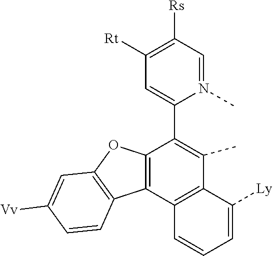 |
| L_{A}′5-(Rs)(Rf)(Vv), wherein L_{A}′5-(R1)(R1)(V1) to L_{A}′5- (R70)(R70)(V44), having the structure | 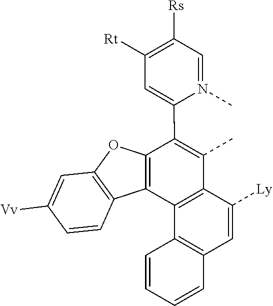 |
| L_{A}′6-(Rs)(Rf)(Vv), wherein L_{A}′6-(R1)(R1)(V1) to L_{A}′6- (R70)(R70)(V44), having the structure | 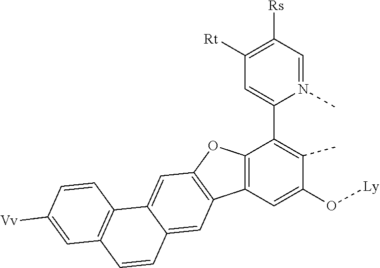 |
| L_{A}′7-(Rs)(Rf)(Vv), wherein L_{A}′7-(R1)(R1)(V1) to L_{A}′7- (R70)(R70)(V44), having the structure | 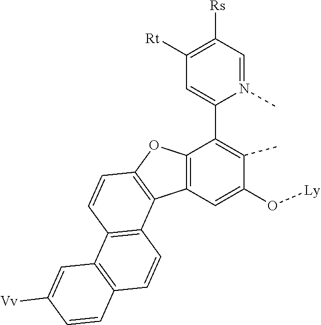 |
| L_{A}′8-(Rs)(Rf)(Vv), wherein L_{A}′8-(R1)(R1)(V1) to L_{A}′8- (R70)(R70)(V44), having the structure | 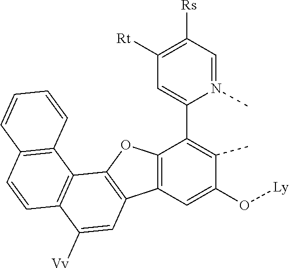 |
| L_{A}′9-(Rs)(Rf)(Vv), wherein L_{A}′9-(R1)(R1)(V1) to L_{A}′9- (R70)(R70)(V44), having the structure | 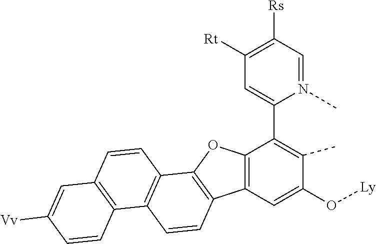 |
| L_{A}′10-(Rs)(Rf)(Vv), wherein L_{A}′10-(R1)(R1)(V1) to L_{A}′10- (R70)(R70)(V44), having the structure | 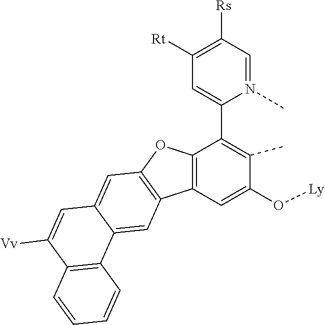 |
| L_{A}′11-(Rs)(Rf)(Vv), wherein L_{A}′11-(R1)(R1)(V1) to L_{A}′11- (R70)(R70)(V44), having the structure | 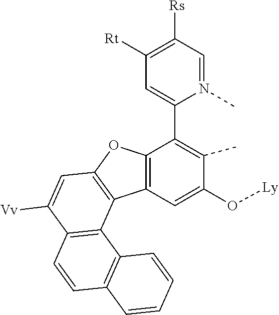 |
| L_{A}′12-(Rs)(Rf)(Vv), wherein L_{A}′12-(R1)(R1)(V1) to L_{A}′12- (R70)(R70)(V44), having the structure | 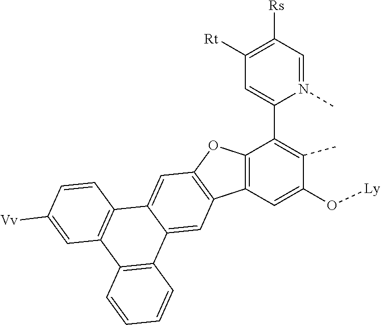 |
| L_{A}′13-(Rs)(Rf)(Vv), wherein L_{A}′13-(R1)(R1)(V1) to L_{A}′13- (R70)(R70)(V44), having the structure | 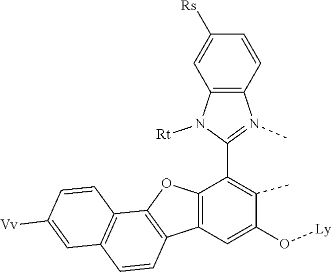 |
| L_{A}′14-(Rs)(Rf)(Vv), wherein L_{A}′14-(R1)(R1)(V1) to L_{A}′14- (R70)(R70)(V44), having the structure | 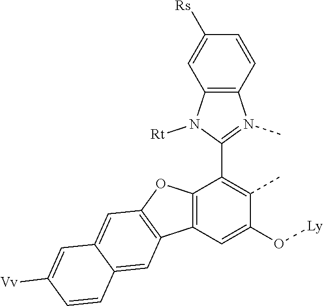 |
| L_{A}′15-(Rs)(Rf)(Vv), wherein L_{A}′15-(R1)(R1)(V1) to L_{A}′15- (R70)(R70)(V44), having the structure | 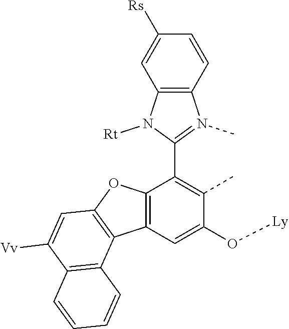 |
| L_{A}′16-(Rs)(Rf)(Vv), wherein L_{A}′16-(R1)(R1)(V1) to L_{A}′16- (R70)(R70)(V44), having the structure | 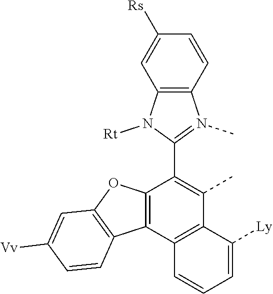 |
| L_{A}′17-(Rs)(Rt)(Vv), wherein L_{A}′17-(R1)(R1)(V1) to L_{A}′17- (R70)(R70)(V44), having the structure | 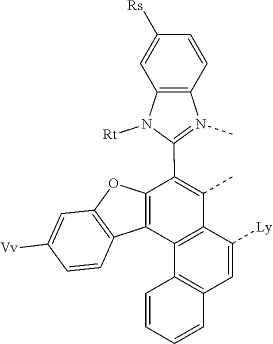 |
| L_{A}′18-(Rs)(Rf)(Vv), wherein L_{A}′18-(R1)(R1)(V1) to L_{A}′18- (R70)(R70)(V44), having the structure | 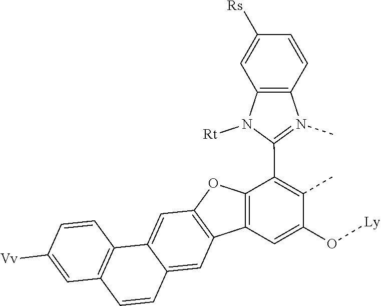 |
| L_{A}′19-(Rs)(Rf)(Vv), wherein L_{A}′19-(R1)(R1)(V1) to L_{A}′19- (R70)(R70)(V44), having the structure | 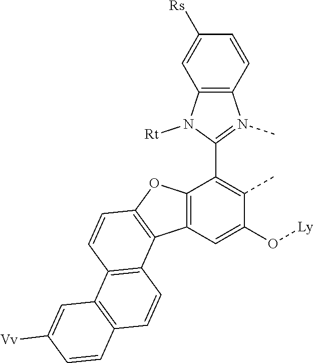 |
| L_{A}′20-(Rs)(Rf)(Vv), wherein L_{A}′20-(R1)(R1)(V1) to L_{A}′20- (R70)(R70)(V44), having the structure | 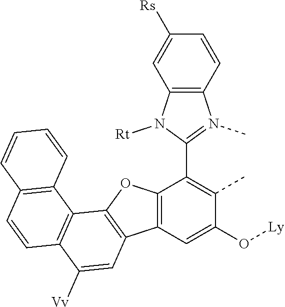 |
| L_{A}′21-(Rs)(Rf)(Vv), wherein L_{A}′21-(R1)(R1)(V1) to L_{A}′21- (R70)(R70)(V44), having the structure | 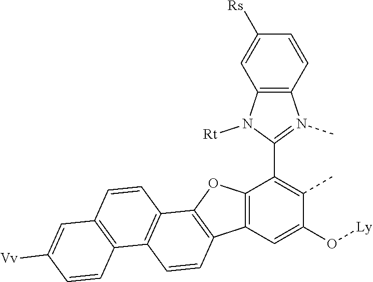 |
| L_{A}′22-(Rs)(Rf)(Vv), wherein L_{A}′22-(R1)(R1)(V1) to L_{A}′22- (R70)(R70)(V44), having the structure | 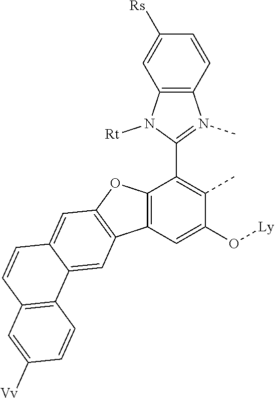 |
| L_{A}′23-(Rs)(Rf)(Vv), wherein L_{A}′23-(R1)(R1)(V1) to L_{A}′23- (R70)(R70)(V44), having the structure | 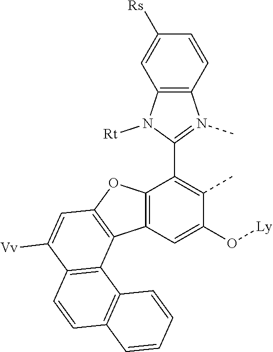 |
| L_{A}′24-(Rs)(Rf)(Vv), wherein L_{A}′24-(R1)(R1)(V1) to L_{A}′24- (R70)(R70)(V44), having the structure | 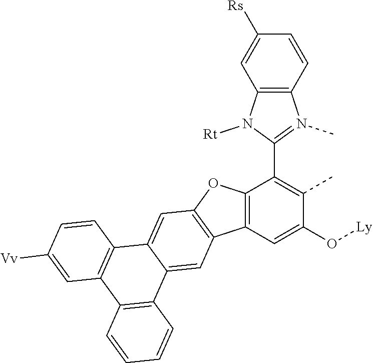 |
| L_{A}′25-(Rs)(Rf)(Vv), wherein L_{A}′25-(R1)(R1)(V1) to L_{A}′25- (R70)(R70)(V44), having the structure | 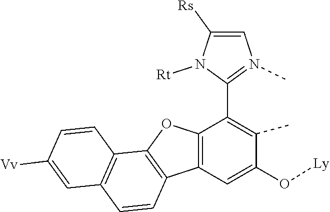 |
| L_{A}′26-(Rs)(Rf)(Vv), wherein L_{A}′26-(R1)(R1)(V1) to L_{A}′26- (R70)(R70)(V44), having the structure | 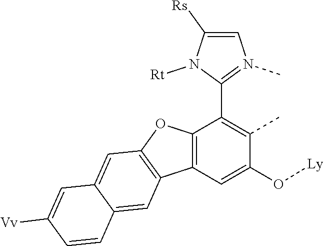 |
| L_{A}′27-(Rs)(Rf)(Vv), wherein L_{A}′27-(R1)(R1)(V1) to L_{A}′27- (R70)(R70)(V44), having the structure | 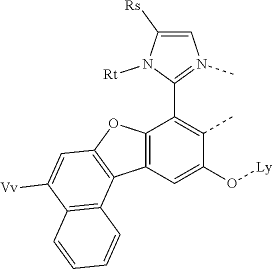 |
| L_{A}′28-(Rs)(Rt)(Vv), wherein L_{A}′28-(R1)(R1)(V1) to L_{A}′28- (R70)(R70)(V44), having the structure | 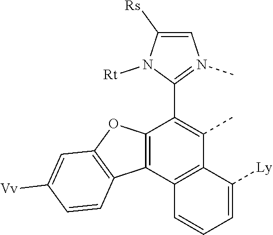 |
| L_{A}′29-(Rs)(Rf)(Vv), wherein L_{A}′29-(R1)(R1)(V1) to L_{A}′29- (R70)(R70)(V44), having the structure | 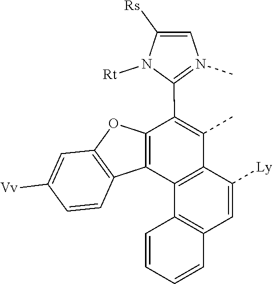 |
| L_{A}′30-(Rs)(Rf)(Vv), wherein L_{A}′30-(R1)(R1)(V1) to L_{A}′30- (R70)(R70)(V44), having the structure | 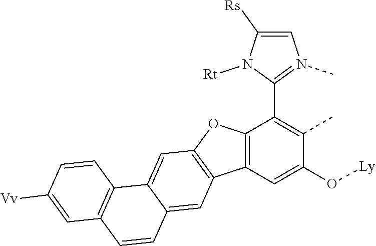 |
| L_{A}′31-(Rs)(Rt)(Vv), wherein L_{A}′31-(R1)(R1)(V1) to L_{A}′31- (R70)(R70)(V44), having the structure | 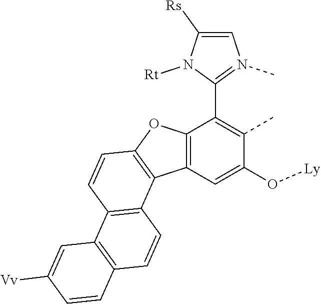 |
| L_{A}′32-(Rs)(Rf)(Vv), wherein L_{A}′32-(R1)(R1)(V1) to L_{A}′32- (R70)(R70)(V44), having the structure | 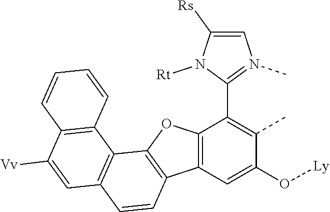 |
| L_{A}′33-(Rs)(Rf)(Vv), wherein L_{A}′33-(R1)(R1)(V1) to L_{A}′33- (R70)(R70)(V44), having the structure | 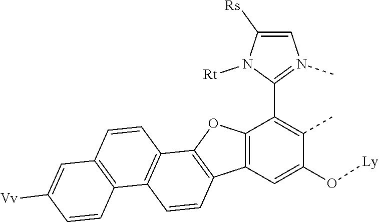 |
| L_{A}′34-(Rs)(Rf)(Vv), wherein L_{A}′34-(R1)(R1)(V1) to L_{A}′34- (R70)(R70)(V44), having the structure | 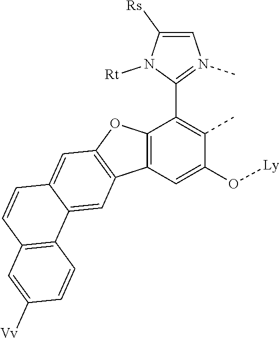 |
| L_{A}′35-(Rs)(R)(Vv), wherein L_{A}′35-(R1)(R1)(V1) to L_{A}′35- (R70)(R70)(V44), having the structure | 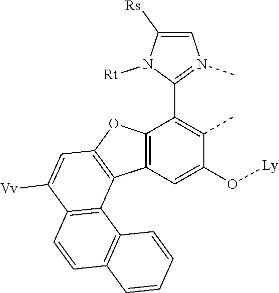 |
| L_{A}′36-(Rs)(Rf)(Vv), wherein L_{A}′36-(R1)(R1)(V1) to L_{A}′36- (R70)(R70)(V44), having the structure | 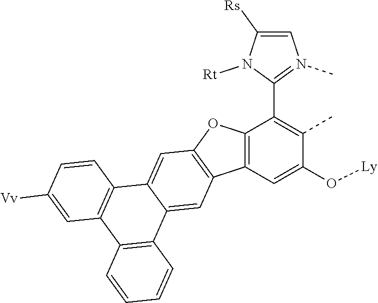 |
| L_{A}′37-(Rs)(Rt)(Vv), wherein L_{A}′37-(R1)(R1)(V1) to L_{A}′37- (R70)(R70)(V44), having the structure | 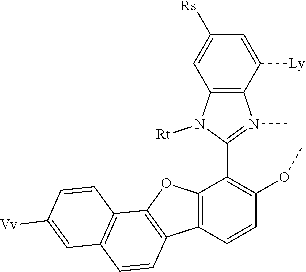 |
| L_{A}′38-(Rs)(Rf)(Vv), wherein L_{A}′38-(R1)(R1)(V1) to L_{A}′38- (R70)(R70)(V44), having the structure | 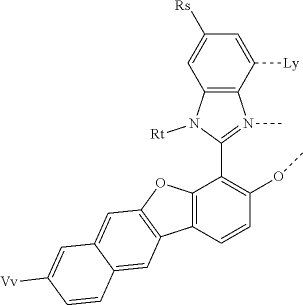 |
| L_{A}′39-(Rs)(Rf)(Vv), wherein L_{A}′39-(R1)(R1)(V1) to L_{A}′39- (R70)(R70)(V44), having the structure | 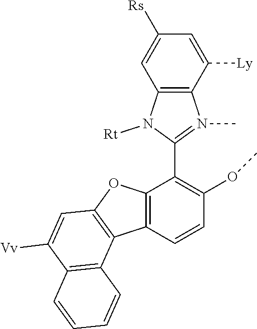 |
| L_{A}′40-(Rs)(Rf)(Vv), wherein L_{A}′40-(R1)(R1)(V1) to L_{A}′40- (R70)(R70)(V44), having the structure | 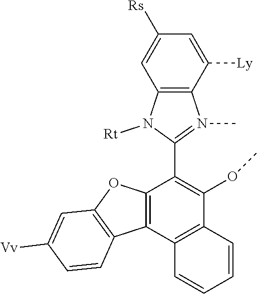 |
| L_{A}′41-(Rs)(Rf)(Vv), wherein L_{A}′41-(R1)(R1)(V1) to L_{A}′41- (R70)(R70)(V44), having the structure | 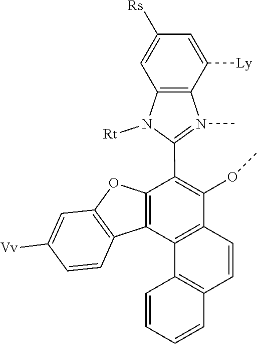 |
| L_{A}′42-(Rs)(Rf)(Vv), wherein L_{A}′42-(R1)(R1)(V1) to L_{A}′42- (R70)(R70)(V44), having the structure | 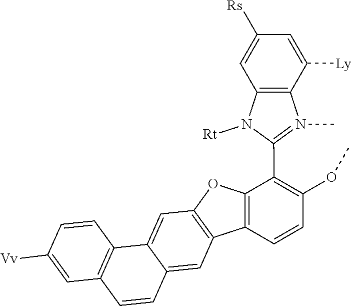 |
| L_{A}′43-(Rs)(Rf)(Vv), wherein L_{A}′43-(R1)(R1)(V1) to L_{A}′43- (R70)(R70)(V44), having the structure | 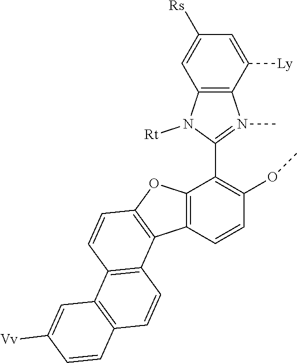 |
| L_{A}′44-(Rs)(Rf)(Vv), wherein L_{A}′44-(R1)(R1)(V1) to L_{A}′44- (R70)(R70)(V44), having the structure | 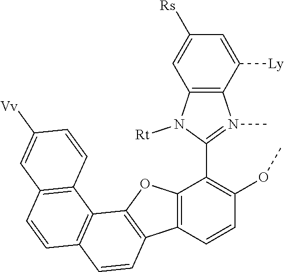 |
| L_{A}′45-(Rs)(Rf)(Vv), wherein L_{A}′45-(R1)(R1)(V1) to L_{A}′45- (R70)(R70)(V44), having the structure | 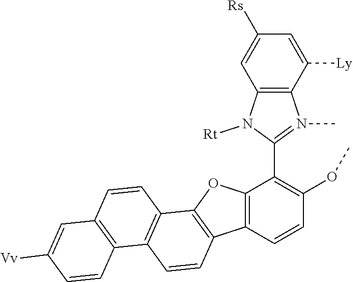 |
| L_{A}′46-(Rs)(Rt)(Vv), wherein L_{A}′46-(R1)(R1)(V1) to L_{A}′46- (R70)(R70)(V44), having the structure | 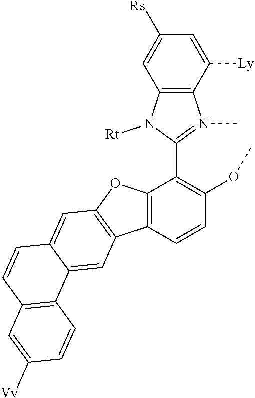 |
| L_{A}′47-(Rs)(Rf)(Vv), wherein L_{A}′47-(R1)(R1)(V1) to L_{A}′47- (R70)(R70)(V44), having the structure | 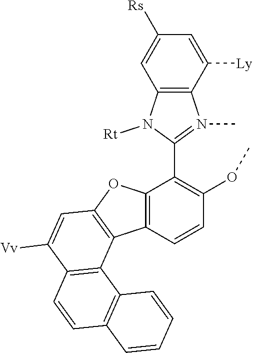 |
| L_{A}′48-(Rs)(Rf)(Vv), wherein L_{A}′48-(R1)(R1)(V1) to L_{A}′48- (R70)(R70)(V44), having the structure | 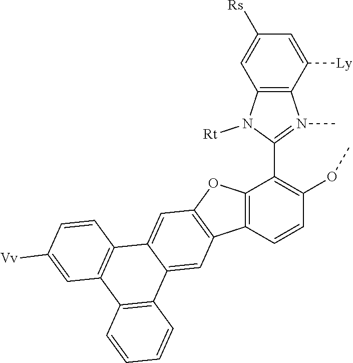 |

wherein ligand L_{y} is selected from the group consisting of L_{y}j-(Rs)(Rt)(Ru), wherein j is an integer from 1 to 62, and s, t, and u are each independently an integer from 1 to 70; wherein L_{y}1-(R1)(R1)(R1) to L_{y}62-(R70)(R70)(R70) are defined by the structures in the following LIST 17:

| L_{y} | Structure of L_{y} |
|---|---|
| L_{y}1-(R1)(R1)(R1) to L_{y}1- (R70)(R70)(R70), having the structure | 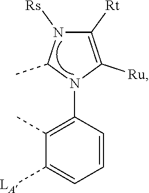 |
| Ly₂-(R1)(R1)(R1) to Ly₂- (R70)(R70)(R70), having the structure | 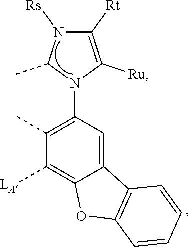 |
| L_{y}3-(R1)(R1)(R1) to L_{y}3- (R70)(R70)(R70) having the structure | 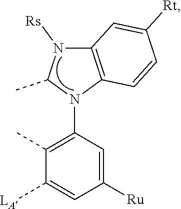 |
| L_{y}4-(R1)(R1)(R1) to L_{y}4- (R70)(R70)(R70)having the structure | 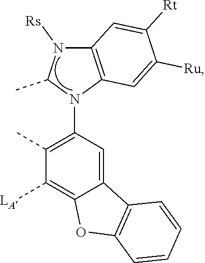 |
| L_{y}5-(R1)(R1)(R1) to L_{y}5- (R70)(R70)(R70) having the structure | 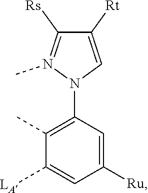 |
| L_{y}6-(R1)(R1)(R1) to L_{y}6- (R70)(R70)(R70) having the structure | 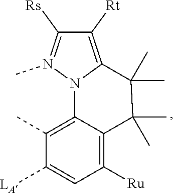 |
| L_{y}7-(R1)(R1)(R1) to L_{y}7- (R70)(R70)(R70) having the structure | 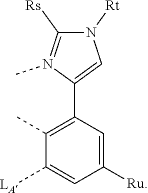 |
| L_{y}8-(R1)(R1)(R1) to L_{y}8- (R70)(R70)(R70) having the structure | 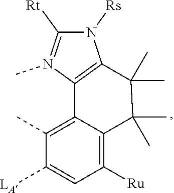 |
| L_{y}9-(R1)(R1)(R1) to L_{y}9- (R70)(R70)(R70) having the structure | 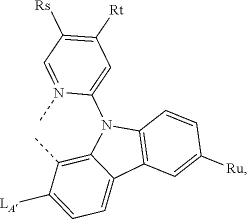 |
| L_{y}10-(R1)(R1)(R1) to L_{y}10-(R70)(R70)(R70) having the structure | 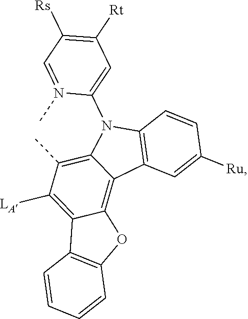 |
| L_{y}11-(R1)(R1)(R1) to L_{y}11-(R70)(R70)(R70) having the structure | 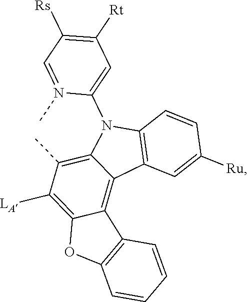 |
| L_{y}12-(R1)(R1)(R1) to L_{y}12-(R70)(R70)(R70) having the structure | 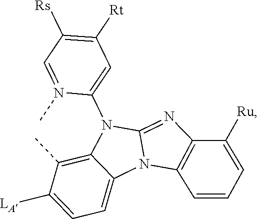 |
| L_{y}13-(R1)(R1)(R1) to L_{y}13-(R70)(R70)(R70) having the structure | 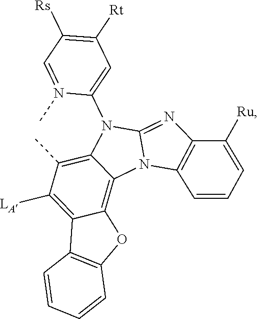 |
| L_{y}14-(R1)(R1)(R1) to L_{y}14-(R70)(R70)(R70) having the structure | 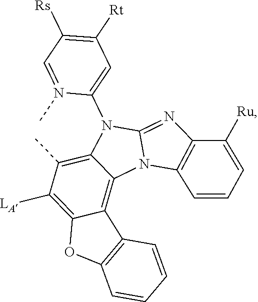 |
| L_{y}15-(R1)(R1)(R1) to L_{y}15-(R70)(R70)(R70) having the structure | 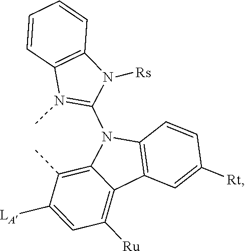 |
| L_{y}16-(R1)(R1)(R1) to L_{y}16-(R70)(R70)(R70) having the structure | 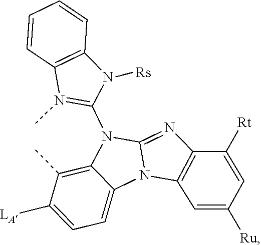 |
| L_{y}17-(R1)(R1)(R1) to L_{y}17-(R70)(R70)(R70) having the structure | 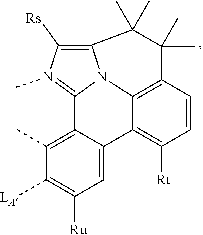 |
| L_{y}18-(R1)(R1)(R1) to L_{y}18-(R70)(R70)(R70), having the structure | 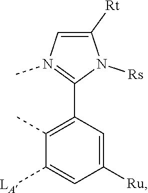 |
| L_{y}19-(R1)(R1)(R1) to L_{y}19-(R70)(R70)(R70) having the structure | 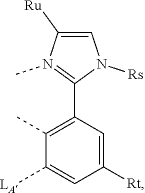 |
| L_{y}20-(R1)(R1)(R1) to L_{y}20-(R70)(R70)(R70) having the structure | 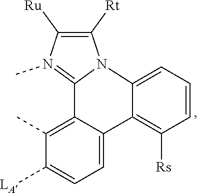 |
| L_{y}21-(R1)(R1)(R1) to L_{y}21-(R70)(R70)(R70) having the structure | 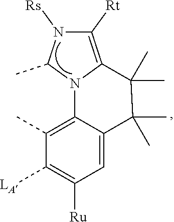 |
| L_{y}22-(R1)(R1)(R1) to L_{y}22-(R70)(R70)(R70) having the structure | 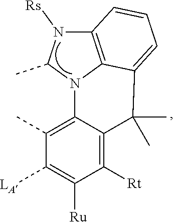 |
| L_{y}23-(R1)(R1)(R1) to L_{y}23-(R70)(R70)(R70) having the structure | 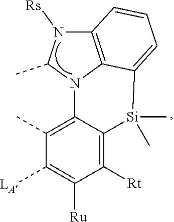 |
| L_{y}24-(R1)(R1)(R1) to L_{y}24-(R70)(R70)(R70) having the structure | 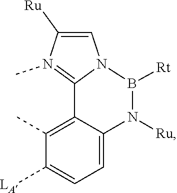 |
| L_{y}25-(R1)(R1)(R1) to L_{y}25-(R70)(R70)(R70) having the structure | 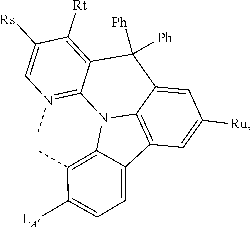 |
| L_{y}26-(R1)(R1)(R1) to L_{y}26-(R70)(R70)(R70) having the structure | 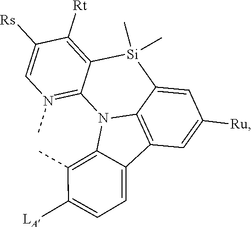 |
| L_{y}27-(R1)(R1)(R1) to L_{y}27-(R70)(R70)(R70) having the structure | 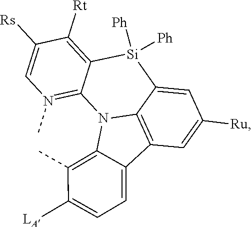 |
| L_{y}28-(R1)(R1)(R1) to L_{y}28-(R70)(R70)(R70) having the structure | 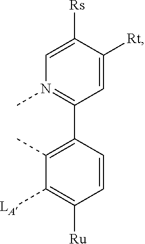 |
| L_{y}29-(R1)(R1)(R1) to L_{y}29-(R70)(R70)(R70) having the structure | 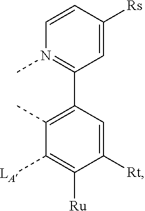 |
| L_{y}30-(R1)(R1)(R1) to L_{y}30-(R70)(R70)(R70) having the structure | 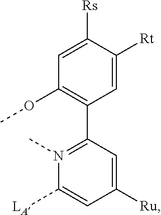 |
| L_{y}31-(R1)(R1)(R1) to L_{y}31-(R70) R70)(R70) having the structure | 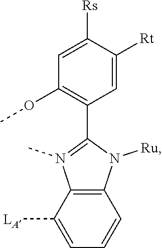 |
| L_{y}32-(R1)(R1)(R1) to L_{y}32-(R70)(R70)(R70) having the structure | 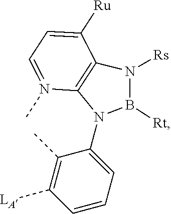 |
| L_{y}33-(R1)(R1)(R1) to L_{y}33-(R70)(R70)(R70) having the structure | 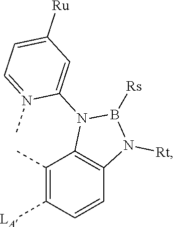 |
| L_{y}34-(R1)(R1)(R1) to L_{y}34-(R70)(R70)(R70) having the structure | 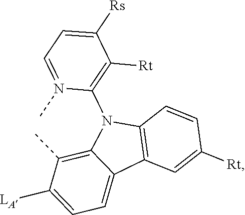 |
| L_{y}35-(R1)(R1)(R1) to L_{y}35-(R70)(R70)(R70) having the structure | 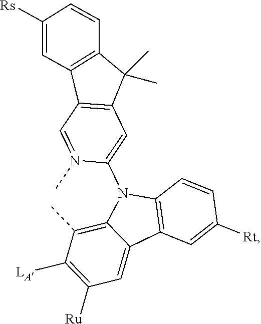 |
| L_{y}36-(R1)(R1)(R1) to L_{y}36-(R70)(R70)(R70) having the structure | 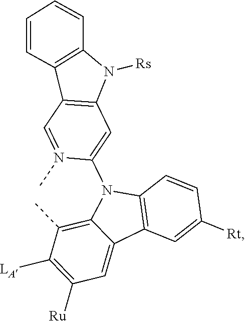 |
| L_{y}37-(R1)(R1)(R1) to L_{y}37-(R70)(R70)(R70) having the structure | 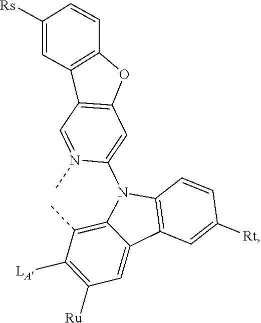 |
| L_{y}38-(R1)(R1)(R1) to L_{y}38-(R70)(R70)(R70) having the structure | 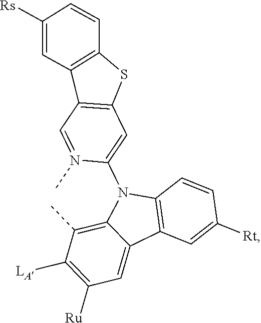 |
| L_{y}39-(R1)(R1)(R1) to L_{y}39-(R70)(R70)(R70) having the structure | 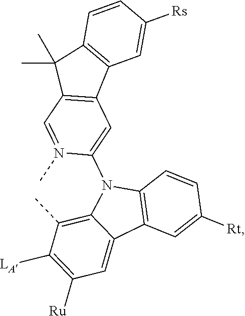 |
| L_{y}40-(R1)(R1)(R1) to L_{y}40-(R70)(R70)(R70) having the structure | 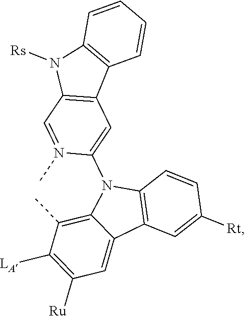 |
| L_{y}41-(R1)(R1)(R1) to L_{y}41-(R70)(R70)(R70) having the structure | 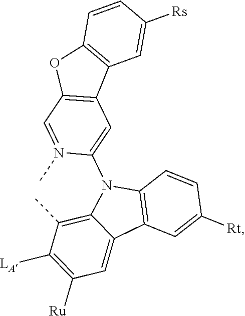 |
| L_{y}42-(R1)(R1)(R1) to L_{y}42-(R70)(R70)(R70) having the structure | 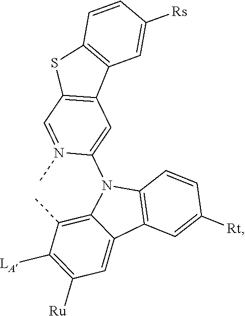 |
| L_{y}43-(R1)(R1)(R1) to L_{y}43-(R70)(R70)(R70) having the structure | 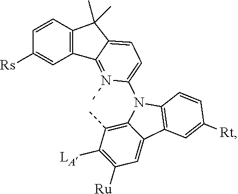 |
| L_{y}44-(R1)(R1)(R1) to L_{y}44-(R70)(R70)(R70) having the structure | 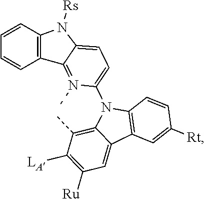 |
| L_{y}45-(R1)(R1)(R1) to L_{y}45-(R70)(R70)(R70) having the structure | 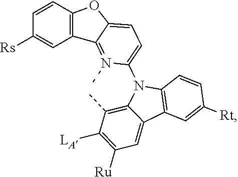 |
| L_{y}46-(R1)(R1)(R1) to L_{y}46-(R70)(R70)(R70) having the structure | 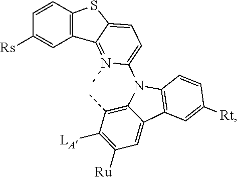 |
| L_{y}47-(R1)(R1)(R1) to L_{y}47-(R70)(R70)(R70) having the structure | 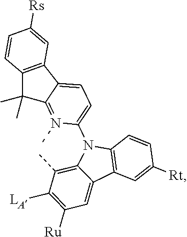 |
| L_{y}48-(R1)(R1)(R1) to L_{y}48-(R70)(R70)(R70) having the structure | 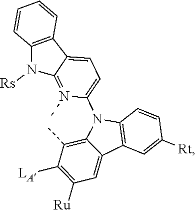 |
| L_{y}49-(R1)(R1)(R1) to L_{y}49-(R70)(R70)(R70) having the structure | 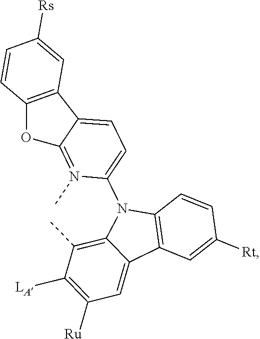 |
| L_{y}50-(R1)(R1)(R1) to L_{y}50-(R70)(R70)(R70) having the structure | 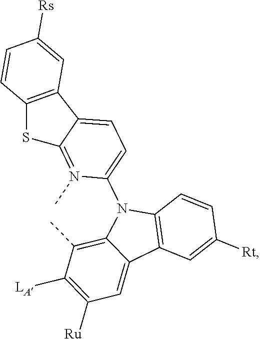 |
| L_{y}51-(R1)(R1)(R1) to L_{y}51-(R70)(R70)(R70) having the structure | 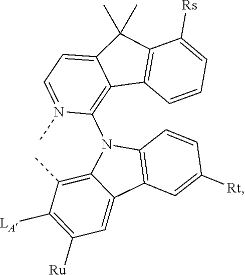 |
| L_{y}52-(R1)(R1)(R1) to L_{y}52-(R70)(R70)(R70) having the structure | 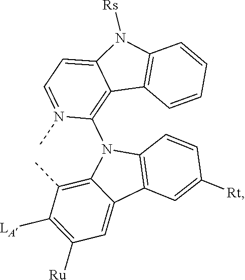 |
| L_{y}53-(R1)(R1)(R1) to L_{y}53-(R70)(R70)(R70) having the structure | 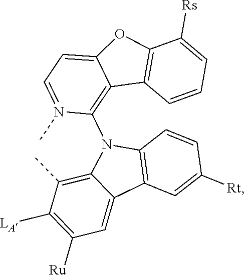 |
| L_{y}54-(R1)(R1)(R1) to L_{y}54-(R70)(R70)(R70) having the structure | 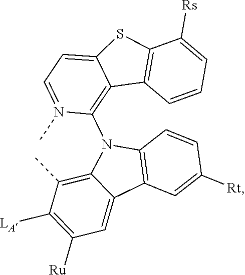 |
| L_{y}55-(R1)(R1)(R1) to L_{y}55-(R70)(R70)(R70) having the structure | 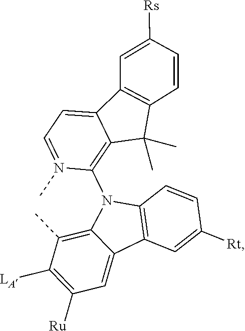 |
| L_{y}56-(R1)(R1)(R1) to L_{y}56-(R70)(R70)(R70) having the structure | 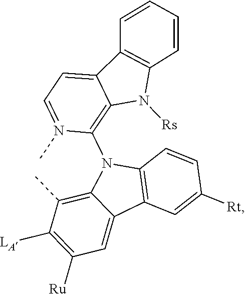 |
| L_{y}57-(R1)(R1)(R1) to L_{y}57-(R70)(R70)(R70) having the structure | 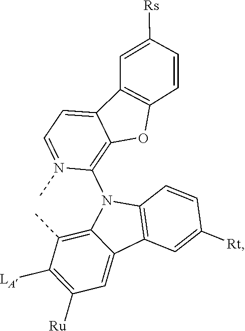 |
| L_{y}58-(R1)(R1)(R1) to L_{y}58-(R70)(R70)(R70) having the structure | 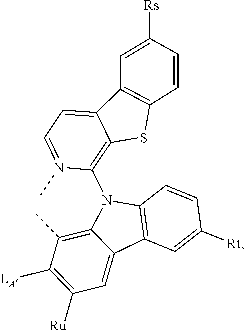 |
| L_{y}59-(R1)(R1)(R1) to L_{y}59-(R70)(R70)(R70) having the structure | 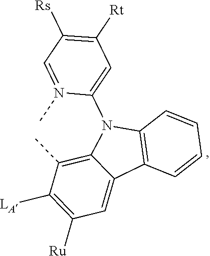 |
| L_{y}60-(R1)(R1)(R1) to L_{y}60-(R70)(R70)(R70) having the structure | 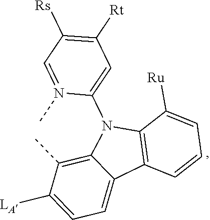 |
| L_{y}61-(R1)(R1)(R1) to L_{y}61-(R70)(R70)(R70) having the structure | 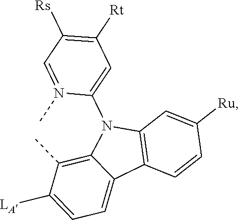 |
| L_{y}62-(R1)(R1)(R1) to L_{y}62-(R70)(R70)(R70) having the structure | 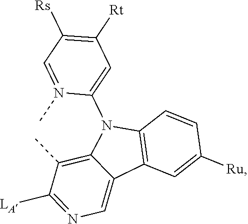 |

wherein, for each occurrence in L_{A} and each occurrence in L_{y}, each of s, t, and u are each independently an integer from 1 to 70, wherein R1 to R70 have the structures defined in LIST 7.

In some embodiments, the compound can be selected from the group consisting of the compounds of the following LIST 18:

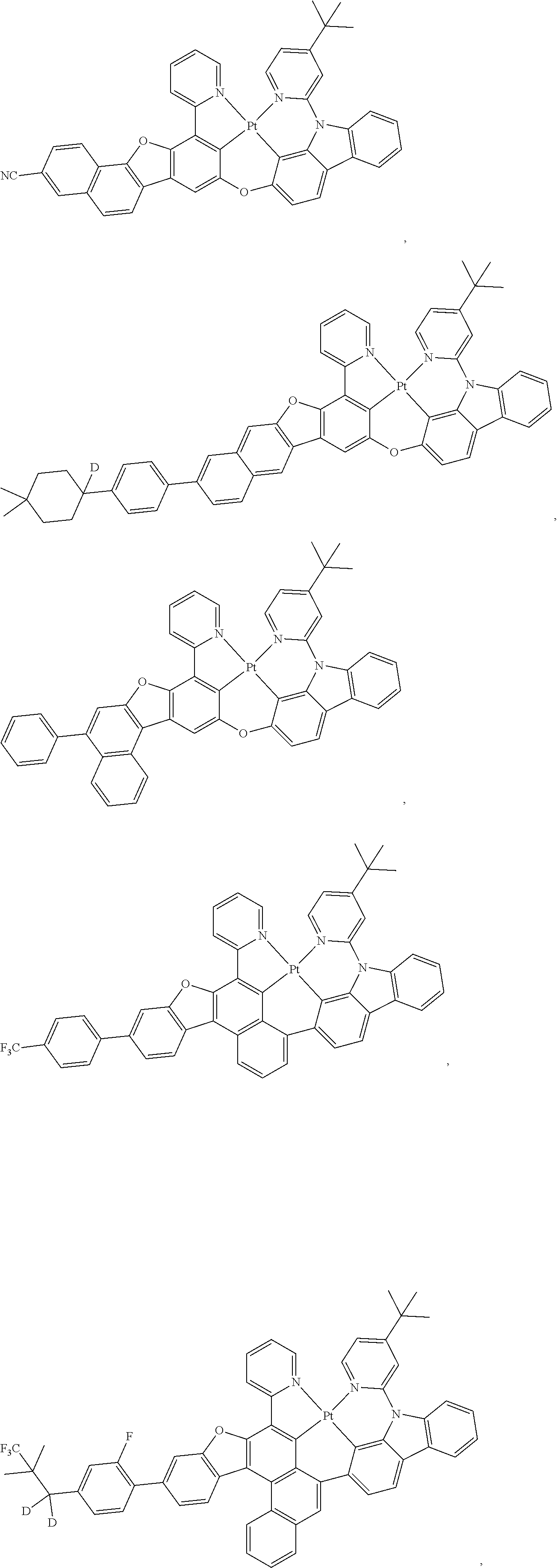

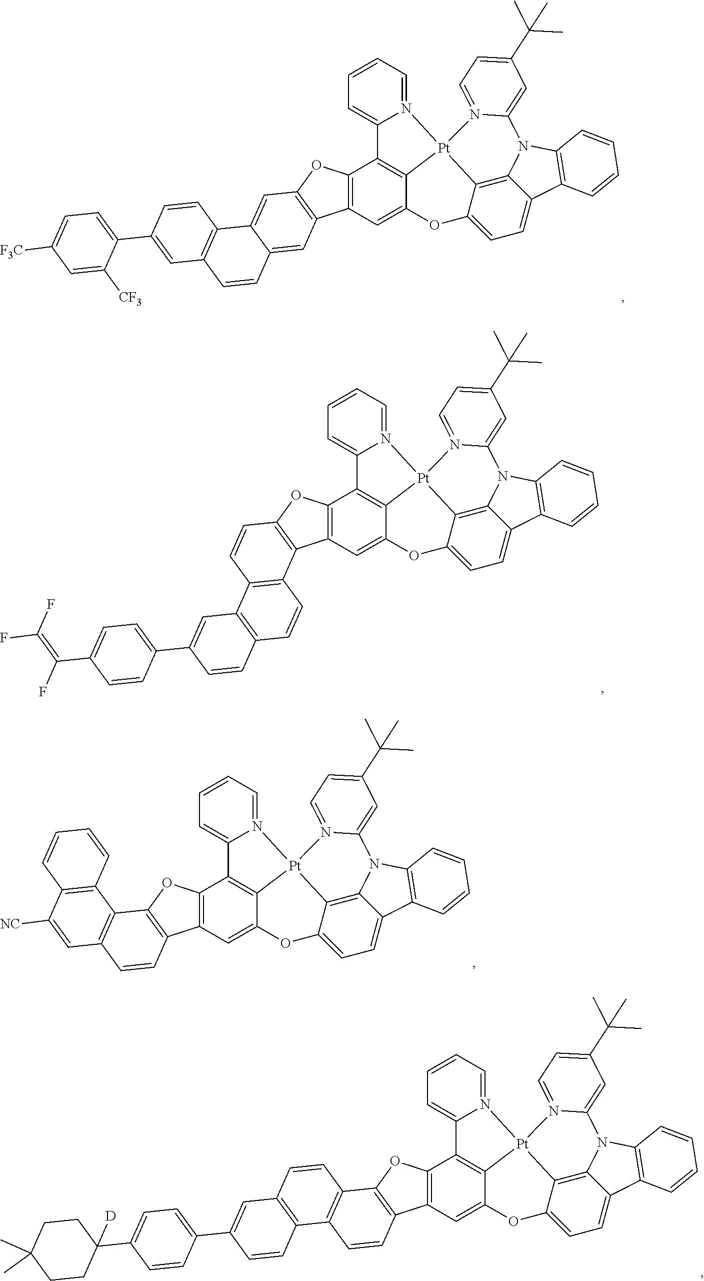

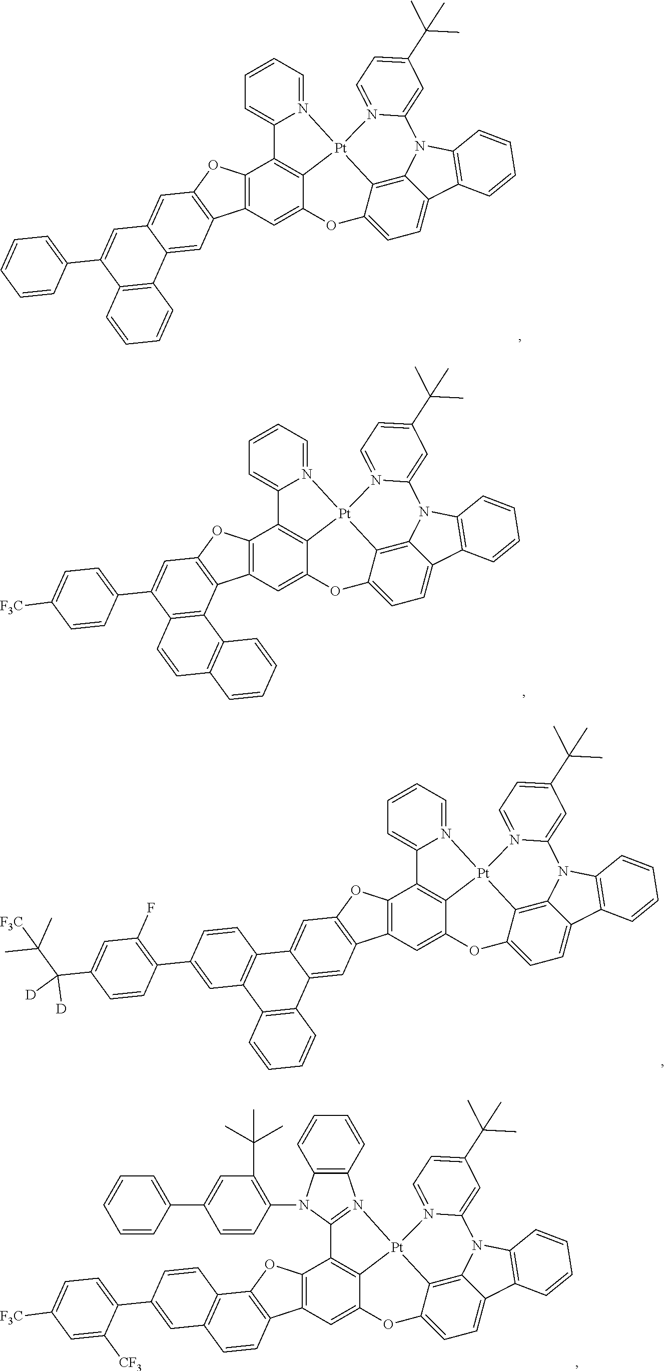

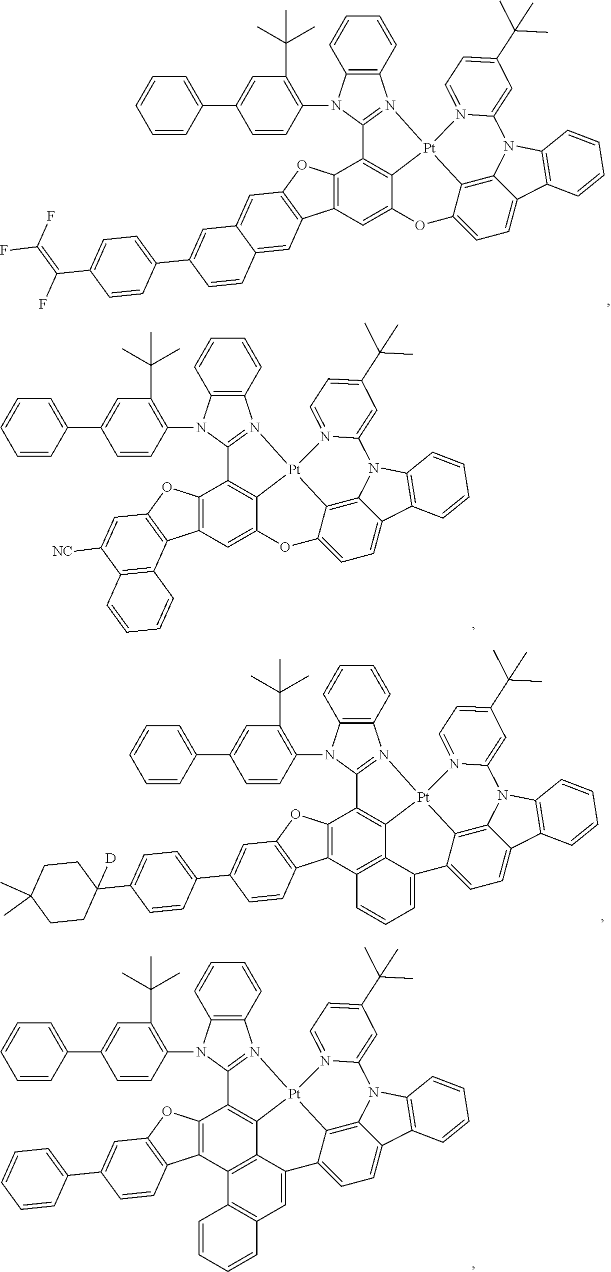

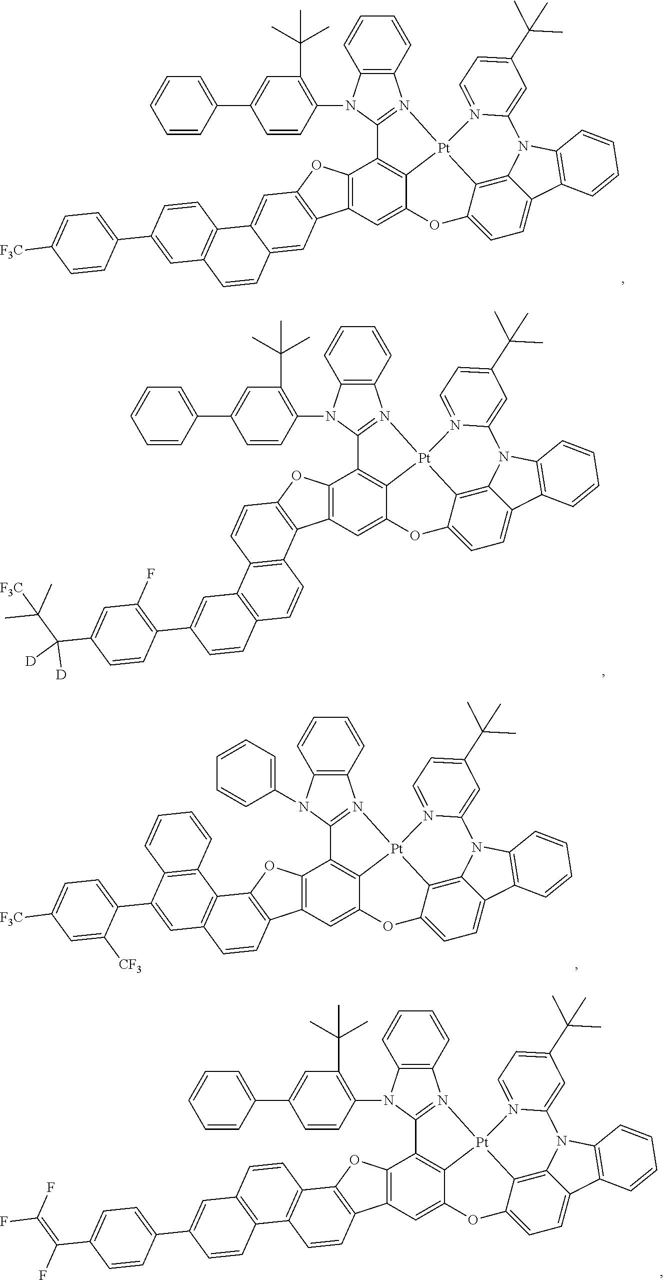

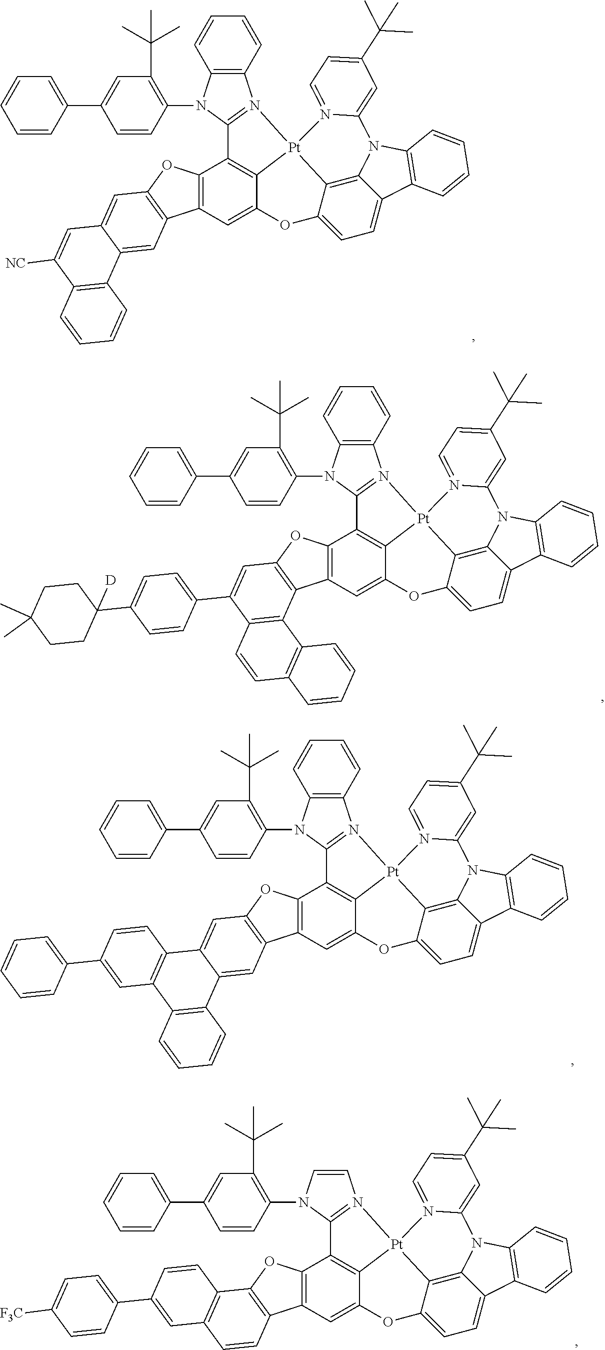

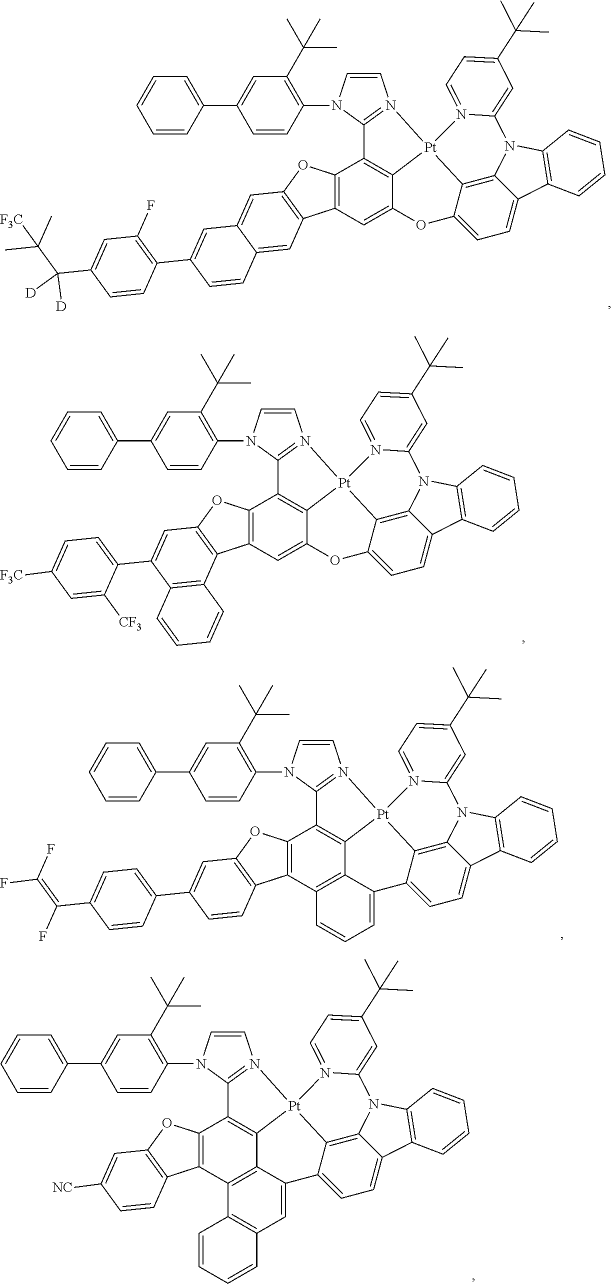

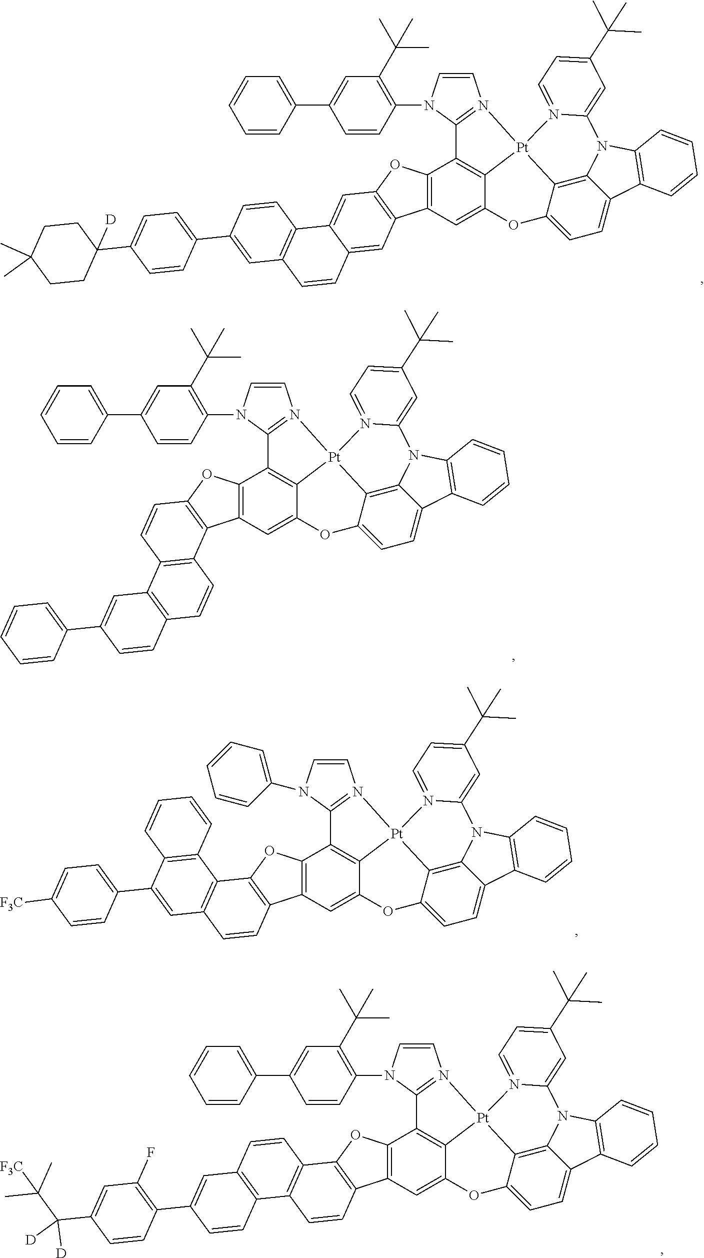

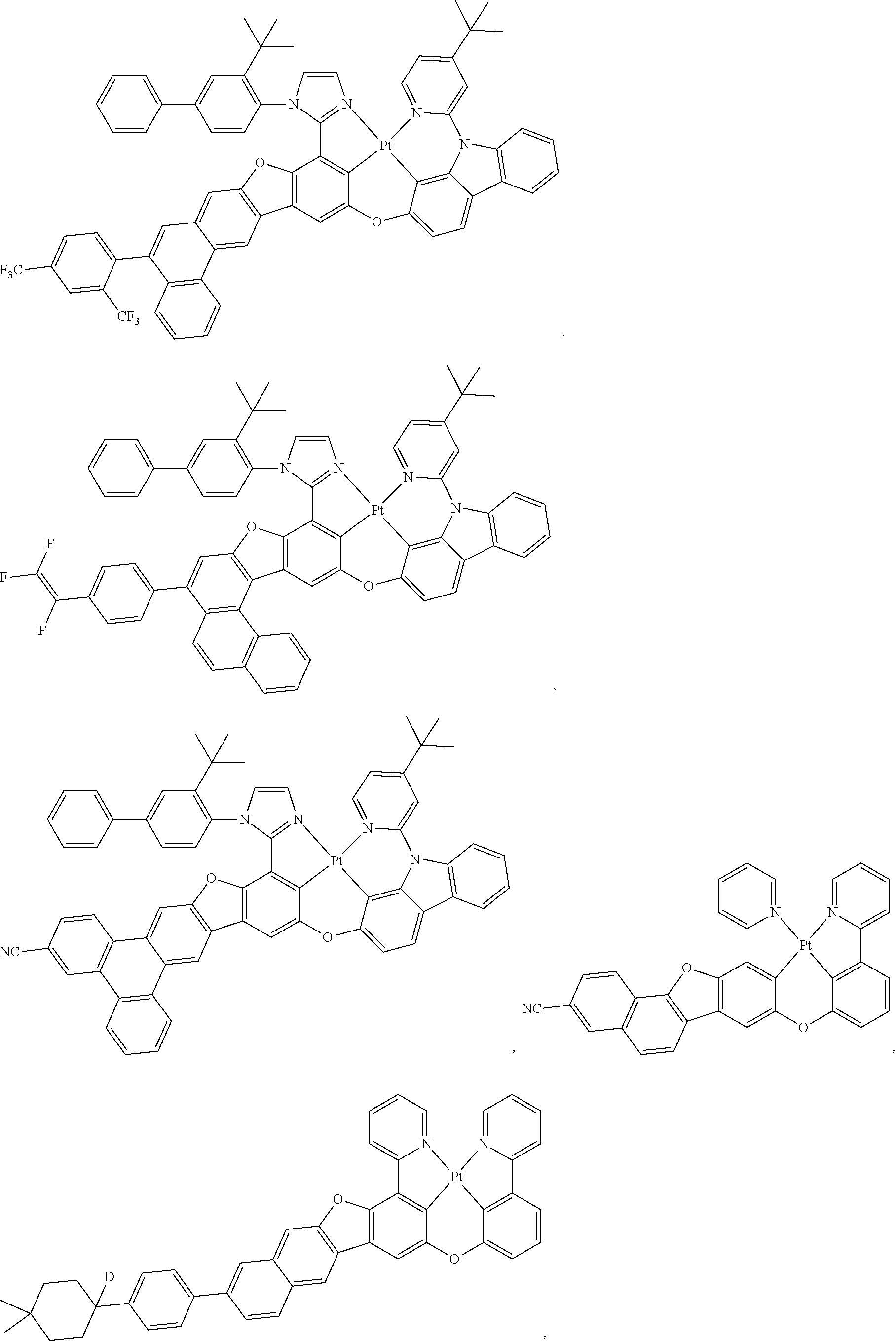

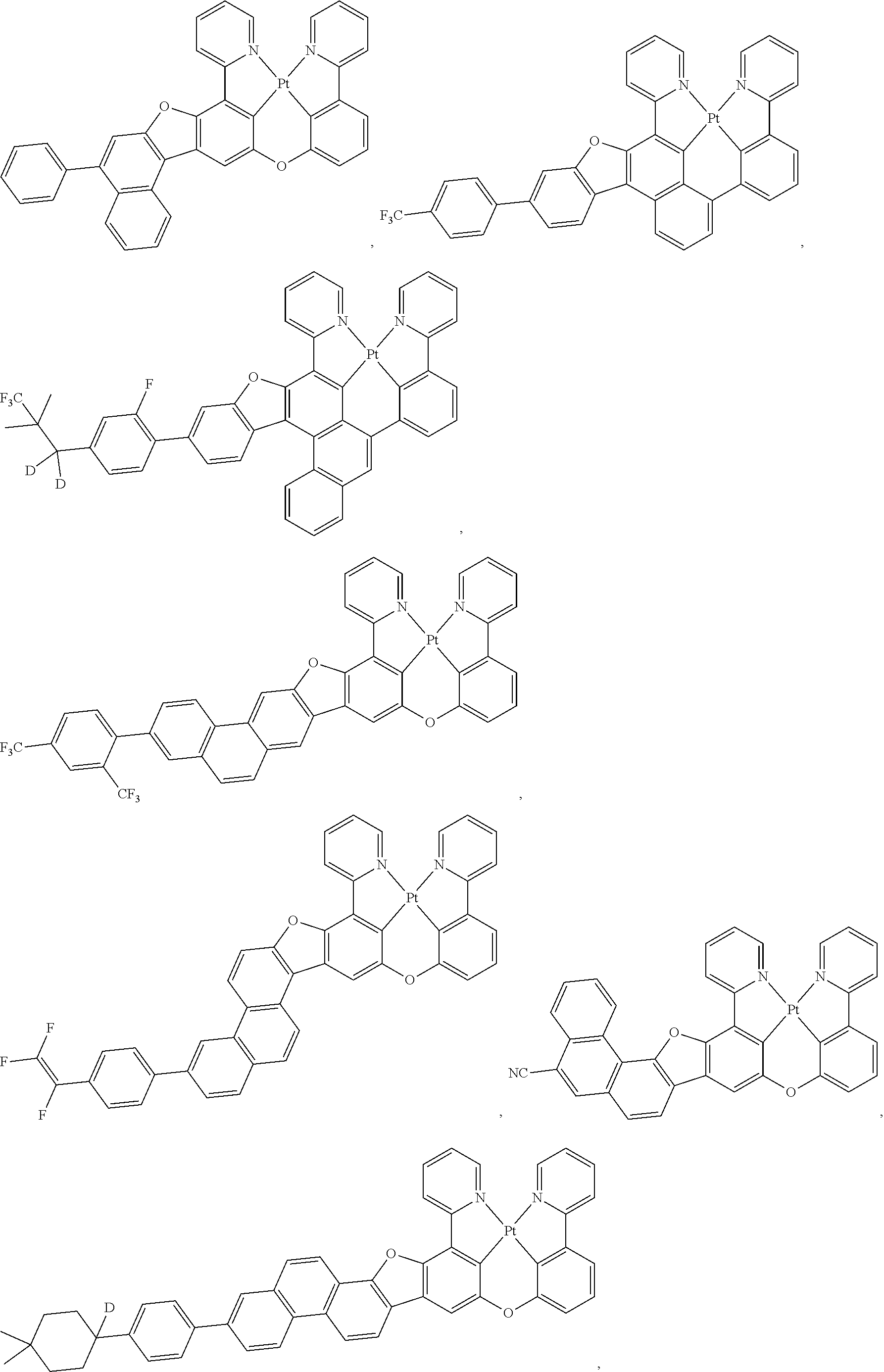

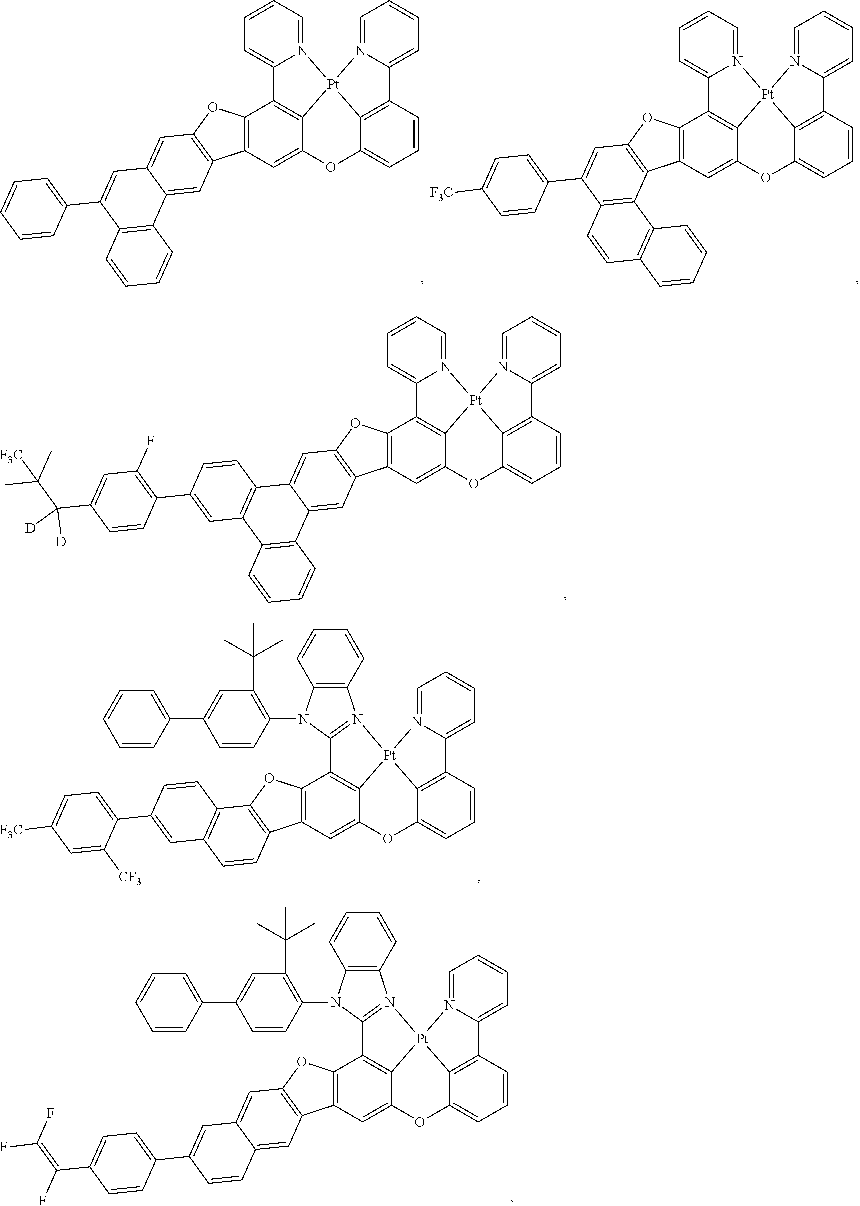

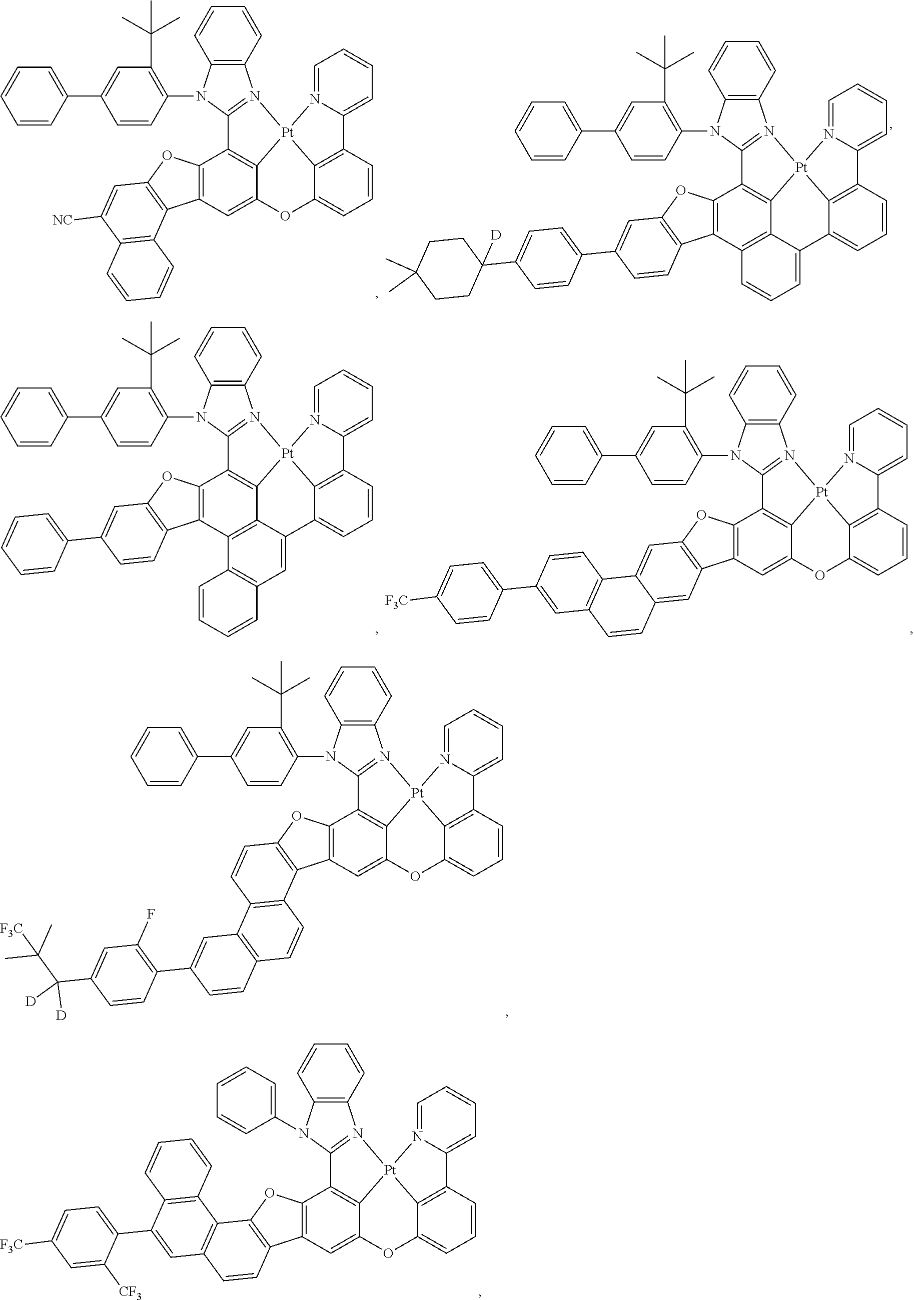

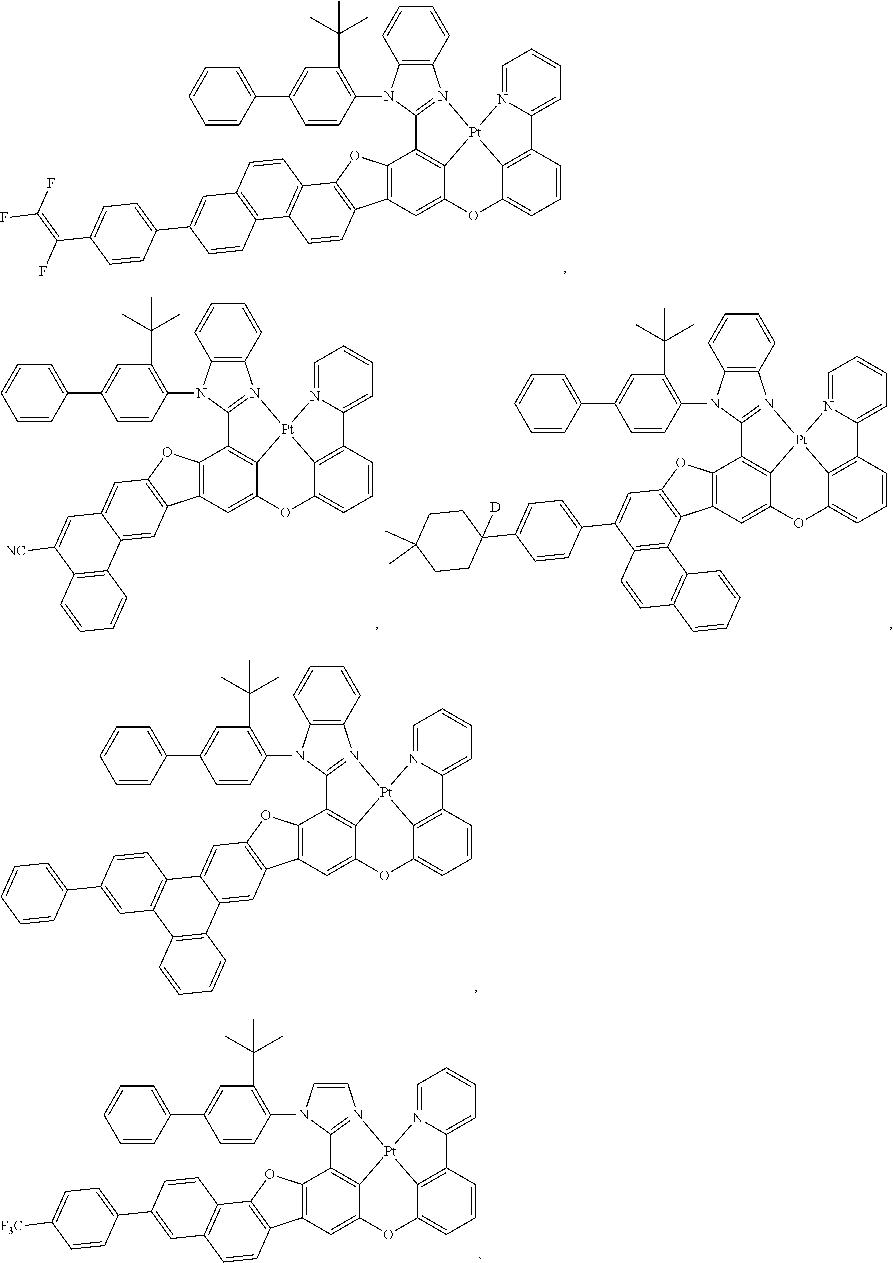

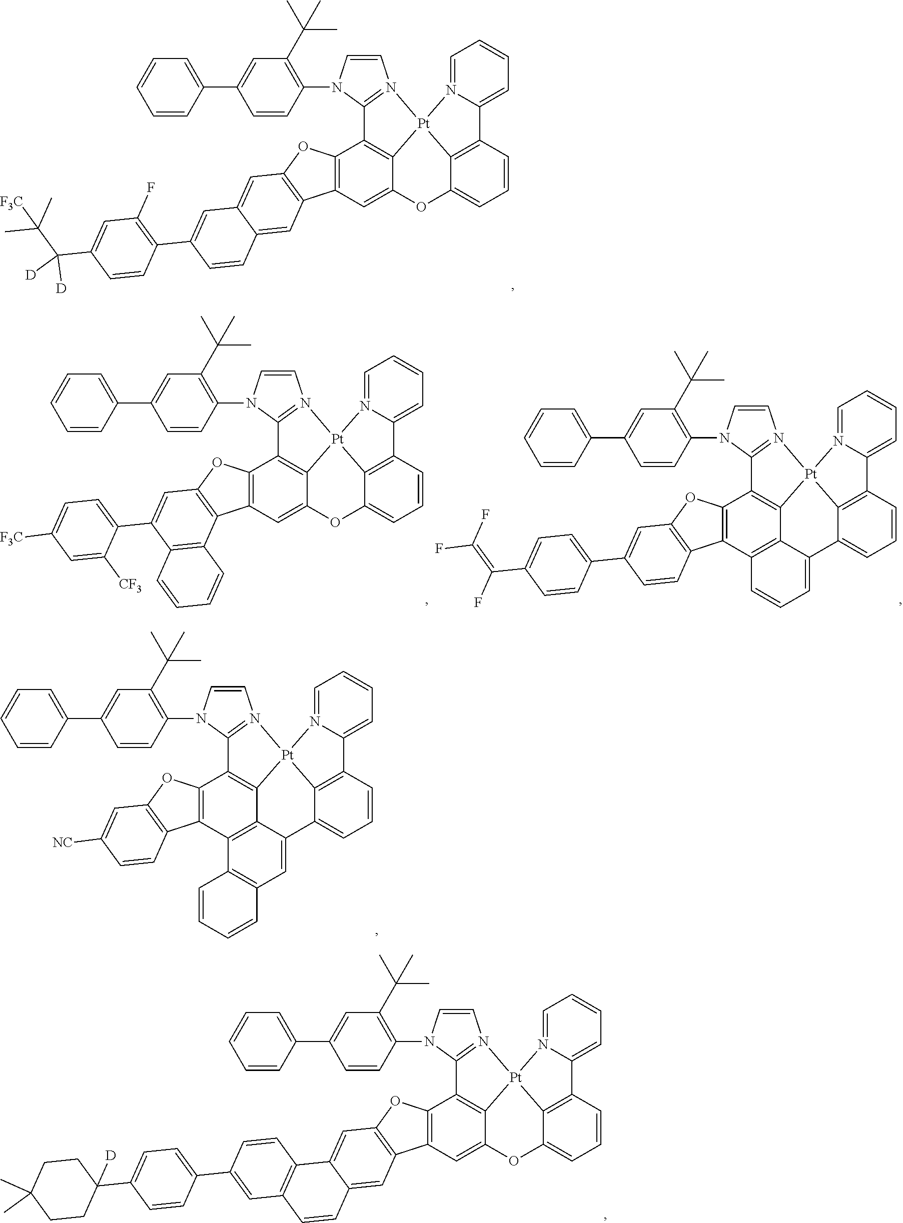

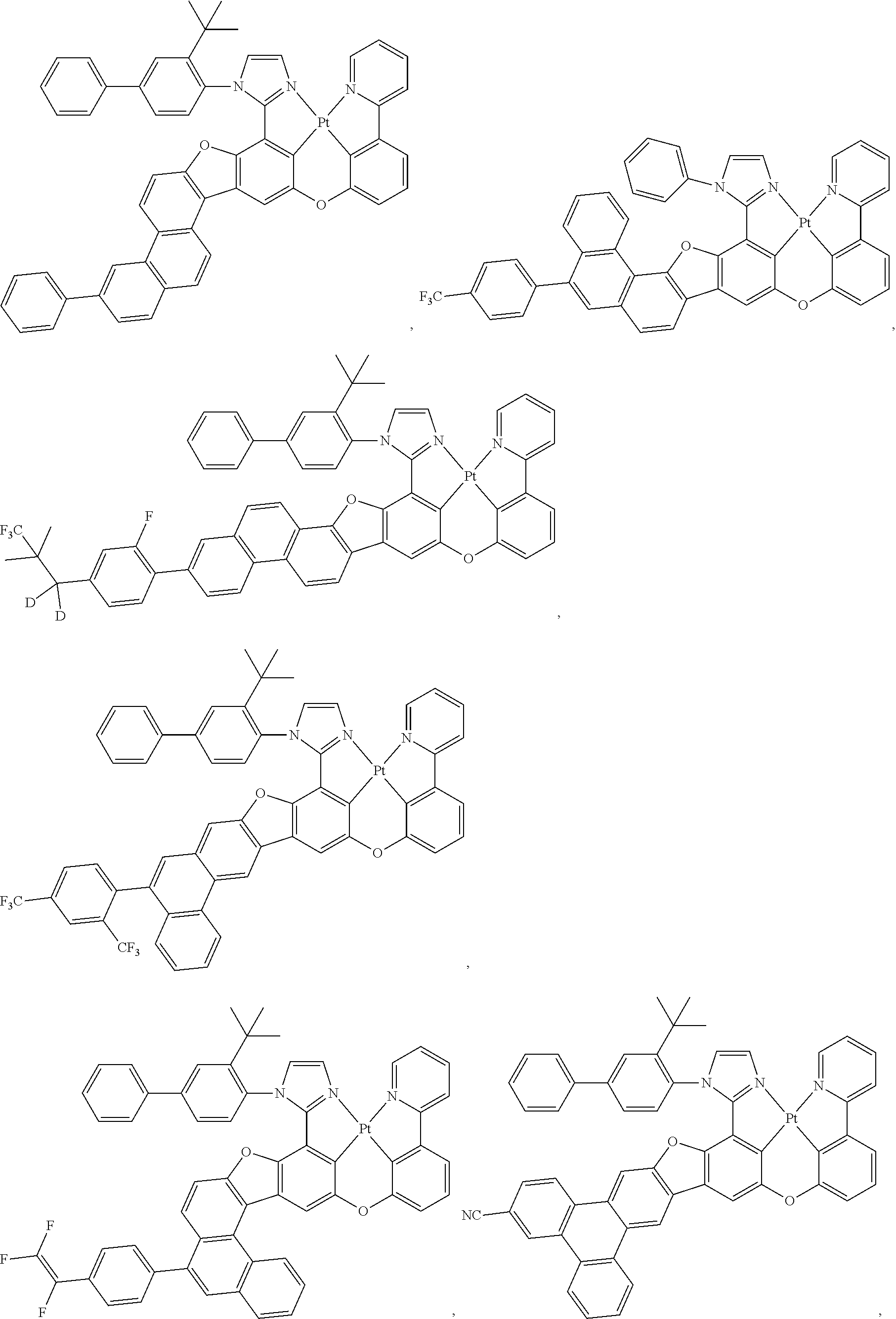

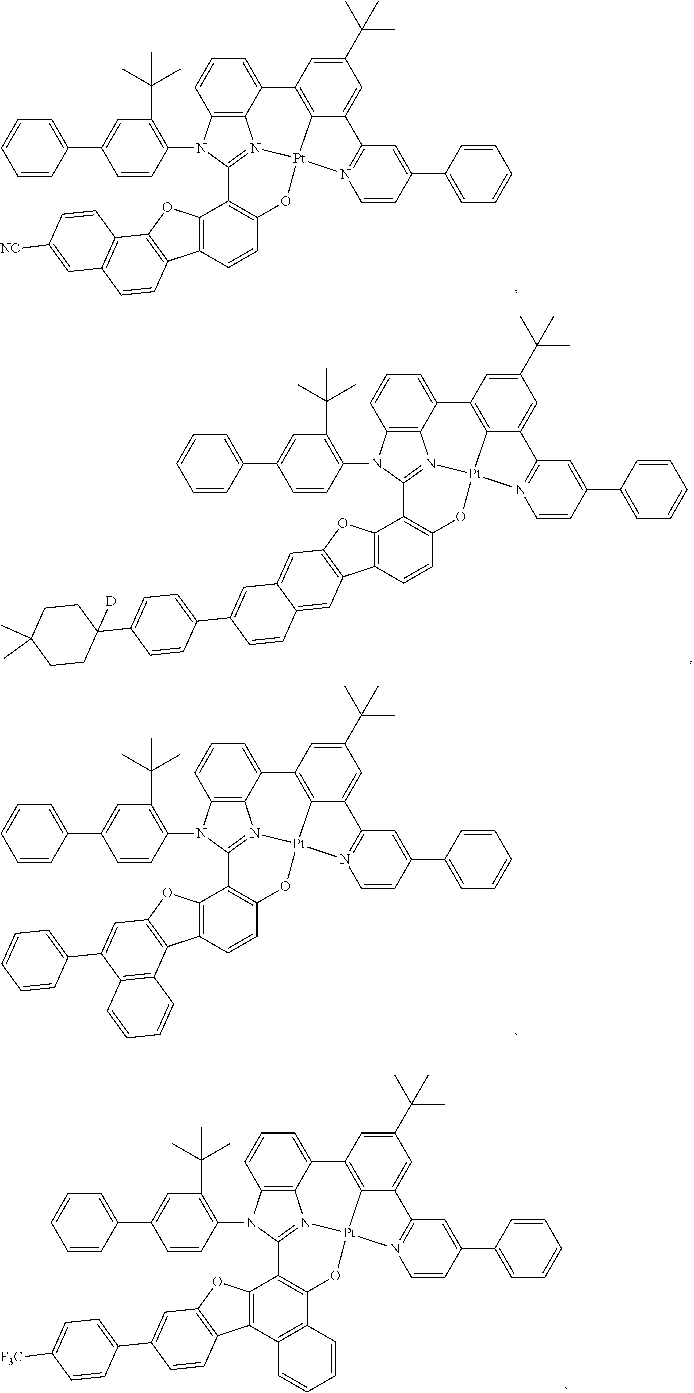

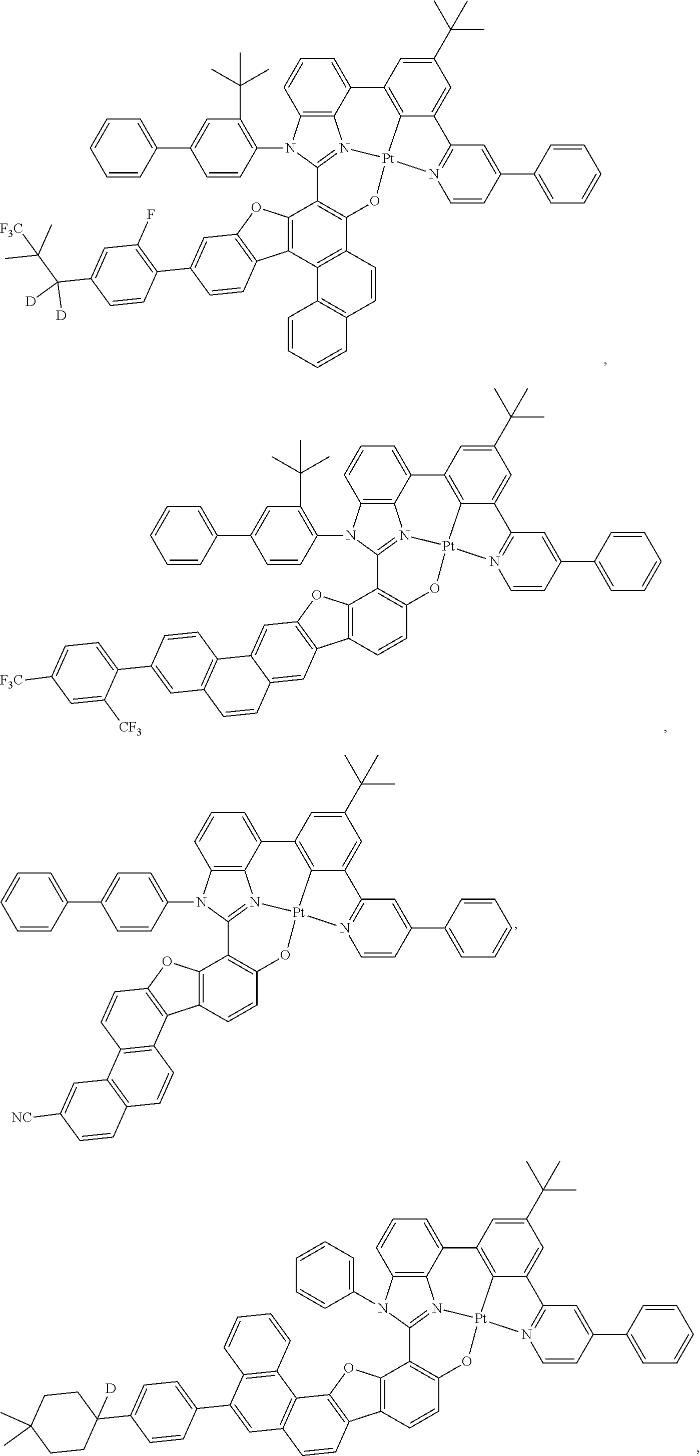

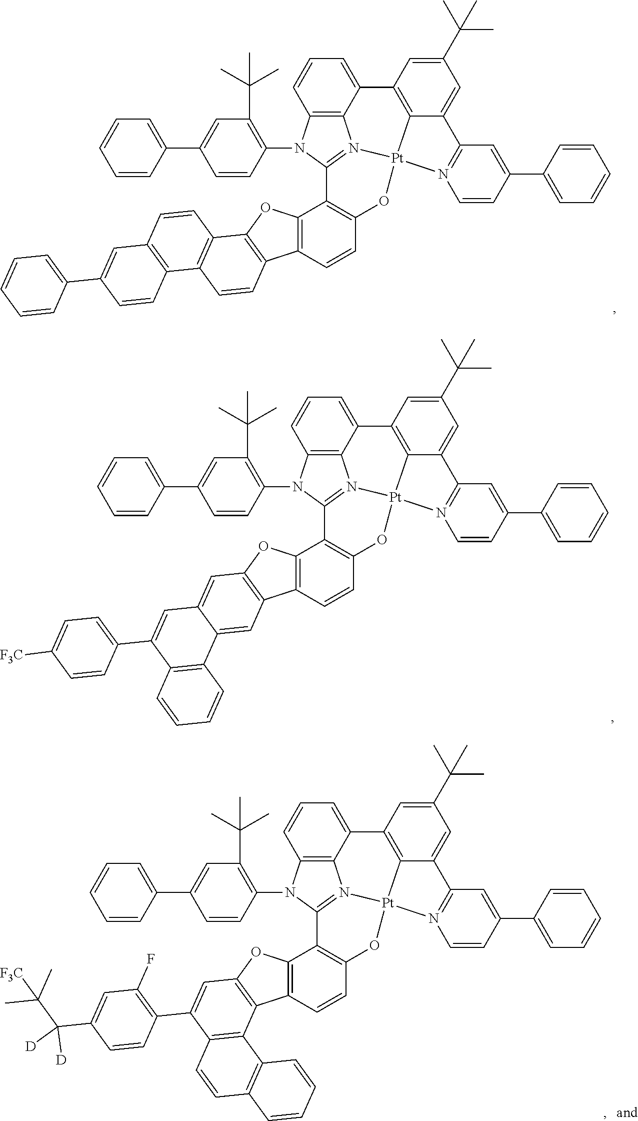

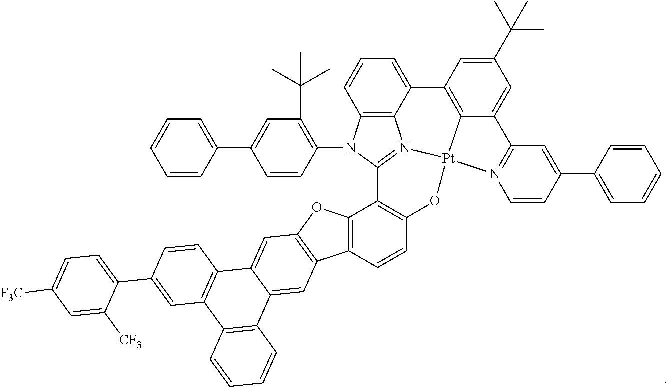

In some embodiments, the compound having a first ligand L_{A} of Formula I described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of possible hydrogen atoms (e.g., positions that are hydrogen, deuterium, or halogen) that are replaced by deuterium atoms.

In some embodiments of heteroleptic compound having the formula of M(L_{A})ₚ(L_{B})_{q}(L_{C})ᵣ as defined herein, the ligand L_{A} has a first substituent R′, where the first substituent R′ has a first atom a-I that is the farthest away from the metal M among all atoms in the ligand L_{A}. Additionally, the ligand L_{B}, if present, has a second substituent R^{II}, where the second substituent R^{II} has a first atom a-II that is the farthest away from the metal M among all atoms in the ligand L_{B}. Furthermore, the ligand L_{C}, if present, has a third substituent R^{III}, where the third substituent R^{III} has a first atom a-III that is the farthest away from the metal M among all atoms in the ligand L_{C}.

In such heteroleptic compounds, vectors V_{D1}, V_{D2}, and V_{D3} can be defined that are defined as follows. V_{D1} represents the direction from the metal M to the first atom a-I and the vector V_{D1} has a value D¹ that represents the straight line distance between the metal M and the first atom a-I in the first substituent R¹. V_{D2} represents the direction from the metal M to the first atom a-II and the vector V_{D2} has a value D² that represents the straight line distance between the metal M and the first atom a-II in the second substituent R^{II}. V_{D3} represents the direction from the metal M to the first atom a-III and the vector V_{D3} has a value D³ that represents the straight line distance between the metal M and the first atom a-III in the third substituent R^{III}.

In such heteroleptic compounds, a sphere having a radius r is defined whose center is the metal M and the radius r is the smallest radius that will allow the sphere to enclose all atoms in the compound that are not part of the substituents R^{I}, R^{II} and R^{III}; and where at least one of D¹, D², and D³ is greater than the radius r by at least 1.5 Å. In some embodiments, at least one of D¹, D², and D³ is greater than the radius r by at least 2.9, 3.0, 4.3, 4.4, 5.2, 5.9, 7.3, 8.8, 10.3, 13.1, 17.6, or 19.1 Å.

In some embodiments of such heteroleptic compound, the compound has a transition dipole moment axis and angles are defined between the transition dipole moment axis and the vectors V_{D1}, V_{D2}, and V_{D3}, where at least one of the angles between the transition dipole moment axis and the vectors V_{D1}, V_{D2}, and V_{D3} is less than 40°. In some embodiments, at least one of the angles between the transition dipole moment axis and the vectors V_{D1}, V_{D2}, and V_{D3} is less than 30°. In some embodiments, at least one of the angles between the transition dipole moment axis and the vectors V_{D1}, V_{D2}, and V_{D3} is less than 20°. In some embodiments, at least one of the angles between the transition dipole moment axis and the vectors V_{D1}, V_{D2}, and V_{D3} is less than 15°. In some embodiments, at least one of the angles between the transition dipole moment axis and the vectors V_{D1}, V_{D2}, and V_{D3} is less than 10°. In some embodiments, at least two of the angles between the transition dipole moment axis and the vectors V_{D1}, V_{D2}, and V_{D3} are less than 20°.

In some embodiments, at least two of the angles between the transition dipole moment axis and the vectors V_{D1}, V_{D2}, and V_{D3} are less than 15°. In some embodiments, at least two of the angles between the transition dipole moment axis and the vectors V_{D1}, V_{D2}, and V_{D3} are less than 10°.

In some embodiments, all three angles between the transition dipole moment axis and the vectors V_{D1}, V_{D2}, and V_{D3} are less than 20°. In some embodiments, all three angles between the transition dipole moment axis and the vectors V_{D1}, V_{D2}, and V_{D3} are less than 15°. In some embodiments, all three angles between the transition dipole moment axis and the vectors V_{D1}, V_{D2}, and V_{D3} are less than 100.

In some embodiments of such heteroleptic compounds, the compound has a vertical dipole ratio (VDR) of 0.33 or less. In some embodiments of such heteroleptic compounds, the compound has a VDR of 0.30 or less. In some embodiments of such heteroleptic compounds, the compound has a VDR of 0.25 or less. In some embodiments of such heteroleptic compounds, the compound has a VDR of 0.20 or less. In some embodiments of such heteroleptic compounds, the compound has a VDR of 0.15 or less.

One of ordinarily skill in the art would readily understand the meaning of the terms transition dipole moment axis of a compound and vertical dipole ratio of a compound. Nevertheless, the meaning of these terms can be found in U.S. Pat. No. 10,672,997 whose disclosure is incorporated herein by reference in its entirety. In U.S. Pat. No. 10,672,997, horizontal dipole ratio (HDR) of a compound, rather than VDR, is discussed. However, one skilled in the art readily understands that VDR=1−HDR.

### C. The OLEDs and the Devices of the Present Disclosure

In another aspect, the present disclosure also provides an OLED device comprising a first organic layer that contains a compound as disclosed in the above compounds section of the present disclosure.

In some embodiments, the OLED comprises: an anode; a cathode; and an organic layer disposed between the anode and the cathode, where the organic layer comprises a compound having a first ligand L_{A} of Formula I as described herein.

In some embodiments, the organic layer may be an emissive layer and the compound as described herein may be an emissive dopant or a non-emissive dopant.

In some embodiments, the emissive layer comprises one or more quantum dots.

In some embodiments, the organic layer may further comprise a host, wherein the host comprises a triphenylene containing benzo-fused thiophene or benzo-fused furan, wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡CCₙH₂ₙ₊₁, Ar₁, Ar₁-Ar₂, CₙH₂ₙ-Ar₁, or no substitution, wherein n is an integer from 1 to 10; and wherein Ar₁ and Ar₂ are independently selected from the group consisting of benzene, biphenyl, naphthalene, triphenylene, carbazole, and heteroaromatic analogs thereof.

In some embodiments, the organic layer may further comprise a host, wherein host comprises at least one chemical group selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, triazine, boryl, silyl, azatriphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

In some embodiments, the host may be selected from the HOST Group consisting of:

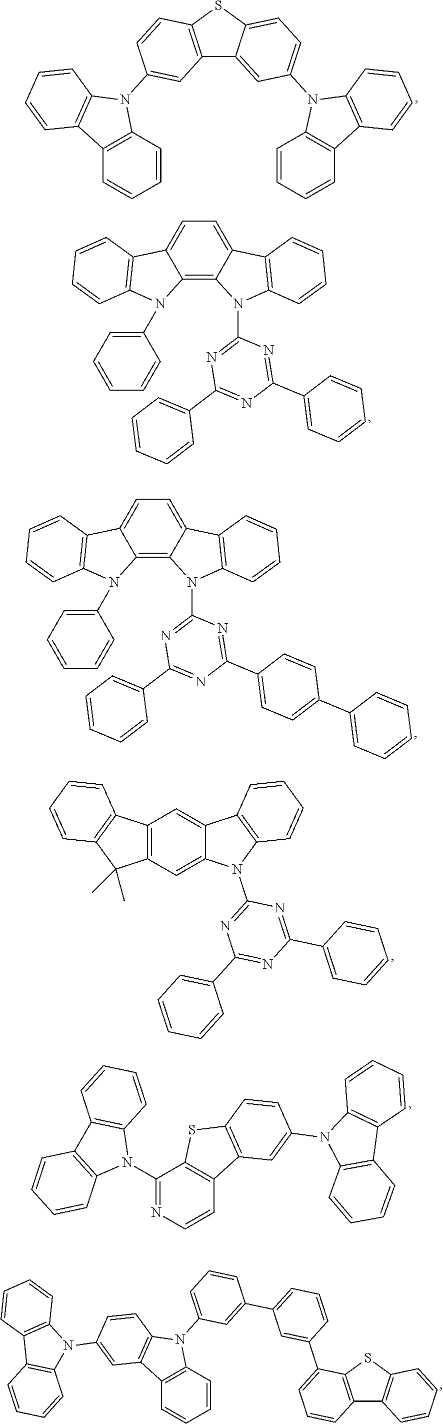

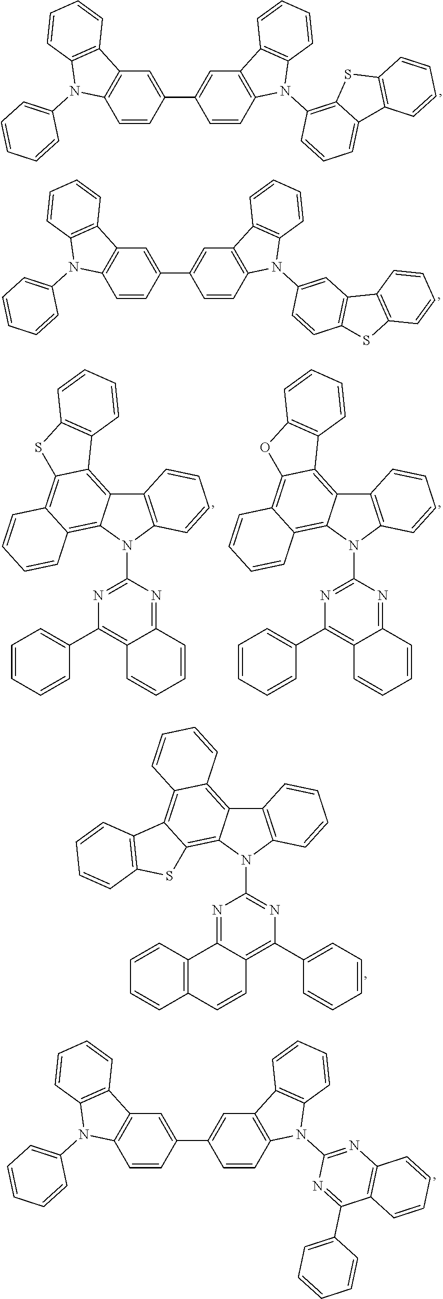

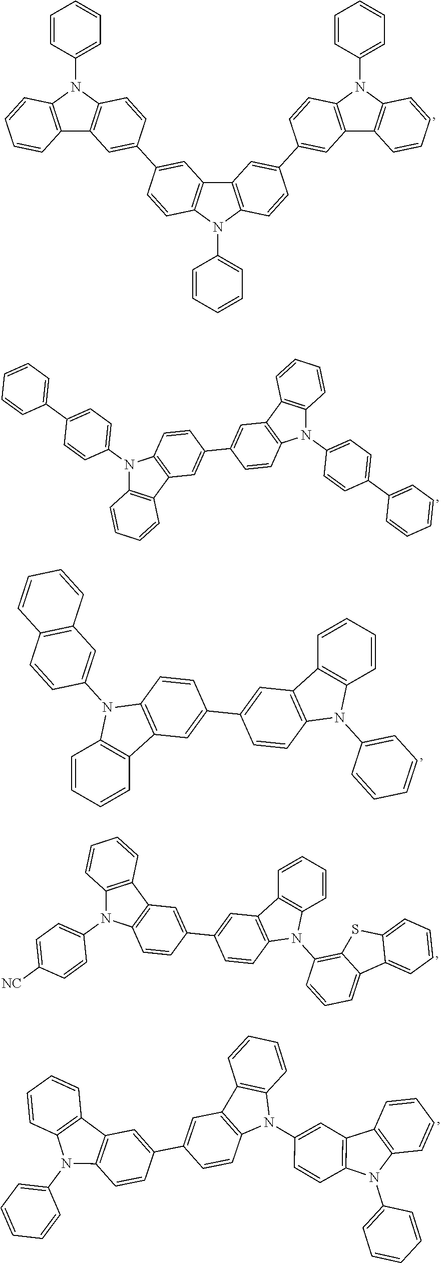

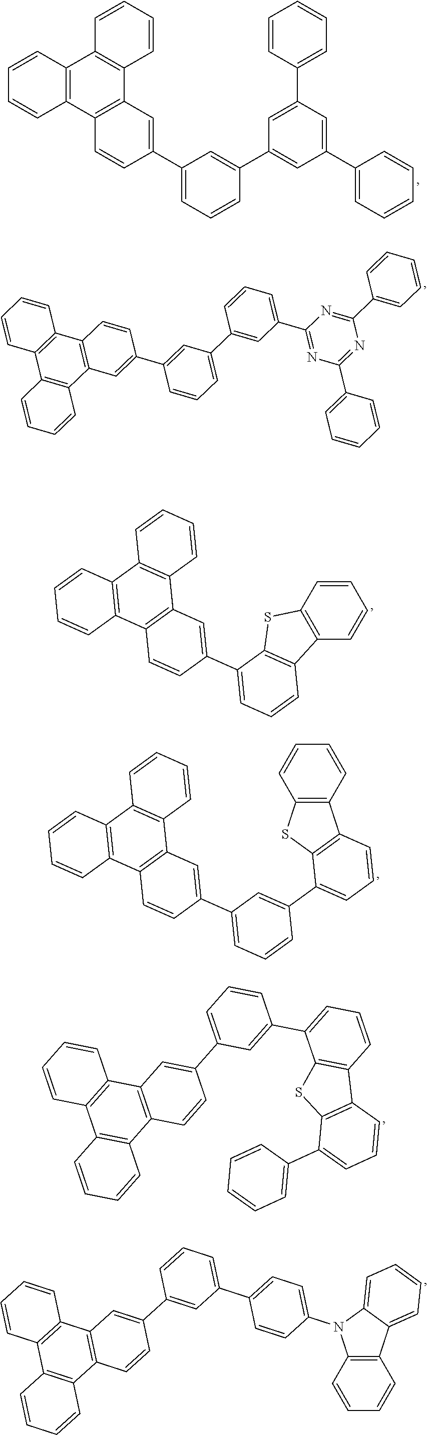

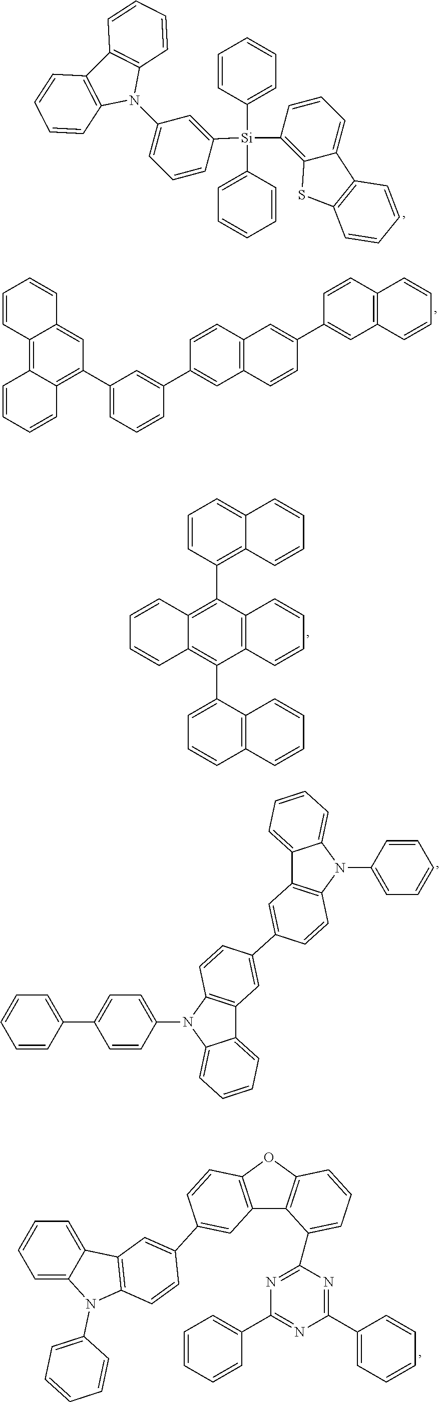

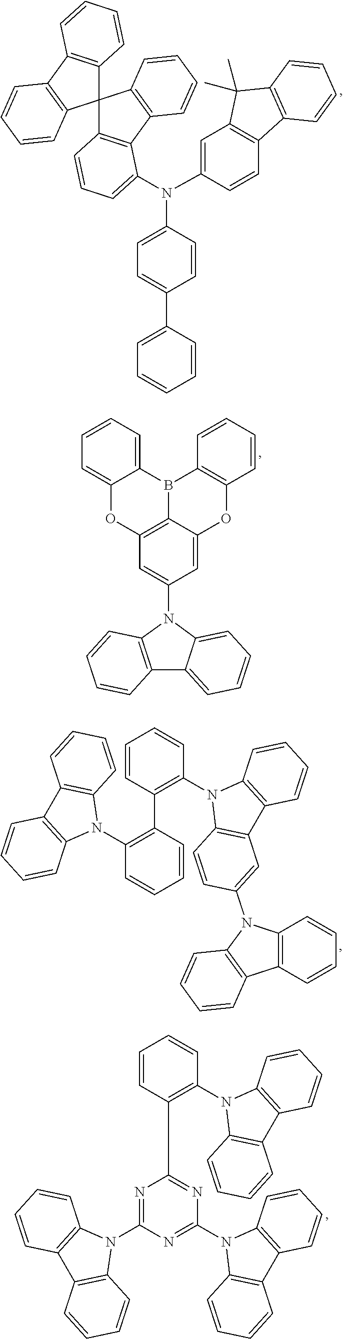

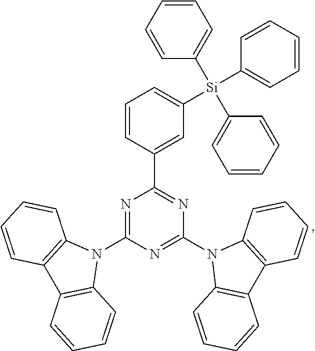 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

and combinations thereof.

In some embodiments, the organic layer may further comprise a host, wherein the host comprises a metal complex.

In some embodiments, the emissive layer can comprise two hosts, a first host and a second host. In some embodiments, the first host is a hole transporting host, and the second host is an electron transporting host. In some embodiments, the first host and the second host can form an exciplex.

In some embodiments, the compound as described herein may be a sensitizer; wherein the device may further comprise an acceptor; and wherein the acceptor may be selected from the group consisting of fluorescent emitter, delayed fluorescence emitter, and combination thereof.

In yet another aspect, the OLED of the present disclosure may also comprise an emissive region containing a compound as disclosed in the above compounds section of the present disclosure.

In some embodiments, the emissive region can comprise a compound having a first ligand L_{A} of Formula I as described herein.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In yet another aspect, the present disclosure also provides a consumer product comprising an organic light-emitting device (OLED) having an anode; a cathode; and an organic layer disposed between the anode and the cathode, wherein the organic layer may comprise a compound as disclosed in the above compounds section of the present disclosure.

In some embodiments, the consumer product comprises an OLED having an anode; a cathode; and an organic layer disposed between the anode and the cathode, wherein the organic layer may comprise a compound having a first ligand L_{A} of Formula I as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

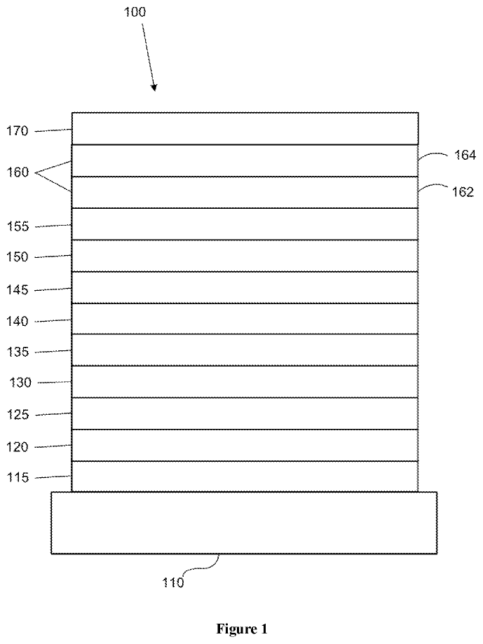

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

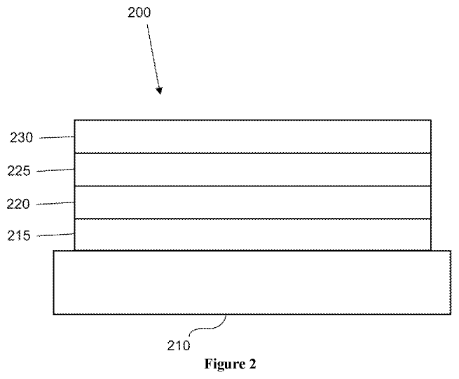

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve outcoupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP, also referred to as organic vapor jet deposition (OVJD)), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18 degrees C. to 30 degrees C., and more preferably at room temperature (20-25° C.), but could be used outside this temperature range, for example, from −40 degree C. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as a phosphorescent sensitizer in an OLED where one or multiple layers in the OLED contains an acceptor in the form of one or more fluorescent and/or delayed fluorescence emitters. In some embodiments, the compound can be used as one component of an exciplex to be used as a sensitizer. As a phosphorescent sensitizer, the compound must be capable of energy transfer to the acceptor and the acceptor will emit the energy or further transfer energy to a final emitter. The acceptor concentrations can range from 0.001% to 100%. The acceptor could be in either the same layer as the phosphorescent sensitizer or in one or more different layers. In some embodiments, the acceptor is a TADF emitter. In some embodiments, the acceptor is a fluorescent emitter. In some embodiments, the emission can arise from any or all of the sensitizer, acceptor, and final emitter.

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### D. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

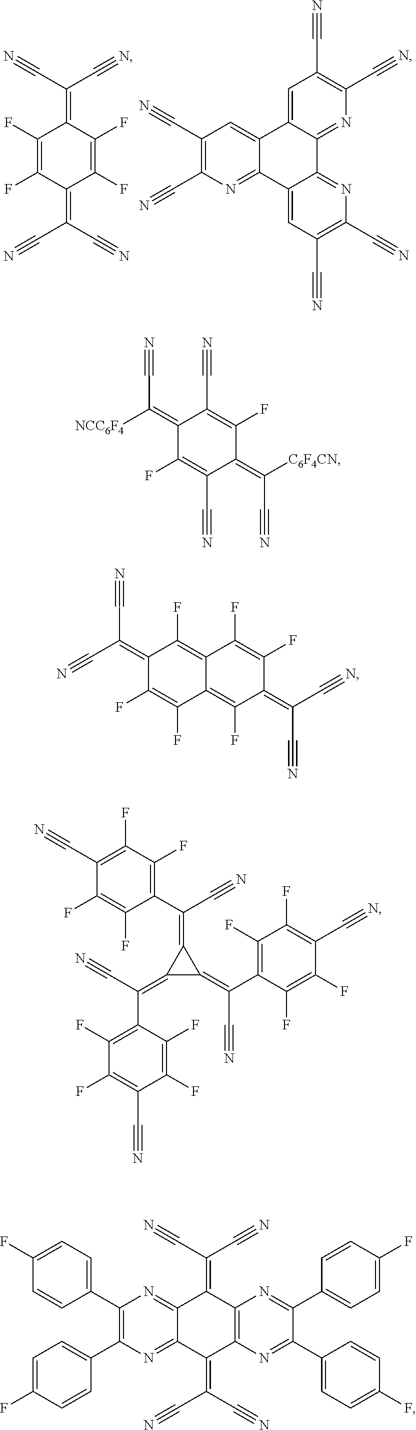

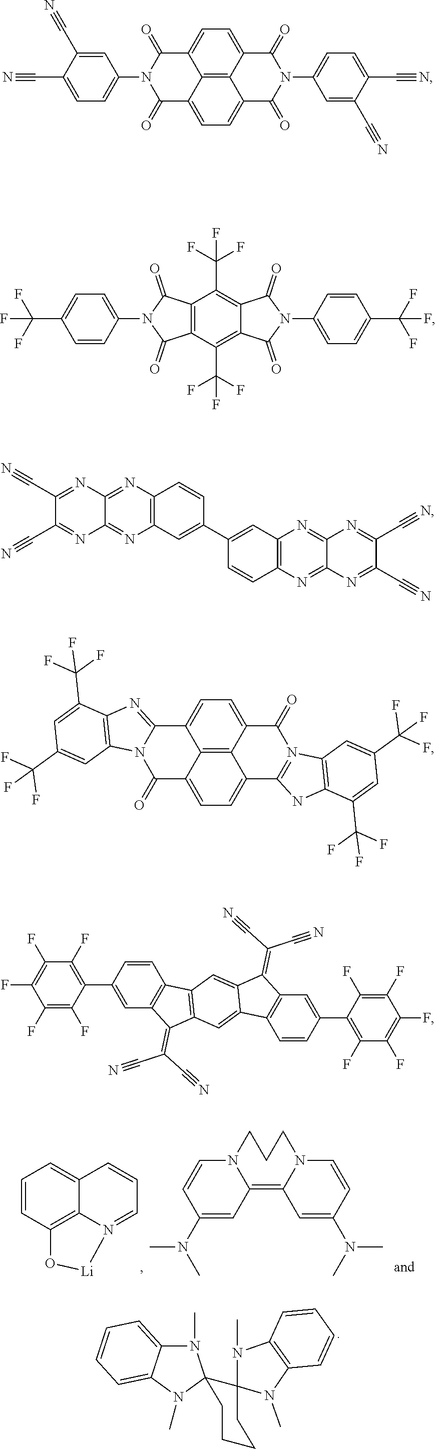

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

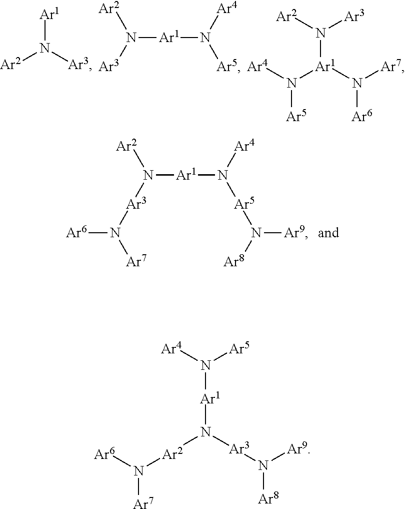

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

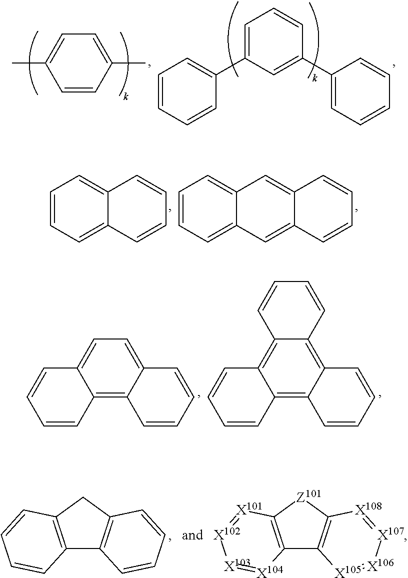

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

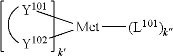

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Ser. No. 06/517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

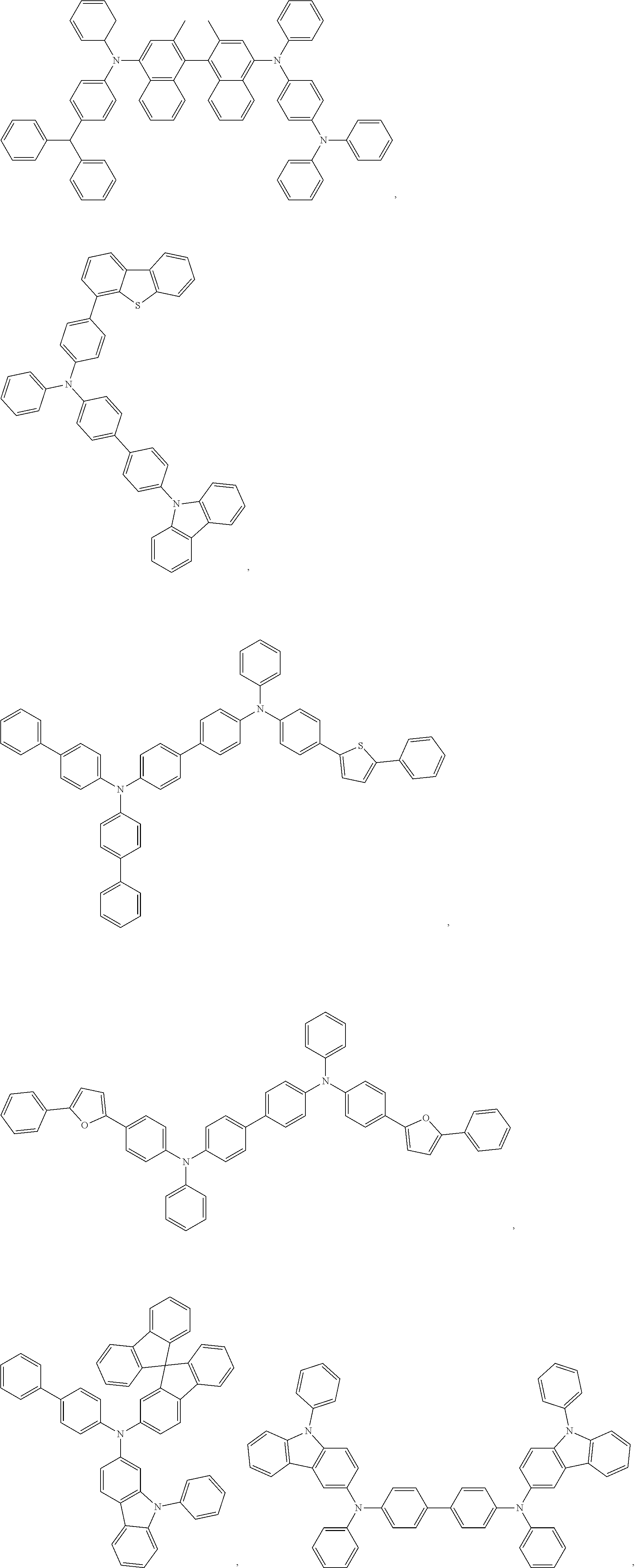

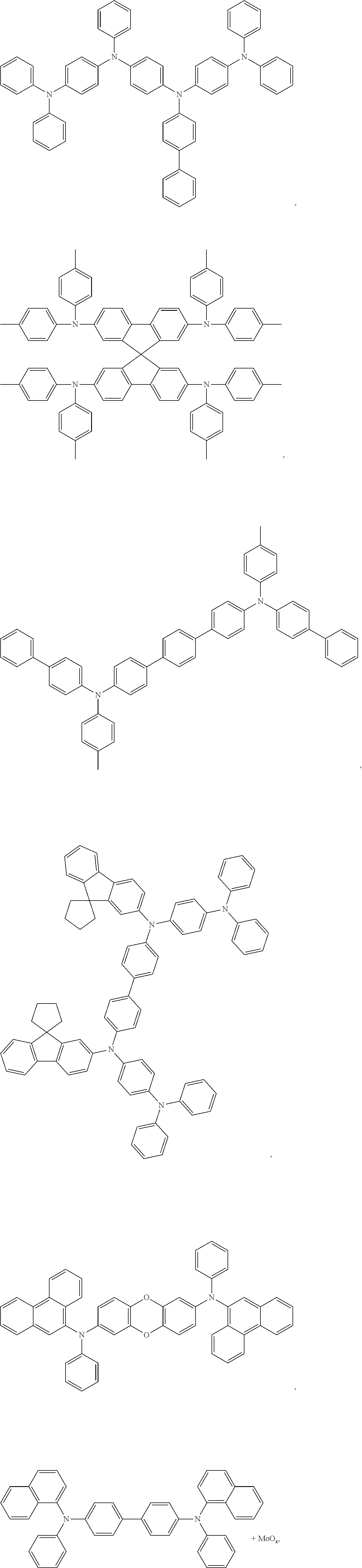

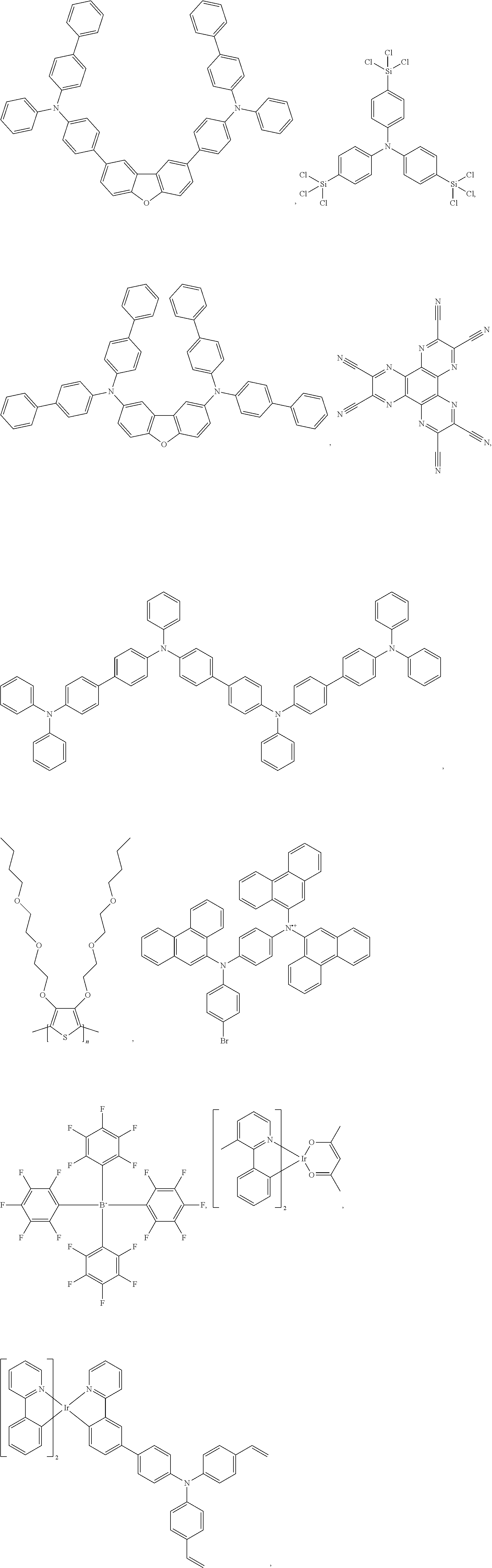

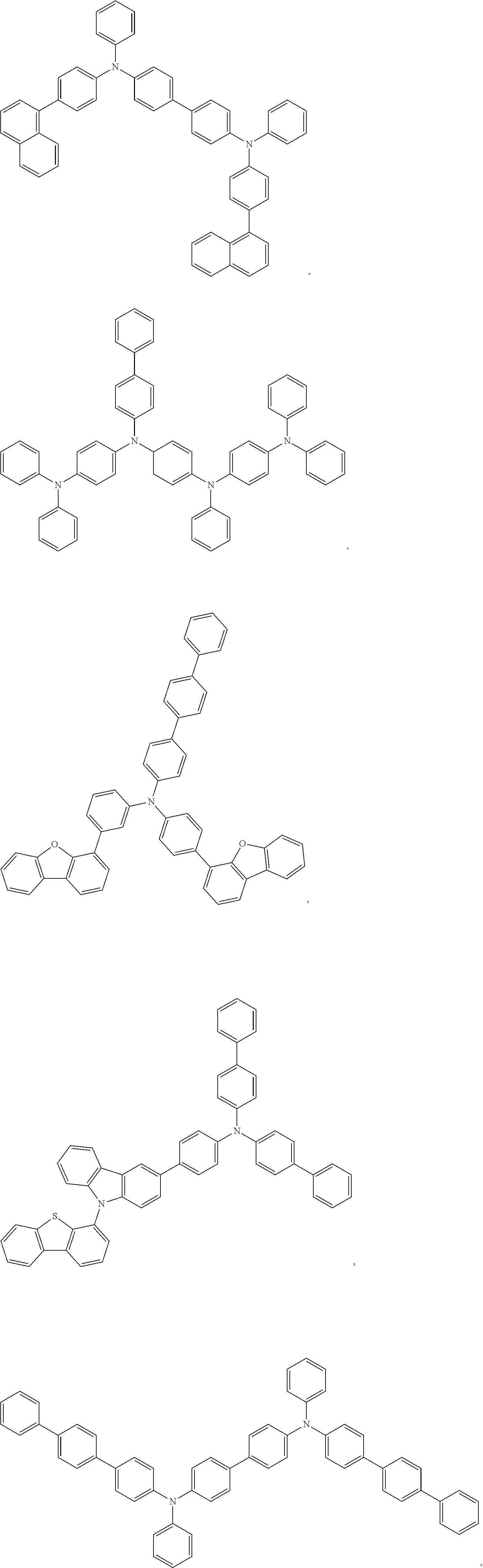

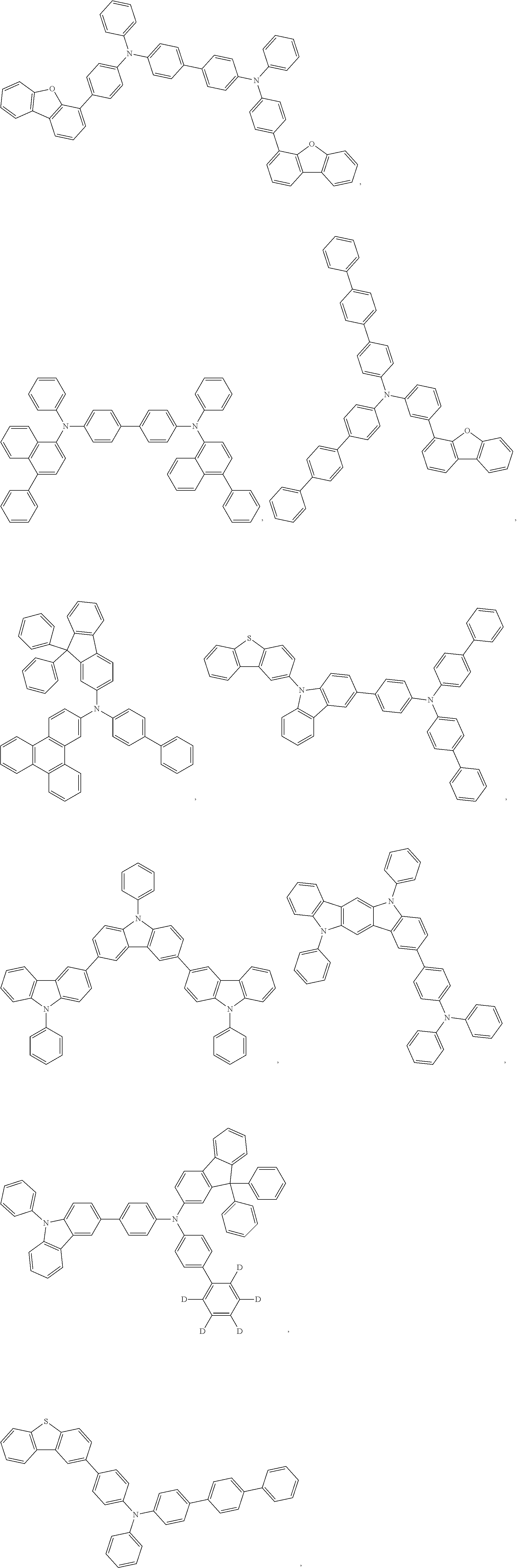

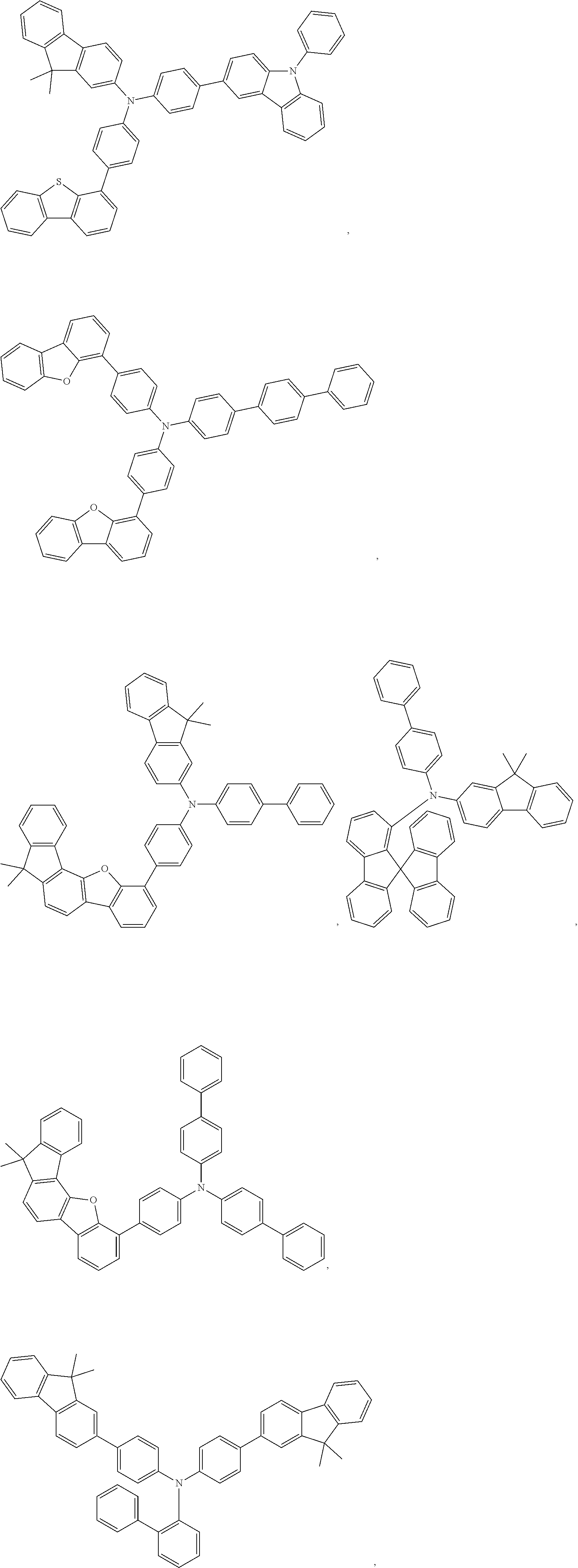

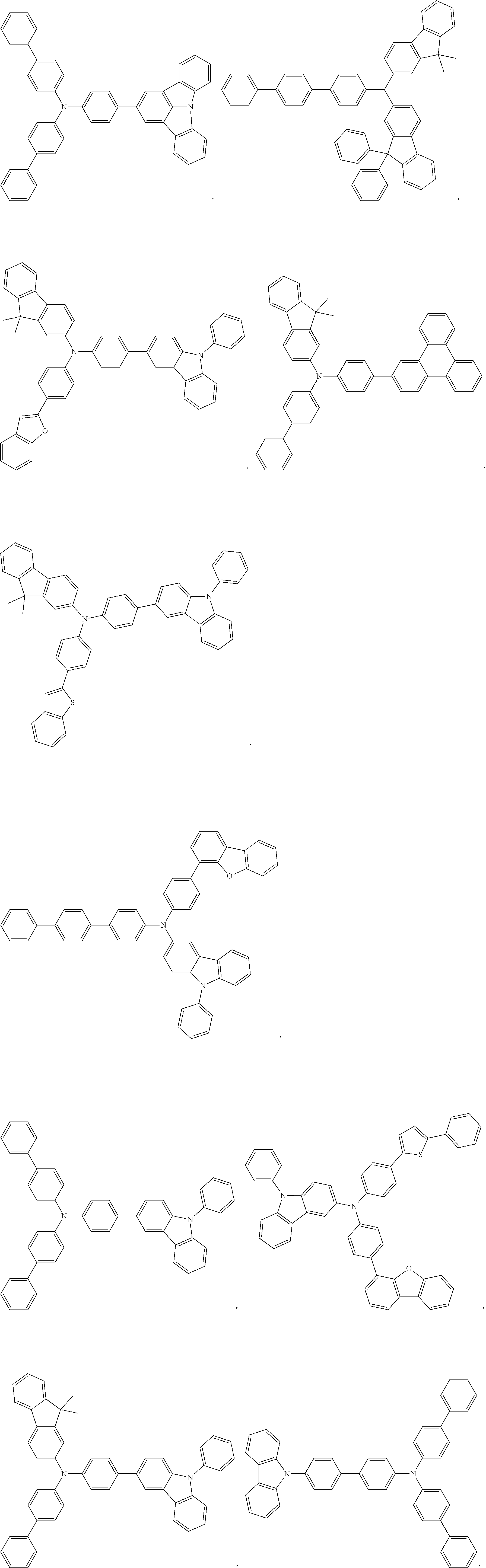

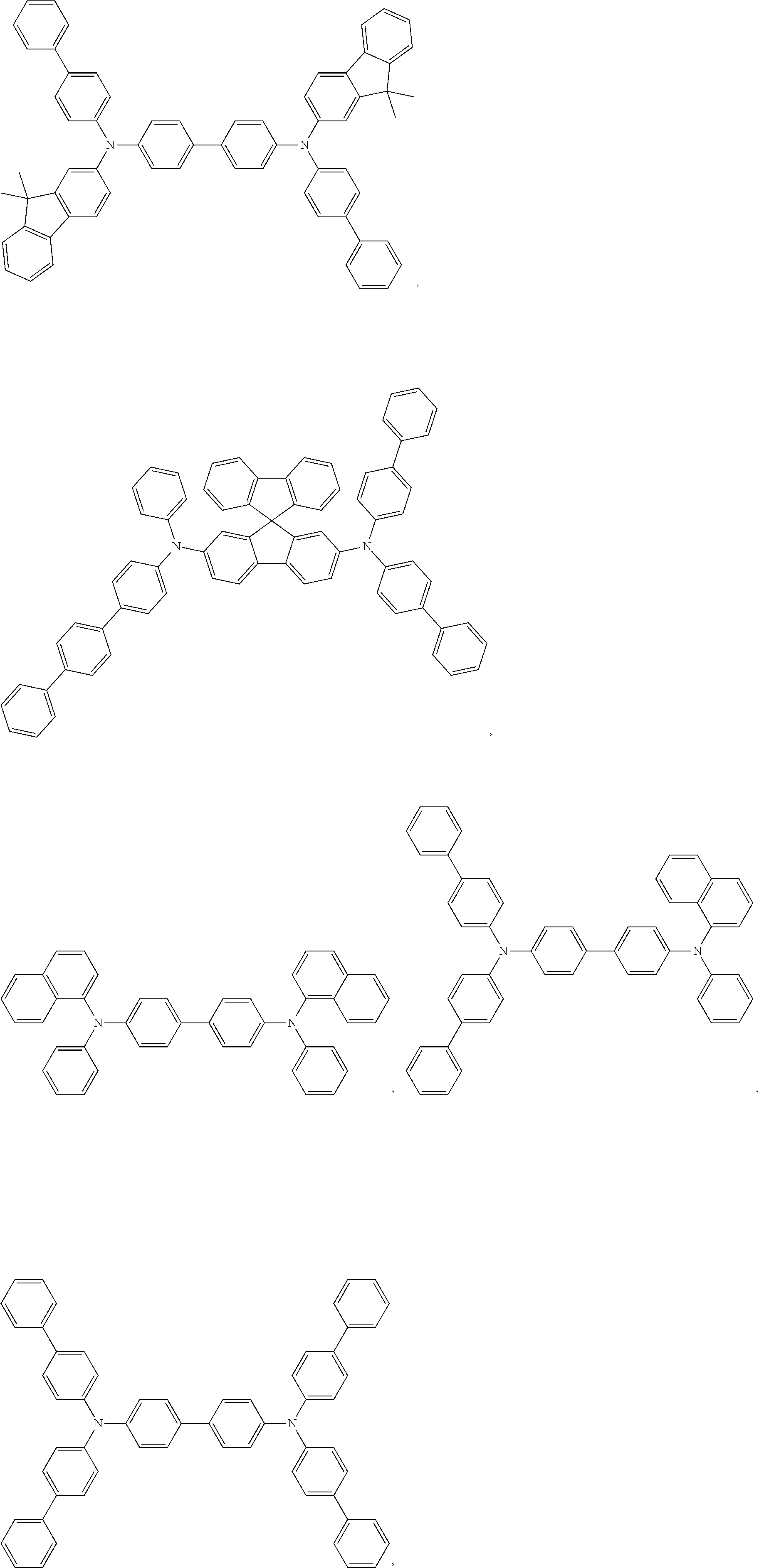

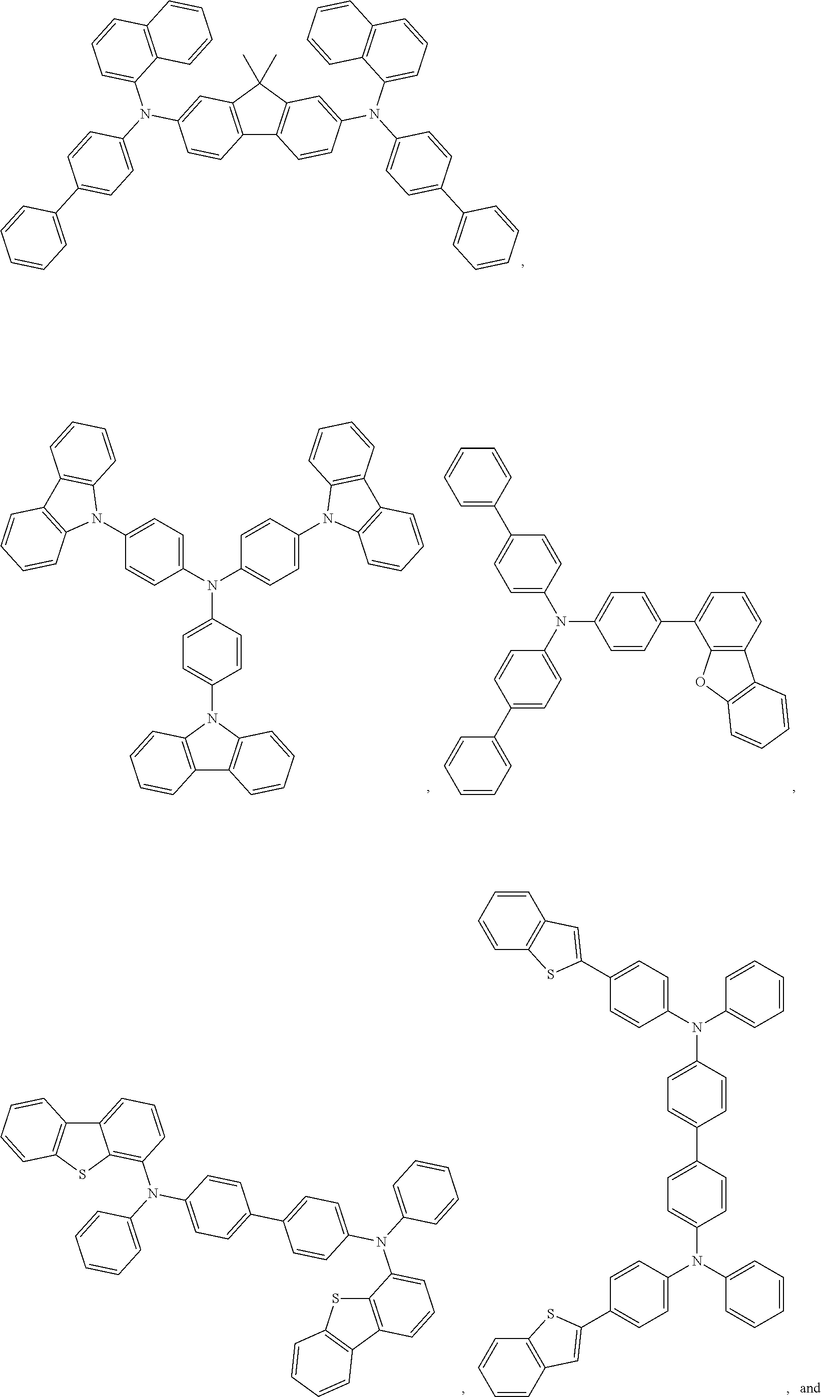 [SMILES: CC1(C)c2cc(N(c3ccc(-c4ccccc4)cc3)c3cccc4ccccc34)ccc2-c2ccc(N(c3ccc(-c4ccccc4)cc3)c3cccc4ccccc34)cc21 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2ccc(N(c3ccc(-c4ccccc4)cc3)c3ccc(-c4cccc5c4oc4ccccc45)cc3)cc2)cc1 ; c1ccc(N(c2ccc(-c3ccc(N(c4ccccc4)c4cccc5c4sc4ccccc45)cc3)cc2)c2cccc3c2sc2ccccc23)cc1 ; c1ccc(N(c2ccc(-c3ccc(N(c4ccccc4)c4ccc(-c5cc6ccccc6s5)cc4)cc3)cc2)c2ccc(-c3cc4ccccc4s3)cc2)cc1]

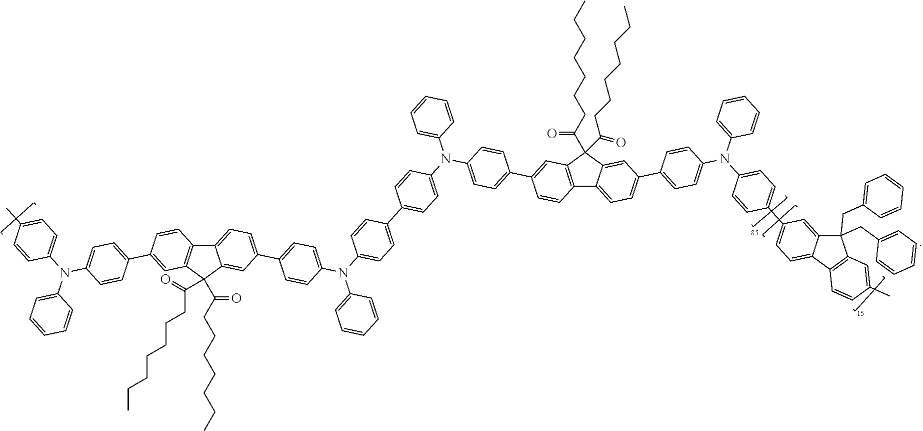

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### d) Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

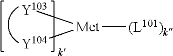

wherein Met is a metal; (Y¹⁰³-Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

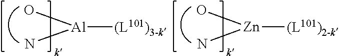

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

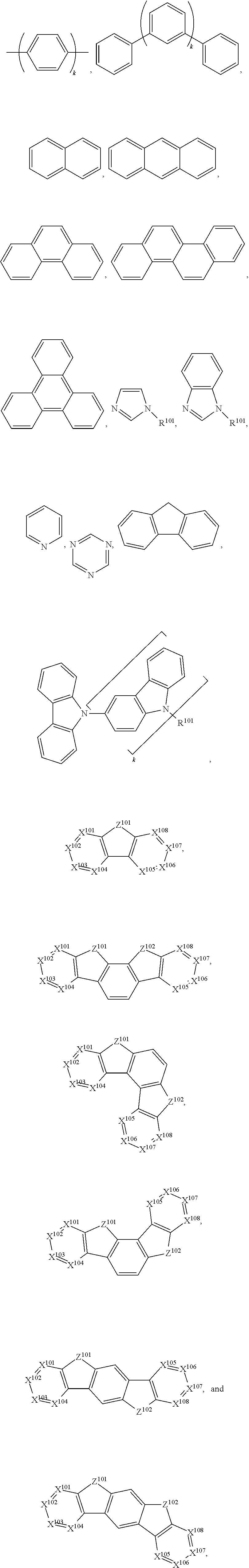

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

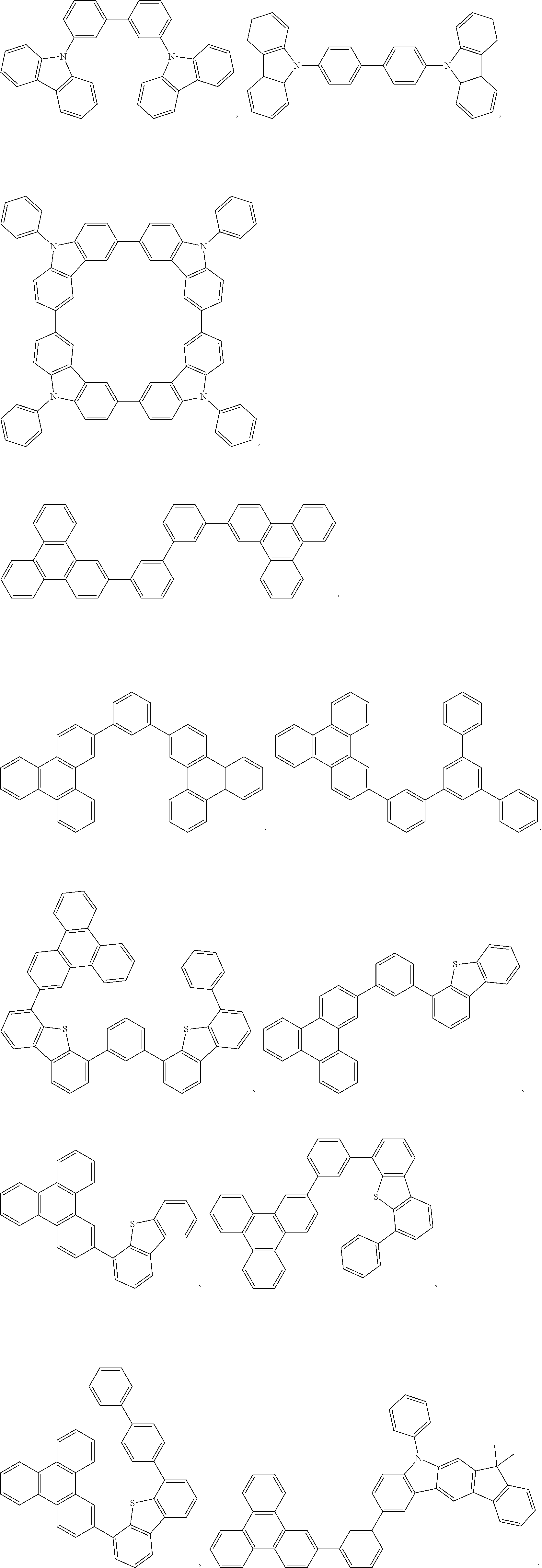

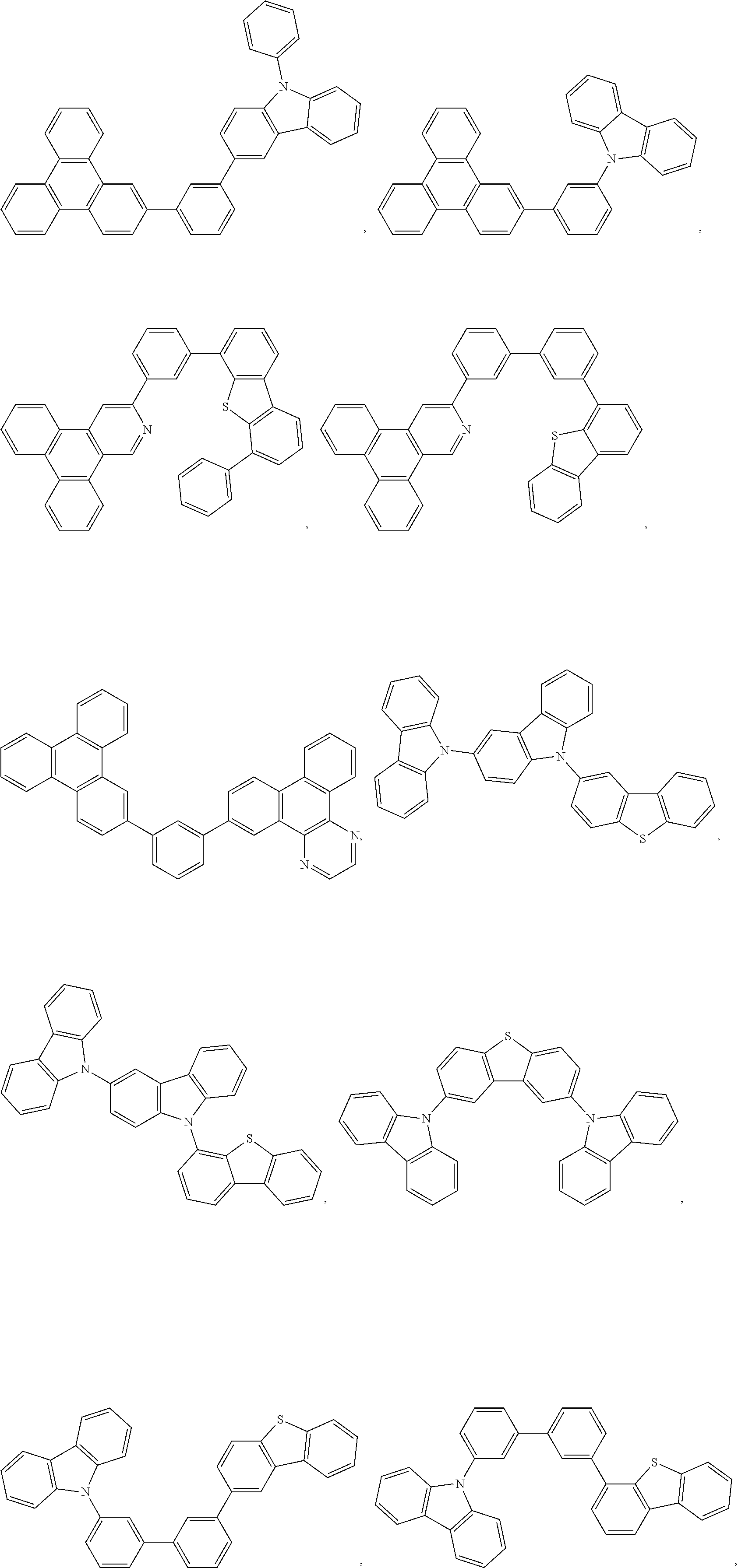

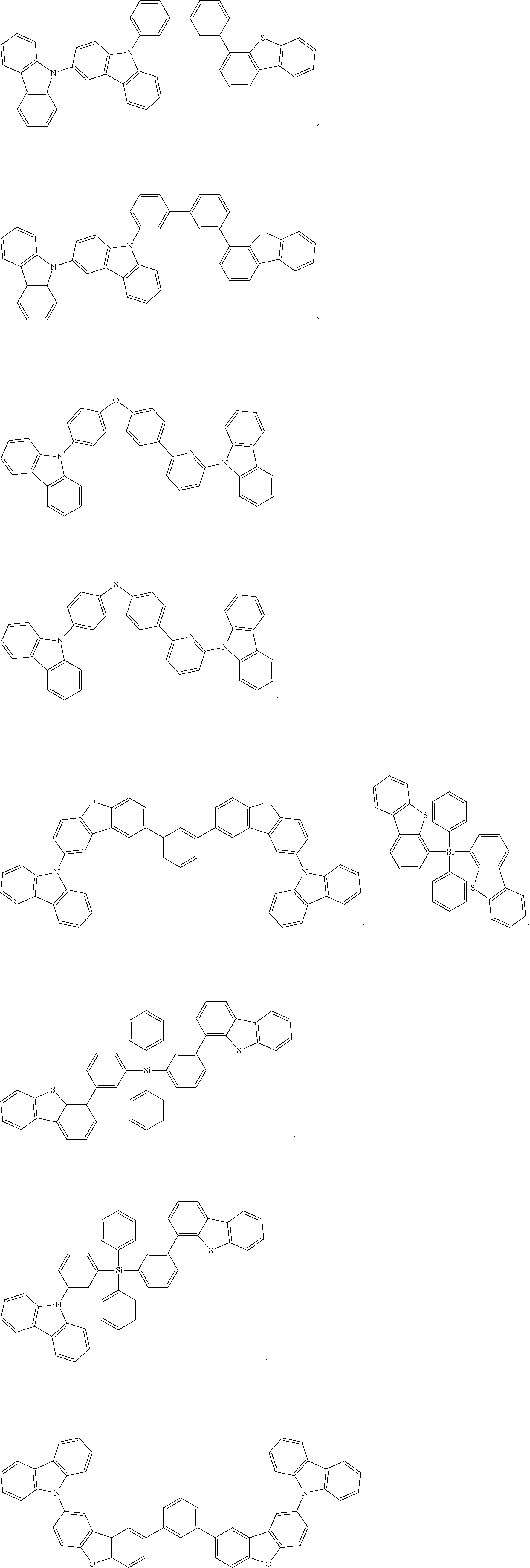

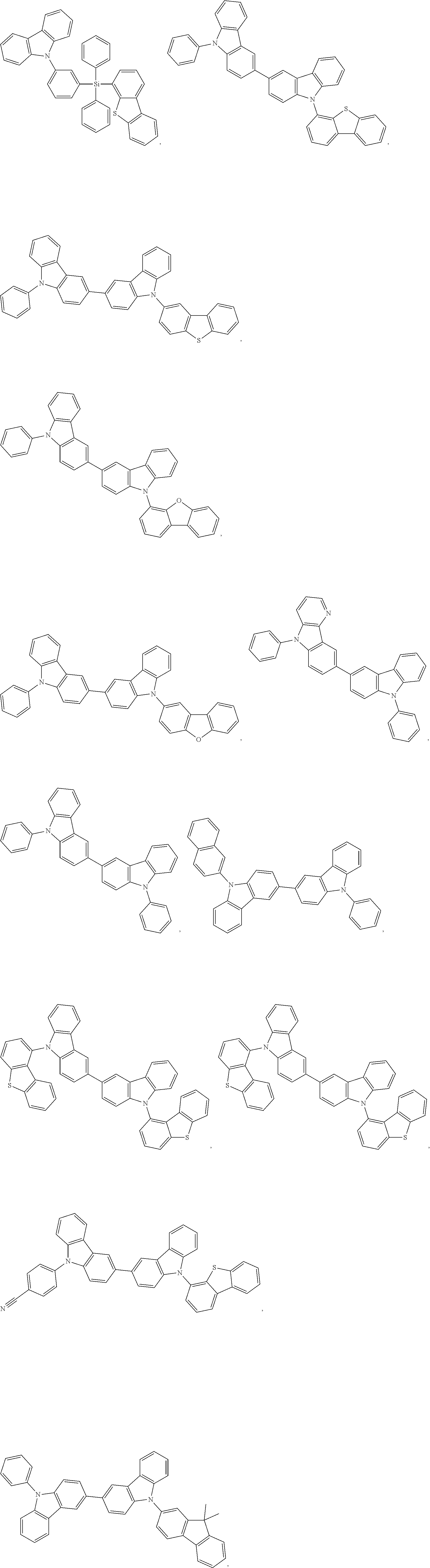

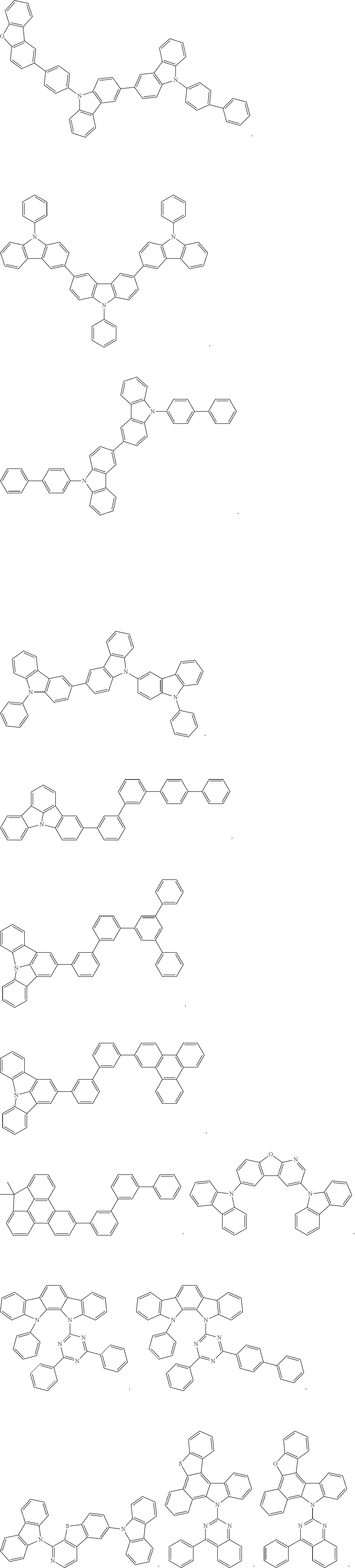

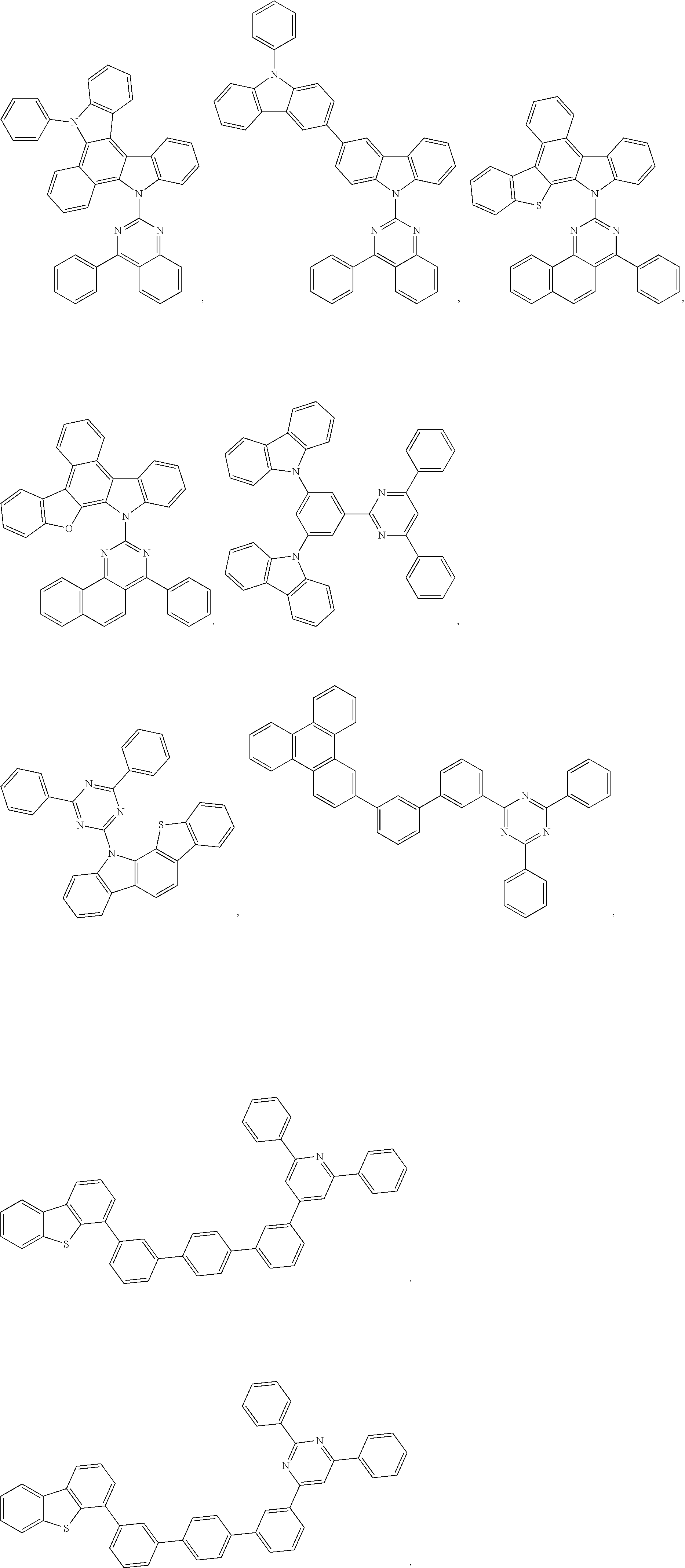

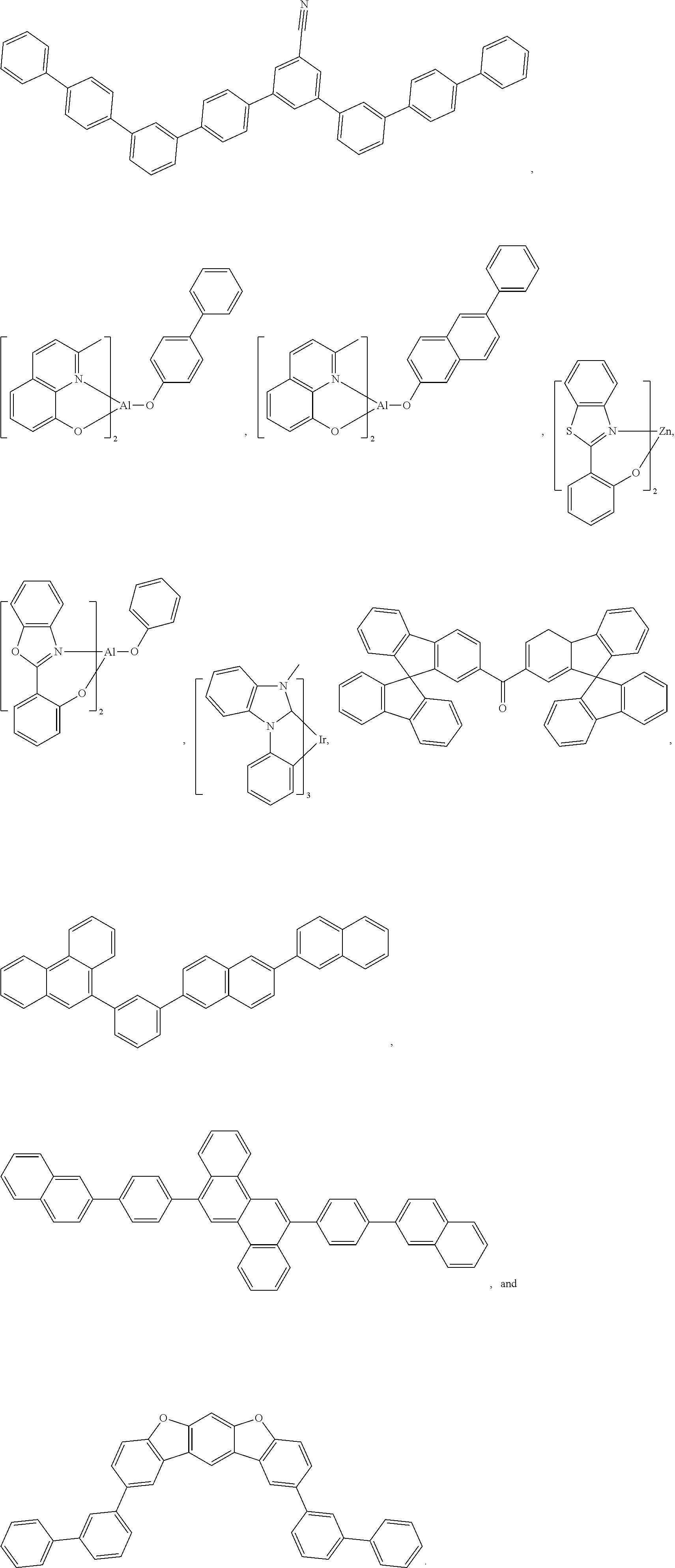

e) Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Ser. No. 06/699,599, U.S. Ser. No. 06/916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

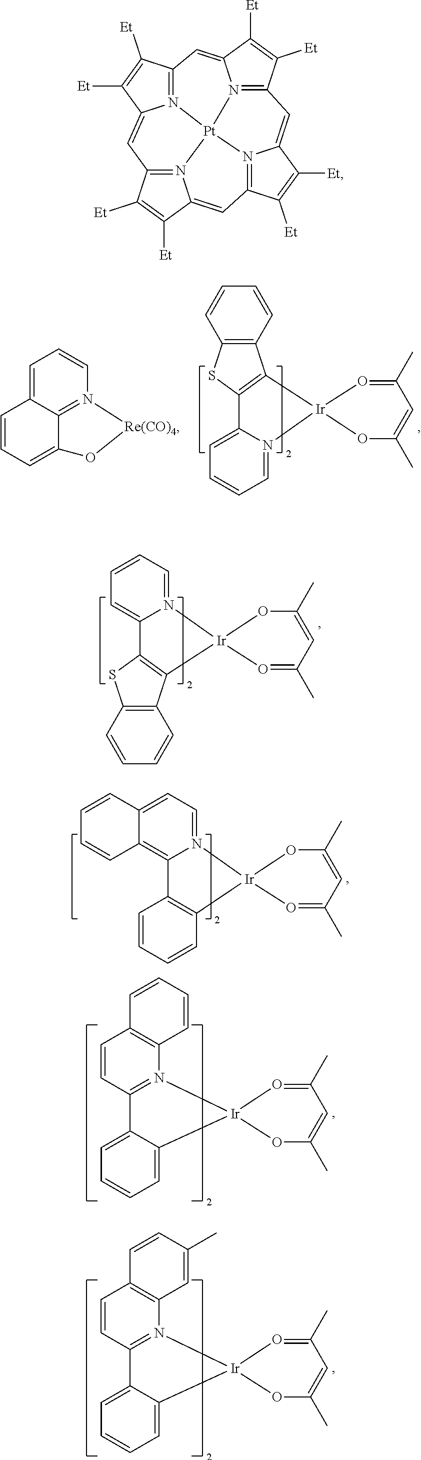

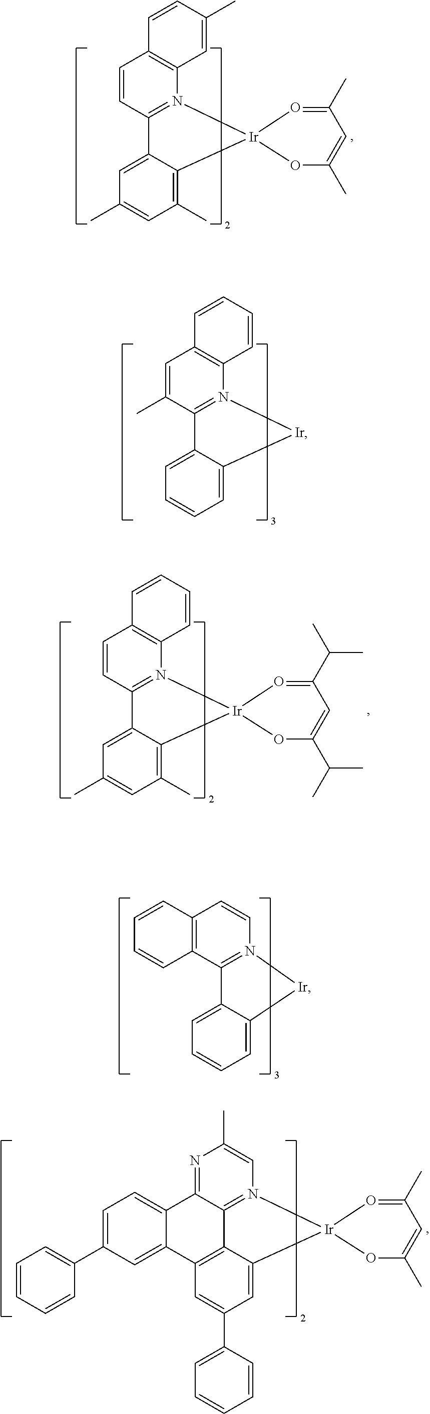

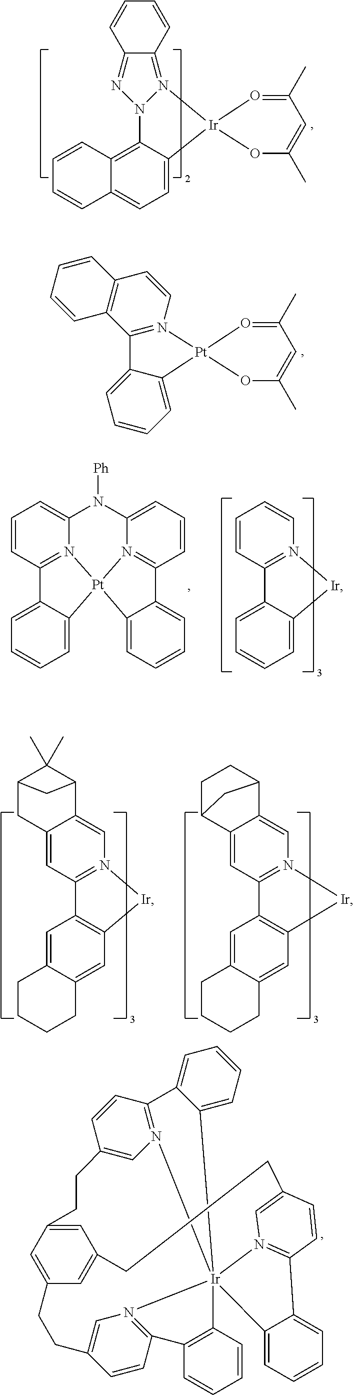

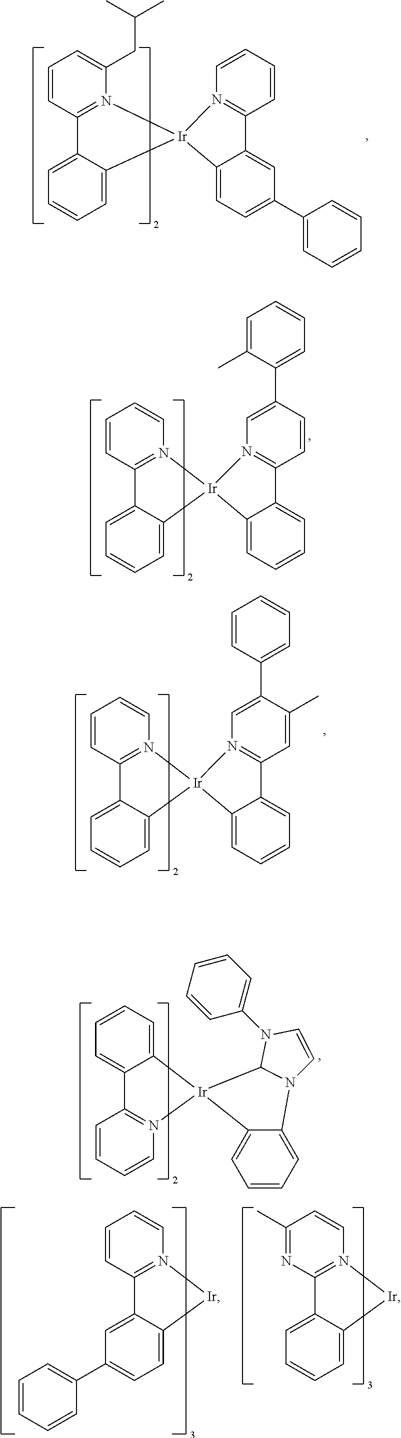

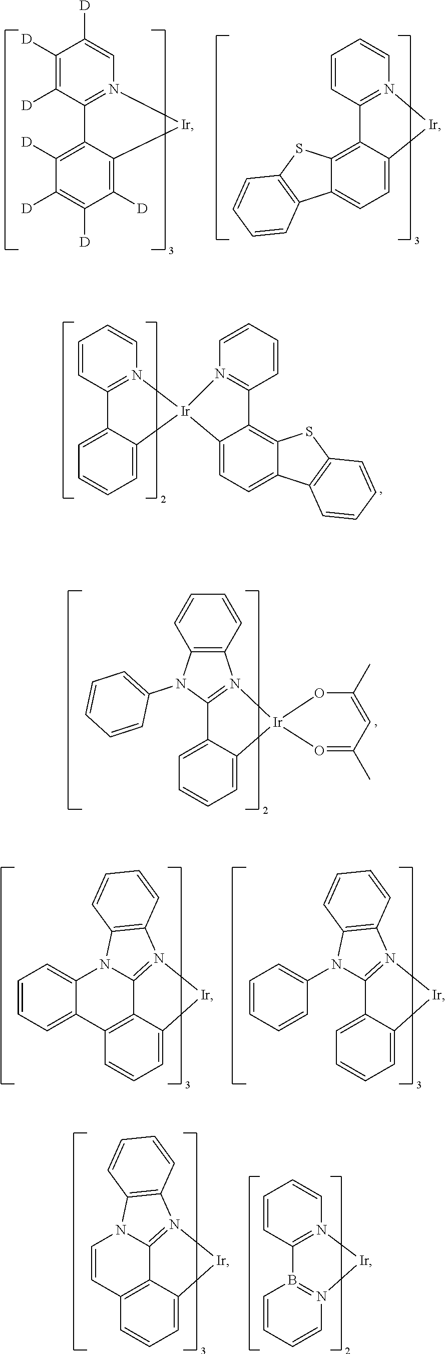

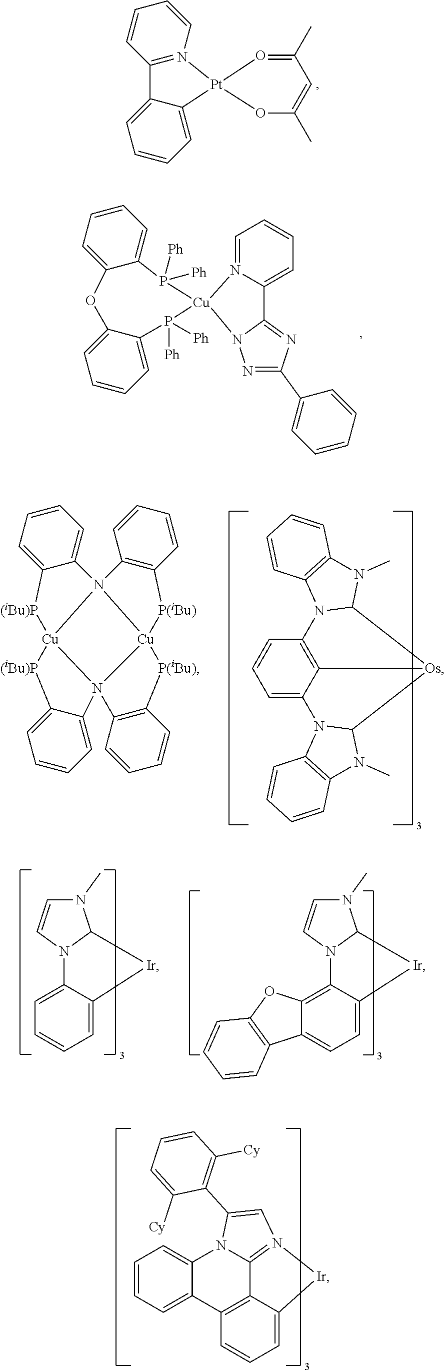

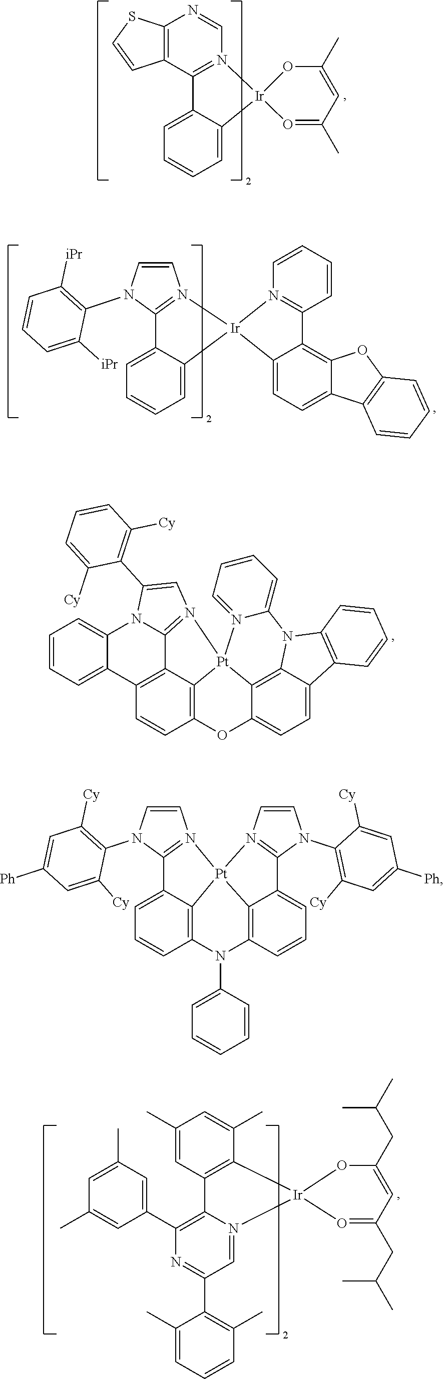

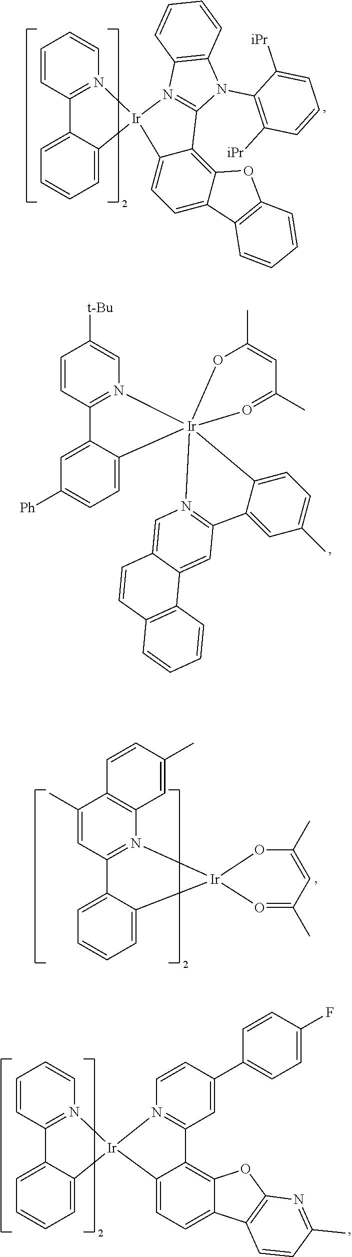

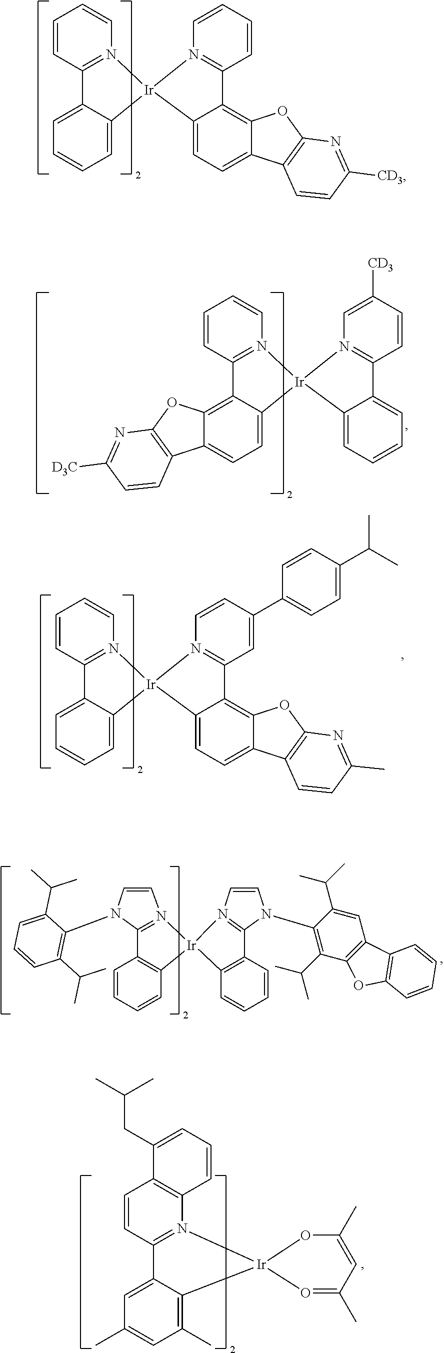

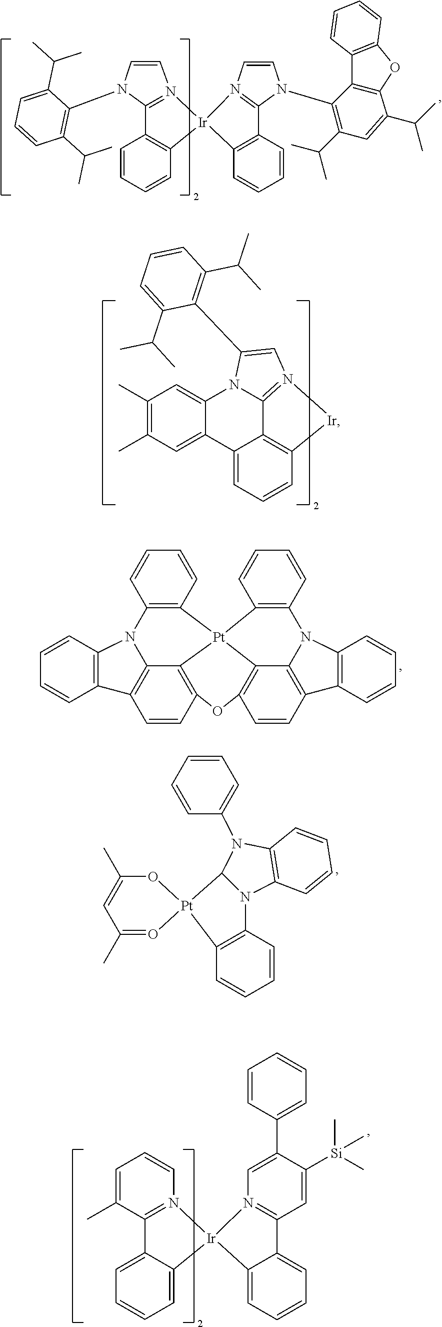

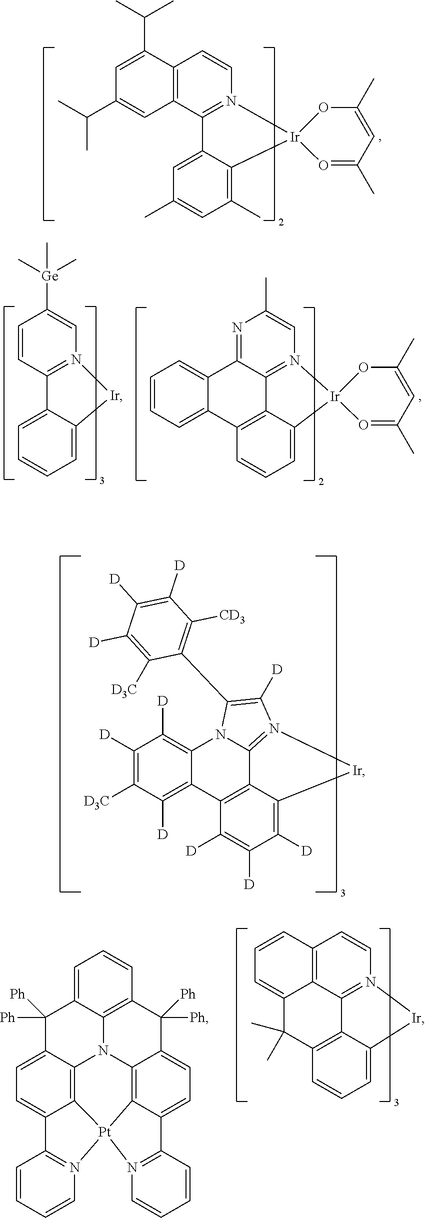

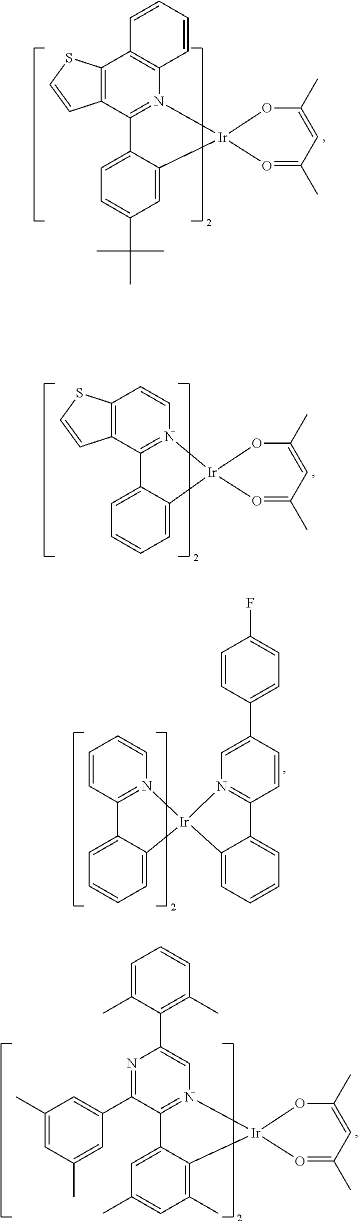

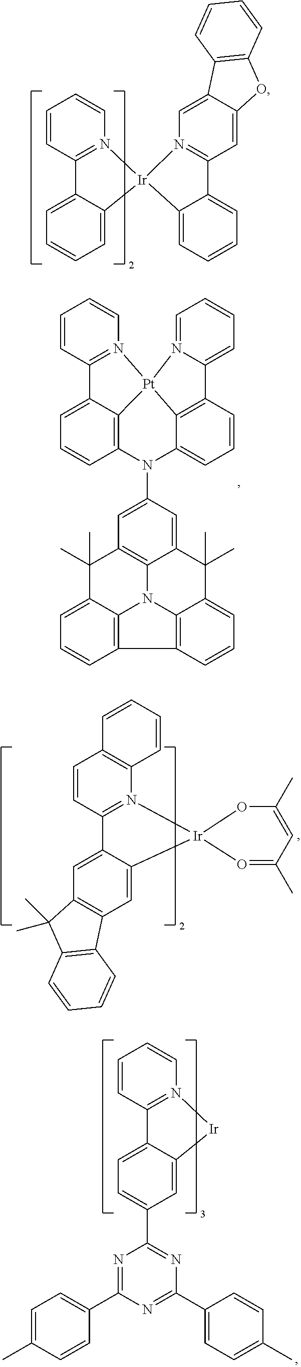

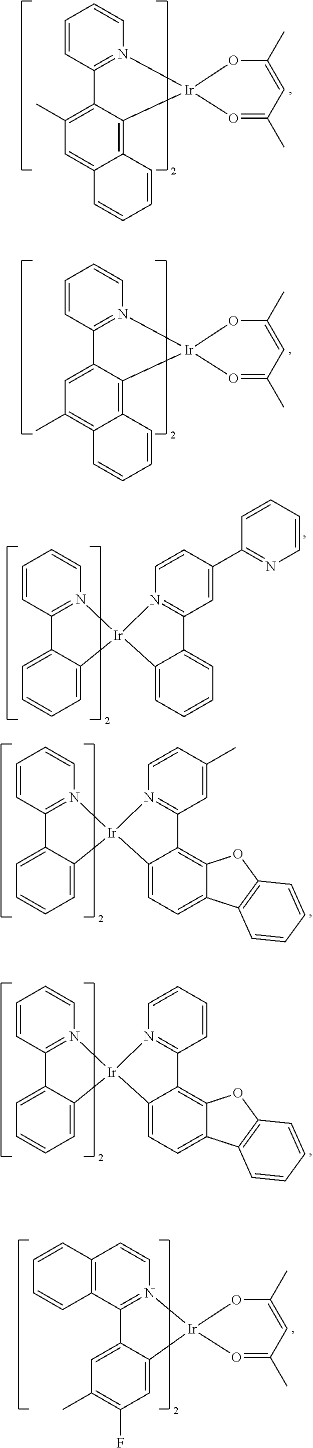

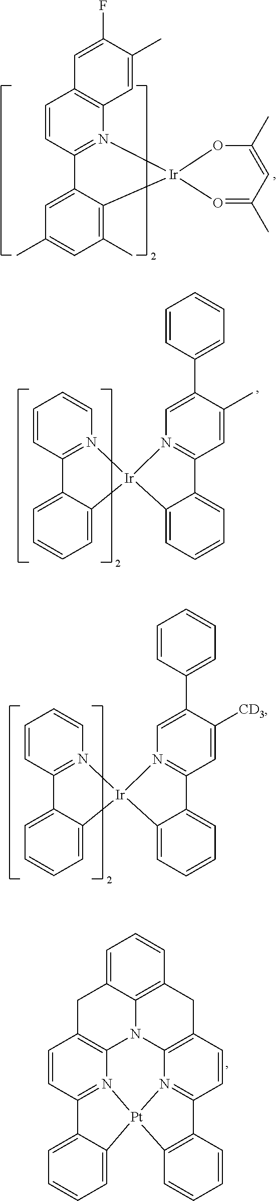

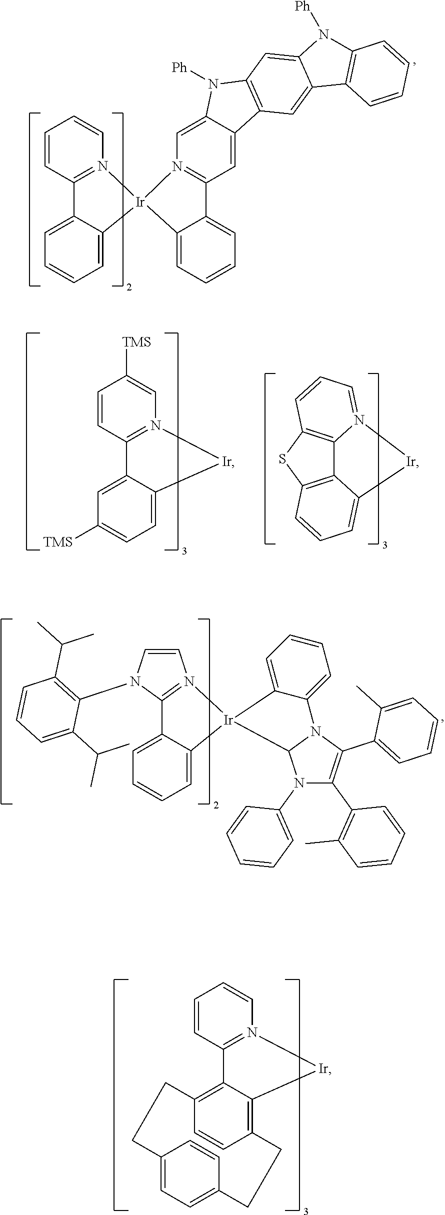

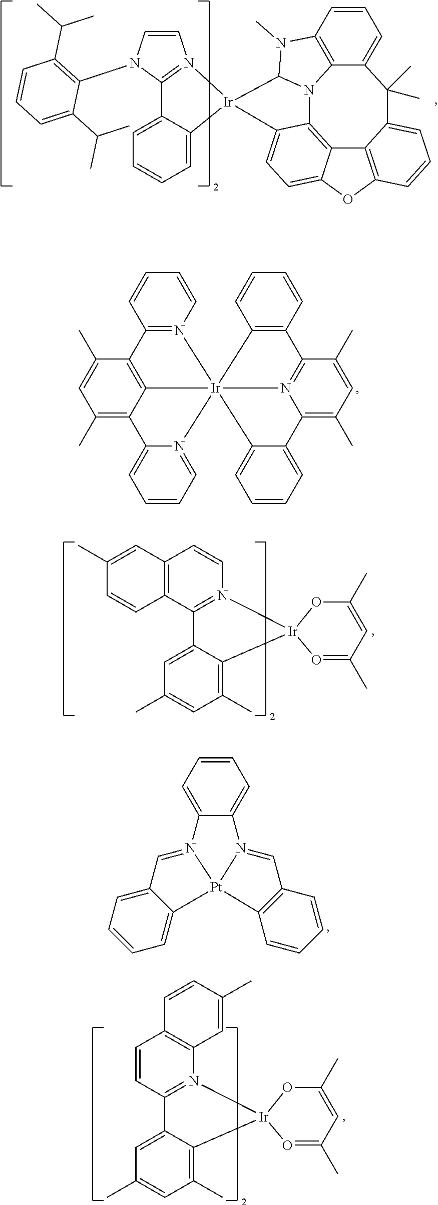

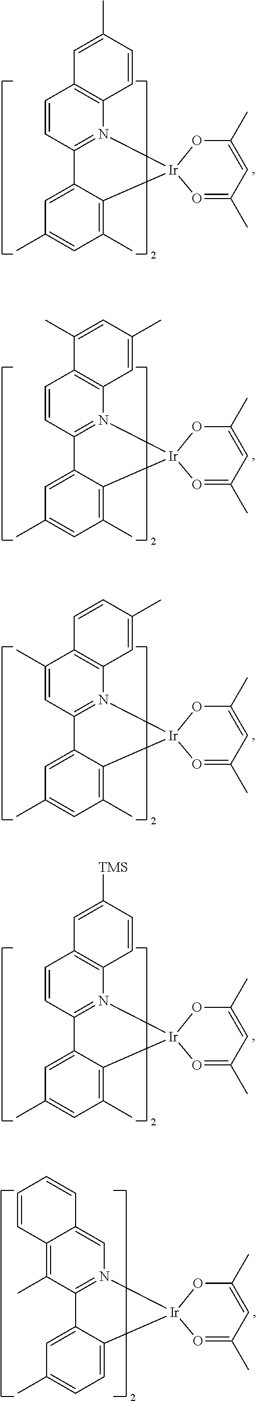

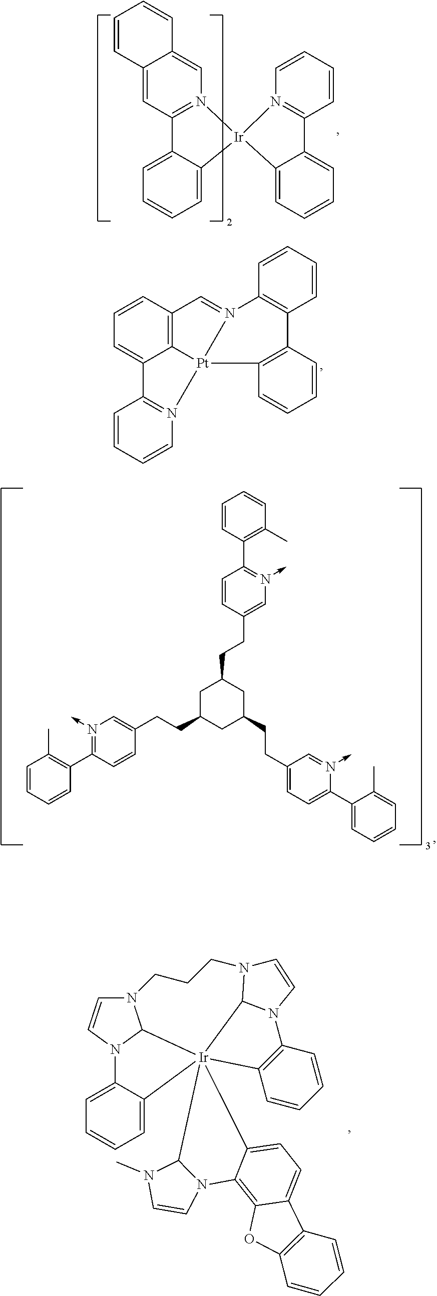

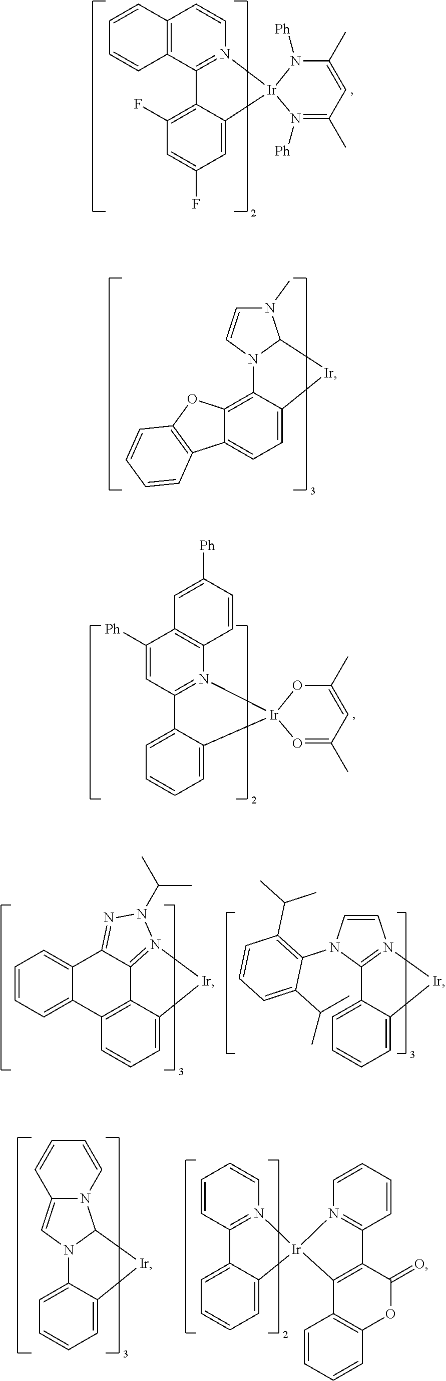

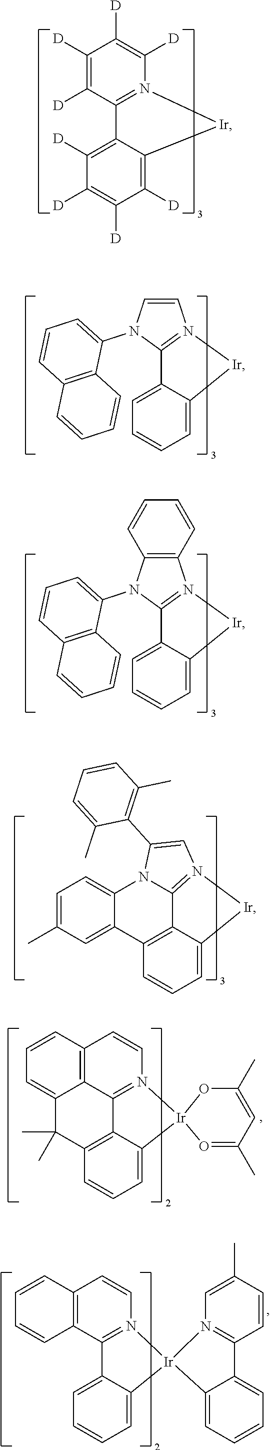

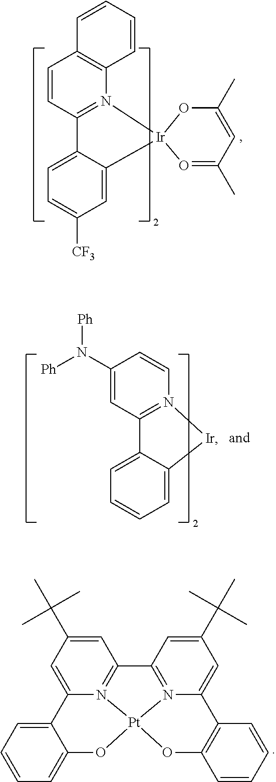

f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

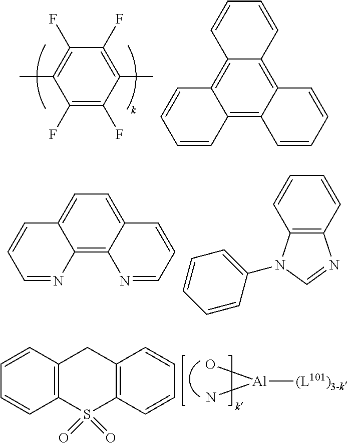

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

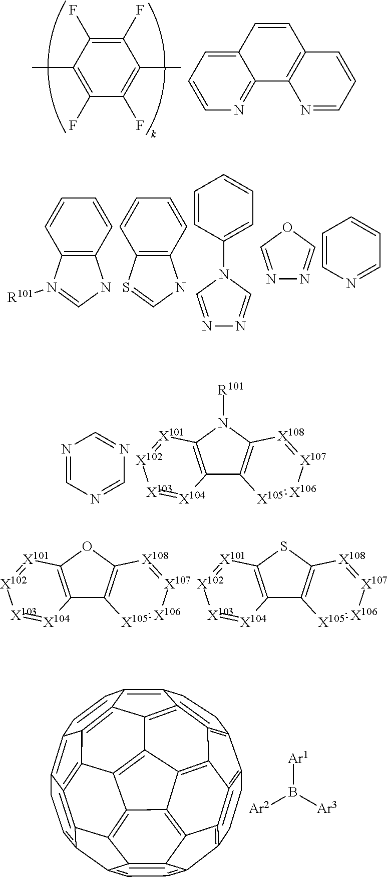

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

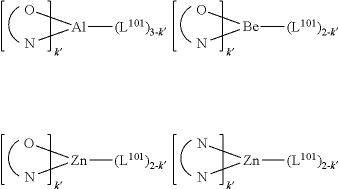

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

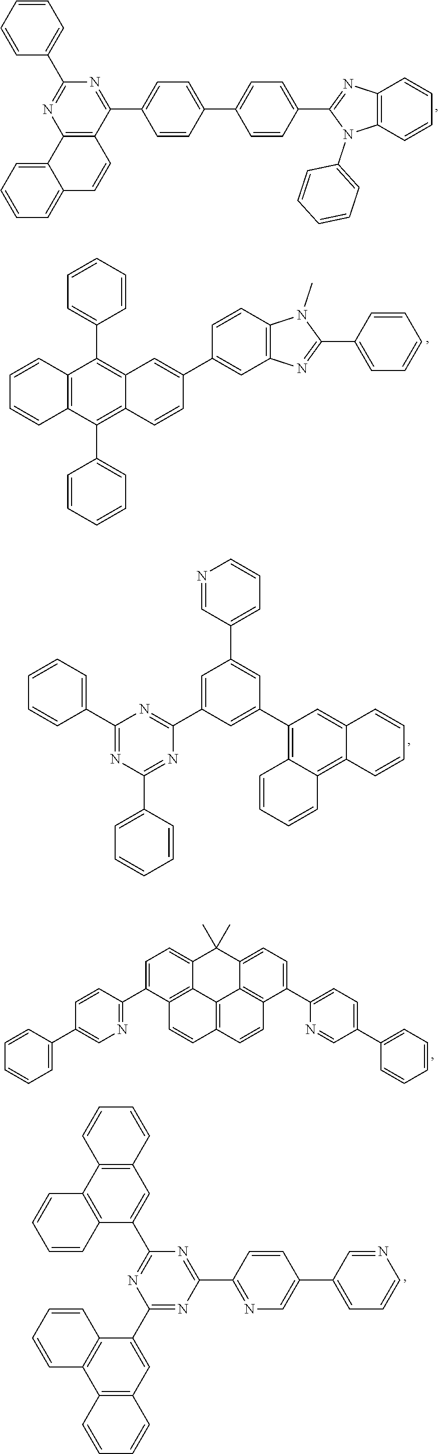 [SMILES: c1ccc(-c2nc(-c3ccc(-c4ccc(-c5nc6ccccc6n5-c5ccccc5)cc4)cc3)c3ccc4ccccc4c3n2)cc1 ; Cn1c(-c2ccccc2)nc2cc(-c3ccc4c(-c5ccccc5)c5ccccc5c(-c5ccccc5)c4c3)ccc21 ; c1ccc(-c2nc(-c3ccccc3)nc(-c3cc(-c4cccnc4)cc(-c4cc5ccccc5c5ccccc45)c3)n2)cc1 ; CC1(C)c2ccc(-c3ccc(-c4ccccc4)cn3)c3ccc4ccc5c(-c6ccc(-c7ccccc7)cn6)ccc1c5c4c23 ; c1cncc(-c2ccc(-c3nc(-c4cc5ccccc5c5ccccc45)nc(-c4cc5ccccc5c5ccccc45)n3)nc2)c1]

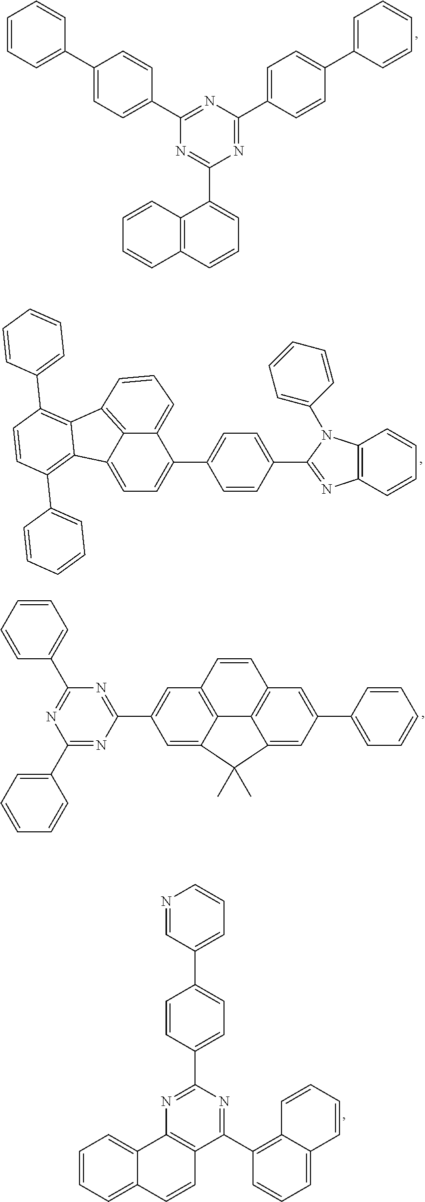

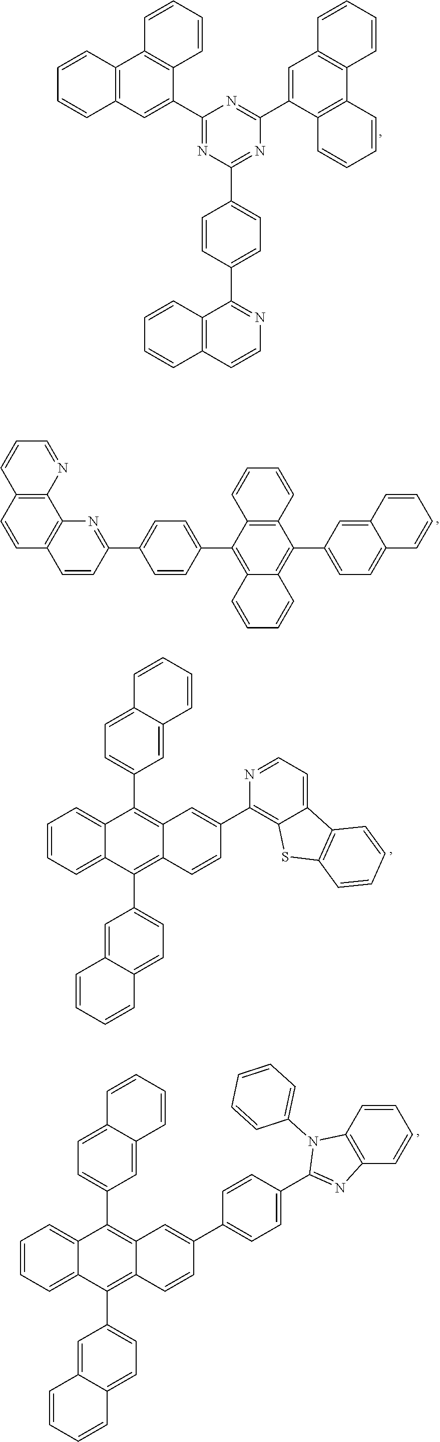 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc2cc(-c3c4ccccc4c(-c4ccc(-c5ccc6ccc7cccnc7c6n5)cc4)c4ccccc34)ccc2c1 ; c1ccc2cc(-c3c4ccccc4c(-c4ccc5ccccc5c4)c4cc(-c5nccc6c5sc5ccccc56)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

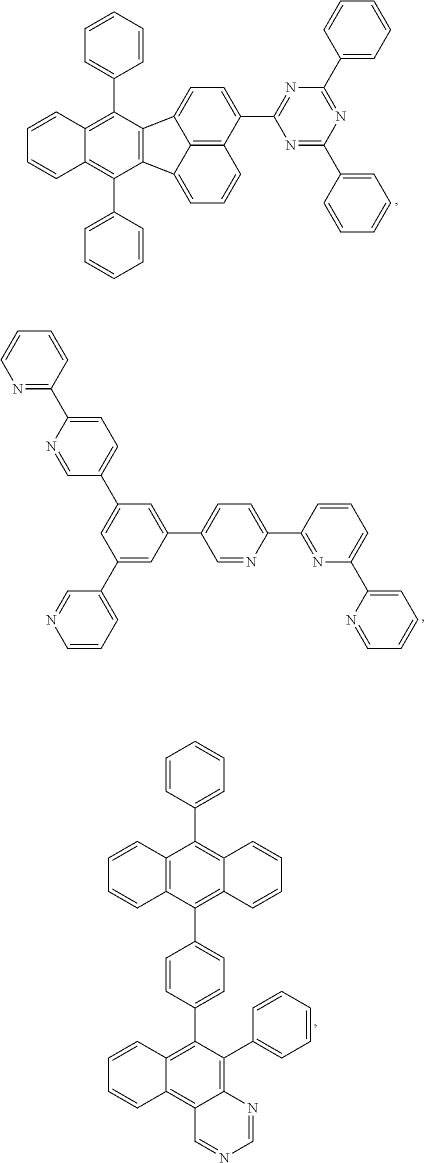 [SMILES: c1ccc(-c2nc(-c3ccccc3)nc(-c3ccc4c5c(cccc35)-c3c-4c(-c4ccccc4)c4ccccc4c3-c3ccccc3)n2)cc1 ; c1ccc(-c2ccc(-c3cc(-c4cccnc4)cc(-c4ccc(-c5cccc(-c6ccccn6)n5)nc4)c3)cn2)nc1 ; c1ccc(-c2c3ccccc3c(-c3ccc(-c4c(-c5ccccc5)c5ncncc5c5ccccc45)cc3)c3ccccc23)cc1]

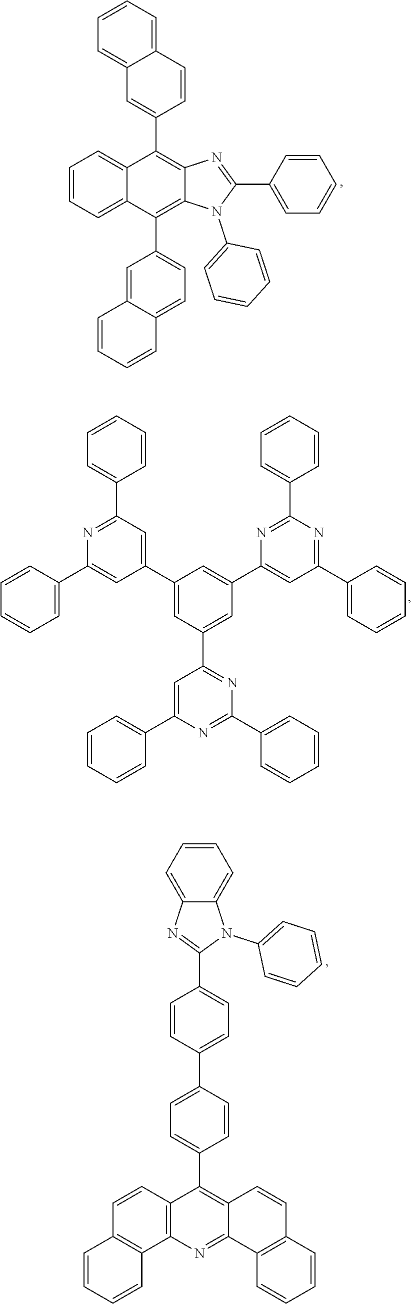 [SMILES: c1ccc(-c2nc3c(-c4ccc5ccccc5c4)c4ccccc4c(-c4ccc5ccccc5c4)c3n2-c2ccccc2)cc1 ; c1ccc(-c2cc(-c3cc(-c4cc(-c5ccccc5)nc(-c5ccccc5)n4)cc(-c4cc(-c5ccccc5)nc(-c5ccccc5)n4)c3)cc(-c3ccccc3)n2)cc1 ; c1ccc(-n2c(-c3ccc(-c4ccc(-c5c6ccc7ccccc7c6nc6c5ccc5ccccc56)cc4)cc3)nc3ccccc32)cc1]

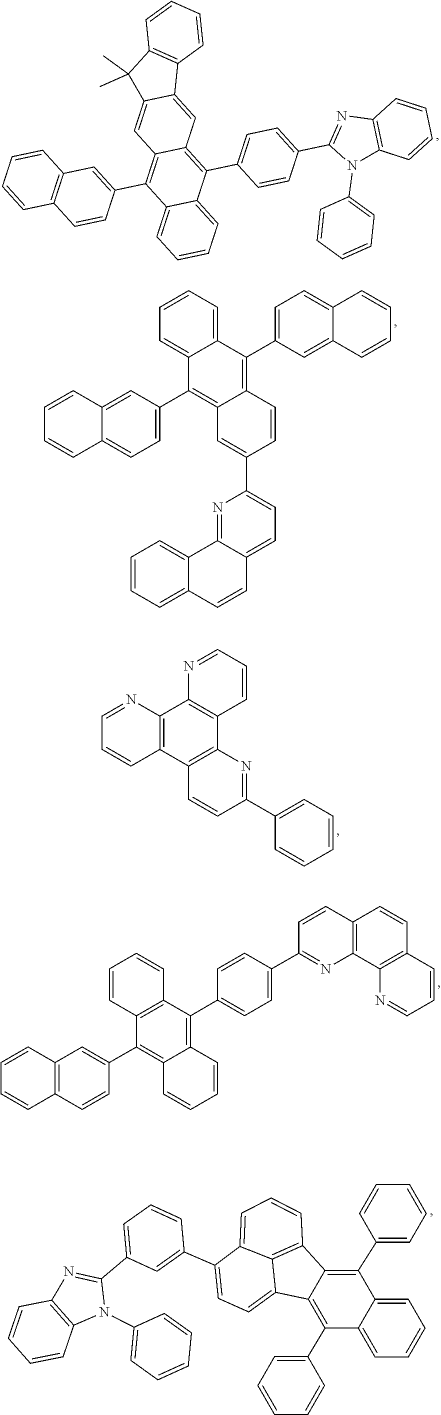

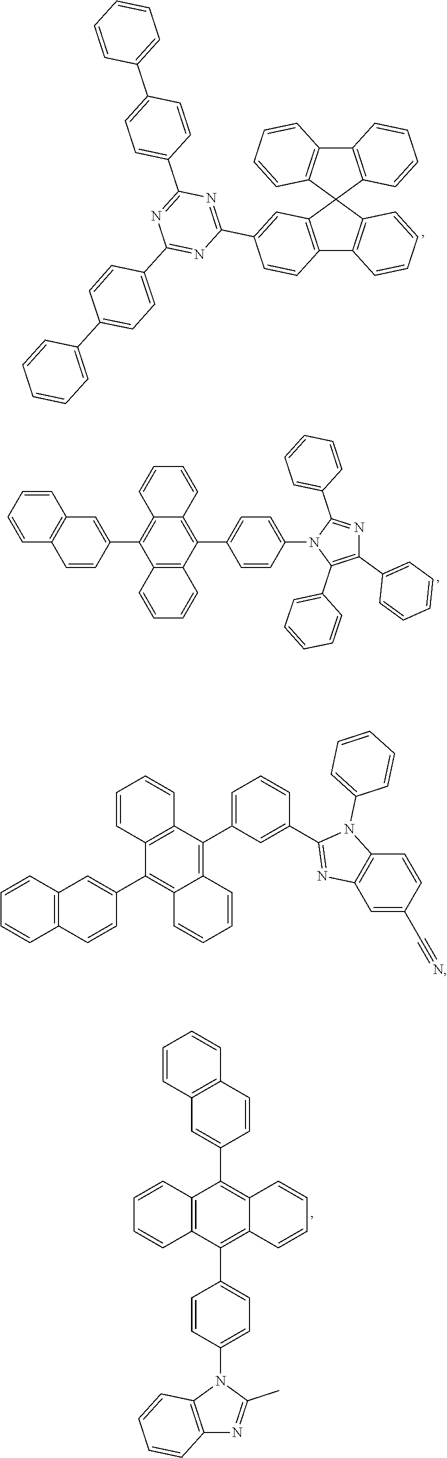 [SMILES: c1ccc(-c2ccc(-c3nc(-c4ccc(-c5ccccc5)cc4)nc(-c4ccc5c(c4)C4(c6ccccc6-c6ccccc64)c4ccccc4-5)n3)cc2)cc1 ; c1ccc(-c2nc(-c3ccccc3)n(-c3ccc(-c4c5ccccc5c(-c5ccc6ccccc6c5)c5ccccc45)cc3)c2-c2ccccc2)cc1 ; N#Cc1ccc2c(c1)nc(-c1cccc(-c3c4ccccc4c(-c4ccc5ccccc5c4)c4ccccc34)c1)n2-c1ccccc1 ; Cc1nc2ccccc2n1-c1ccc(-c2c3ccccc3c(-c3ccc4ccccc4c3)c3ccccc23)cc1]

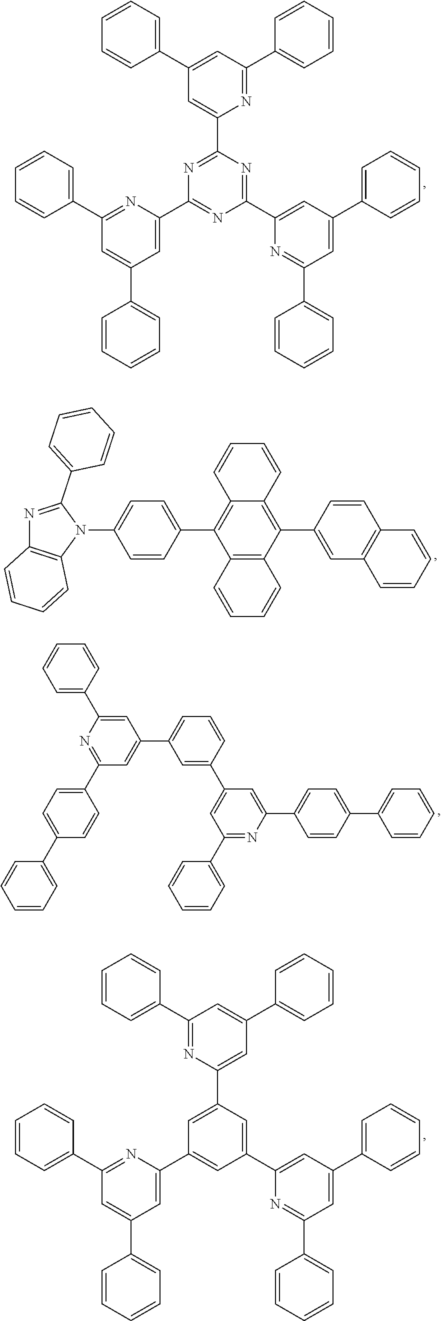

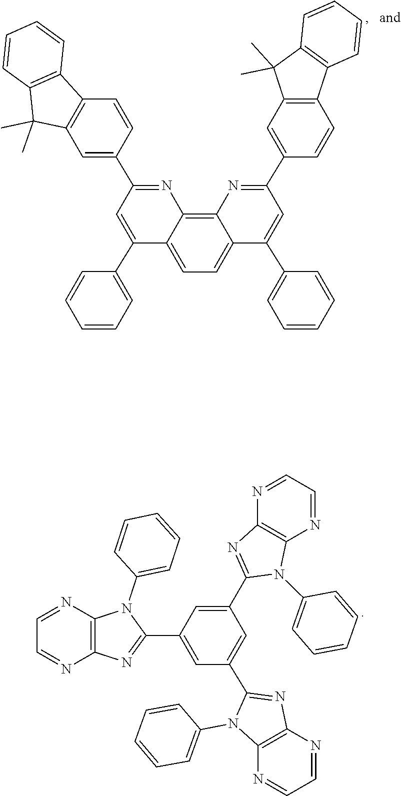 [SMILES: CC1(C)c2ccccc2-c2ccc(-c3cc(-c4ccccc4)c4ccc5c(-c6ccccc6)cc(-c6ccc7c(c6)C(C)(C)c6ccccc6-7)nc5c4n3)cc21 ; c1ccc(-n2c(-c3cc(-c4nc5nccnc5n4-c4ccccc4)cc(-c4nc5nccnc5n4-c4ccccc4)c3)nc3nccnc32)cc1]

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes.

The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### Experimental Data

### Synthetic of Inventive Example

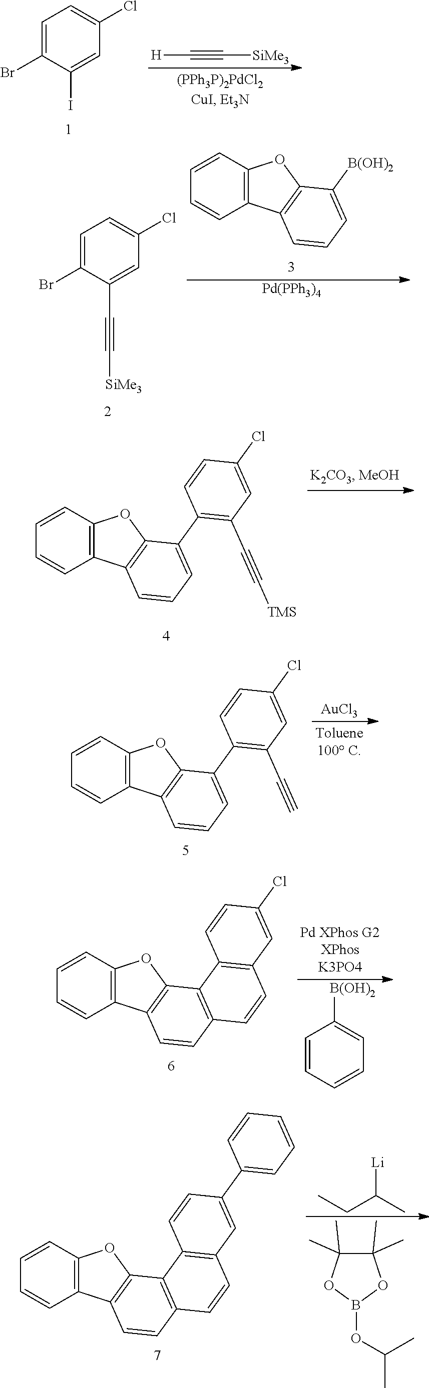

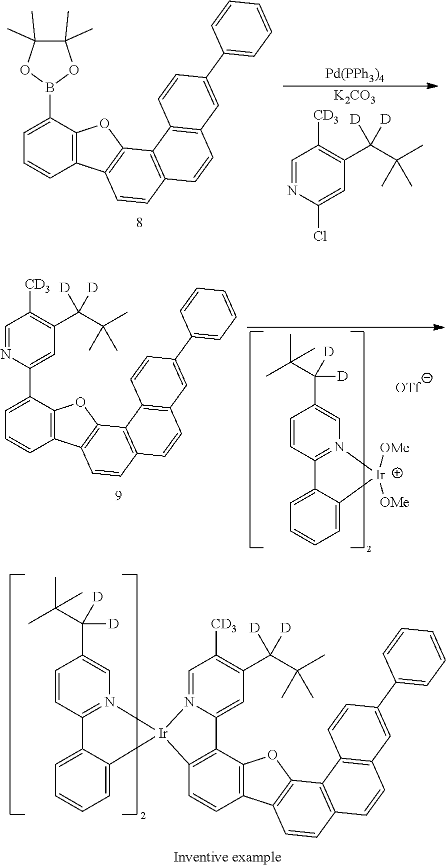

1-Bromo-4-chloro-2-iodobenzene (1) (50 g, 158 mmol), copper(I) iodide (0.750 g, 3.94 mmol) and bis(triphenylphosphine)palladium (II) chloride (2.76 g, 3.94 mmol) were combined and suspended in THF (315 ml) and triethylamine (132 ml, 945 mmol). The flask was vacuum/backfilled with N2 10 times (until boiling). Ethynyltrimethylsilane (17.02 g, 173 mmol) was then added over the course of 75 minutes via syringe pump and the reaction stirred at RT for 18 h. Reaction mixture turned from yellow to black over the course of 2 hours. The reaction was filtered through celite (10 g cartridge), and the filter washed with THF (200 mL). The organics were diluted with ether (1 L) and washed with brine (3×250 mL) before drying over MgSO4. Filtering and subsequent concentration in vacuo provided a dark orange oil (47 g). The oil was suspended in iso-hexane (200 mL), filtered through a plug of silica (approx. 20 g) and the plug washed with additional iso-hexane (300 mL). Concentration in vacuo provided an orange oil which was dissolved in iso-hexane (200 mL) and activated charcoal added (1 spatula). The suspension was filtered through a silica plug (20 g) and washed with iso-hexane (200 mL) before removing solvents in vacuo to provide ((2-bromo-5-chlorophenyl) ethynyl)trimethylsilane (2) (45.6 g, 155 mmol, 99% yield) as a yellow oil.

Dibenzo[b,d]furan-4-ylboronic acid (3) (34.5 g, 163 mmol), tetrakistriphenylphosphinepalladium (0) (8.96 g, 7.75 mmol), sodium carbonate (49.3 g, 465 mmol), ((2-bromo-5-chlorophenyl)ethynyl)trimethylsilane (2) (44.6 g, 155 mmol) and toluene (500 mL) were added to a 3-neck 2 L flask fitted with a condenser. The vessel was vacuum/backfilled with nitrogen 3 times whereupon ethanol (125 mL) and water (125 mL) were then added. The reaction vessel was vacuum/backfilled with nitrogen 3 times (until the solvent was boiling) and the reaction sparged with nitrogen for 30 minutes. The reaction mixture was heated to 80° C. for 22 h. The reaction was then allowed cooled down to RT and diluted with ethyl acetate (500 mL). Then washed with brine (3×250 mL). The organics were dried over MgSO4 and concentrated in vacuo to give a brown oil which was suspended in iso-hexane. The resulting brown solid was filtered away and discarded. The remaining dark orange oil was purified using a silica plug, eluting with neat iso-hexane. Fractions were combined and concentrated in vacuo to give ((5-chloro-2-(dibenzo[b,d]furan-4-yl)phenyl)ethynyl)trimethylsilane (4) (52.75 g, 139 mmol, 90% yield) as an orange oil which slowly crystallised to a solid.

((5-Chloro-2-(dibenzo[b,d]furan-4-yl)phenyl)ethynyl)trimethylsilane (4) (46.92 g, 125 mmol) was dissolved in MeOH (600 mL) and DCM (150 mL) and potassium carbonate (17.29 g, 125 mmol) was added in one portion. The reaction was stirred at 25° C. for 17 h over which time a thick white precipitate formed. The solid was collected by filtration and washed with MeOH (200 mL). The solid was then dissolved in DCM (1 L) and washed with water (250 mL) and saturated brine (aq., 250 mL) before passing through a phase separator cartridge and concentrating in vacuo to provide 4-(4-chloro-2-ethynylphenyl)dibenzo[b,d]furan (5) (33.2 g, 107 mmol, 86% yield) as a light orange solid.

4-(4-chloro-2-ethynylphenyl)dibenzo[b,d]furan (5) (34.9 g, 115 mmol) was dissolved in toluene (1200 mL) and the solution sparged with nitrogen for 20 min before adding gold (III) chloride (7.00 g, 23.06 mmol) in one portion. The suspension was sparged with nitrogen for an additional 5 min then heated to 100° C. and stirred at this temperature for 24 hrs. The brown reaction was hot filtered through celite and then left to stand at RT overnight. The light brown crystals which formed were collected by filtration and washed with iso-hexane (approx. 200 mL). Concentration of the filtrate in vacuo gave a dark brown solid. The crystals were dissolved in hot DCM (2 L) and then stirred over silica (4 large spatulas) and charcoal (1 large spatula) for 30 mins at 40° C. The suspension was filtered through celite, and silica (4× spatulas) and charcoal (1× spatula) added to the resultant yellow filtrate and stirred at 40° C. for an additional 30 min. Filtration through celite gave a pale-yellow solution which was concentrated in vacuo to afford a yellow solid, 13 g. The filtrate was dissolved in hot toluene (550 mL) and left to crystallise at RT overnight. The resultant light brown crystals were collected by filtration and washed with iso-hexane, Concentration of the filtrate in vacuo gave a dark brown solid. The crystals were dissolved in warm DCM (1.5 L, 40° C.) and stirred over silica (3× spatulas) and charcoal (1× spatula) for 30 mins. Filtration through celite gave a yellow solution to which was added silica (3× spatulas) and charcoal (1× spatula) and stirred at 40° C. for 30 mins. Filtration through celite gave a pale-yellow solution which was combined with the previous isolated 13 g and concentrated in vacuo to afford a yellow solid, 22.8 g. The second filtrate was dissolved in hot toluene (250 mL) and left to crystallise at RT overnight. The resultant light brown crystals were collected by filtration and washed with iso-hexane. The crystals were dissolved in warm DCM (500 mL, 40° C.) and stirred over silica (3× spatulas) and charcoal (1× spatula) for 30 mins. Filtration through celite gave a yellow solution to which was added silica (3× spatulas) and charcoal (1× spatula) and stirred at 40° C. for 30 min. Filtration through celite gave a pale-yellow solution which was combined with the previous 22 g batch and concentrated in vacuo to provide a yellow solid, 24.8 g. This solid was dissolved in hot toluene (450 mL) and left to stand at RT for 64 h. The resultant crystals were collected by filtration and washed with iso-hexane (250 mL) before drying at 50° C. under vacuum for 90 min. Afforded light yellow fine crystals, 21.16 g that were subsequently was dissolved in warm DCM (1.5 L, 40° C.) and stirred over silica (3× spatulas) and charcoal (1× spatula) for 30 min. Filtration through celite gave a pale yellow solution to which was added silica (3× spatulas) and charcoal (1× spatula) and stirred at 40° C. for 30 min. Filtration through celite gave a pale yellow solution which was concentrated in vacuo to provide a light yellow fluffy solid, 19.01 g (62.8 mmol, 54.5%).

3-Chlorophenanthro[4,3-b]benzofuran (6) (3.0 g, 9.91 mmol) and phenylboronic acid (2.4 g, 2 eq.) were suspended in 75 mL of toluene and 20 mL of water. Palladium G2 XPhos catalyst (2 mol. %) and XPhos ligand (5 mol. %) were added as one portion. The reaction mixture was degassed and heated to 100° C. for 5 h, then it was cooled down to room temperature and evaporated. The residue was subjected to column chromatography on silica gel, eluting with heptane/DCM 1/1 (v/v), providing 3-phenylphenanthro[4,3-b]benzofuran (3.24 g, 90% yield) as white solid.

3-Phenylphenanthro[4,3-b]benzofuran (7) (7.2 g, 20.91 mmol) was dissolved in 150 mL of dry THF under nitrogen atmosphere and cooled in acetone/dry ice bath. Sec-Bu lithium solution in hexanes (30 ml, 41.8 mmol) was added via syringe, the reaction mixture was stirred for 45 min, then 2-isopropoxy-4,4,5,5-tetramethyl-1,3,2-dioxaborolane (7.78 g, 41.8 mmol) was added via syringe dropwise. The reaction mixture was allowed to warm up to room temperature and stirred for 12 h. It was quenched with ammonium chloride 10% aqueous solution, extracted with ethyl acetate, filtered and evaporated. The residue was subjected to column chromatography on silica gel column, eluted with heptanes/ethyl acetate gradient mixture, providing 4,4,5,5-tetramethyl-2-(3-phenylphenanthro[4,3-b]benzofuran-12-yl)-1,3,2-dioxaborolane as white solid (4.9 g, 50% yield).

The 4,4,5,5-tetramethyl-2-(3-phenylphenanthro[4,3-b]benzofuran-12-yl)-1,3,2-dioxaborolane (8) (3.2 g, 6.80 mmol) and 2-chloro-4-(2,2-dimethylpropyl-1,1-d2)-5-(methyl-d3)pyridine were suspended in DME (150 mL)/water (30 mL), added Pd catalyst (160 mg, 2 mol. %) and potassium carbonate (1.88 g, 2 eq.). The reaction mixture was degassed and heated to 80° C. for 16 h. The reaction mixture was cooled down, diluted with ethyl acetate, washed with water, filtered, and evaporated. The residue was subjected to column chromatography on silica gel, eluted with gradient mixture heptane/ethyl acetate, providing 4-(2,2-dimethylpropyl-1,1-d2)-5-(methyl-d3)-2-(3-phenylphenanthro[4,3-b]benzofuran-12-yl)pyridine (9) as white solid (3.12 g, 90% yield).

Iridium triflate complex (1.8 g) and ligand (1.8 g, 1.75 eq.) were suspended in 40 mL of DMF/2-ethoxyethanol 1/1 mixture. The reaction mixture was degassed and heated to 100° C. for 120 h. The material was dissolved in ethyl acetate, washed with brine, and evaporated. The residue was subjected to column chromatography on silica gel column, eluted with toluene/heptane/DCM 3/1/1 mixture. Pure fractions were combined, evaporated, and crystallized from toluene/ethanol, providing 920 mg of pure product as yellow needles.

### Synthetic of Comparative Example

The synthesis of the comparative example can be found in US20190280219, which is incorporated in its entirety herein by reference.

### Device Example

All example devices were fabricated by high vacuum (<10⁻⁷ Torr) thermal evaporation. The anode electrode was 800 Å of indium tin oxide (ITO). The cathode consisted of 10 Å of Liq (8-hydroxyquinoline lithium) followed by 1,000 Å of A1. All devices were encapsulated with a glass lid sealed with an epoxy resin in a nitrogen glove box (<1 ppm of H₂O and O₂) immediately after fabrication with a moisture getter incorporated inside the package. The organic stack of the device examples consisted of sequentially, from the ITO Surface: 100 Å of LG101 (purchased from LG Chem) as the hole injection layer (HIL); 400 Å of HTM as a hole transporting layer (HTL); emissive layer (EML) with thickness 400 Å; 50 Å of EBM as an electron blocking layer (EBL); Emissive layer containing H-host (H1): E-host (H2) in 6:4 ratio and 5 weight % of green emitter; 350 Å of Liq (8-hydroxyquinoline lithium) doped with 35% of ETM as the ETL. The device structure is shown in Table 1. The chemical structures of the device materials are shown below.

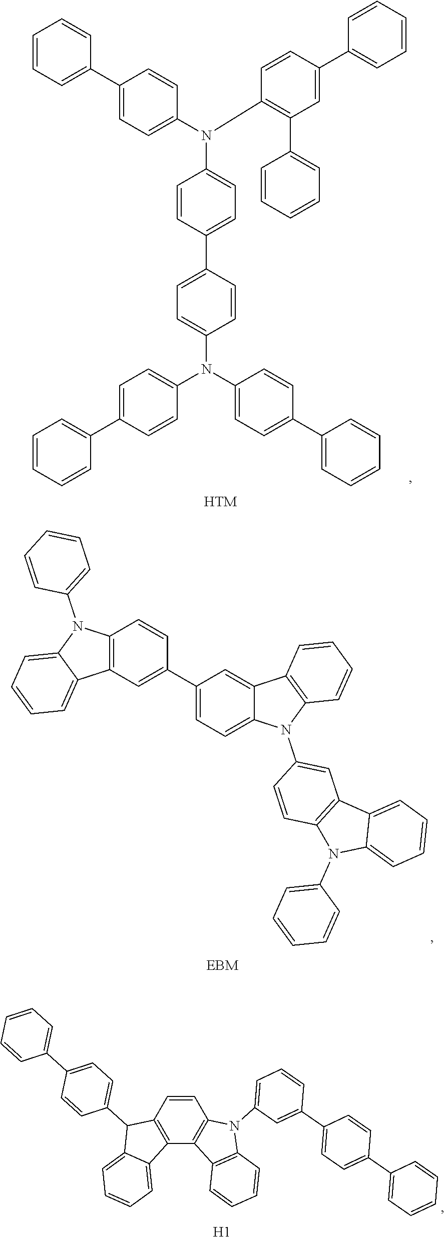

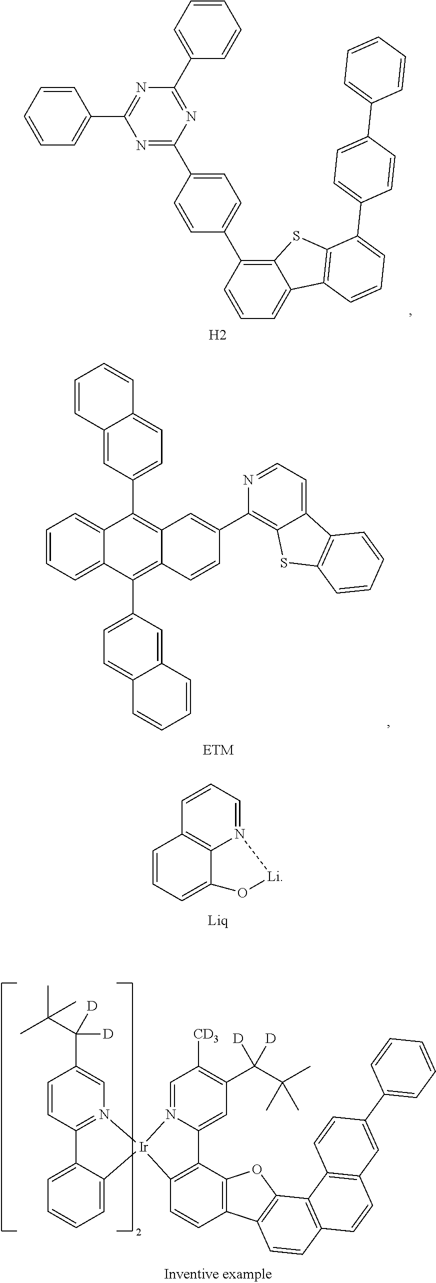

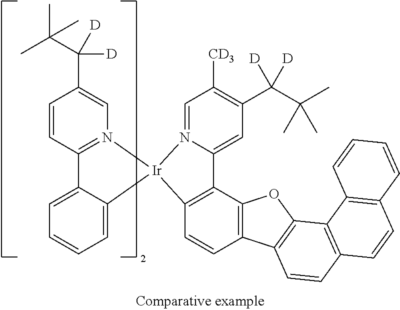

TABLE 1
Device layer materials and thicknesses

| Layer | Material | Thickness [Å] |
|---|---|---|
| Anode | ITO | 800 |
| HIL | LG-101 | 100 |
| HTL | HTM | 400 |
| EBL | EBM | 50 |
| EML | H1:H2:Emitter 5% | 400 |
| ETL | Liq:ETM 35% | 350 |
| EIL | Liq | 10 |
| Cathode | Al | 1,000 |

Upon fabrication, the device was tested to measure EL and JVL. For this purpose, the samples were energized by the 2 channel Keysight B2902A SMU at a current density of 10 mA/cm² and measured by the Photo Research PR735 Spectroradiometer. Radiance (W/str/cm²) from 380 nm to 1080 nm, and total integrated photon count were collected. The devices were then placed under a large area silicon photodiode for the JVL sweep. The integrated photon count of the device at 10 mA/cm² is used to convert the photodiode current to photon count. The voltage is swept from 0 to a voltage equating to 200 mA/cm². The EQE of the device is calculated using the total integrated photon count. All results are summarized in Table 2. Voltage, LE, EQE and PE of inventive example are reported as relative numbers normalized to the results of the comparative example.

TABLE 2
device performance results

| | 1931 CIE | | | | At 10 mA/cm^{2*} | | | | At 9K nits* |
|---|---|---|---|---|---|---|---|---|---|
| | | | λ max | FWHM | Voltage | LE | EQE | PE | calculated |
| Emitter 12% | x | y | [nm] | [nm] | [V] | [cd/A] | [%] | [lm/W] | 97% [h] ** |
| Inventive | 0.329 | 0.643 | 528 | 25 | 1 | 1.07 | 1.06 | 1.08 | 1.21 |
| Example | | | | | | | | | |
| Comparative | 0.328 | 0.643 | 527 | 26 | 1 | 1 | 1 | 1 | 1 |
| Example | | | | | | | | | |

Table 2 provides a summary of performance of electroluminescence device of the materials. The inventive example shows higher efficiency than comparative example. Moreover, the inventive example 1 show better LT, LE and PE compared to the comparative example 1. The improvement of these values is above the value that could be attributed to experimental error and the observed improvement is significant. The performance improvement observed in the above data was unexpected. All results show the significance of the inventive compounds for applications in organic light emitting diodes (OLED).

What is claimed is:

1. A compound comprising a first ligand L_{A} of Formula I, 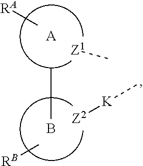
wherein:
moiety A is a 5-membered or 6-membered carbocyclic or heterocyclic ring;
moiety B is a fused ring structure comprising at least three rings, each of which is independently heterocyclic or carbocyclic;
K is a direct bond, S, or O;
each of Z¹ and Z² is independently C or N;
each of R^{A} and R^{B} independently represents mono to the maximum possible number of substitutions, or no substitution;
each R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
any two R^{A} or R^{B} can be joined or fused to form a ring;
at least one R^{B} comprises a cyclic group or an electron-withdrawing group;
L_{A} is coordinated to a metal M;
metal M has an atomic mass of at least 40 and can be coordinated to other ligands; and
the ligand L_{A} is optionally linked with other ligands to comprise a tridentate, tetradentate, pentadentate, or hexadentate ligand.

2. The compound of claim 1, wherein each R^{A} and R^{B} is independently hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, boryl, and combinations thereof.

3. The compound of claim 1, wherein moiety A is selected from the group consisting of benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, phenanthridine, fluorene, and aza-fluorene.

4. The compound of claim 1, wherein moiety B comprises at least one ring of Formula II, 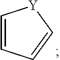
wherein Y is selected from the group consisting of BR′, BR′R″, NR′, PR′, P(O)R′, O, S Se, C═O, C═S, C═Se, C═NR′, C═CR′R″, S═O, SO₂, CR′, CR′R″, SiR′R″, GeR′R″, alkylene, cycloalkyl, aryl, cycloalkylene, arylene, heteroarylene, and combinations thereof;
wherein each R′ or R″ is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

5. The compound of claim 1, wherein moiety B comprises at least four six-membered rings; and/or wherein Z¹ is N and Z² is C or wherein Z¹ is C and Z² is N; and/or wherein metal M is selected from the group consisting of Ir, Os, Rh, Re, Ru, Pt, Pd, Cu, Ag, and Au.

6. The compound of claim 1, wherein at least one R^{B} comprises at least one monocyclic group or a fused multicyclic group; and/or
wherein at least one R^{B} is an electron-withdrawing group selected from the group consisting of: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R)₃, (R)₂CCN, (R)₂CCF₃, CNC(CF₃)₂, BRR′, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate, 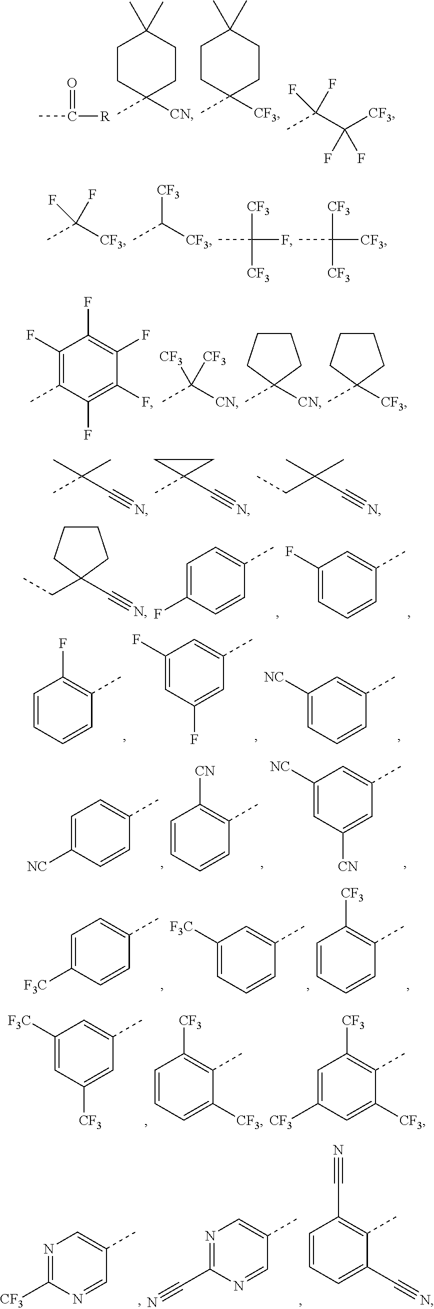 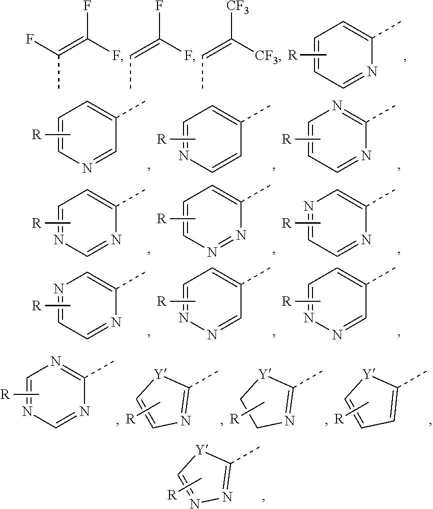
wherein Y′ is selected from the group consisting of BRₑ, NRₑ, PRₑ, O, S, Se, C═O, S═O, SO₂, CRₑR_{f}, SiRₑR_{f}, and GeRₑR_{f}, and each R, Rₑ, and R_{f} is independently a hydrogen or a substituent selected from the group consisting of the General Substituents defined herein. In some embodiments, R can be a mono up to the maximum number of allowable substitutions or no substitution; wherein
each R, Rₑ, and R_{f} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, selenyl, and combinations thereof, and wherein Y′ is selected from the group consisting of BRₑ, NRₑ, PRₑ, O, S, Se, C═O, S═O, SO₂, CRₑR_{f}, SiRₑR_{f}, and GeRₑR_{f}.

7. The compound of claim 1, wherein the ligand L_{A} is selected from the group consisting of: 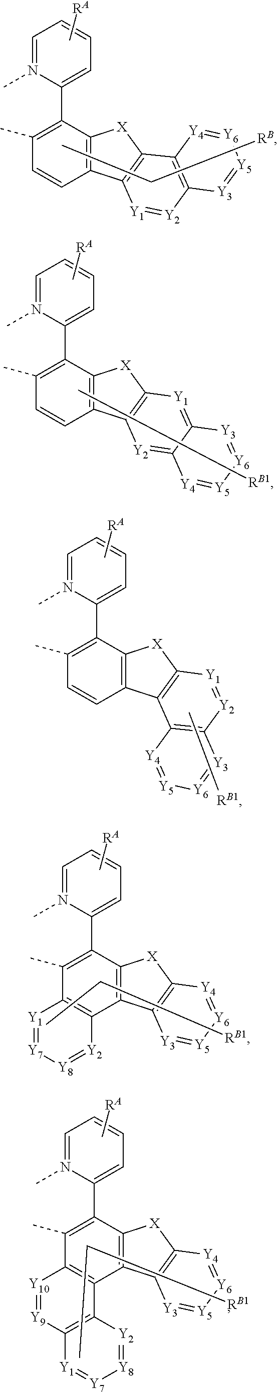 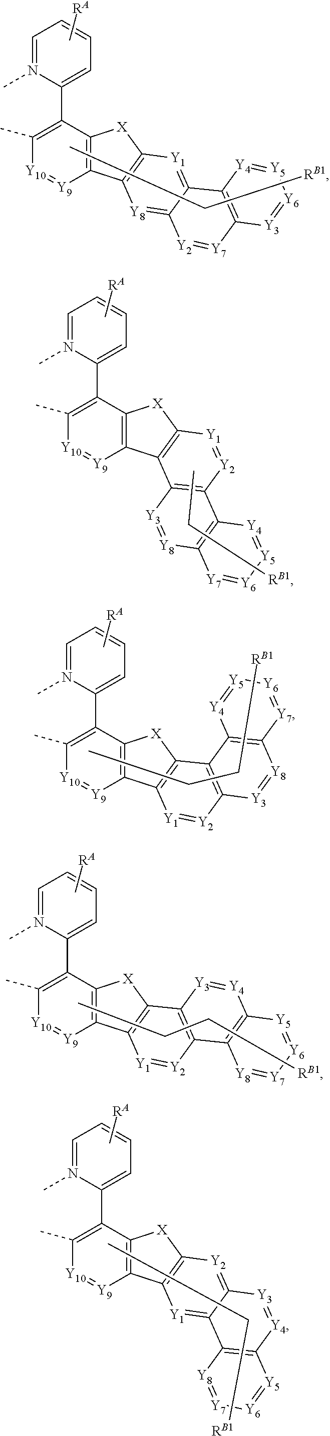 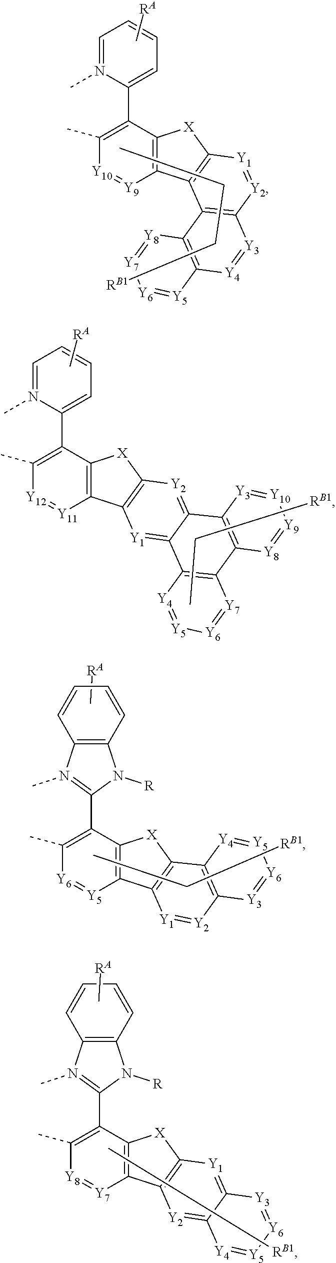 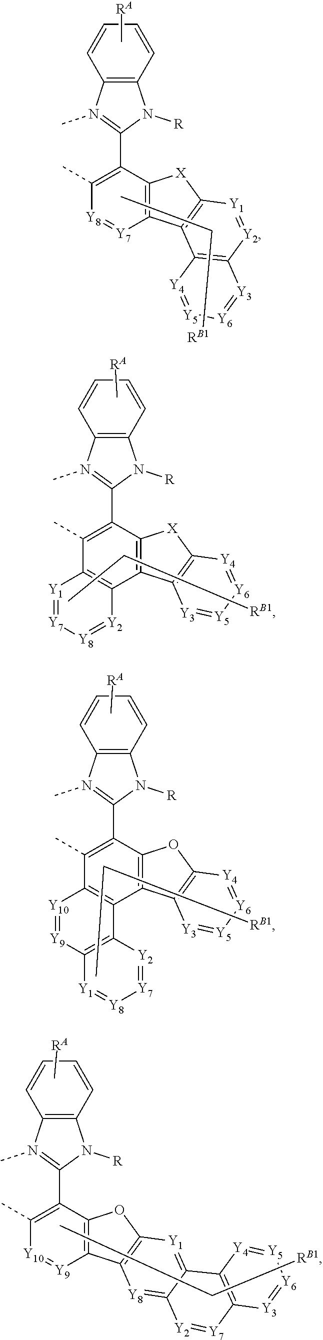 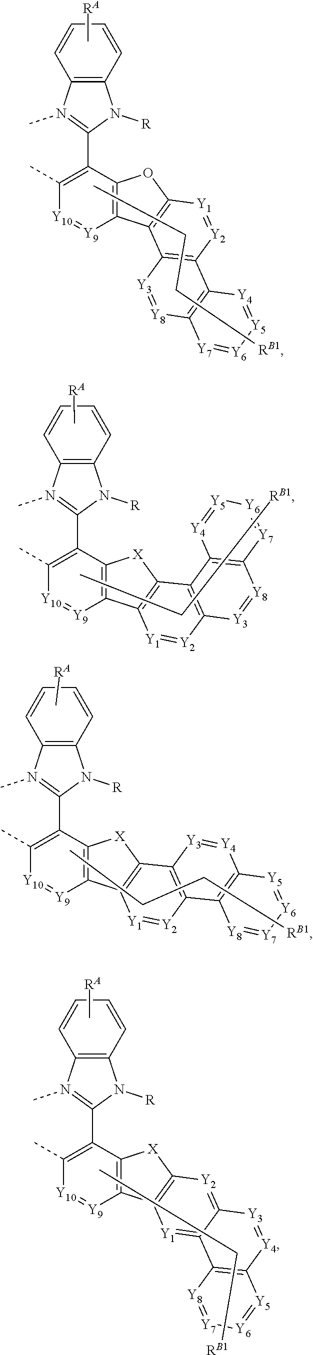 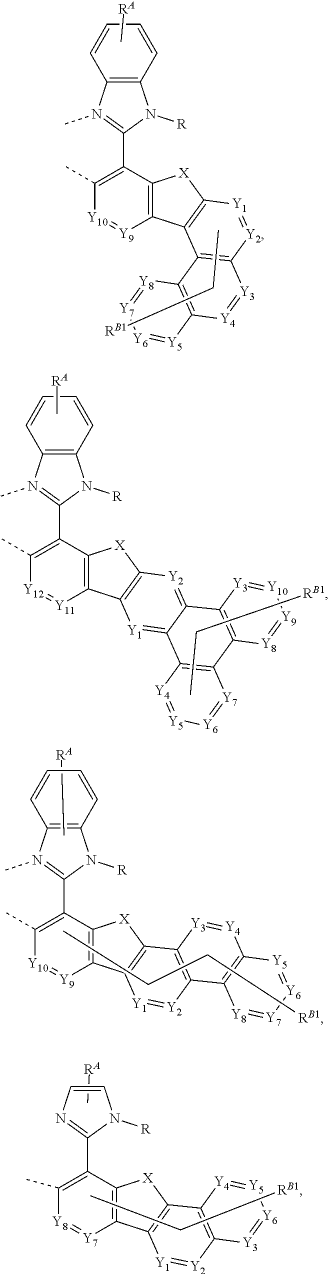 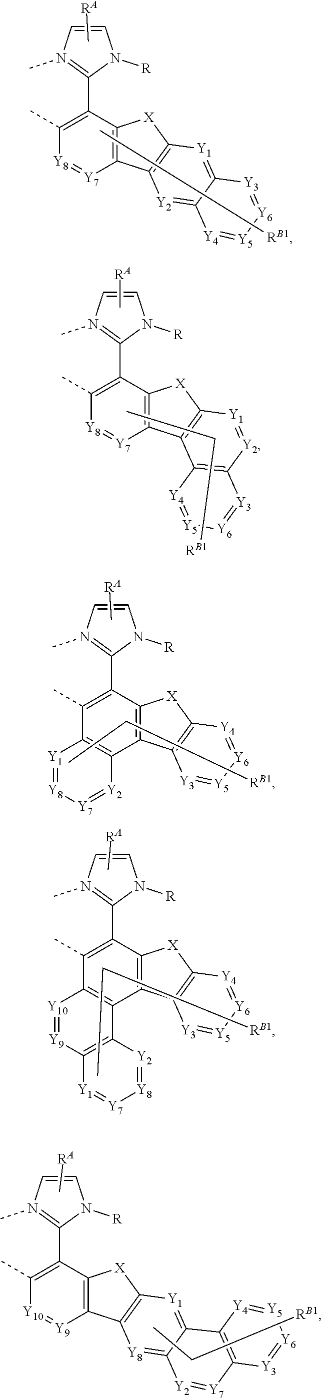 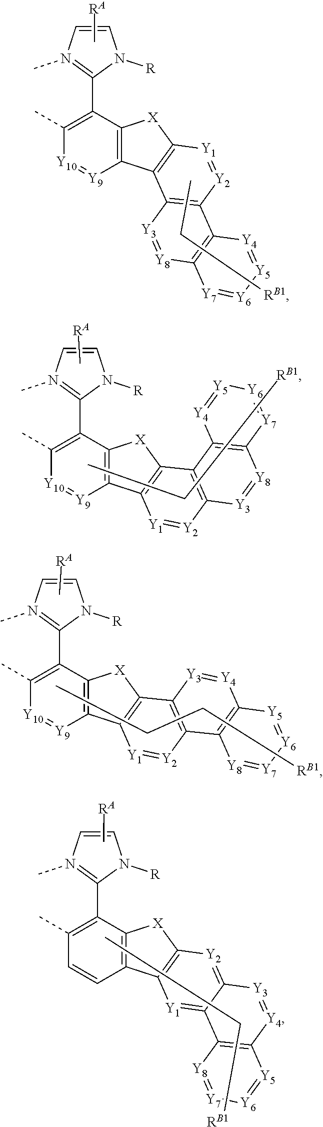 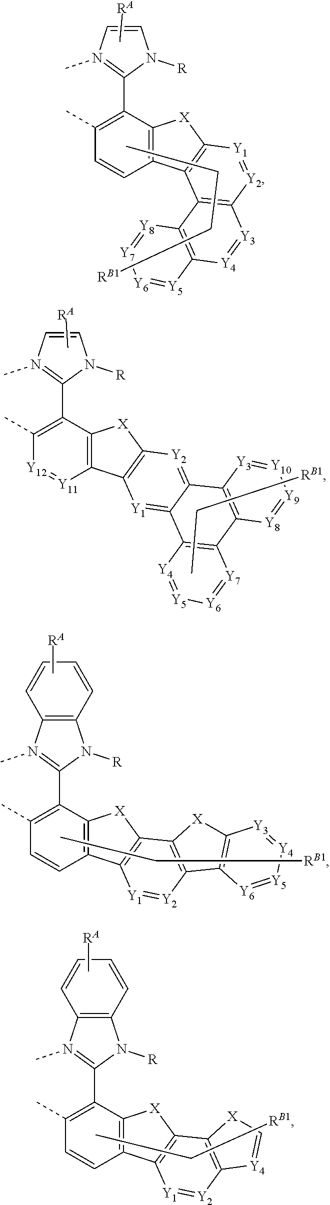 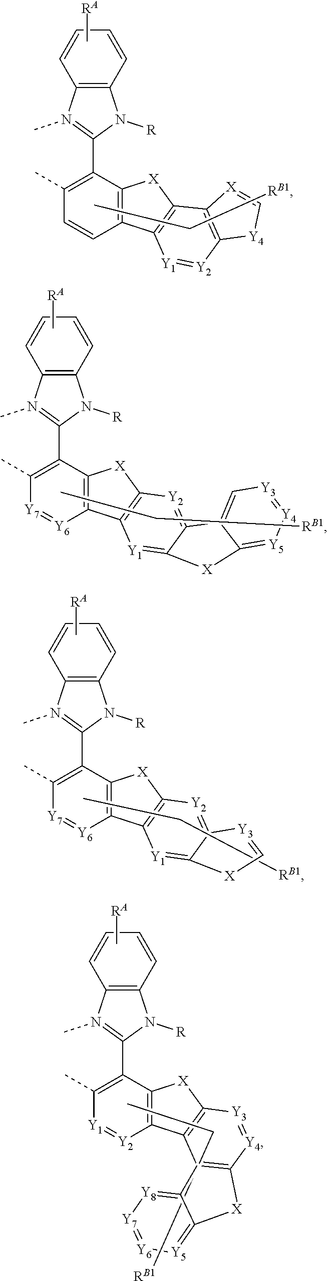 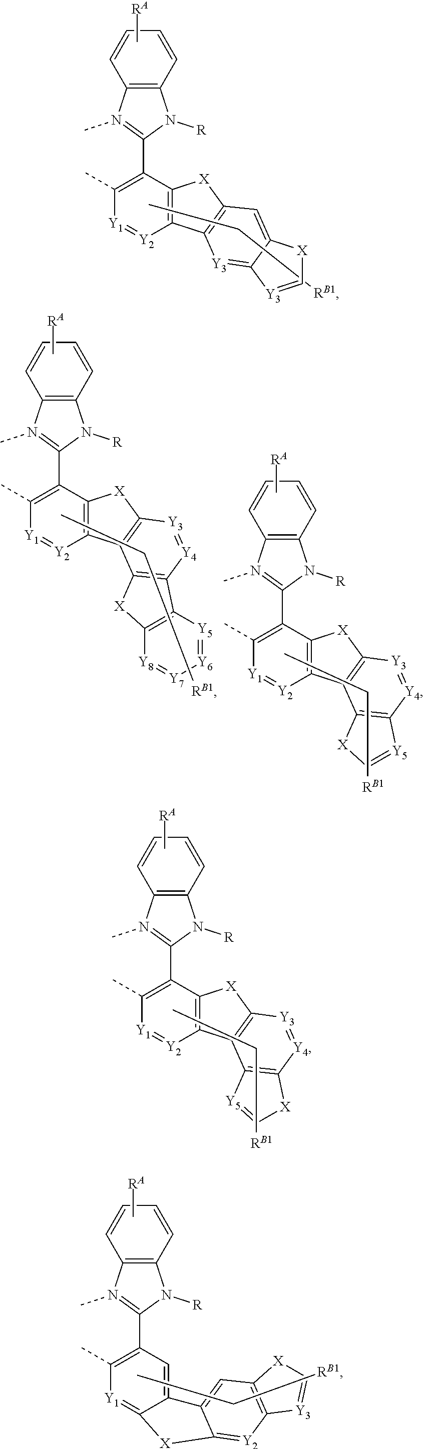 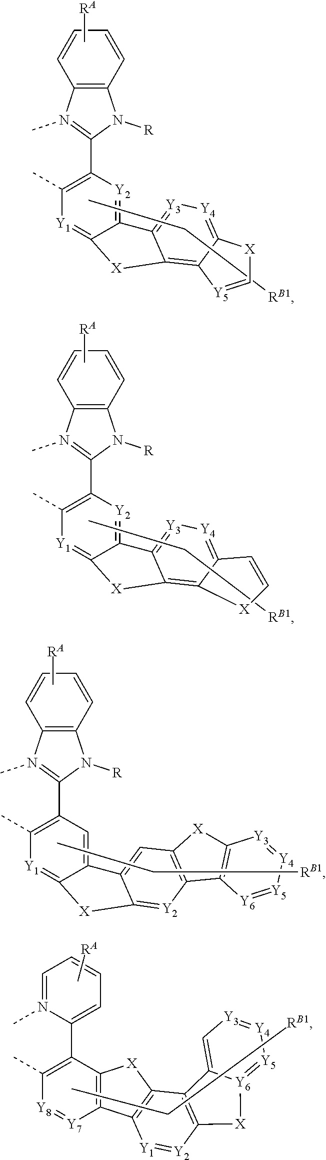 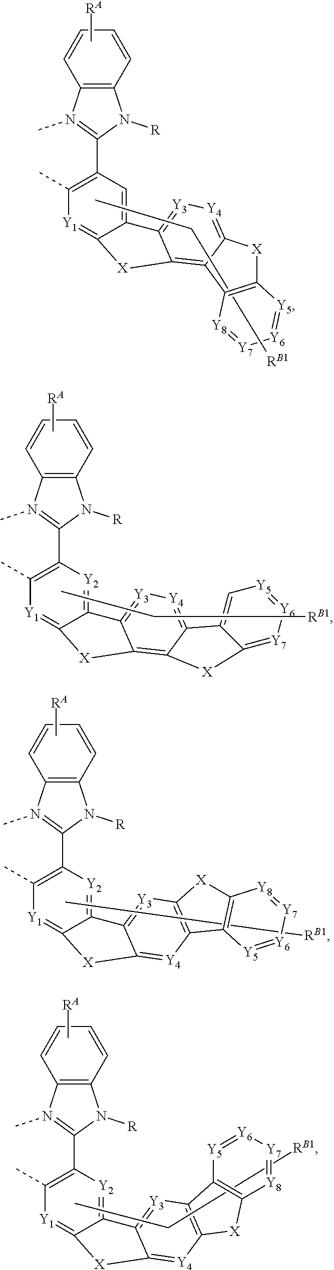 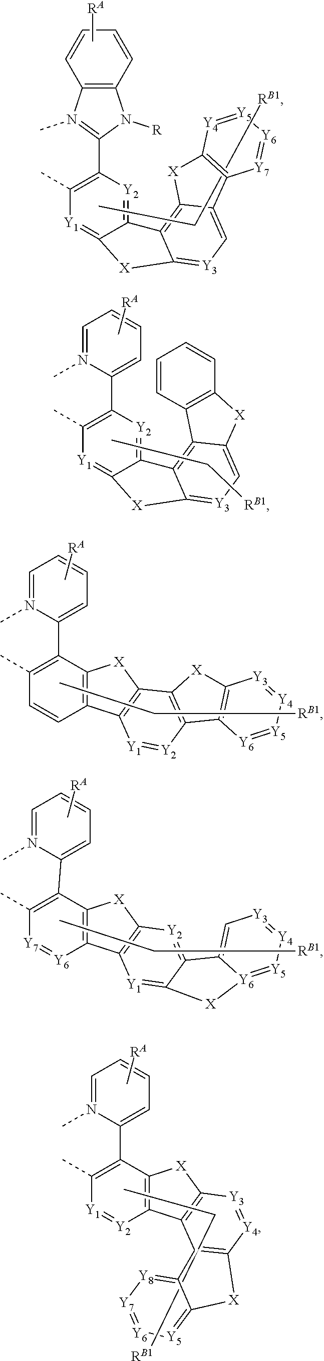 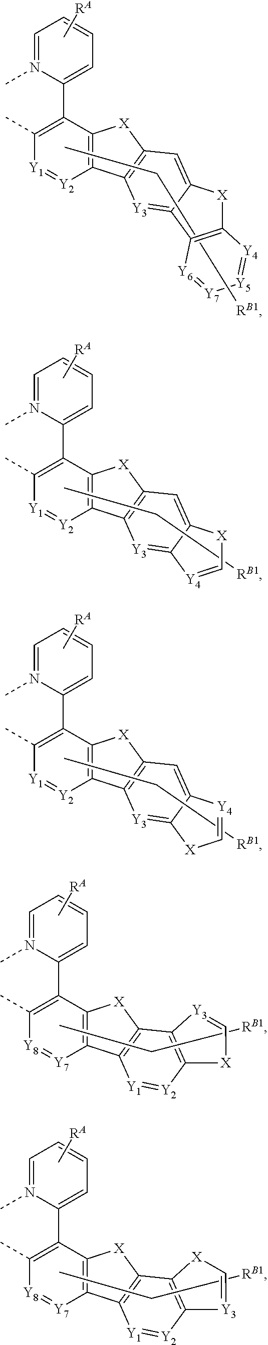 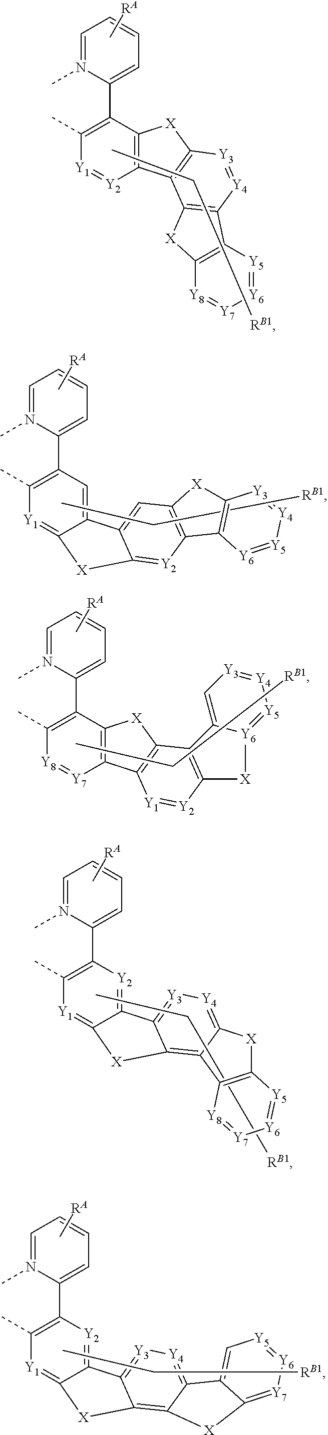 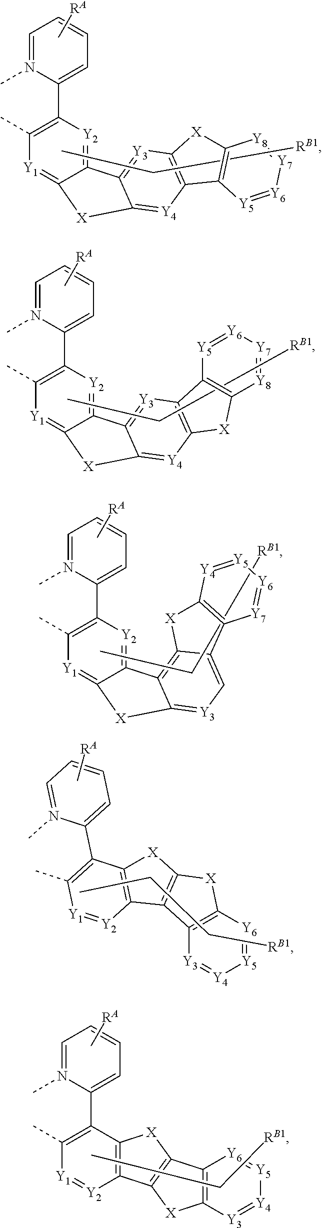 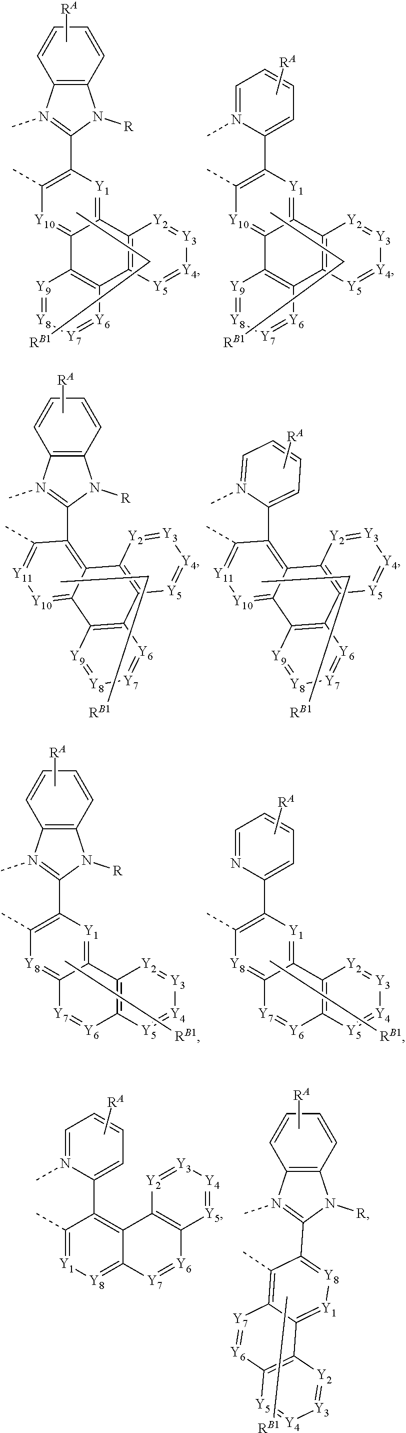 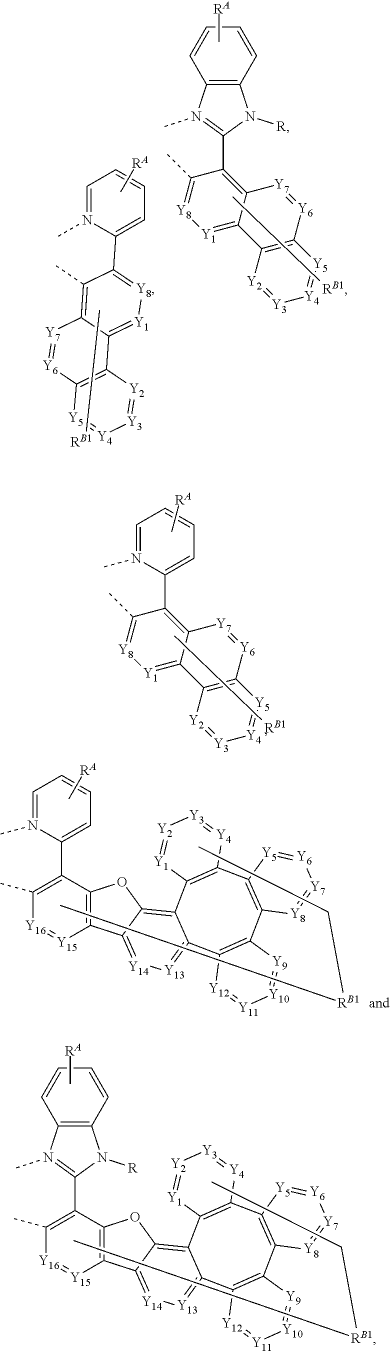
wherein:
each of Y₁, Y₂, Y₃, Y₄, Y₅, Y₆, Y₇, Y₈, Y₉, Y₁₀, Y₁₁, Y₁₂, Y₁₃, Y₁₄, Y₁₅, and Y₁₆ is independently C or N;
R^{B1} represents mono to the maximum possible number of substitutions, or no substitution;
each R and R^{B1} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
at least one R^{B1} comprises a cyclic group or an electron-withdrawing group; and
two adjacent R^{B1} can be joined to form a ring.

8. The compound of claim 1, wherein the ligand L_{A} is selected from the group consisting of: 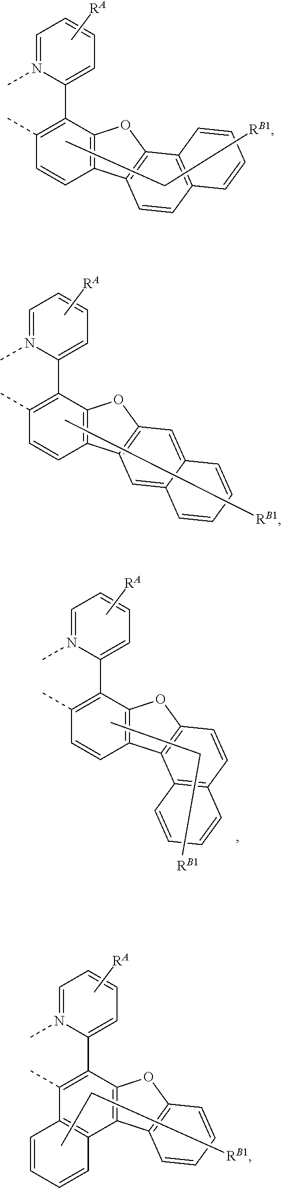 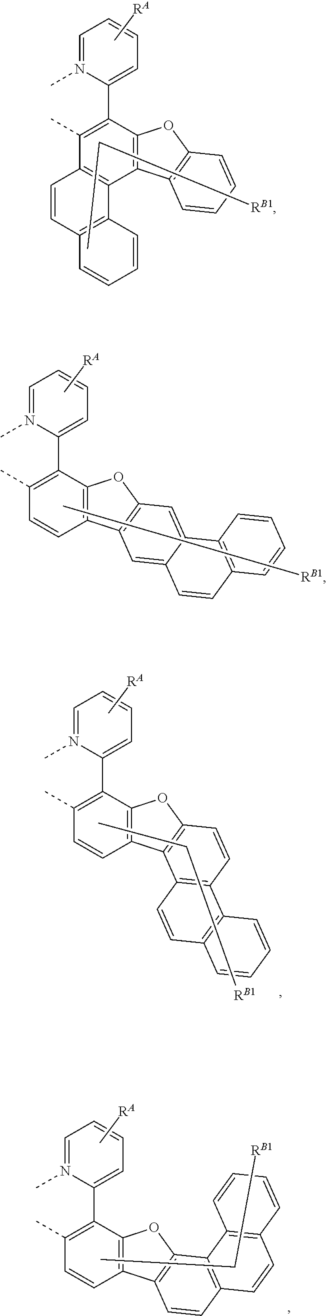 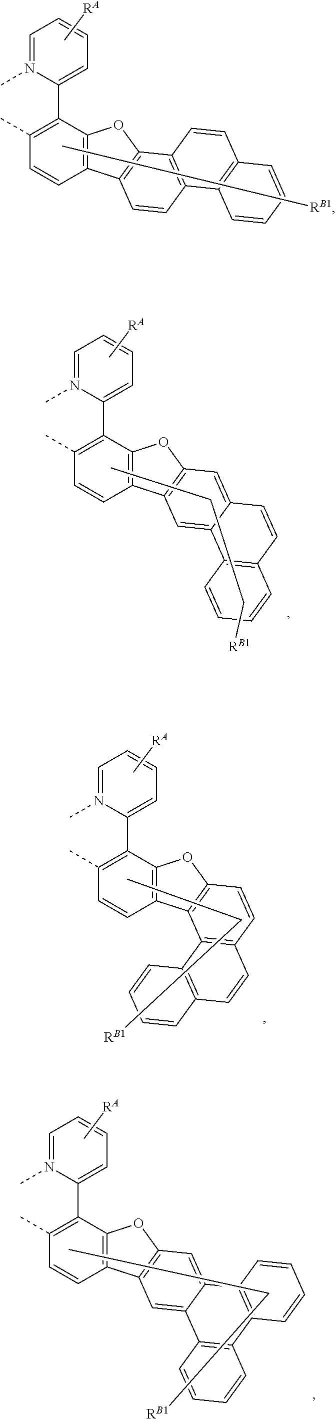 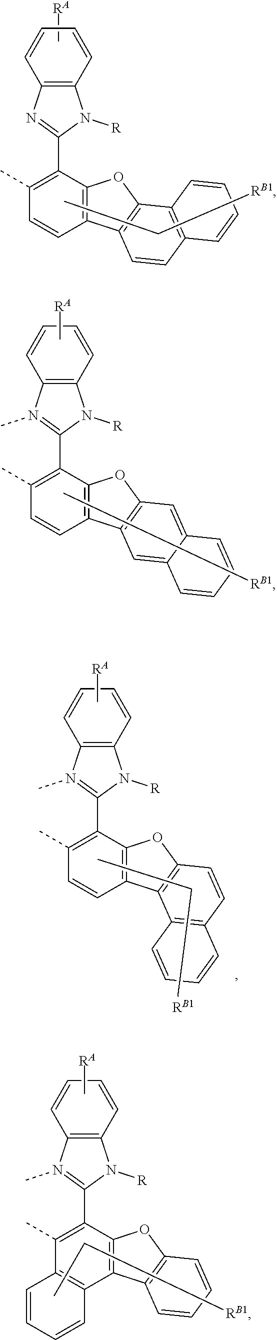 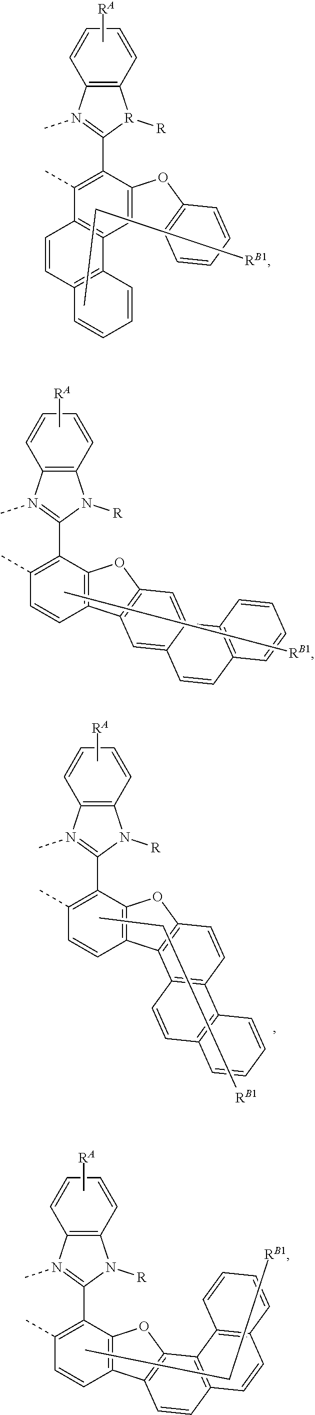 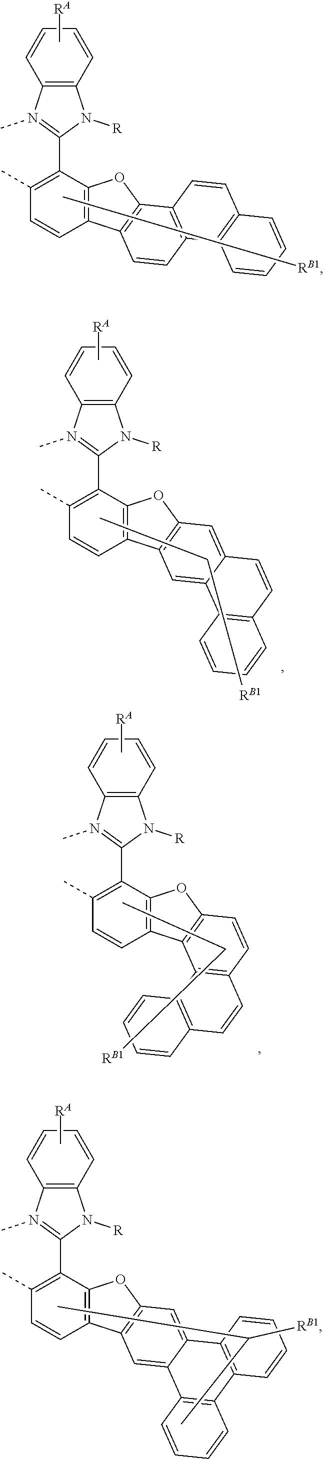 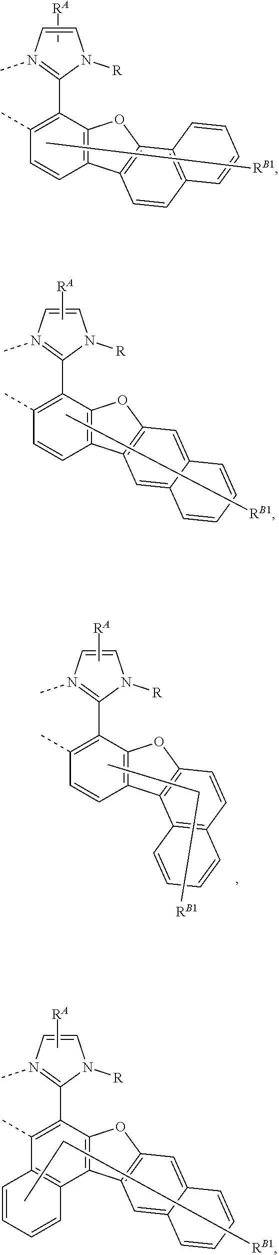 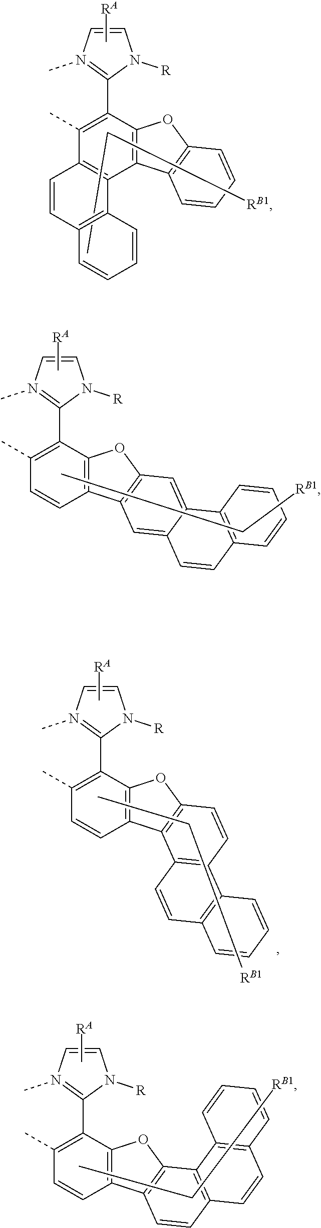 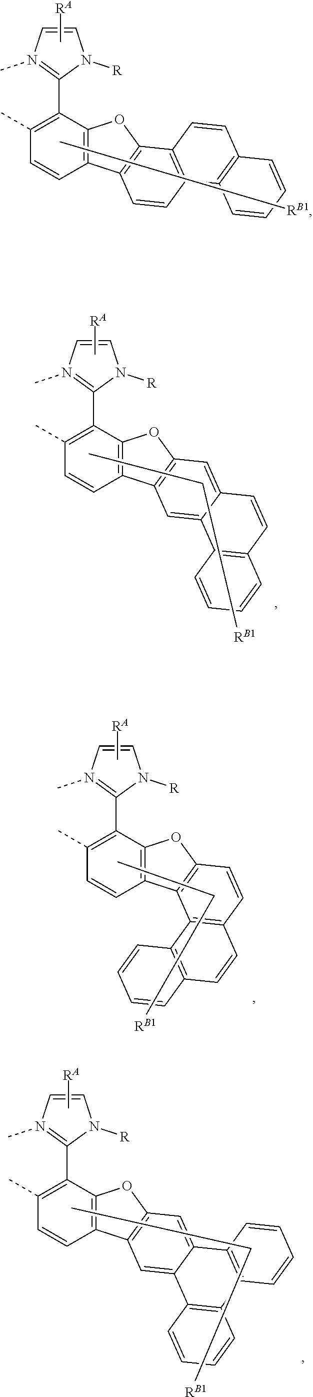 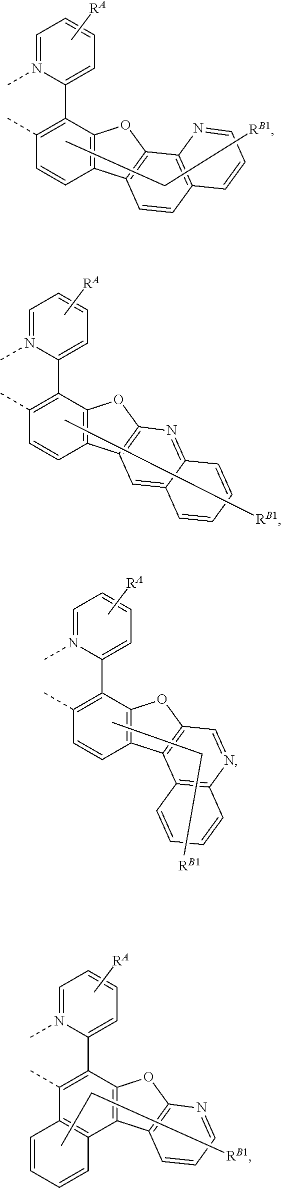 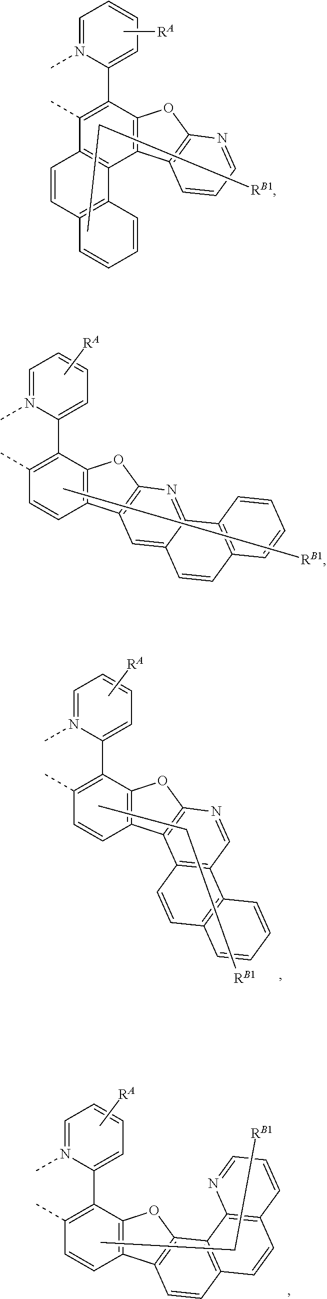 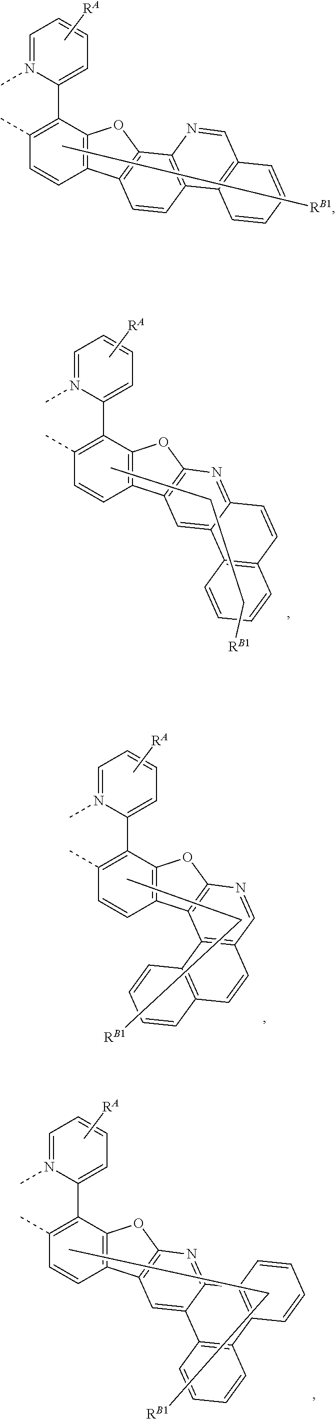 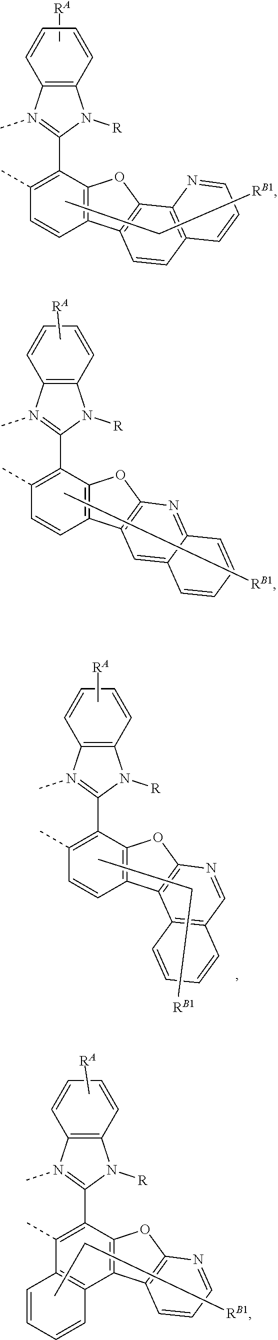 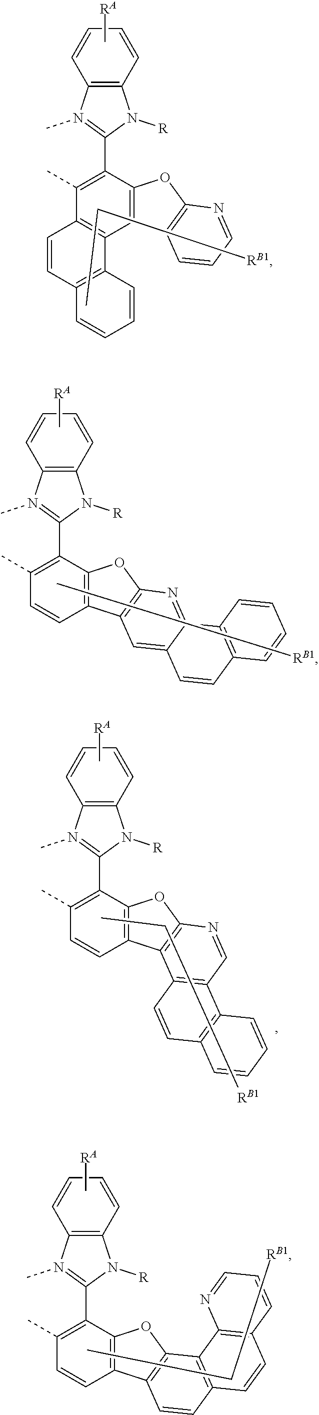 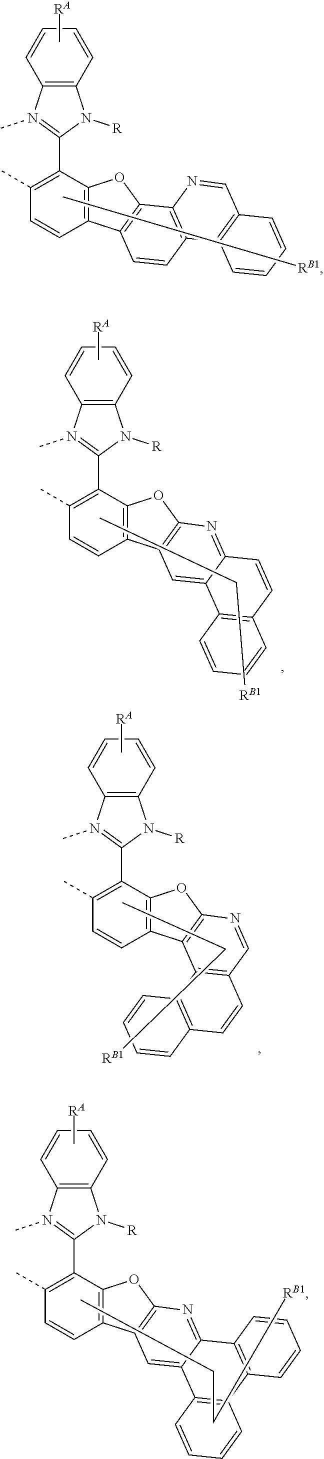 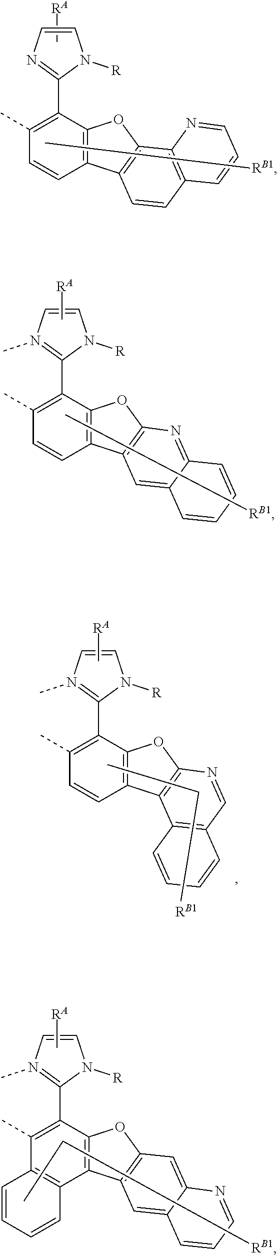 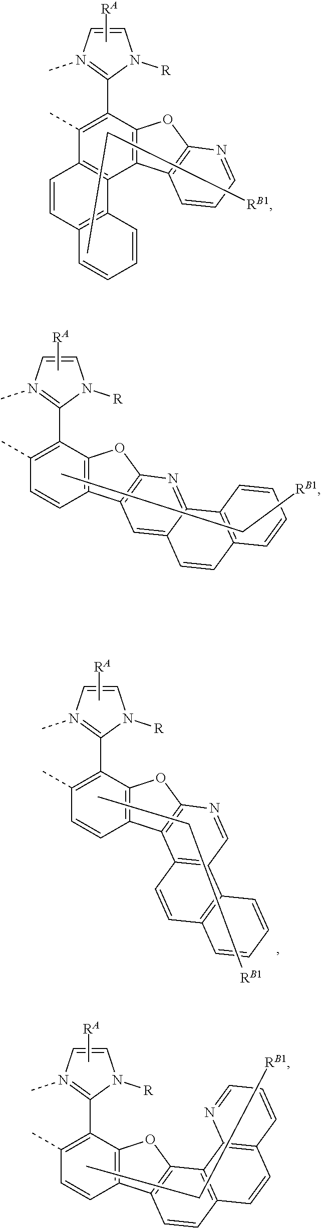 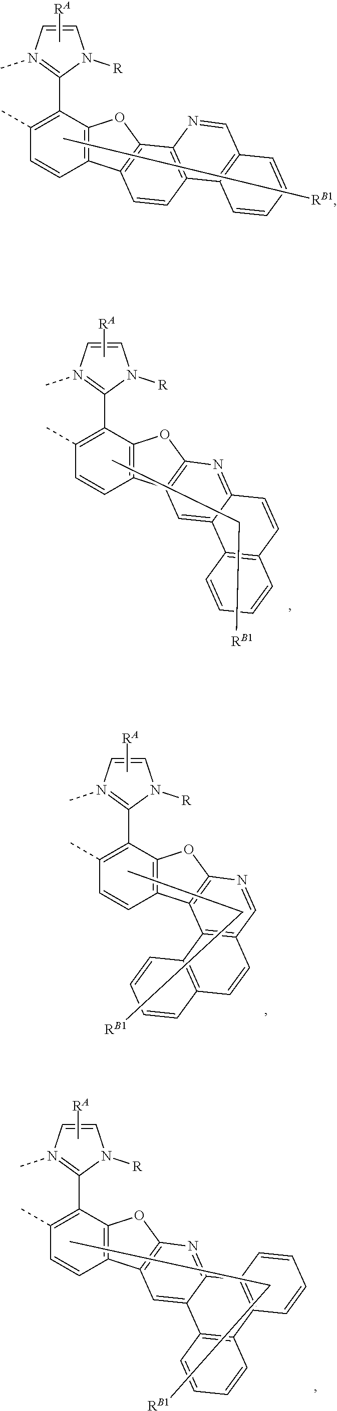 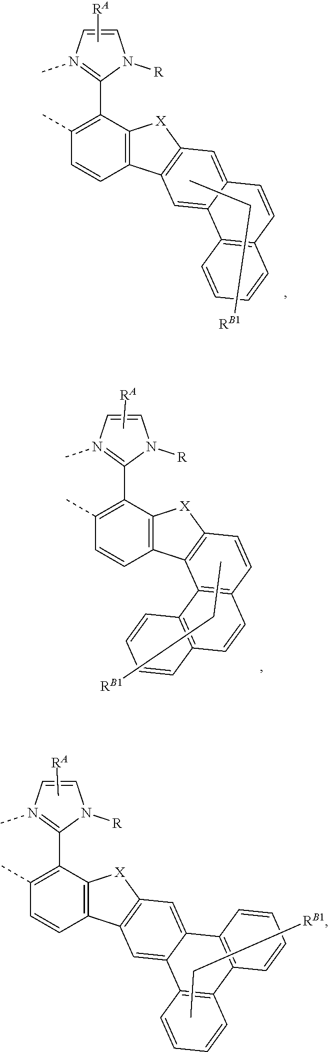 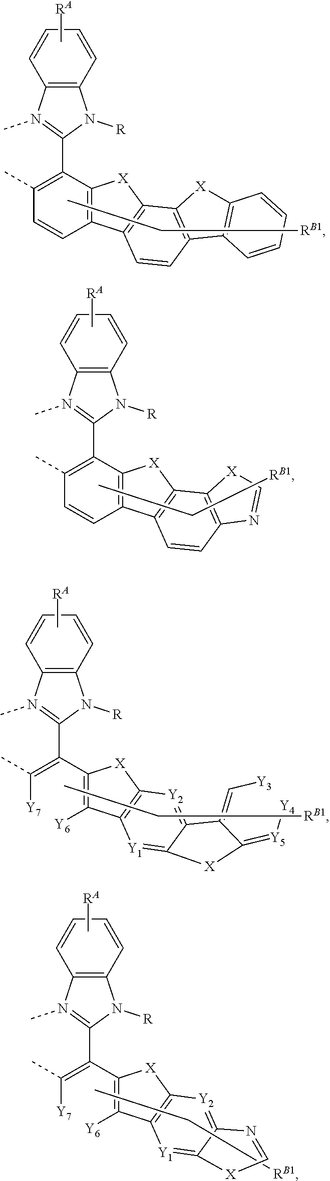 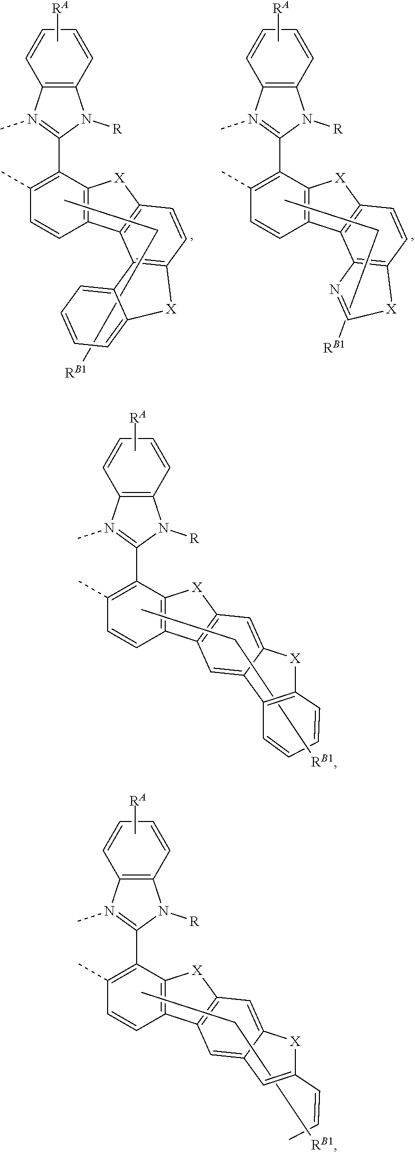 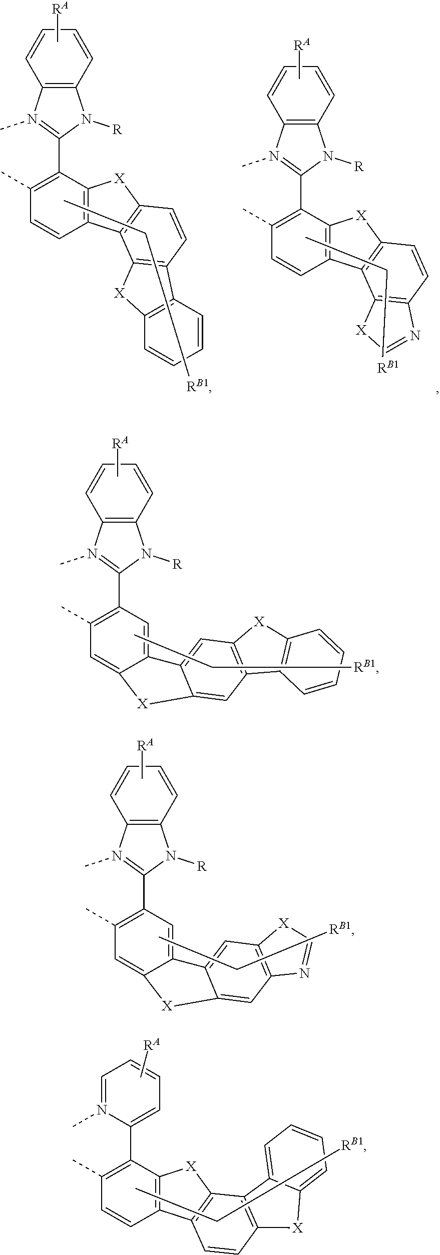 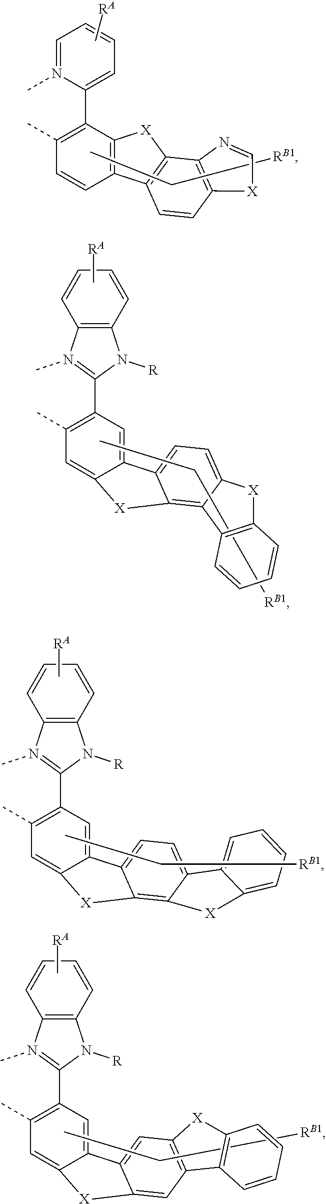 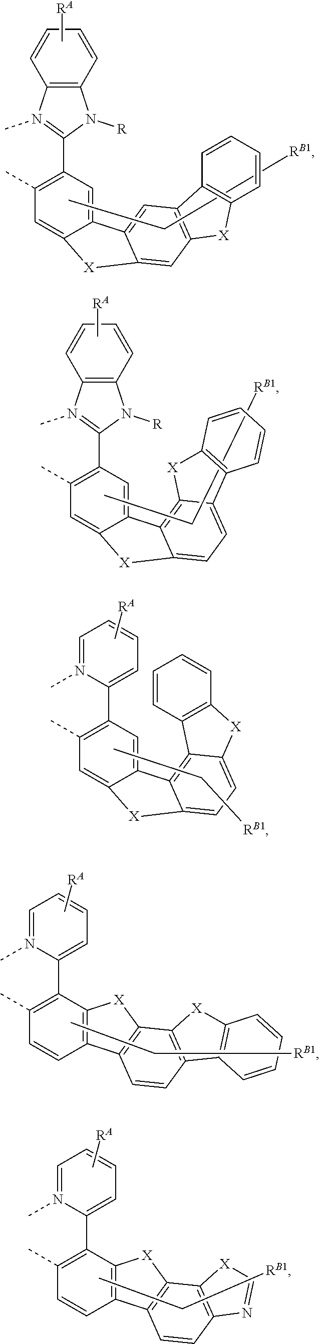 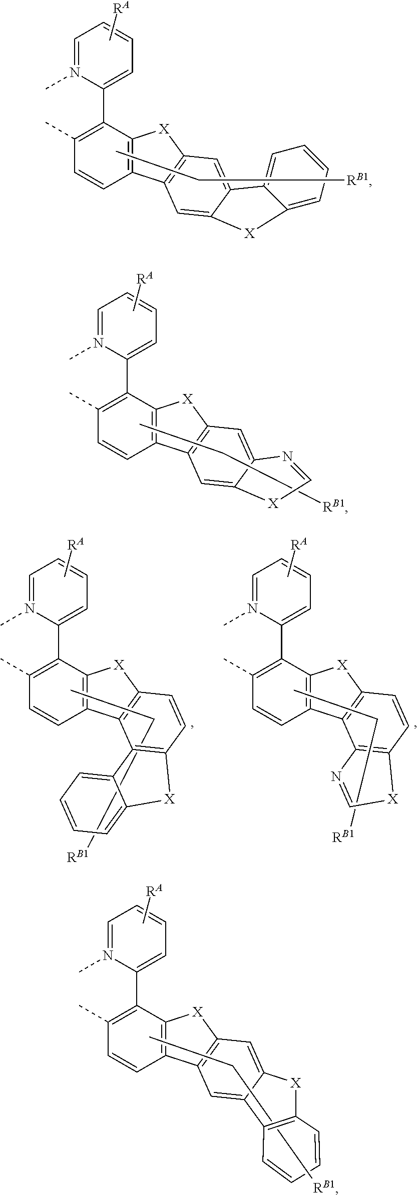 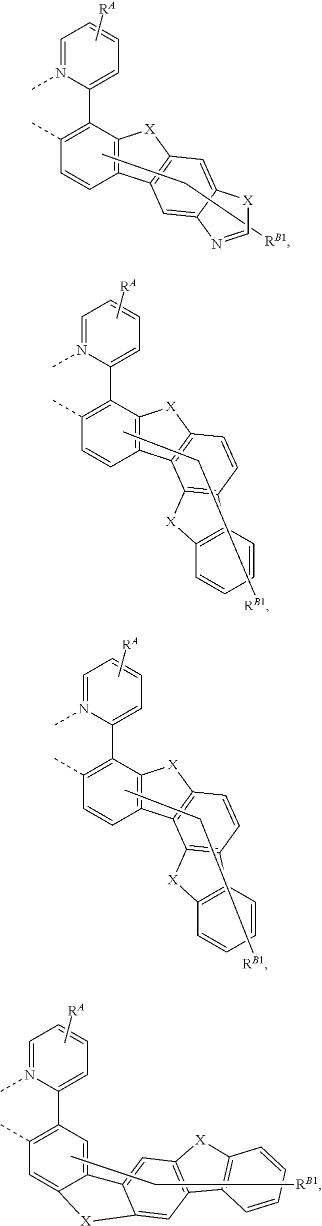 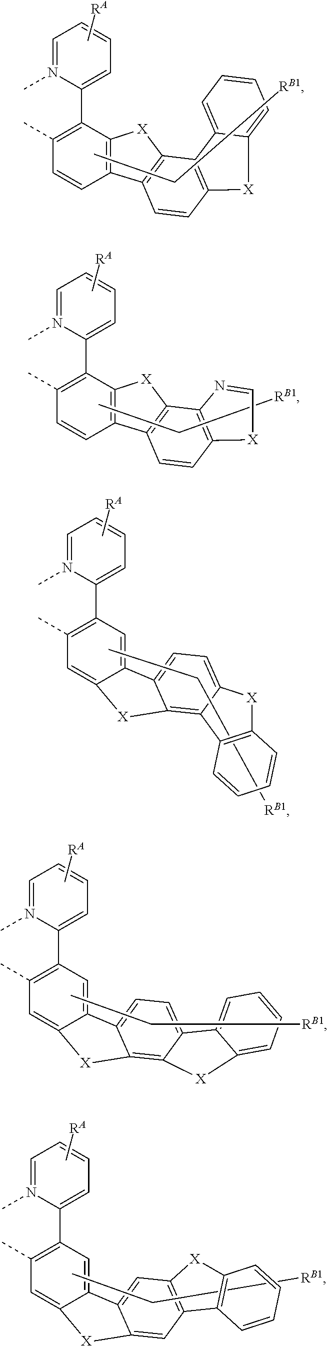 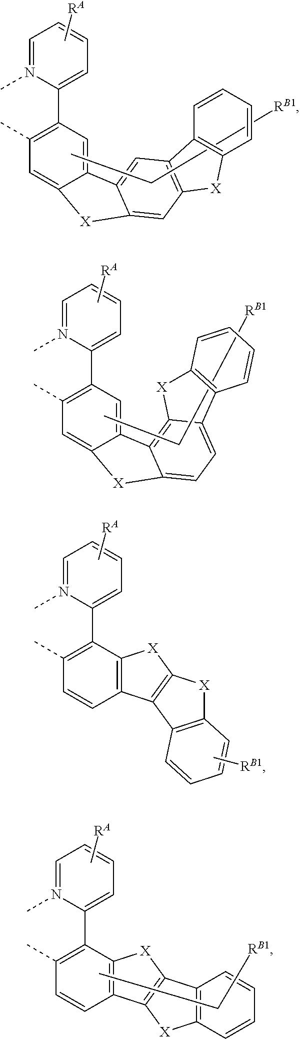 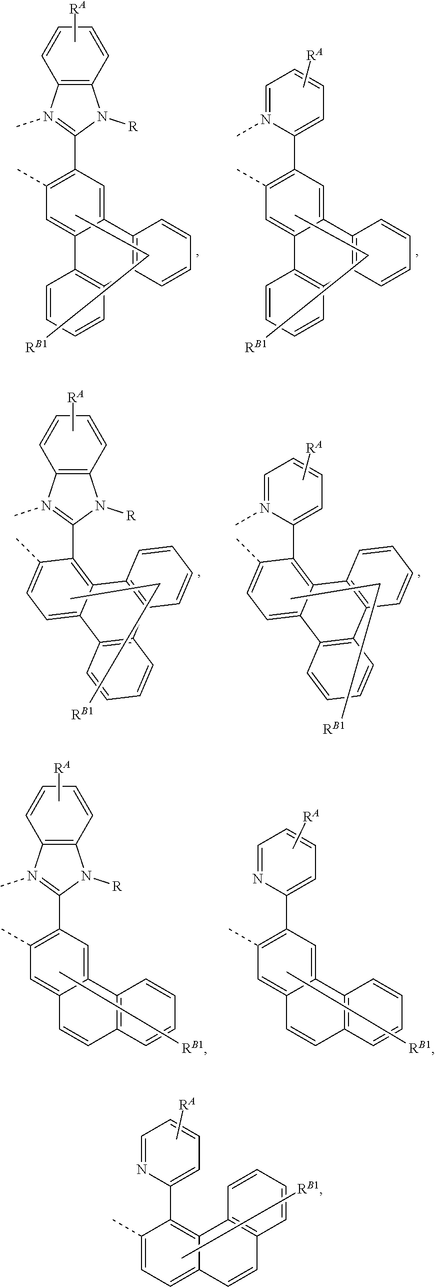 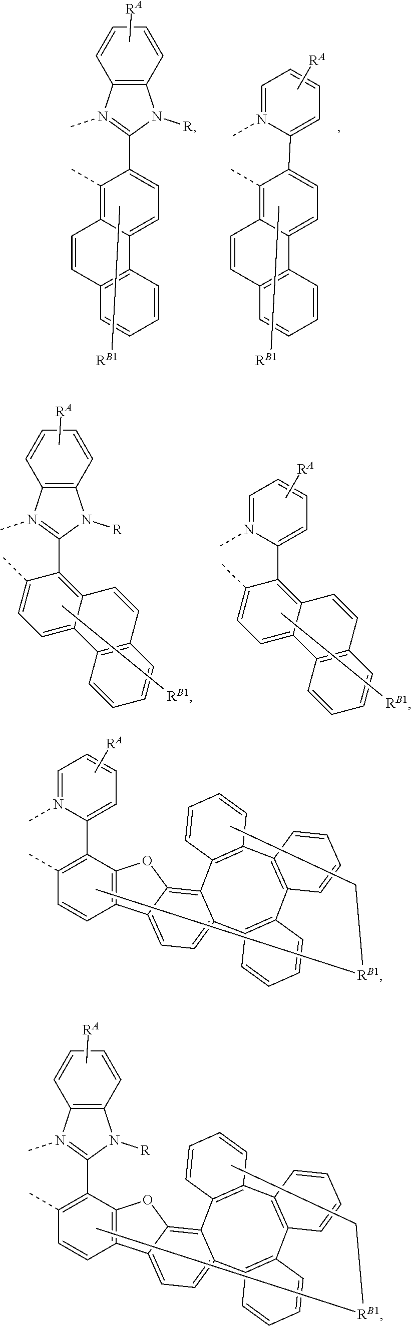 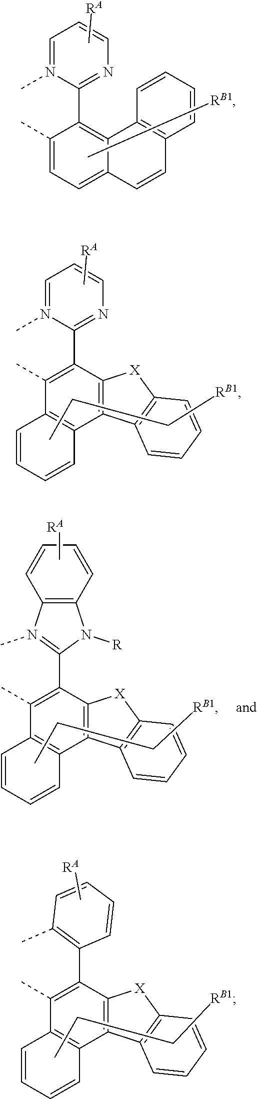
wherein:
R^{B1} represents mono to the maximum possible number of substitutions, or no substitution;
each R and R^{B1} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
at least one R^{B1} comprises a cyclic group or an electron-withdrawing group; and
two adjacent R^{B1} can be joined to form a ring.

9. The compound of claim 1, wherein the ligand L_{A} is selected from the group consisting of L_{Ai}-(Rⁿ)(R^{m})(E^{o})(W^{t}), wherein i is an integer from 1 to 152, n and m are each independently an integer from 1 to 70, o is an integer from 1 to 125, and t is an integer from 1 to 16; wherein L_{A1}-(R1)(R1)(E1)(W1) to L_{A152}-(R70)(R70)(E125)(W16) are defined as follows:

| L_{A} | Structure of L_{A} |
|---|---|
| LA1-(Rn)(Rm)(Eo)(Wt), wherein LA1 (R1)(R1)(E1)(W1) to LA1-(R70)(R70)(E125)(W16) have the structure | 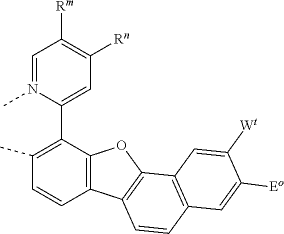 |
| LA2-(Rn)(Rm)(Eo)(Wt), wherein LA2 (R1)(R1)(E1)(W1) to LA2-(R70)(R70)(E125)(W16) have the structure | 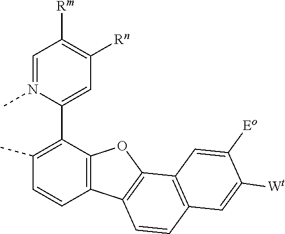 |
| LA3-(Rn)(Rm)(Eo)(Wt), wherein LA3 (R1)(R1)(El)(W1) to LA3-(R70)(R70)(E125)(W16) have the structure | 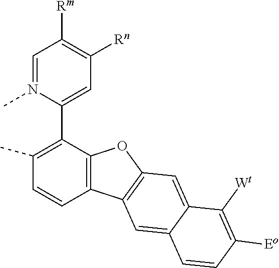 |
| LA4-(Rn)(Rm)(Eo)(Wt), wherein LA4 (R1)(R1)(E1)(W1) to LA4-(R70)(R70)(E125)(W16) have the structure | 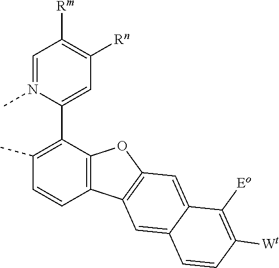 |
| LA5-(Rn)(Rm)(Eo)(Wt), wherein LA5 (R1)(R1)(El)(W1) to LA5-(R70)(R70)(E125)(W16) have the structure | 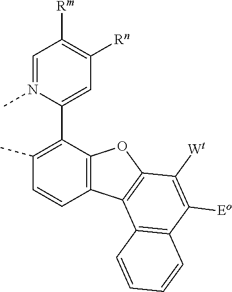 |
| LA6-(Rn)(Rm)(Eo)(Wt), wherein LA6 (R1)(R1)(E1)(W1) to LA6-(R70)(R70)(E125)(W16) have the structure | 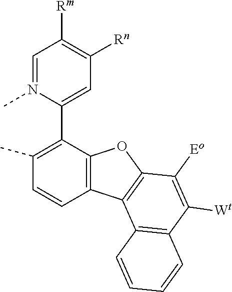 |
| LA7-(Rn)(Rm)(Eo)(Wt), wherein LA7 (R1)(R1)(E1)(W1) to LA7-(R70)(R70)(E125)(W16) have the structure | 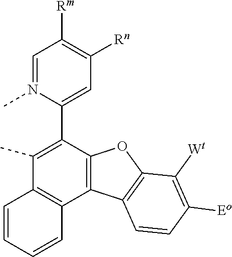 |
| LA8-(Rn)(Rm)(Eo)(Wt), wherein LA8- (R1)(R1)(E1)(W1) to LA8-(R70)(R70)(E125) (W16) have the structure | 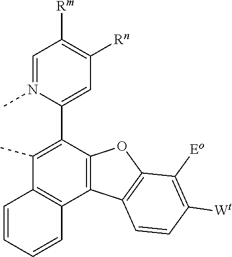 |
| LA9-(Rn)(Rm)(Eo)(Wt), wherein LA9 (R1)(R1)(E1)(W1) to LA9-(R70)(R70)(E125)(W16) have the structure | 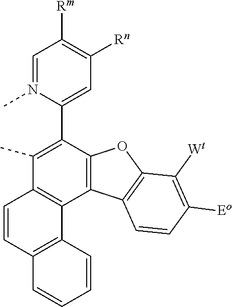 |
| LA10-(Rn)(Rm)(Eo)(Wt), wherein LA10 (R1)(R1)(E1)(W1) to LA10-(R70)(R70)(E125)(W16) have the structure | 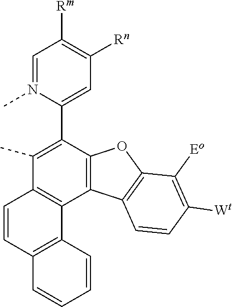 |
| LA11-(Rn)(Rm)(Eo)(Wt), wherein LA11 (R1)(R1)(E1)(W1) to LA11-(R70)(R70)(E125)(W16) have the structure | 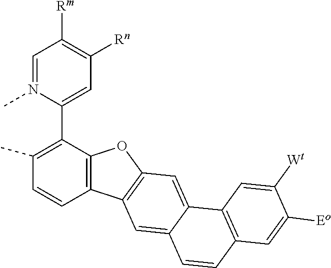 |
| LA12-(Rn)(Rm)(Eo)(Wt), wherein LA12- (R1)(R1)(E1)(W1) to LA12-(R70)(R70)(E125) (W16) have the structure | 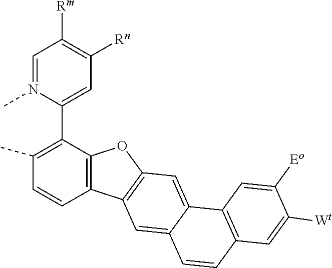 |
| LA13-(Rn)(Rm)(Eo)(Wt), wherein LA13- (R1)(R1)(E1)(W1) to LA13-(R70)(R70)(E125) (W16) have the structure | 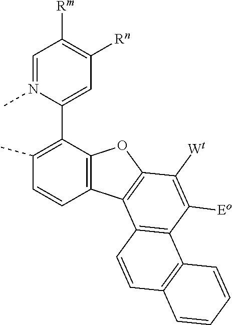 |
| LA14-(Rn)(Rm)(Eo)(Wt), wherein LA14- (R1)(R1)(E1)(W1) to LA14-(R70)(R70)(E125) (W16) have the structure | 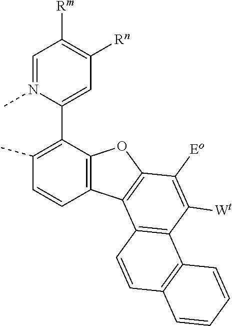 |
| LA15-(Rn)(Rm)(Eo)(Wt), wherein LA15- (R1)(R1)(E1)(W1) to LA15-(R70)(R70)(E125) (W16) have the structure | 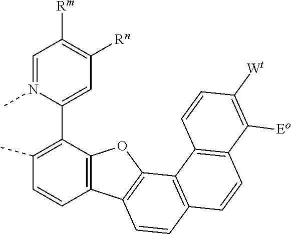 |
| LA16-(Rn)(Rm)(Eo)(Wt), wherein LA16- (R1)(R1)(E1)(W1) to LA16-(R70)(R70)(E125) (W16) have the structure | 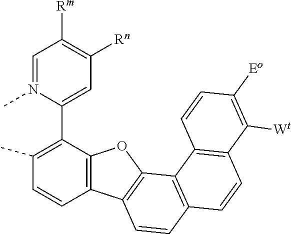 |
| LA17-(Rn)(Rm)(Eo)(Wt), wherein LA17- (R1)(R1)(E1)(W1) to LA17-(R70)(R70)(E125) (W16) have the structure | 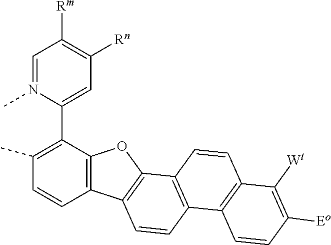 |
| LA18-(Rn)(Rm)(Eo)(Wt), wherein LA18- (R1)(R1)(E1)(W1) to LA18-(R70)(R70)(E125) (W16) have the structure | 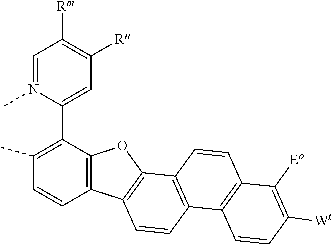 |
| LA19-(Rn)(Rm)(Eo)(Wt), wherein LA19 (R1)(R1)(El)(W1) to LA19-(R70)(R70)(E125)(W16) have the structure | 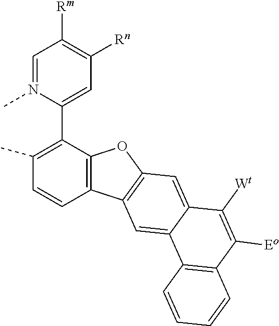 |
| LA20-(Rn)(Rm)(Eo)(Wt), wherein LA20- (R1)(R1)(E1)(W1) to LA20-(R70)(R70)(E125) (W16) have the structure | 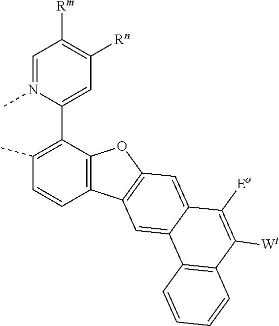 |
| LA21-(Rn)(Rm)(Eo)(Wt), wherein LA21- (R1)(R1)(E1)(W1) to LA21-(R70)(R70)(E125) (W16) have the structure | 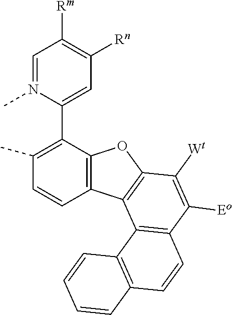 |
| LA22-(Rn)(Rm)(Eo)(Wt), wherein LA22- (R1)(R1)(E1)(W1) to LA22-(R70)(R70)(E125) (W16) have the structure | 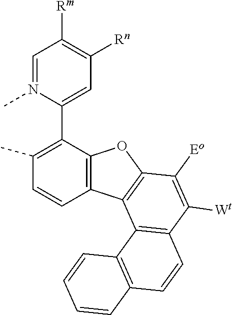 |
| LA23-(Rn)(Rm)(Eo)(Wt), wherein LA23- (R1)(R1)(El)(W1) to LA23-(R70)(R70)(E125) (W16) have the structure | 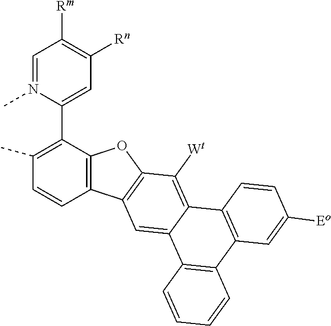 |
| LA24-(Rn)(Rm)(Eo)(Wt), wherein LA24- (R1)(R1)(E1)(W1) to LA24-(R70)(R70)(E125) (W16) have the structure | 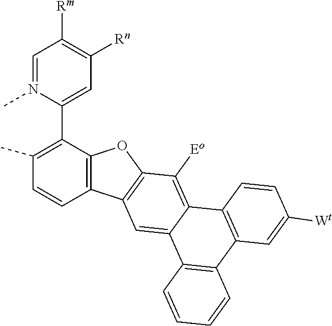 |
| LA25-(Rn)(Rm)(Eo)(Wt), wherein LA25- (R1)(R1)(E1)(W1) to LA25-(R70)(R70)(E125) (W16) have the structure | 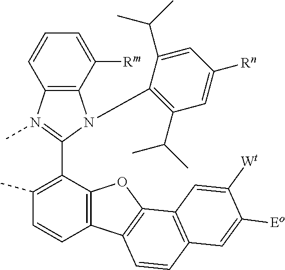 |
| LA26-(Rn)(Rm)(Eo)(Wt), wherein LA26- (R1)(R1)(E1)(W1) to LA26-(R70)(R70)(E125) (W16) have the structure | 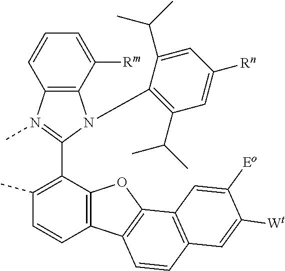 |
| LA27-(Rn)(Rm)(Eo)(Wt), wherein LA27- (R1)(R1)(E1)(W1) to LA27-(R70)(R70)(E125) (W16) have the structure | 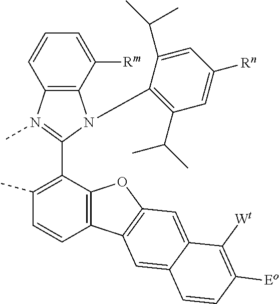 |
| LA28-(Rn)(Rm)(Eo)(Wt), wherein LA28- (R1)(R1)(E1)(W1) to LA28-(R70)(R70)(E125) (W16) have the structure | 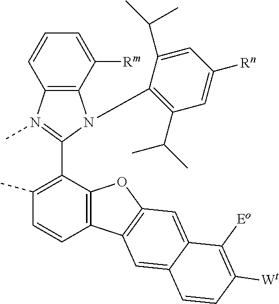 |
| LA29-(Rn)(Rm)(Eo)(Wt), wherein LA29- (R1)(R1)(E1)(W1) to LA29-(R70)(R70)(E125) (W16) have the structure | 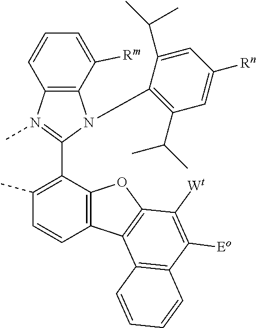 |
| LA30-(Rn)(Rm)(Eo)(Wt), wherein LA30- (R1)(R1)(E1)(W1) to LA30-(R70)(R70)(E125) (W16) have the structure | 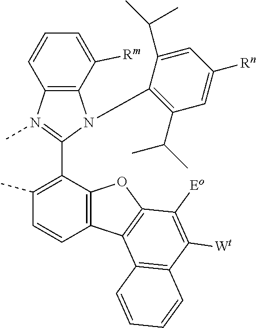 |
| LA31-(Rn)(Rm)(Eo)(Wt), wherein LA31- (R1)(R1)(E1)(W1) to LA31-(R70)(R70)(E125) (W16) have the structure | 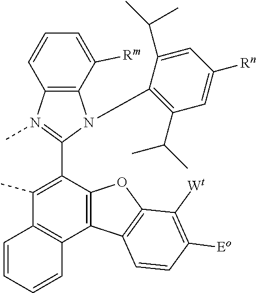 |
| LA32-(Rn)(Rm)(Eo)(Wt), wherein LA32- (R1)(R1)(E1)(W1) to LA32-(R70)(R70)(E125) (W16) have the structure | 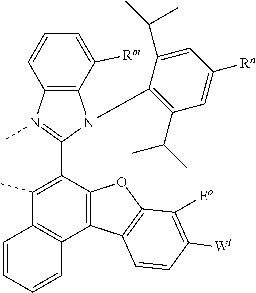 |
| LA33-(Rn)(Rm)(Eo)(Wt), wherein LA33- (R1)(R1)(El)(W1) to LA33-(R70)(R70)(E125) (W16) have the structure | 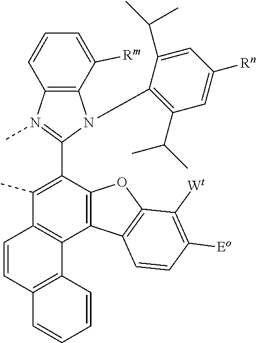 |
| LA34-(Rn)(Rm)(Eo)(Wt), wherein LA34- (R1)(R1)(E1)(W1) to LA34-(R70)(R70)(E125) (W16) have the structure | 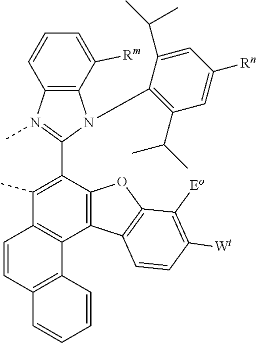 |
| LA35-(Rn)(Rm)(Eo)(Wt), wherein LA35- (R1)(R1)(E1)(W1) to LA35-(R70)(R70)(E125) (W16) have the structure | 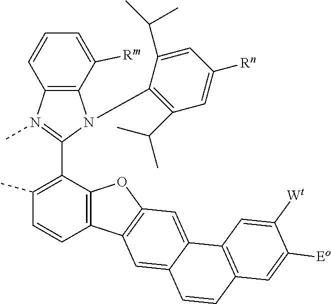 |
| LA36-(Rn)(Rm)(Eo)(Wt), wherein LA36- (R1)(R1)(E1)(W1) to LA36-(R70)(R70)(E125) (W16) have the structure | 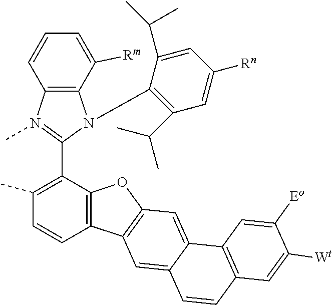 |
| LA37-(Rn)(Rm)(Eo)(Wt), wherein LA37- (R1)(R1)(E1)(W1) to LA37-(R70)(R70)(E125) (W16) have the structure | 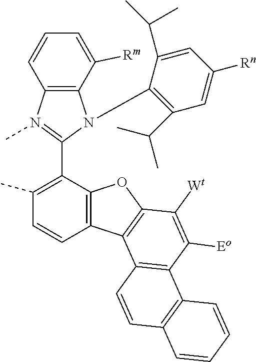 |
| LA38-(Rn)(Rm)(Eo)(Wt), wherein LA38- (R1)(R1)(E1)(W1) to LA38-(R70)(R70)(E125) (W16) have the structure | 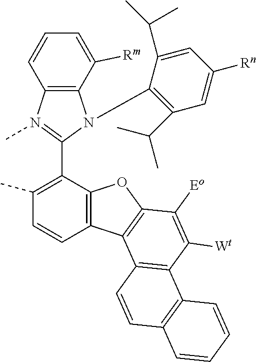 |
| LA39-(Rn)(Rm)(Eo)(Wt), wherein LA39- (R1)(R1)(E1)(W1) to LA39-(R70)(R70)(E125) (W16) have the structure | 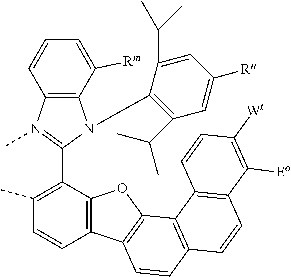 |
| LA40-(Rn)(Rm)(Eo)(Wt), wherein LA40- (R1)(R1)(E1)(W1) to LA40-(R70)(R70)(E125) (W16) have the structure | 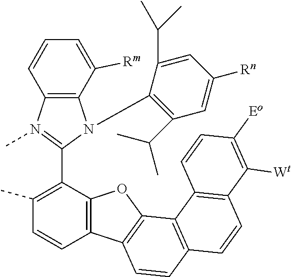 |
| LA41-(Rn)(Rm)(Eo)(Wt), wherein LA41- (R1)(R1)(E1)(W1) to LA41-(R70)(R70)(E125) (W16) have the structure | 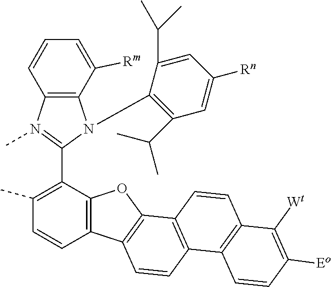 |
| LA42-(Rn)(Rm)(Eo)(Wt), wherein LA42- (R1)(R1)(E1)(W1) to LA42-(R70)(R70)(E125) (W16) have the structure | 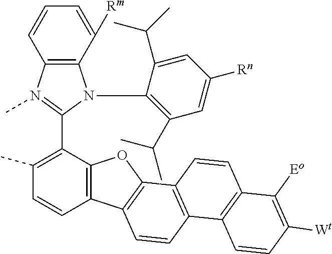 |
| LA43-(Rn)(Rm)(Eo)(Wt), wherein LA43- (R1)(R1)(E1)(W1) to LA43-(R70)(R70)(E125) (W16) have the structure | 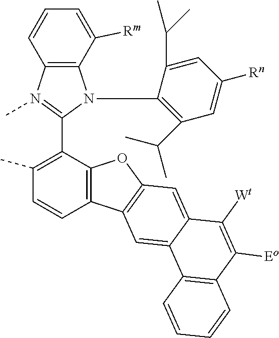 |
| LA44-(Rn)(Rm)(Eo)(Wt), wherein LA44- (R1)(R1)(E1)(W1) to LA44-(R70)(R70)(E125) (W16) have the structure | 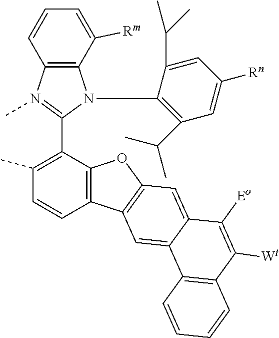 |
| LA45-(Rn)(Rm)(Eo)(Wt), wherein LA45- (R1)(R1)(E1)(W1) to LA45-(R70)(R70)(E125) (W16) have the structure | 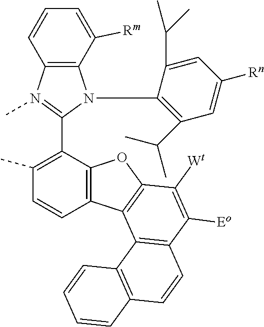 |
| LA46-(Rn)(Rm)(Eo)(Wt), wherein LA46- (R1)(R1)(E1)(W1) to LA46-(R70)(R70)(E125) (W16) have the structure | 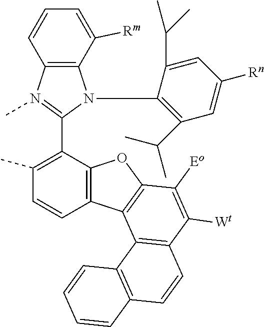 |
| LA47-(Rn)(Rm)(Eo)(Wt), wherein LA47- (R1)(R1)(E1)(W1) to LA47-(R70)(R70)(E125) (W16) have the structure | 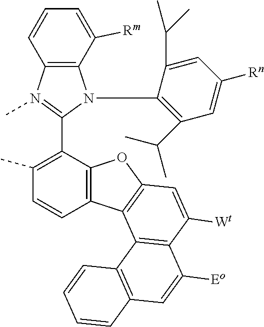 |
| LA48-(Rn)(Rm)(Eo)(Wt), wherein LA48- (R1)(R1)(E1)(W1) to LA48-(R70)(R70)(E125) (W16) have the structure | 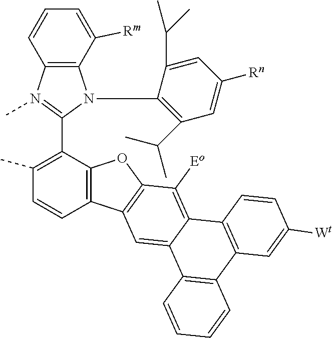 |
| LA49-(Rn)(Rm)(Eo)(Wt), wherein LA49- (R1)(R1)(E1)(W1) to LA49-(R70)(R70)(E125) (W16) have the structure | 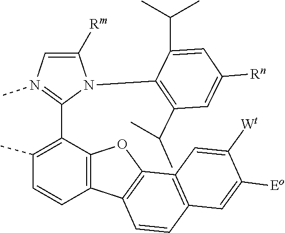 |
| LA50-(Rn)(Rm)(Eo)(Wt), wherein LA50- (R1)(R1)(E1)(W1) to LA50-(R70)(R70)(E125) (W16) have the structure | 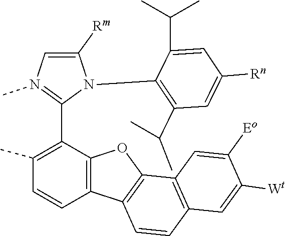 |
| LA51-(Rn)(Rm)(Eo)(Wt), wherein LA51- (R1)(R1)(E1)(W1) to LA51-(R70)(R70)(E125) (W16) have the structure | 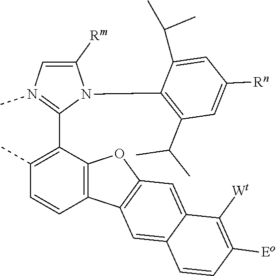 |
| LA52-(Rn)(Rm)(Eo)(Wt), wherein LA52- (R1)(R1)(El)(W1) to LA52-(R70)(R70)(E125) (W16) have the structure | 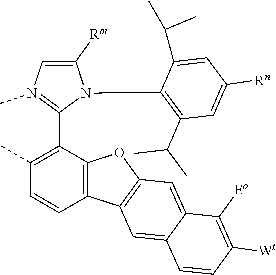 |
| LA53-(Rn)(Rm)(Eo)(Wt), wherein LA53- (R1)(R1)(E1)(W1) to LA53-(R70)(R70)(E125) (W16) have the structure | 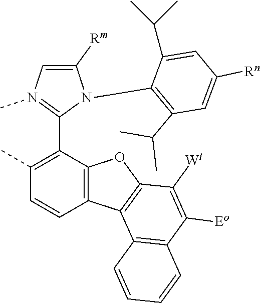 |
| LA54-(Rn)(Rm)(Eo)(Wt), wherein LA54- (R1)(R1)(E1)(W1) to LA54-(R70)(R70)(E125) (W16) have the structure | 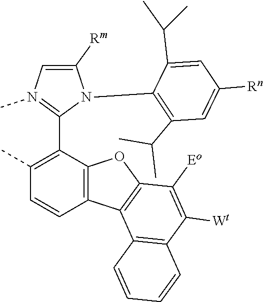 |
| LA55-(Rn)(Rm)(Eo)(Wt), wherein LA55- (R1)(R1)(E1)(W1) to LA55-(R70)(R70)(E125) (W16) have the structure | 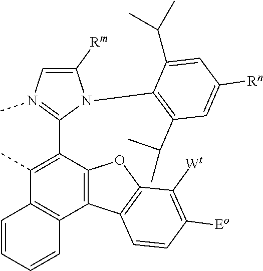 |
| LA56-(Rn)(Rm)(Eo)(Wt), wherein LA56- (R1)(R1)(E1)(W1) to LA56-(R70)(R70)(E125) (W16) have the structure | 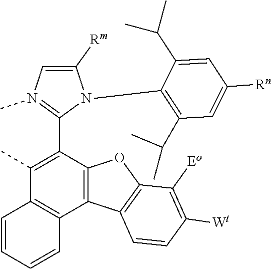 |
| LA57-(Rn)(Rm)(Eo)(Wt), wherein LA57- (R1)(R1)(E1)(W1) to LA57-(R70)(R70) (E125)(W16) have the structure | 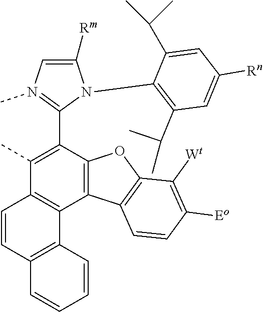 |
| LA58-(Rn)(Rm)(Eo)(Wt), wherein LA58- (R1)(R1)(E1)(W1) to LA58-(R70)(R70) (E125)(W16) have the structure | 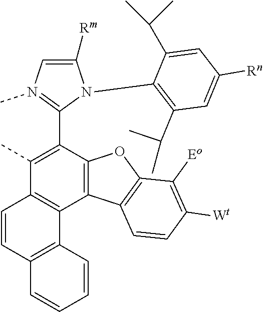 |
| LA59-(Rn)(Rm)(Eo)(Wt), wherein LA59- (R1)(R1)(E1)(W1) to LA59-(R70)(R70) (E125)(W16) have the structure | 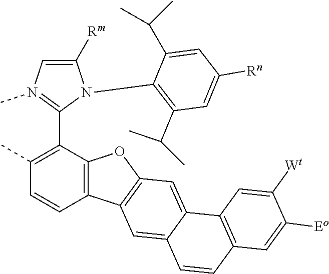 |
| LA60-(Rn)(Rm)(Eo)(Wt), wherein LA60- (R1)(R1)(E1)(W1) to LA60-(R70)(R70) (E125)(W16) have the structure | 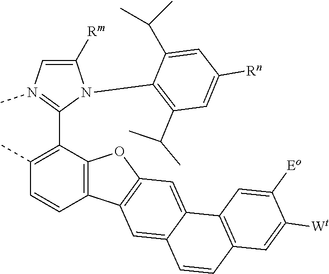 |
| LA61-(Rn)(Rm)(Eo)(Wt), wherein LA61- (R1)(R1)(E1)(W1) to LA61-(R70)(R70) (E125)(W16) have the structure | 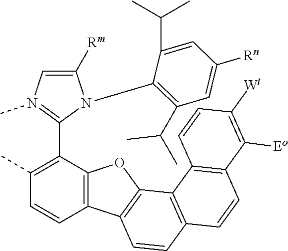 |
| LA62-(Rn)(Rm)(Eo)(Wt), wherein LA62- (R1)(R1)(E1)(W1) to LA62-(R70)(R70) (E125)(W16) have the structure | 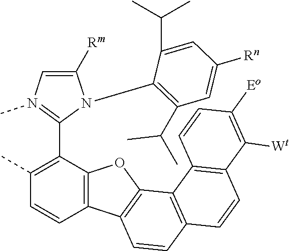 |
| LA63-(Rn)(Rm)(Eo)(Wt), wherein LA63- (R1)(R1)(E1)(W1) to LA63-(R70)(R70) (E125)(W16) have the structure | 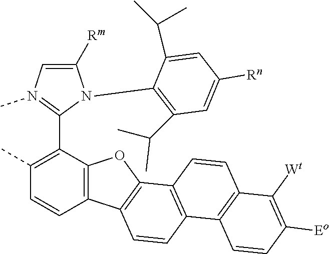 |
| LA64-(Rn)(Rm)(Eo)(Wt), wherein LA64- (R1)(R1)(E1)(W1) to LA64-(R70)(R70) (E125)(W16) have the structure | 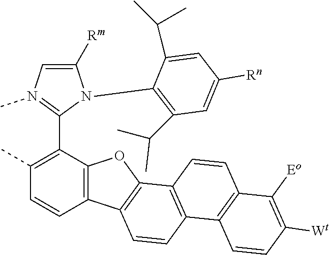 |
| LA65-(Rn)(Rm)(Eo)(Wt), wherein LA65- (R1)(R1)(E1)(W1) to LA65-(R70)(R70) (E125)(W16) have the structure | 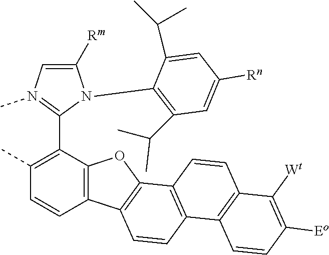 |
| LA66-(Rn)(Rm)(Eo)(Wt), wherein LA66- (R1)(R1)(E1)(W1) to LA66-(R70)(R70) (E125)(W16) have the structure | 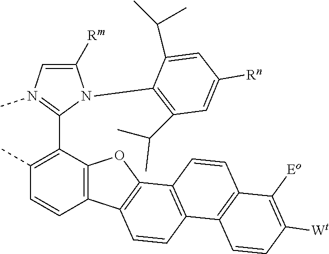 |
| LA67-(Rn)(Rm)(Eo)(Wt), wherein LA67- (R1)(R1)(E1)(W1) to LA67-(R70)(R70) (E125)(W16) have the structure | 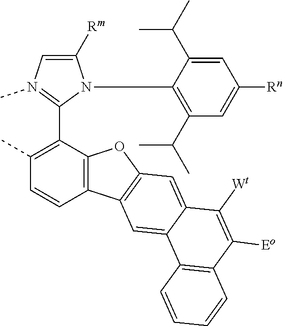 |
| LA68-(Rn)(Rm)(Eo)(Wt), wherein LA68- (R1)(R1)(E1)(W1) to LA68-(R70)(R70) (E125)(W16) have the structure | 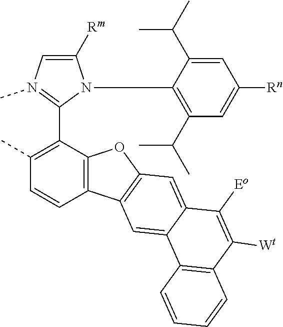 |
| LA69-(Rn)(Rm)(Eo)(Wt), wherein LA69- (R1)(R1)(E1)(W1) to LA69-(R70)(R70) (E125)(W16) have the structure | 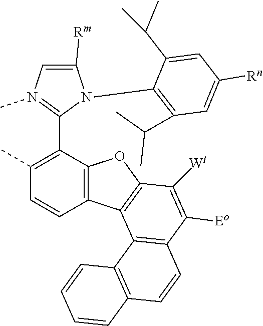 |
| LA70-(Rn)(Rm)(Eo)(Wt), wherein LA70- (R1)(R1)(E1)(W1) to LA70-(R70)(R70) (E125)(W16) have the structure | 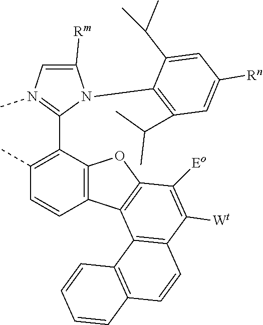 |
| LA71-(Rn)(Rm)(Eo)(Wt), wherein LA71- (R1)(R1)(E1)(W1) to LA71-(R70)(R70) (E125)(W16) have the structure | 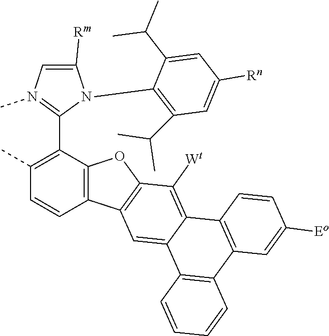 |
| LA72-(Rn)(Rm)(Eo)(Wt), wherein LA72- (R1)(R1)(E1)(W1) to LA72-(R70)(R70) (E125)(W16) have the structure | 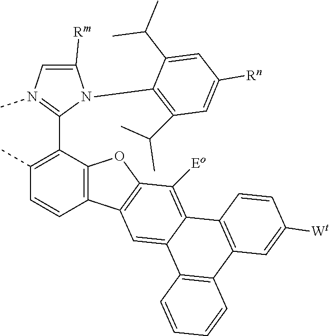 |
| LA73-(Rn)(Rm)(Eo)(Wt), wherein LA73- (R1)(R1)(E1)(W1) to LA73-(R70)(R70) (E125)(W16) have the structure | 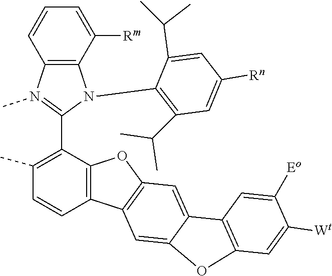 |
| LA75-(Rn)(Rm)(Eo)(Wt), wherein LA75- (R1)(R1)(E1)(W1) to LA75-(R70)(R70) (E125)(W16) have the structure | 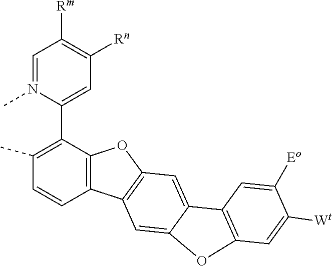 |
| LA76-(Rn)(Rm)(Eo)(Wt), wherein LA76- (R1)(R1)(E1)(W1) to LA76-(R70)(R70) (E125)(W16) have the structure | 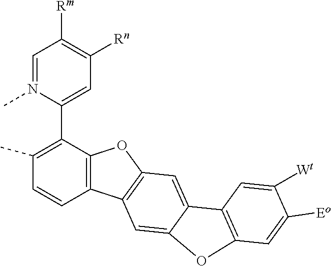 |
| LA77-(Rn)(Rm)(Eo)(Wt), wherein LA77- (R1)(R1)(E1)(W1) to LA77-(R70)(R70) (E125)(W16) have the structure | 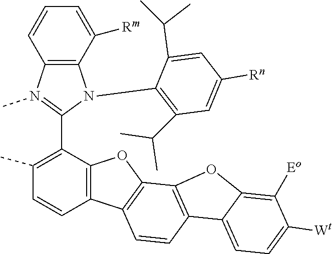 |
| LA78-(Rn)(Rm)(Eo)(Wt), wherein LA78- (R1)(R1)(E1)(W1) to LA78-(R70)(R70) (E125)(W16) have the structure | 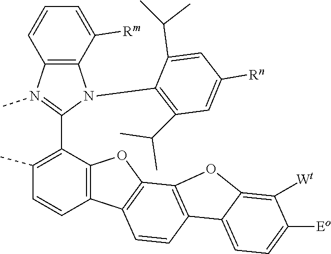 |
| LA79-(Rn)(Rm)(Eo)(Wt), wherein LA79- (R1)(R1)(E1)(W1) to LA79-(R70)(R70) (E125)(W16) have the structure | 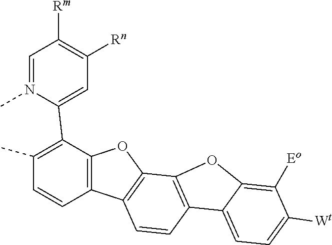 |
| LA80-(Rn)(Rm)(Eo)(Wt), wherein LA80- (R1)(R1)(E1)(W1) to LA80-(R70)(R70) (E125)(W16) have the structure | 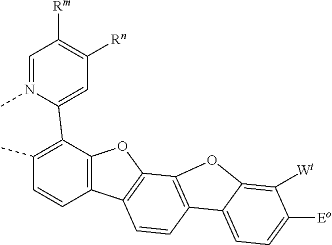 |
| LA81-(Rn)(Rm)(Eo)(Wt), wherein LA81- (R1)(R1)(E1)(W1) to LA81-(R70)(R70) (E125)(W16) have the structure | 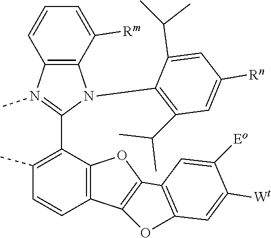 |
| LA82-(Rn)(Rm)(Eo)(Wt), wherein LA82- (R1)(R1)(E1)(W1) to LA82-(R70)(R70) (E125)(W16) have the structure | 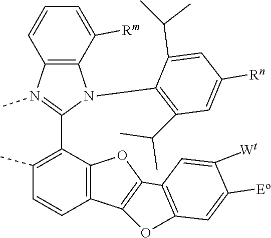 |
| LA83-(Rn)(Rm)(Eo)(Wt), wherein LA83- (R1)(R1)(E1)(W1) to LA83-(R70)(R70) (E125)(W16) have the structure | 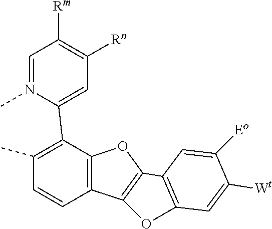 |
| LA84-(Rn)(Rm)(Eo)(Wt), wherein LA84- (R1)(R1)(El)(W1) to LA84-(R70)(R70) (E125)(W16) have the structure | 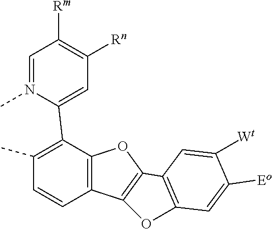 |
| LA85-(Rn)(Rm)(Eo)(Wt), wherein LA85- (R1)(R1)(E1)(W1) to LA85-(R70)(R70) (E125)(W16) have the structure | 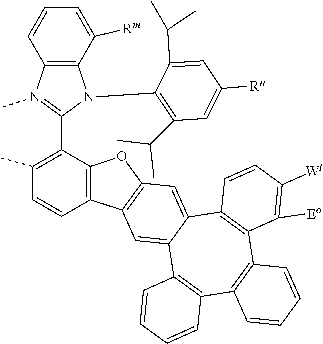 |
| LA86-(Rn)(Rm)(Eo)(Wt), wherein LA86- (R1)(R1)(E1)(W1) to LA86-(R70)(R70) (E125)(W16) have the structure | 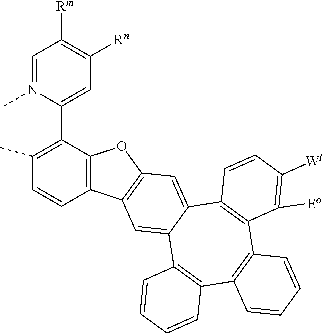 |
| LA87-(Rn)(Rm)(Eo)(Wt), wherein LA87- (R1)(R1)(E1)(W1) to LA87-(R70)(R70) (E125)(W16) have the structure | 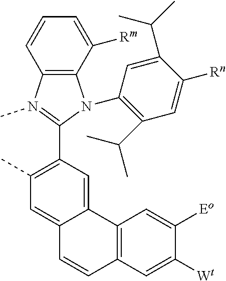 |
| LA88-(Rn)(Rm)(Eo)(Wt), wherein LA88- (R1)(R1)(E1)(W1) to LA88-(R70)(R70) (E125)(W16) have the structure | 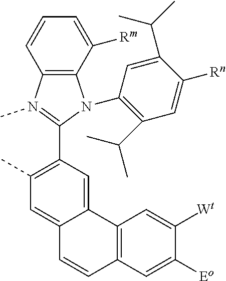 |
| LA89-(Rn)(Rm)(Eo)(Wt), wherein LA89- (R1)(R1)(E1)(W1) to LA89-(R70)(R70) (E125)(W16) have the structure | 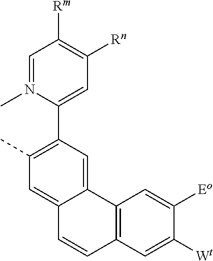 |
| LA90-(Rn)(Rm)(Eo)(Wt), wherein LA90- (R1)(R1)(E1)(W1) to LA90-(R70)(R70) (E125)(W16) have the structure | 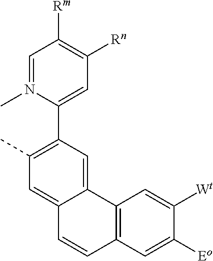 |
| LA91-(Rn)(Rm)(Eo)(Wt), wherein LA91- (R1)(R1)(E1)(W1) to LA91-(R70)(R70) (E125)(W16) have the structure | 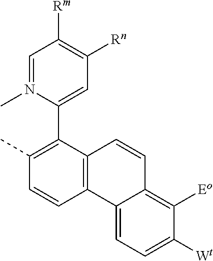 |
| LA92-(Rn)(Rm)(Eo)(Wt), wherein LA92- (R1)(R1)(E1)(W1) to LA92-(R70)(R70) (E125)(W16) have the structure | 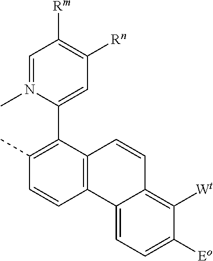 |
| LA93-(Rn)(Rm)(Eo)(Wt), wherein LA93- (R1)(R1)(E1)(W1) to LA93-(R70)(R70) (E125)(W16) have the structure | 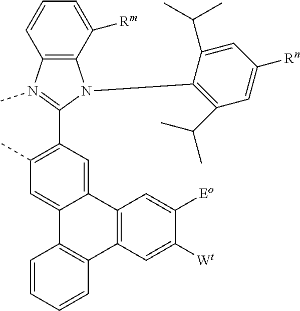 |
| LA94-(Rn)(Rm)(Eo)(Wt), wherein LA94- (R1)(R1)(E1)(W1) to LA94-(R70)(R70) (E125)(W16) have the structure | 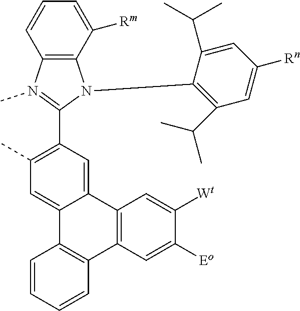 |
| LA95-(Rn)(Rm)(Eo)(Wt), wherein LA95- (R1)(R1)(E1)(W1) to LA95-(R70)(R70) (E125)(W16) have the structure | 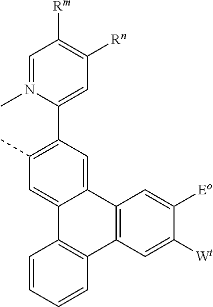 |
| LA96-(Rn)(Rm)(Eo)(Wt), wherein LA96- (R1)(R1)(E1)(W1) to LA96-(R70)(R70) (E125)(W16) have the structure | 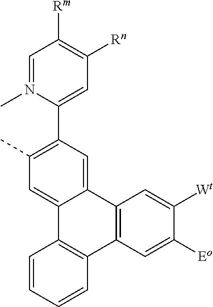 |
| LA97-(Rn)(Rm)(Eo)(Wt), wherein LA97- (R1)(R1)(E1)(W1) to LA97-(R70)(R70) (E125)(W16) have the structure | 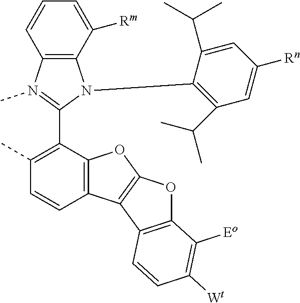 |
| LA98-(Rn)(Rm)(Eo)(Wt), wherein LA98- (R1)(R1)(E1)(W1) to LA98-(R70)(R70) (E125)(W16) have the structure | 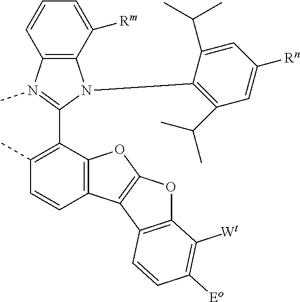 |
| LA99-(Rn)(Rm)(Eo)(Wt), wherein LA99- (R1)(R1)(E1)(W1) to LA99-(R70)(R70) (E125)(W16) have the structure | 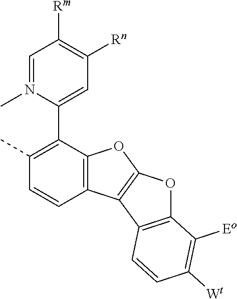 |
| LA100- (Rn)(Rm)(Eo)(Wt), wherein LA100- (R1)(R1)(E1)(W1) to LA100-(R70)(R70) (E125)(W16) have the structure | 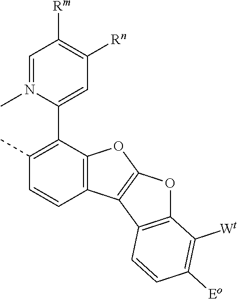 |
| LA101- (Rn)(Rm)(Eo)(Wt), wherein LA101- (R1)(R1)(E1)(W1) to LA101-(R70)(R70) (E125)(W16) have the structure | 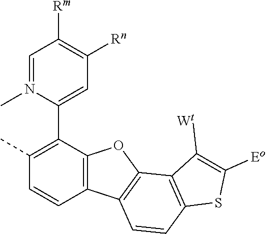 |
| LA102- (Rn)(Rm)(Eo)(Wt), wherein LA102- (R1)(R1)(E1)(W1) to LA102-(R70)(R70) (E125)(W16) have the structure | 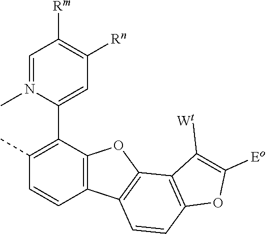 |
| LA103- (Rn)(Rm)(Eo)(Wt), wherein LA103- (R1)(R1)(E1)(W1) to LA103-(R70)(R70) (E125)(W16) have the structure | 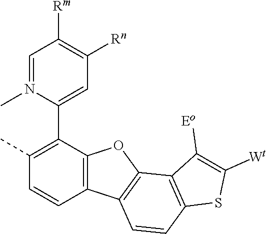 |
| LA104- (Rn)(Rm)(Eo)(Wt), wherein LA104- (R1)(R1)(E1)(W1) to LA104-(R70)(R70) (E125)(W16) have the structure | 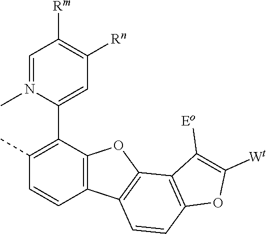 |
| LA105- (Rn)(Rm)(Eo)(Wt), wherein LA105- (R1)(R1)(E1)(W1) to LA105-(R70)(R70) (E125)(W16) have the structure | 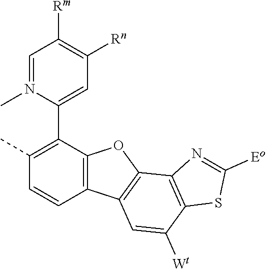 |
| LA106- (Rn)(Rm)(Eo)(Wt), wherein LA106- (R1)(R1)(E1)(W1) to LA106-(R70)(R70) (E125)(W16) have the structure | 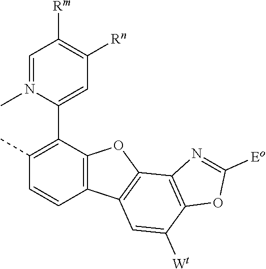 |
| LA107- (Rn)(Rm)(Eo)(Wt), wherein LA107- (R1)(R1)(E1)(W1) to LA107-(R70)(R70) (E125)(W16) have the structure | 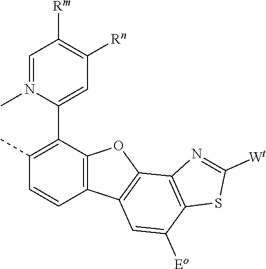 |
| LA108- (Rn)(Rm)(Eo)(Wt), wherein LA108- (R1)(R1)(E1)(W1) to LA108-(R70)(R70) (E125)(W16) have the structure | 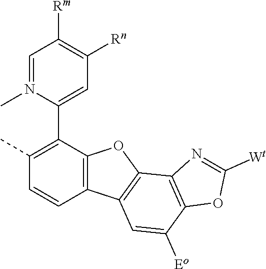 |
| LA109- (Rn)(Rm)(Eo)(Wt), wherein LA109- (R1)(R1)(E1)(W1) to LA109-(R70)(R70) (E125)(W16) have the structure | 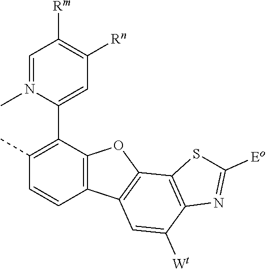 |
| LA110- (Rn)(Rm)(Eo)(Wt), wherein LA110- (R1)(R1)(E1)(W1) to LA110-(R70)(R70) (E125)(W16) have the structure | 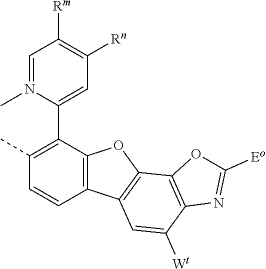 |
| LA111- (Rn)(Rm)(Eo)(Wt), wherein LA111- (R1)(R1)(E1)(W1) to LA111-(R70)(R70) (E125)(W16) have the structure | 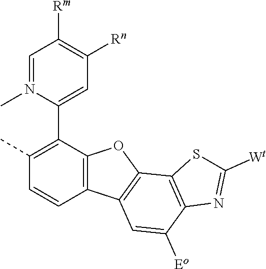 |
| LA112- (Rn)(Rm)(Eo)(Wt), wherein LA112- (R1)(R1)(E1)(W1) to LA112-(R70)(R70) (E125)(W16) have the structure | 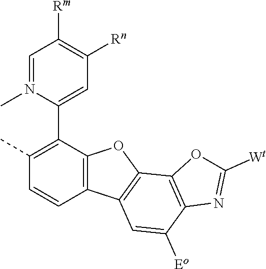 |
| LA113- (Rn)(Rm)(Eo)(Wt), wherein LA113- (R1)(R1)(E1)(W1) to LA113-(R70)(R70) (E125)(W16) have the structure | 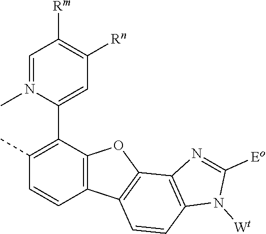 |
| LA114- (Rn)(Rm)(Eo)(Wt), wherein LA114- (R1)(R1)(E1)(W1) to LA114-(R70)(R70) (E125)(W16) have the structure | 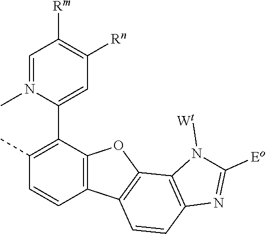 |
| LA115- (Rn)(Rm)(Eo)(Wt), wherein LA115- (R1)(R1)(E1)(W1) to LA115-(R70)(R70) (E125)(W16) have the structure | 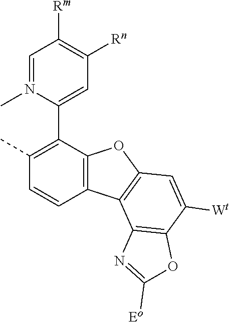 |
| LA116- (Rn)(Rm)(Eo)(Wt), wherein LA116- (R1)(R1)(E1)(W1) to LA116-(R70)(R70) (E125)(W16) have the structure | 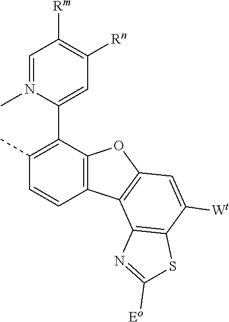 |
| LA117- (Rn)(Rm)(Eo)(Wt), wherein LA117- (R1)(R1)(E1)(W1) to LA117-(R70)(R70) (E125)(W16) have the structure | 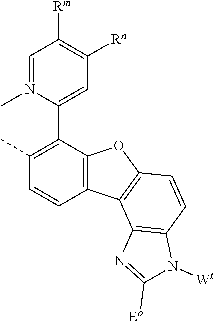 |
| LA118- (Rn)(Rm)(Eo)(Wt), wherein LA118- (R1)(R1)(E1)(W1) to LA118-(R70)(R70) (E125)(W16) have the structure | 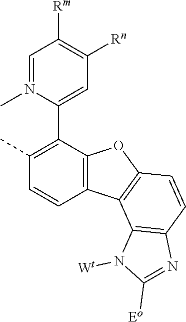 |
| LA119- (Rn)(Rm)(Eo)(Wt), wherein LA119- (R1)(R1)(E1)(W1) to LA119-(R70)(R70) (E125)(W16) have the structure | 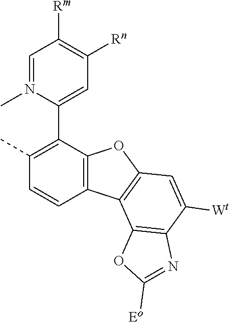 |
| LA120- (Rn)(Rm)(Eo)(Wt), wherein LA120- (R1)(R1)(E1)(W1) to LA120-(R70)(R70) (E125)(W16) have the structure | 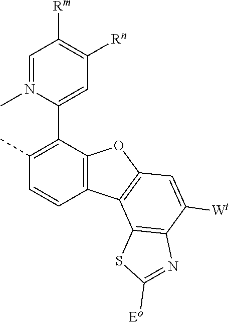 |
| LA121- (Rn)(Rm)(Eo)(Wt), wherein LA121- (R1)(R1)(E1)(W1) to LA121-(R70)(R70) (E125)(W16) have the structure | 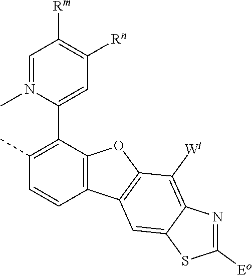 |
| LA122- (Rn)(Rm)(Eo)(Wt), wherein LA122- (R1)(R1)(E1)(W1) to LA122-(R70)(R70) (E125)(W16) have the structure | 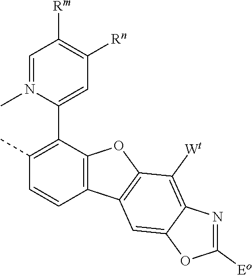 |
| LA123- (Rn)(Rm)(Eo)(Wt), wherein LA123- (R1)(R1)(E1)(W1) to LA123-(R70)(R70) (E125)(W16) have the structure | 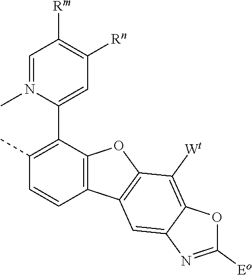 |
| LA124- (Rn)(Rm)(Eo)(Wt), wherein LA124- (R1)(R1)(E1)(W1) to LA124-(R70)(R70) (E125)(W16) have the structure | 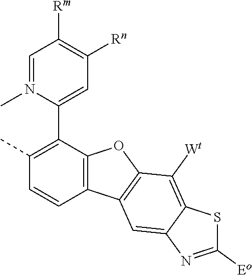 |
| LA125- (Rn)(Rm)(Eo)(Wt), wherein LA125- (R1)(R1)(E1)(W1) to LA125-(R70)(R70) (E125)(W16) have the structure | 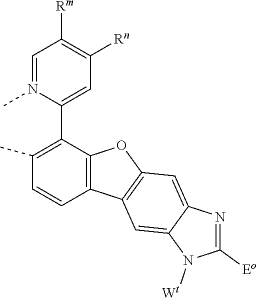 |
| LA126- (Rn)(Rm)(Eo)(Wt), wherein LA126- (R1)(R1)(E1)(W1) to LA126-(R70)(R70) (E125)(W16) have the structure | 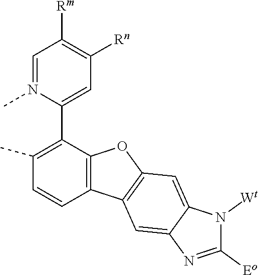 |
| LA127- (Rn)(Rm)(Eo)(Wt), wherein LA127- (R1)(R1)(E1)(W1) to LA127-(R70)(R70) (E125)(W16) have the structure | 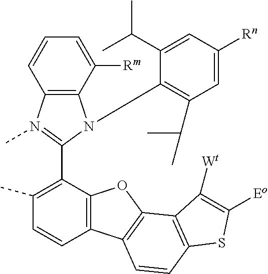 |
| LA128- (Rn)(Rm)(Eo)(Wt), wherein LA128- (R1)(R1)(E1)(W1) to LA128-(R70)(R70) (E125)(W16) have the structure | 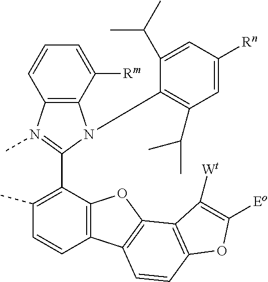 |
| LA129- (Rn)(Rm)(Eo)(Wt), wherein LA129- (R1)(R1)(E1)(W1) to LA129-(R70)(R70) (E125)(W16) have the structure | 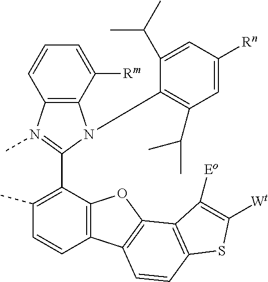 |
| LA130- (Rn)(Rm)(Eo)(Wt), wherein LA130- (R1)(R1)(E1)(W1) to LA130-(R70)(R70) (E125)(W16) have the structure | 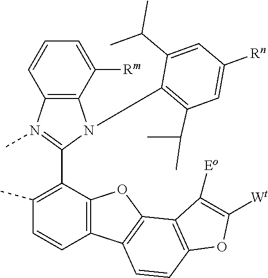 |
| LA131- (Rn)(Rm)(Eo)(Wt), wherein LA131- (R1)(R1)(El)(W1) to LA131-(R70)(R70) (E125)(W16) have the structure | 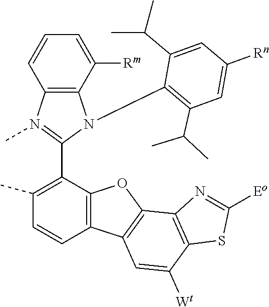 |
| LA132- (Rn)(Rm)(Eo)(Wt), wherein LA132- (R1)(R1)(El)(W1) to LA132-(R70)(R70) (E125)(W16) have the structure | 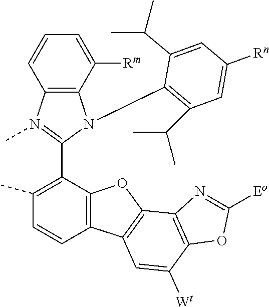 |
| LA133- (Rn)(Rm)(Eo)(Wt), wherein LA133- (R1)(R1)(E1)(W1) to LA133-(R70)(R70) (E125)(W16) have the structure | 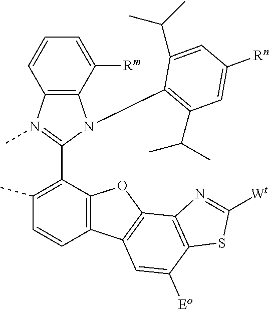 |
| LA134- (Rn)(Rm)(Eo)(Wt), wherein LA134- (R1)(R1)(El)(W1) to LA134-(R70)(R70) (E125)(W16) have the structure | 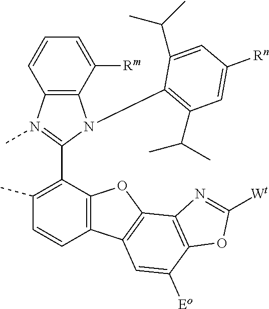 |
| LA135- (Rn)(Rm)(Eo)(Wt), wherein LA135- (R1)(R1)(E1)(W1) to LA135-(R70)(R70) (E125)(W16) have the structure | 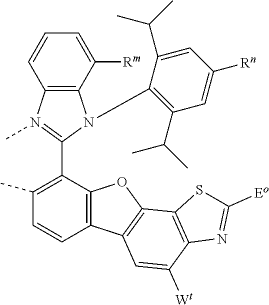 |
| LA136- (Rn)(Rm)(Eo)(Wt), wherein LA136- (R1)(R1)(El)(W1) to LA136-(R70)(R70) (E125)(W16) have the structure | 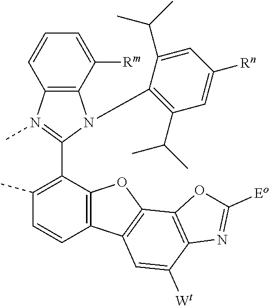 |
| LA137- (Rn)(Rm)(Eo)(Wt), wherein LA137- (R1)(R1)(E1)(W1) to LA137-(R70)(R70) (E125)(W16) have the structure | 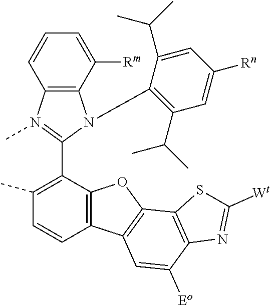 |
| LA138- (Rn)(Rm)(Eo)(Wt), wherein LA138- (R1)(R1)(E1)(W1) to LA138-(R70)(R70) (E125)(W16) have the structure | 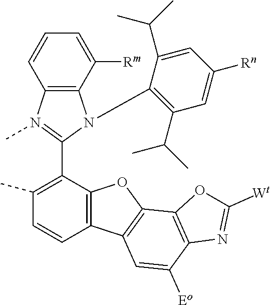 |
| LA139- (Rn)(Rm)(Eo)(Wt), wherein LA139- (R1)(R1)(E1)(W1) to LA139-(R70)(R70) (E125)(W16) have the structure | 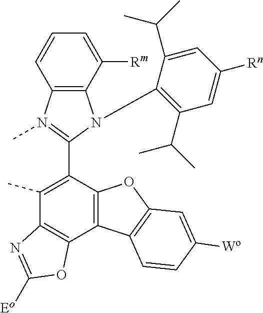 |
| LA140- (Rn)(Rm)(Eo)(Wt), wherein LA140- (R1)(R1)(E1)(W1) to LA140-(R70)(R70) (E125)(W16) have the structure | 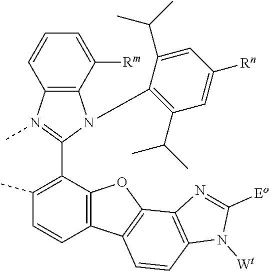 |
| LA141- (Rn)(Rm)(Eo)(Wt), wherein LA141- (R1)(R1)(E1)(W1) to LA141-(R70)(R70) (E125)(W16) have the structure | 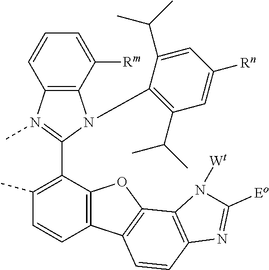 |
| LA142- (Rn)(Rm)(Eo)(Wt), wherein LA142- (R1)(R1)(E1)(W1) to LA142-(R70)(R70) (E125)(W16) have the structure | 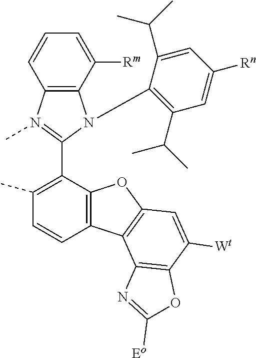 |
| LA143- (Rn)(Rm)(Eo)(Wt), wherein LA143- (R1)(R1)(El)(W1) to LA143-(R70)(R70) (E125)(W16) have the structure | 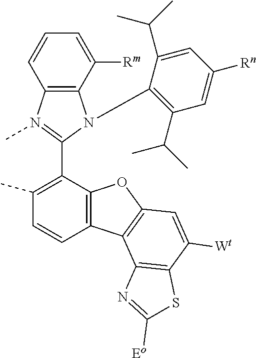 |
| LA144- (Rn)(Rm)(Eo)(Wt), wherein LA144- (R1)(R1)(E1)(W1) to LA144-(R70)(R70) (E125)(W16) have the structure | 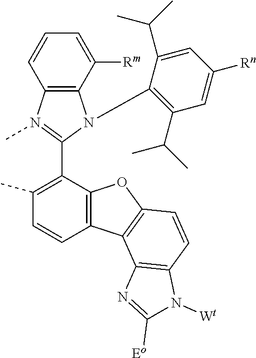 |
| LA145- (Rn)(Rm)(Eo)(Wt), wherein LA145- (R1)(R1)(E1)(W1) to LA145-(R70)(R70) (E125)(W16) have the structure | 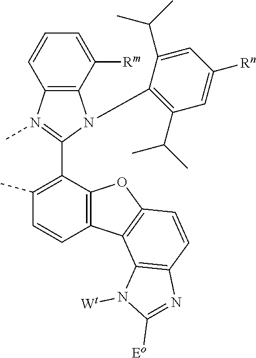 |
| LA146- (Rn)(Rm)(Eo)(Wt), wherein LA146- (R1)(R1)(E1)(W1) to LA146-(R70)(R70) (E125)(W16) have the structure | 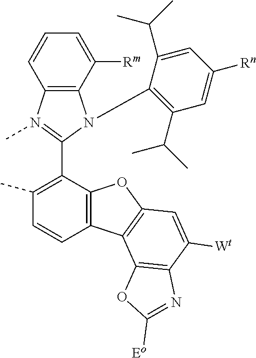 |
| LA147- (Rn)(Rm)(Eo)(Wt), wherein LA147- (R1)(R1)(E1)(W1) to LA147-(R70)(R70) (E125)(W16) have the structure | 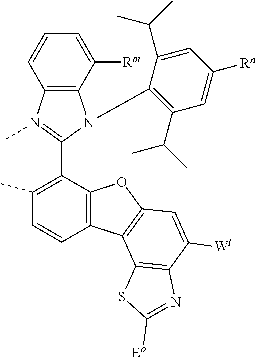 |
| LA148- (Rn)(Rm)(Eo)(Wt), wherein LA148- (R1)(R1)(El)(W1) to LA148-(R70)(R70) (E125)(W16) have the structure | 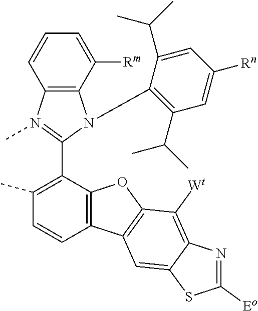 |
| LA149- (Rn)(Rm)(Eo)(Wt), wherein LA149- (R1)(R1)(El)(W1) to LA149-(R70)(R70) (E125)(W16) have the structure | 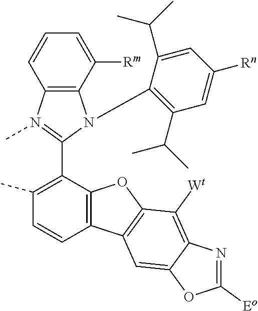 |
| LA150- (Rn)(Rm)(Eo)(Wt), wherein LA150- (R1)(R1)(El)(W1) to LA150-(R70)(R70) (E125)(W16) have the structure | 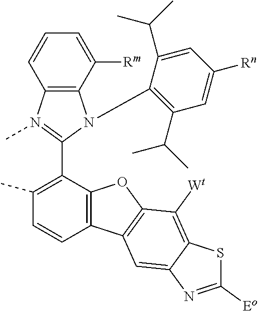 |
| LA151- (Rn)(Rm)(Eo)(Wt), wherein LA151- (R1)(R1)(E1)(W1) to LA151-(R70)(R70) (E125)(W16) have the structure | 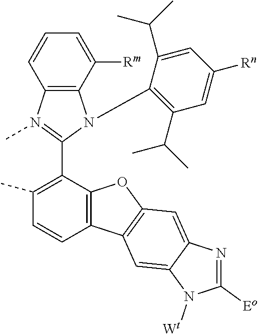 |
| LA152- (Rn)(Rm)(Eo)(Wt), wherein LA152- (R1)(R1)(E1)(W1) to LA152-(R70)(R70) (E125)(W16) have the structure | 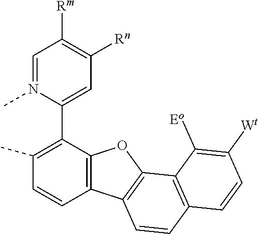 |
| LA153- (Rn)(Rm)(Eo)(Wt), wherein LA153- (R1)(R1)(E1)(W1) to LA153-(R70)(R70) (E125)(W16) have the structure | 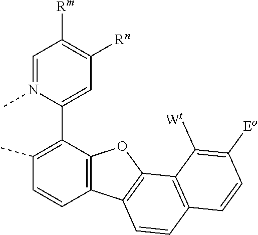 |
| LA154- (Rn)(Rm)(Eo)(Wt), wherein LA154- (R1)(R1)(El)(W1) to LA154-(R70)(R70) (E125)(W16) have the structure | 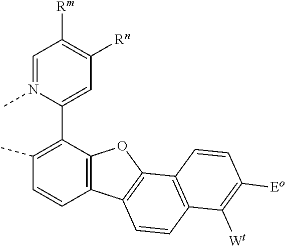 |
| LA155- (Rn)(Rm)(Eo)(Wt), wherein LA155- (R1)(R1)(E1)(W1) to LA155-(R70)(R70) (E125)(W16) have the structure | 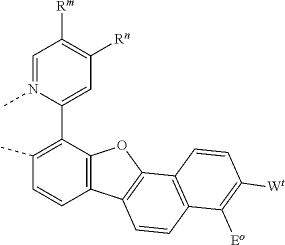 |
| LA156- (Rn)(Rm)(Eo)(Wt), wherein LA156- (R1)(R1)(E1)(W1) to LA156-(R70)(R70) (E125)(W16) have the structure | 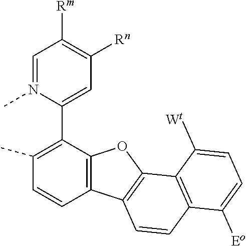 |
| LA157- (Rn)(Rm)(Eo)(Wt), wherein LA157- (R1)(R1)(El)(W1) to LA157-(R70)(R70) (E125)(W16) have the structure | 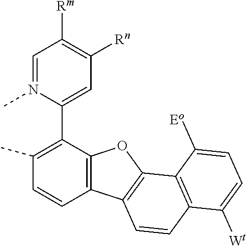 |
| LA158- (Rn)(Rm)(Eo)(Wt), wherein LA158- (R1)(R1)(E1)(W1) to LA158-(R70)(R70) (E125)(W16) have the structure | 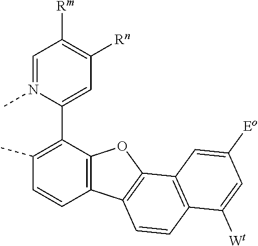 |
| LA159- (Rn)(Rm)(Eo)(Wt), wherein LA159- (R1)(R1)(E1)(W1) to LA159-(R70)(R70) (E125)(W16) have the structure | 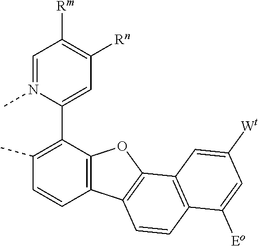 |
| LA160- (Rn)(Rm)(Eo)(Wt), wherein LA160- (R1)(R1)(E1)(W1) to LA160-(R70)(R70) (E125)(W16) have the structure | 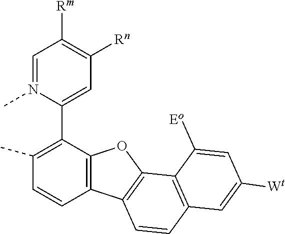 |
| LA161- (Rn)(Rm)(Eo)(Wt), wherein LA161- (R1)(R1)(E1)(W1) to LA161-(R70)(R70) (E125)(W16) have the structure | 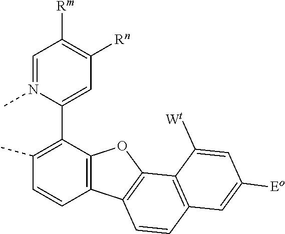 |
| LA162- (Rn)(Rm)(Eo)(Wt), wherein LA162- (R1)(R1)(E1)(W1) to LA162-(R70)(R70) (E125)(W16) have the structure | 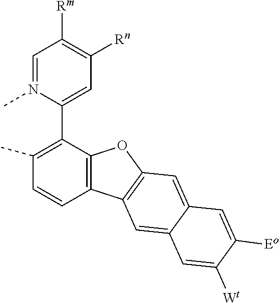 |
| LA163- (Rn)(Rm)(Eo)(Wt), wherein LA163- (R1)(R1)(E1)(W1) to LA163-(R70)(R70) (E125)(W16) have the structure | 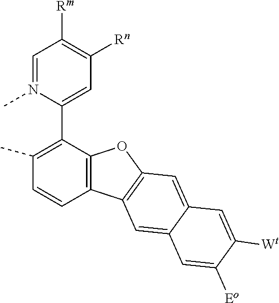 |
| LA164- (Rn)(Rm)(Eo)(Wt), wherein LA164- (R1)(R1)(El)(W1) to LA164-(R70)(R70) (E125)(W16) have the structure | 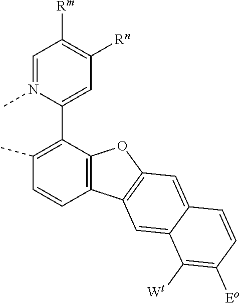 |
| LA165- (Rn)(Rm)(Eo)(Wt), wherein LA165- (R1)(R1)(E1)(W1) to LA165-(R70)(R70) (E125)(W16) have the structure | 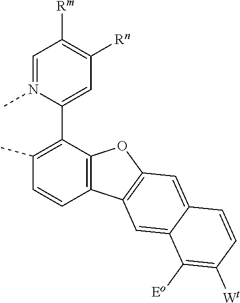 |
| LA166- (Rn)(Rm)(Eo)(Wt), wherein LA166- (R1)(R1)(E1)(W1) to LA166-(R70)(R70) (E125)(W16) have the structure | 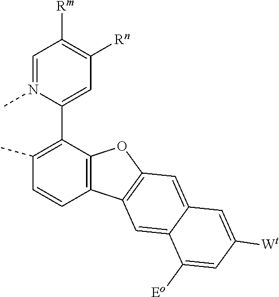 |
| LA167- (Rn)(Rm)(Eo)(Wt), wherein LA167- (R1)(R1)(E1)(W1) to LA167-(R70)(R70) (E125)(W16) have the structure | 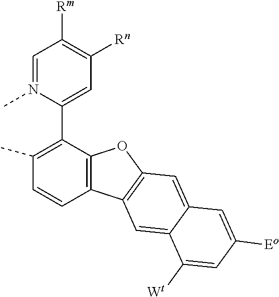 |
| LA168- (Rn)(Rm)(Eo)(Wt), wherein LA168- (R1)(R1)(E1)(W1) to LA168-(R70)(R70) (E125)(W16) have the structure | 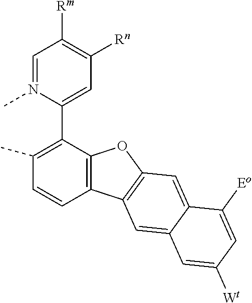 |
| LA169- (Rn)(Rm)(Eo)(Wt), wherein LA169- (R1)(R1)(El)(W1) to LA169-(R70)(R70) (E125)(W16) have the structure | 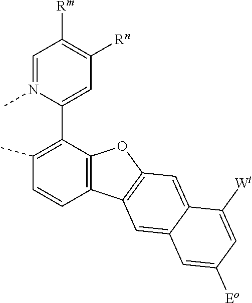 |
| LA170- (Rn)(Rm)(Eo)(Wt), wherein LA170- (R1)(R1)(E1)(W1) to LA170-(R70)(R70) (E125)(W16) have the structure | 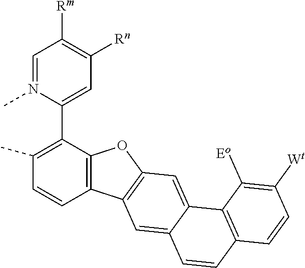 |
| LA171- (Rn)(Rm)(Eo)(Wt), wherein LA171- (R1)(R1)(El)(W1) to LA171-(R70)(R70) (E125)(W16) have the structure | 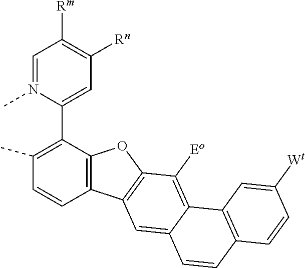 |
| LA172- (Rn)(Rm)(Eo)(Wt), wherein LA172- (R1)(R1)(E1)(W1) to LA172-(R70)(R70) (E125)(W16) have the structure | 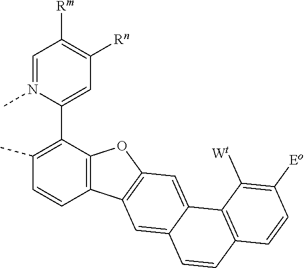 |
| LA173- (Rn)(Rm)(Eo)(Wt), wherein LA173- (R1)(R1)(E1)(W1) to LA173-(R70)(R70) (E125)(W16) have the structure | 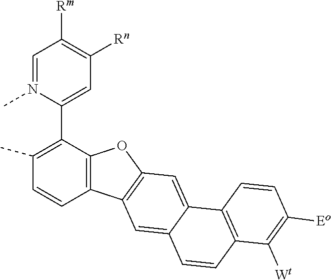 |
| LA174- (Rn)(Rm)(Eo)(Wt), wherein LA174- (R1)(R1)(E1)(W1) to LA174-(R70)(R70) (E125)(W16) have the structure | 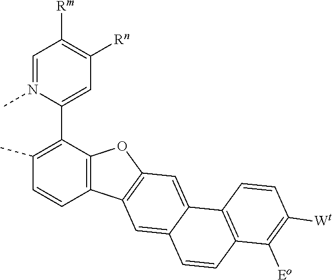 |
| LA175- (Rn)(Rm)(Eo)(Wt), wherein LA175- (R1)(R1)(E1)(W1) to LA175-(R70)(R70) (E125)(W16) have the structure | 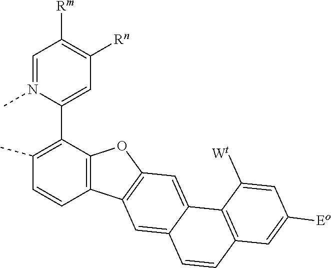 |
| LA176- (Rn)(Rm)(Eo)(Wt), wherein LA176- (R1)(R1)(El)(W1) to LA176-(R70)(R70) (E125)(W16) have the structure | 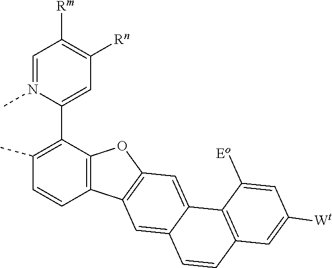 |
| LA177- (Rn)(Rm)(Eo)(Wt), wherein LA177- (R1)(R1)(E1)(W1) to LA177-(R70)(R70) (E125)(W16) have the structure | 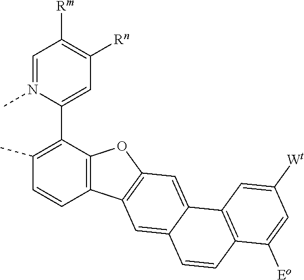 |
| LA178- (Rn)(Rm)(Eo)(Wt), wherein LA178- (R1)(R1)(El)(W1) to LA178-(R70)(R70) (E125)(W16) have the structure | 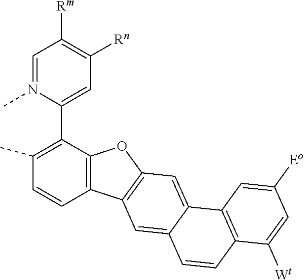 |
| LA179- (Rn)(Rm)(Eo)(Wt), wherein LA179- (R1)(R1)(El)(W1) to LA179-(R70)(R70) (E125)(W16) have the structure | 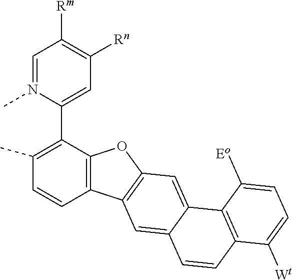 |
| LA180- (Rn)(Rm)(Eo)(Wt), wherein LA180- (R1)(R1)(E1)(W1) to LA180-(R70)(R70) (E125)(W16) have the structure | 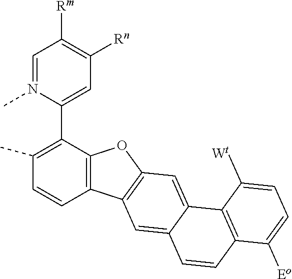 |
| LA181- (Rn)(Rm)(Eo)(Wt), wherein LA181- (R1)(R1)(E1)(W1) to LA181-(R70)(R70) (E125)(W16) have the structure | 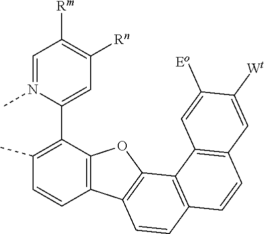 |
| LA182- (Rn)(Rm)(Eo)(Wt), wherein LA182- (R1)(R1)(E1)(W1) to LA182-(R70)(R70) (E125)(W16) have the structure | 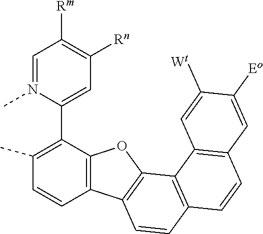 |
| LA183- (Rn)(Rm)(Eo)(Wt), wherein LA183- (R1)(R1)(E1)(W1) to LA183-(R70)(R70) (E125)(W16) have the structure | 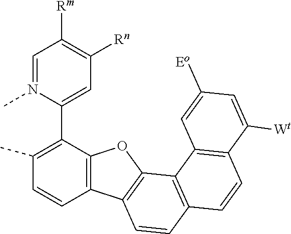 |
| LA184- (Rn)(Rm)(Eo)(Wt), wherein LA184- (R1)(R1)(El)(W1) to LA184-(R70)(R70) (E125)(W16) have the structure | 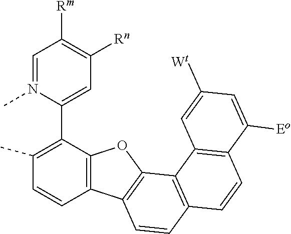 |
| LA185- (Rn)(Rm)(Eo)(Wt), wherein LA185- (R1)(R1)(E1)(W1) to LA185-(R70)(R70) (E125)(W16) have the structure | 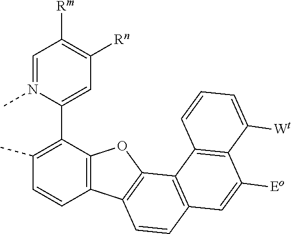 |
| LA186- (Rn)(Rm)(Eo)(Wt), wherein LA186- (R1)(R1)(E1)(W1) to LA186-(R70)(R70) (E125)(W16) have the structure | 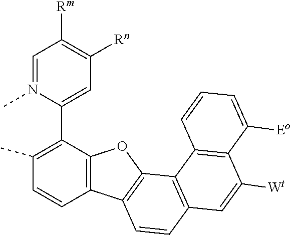 |
| LA187- (Rn)(Rm)(Eo)(Wt), wherein LA187- (R1)(R1)(El)(W1) to LA187-(R70)(R70) (E125)(W16) have the structure | 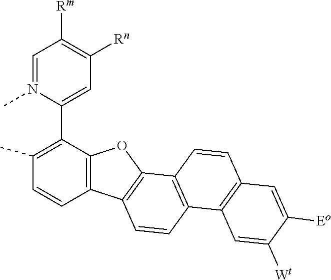 |
| LA188- (Rn)(Rm)(Eo)(Wt), wherein LA188- (R1)(R1)(El)(W1) to LA188-(R70)(R70) (E125)(W16) have the structure | 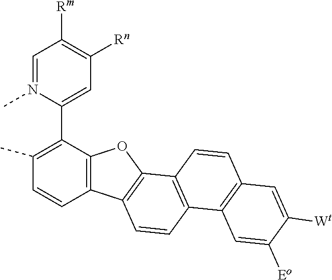 |
| LA189- (Rn)(Rm)(Eo)(Wt), wherein LA189- (R1)(R1)(El)(W1) to LA189-(R70)(R70) (E125)(W16) have the structure | 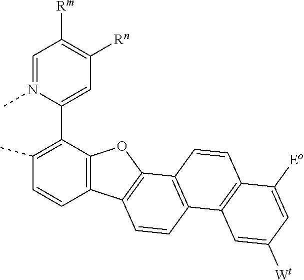 |
| LA190- (Rn)(Rm)(Eo)(Wt), wherein LA190- (R1)(R1)(El)(W1) to LA190-(R70)(R70) (E125)(W16) have the structure | 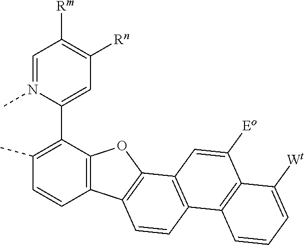 |
| LA191- (Rn)(Rm)(Eo)(Wt), wherein LA191- (R1)(R1)(El)(W1) to LA191-(R70)(R70) (E125)(W16) have the structure | 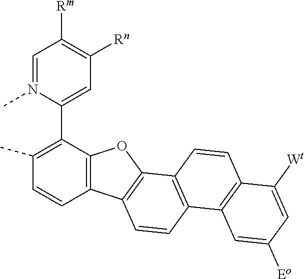 |
| LA192- (Rn)(Rm)(Eo)(Wt), wherein LA192- (R1)(R1)(El)(W1) to LA192-(R70)(R70) (E125)(W16) have the structure | 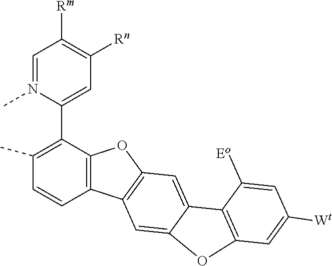 |
| LA193- (Rn)(Rm)(Eo)(Wt), wherein LA193- (R1)(R1)(El)(W1) to LA193-(R70)(R70) (E125)(W16) have the structure | 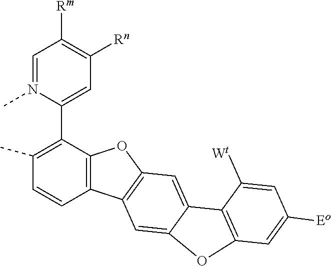 |
| LA194- (Rn)(Rm)(Eo)(Wt), wherein LA194- (R1)(R1)(E1)(W1) to LA194-(R70)(R70) (E125)(W16) have the structure | 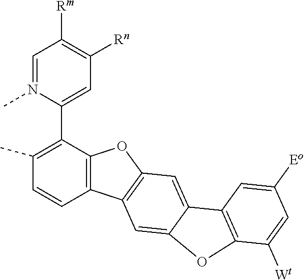 |
| LA195- (Rn)(Rm)(Eo)(Wt), wherein LA195- (R1)(R1)(El)(W1) to LA195-(R70)(R70) (E125)(W16) have the structure | 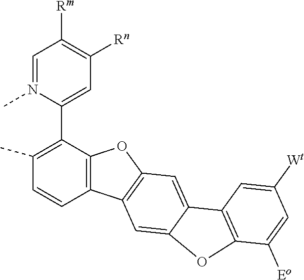 |
| LA196- (Rn)(Rm)(Eo)(Wt), wherein LA196- (R1)(R1)(E1)(W1) to LA196-(R70)(R70) (E125)(W16) have the structure | 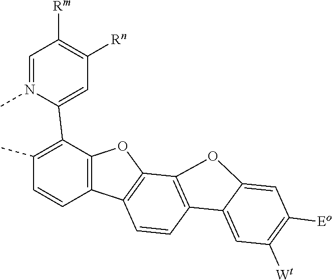 |
| LA197- (Rn)(Rm)(Eo)(Wt), wherein LA197- (R1)(R1)(El)(W1) to LA197-(R70)(R70) (E125)(W16) have the structure | 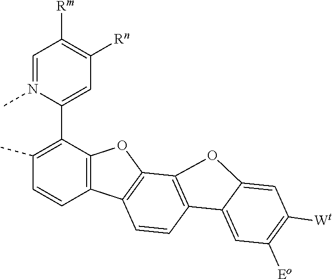 |
| LA198- (Rn)(Rm)(Eo)(Wt), wherein LA198- (R1)(R1)(E1)(W1) to LA198-(R70)(R70) (E125)(W16) have the structure | 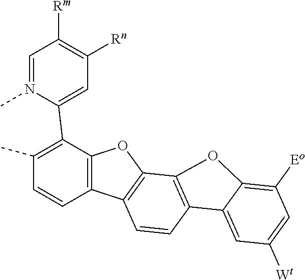 |
| LA199- (Rn)(Rm)(Eo)(Wt), wherein LA199- (R1)(R1)(E1)(W1) to LA199-(R70)(R70) (E125)(W16) have the structure | 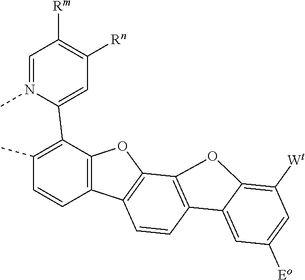 |
| LA200- (Rn)(Rm)(Eo)(Wt), wherein LA200- (R1)(R1)(El)(W1) to LA200-(R70)(R70) (E125)(W16) have the structure | 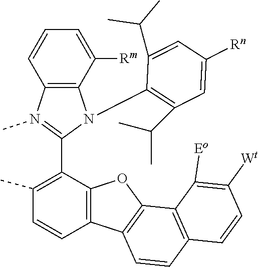 |
| LA201- (Rn)(Rm)(Eo)(Wt), wherein LA201- (R1)(R1)(E1)(W1) to LA201-(R70)(R70) (E125)(W16) have the structure | 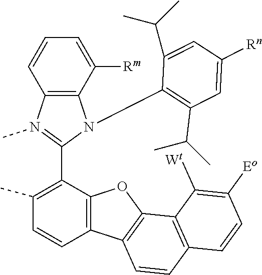 |
| LA202- (Rn)(Rm)(Eo)(Wt), wherein LA202- (R1)(R1)(E1)(W1) to LA202-(R70)(R70) (E125)(W16) have the structure | 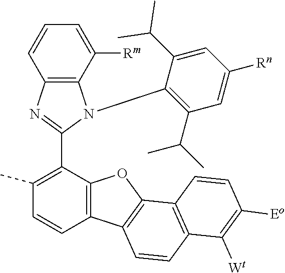 |
| LA203- (Rn)(Rm)(Eo)(Wt), wherein LA203- (R1)(R1)(E1)(W1) to LA203-(R70)(R70) (E125)(W16) have the structure | 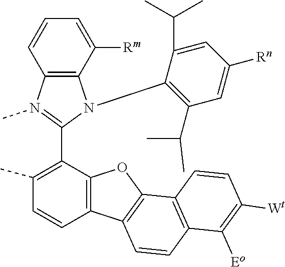 |
| LA204- (Rn)(Rm)(Eo)(Wt), wherein LA204- (R1)(R1)(E1)(W1) to LA204-(R70)(R70) (E125)(W16) have the structure | 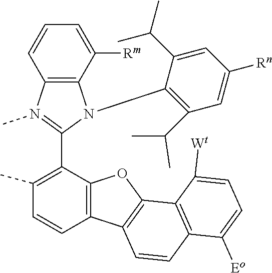 |
| LA205- (Rn)(Rm)(Eo)(Wt), wherein LA205- (R1)(R1)(El)(W1) to LA205-(R70)(R70) (E125)(W16) have the structure | 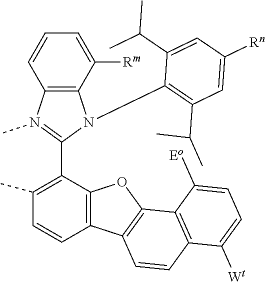 |
| LA206- (Rn)(Rm)(Eo)(Wt), wherein LA206- (R1)(R1)(El)(W1) to LA206-(R70)(R70) (E125)(W16) have the structure | 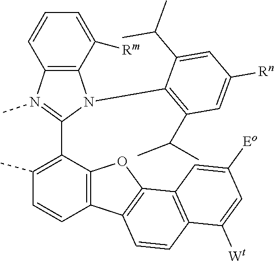 |
| LA207- (Rn)(Rm)(Eo)(Wt), wherein LA207- (R1)(R1)(El)(W1) to LA207-(R70)(R70) (E125)(W16) have the structure | 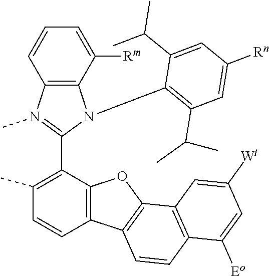 |
| LA208- (Rn)(Rm)(Eo)(Wt), wherein LA208- (R1)(R1)(E1)(W1) to LA208-(R70)(R70) (E125)(W16) have the structure | 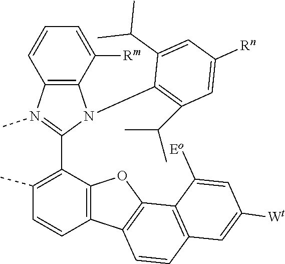 |
| LA209- (Rn)(Rm)(Eo)(Wt), wherein LA209- (R1)(R1)(E1)(W1) to LA209-(R70)(R70) (E125)(W16) have the structure | 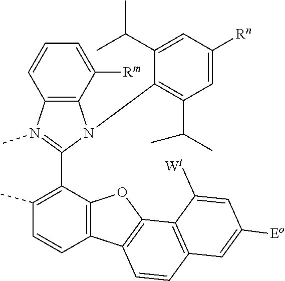 |
| LA210- (Rn)(Rm)(Eo)(Wt), wherein LA210- (R1)(R1)(E1)(W1) to LA210-(R70)(R70) (E125)(W16) have the structure | 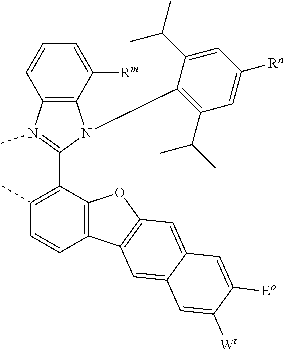 |
| LA211- (Rn)(Rm)(Eo)(Wt), wherein LA211- (R1)(R1)(El)(W1) to LA211-(R70)(R70) (E125)(W16) have the structure | 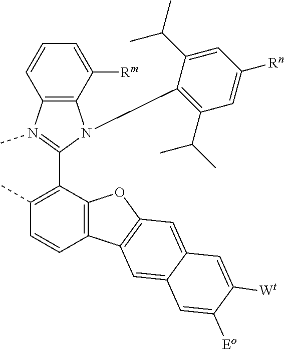 |
| LA212- (Rn)(Rm)(Eo)(Wt), wherein LA212- (R1)(R1)(E1)(W1) to LA212-(R70)(R70) (E125)(W16) have the structure | 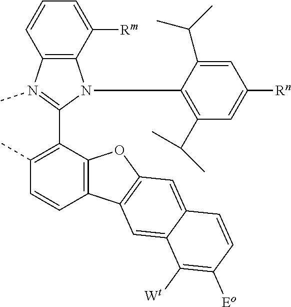 |
| LA213- (Rn)(Rm)(Eo)(Wt), wherein LA213- (R1)(R1)(E1)(W1) to LA213-(R70)(R70) (E125)(W16) have the structure | 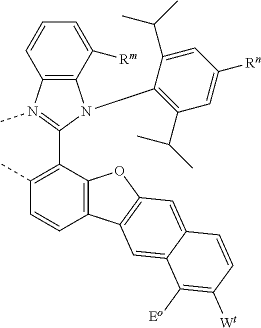 |
| LA214- (Rn)(Rm)(Eo)(Wt), wherein LA214- (R1)(R1)(E1)(W1) to LA214-(R70)(R70) (E125)(W16) have the structure | 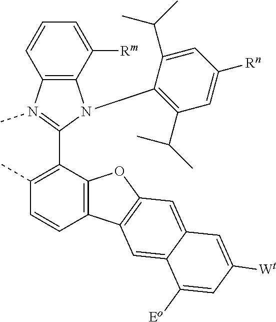 |
| LA215- (Rn)(Rm)(Eo)(Wt), wherein LA215- (R1)(R1)(E1)(W1) to LA215-(R70)(R70) (E125)(W16) have the structure | 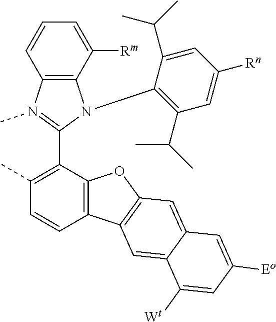 |
| LA216- (Rn)(Rm)(Eo)(Wt), wherein LA216- (R1)(R1)(El)(W1) to LA216-(R70)(R70) (E125)(W16) have the structure | 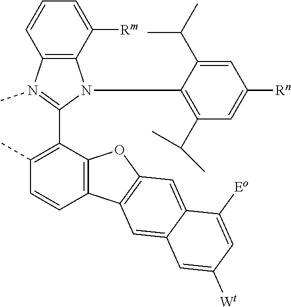 |
| LA217- (Rn)(Rm)(Eo)(Wt), wherein LA217- (R1)(R1)(El)(W1) to LA217-(R70)(R70) (E125)(W16) have the structure | 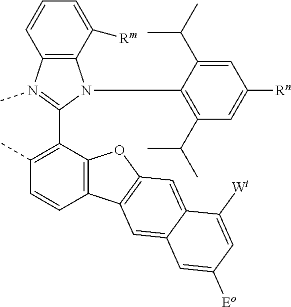 |
| LA218- (Rn)(Rm)(Eo)(Wt), wherein LA218- (R1)(R1)(El)(W1) to LA218-(R70)(R70) (E125)(W16) have the structure | 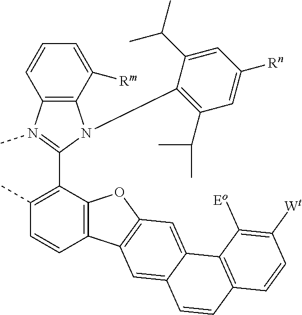 |
| LA219- (Rn)(Rm)(Eo)(Wt), wherein LA219- (R1)(R1)(E1)(W1) to LA219-(R70)(R70) (E125)(W16) have the structure | 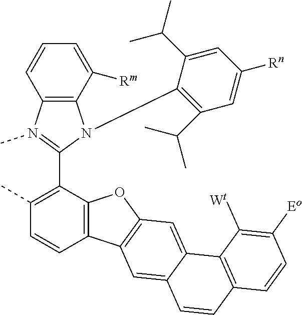 |
| LA220- (Rn)(Rm)(Eo)(Wt), wherein LA220- (R1)(R1)(El)(W1) to LA220-(R70)(R70) (E125)(W16) have the structure | 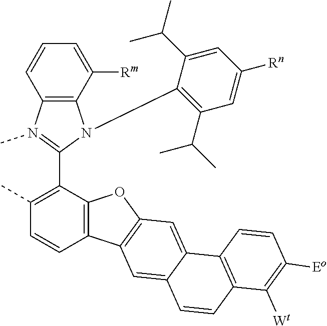 |
| LA221- (Rn)(Rm)(Eo)(Wt), wherein LA221- (R1)(R1)(E1)(W1) to LA221-(R70)(R70) (E125)(W16) have the structure | 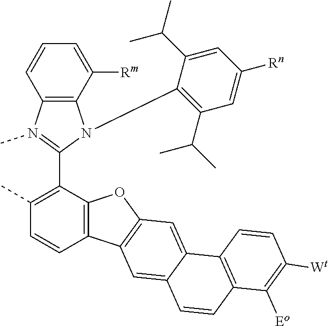 |
| LA222- (Rn)(Rm)(Eo)(Wt), wherein LA222- (R1)(R1)(E1)(W1) to LA222-(R70)(R70) (E125)(W16) have the structure | 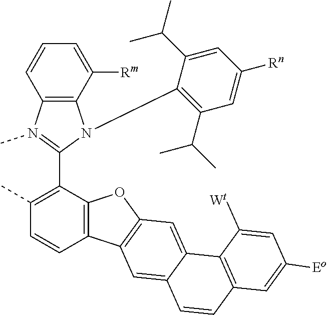 |
| LA223- (Rn)(Rm)(Eo)(Wt), wherein LA223- (R1)(R1)(E1)(W1) to LA223-(R70)(R70) (E125)(W16) have the structure | 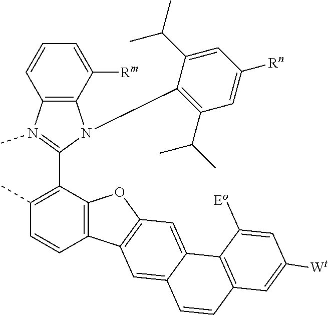 |
| LA224- (Rn)(Rm)(Eo)(Wt), wherein LA224- (R1)(R1)(E1)(W1) to LA224-(R70)(R70) (E125)(W16) have the structure | 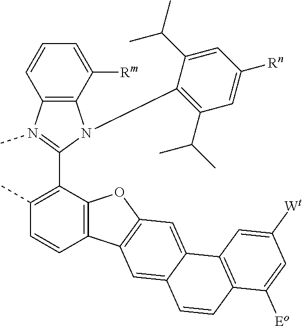 |
| LA225- (Rn)(Rm)(Eo)(Wt), wherein LA225- (R1)(R1)(El)(W1) to L-(R70)(R70) (E125)(W16) have the structure | 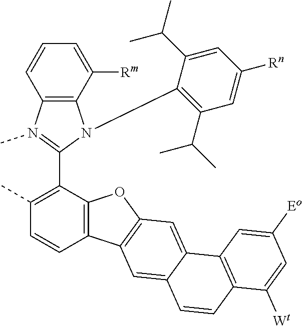 |
| LA226- (Rn)(Rm)(Eo)(Wt), wherein LA226- (R1)(R1)(E1)(W1) to LA226-(R70)(R70) (E125)(W16) have the structure | 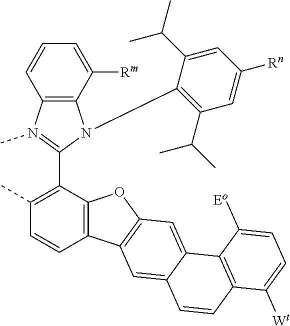 |
| LA227- (Rn)(Rm)(Eo)(Wt), wherein LA227- (R1)(R1)(E1)(W1) to LA227-(R70)(R70) (E125)(W16) have the structure | 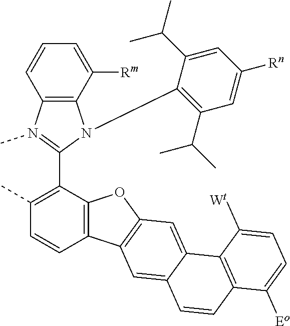 |
| LA228- (Rn)(Rm)(Eo)(Wt), wherein LA228- (R1)(R1)(El)(W1) to LA228-(R70)(R70) (E125)(W16) have the structure | 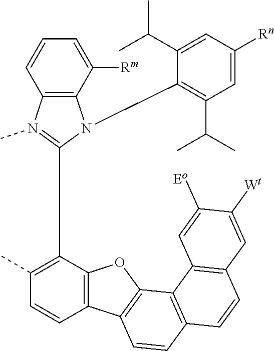 |
| LA229- (Rn)(Rm)(Eo)(Wt), wherein LA229- (R1)(R1)(El)(W1) to LA229-(R70)(R70) (E125)(W16) have the structure | 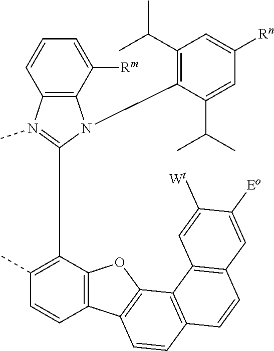 |
| LA230- (Rn)(Rm)(Eo)(Wt), wherein LA230- (R1)(R1)(E1)(W1) to LA230-(R70)(R70) (E125)(W16) have the structure | 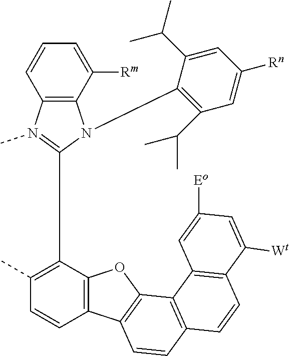 |
| LA231- (Rn)(Rm)(Eo)(Wt), wherein LA231- (R1)(R1)(El)(W1) to LA231-(R70)(R70) (E125)(W16) have the structure | 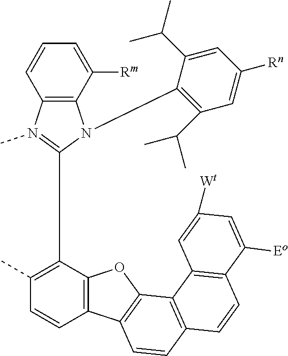 |
| LA232- (Rn)(Rm)(Eo)(Wt), wherein LA232- (R1)(R1)(E1)(W1) to LA232-(R70)(R70) (E125)(W16) have the structure | 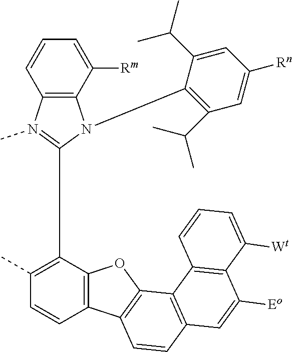 |
| LA233- (Rn)(Rm)(Eo)(Wt), wherein LA233- (R1)(R1)(E1)(W1) to LA233-(R70)(R70) (E125)(W16) have the structure | 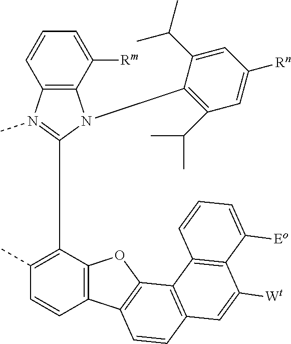 |
| LA234- (Rn)(Rm)(Eo)(Wt), wherein LA234- (R1)(R1)(E1)(W1) to LA234-(R70)(R70) (E125)(W16) have the structure | 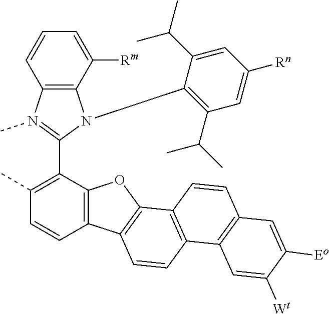 |
| LA235- (Rn)(Rm)(Eo)(Wt), wherein LA235- (R1)(R1)(E1)(W1) to LA235-(R70)(R70) (E125)(W16) have the structure | 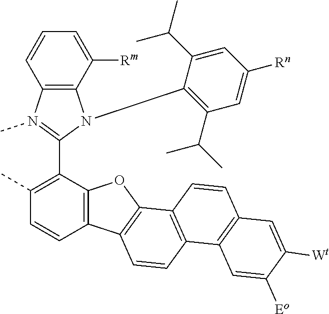 |
| LA236- (Rn)(Rm)(Eo)(Wt), wherein LA236- (R1)(R1)(El)(W1) to LA236-(R70)(R70) (E125)(W16) have the structure | 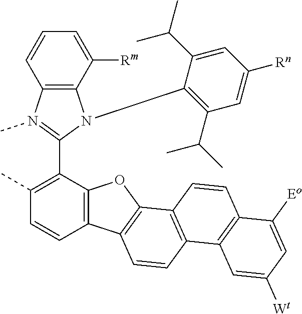 |
| LA237- (Rn)(Rm)(Eo)(Wt), wherein LA237- (R1)(R1)(El)(W1) to LA237-(R70)(R70) (E125)(W16) have the structure | 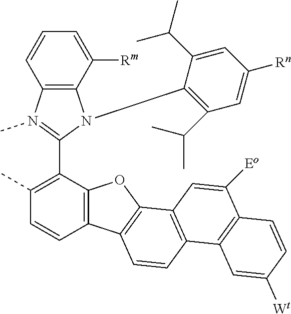 |
| LA238- (Rn)(Rm)(Eo)(Wt), wherein LA238- (R1)(R1)(E1)(W1) to LA238-(R70)(R70) (E125)(W16) have the structure | 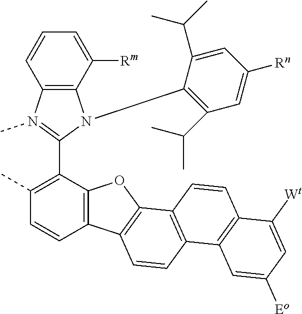 |
| LA239- (Rn)(Rm)(Eo)(Wt), wherein LA239- (R1)(R1)(E1)(W1) to LA239-(R70)(R70) (E125)(W16) have the structure | 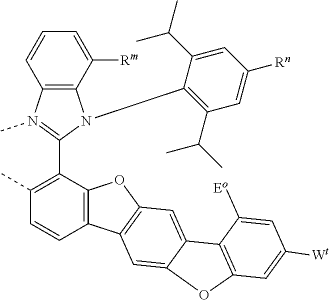 |
| LA240- (Rn)(Rm)(Eo)(Wt), wherein LA240- (R1)(R1)(El)(W1) to LA240-(R70)(R70) (E125)(W16) have the structure | 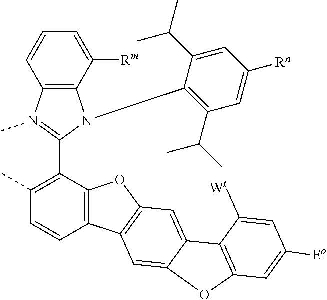 |
| LA241- (Rn)(Rm)(Eo)(Wt), wherein LA241- (R1)(R1)(E1)(W1) to LA241-(R70)(R70) (E125)(W16) have the structure | 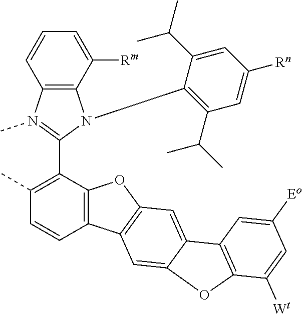 |
| LA242- (Rn)(Rm)(Eo)(Wt), wherein LA242- (R1)(R1)(E1)(W1) to LA242-(R70)(R70) (E125)(W16) have the structure | 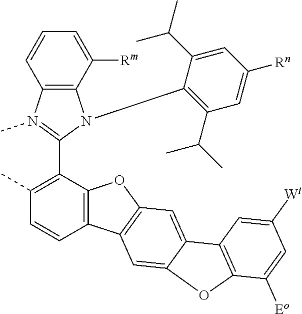 |
| LA243- (Rn)(Rm)(Eo)(Wt), wherein LA243- (R1)(R1)(E1)(W1) to LA243-(R70)(R70) (E125)(W16) have the structure | 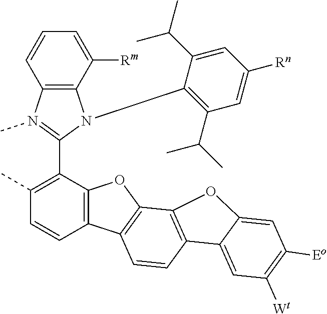 |
| LA244- (Rn)(Rm)(Eo)(Wt), wherein LA244- (R1)(R1)(E1)(W1) to LA244-(R70)(R70) (E125)(W16) have the structure | 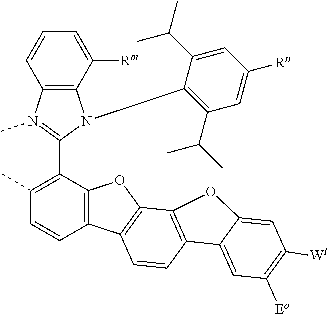 |
| LA245- (Rn)(Rm)(Eo)(Wt), wherein LA245- (R1)(R1)(E1)(W1) to LA245-(R70)(R70) (E125)(W16) have the structure | 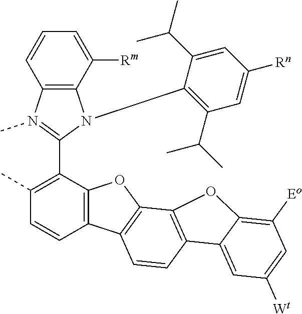 |
| LA246- (Rn)(Rm)(Eo)(Wt), wherein LA246- (R1)(R1)(E1)(W1) to LA246-(R70)(R70) (E125)(W16) have the structure | 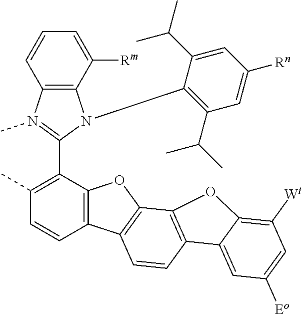 |

wherein E1 to E125 have the following structures: 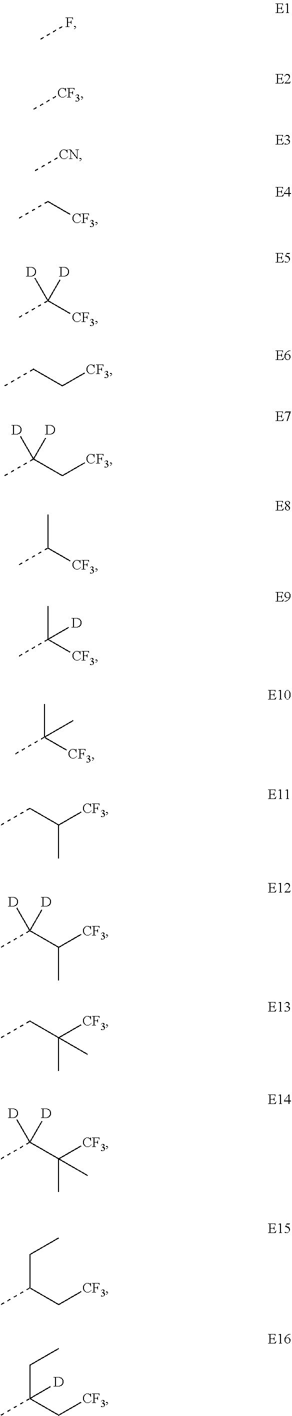 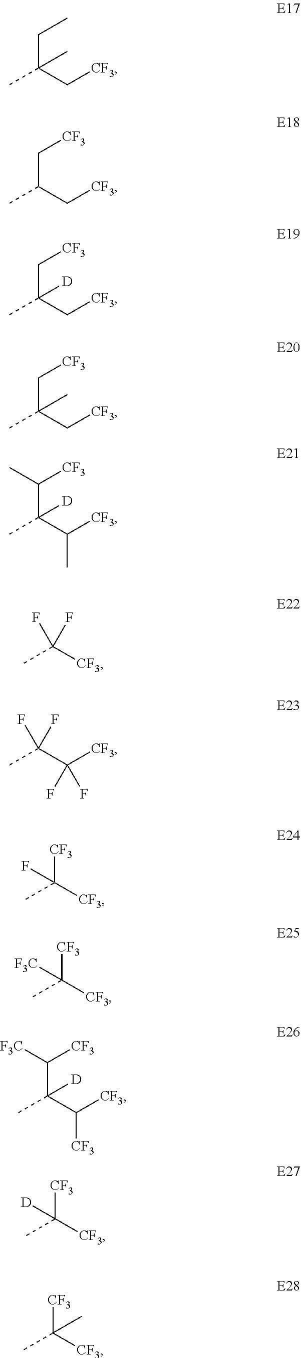 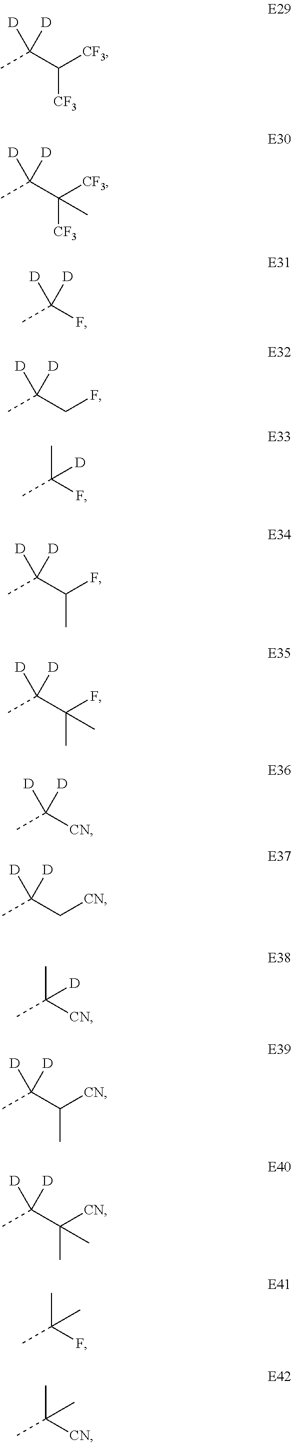 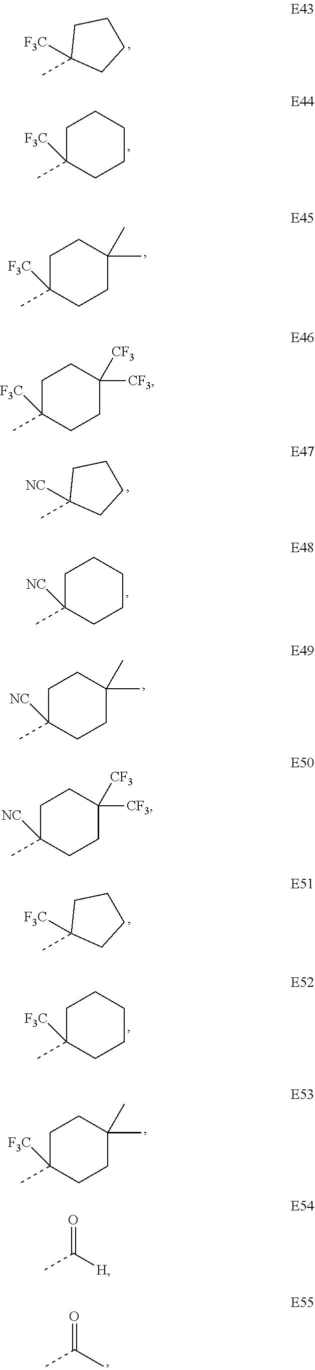 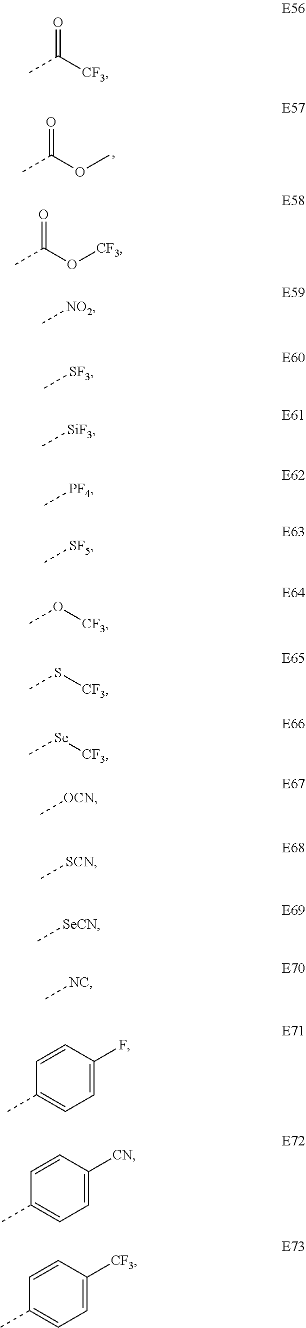 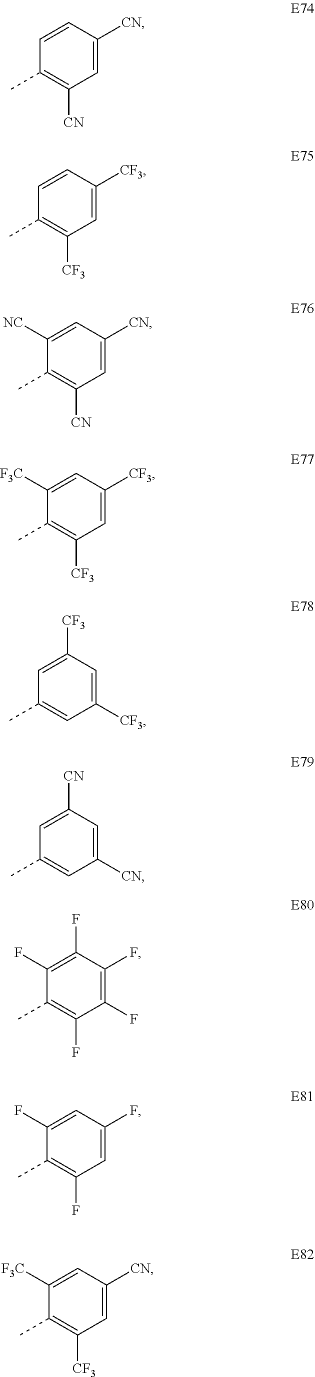 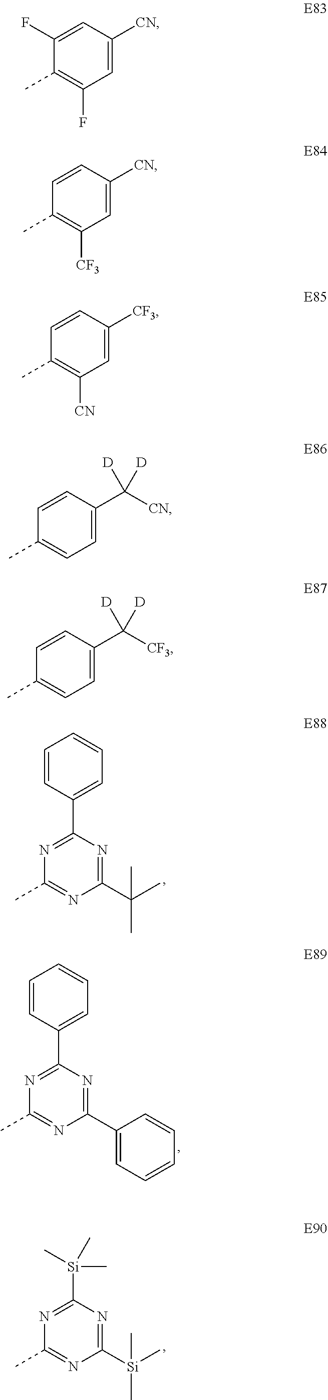 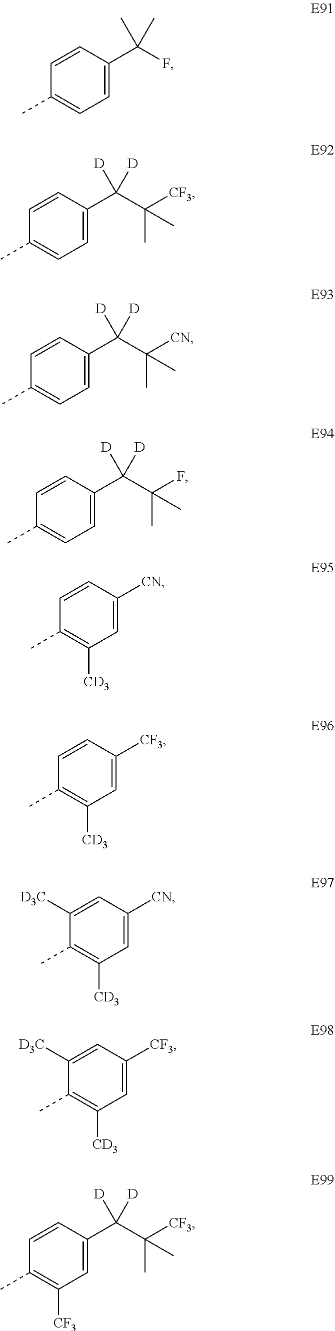 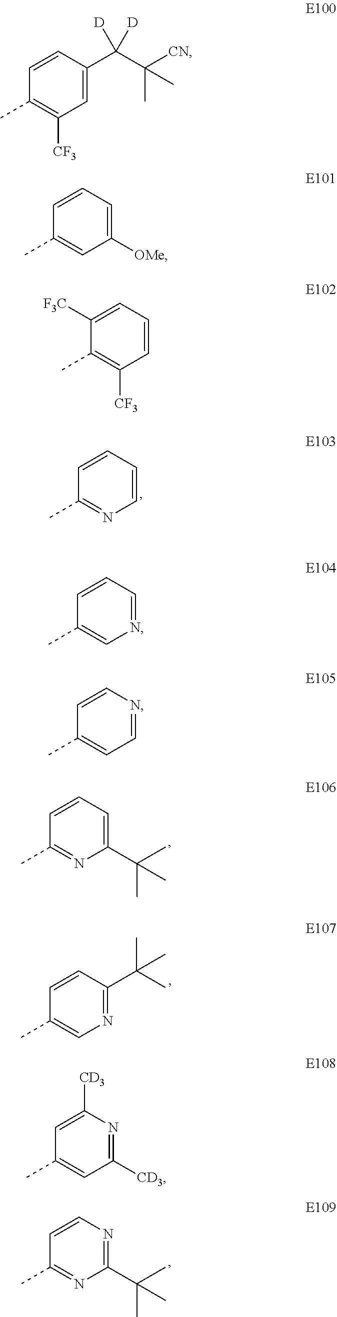 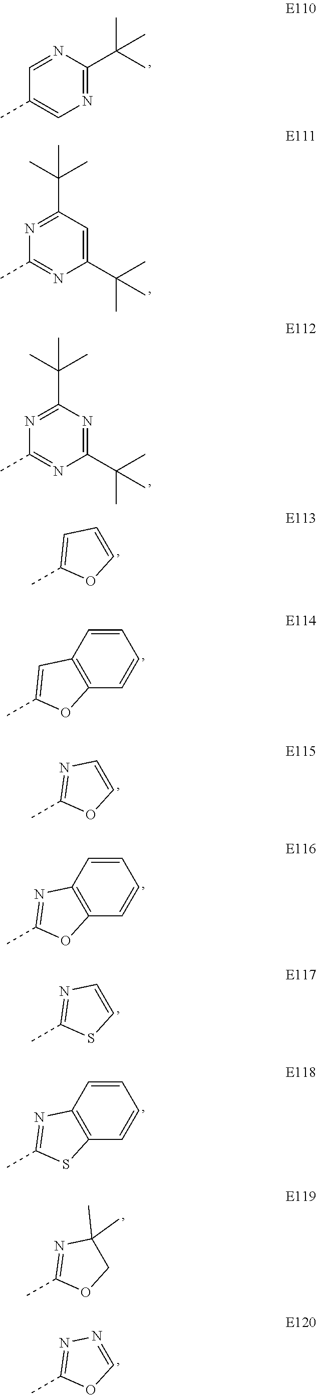 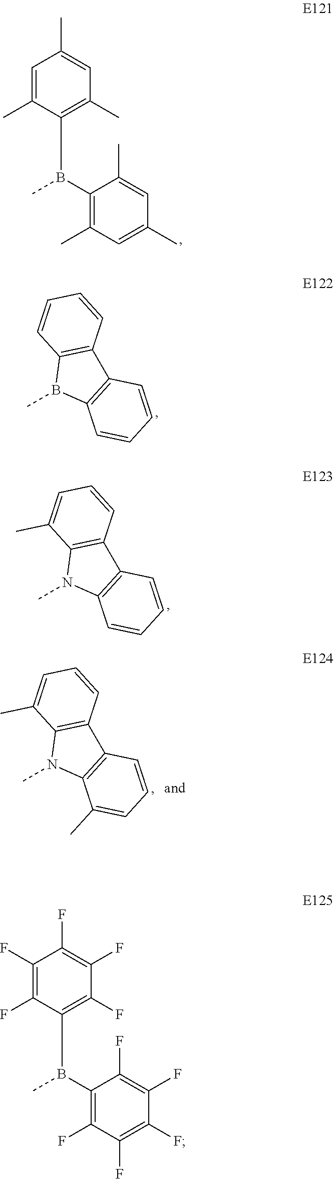
wherein W1 to W16 have the following structures: 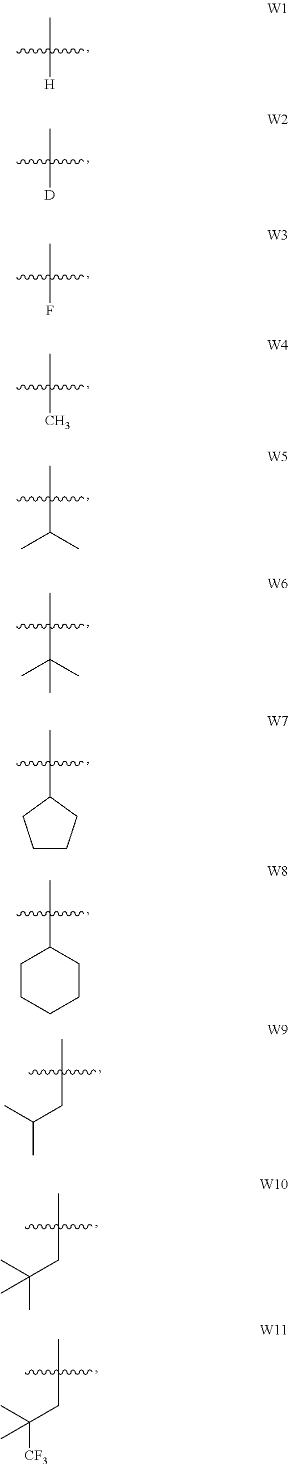 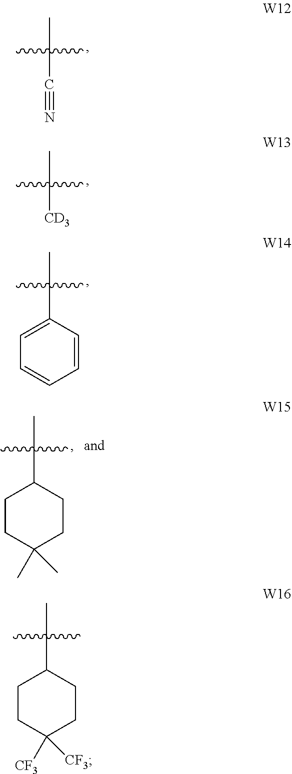
and
wherein R1 to R70 have the following structures:

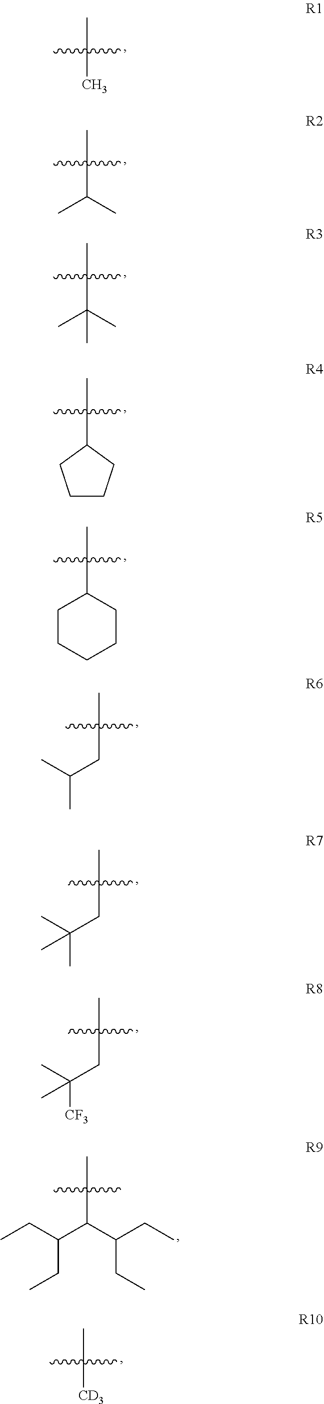

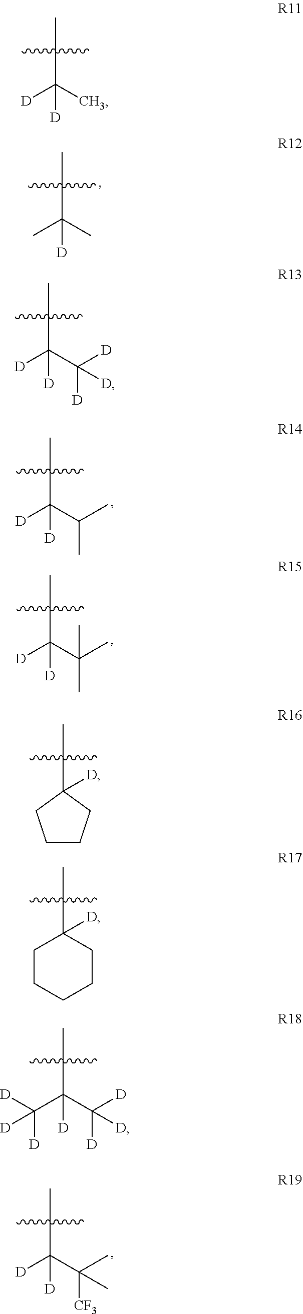

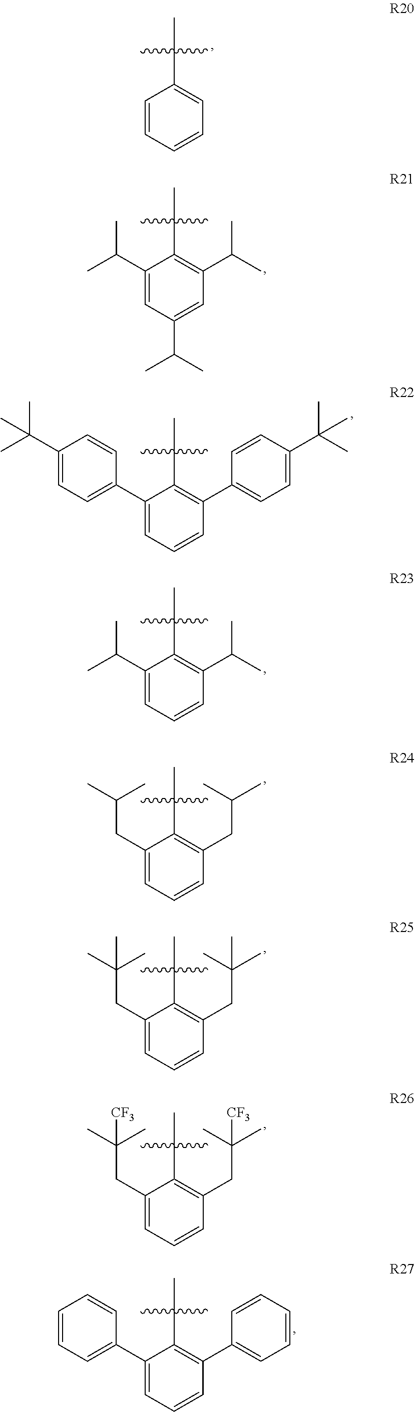

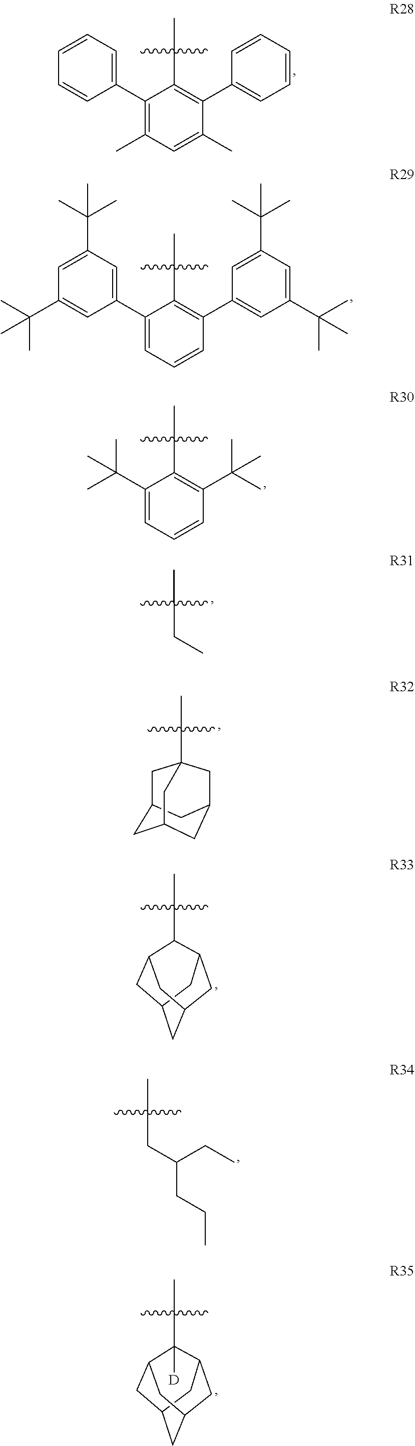

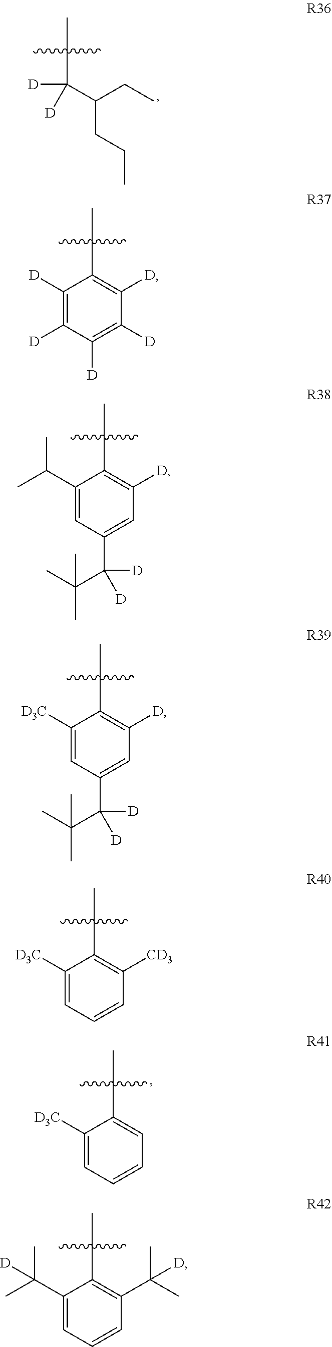

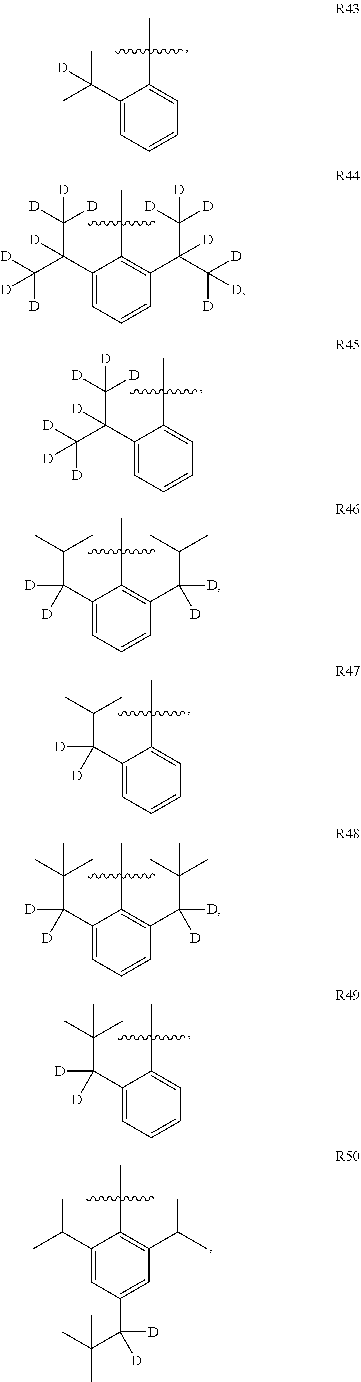

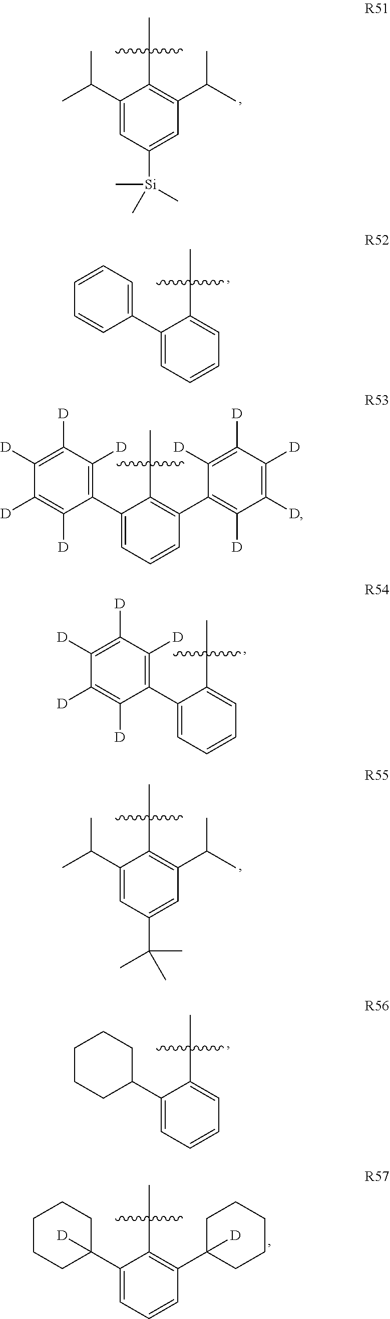

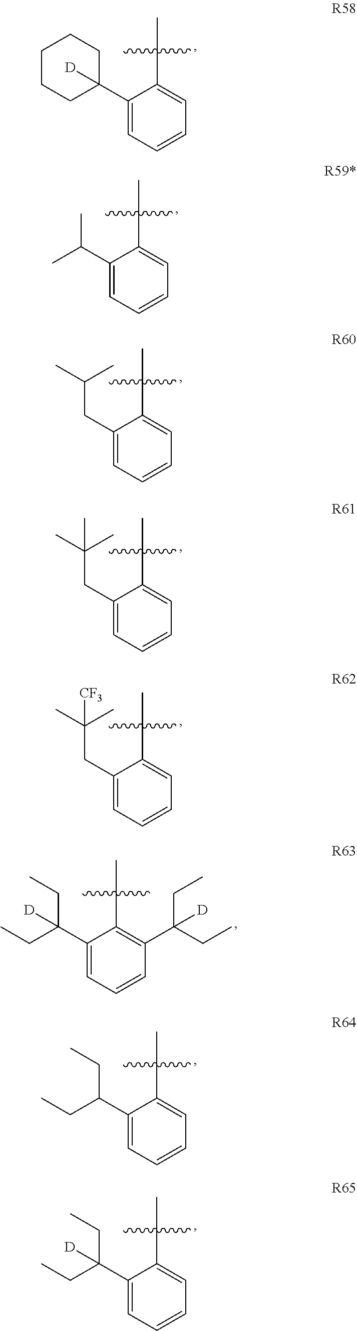

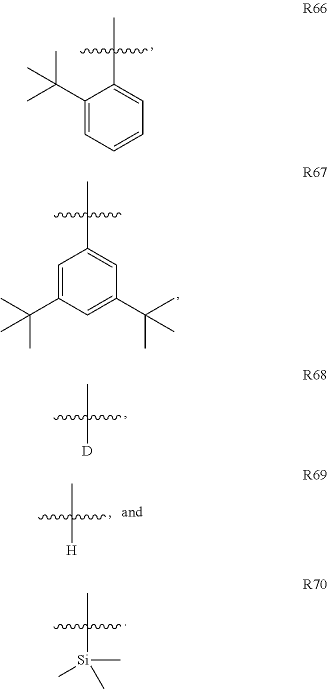

10. The compound of claim 1, wherein the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

11. The compound of claim 10, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other; wherein the compound has a formula of Pt(L_{A})(L_{B}); and wherein L_{A} and L_{B} can be same or different.

12. The compound of claim 10, wherein L_{B} and L_{C} are each independently selected from the group consisting of: 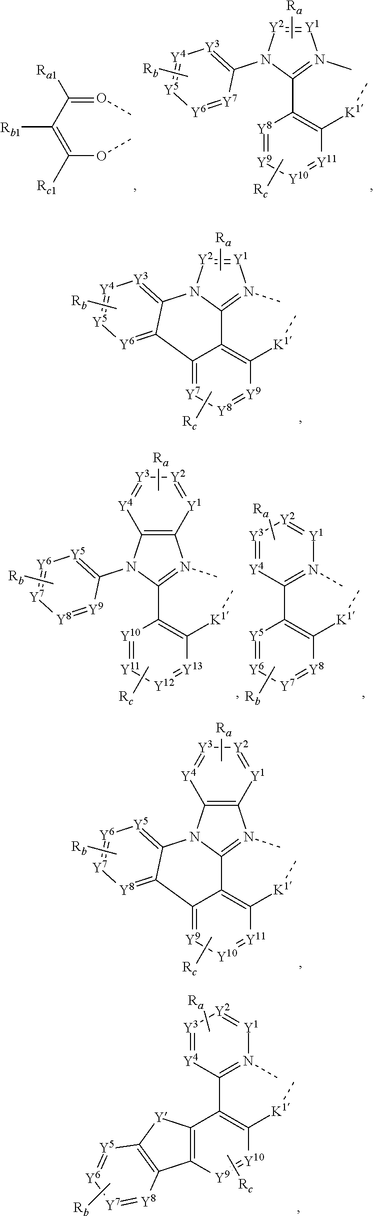 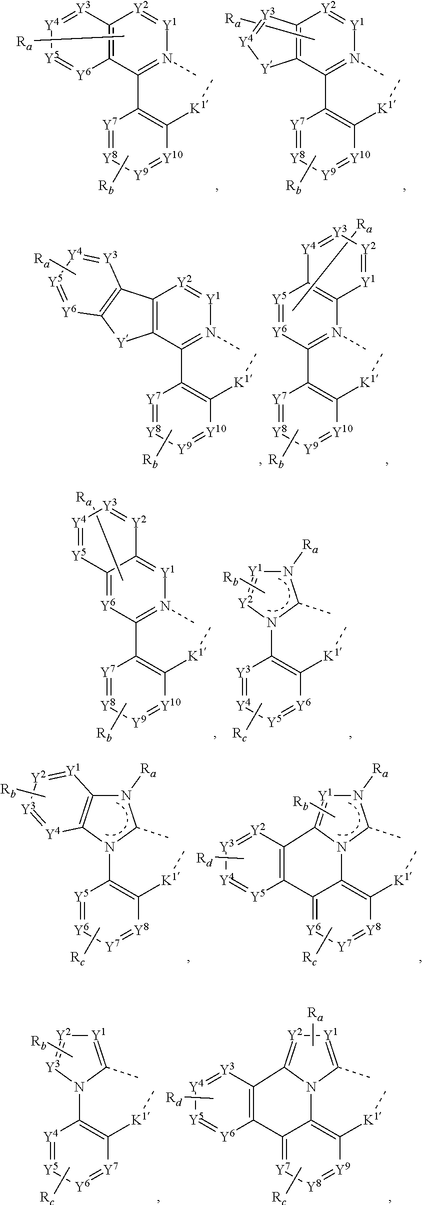 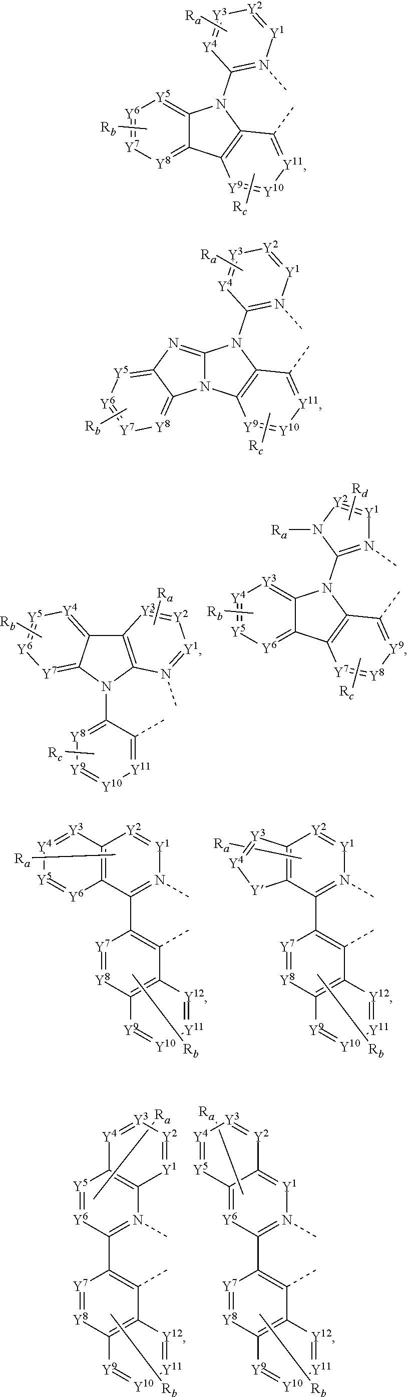 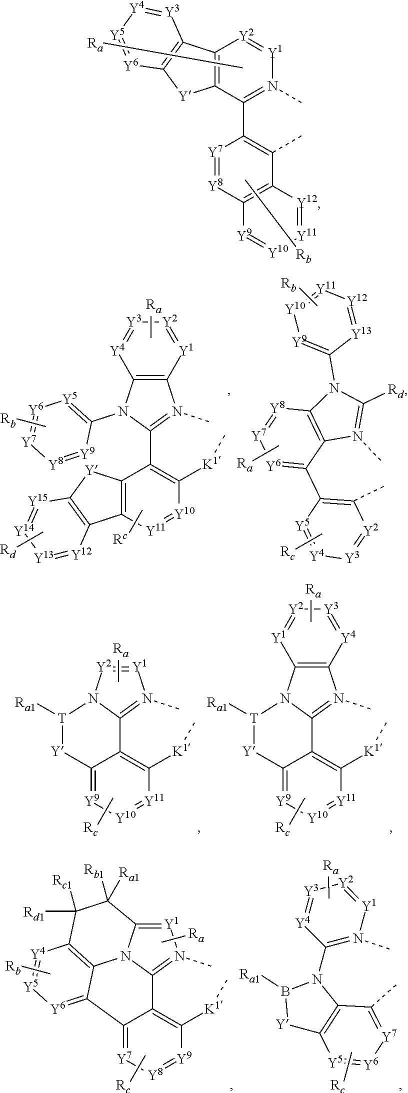 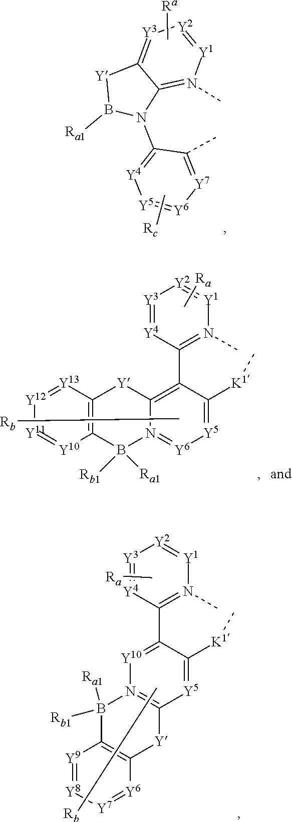
wherein: T is selected from the group consisting of B, Al, Ga, and In;
K^{1′} is a direct bond or is selected from the group consisting of NRₑ, PRₑ, O, S, and Se;
each Y¹ to Y¹³ are independently selected from the group consisting of carbon and nitrogen;
Y′ is selected from the group consisting of BRₑ, NRₑ, PRₑ, O, S, Se, C═O, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} can independently represent from mono to the maximum possible number of substitutions, or no substitution;
each Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and
any two of Rₐ₁, R_{b1}, R_{c1}, R_{d1}, Rₐ, R_{b}, R_{c}, and R_{d} can be fused or joined to form a ring or form a multidentate ligand.

13. The compound of claim 10, wherein the compound has a formula selected from the group consisting of Formula Ir(L_{A})₃, Formula Ir(L_{A})(L_{Bk})₂, Formula Ir(L_{A})₂(L_{Bk}), Formula Ir(L_{A})₂(L_{Cj-I}), and Formula Ir(L_{A})₂(L_{Cj-II}),
wherein the structures of each L_{A} is defined according to claim 1;
wherein k is an integer from 1 to 474;
wherein j is an integer from 1 to 1416;
wherein each L_{B1} to L_{B474} have the following structures: 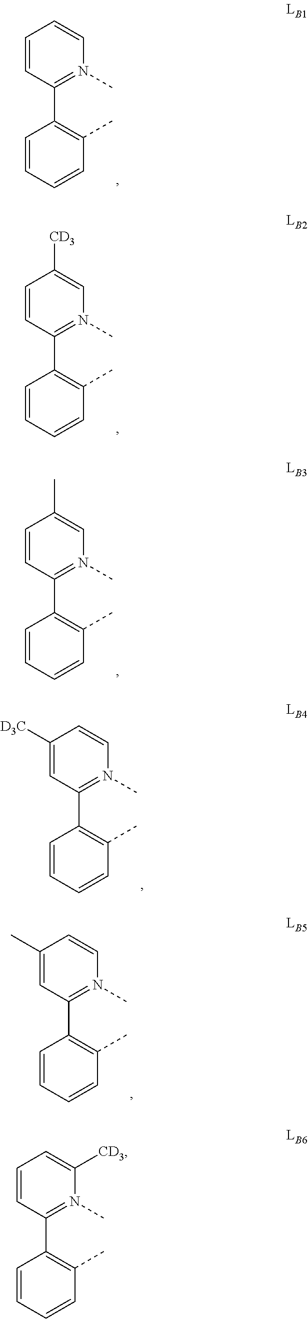 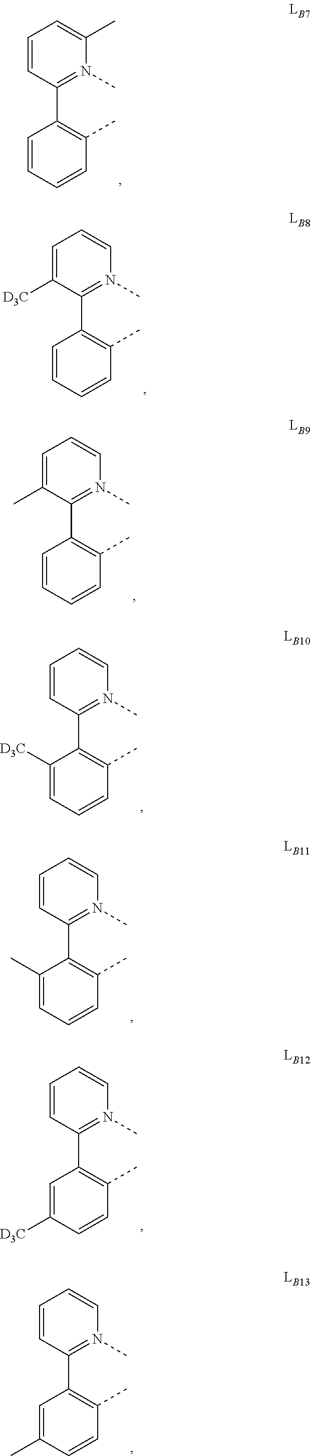 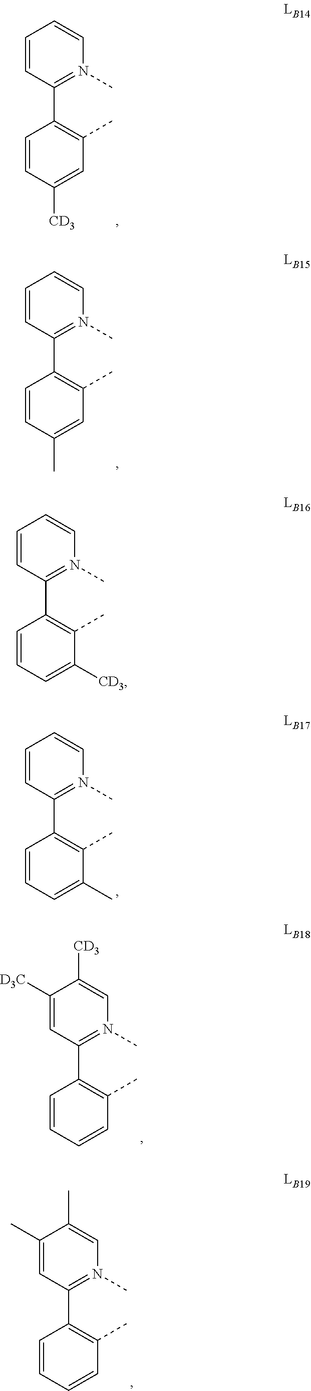 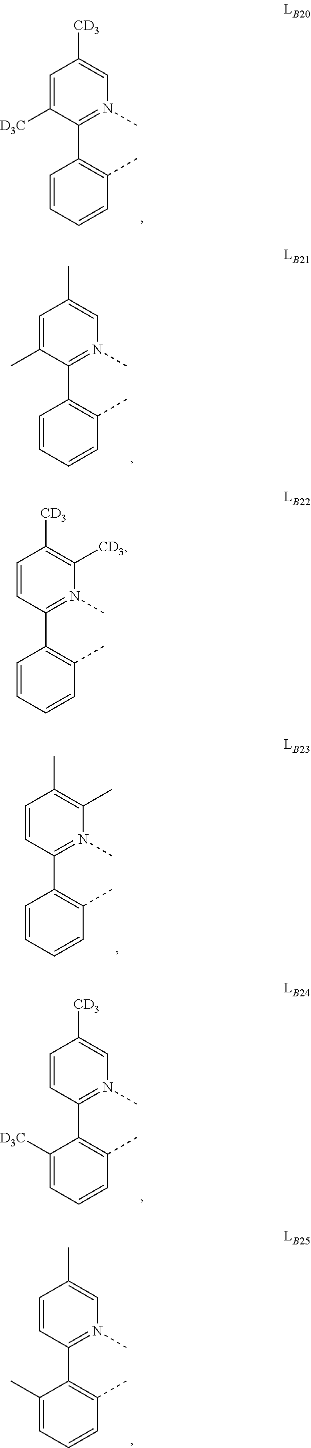 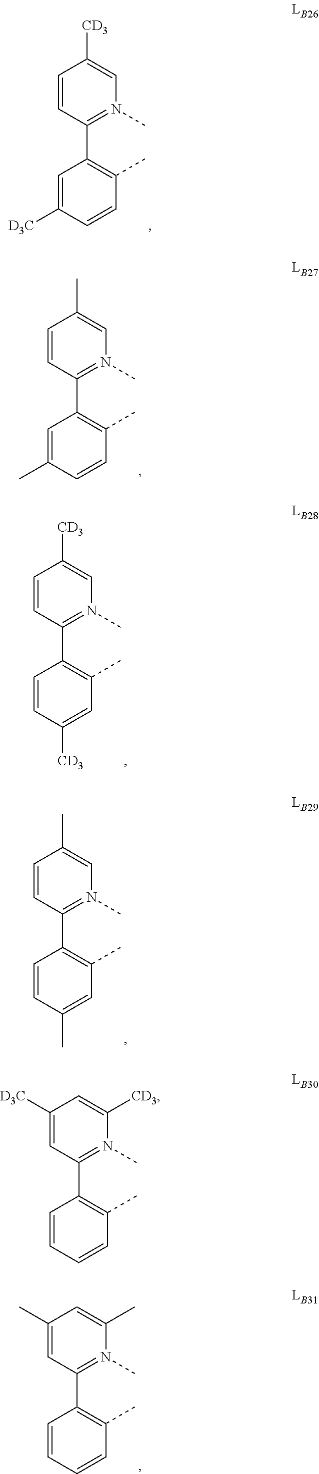 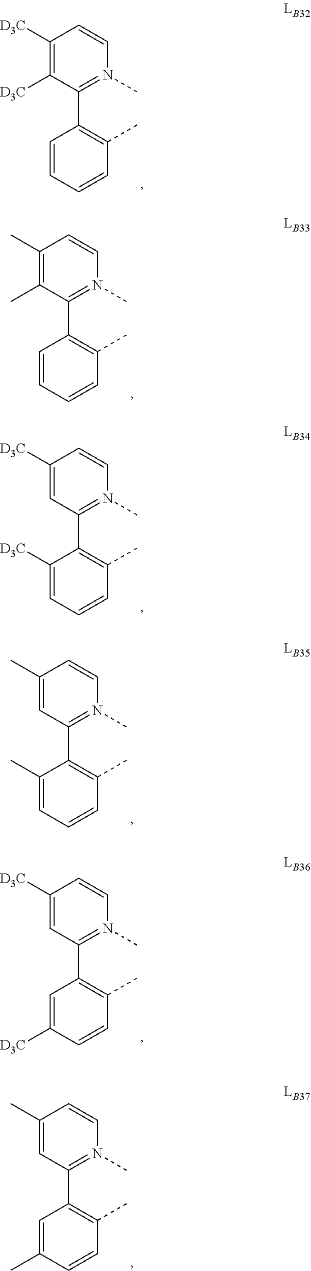 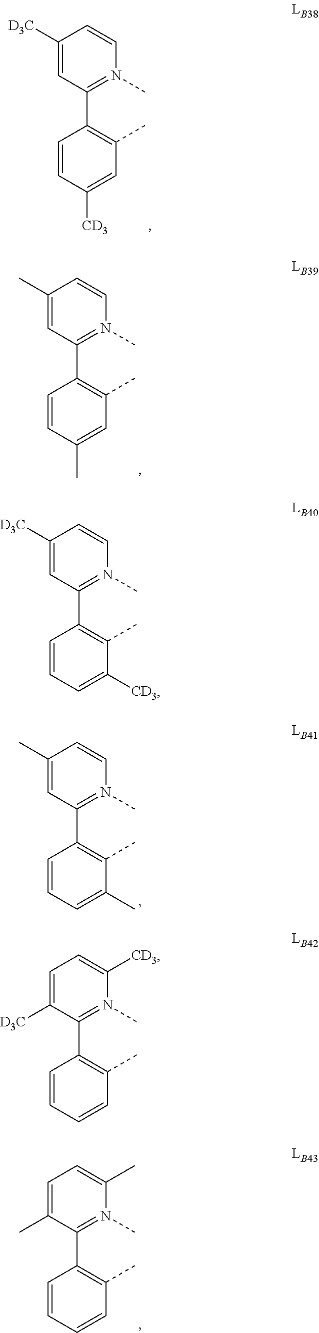 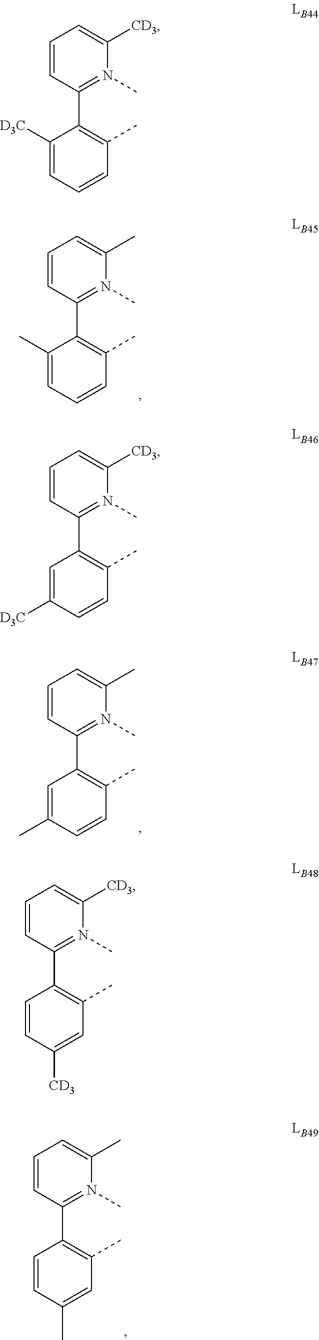 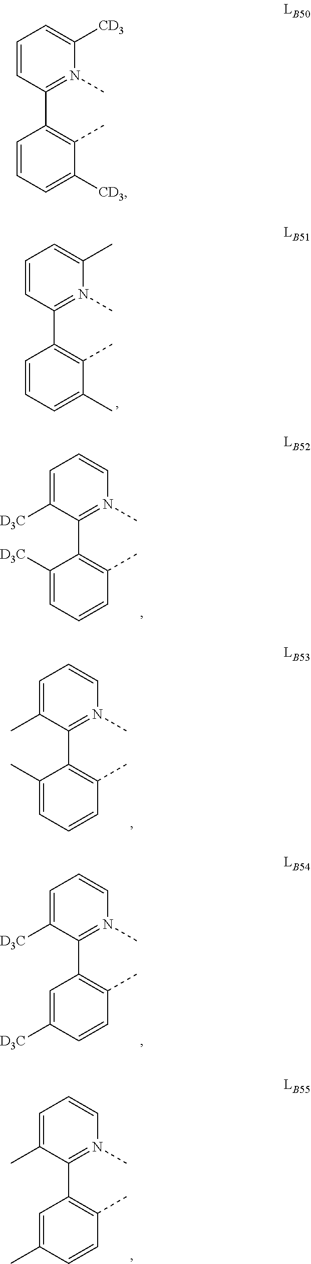 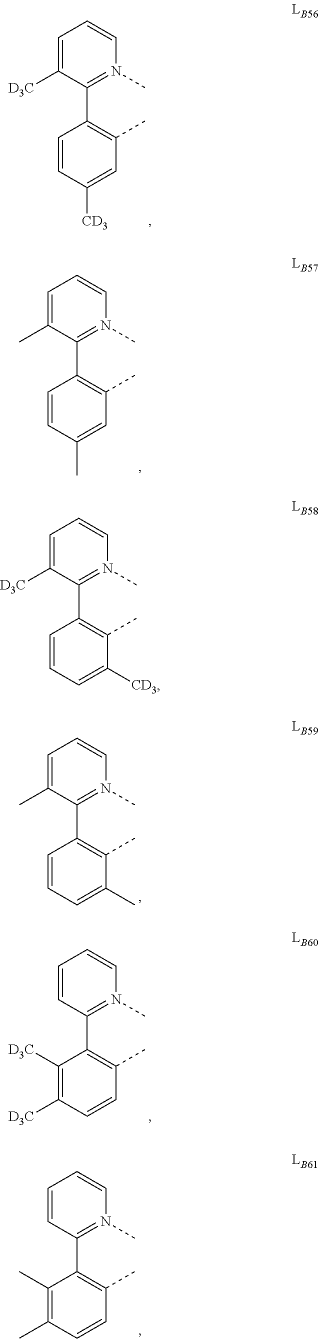 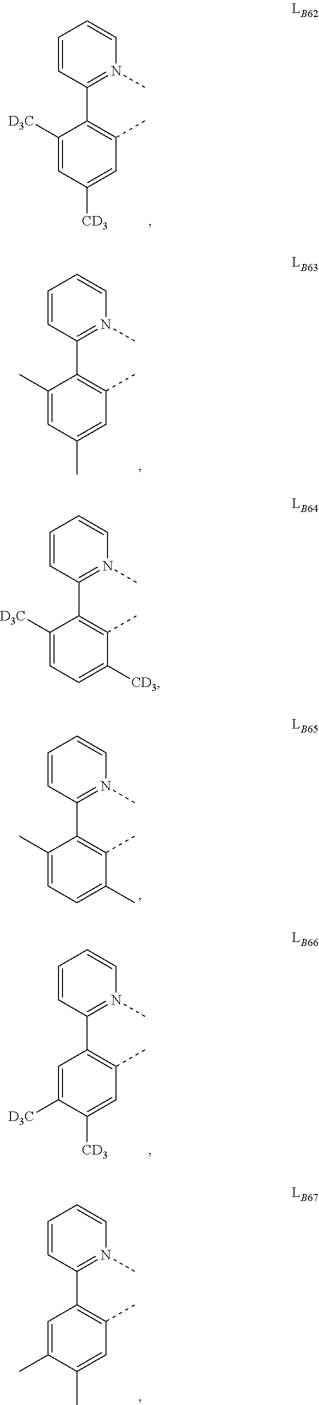 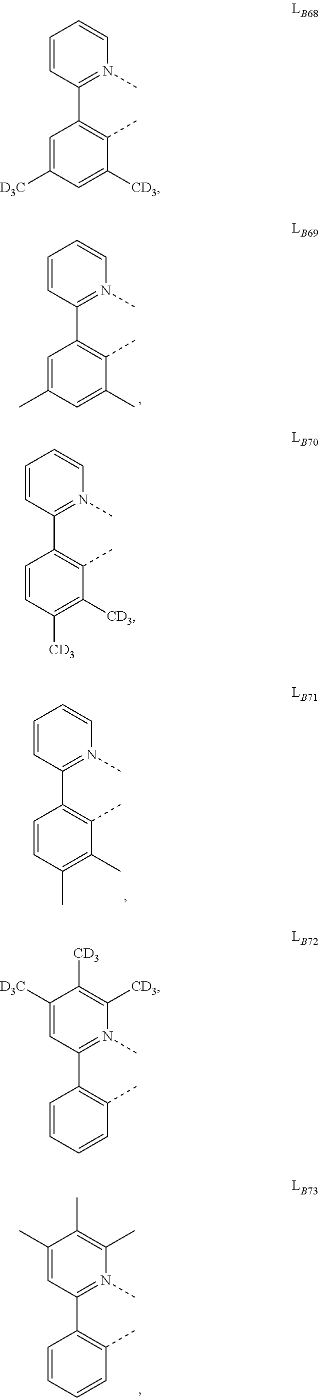 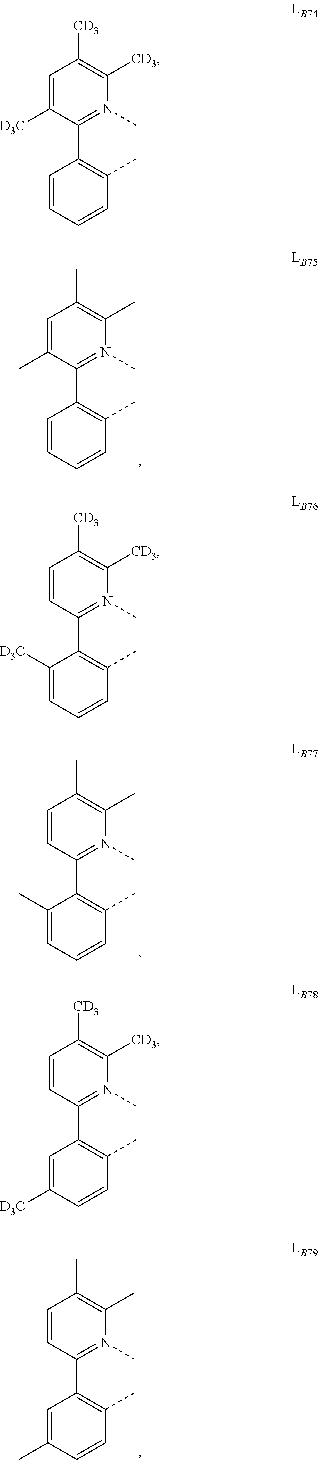 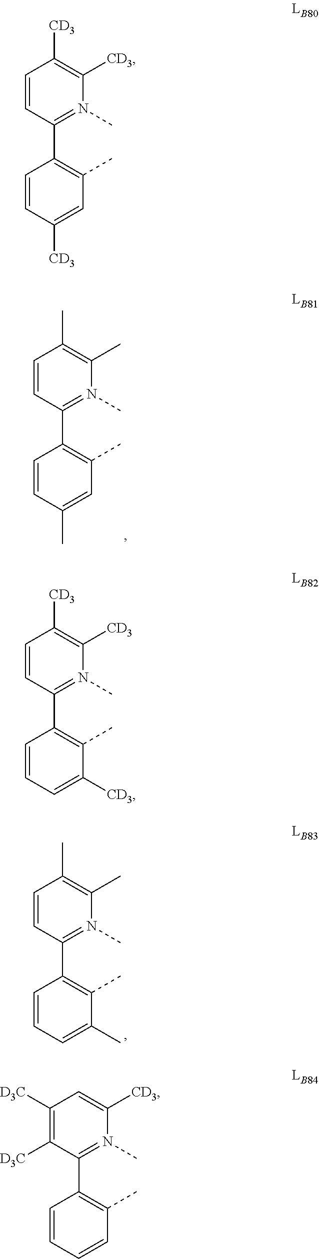 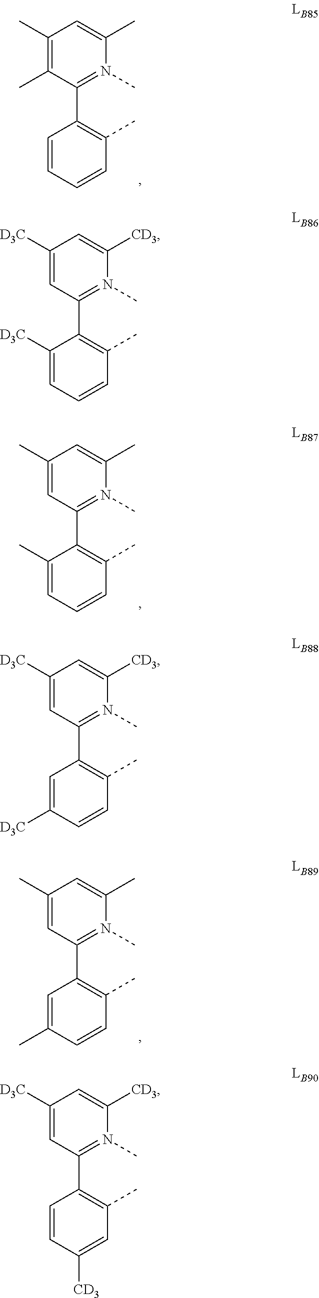 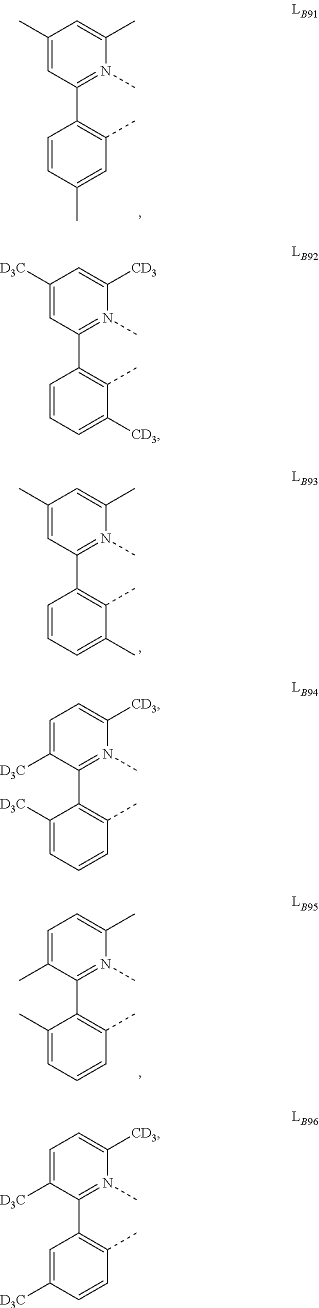 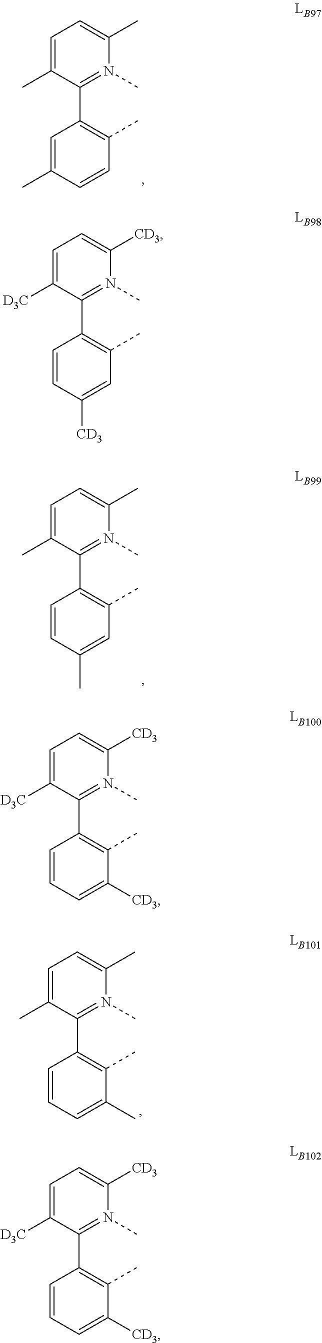 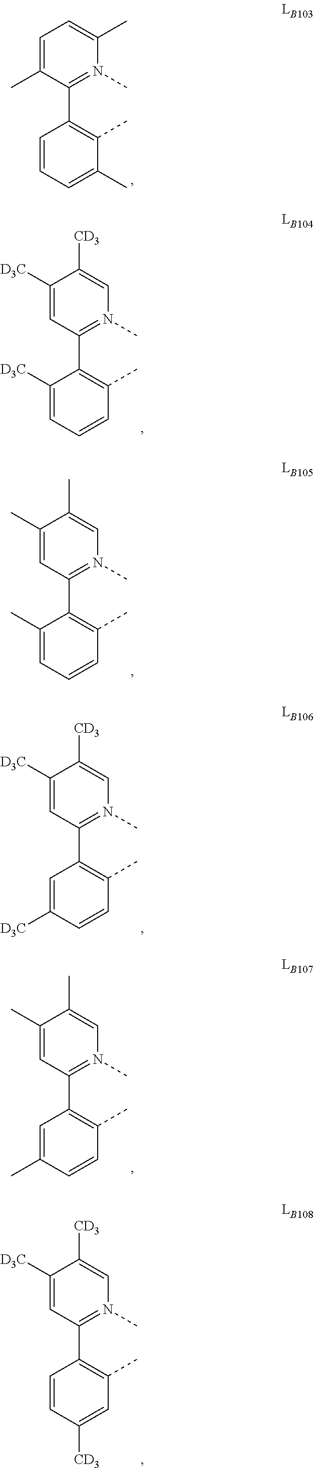 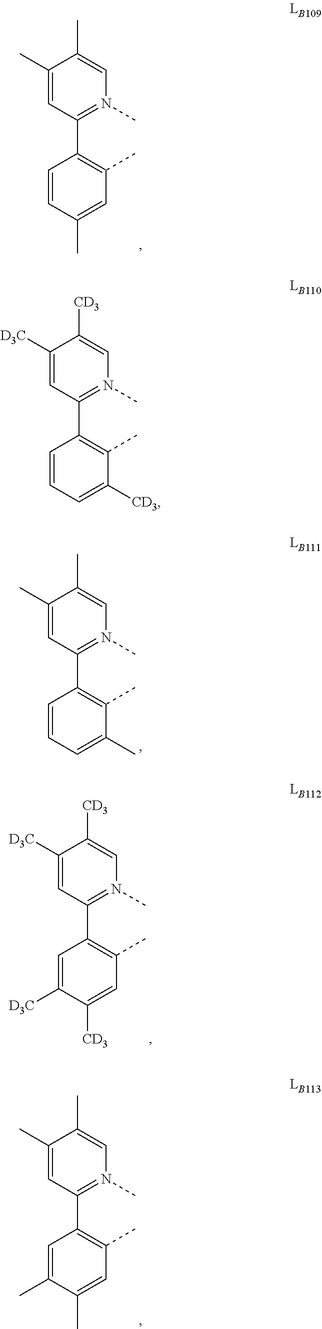 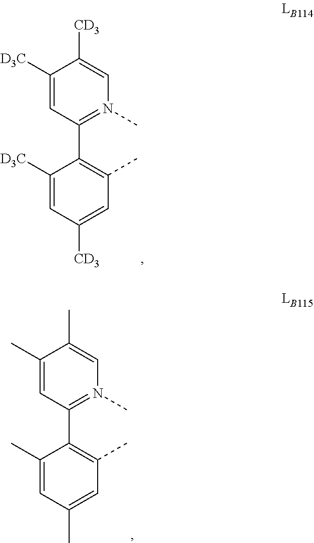 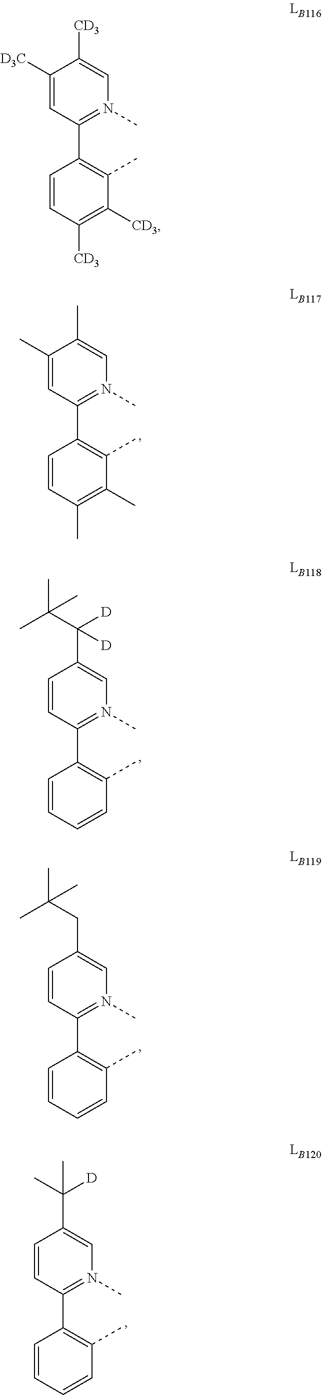 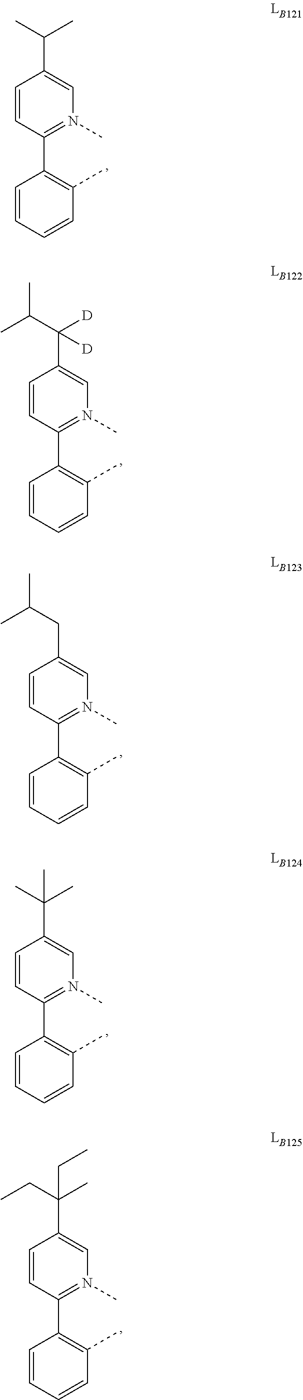 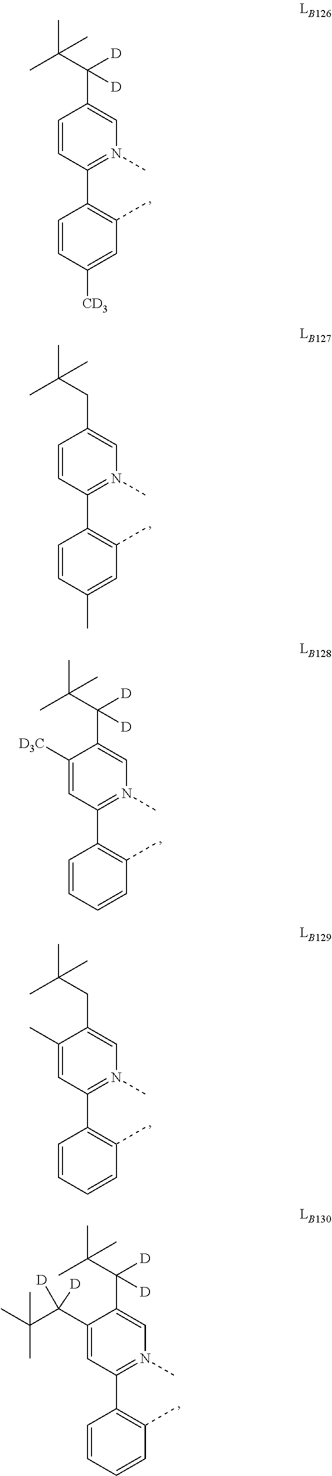 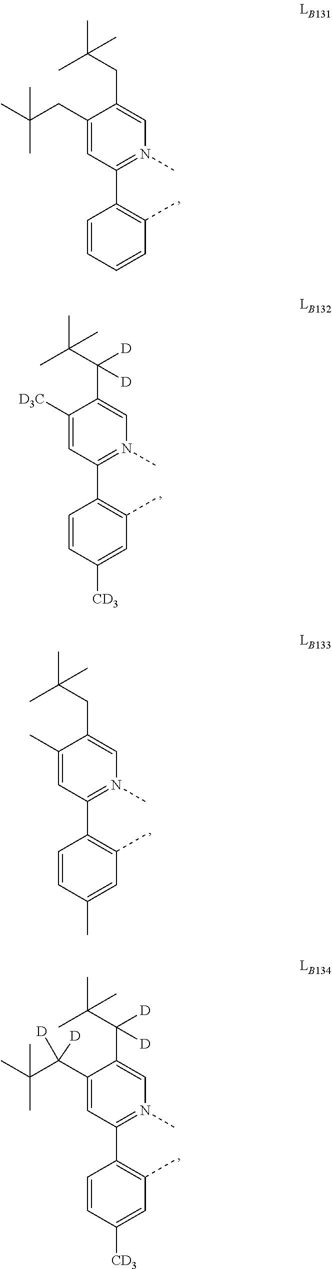 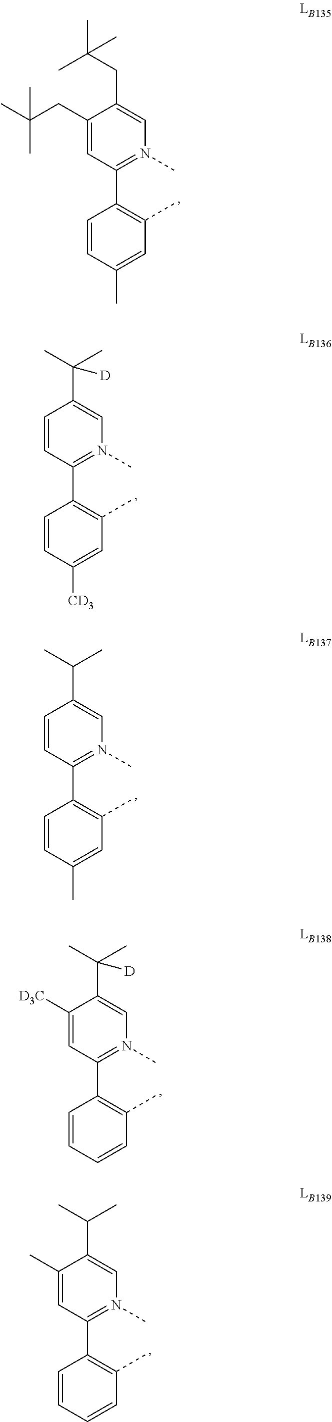 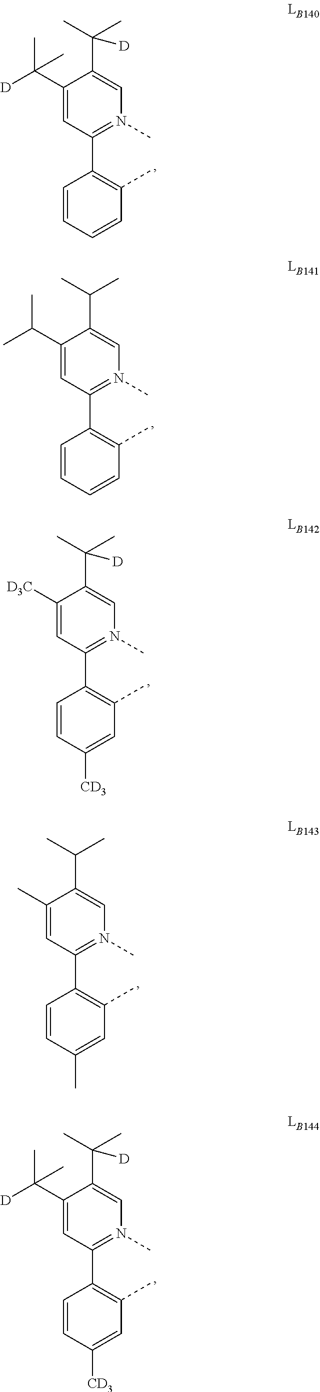 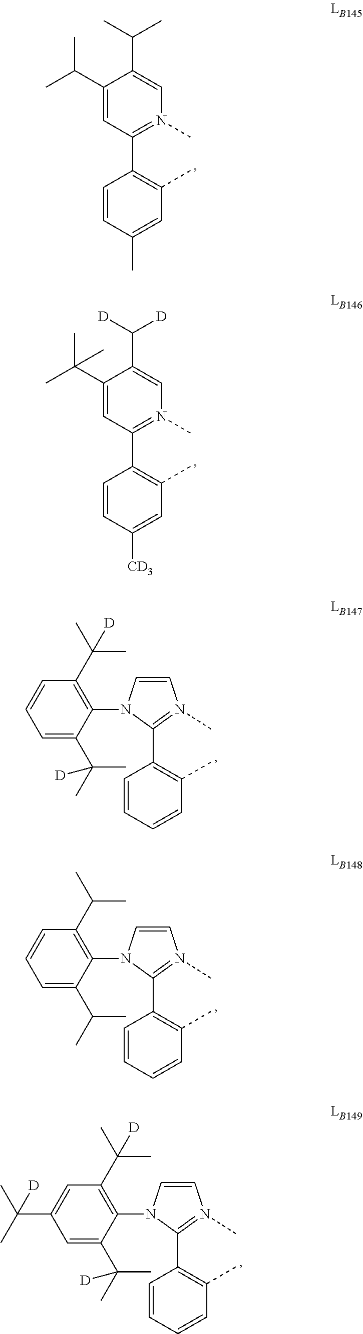 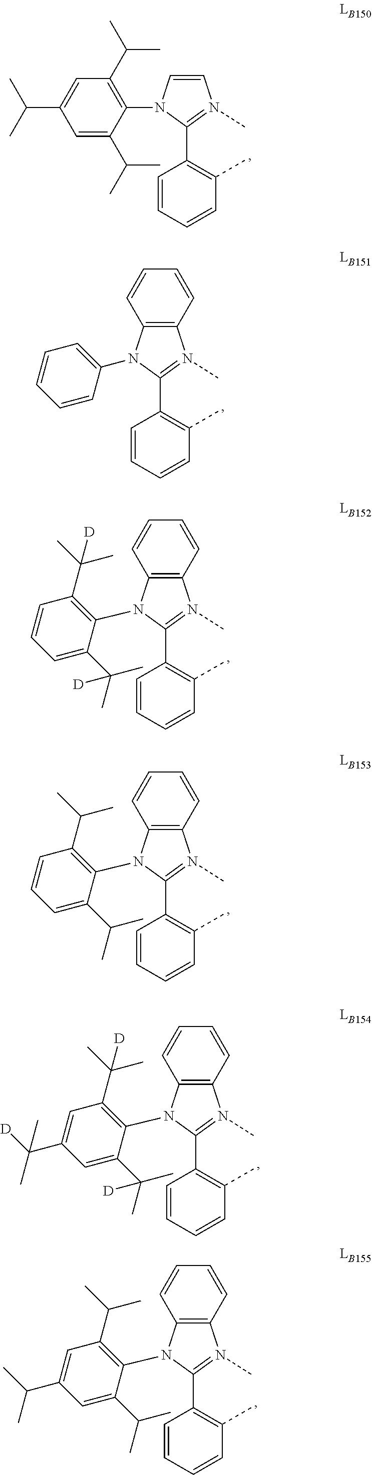 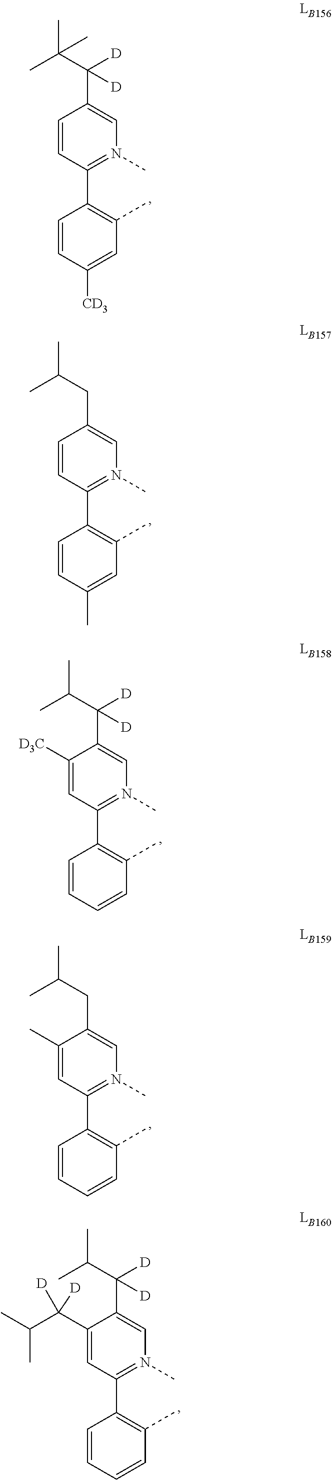 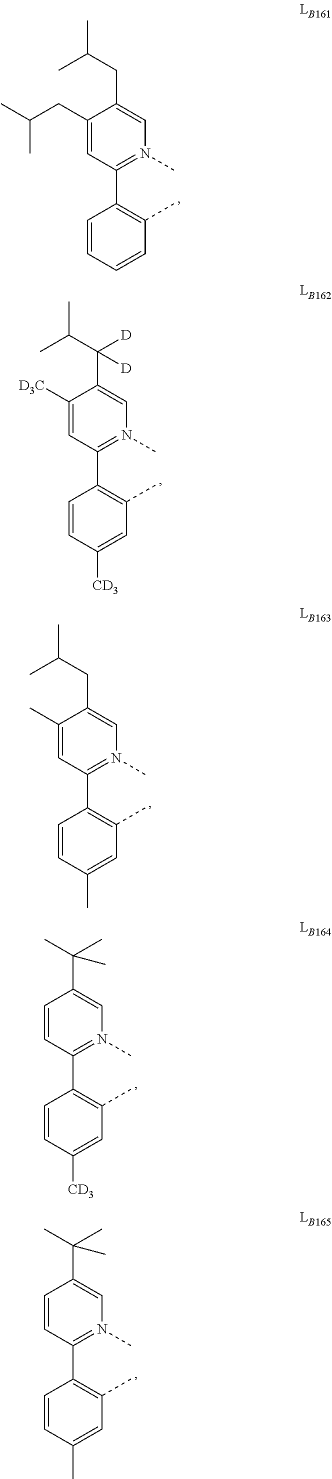 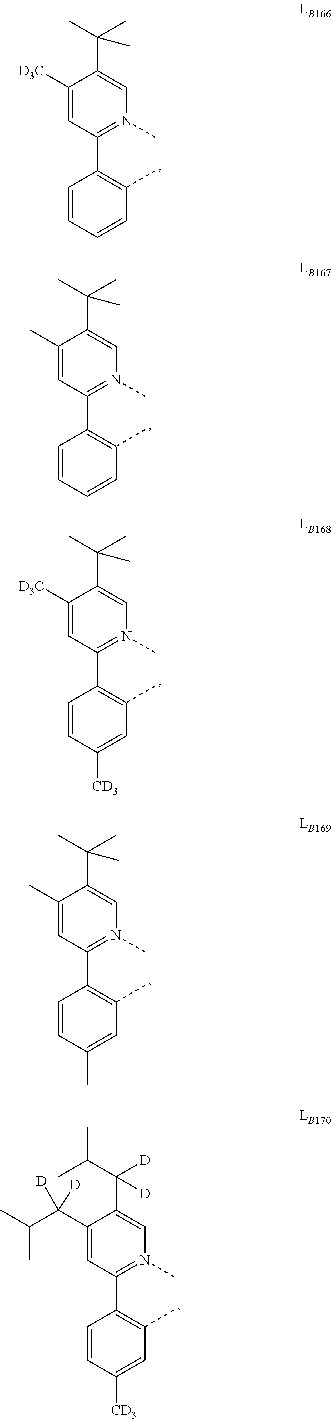 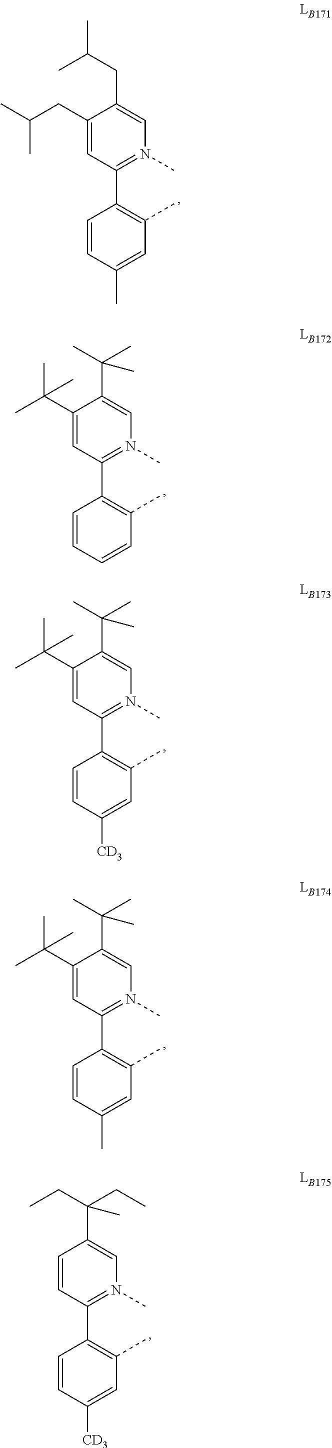 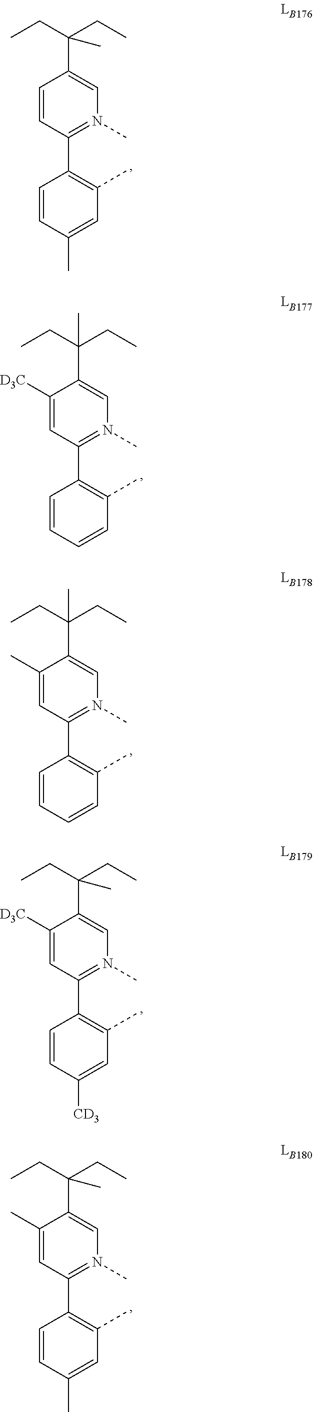 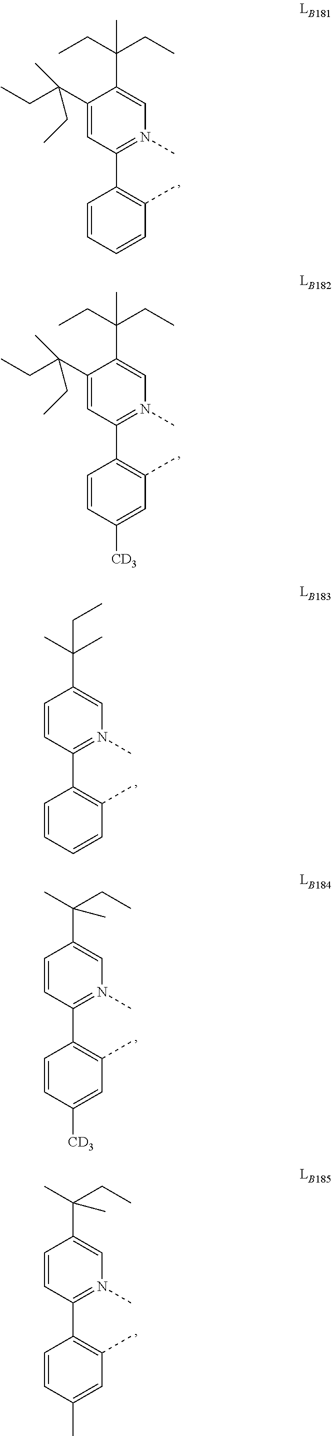 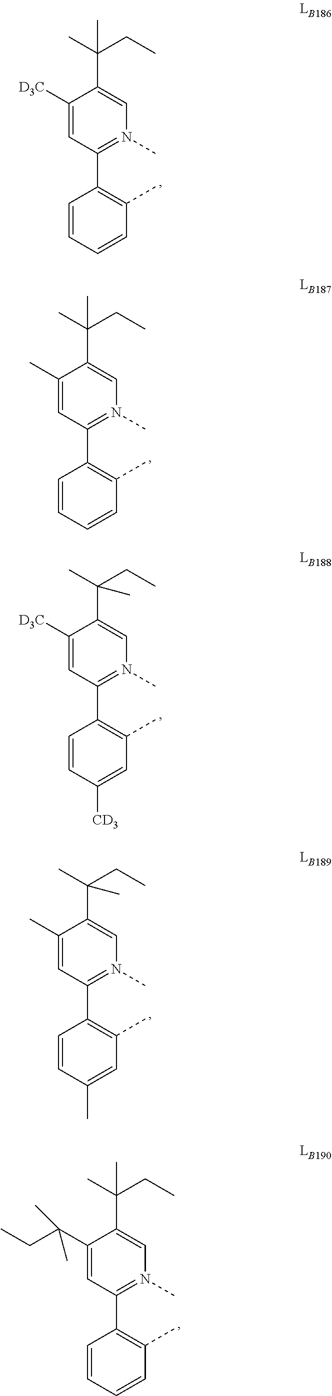 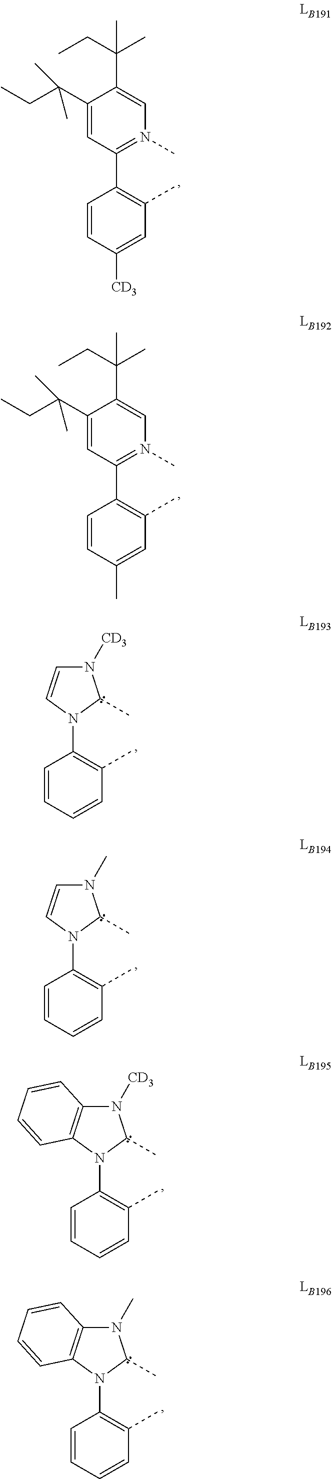 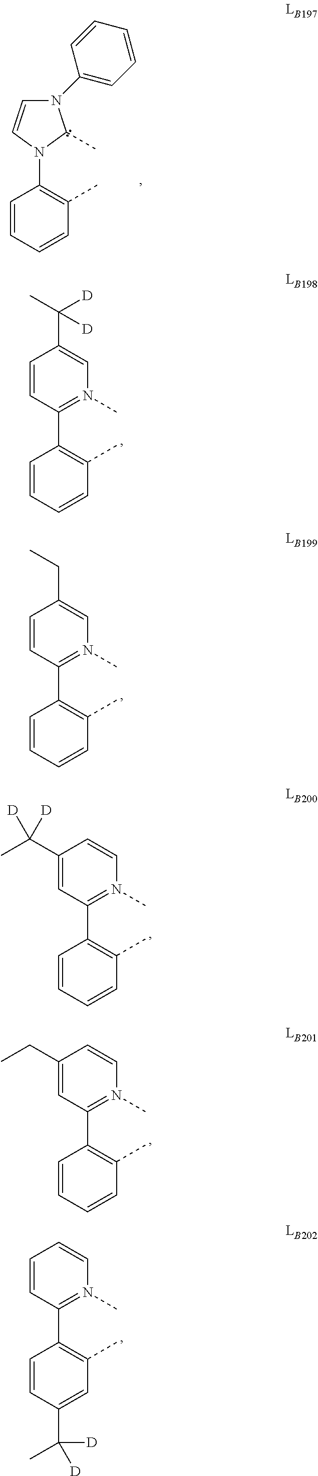 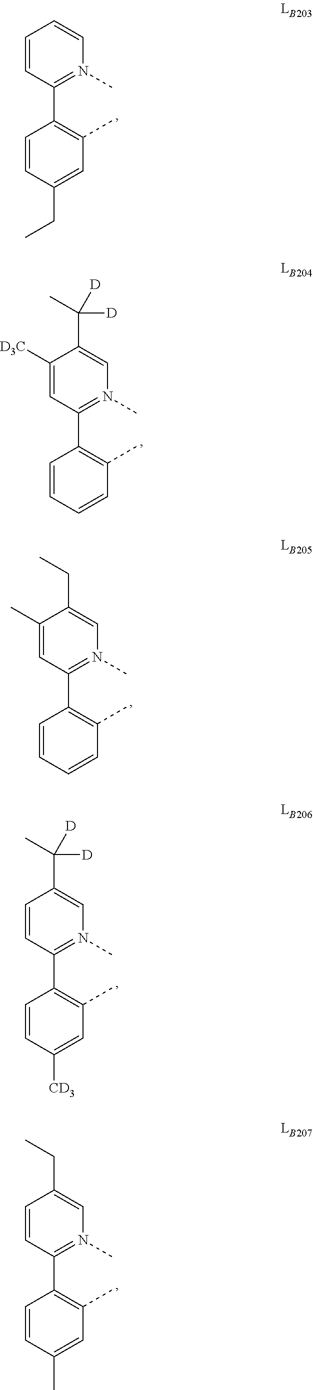 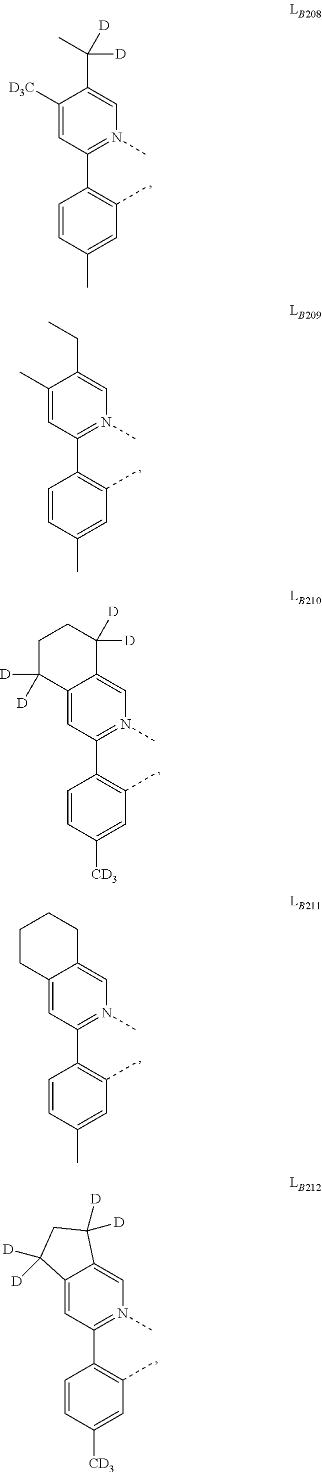 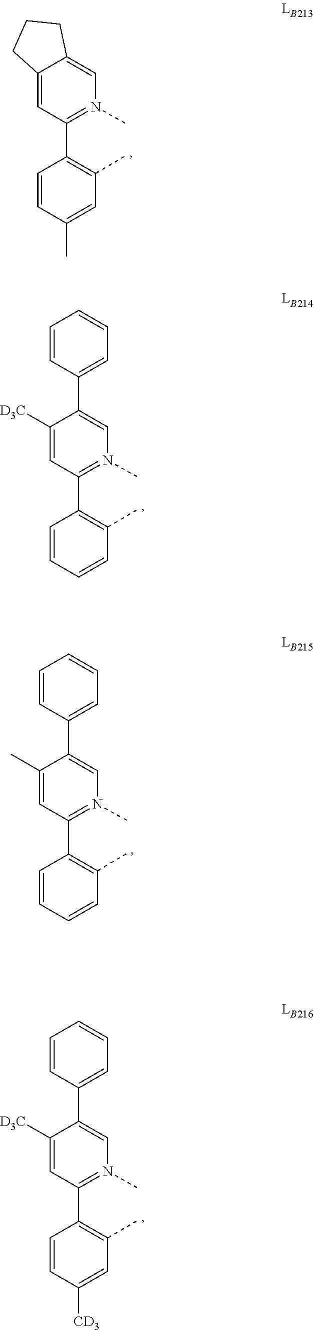 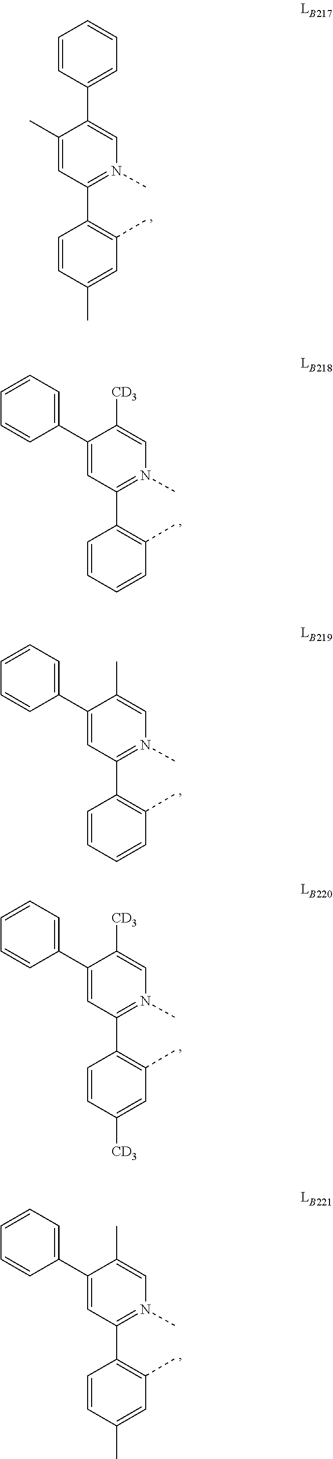 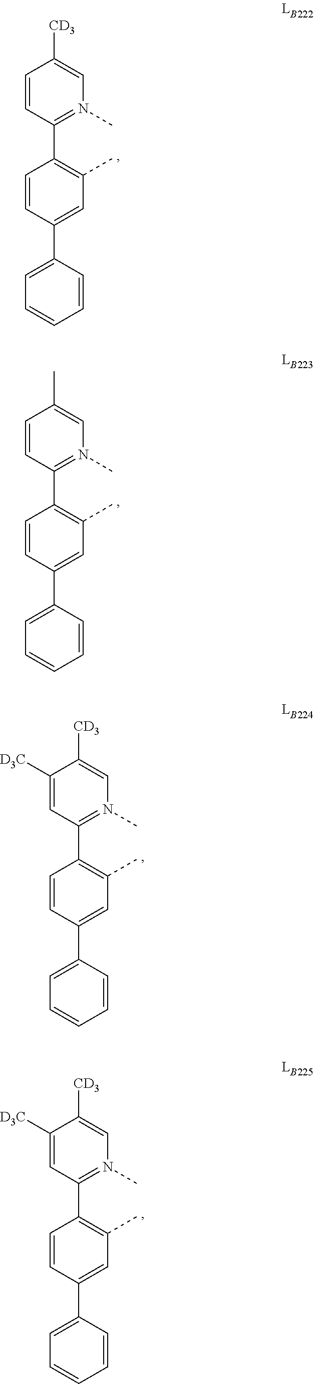 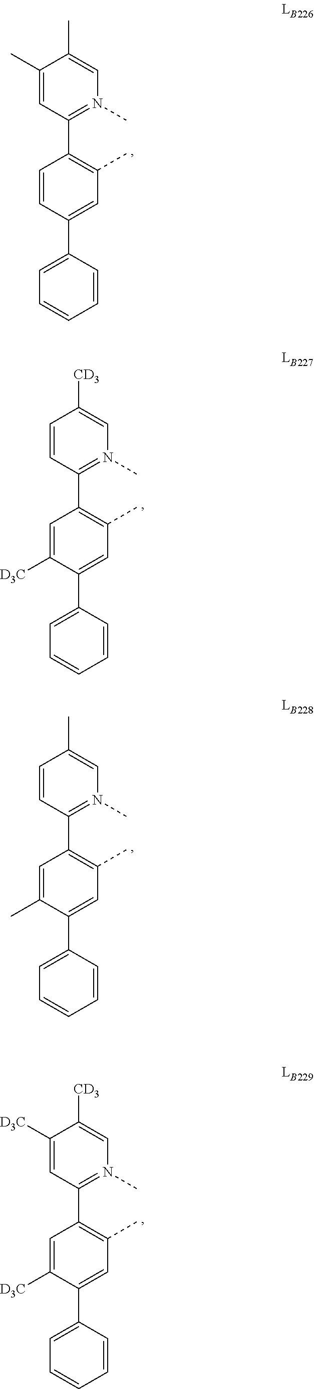 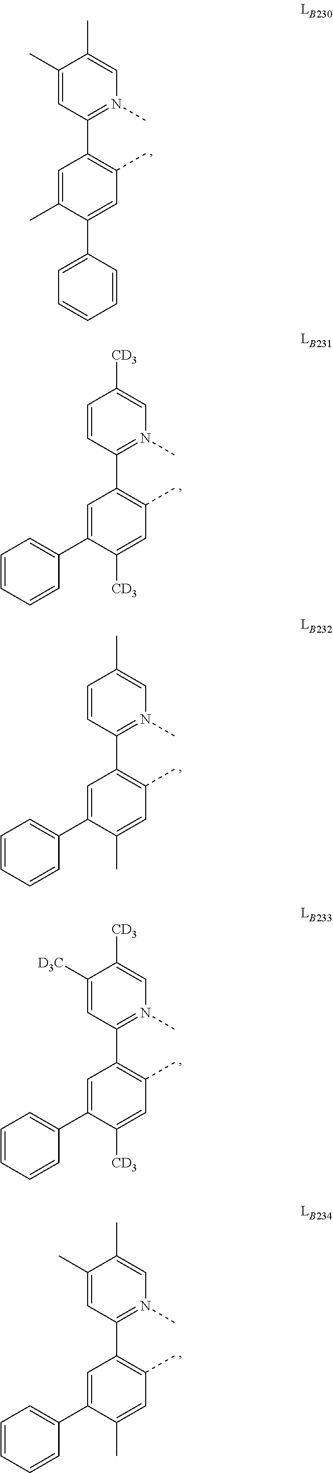 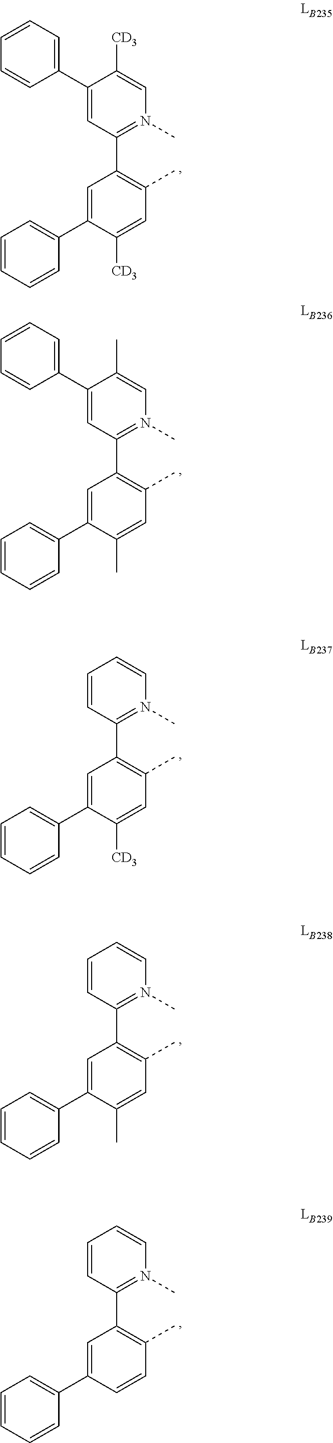 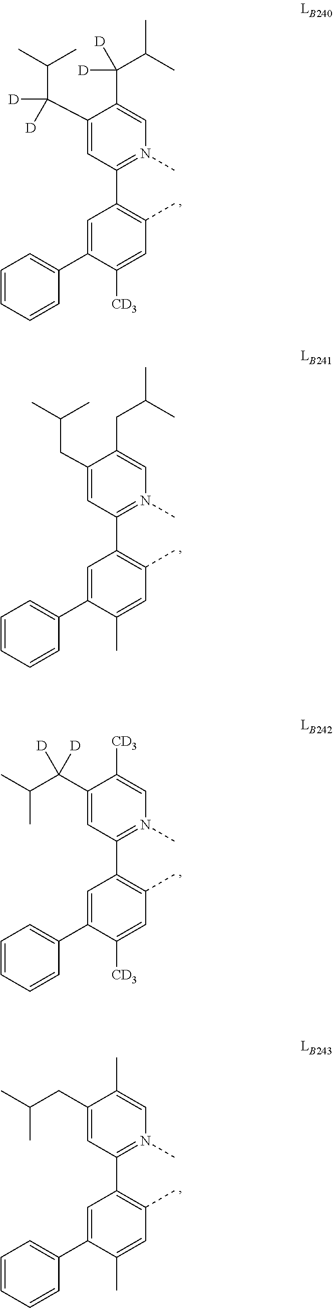 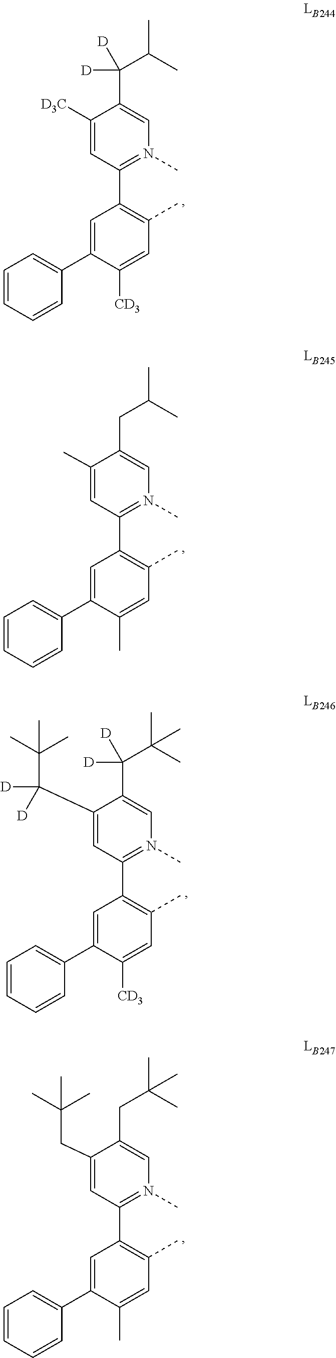 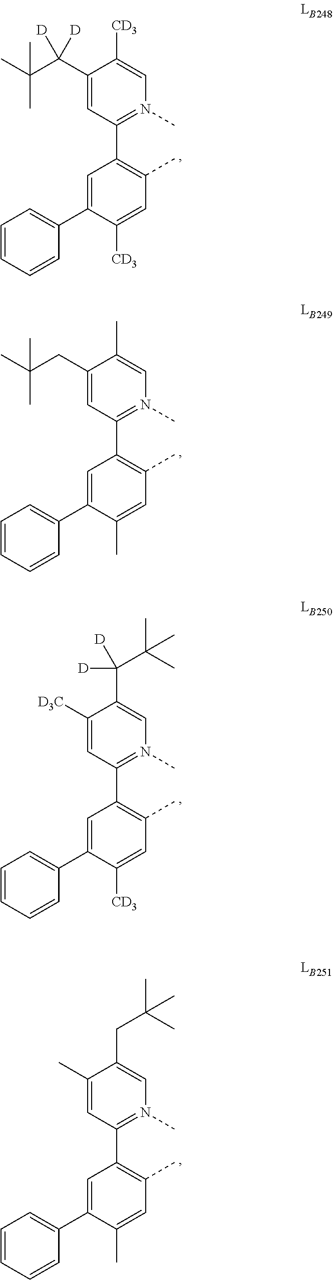 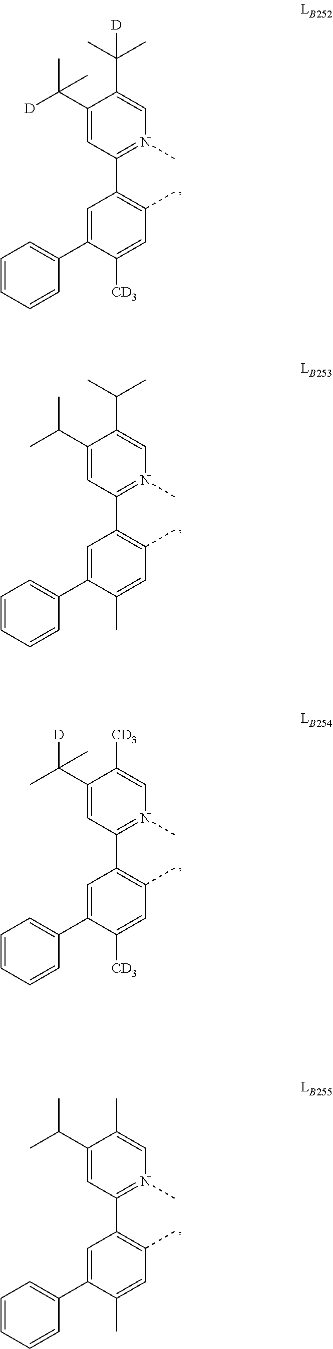 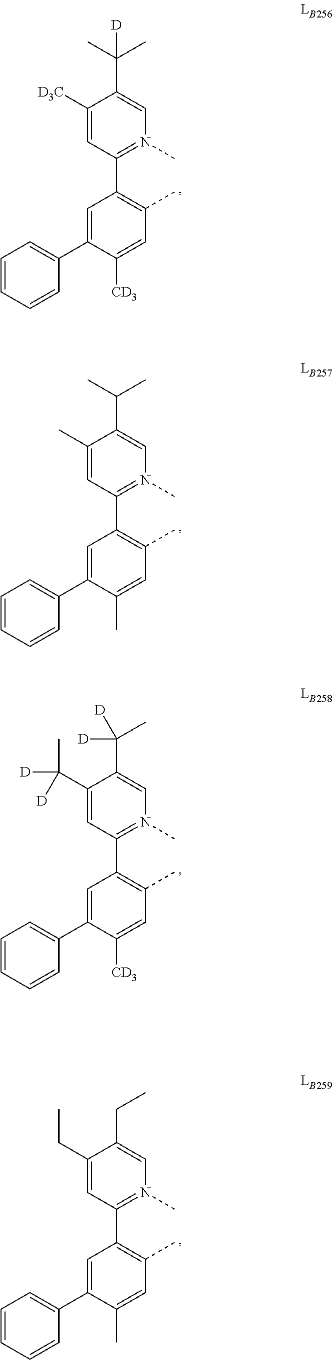 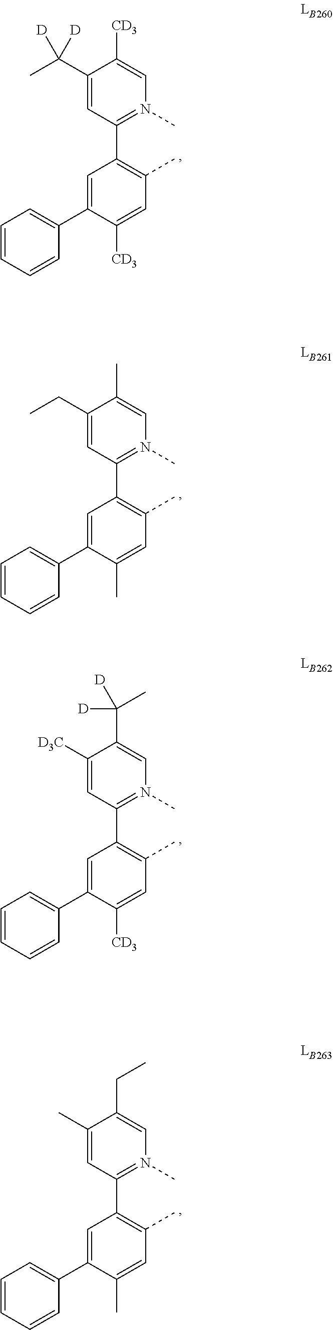 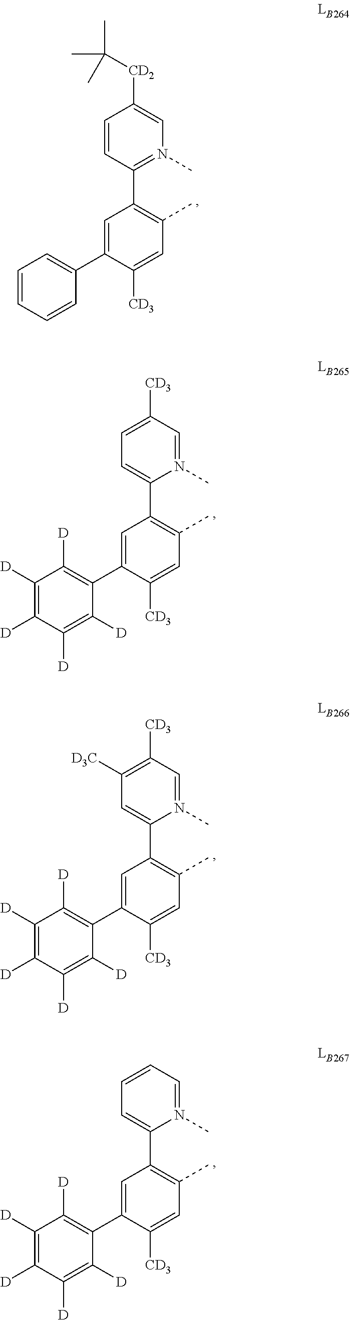 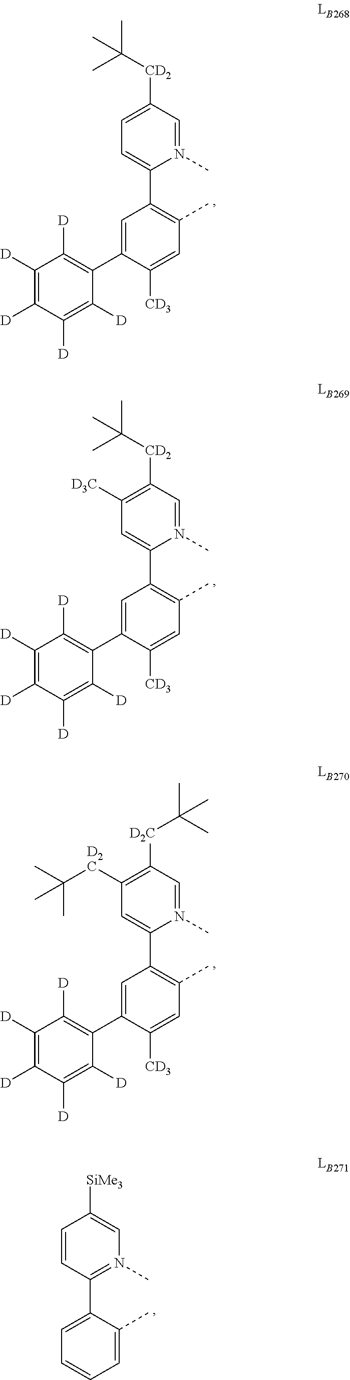 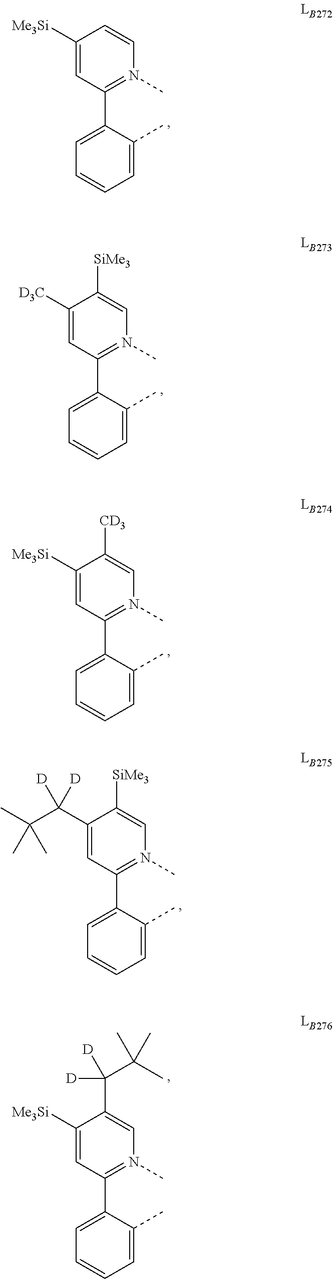 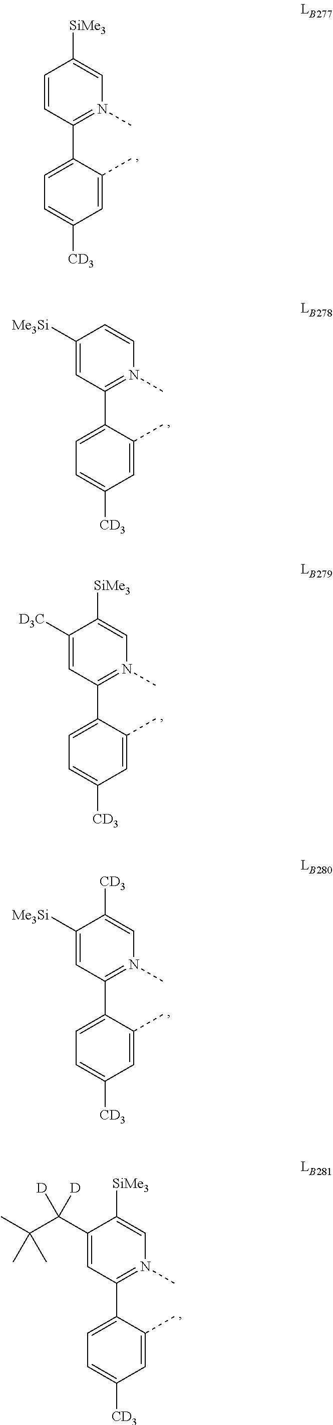 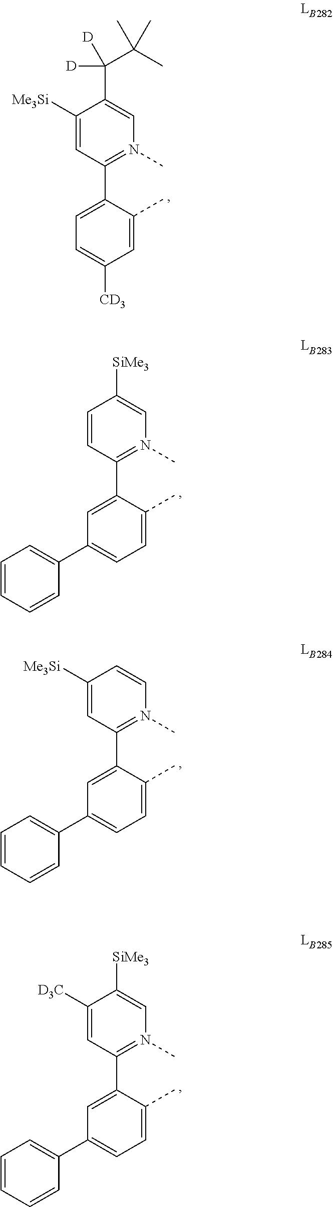 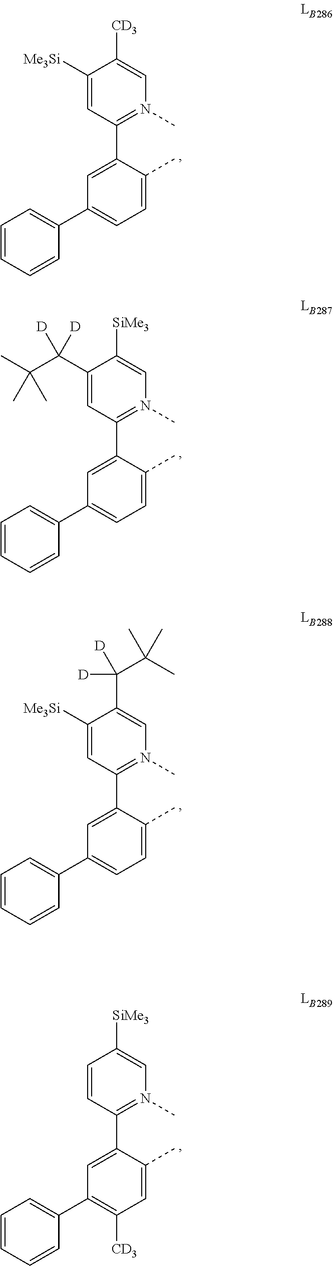 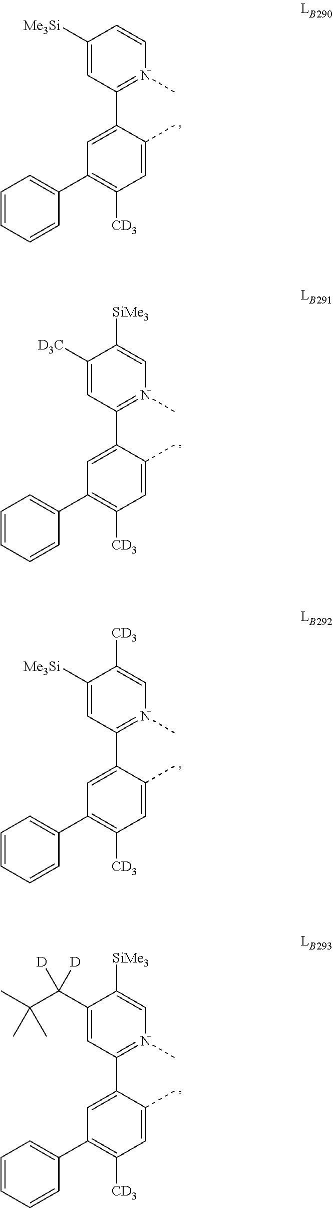 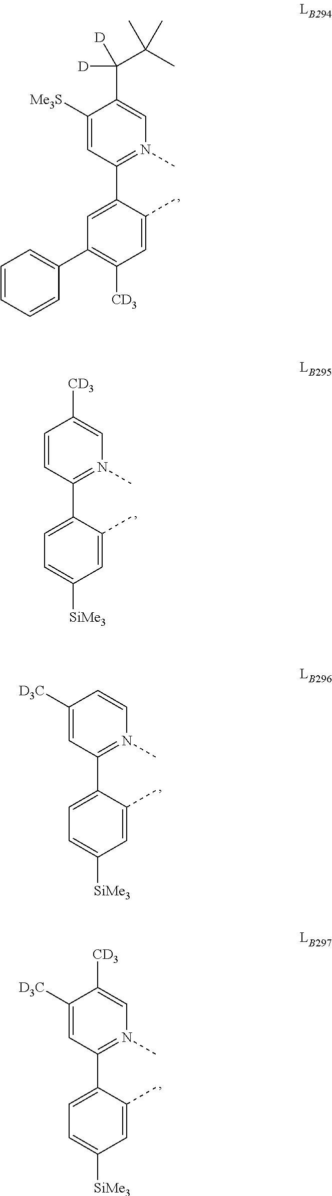 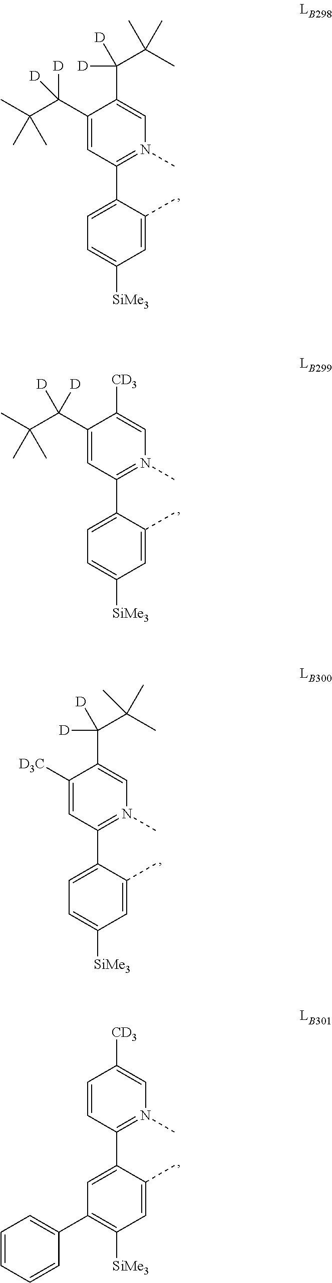 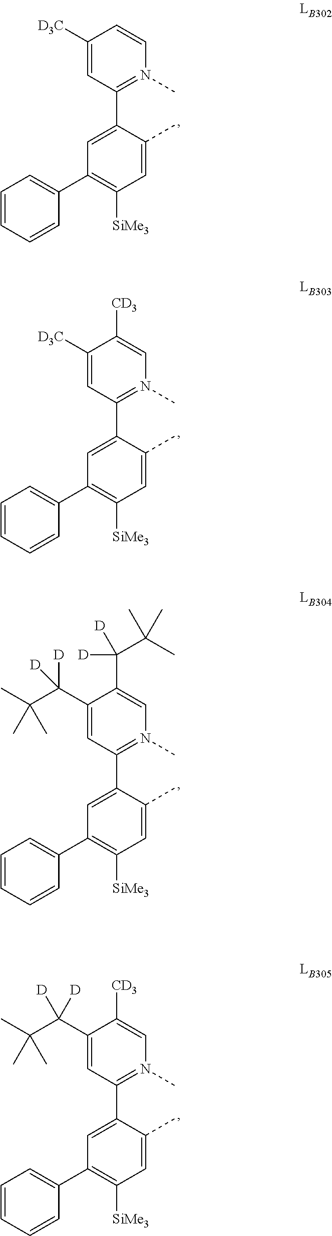 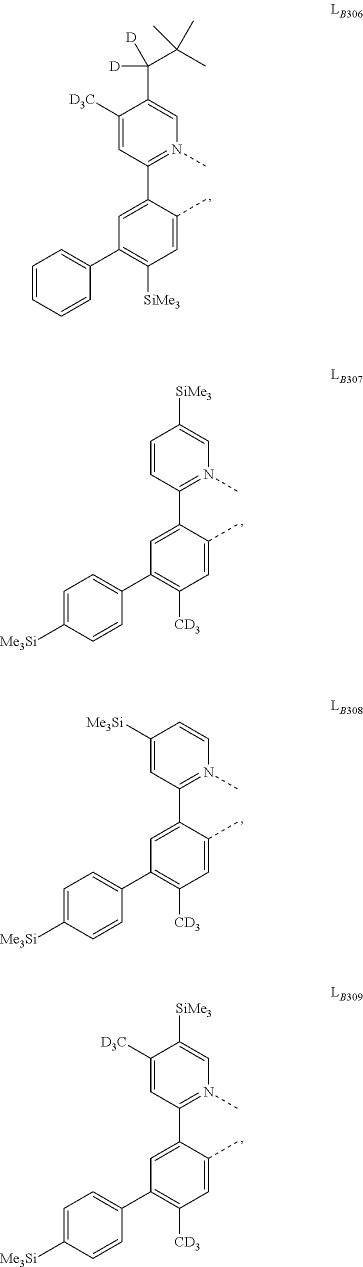 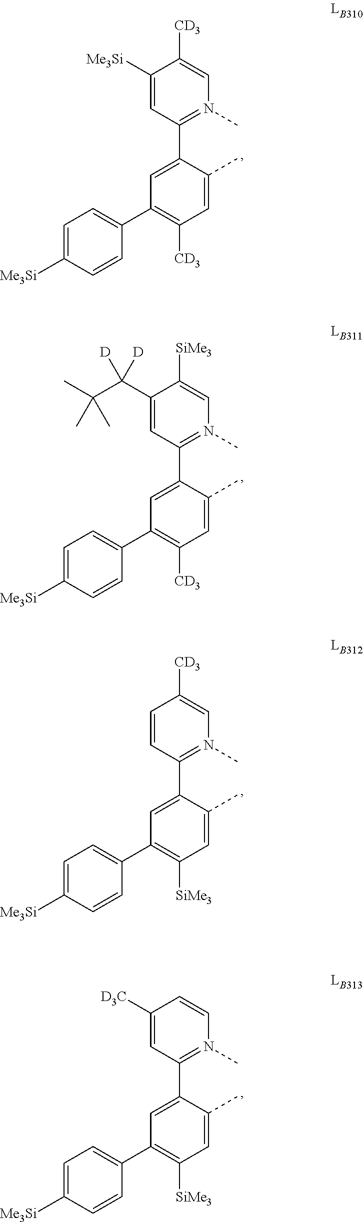 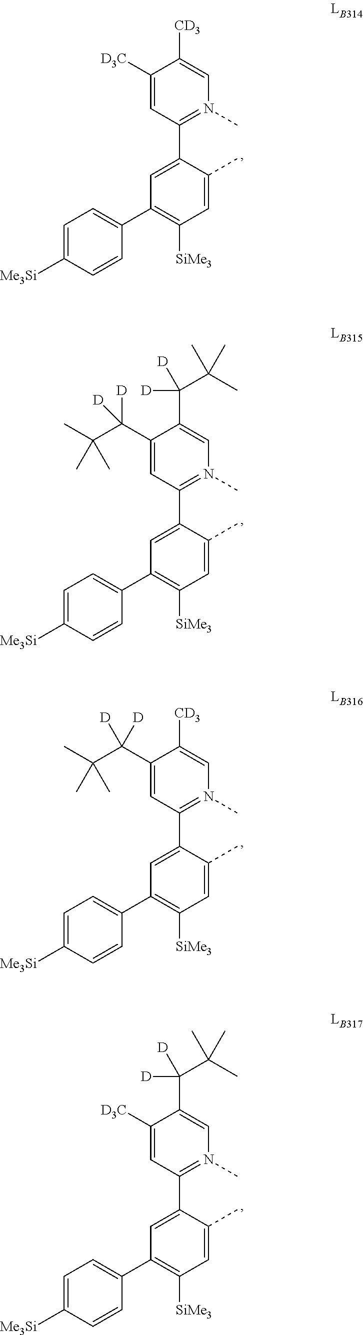 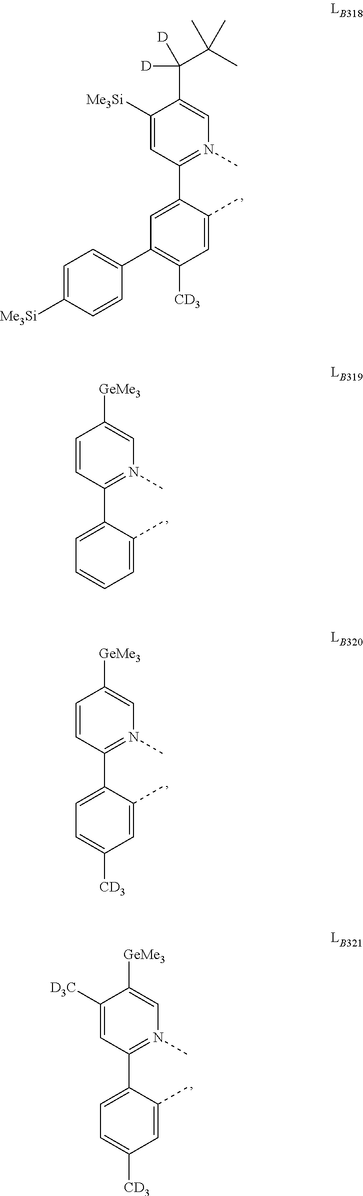 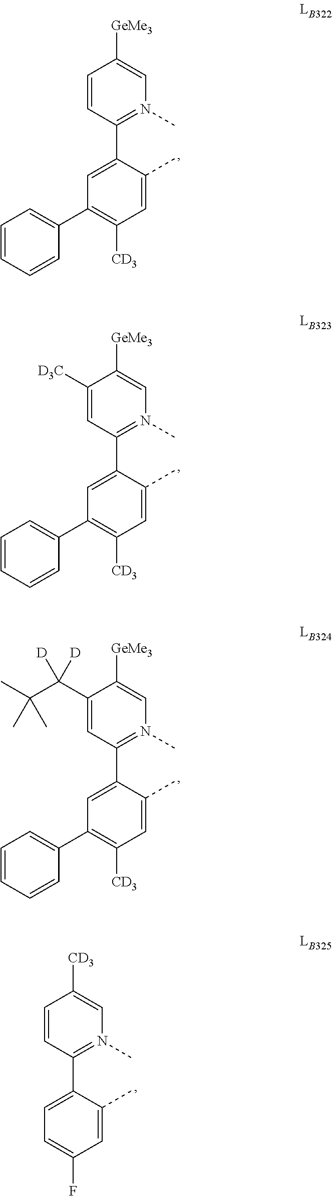 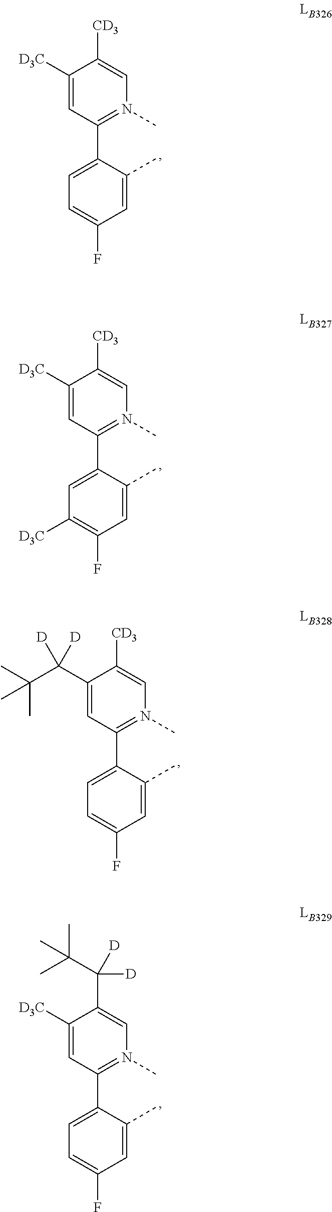 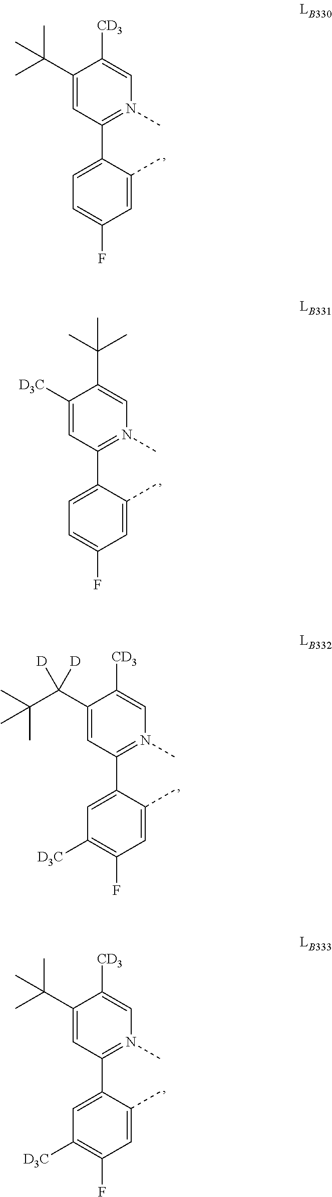 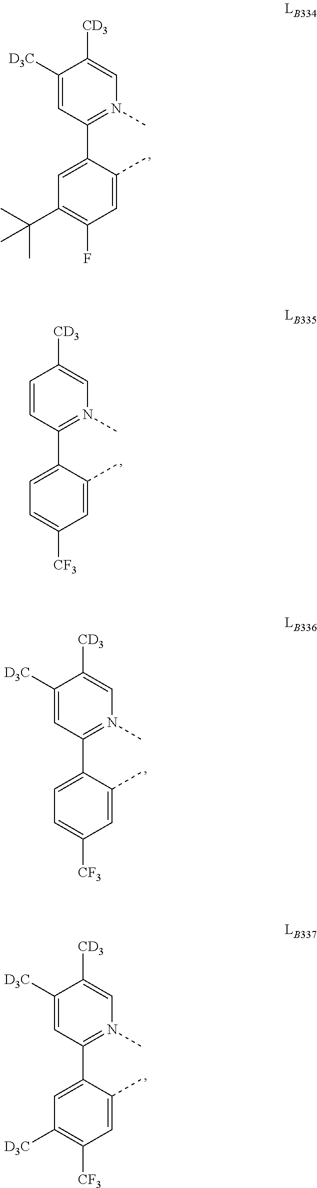 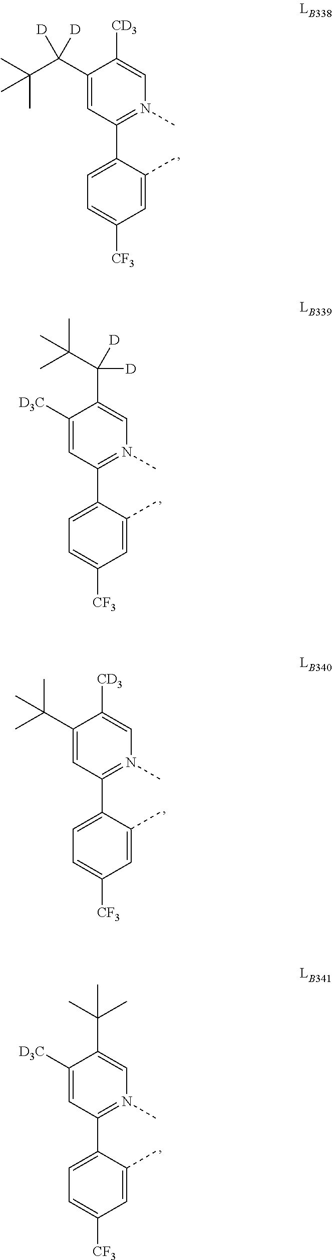 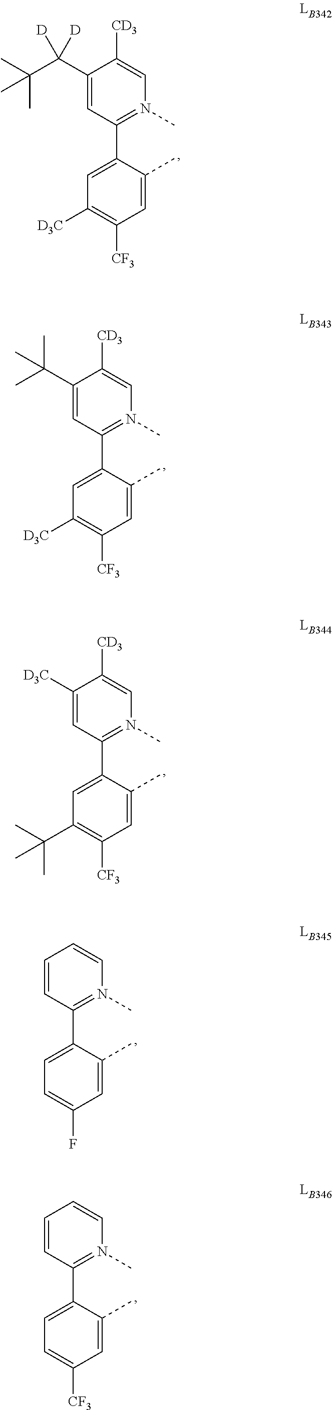 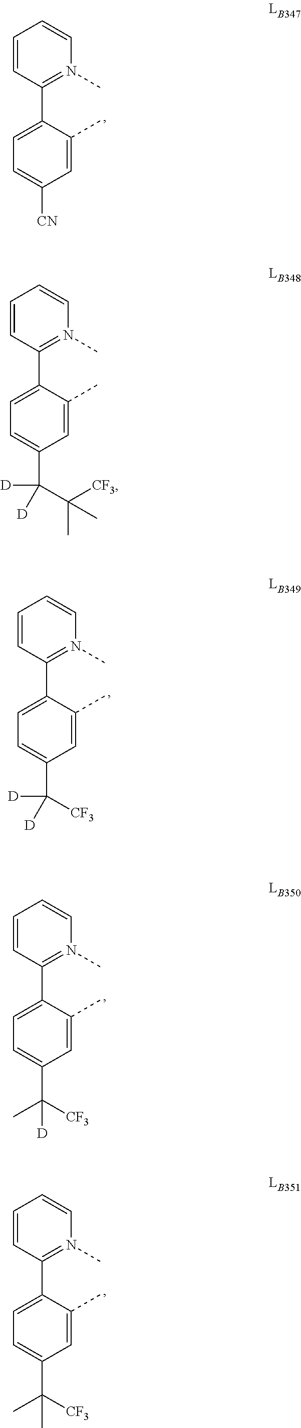 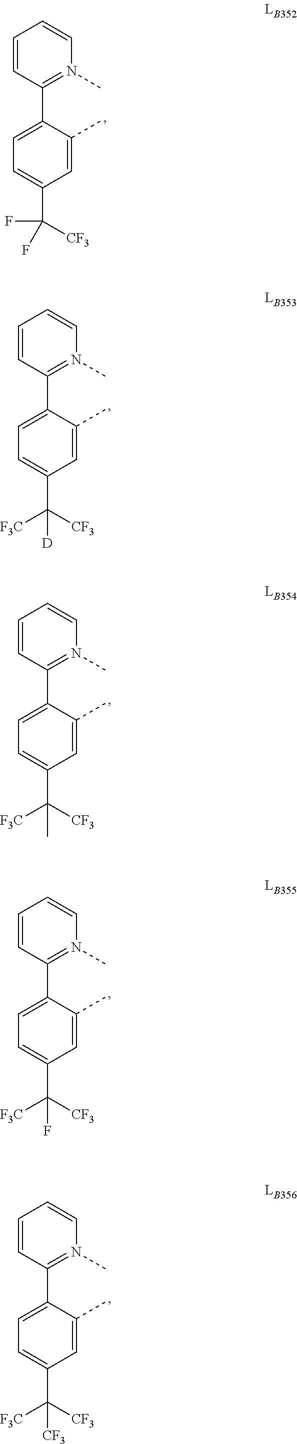 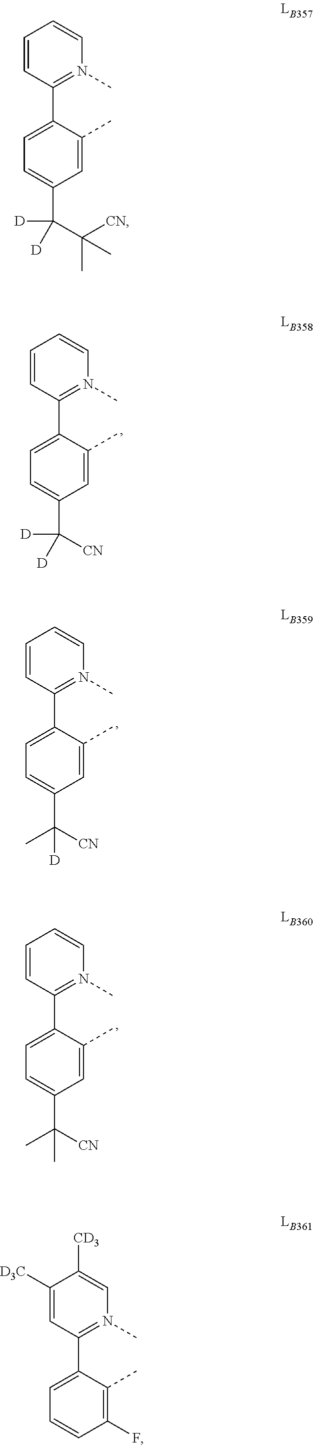 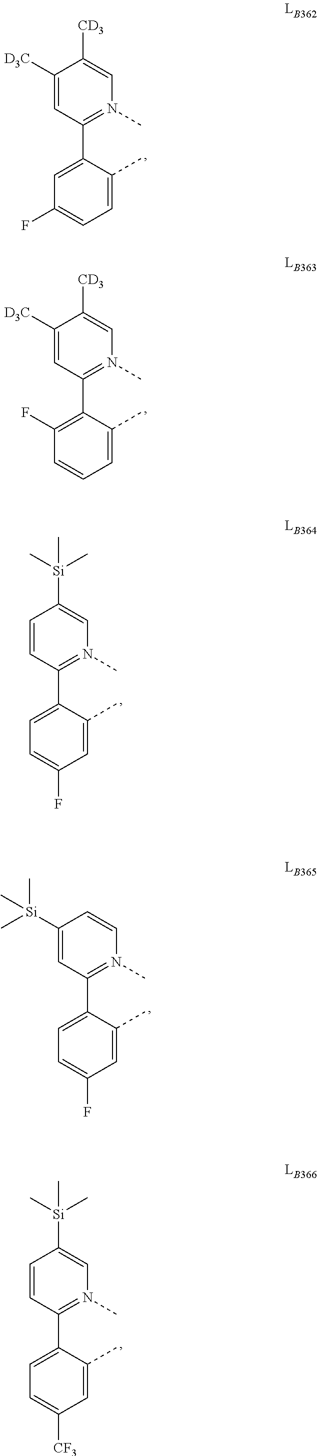 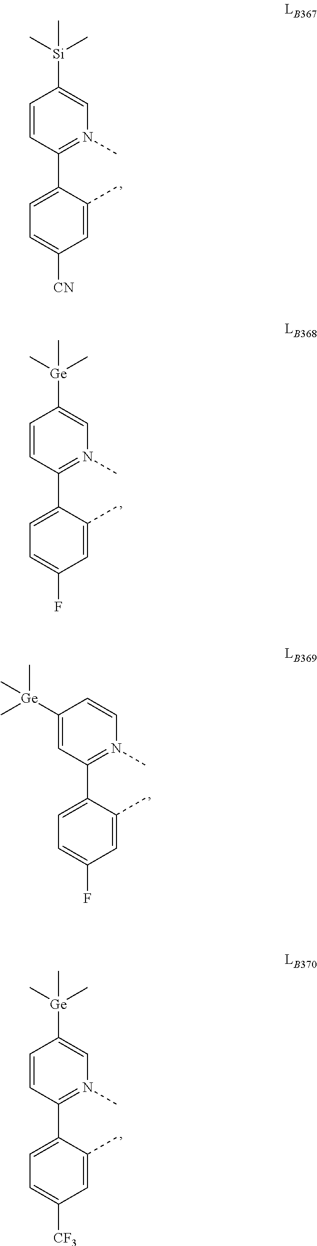 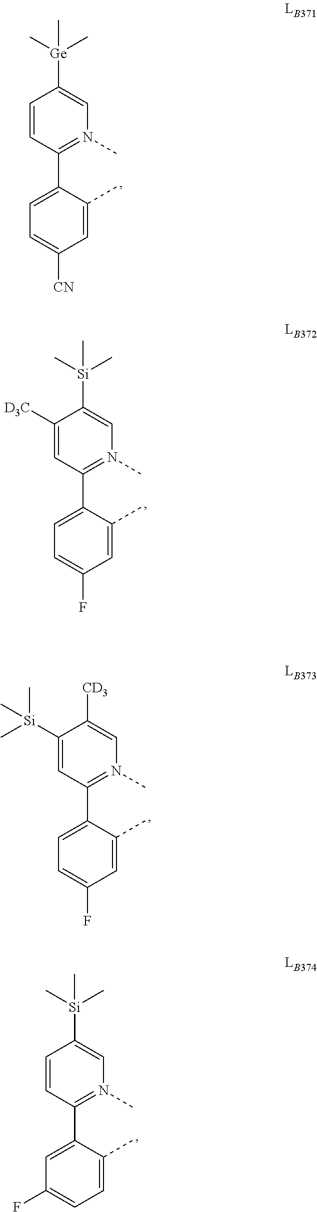 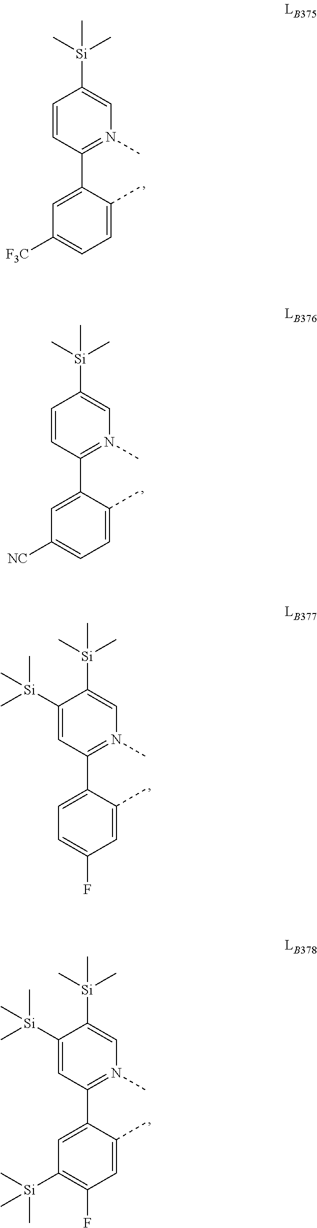 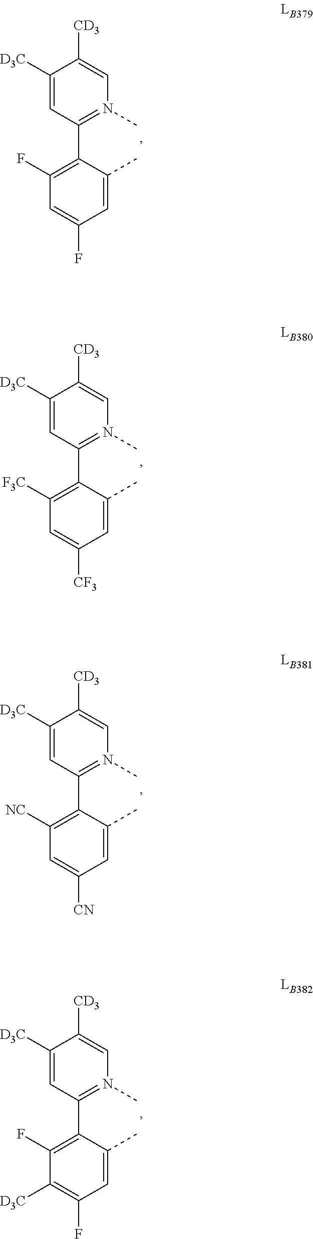 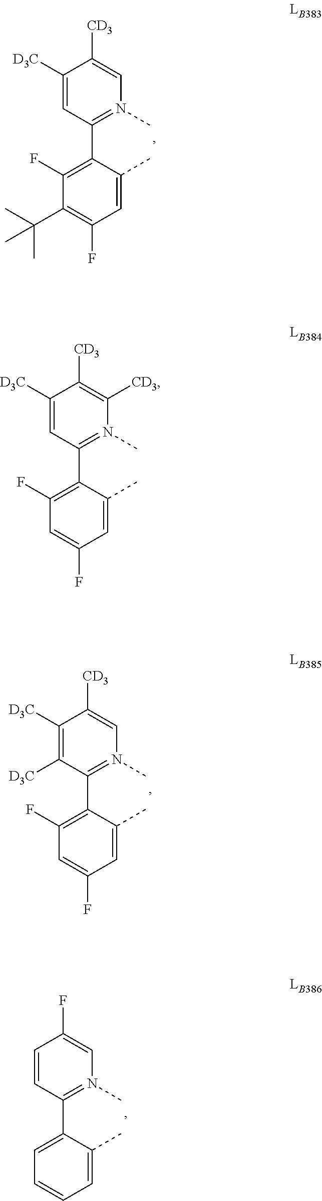 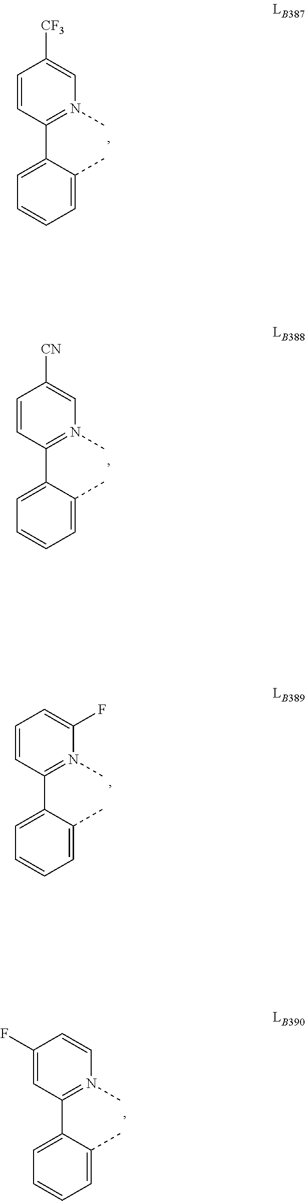 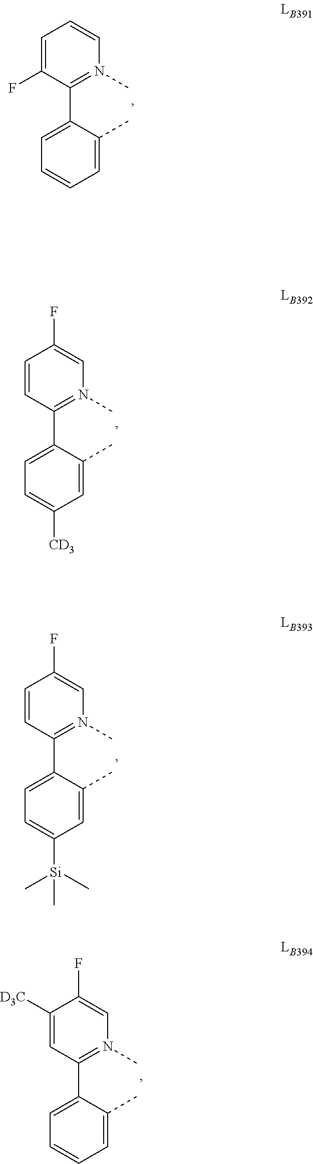 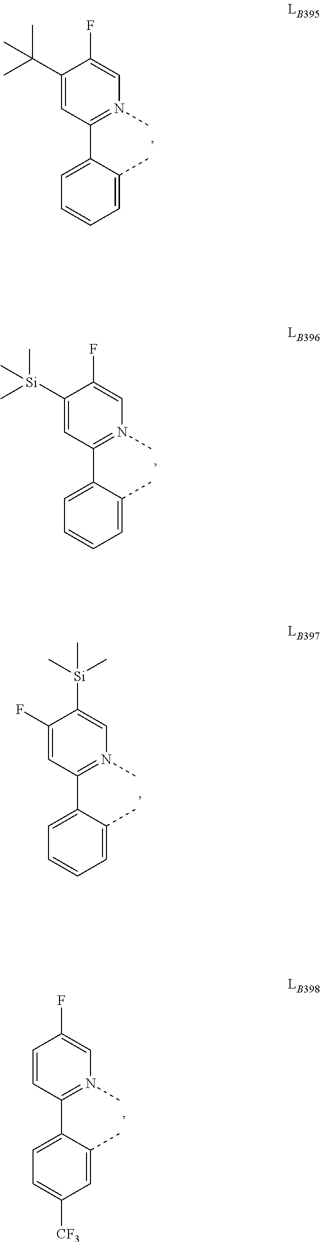 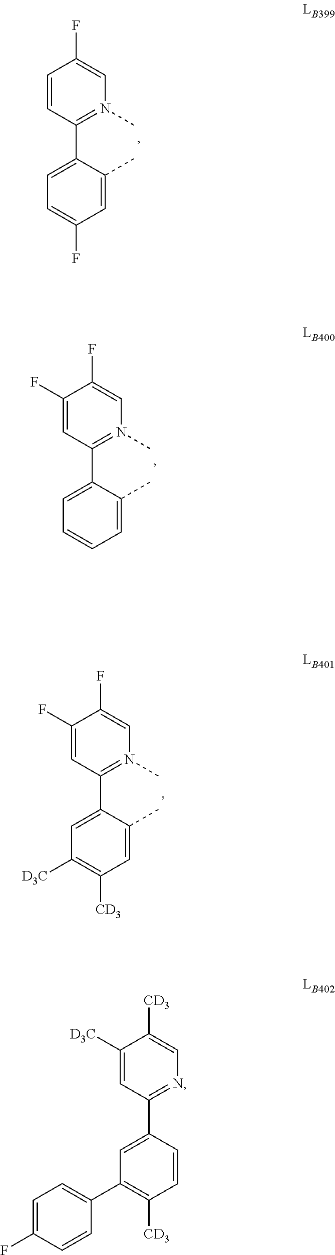 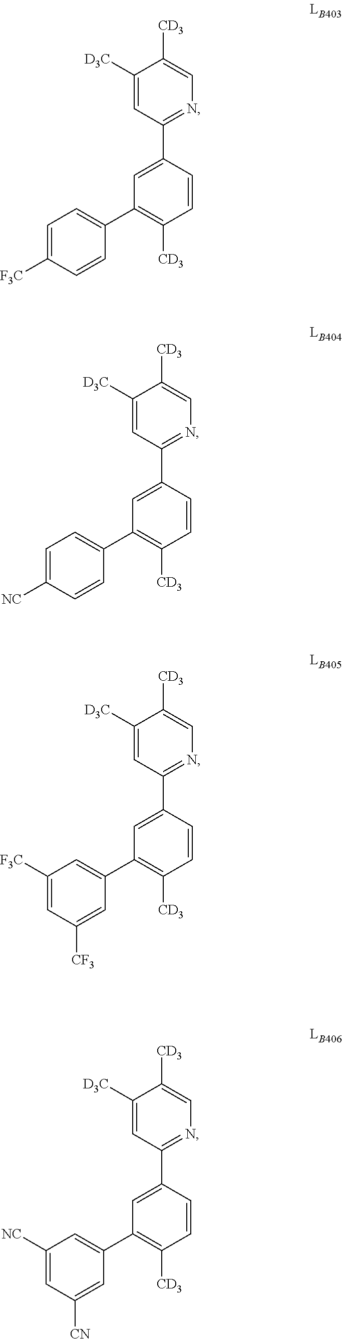 [SMILES: [2H]C([2H])([2H])c1ccc(-c2cc(C([2H])([2H])[2H])c(C([2H])([2H])[2H])cn2)cc1-c1ccc(C(F)(F)F)cc1 ; [2H]C([2H])([2H])c1ccc(-c2cc(C([2H])([2H])[2H])c(C([2H])([2H])[2H])cn2)cc1-c1ccc(C#N)cc1 ; [2H]C([2H])([2H])c1ccc(-c2cc(C([2H])([2H])[2H])c(C([2H])([2H])[2H])cn2)cc1-c1cc(C(F)(F)F)cc(C(F)(F)F)c1 ; [2H]C([2H])([2H])c1ccc(-c2cc(C([2H])([2H])[2H])c(C([2H])([2H])[2H])cn2)cc1-c1cc(C#N)cc(C#N)c1] 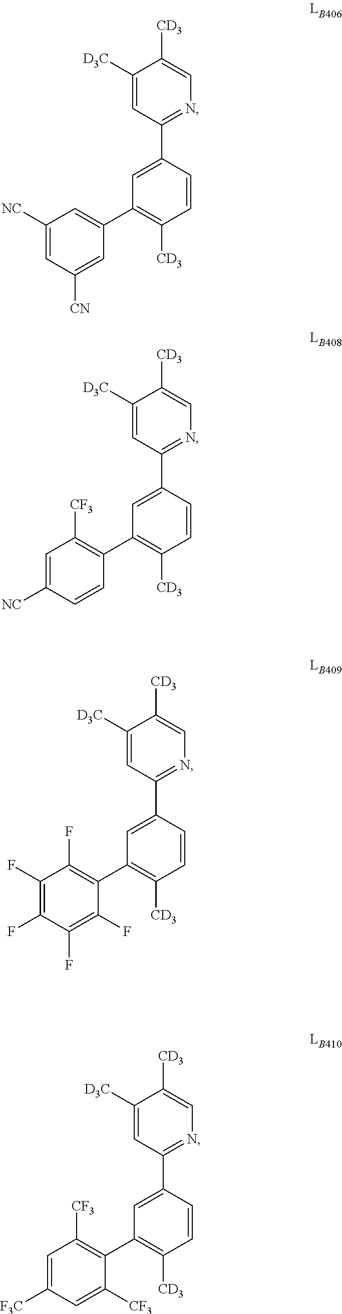 [SMILES: [2H]C([2H])([2H])c1ccc(-c2cc(C([2H])([2H])[2H])c(C([2H])([2H])[2H])cn2)cc1-c1cc(C#N)cc(C#N)c1 ; [2H]C([2H])([2H])c1ccc(-c2cc(C([2H])([2H])[2H])c(C([2H])([2H])[2H])cn2)cc1-c1ccc(C#N)cc1C(F)(F)F ; [2H]C([2H])([2H])c1ccc(-c2cc(C([2H])([2H])[2H])c(C([2H])([2H])[2H])cn2)cc1-c1c(F)c(F)c(F)c(F)c1F ; [2H]C([2H])([2H])c1ccc(-c2cc(C([2H])([2H])[2H])c(C([2H])([2H])[2H])cn2)cc1-c1c(C(F)(F)F)cc(C(F)(F)F)cc1C(F)(F)F] 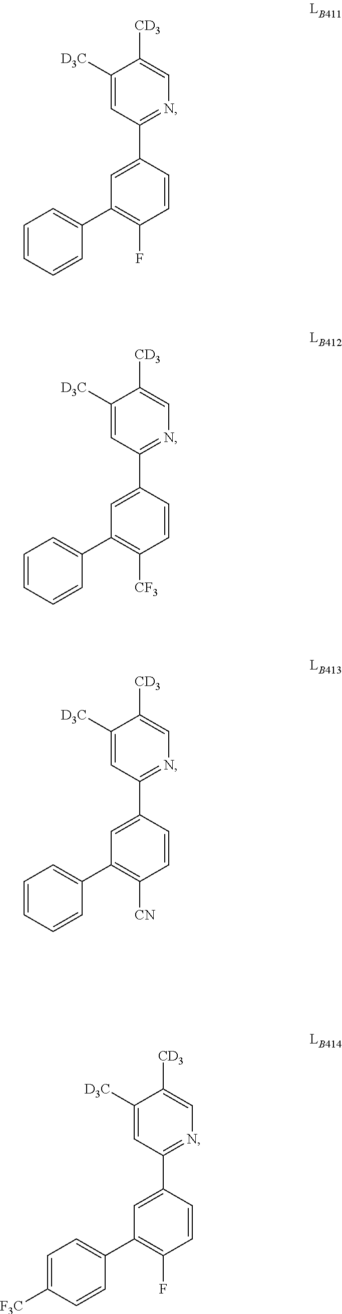 [SMILES: [2H]C([2H])([2H])c1cnc(-c2ccc(F)c(-c3ccccc3)c2)cc1C([2H])([2H])[2H] ; [2H]C([2H])([2H])c1cnc(-c2ccc(C(F)(F)F)c(-c3ccccc3)c2)cc1C([2H])([2H])[2H] ; [2H]C([2H])([2H])c1cnc(-c2ccc(C#N)c(-c3ccccc3)c2)cc1C([2H])([2H])[2H] ; [2H]C([2H])([2H])c1cnc(-c2ccc(F)c(-c3ccc(C(F)(F)F)cc3)c2)cc1C([2H])([2H])[2H]] 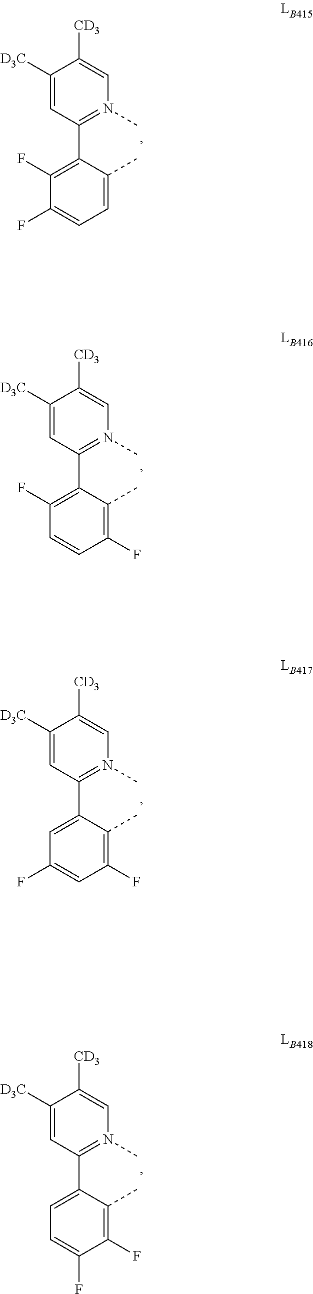 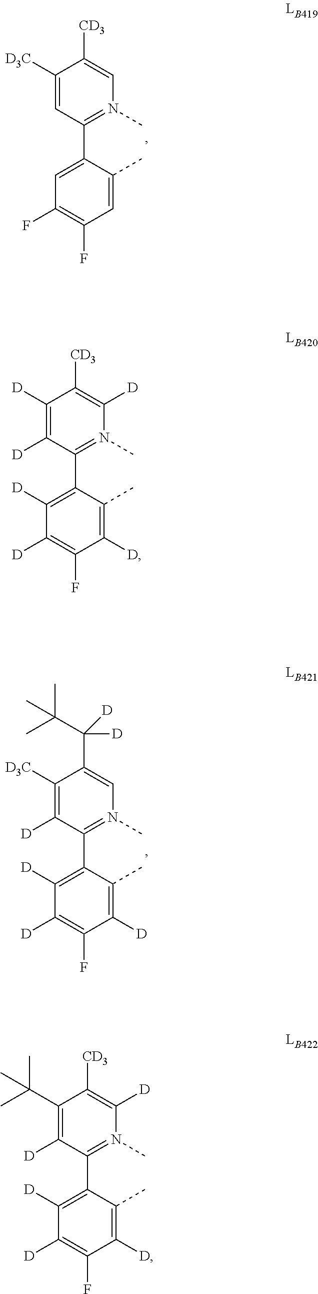 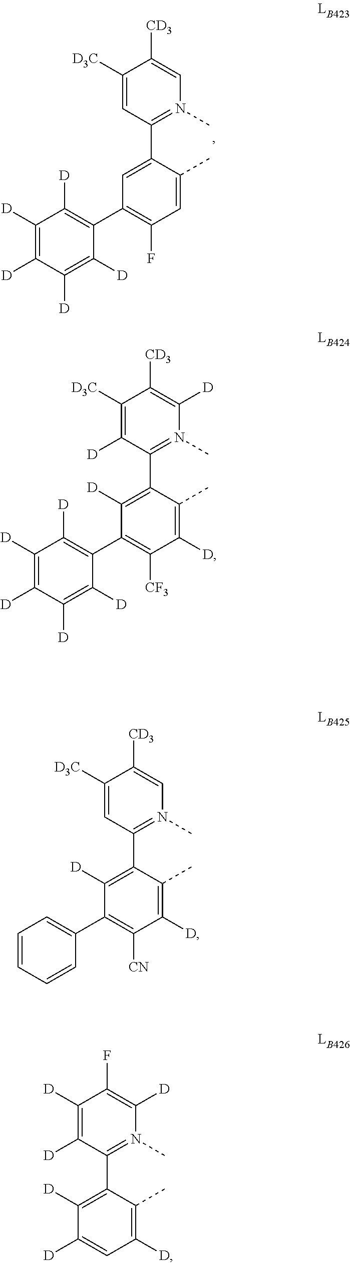 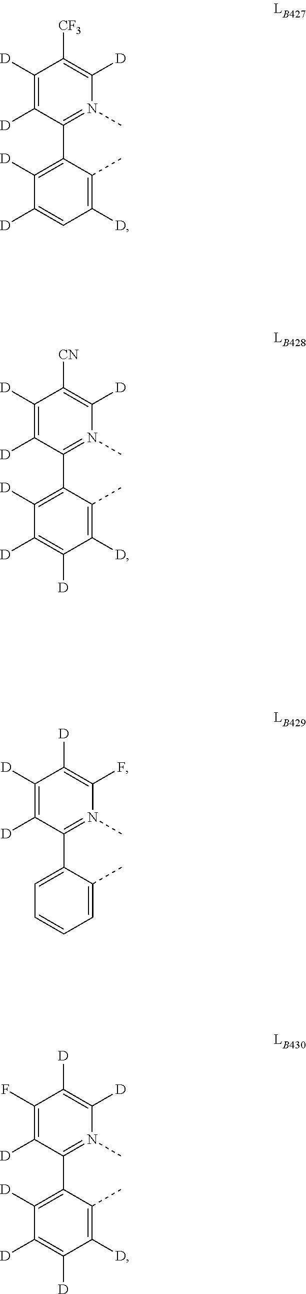 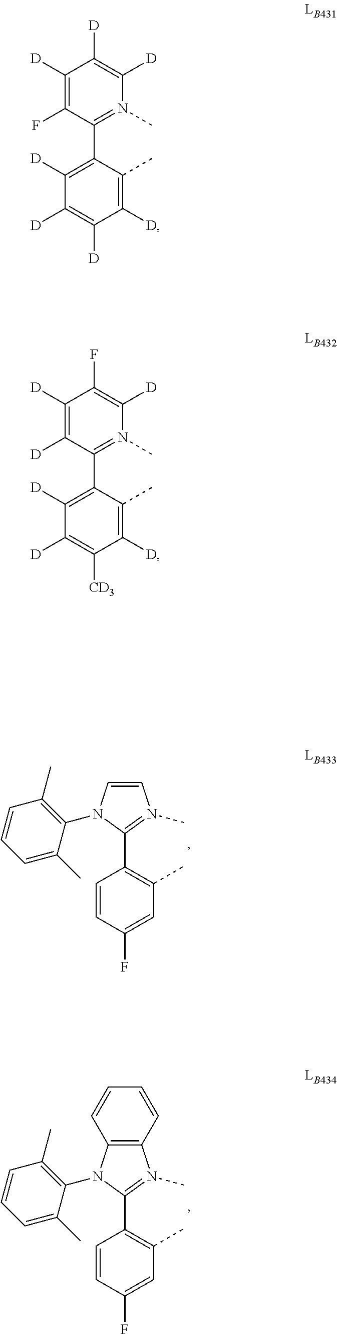 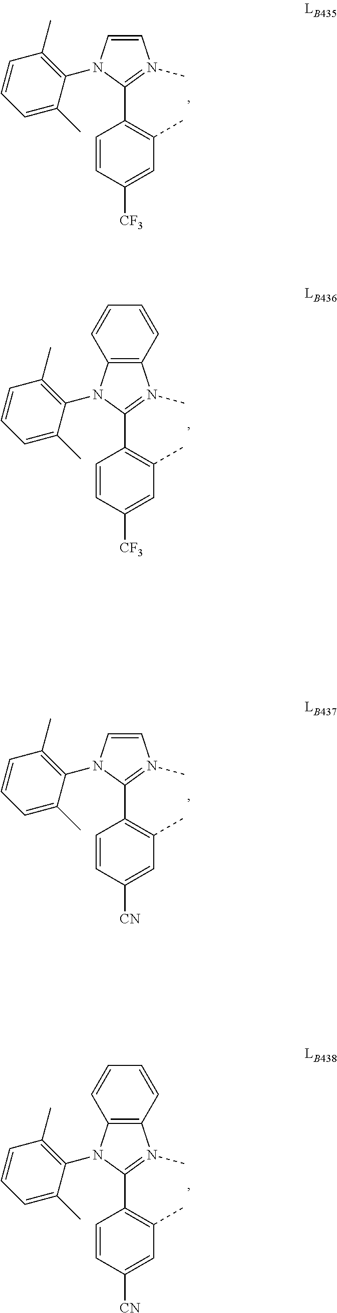 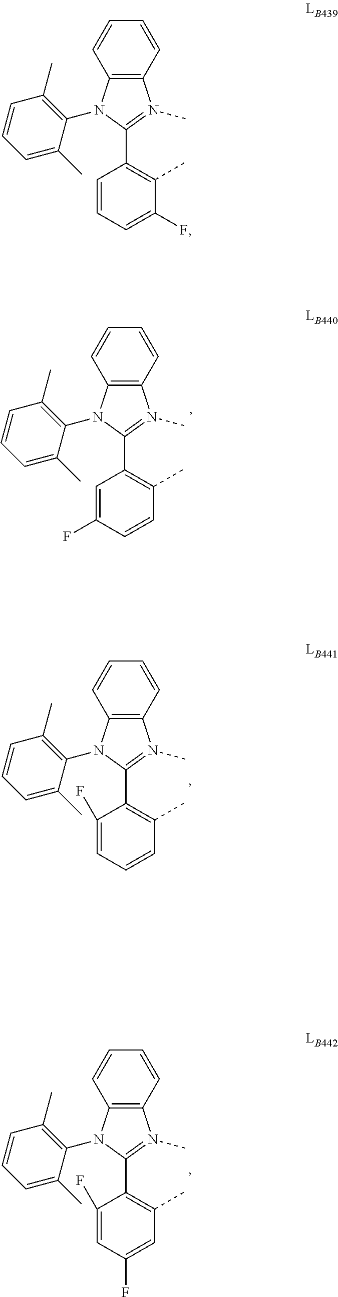 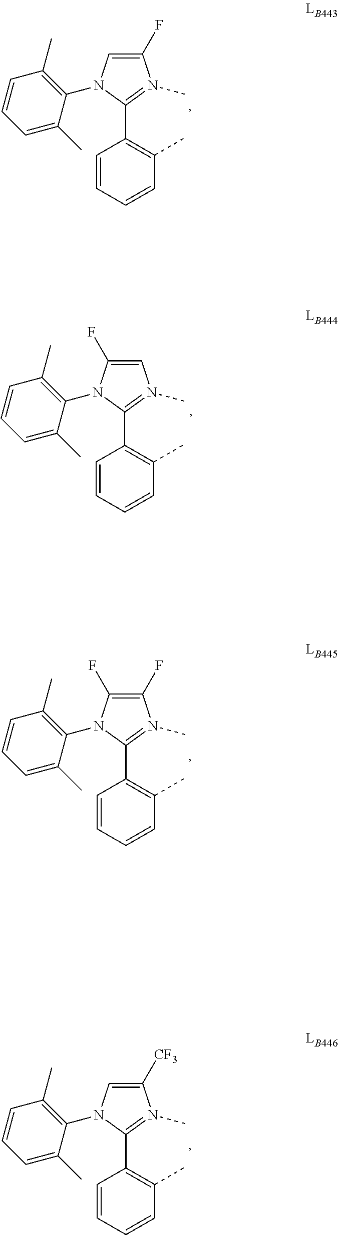 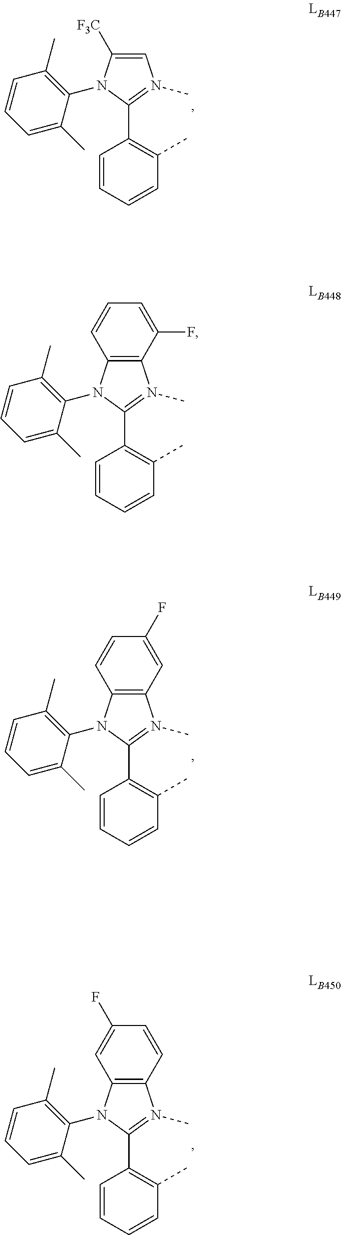 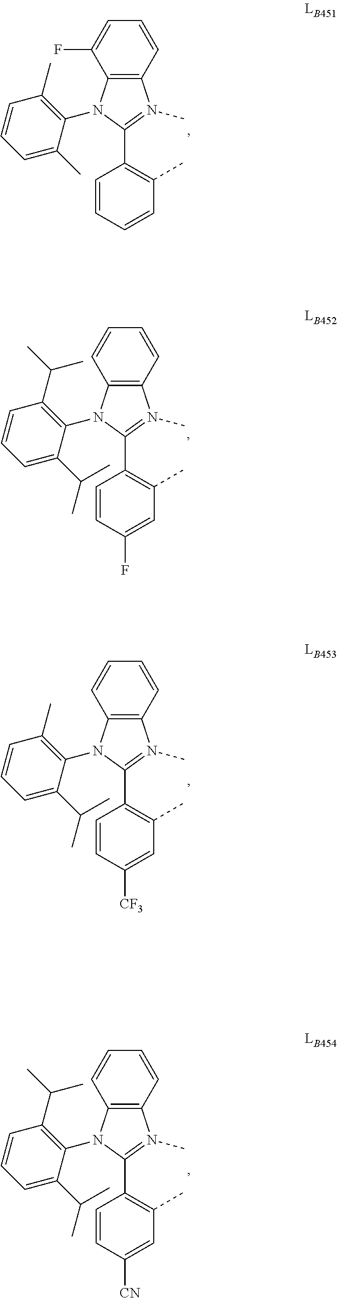 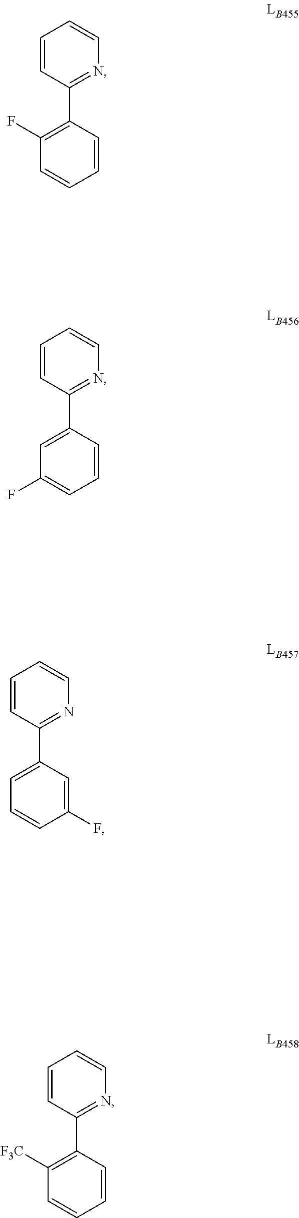 [SMILES: Fc1ccccc1-c1ccccn1 ; Fc1cccc(-c2ccccn2)c1 ; Fc1cccc(-c2ccccn2)c1 ; FC(F)(F)c1ccccc1-c1ccccn1] 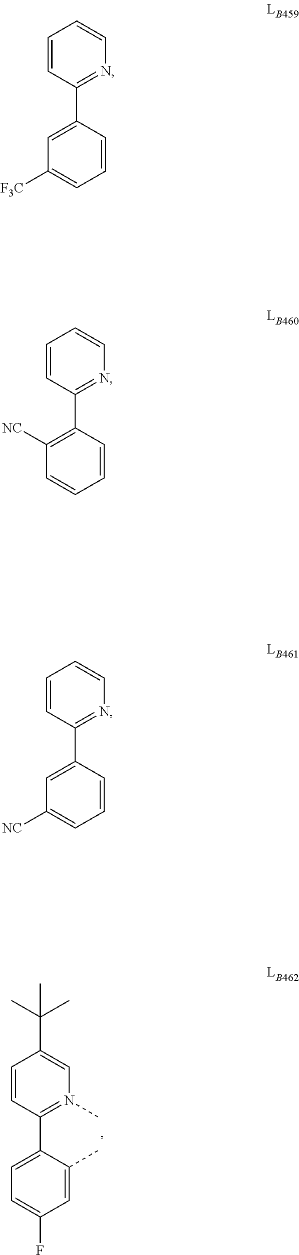 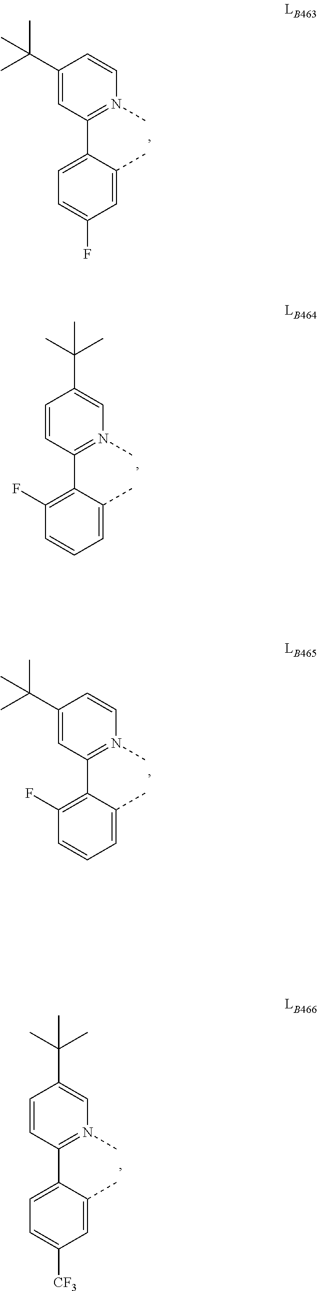 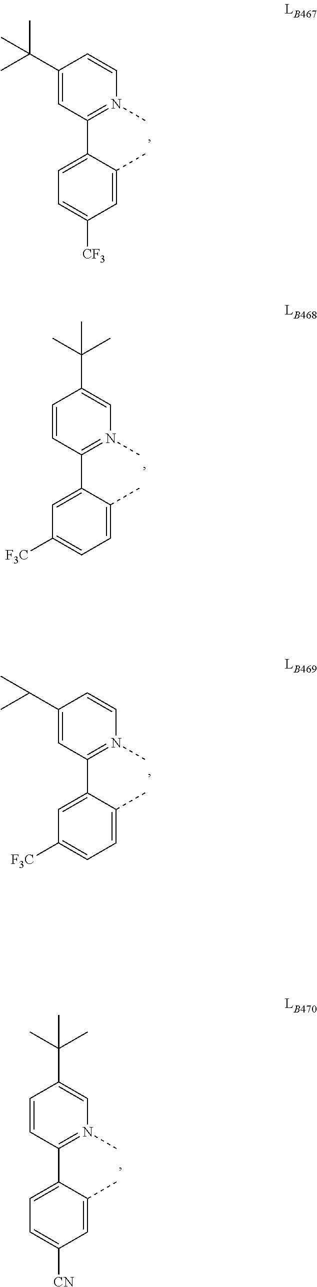 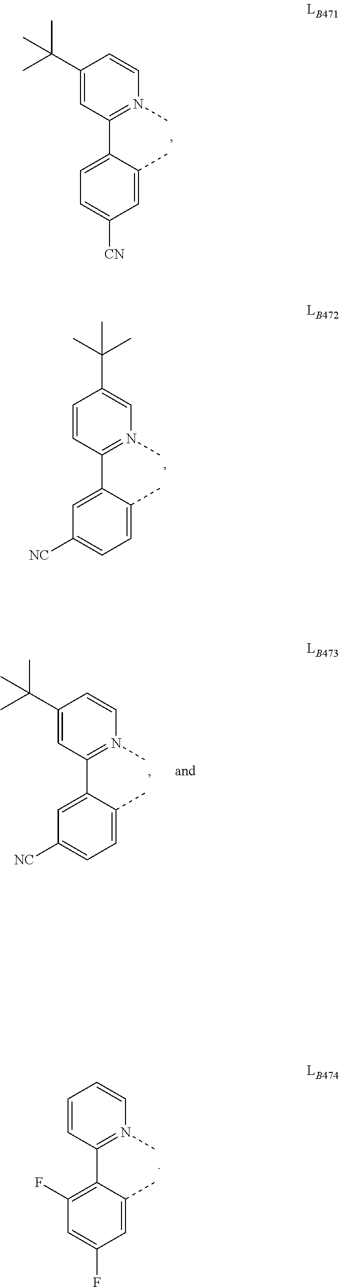
wherein each L_{Cj-I} has a structure based on formula 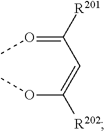
and
each L_{Cj-II} has a structure based on formula 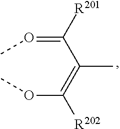
wherein for each L_{Cj} in L_{Cj-I} and L_{Cj-II}, R²⁰¹ and R²⁰² are defined as follows:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D55} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D95} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

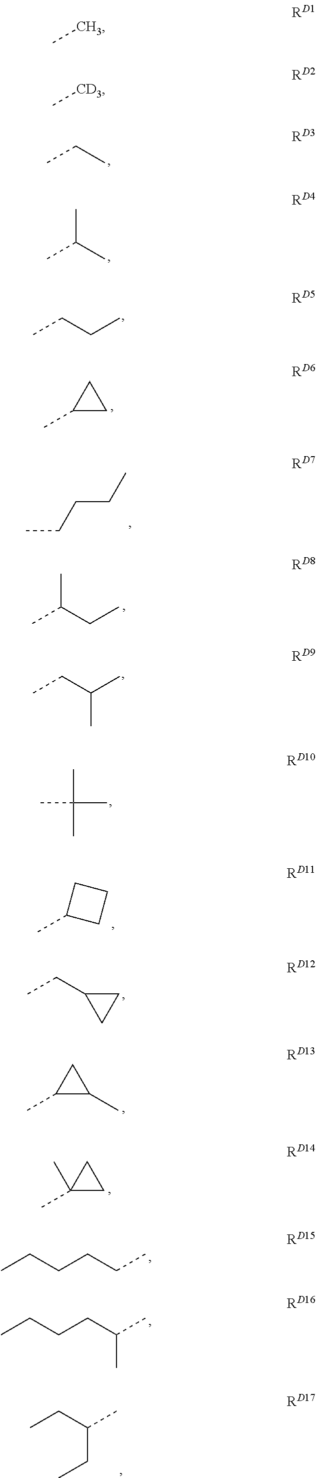

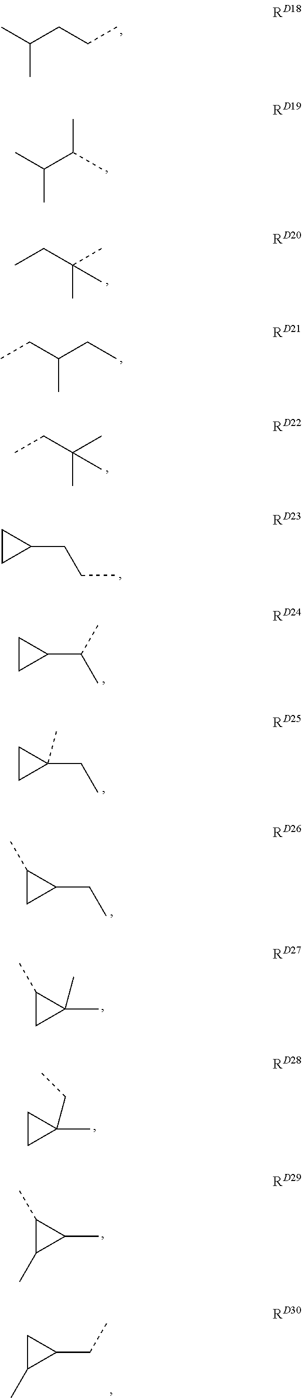

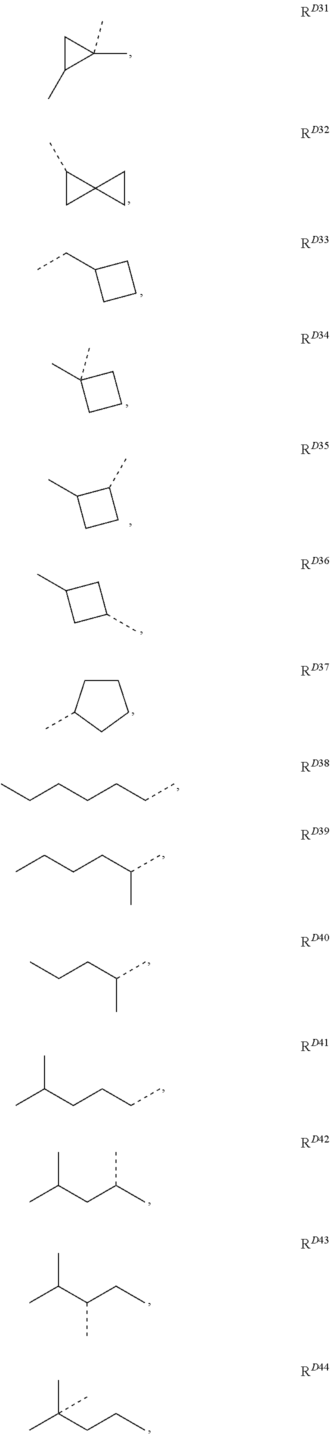

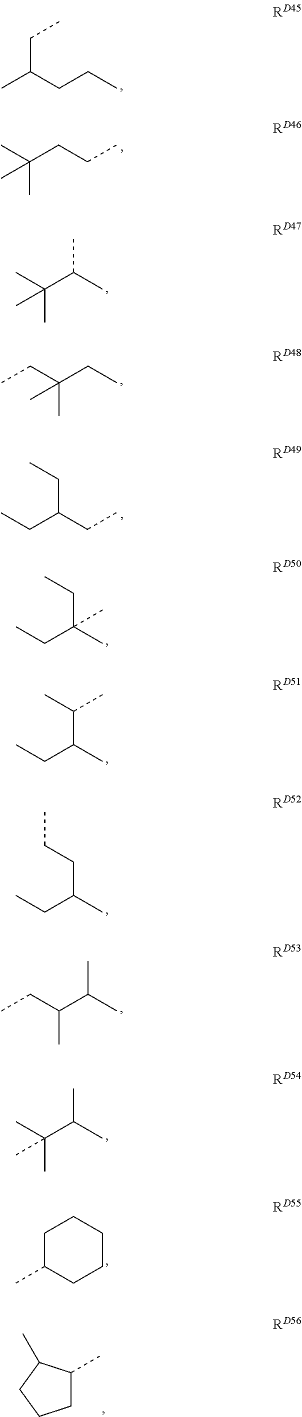

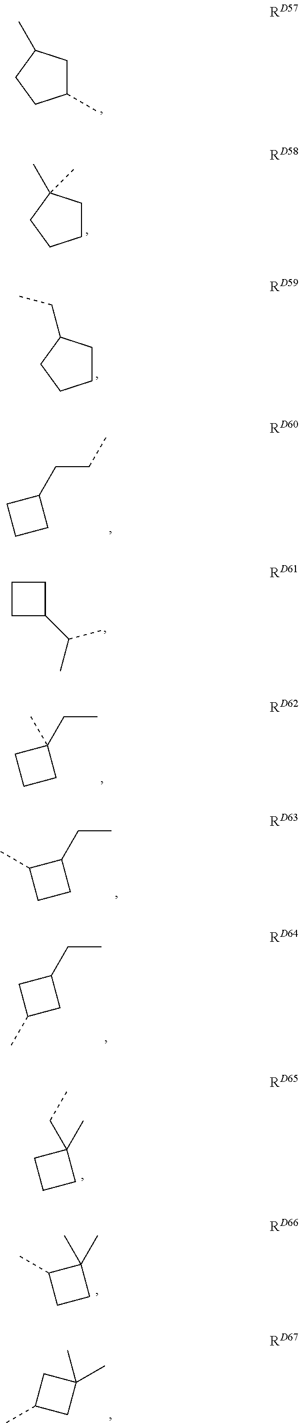

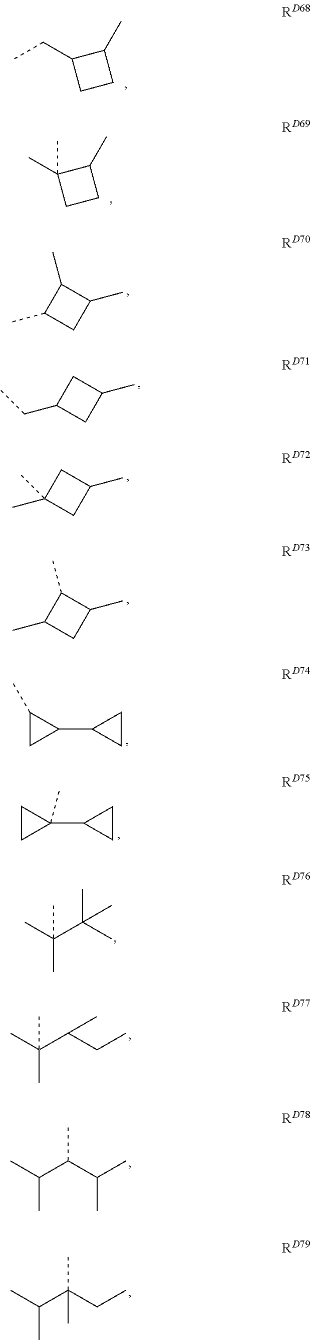

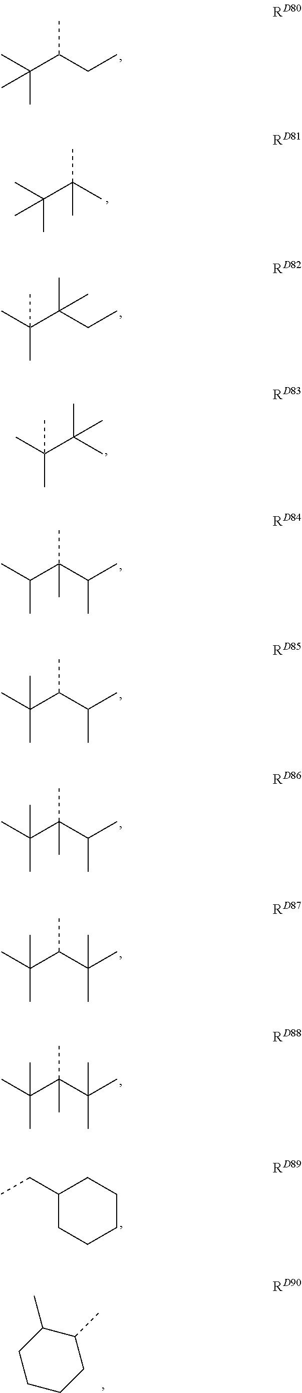

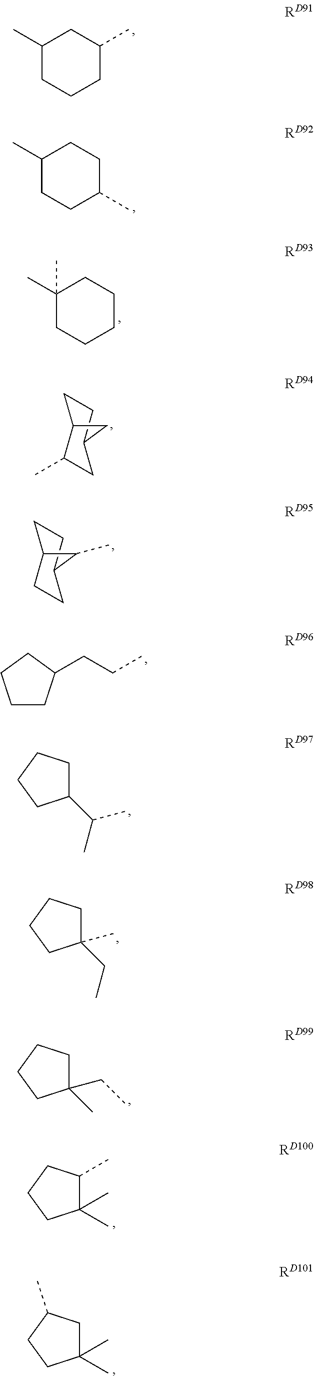

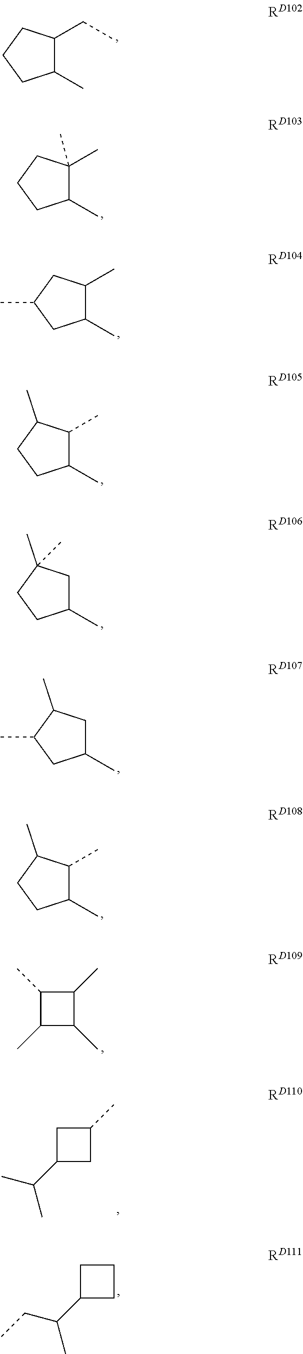

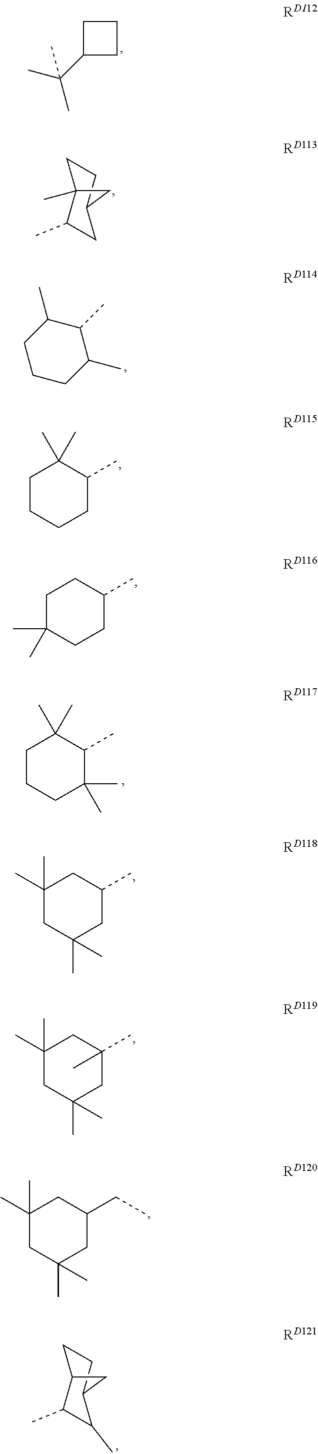

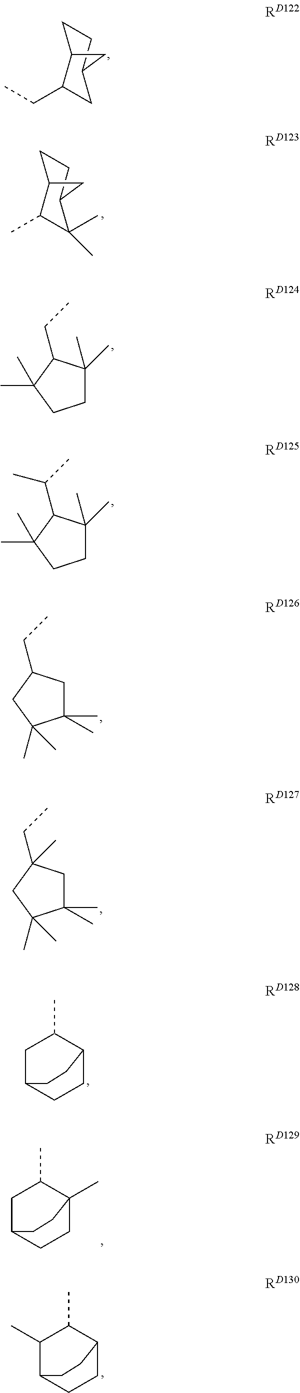

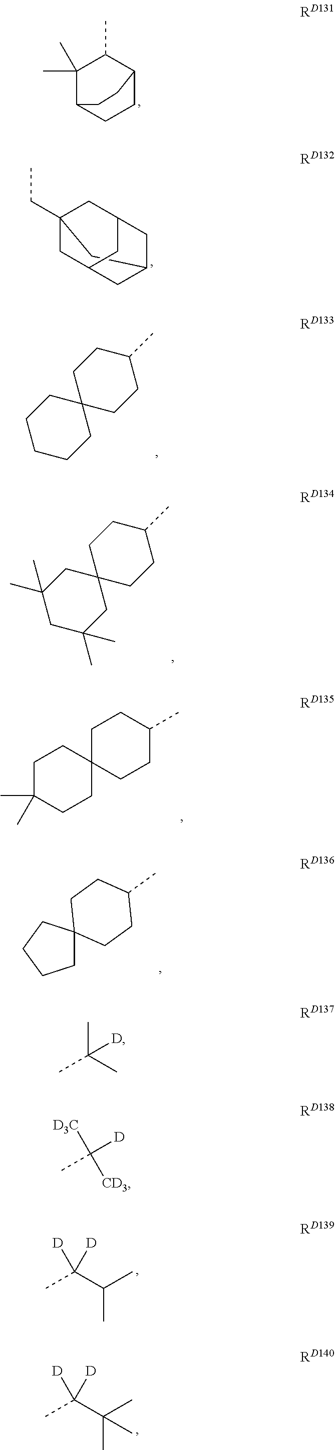

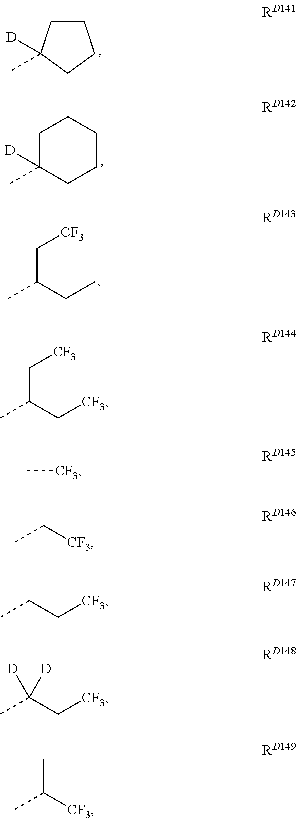

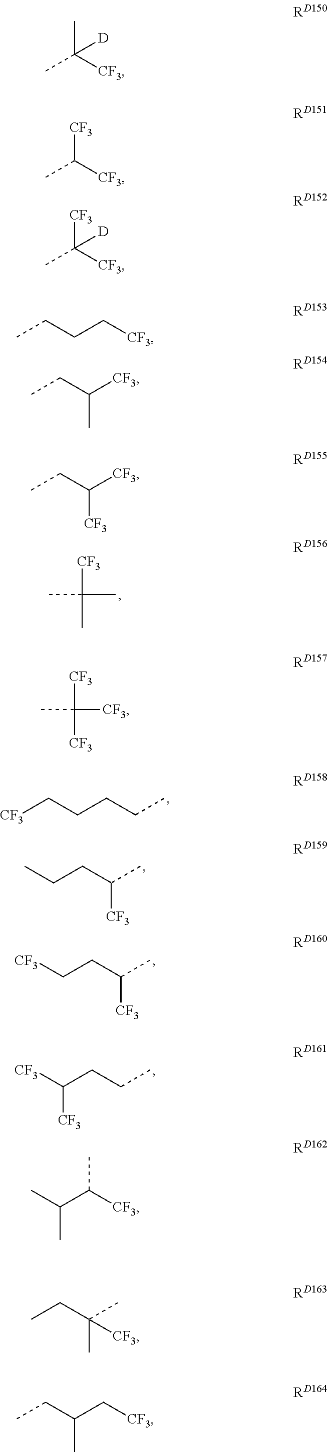

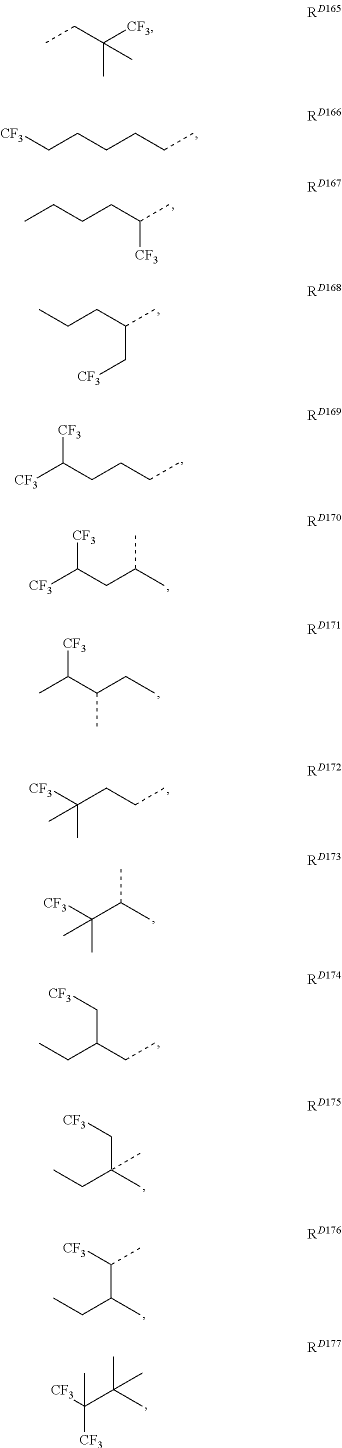

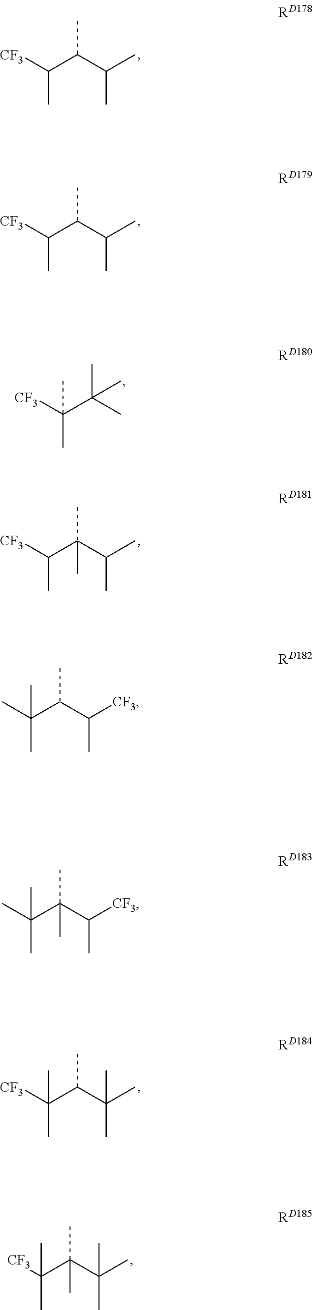

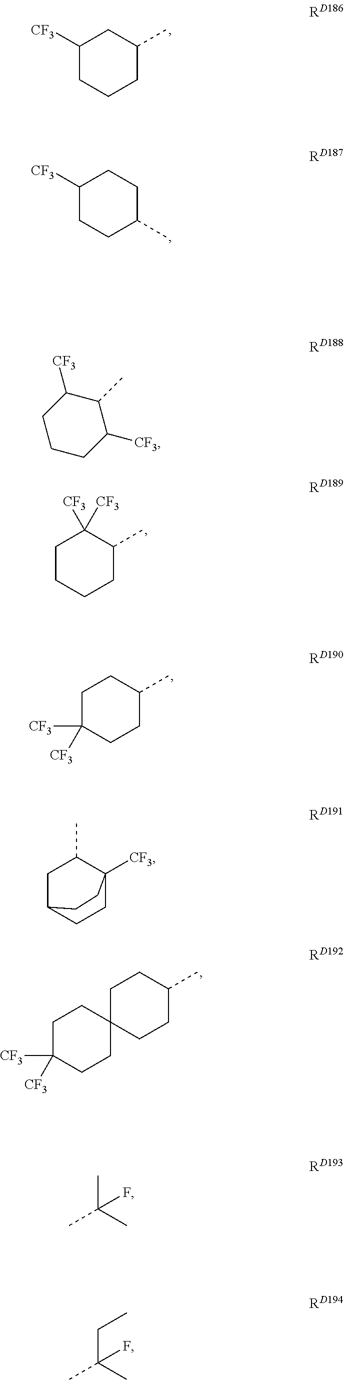

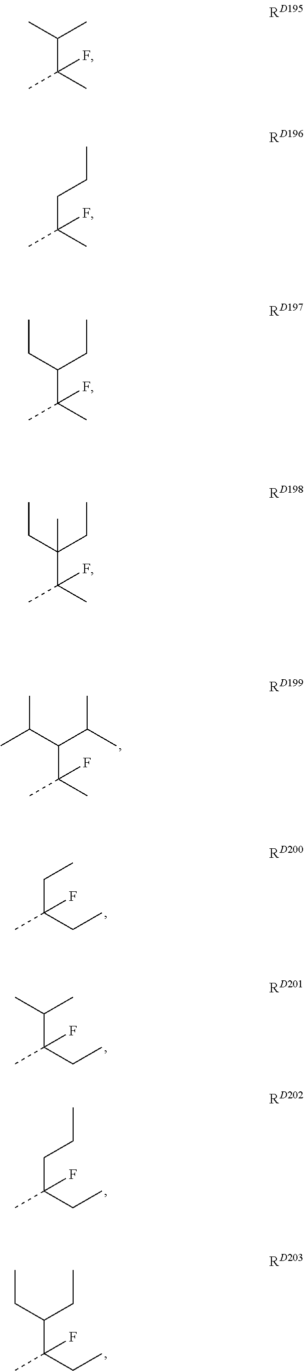

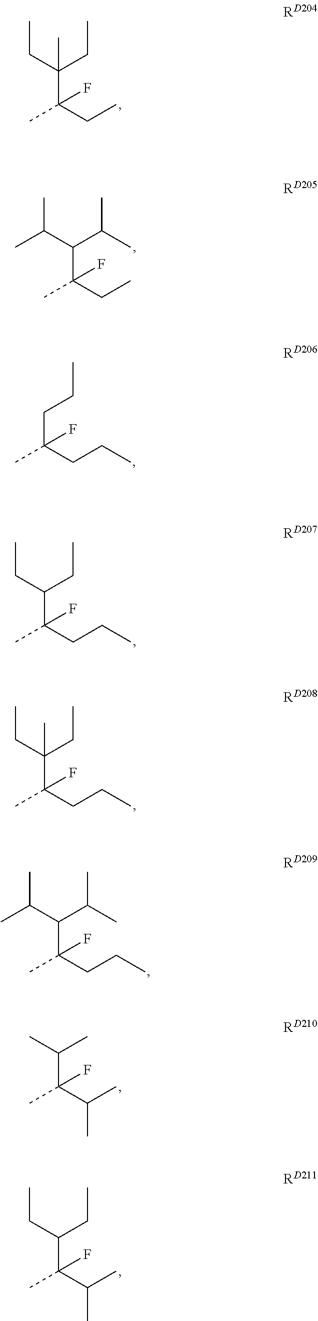

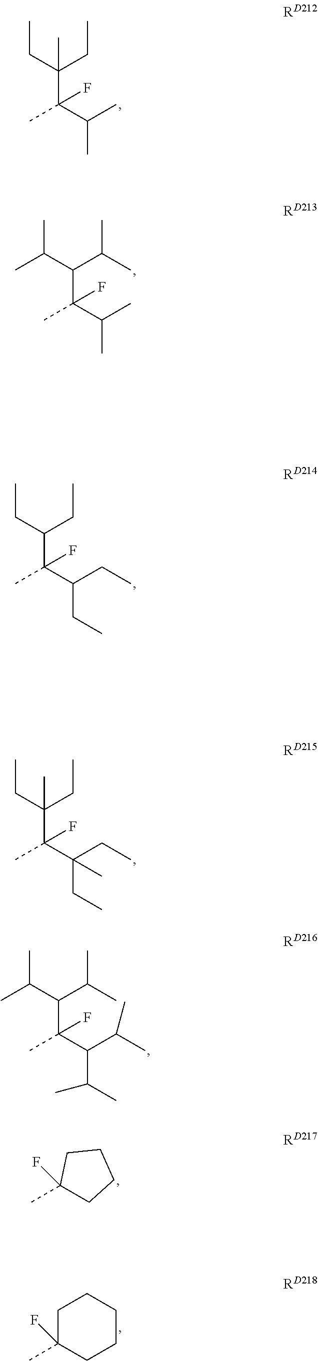

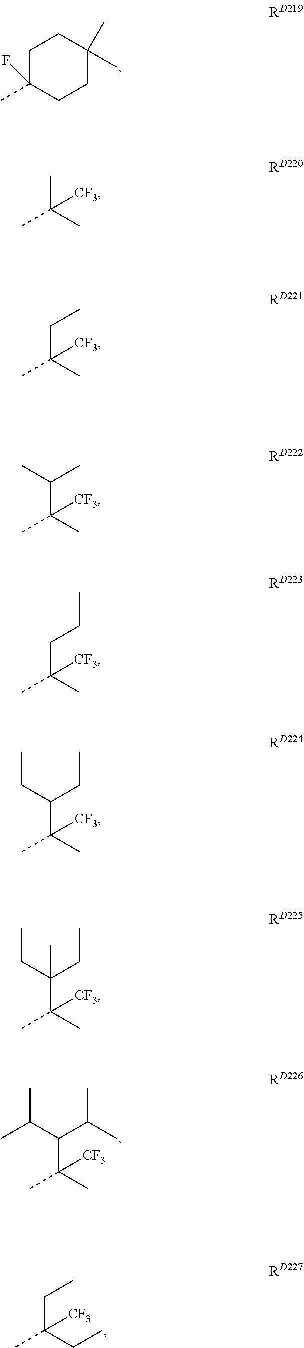

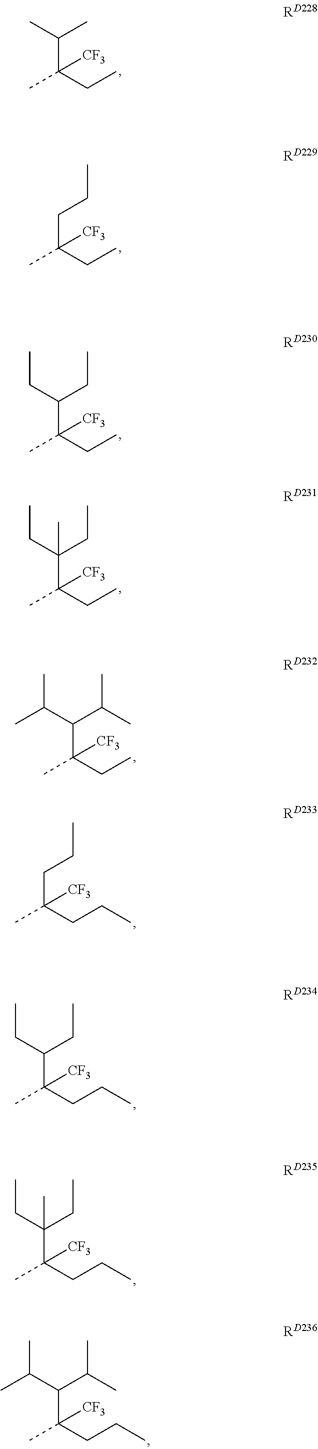

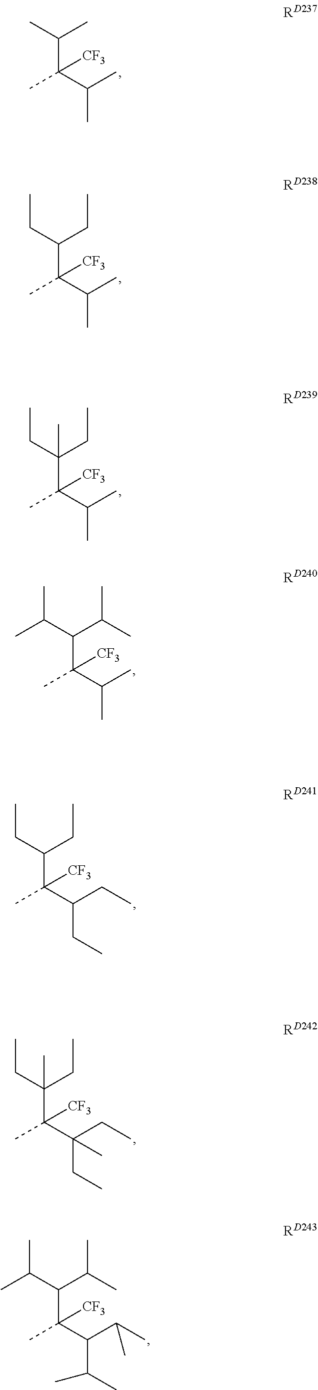

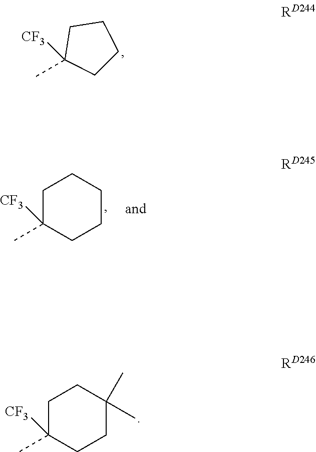

14. The compound of claim 1, wherein the compound comprising a first ligand L_{A} of Formula I is selected from the group consisting of 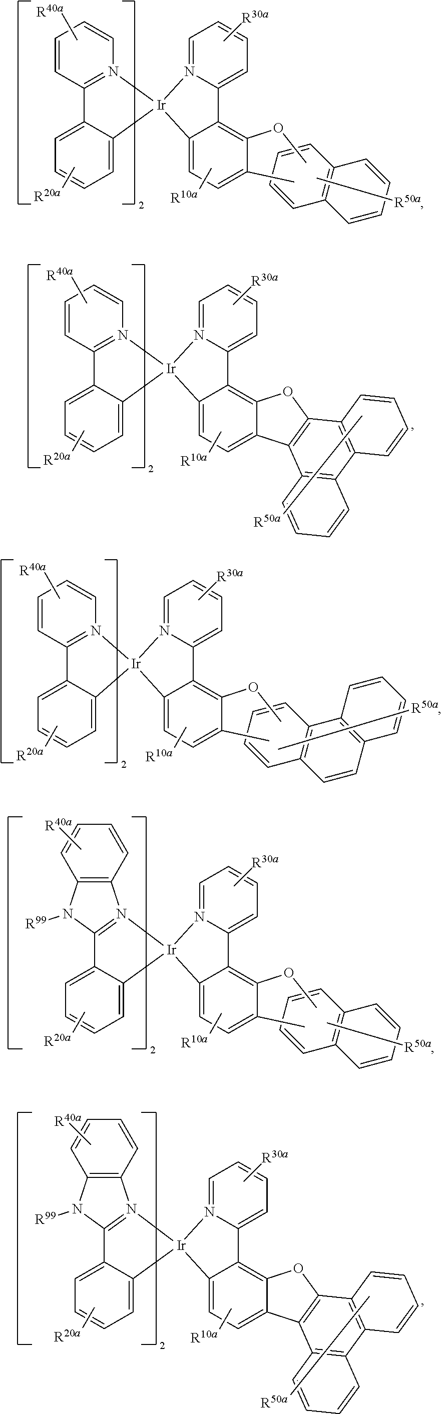 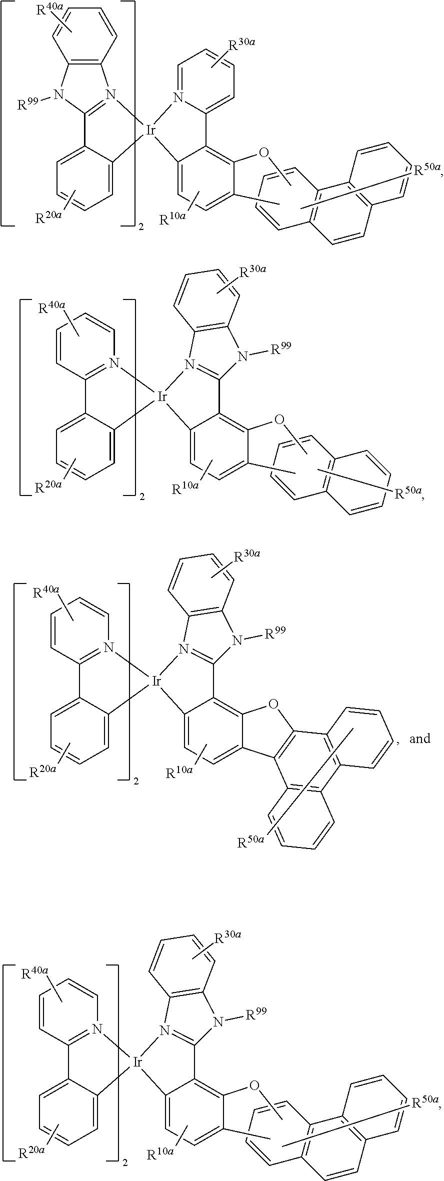
wherein
each of R^{10a}, R^{20a}, R^{30a}, R^{40a}, and R^{50a} independently represents mono substitution, up to the maximum substitutions, or no substitution;
each of R^{10a}, R^{20a}, R^{30a}, R^{40a}, R^{50a}, and R⁹⁹ is independently a hydrogen or a substituent selected from the group consisting of deuterium, halide, alkyl, cycloalkyl, heteroalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof; and
at least one R^{10a} or R^{50a} comprises a cyclic group or an electron-withdrawing group; and
two adjacent R^{10a}, R^{20a}, R^{30a}, R^{40a}, R^{50a}, and R⁹⁹ are optionally joined or fused to form a ring.

15. The compound of claim 1, wherein the compound is selected from the group consisting of:

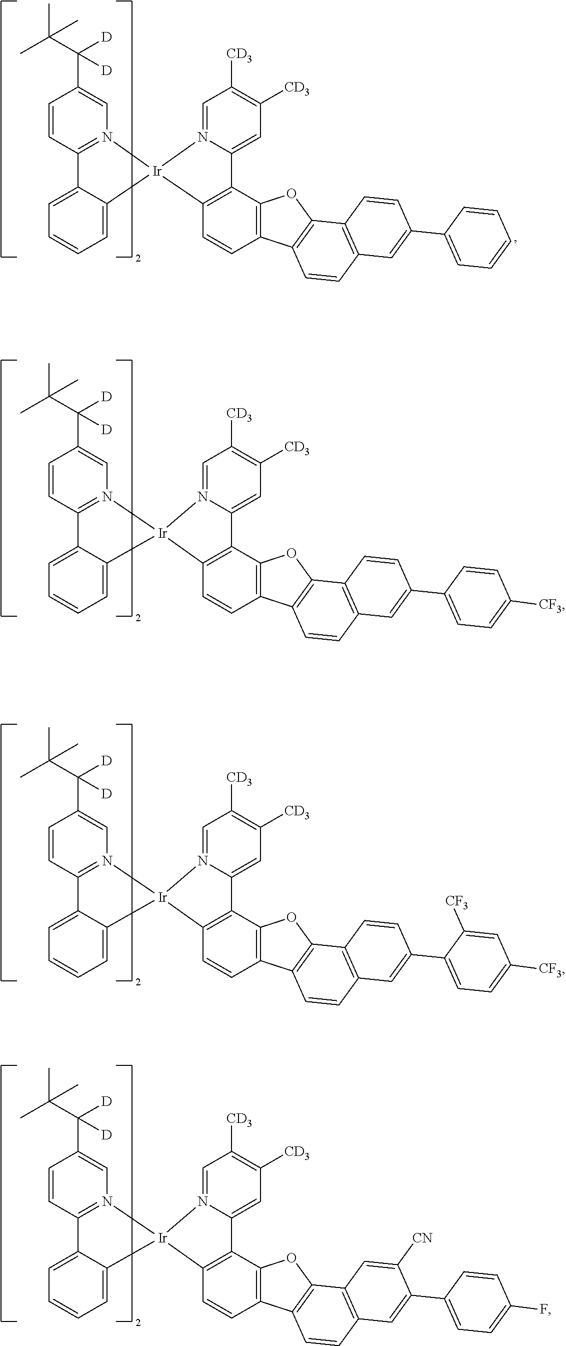

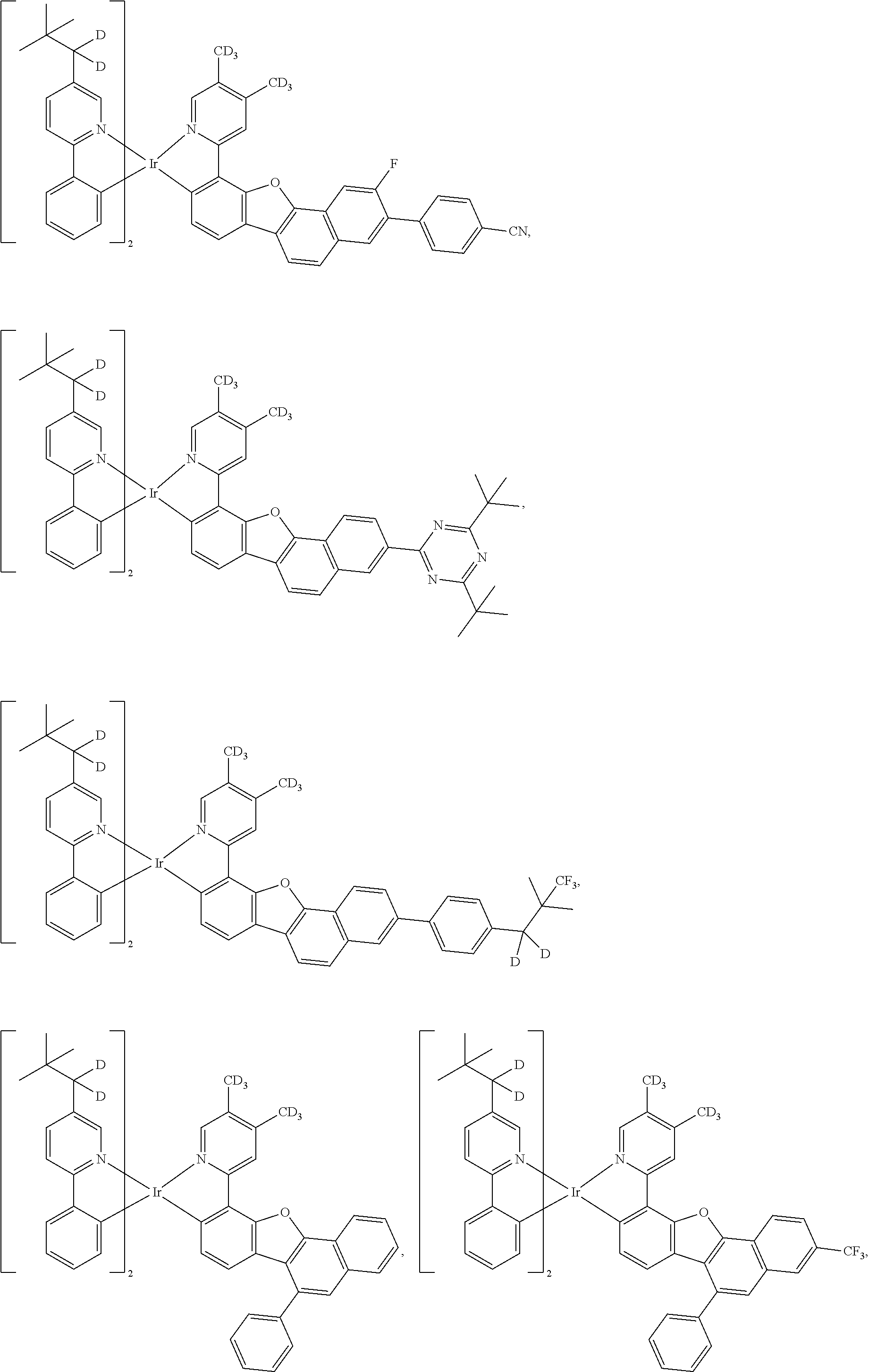

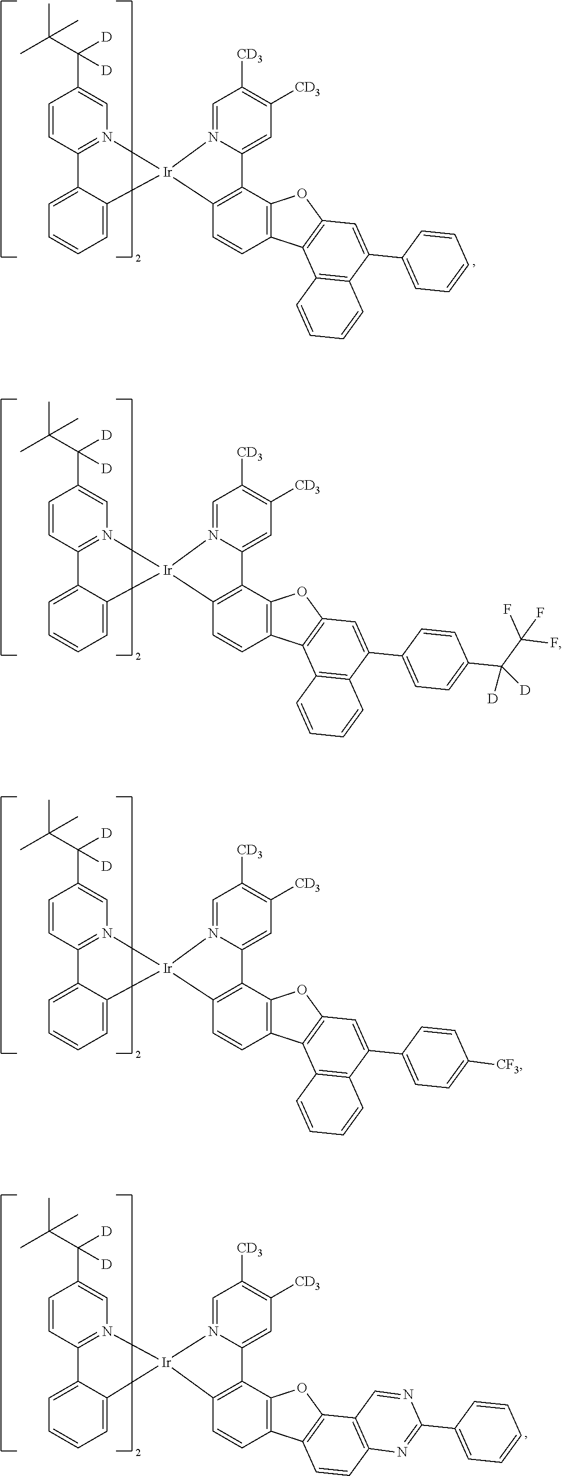

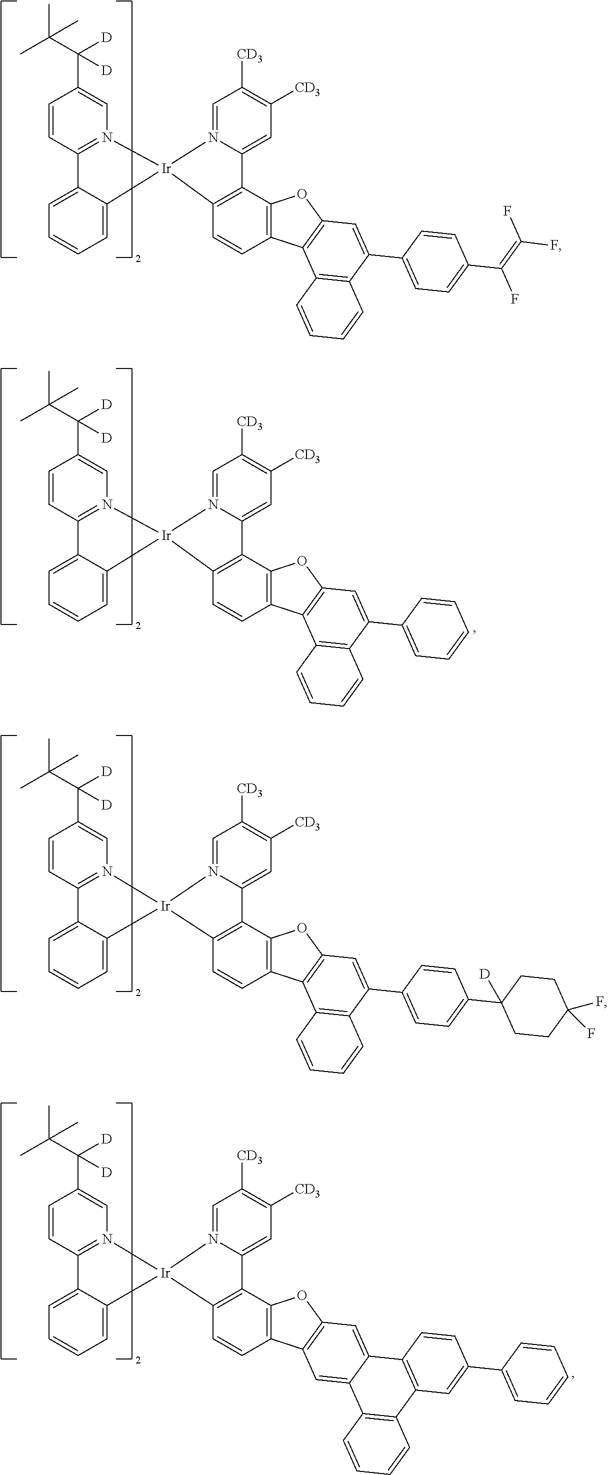

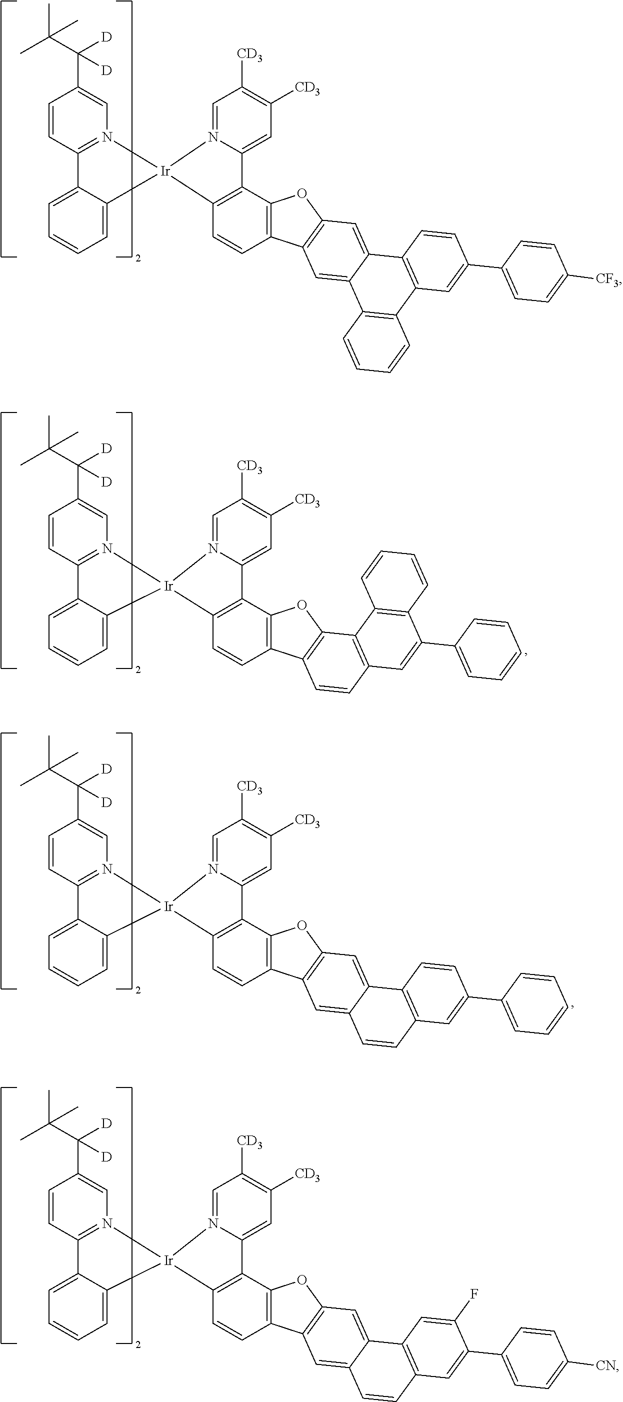

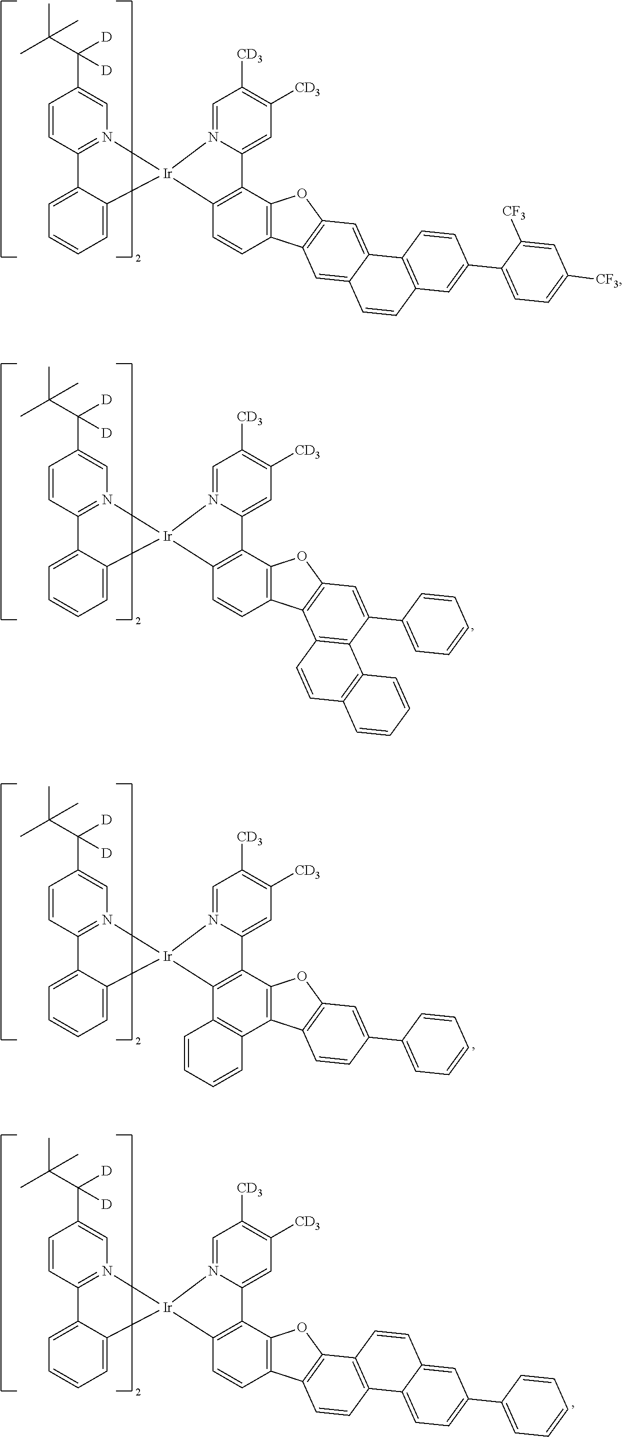

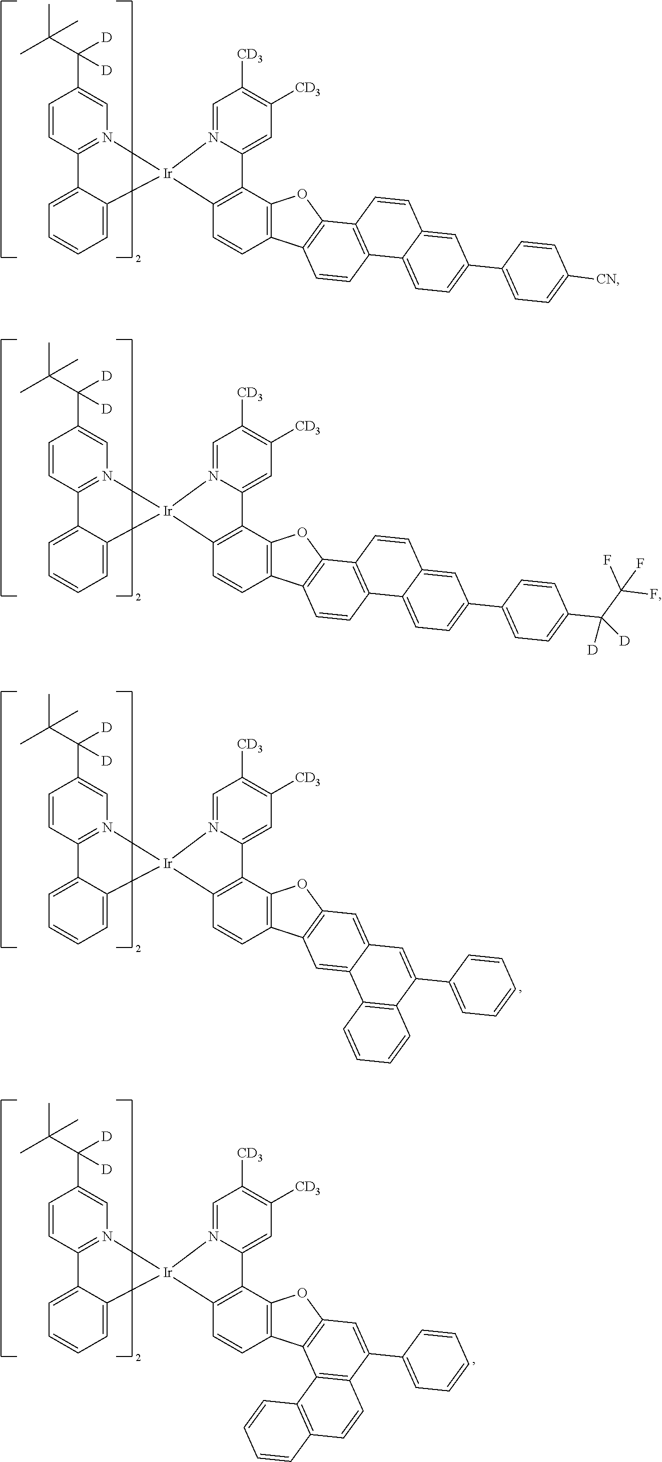

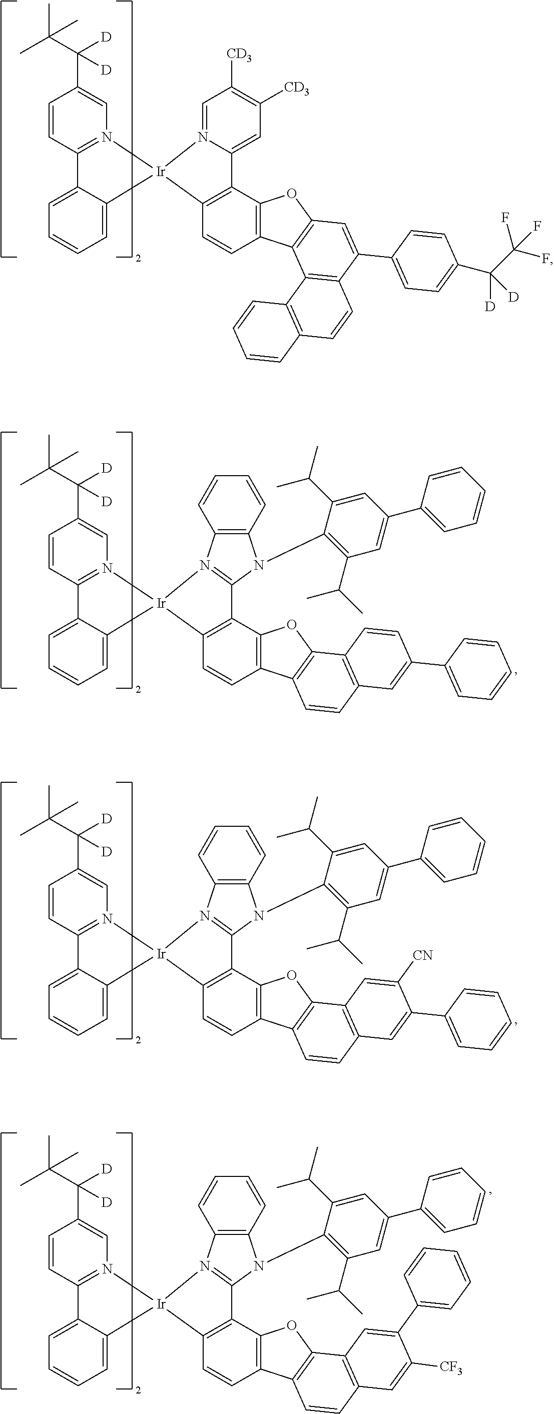

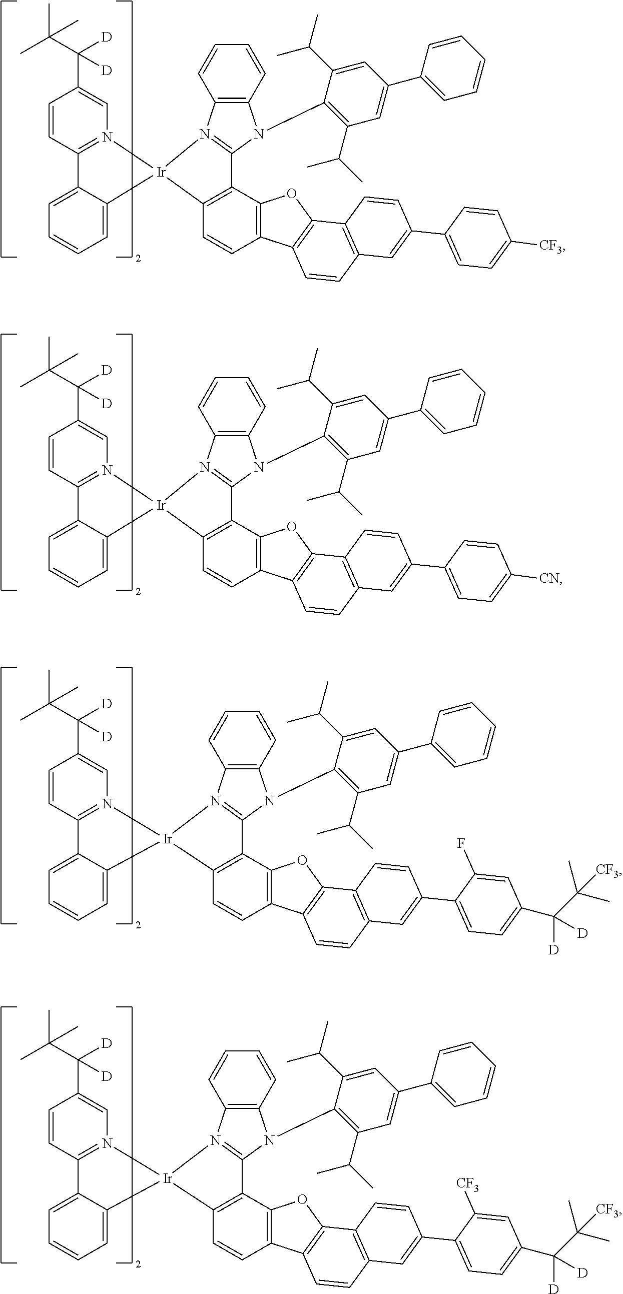

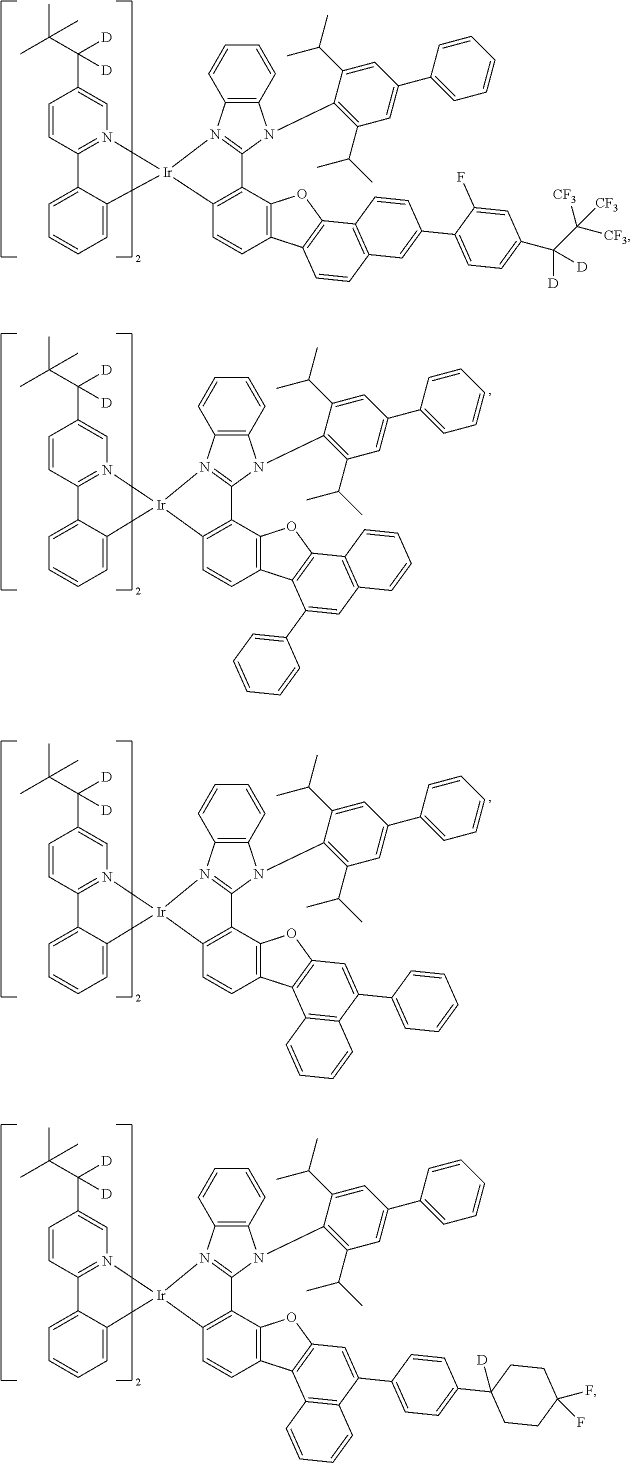

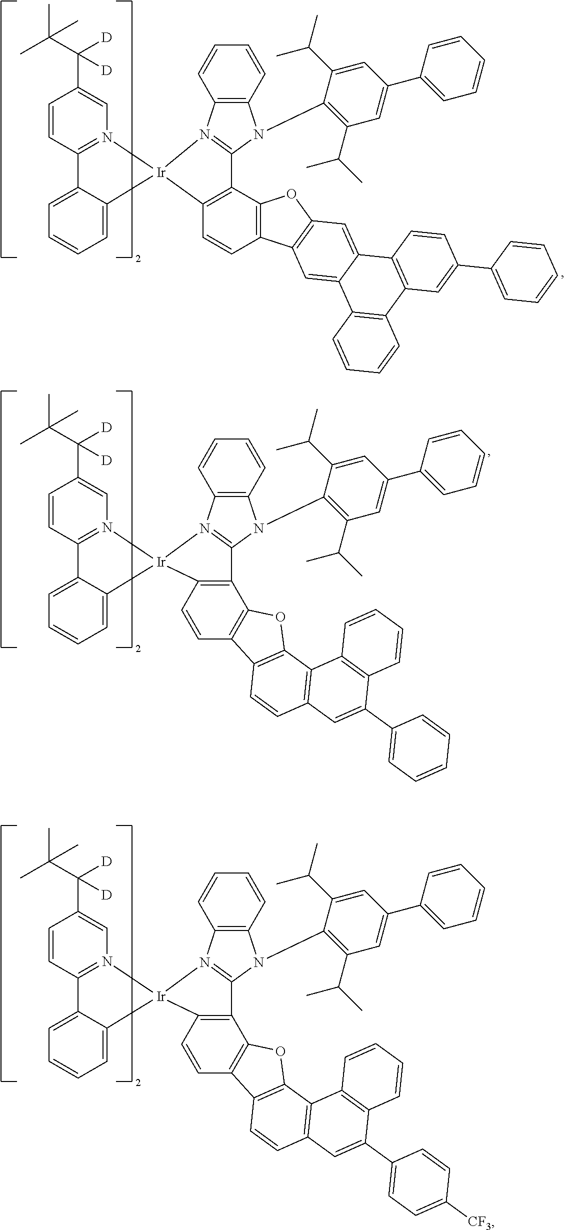

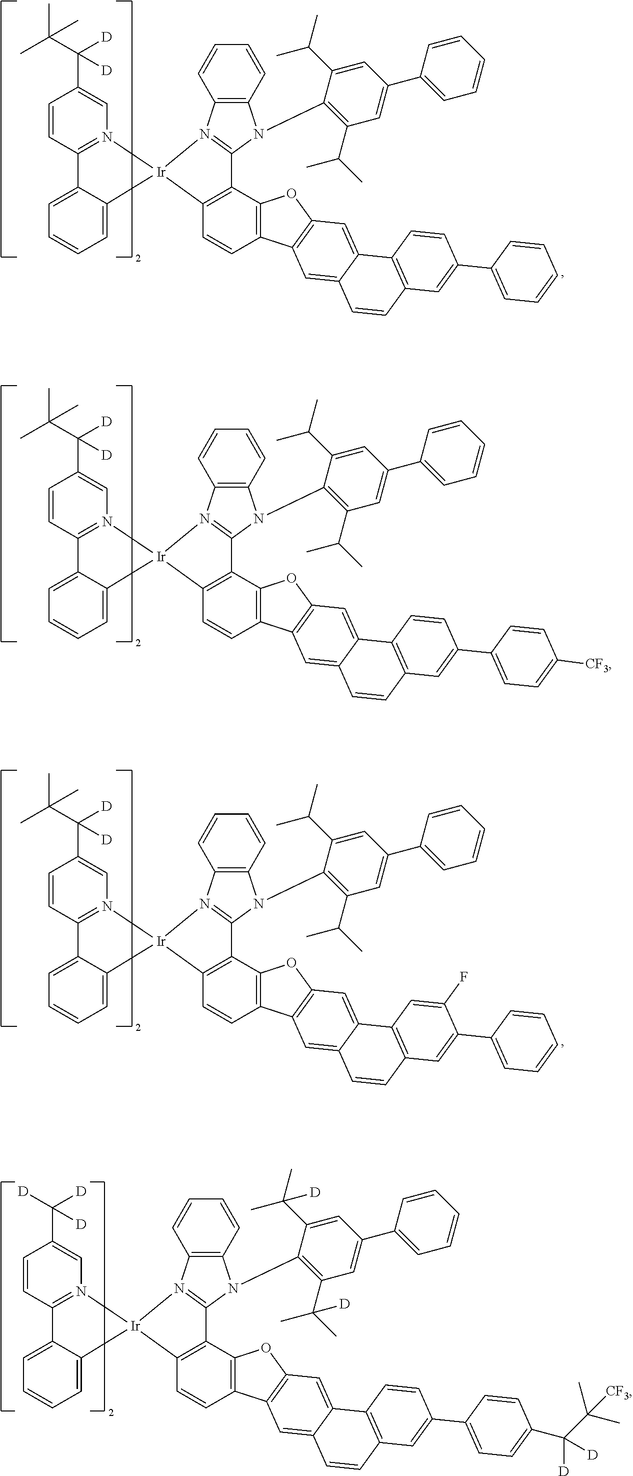

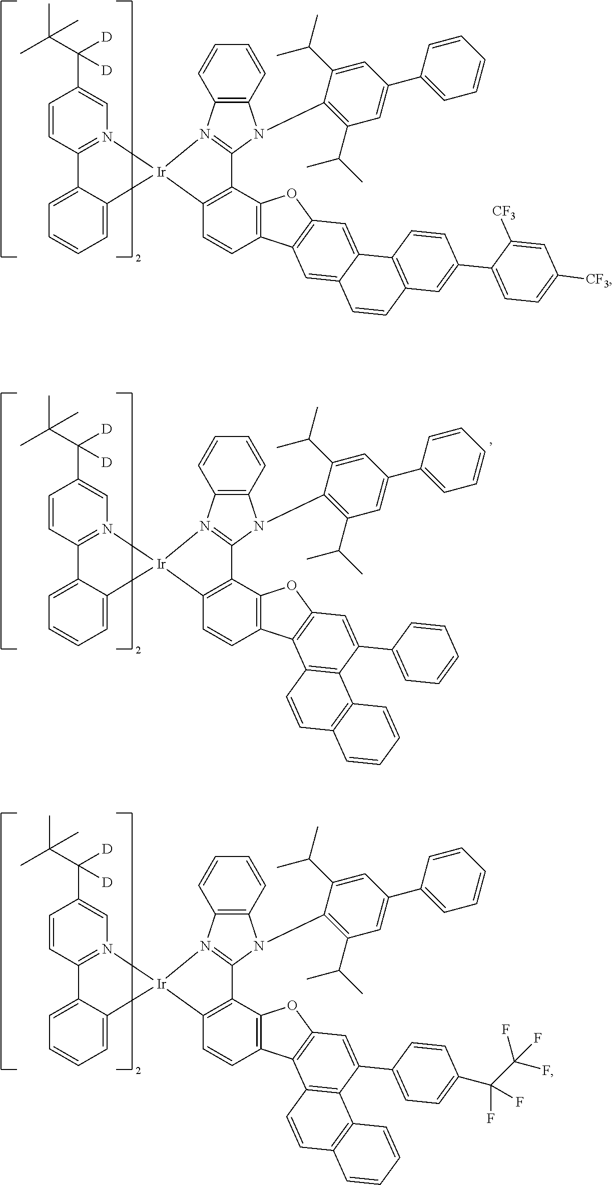

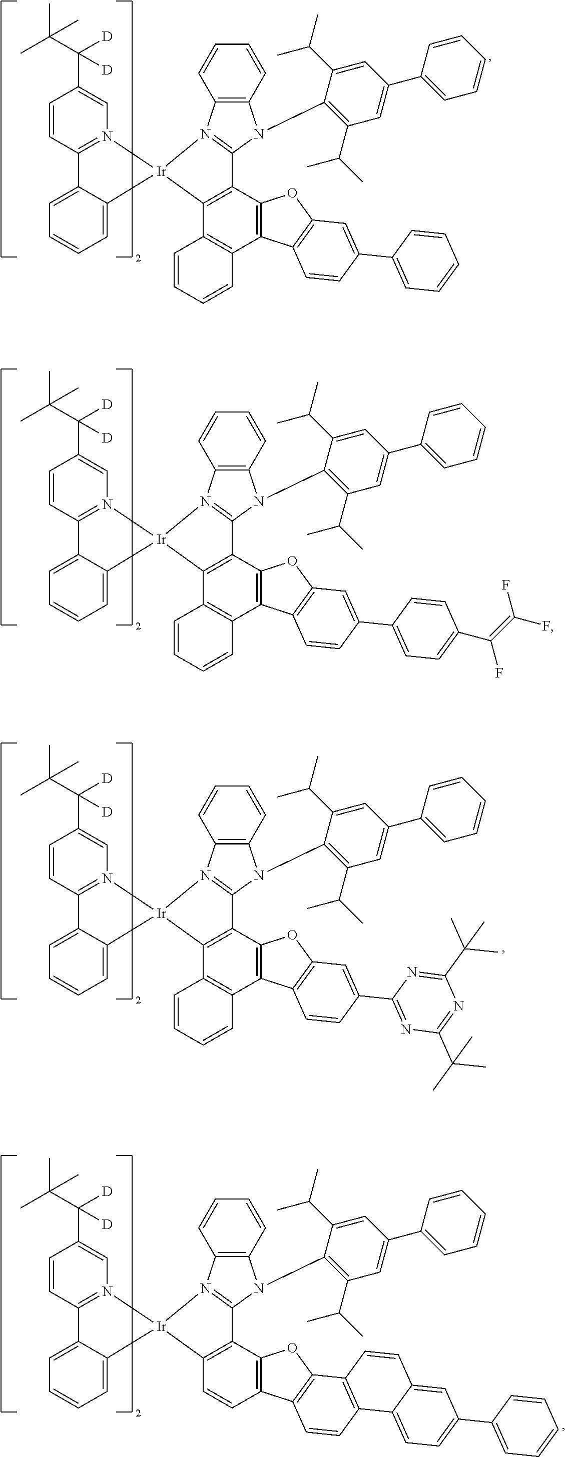

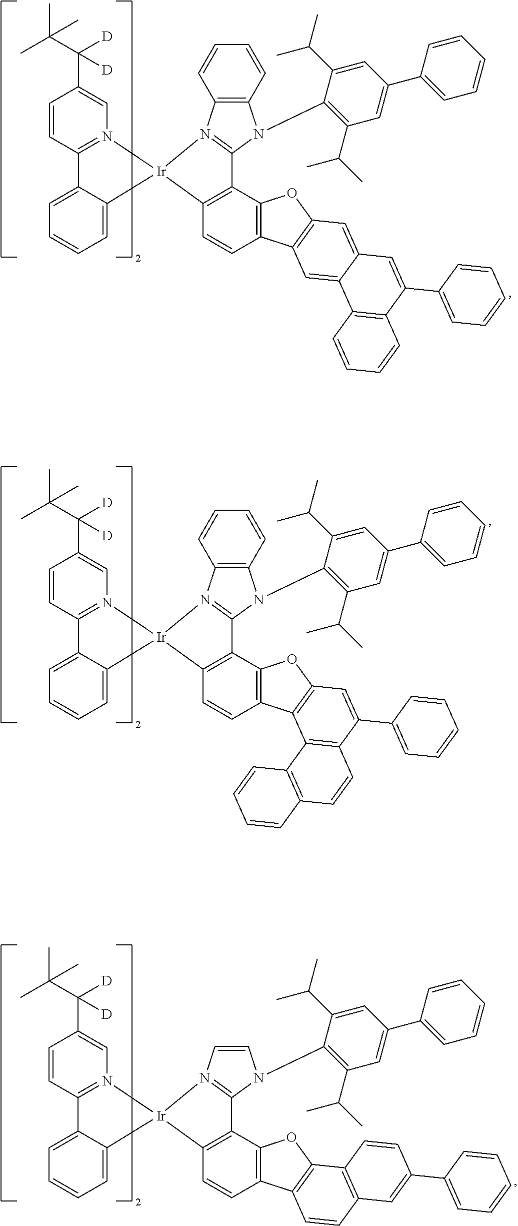

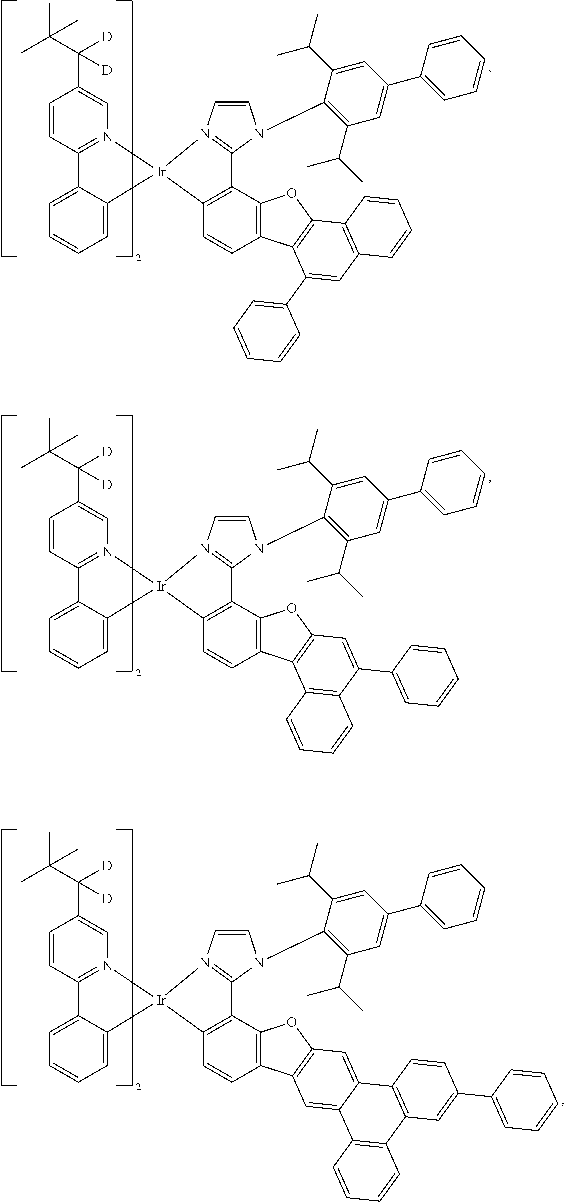

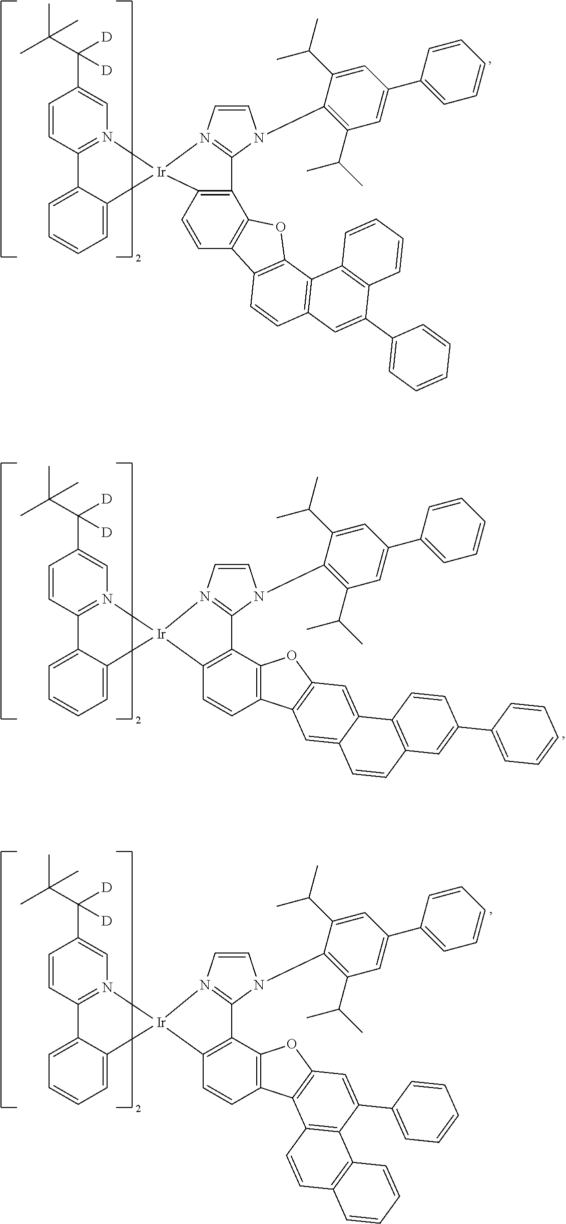

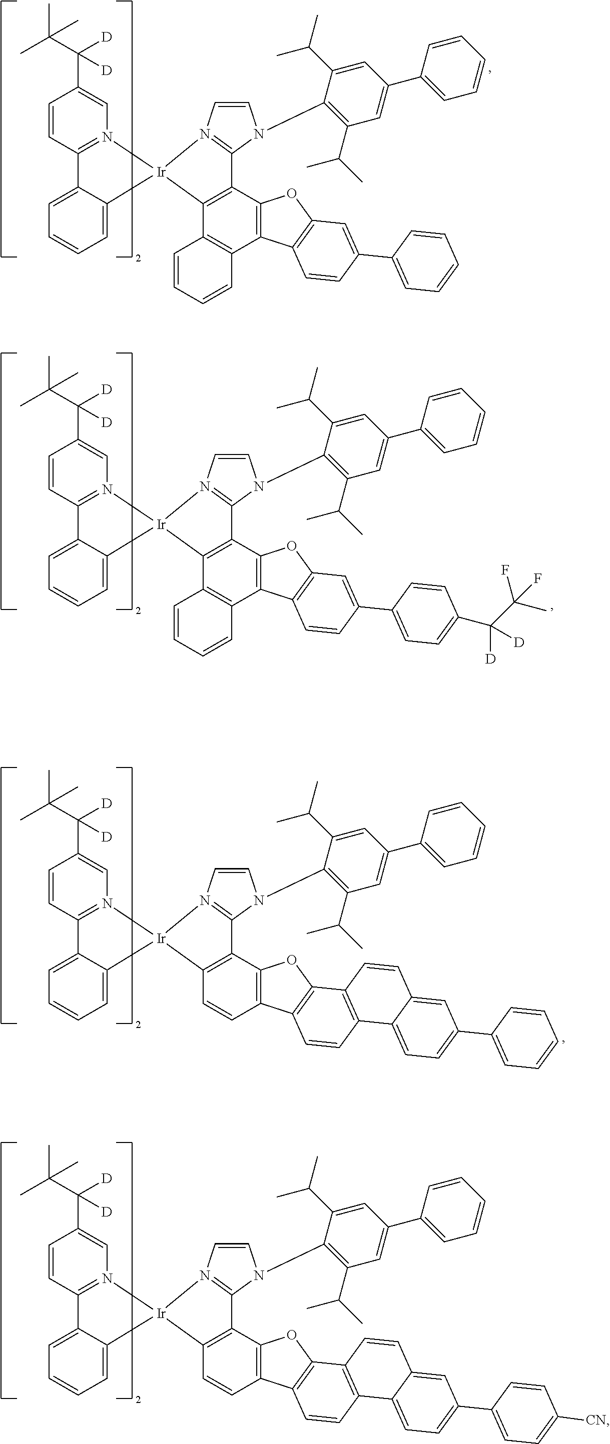

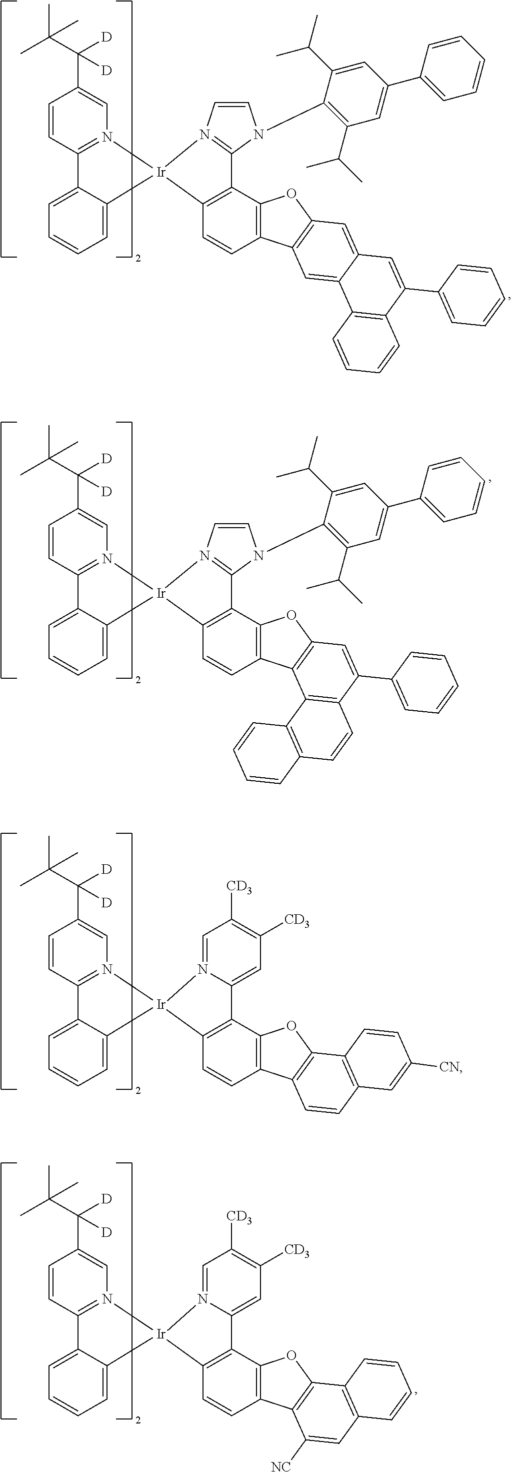

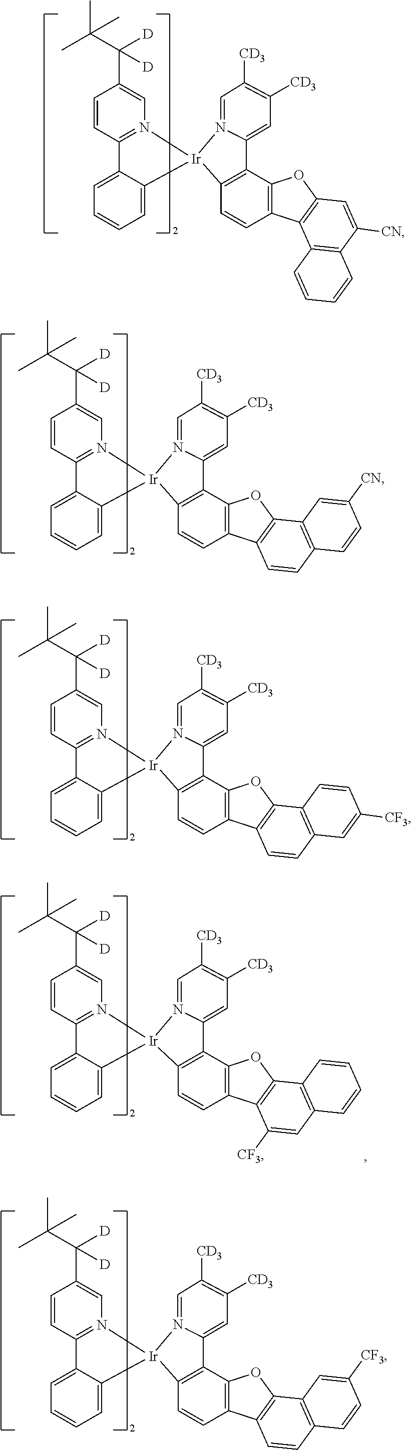

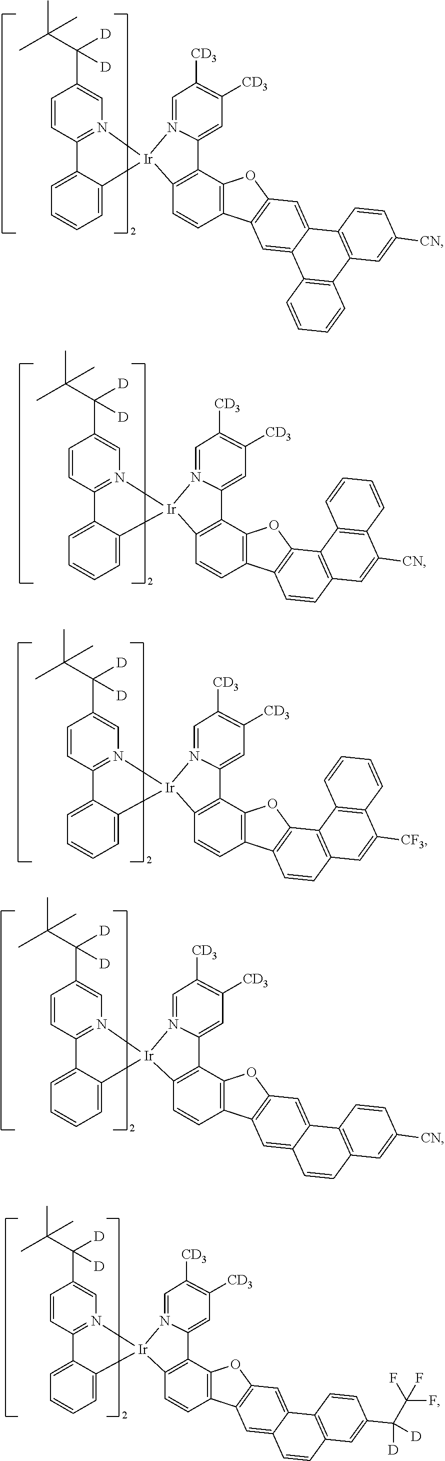

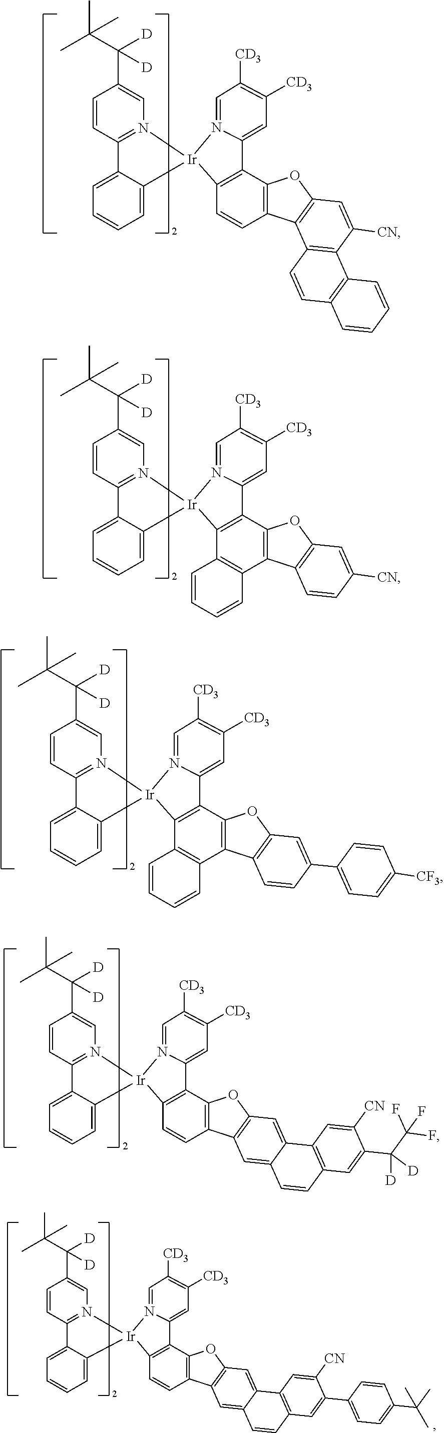

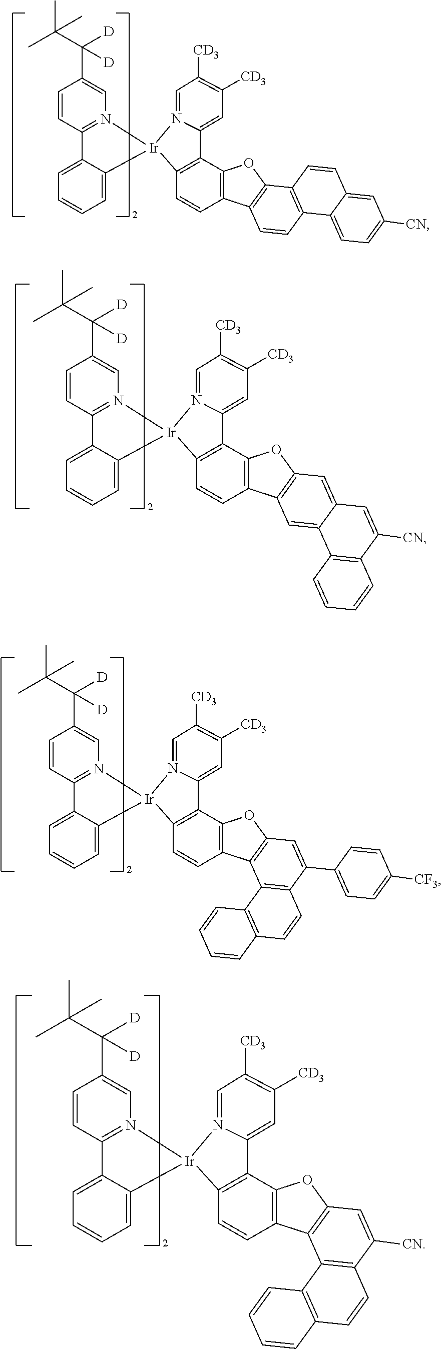

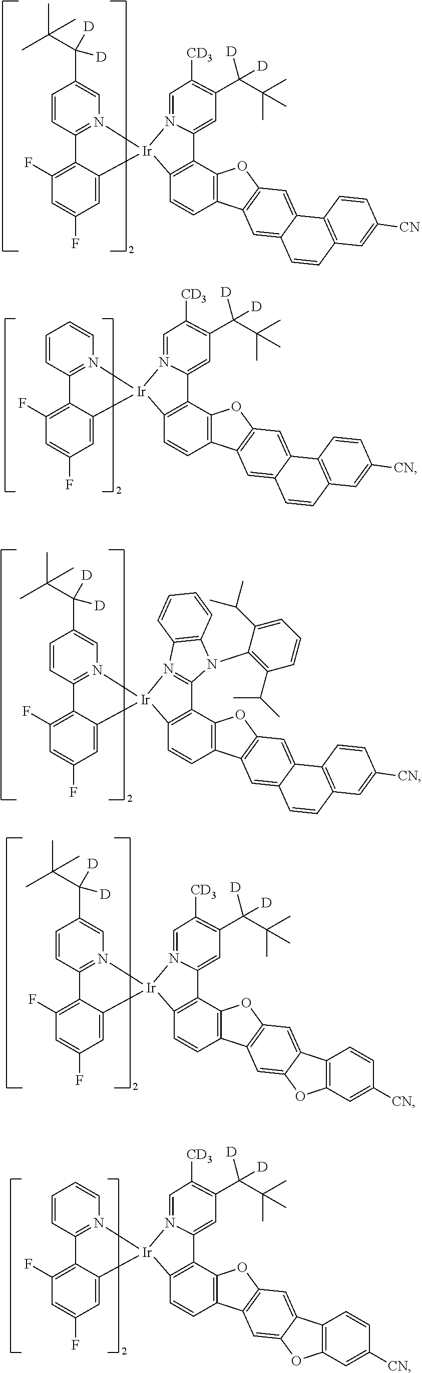

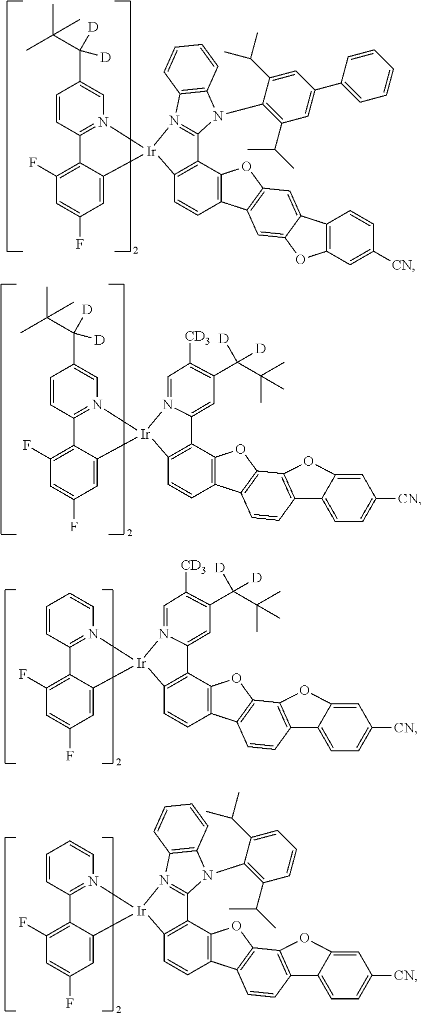

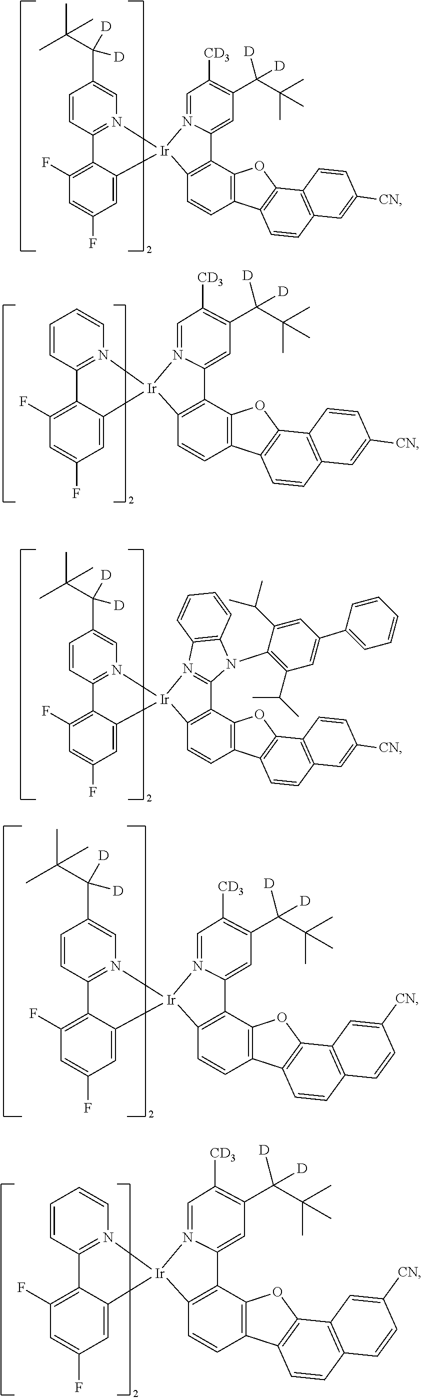

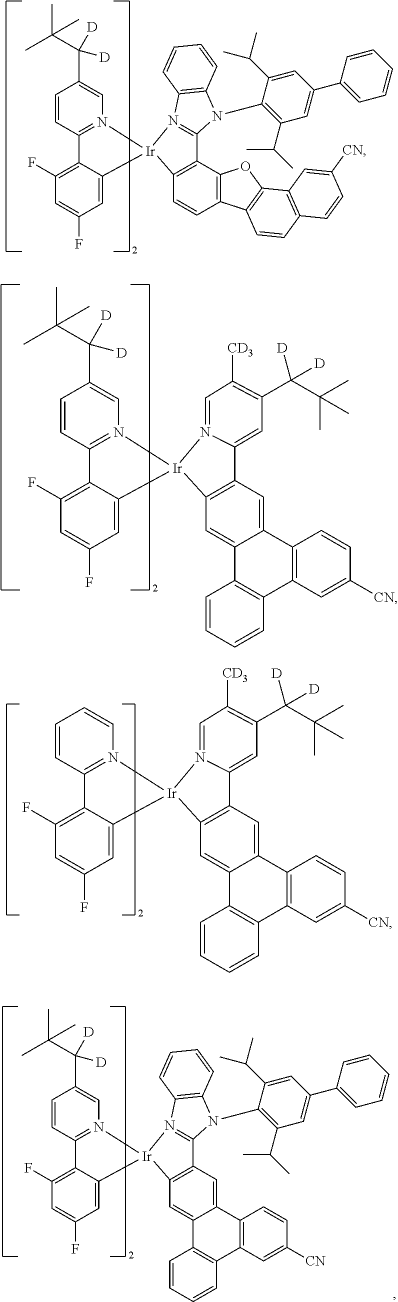

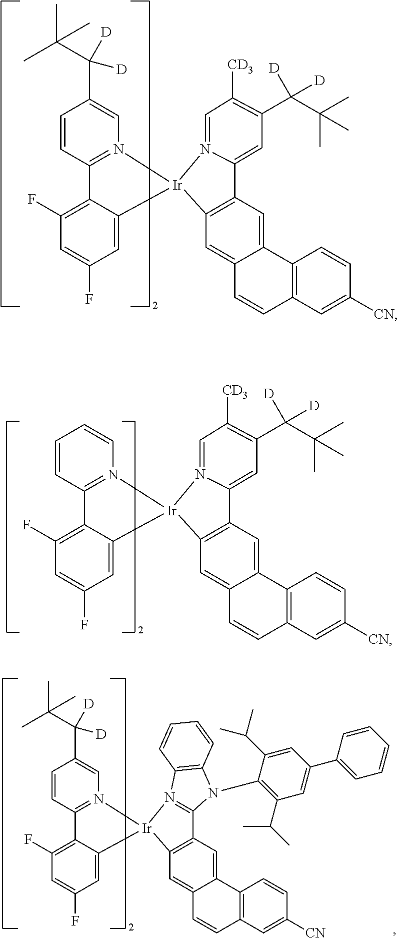

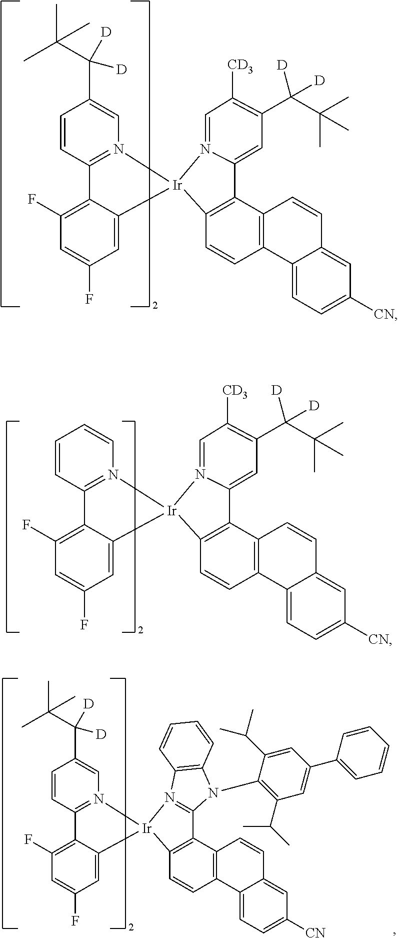

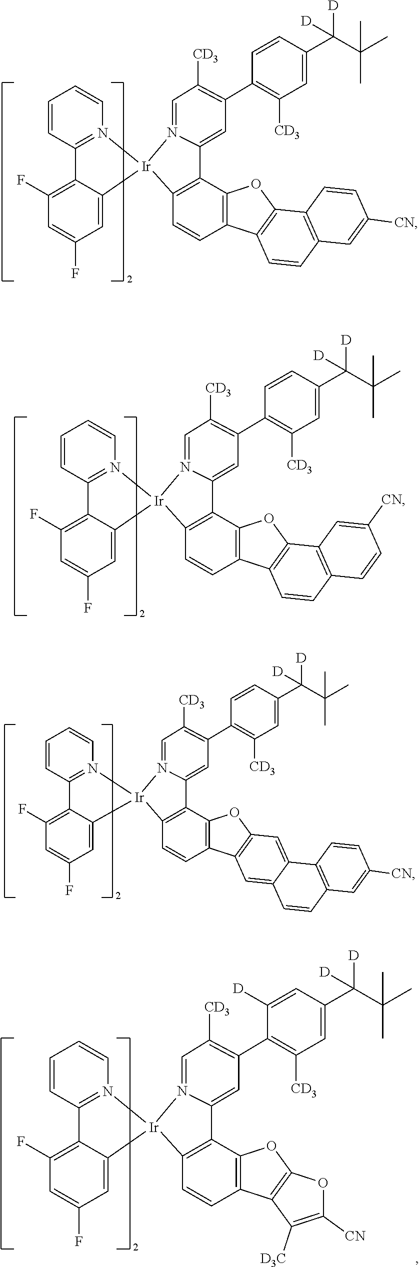

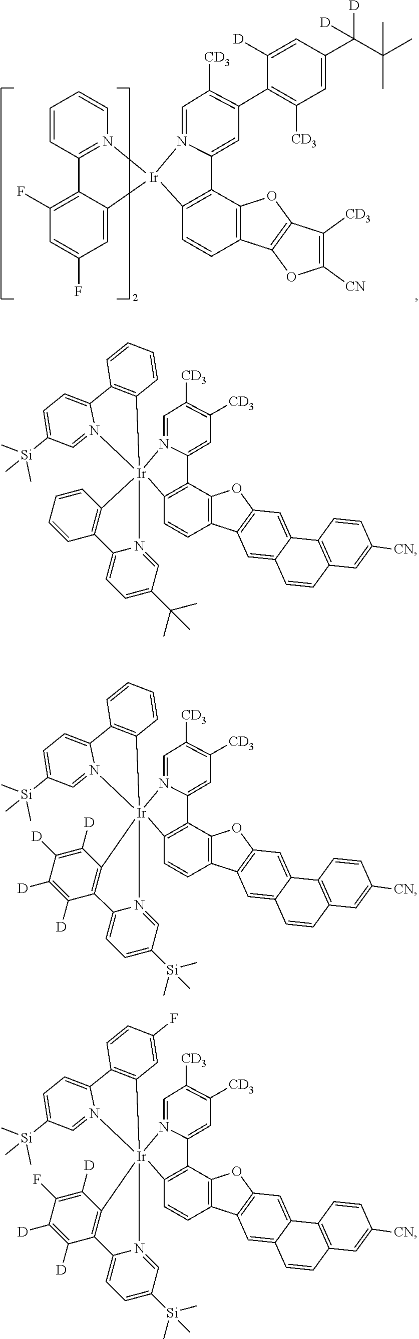

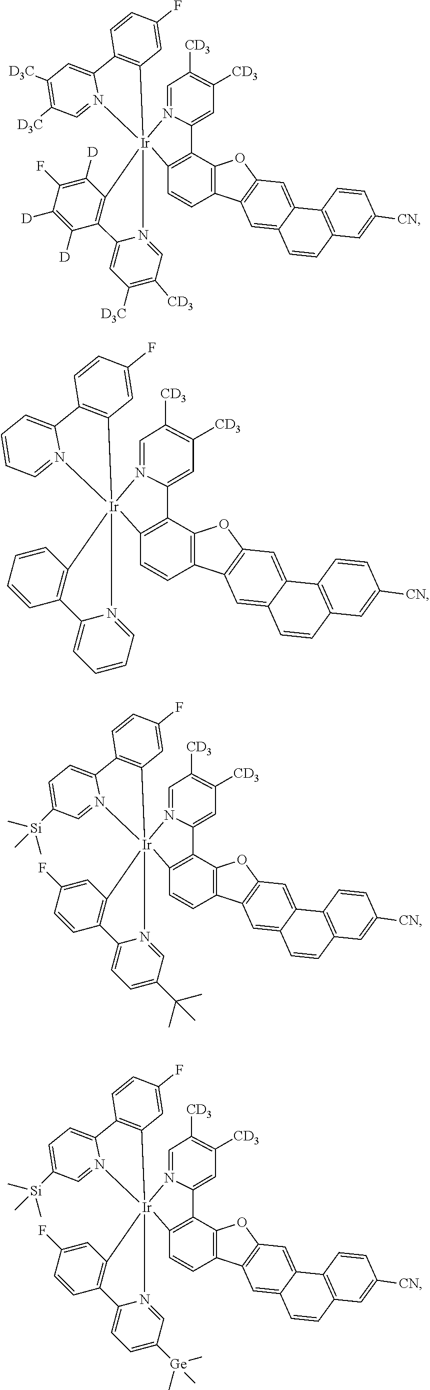

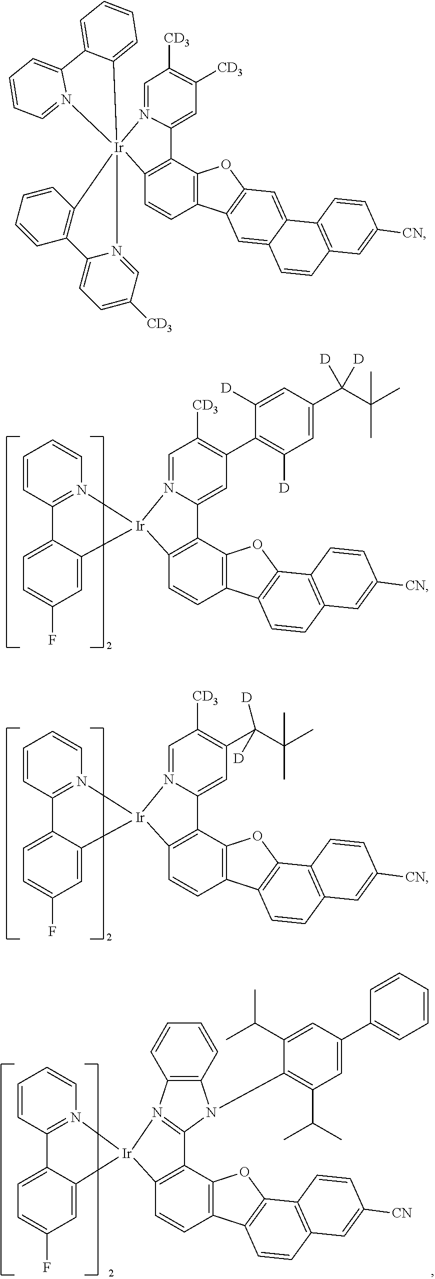

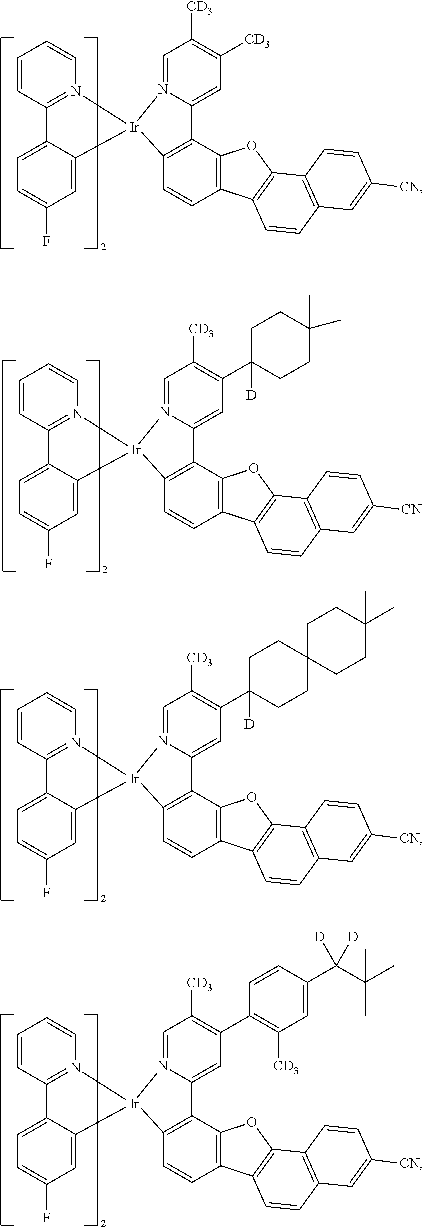

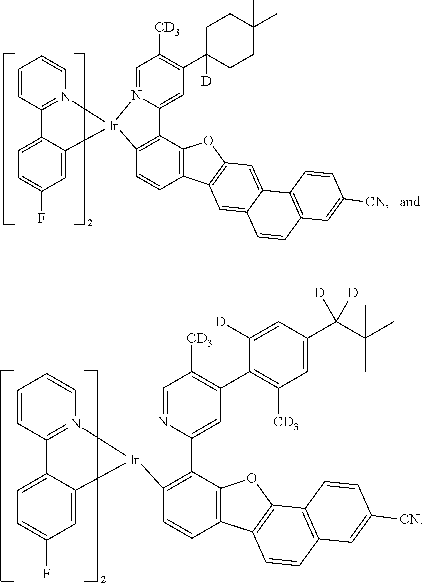

16. The compound of claim 10, wherein the compound has the Formula III: 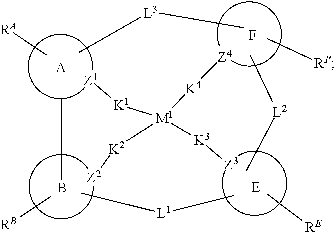
wherein:
M¹ is Pd or Pt;
moieties E and F are each independently monocyclic or polycyclic ring structure comprising 5-membered and/or 6-membered carbocyclic or heterocyclic rings;
Z³ and Z⁴ are each independently C or N;
K¹, K², K³, and K⁴ are each independently selected from the group consisting of a direct bond, O, and S, wherein at least two of them are direct bonds;
L¹, L², and L³ are each independently selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof;
at least one of L¹ and L² is present;
R^{E} and R^{F} each independently represents zero, mono, or up to a maximum allowed number of substitutions to its associated ring;
each R, R′, R^{E}, and R^{F} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof; and
two adjacent R, R′, R^{A}, R^{B}, R^{E}, and R^{F} can be joined or fused together to form a ring where chemically feasible.

17. An organic light emitting device (OLED) comprising:
an anode;
a cathode; and
an organic layer disposed between the anode and the cathode, wherein the organic layer comprises a compound comprising a first ligand L_{A} of Formula I, 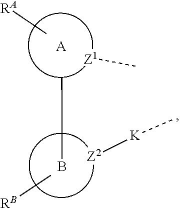
wherein:
moiety A is a 5-membered or 6-membered carbocyclic or heterocyclic ring;
moiety B is a fused ring structure comprising at least three rings, each of which is independently heterocyclic or carbocyclic;
K is a direct bond, S, or O;
each of Z¹ and Z² is independently C or N;
each of R^{A} and R^{B} independently represents mono to the maximum possible number of substitutions, or no substitution;
each R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
any two R^{A} or R^{B} can be joined or fused to form a ring;
at least one R^{B} comprises a cyclic group or an electron-withdrawing group;
L_{A} is coordinated to a metal M;
metal M has an atomic mass of at least 40 and can be coordinated to other ligands; and
the ligand L_{A} is optionally linked with other ligands to comprise a tridentate, tetradentate, pentadentate, or hexadentate ligand.

18. The OLED of claim 17, wherein the organic layer further comprises a host, wherein host comprises at least one chemical moiety selected from the group consisting of triphenylene, carbazole, indolocarbazole, dibenzothiophene, dibenzofuran, dibenzoselenophene, 5λ²-benzo[d]benzo[4,5]imidazo[3,2-a]imidazole, 5,9-dioxa-13b-boranaphtho[3,2,1-de]anthracene, triazine, aza-triphenylene, aza-carbazole, aza-indolocarbazole, aza-dibenzothiophene, aza-dibenzofuran, aza-dibenzoselenophene, aza-5λ²-benzo[d]benzo[4,5]imidazo[3,2-a]imidazole, and aza-(5,9-dioxa-13b-boranaphtho[3,2,1-de]anthracene).

19. The OLED of claim 18, wherein the host is selected from the group consisting of: 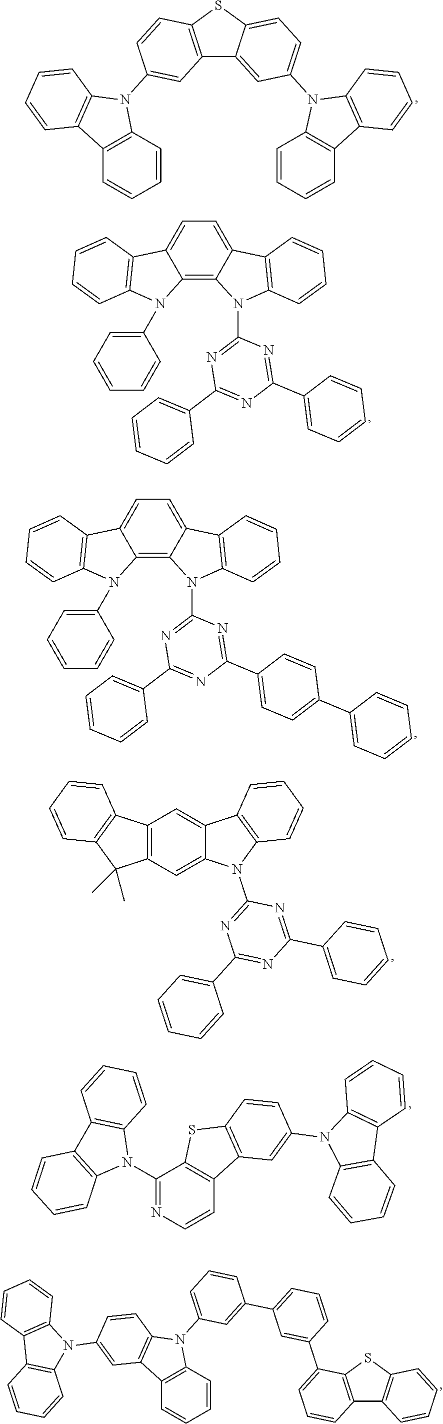 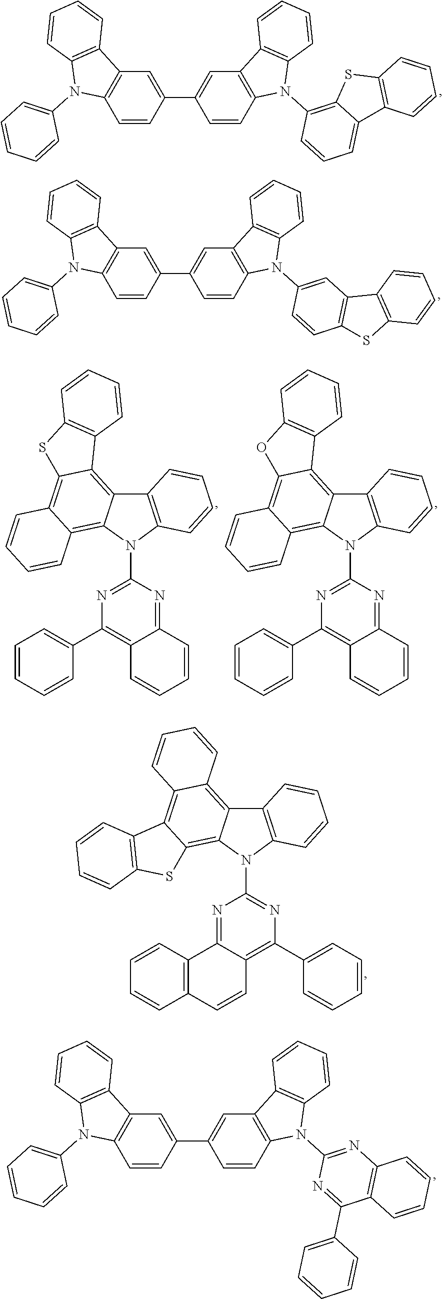 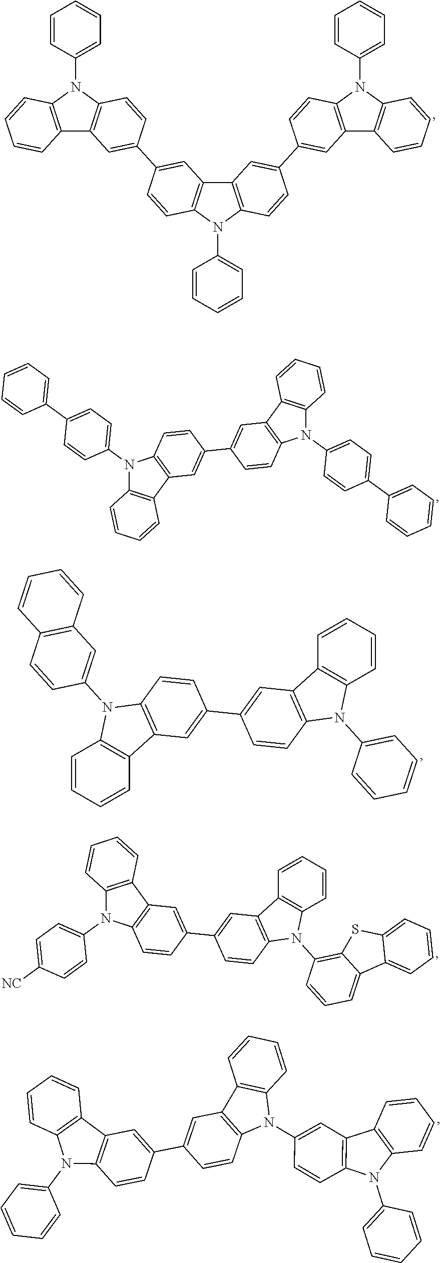 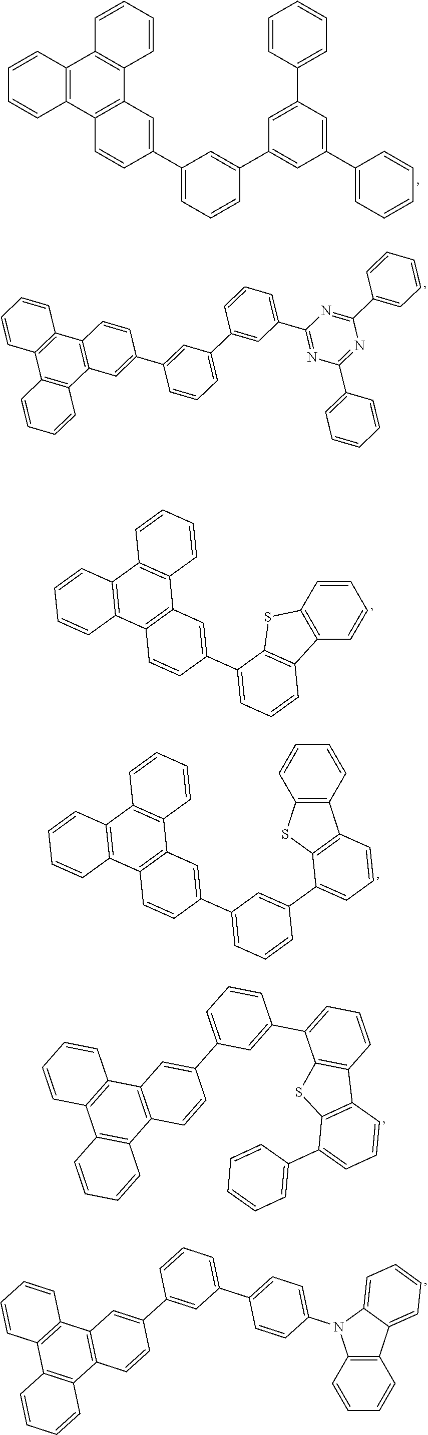 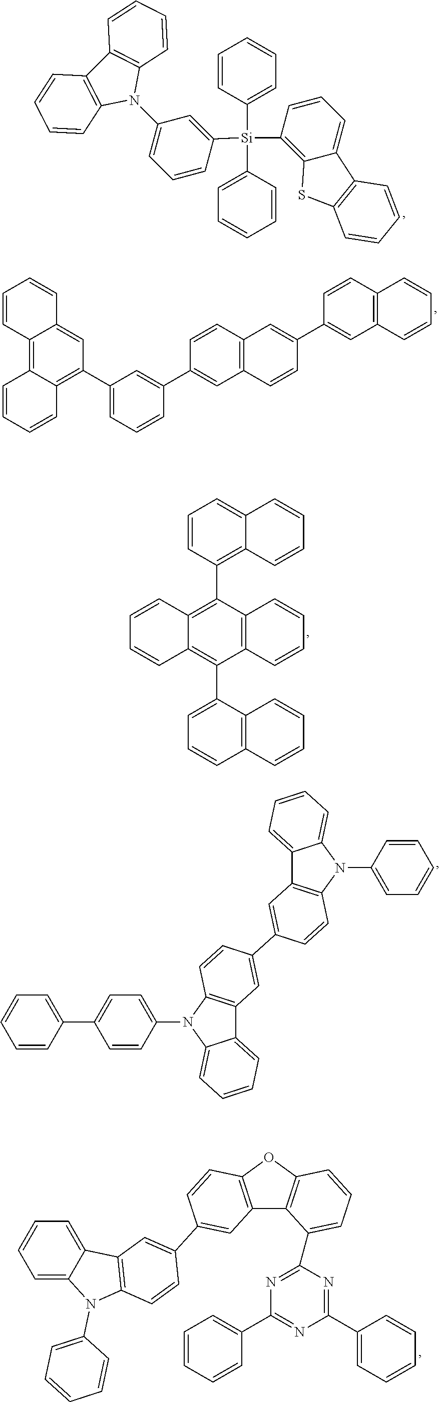 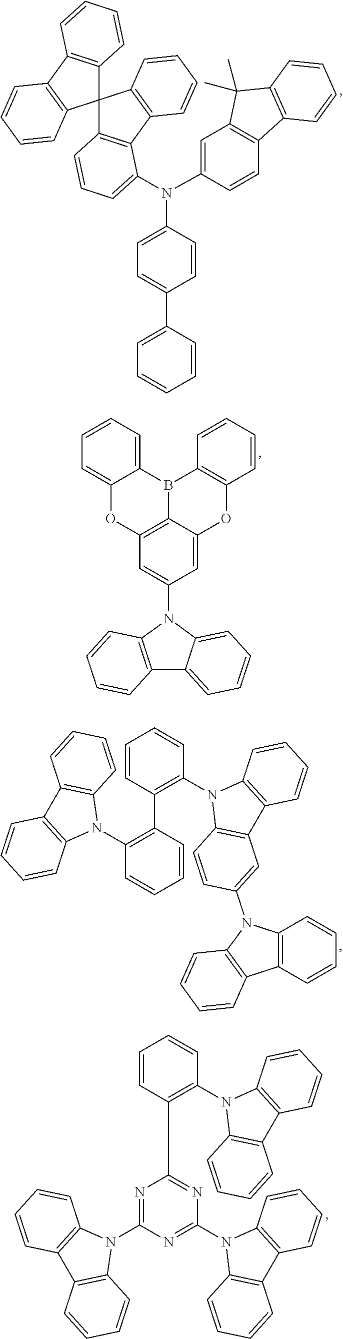 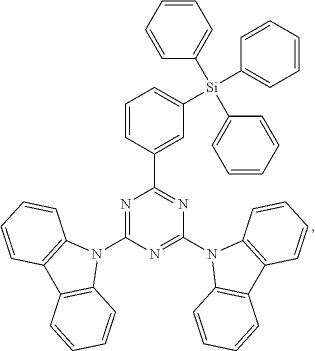 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]
and combinations thereof.

20. A consumer product comprising an organic light-emitting device comprising:
an anode;
a cathode; and
an organic layer disposed between the anode and the cathode, wherein the organic layer comprises a compound comprising a first ligand L_{A} of Formula I, 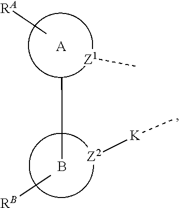
wherein:
moiety A is a 5-membered or 6-membered carbocyclic or heterocyclic ring;
moiety B is a fused ring structure comprising at least three rings, each of which is independently heterocyclic or carbocyclic;
K is a direct bond, S, or O;
each of Z¹ and Z² is independently C or N;
each of R^{A} and R^{B} independently represents mono to the maximum possible number of substitutions, or no substitution;
each R^{A} and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, selenyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
any two R^{A} or R^{B} can be joined or fused to form a ring;
at least one R^{B} comprises a cyclic group or an electron-withdrawing group;
L_{A} is coordinated to a metal M;
metal M has an atomic mass of at least 40 and can be coordinated to other ligands; and
the ligand L_{A} is optionally linked with other ligands to comprise a tridentate, tetradentate, pentadentate, or hexadentate ligand.
